(19) United States
(12) Patent Application Publication
(10) Pub. No.: US 2018/0112022 A1
(43) Pub. Date: Apr. 26, 2018

(54) POLYMERIZABLE COMPOSITION AND OPTICALLY ANISOTROPIC MATERIAL

(71) Applicant: DIC Corporation, Tokyo (JP)

(72) Inventors: Toru Ishii, Kita-adachi-gun (JP); Yasuhiro Kuwana, Kita-adachi-gun (JP); Masahiro Horiguchi, Kita-adachi-gun (JP); Yutaka Kadomoto, Kita-adachi-gun (JP); Tetsuo Kusumoto, Kita-adachi-gun (JP)

(73) Assignee: DIC Corporation, Tokyo (JP)

(21) Appl. No.: 15/541,933

(22) PCT Filed: Jan. 14, 2016
(86) PCT No.: PCT/JP2016/050986

§ 371 Date: Dec. 11, 2017

(30) Foreign Application Priority Data
Jan. 16, 2015 (JP) 2015-006293

(51) Int. Cl. C08F 220/38; H01L 51/00; C08F 222/24; G02B 5/30

(52) U.S. Cl. CPC C08F 220/38; H01L 51/004; H01L 51/5281; G02B 5/3016; C08F 2220/387; C08F 222/24

(57) ABSTRACT

Provided are a polymerizable composition in which precipitation or the like of crystals does not occur and which has high storage stability; and a polymerizable composition in which unevenness is unlikely to occur when a film-like polymerized material obtained by polymerizing the composition is prepared. Further, provided are an optically anisotropic body, a retardation film, an optical compensation film, an anti-reflective film, a lens, and a lens sheet which are formed of the polymerizable composition, a liquid crystal display element, an organic light-emitting display element, a lighting element, an optical component, a colorant, a security marking, a member for emitting a laser, a polarizing film, a coloring material, and a printed matter for which the polymerizable composition is used.

### TECHNICAL FIELD

The present invention relates to a polymer having optical anisotropy that requires various optical characteristics, a polymerizable composition which is useful as a constituent member of a film, an optically anisotropic body, a retardation film, an optical compensation film, an anti-reflective film, a lens, and a lens sheet which are formed of the polymerizable composition, a liquid crystal display element, an organic light-emitting display element, a lighting element, an optical component, a colorant, a security marking, a member for emitting a laser, and a printed matter for which the polymerizable composition is used.

### BACKGROUND ART

A compound (polymerizable compound) containing a polymerizable group is used for various optical materials. For example, a uniformly aligned polymer can be prepared by aligning a polymerizable composition containing a polymerizable compound in a liquid crystal state and then polymerizing the aligned composition. Such a polymer can be used for a polarizing plate, a retardation plate, and the like which are required for a display. In many cases, a polymerizable composition containing two or more polymerizable compounds is used to satisfy optical characteristics, the polymerization rate, the solubility, the melting point, the glass transition temperature, the transparency of the polymer, the mechanical strength, the surface hardness, the heat resistance, and the light resistance to be required. At this time, it is necessary that the polymerizable compounds to be used provide excellent physical properties for the polymerizable composition without adversely affecting other characteristics.

In order to improve the viewing angle of a liquid crystal display, wavelength dispersion of the birefringence of a retardation film needs to be low or reversed. As materials for this purpose, various polymerizable liquid crystal compounds having reversed wavelength dispersion or low wavelength dispersion have been developed. However, precipitation of crystals occurs and storage stability is insufficient in a case where those polymerizable compounds are added to a polymerizable composition (PTL 1). Further, there is a problem in that unevenness tends to occur in a case where a base material is coated with the polymerizable composition and polymerized (PTLs 1 to 3). Unevenness occurs in brightness of a screen or the color tone thereof becomes unnatural in a case where the film in which unevenness has occurred is used for a display or the like, and this results in a problem of significant degradation of the quality of a display product. Therefore, there has been a demand for development of polymerizable liquid crystal compounds having reversed wavelength dispersion or low wavelength dispersion, which can solve such problems.

### CITATION LIST

### Patent Literature

[PTL 1] JP-A-2008-107767

[PTL 2] JP-T-2010-522892

[PTL 3] JP-T-2013-509458

### SUMMARY OF INVENTION

### Technical Problem

An object of the present invention is to provide a polymerizable composition in which precipitation or the like of crystals does not occur and which has high storage stability; and a polymerizable composition in which unevenness is unlikely to occur when a film-like polymerized material obtained by polymerizing the composition is prepared. Further, another object thereof is to provide an optically anisotropic body, a retardation film, an optical compensation film, an anti-reflective film, a lens, and a lens sheet which are formed of the polymerizable composition, a liquid crystal display element, an organic light-emitting display element, a lighting element, an optical component, a colorant, a security marking, a member for emitting a laser, and a printed matter for which the polymerizable composition is used.

### Solution to Problem

The present invention has been made in order to solve the problems and completed as the result of intensive research by focusing on a polymerizable composition for which a liquid crystal compound which has a specific structure containing one polymerizable group is used.

In other words, the present invention provides a polymerizable composition including: a polymerizable compound (a) represented by General Formula (1);

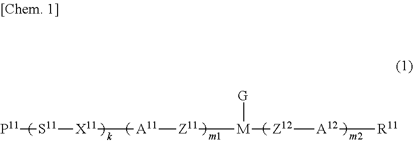

(in the formula, P¹¹ represents a polymerizable group, S¹¹ represents a spacer group or a single bond, and in a case where a plurality of S¹¹ is present, these may be the same as or different from each other, X¹¹ represents —O—, —S—, —OCH₂—, —CH₂O—, —CO—, —COO—, —OCO—, —CO—S—, —S—CO—, —O—CO—O—, —CO—NH—, —NH—CO—, —SCH₂—, —CH₂S—, —CF₂O—, —OCF₂—, —CF₂S—, —SCF₂—, —CH═CH—COO—, —CH═CH—OCO—, —COO—CH═CH—, —OCO—CH═CH—, —COO—CH₂CH₂—, —OCO—CH₂CH—, —CH₂CH₂—COO—, —CH₂CH₂—OCO—, —COO—CH₂—, —OCO—CH₂—, —CH₂—COO—, —CH₂—OCO—, —CH═CH—, —N═N—, —CH═N—N═CH—, —CF═CF—, —C≡C—, or a single bond, and in a case where a plurality of X¹¹ is present, these may be the same as or different from each other, provided that P¹¹—(S¹¹—X¹¹)ₖ— does not have a —O—O— bond, A¹¹ and A¹² each independently represent a 1,4-phenylene group, a 1,4-cyclohexylene group, a pyridine-2,5-diyl group, a pyrimidine-2,5-diyl group, a naphthalene-2, 6-diyl group, a naphthalene-1,4-diyl group, a tetrahydronaphthalene-2, 6-diyl group, a decahydronaphthalene-2, 6-diyl group, or a 1, 3-dioxane-2,5-diyl group, these groups may be unsubstituted or substituted with one or more of L¹'s, and in a case where a plurality of each of A¹¹ and A¹² is present, these may be the same as or different from each other, Z¹¹ and Z¹² each independently represent —O—, —S—, —OCH₂—, —CH₂O—, —CH₂CH₂—, —CO—, —COO—, —OCO—, —CO—S—, —S—CO—, —O—CO—O—, —CO—NH—, —NH—CO—, —OCO—NH—, —NH—COO—, —NH—CO—NH—, —NH—O—, —O—NH—, —SCH₂—, —CH₂S—, —CF₂O—, —OCF₂—, —CF₂S—, —SCF₂—, —CH═CH—COO—, —CH═CH—OCO—, —COO— CH═CH—, —OCO—CH═CH—, —CO—CH₂CH₂—, —OCO—CH₂CH₂—, —CH₂CH₂—COO—, —CH₂CH₂—OCO—, —COO—CH₂—, —OCO—CH₂—, —CH₂—COO—, —CH₂—OCO—, —CH═CH—, —N═N—, —CH═N—, —N═CH—, —CH═N—N═CH—, —CF═CF—, —C≡C—, or a single bond, and in a case where a plurality of each of Z¹¹ and Z¹² is present, these may be the same as or different from each other, k represents an integer of 0 to 8, m1 and m2 each independently represent an integer of 0 to 5, and m1+m2 represents an integer of 1 to 5, N represents a group selected from groups represented by Formula (M-1) to Formula (M-8), and these groups may be unsubstituted or substituted with one or more of L¹'s,

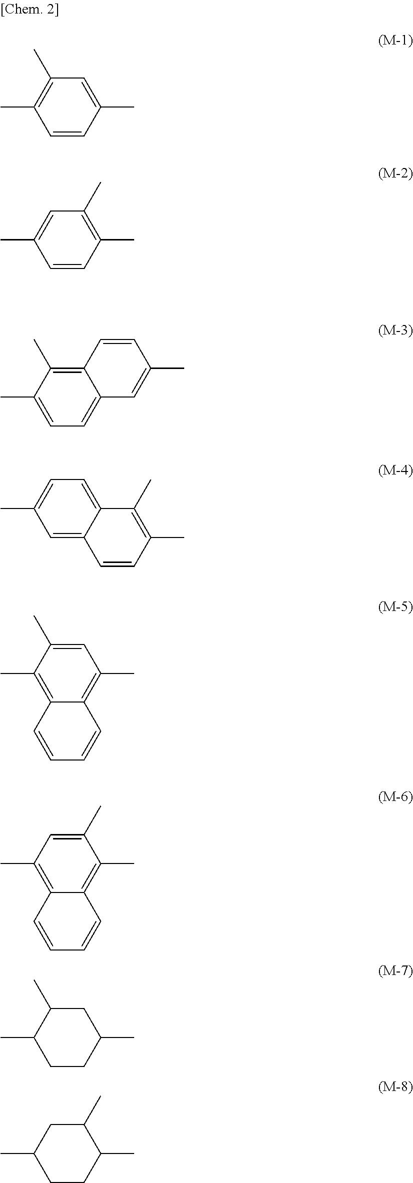

R¹¹ represents a hydrogen atom, a fluorine atom, a chlorine atom, a bromine atom, an iodine atom, a pentafluoro su furanyl group, a cyano group, a nitro group, an isocyano group, a thioisocyano group, or a linear or branched alkyl group having 1 to 20 carbon atoms in which one —CH₂— or two or more (—CH₂—)'s which are not adjacent to each other may be each independently substituted with —O—, —S—, —CO—, —COO—, —OCO—, —CO—S—, —S—CO—, —O—CO—O—, —CO—NH—, —NH—CO—, or —C≡C—, and one or more of arbitrary hydrogen atoms in the alkyl group may be substituted with a fluorine atom, G represents a group selected from groups represented by Formula (G-1) or (G-2),

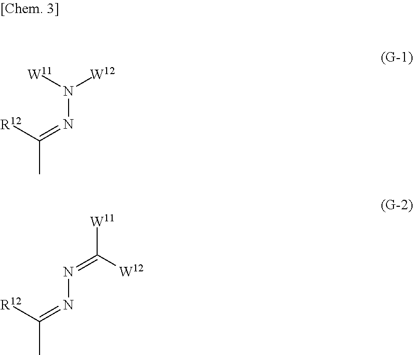

(In the formulae, R¹² represents a hydrogen atom or a linear or branched alkyl group having 1 to 20 carbon atoms in which one —CH₂— or two or more (—CH₂—)'s which are not adjacent to each other may be each independently substituted with —O—, —S—, —CO—, —COO—, —OCO—, —CO—S—, —S—CO—, —O—CO—O—, —CO—NH—, —NH—CO—, or —C≡C—, and one or more of arbitrary hydrogen atoms in the alkyl group may be substituted with a fluorine atom, W¹¹ represents a group having at least one aromatic group and 5 to 30 carbon atoms and the group may be unsubstituted or substituted with one or more of L¹'s, W¹² represents a hydrogen atom or a linear or branched alkyl group having 1 to 20 carbon atoms in which one —CH₂— or two or more (—CH₂—)'s which are not adjacent to each other may be each independently substituted with —O—, —S—, —CO—, —COO—, —OCO—, —CO—S—, —S—CO—, —O—CO—O—, —CO—NH—, —NH—CO—, —CH═CH—COO—, —CH═CH—OCO—, —COO—CH═CH—, —OCO—CH═CH—, —CH═CH—, —CF═CF—, or —C≡C—, and one or more of arbitrary hydrogen atoms in the alkyl group may be substituted with a fluorine atom, W¹² may have the same definition as that for W¹¹, W¹¹ and W¹² may be linked to each other to form a ring structure, W⁸² represents a group selected from groups represented by the following formula,

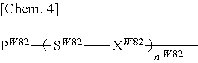

(in the formula, P^{W82} has the same definition as that for R¹¹, S^{W82} has the same definition as that for S¹¹, X^{W82} has the same definition as that for X¹¹, and n^{W82} has the same definition as that for k), and one or more of arbitrary hydrogen atoms in the alkyl group may be substituted with a fluorine atom, L¹ represents a fluorine atom, a chlorine atom, a bromine atom, an iodine atom, a pentafluorosulfuranyl group, a nitro group, an isocyano group, an amino group, a hydroxyl group, a mercapto group, a methylamino group, a dimethylamino group, a diethylamino group, a diisopropylamino group, a trimethylsilyl group, a dimethylsilyl group, a thioisocyano group, or an alkyl group having 1 to 20 carbon atoms, and the alkyl group may be linear or branched, one or more of arbitrary hydrogen atoms may be substituted with a fluorine atom, one —CH₂— or two or more (—CH₂—)'s which are not adjacent to each other in the alkyl group may be each independently substituted with a group selected from —O—, —S—, —CO—, —COO—, —OCO—, —CO—S—, —S—CO—, —O—CO—O—, —CO—NH—, —NH—CO—, —CH═CH—COO—, —CH═CH—OCO—, —COO—CH═CH—, —OCO—CH═CH—, —CH═CH—, —CF═CF—, or —C≡C—, and in a case where a plurality of L¹ is present in the compound, these may be the same as or different from each other)

a polymerizable compound (b) which contains at least two or more polymerizable groups;

an initiator (c) as necessary; and

a solvent (d) as necessary.

Further, the present invention provides an optically anisotropic body, a retardation film, an optical compensation film, an anti-reflective film, a lens, and a lens sheet which are formed of the polymerizable composition, a liquid crystal display element, an organic light-emitting display element, a lighting element, an optical component, a colorant, a security marking, a member for emitting a laser, and a printed matter for which the polymerizable composition is used.

### Advantageous Effects of Invention

It is possible to obtain a polymerizable composition having excellent solubility and storage stability by using a liquid crystal compound which contains one polymerizable group and has a specific structure and reversed wavelength dispersibility or low wavelength dispersibility and a polymerizable compound which contains at least two or more polymerizable groups and to obtain a polymer, an optically anisotropic body, and a retardation film which have excellent productivity by using the polymerizable composition.

### BRIEF DESCRIPTION OF DRAWINGS

FIG. 1 is a diagram showing a change in retardation (phase difference) of an optically anisotropic body obtained in Example 145 and a change in incident angle dependence of the retardation.

FIG. 2 is a diagram showing a change in retardation (phase difference) of an optically anisotropic body obtained in Example 148 and a change in incident angle dependence of the retardation.

### DESCRIPTION OF EMBODIMENTS

Hereinafter, the best mode of a polymerizable composition according to the present invention will be described. In the present invention, the “liquid crystalline compound” is intended to show a compound having a mesogenic skeleton and the compound alone does not need to exhibit liquid crystallinity. Further, a polymerizable compound can be made into a polymer (or a film) by performing a polymerization treatment by means of irradiating the polymerizable composition with light such as ultraviolet rays or heating the polymerizable composition.

Further, in a graph obtained by plotting a wavelength λ of incident light, which is incident on the retardation film, on a horizontal axis and a birefringence Δn of the incident light on a vertical axis, in a case where the birefringence Δn becomes smaller as the wavelength λ becomes shorter, such a film is typically referred to as having “reversed wavelength dispersibility” or “reversed dispersibility” by those skilled in the art. In the present invention, a compound constituting a retardation film exhibiting reversed wavelength dispersibility is referred to as a reversed wavelength dispersible compound or a low wavelength dispersible compound.

Compound Represented by General Formula (1)

The polymerizable composition of the present invention contains a compound represented by General Formula (1) as an indispensable component. Further, the compound represented by General Formula (1) does not have a —O—O— bond.

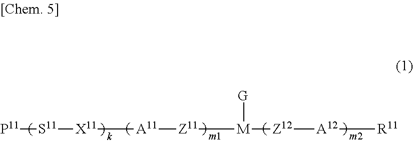

In General Formula (1), it is preferable that polymerizable groups P¹¹ represents a group selected from groups represented by any of Formulae (P-1) to (P-20) and these polymerizable groups are polymerized by radical polymerization, radical addition polymerization, cationic pclymerization, and anionic polymerization.

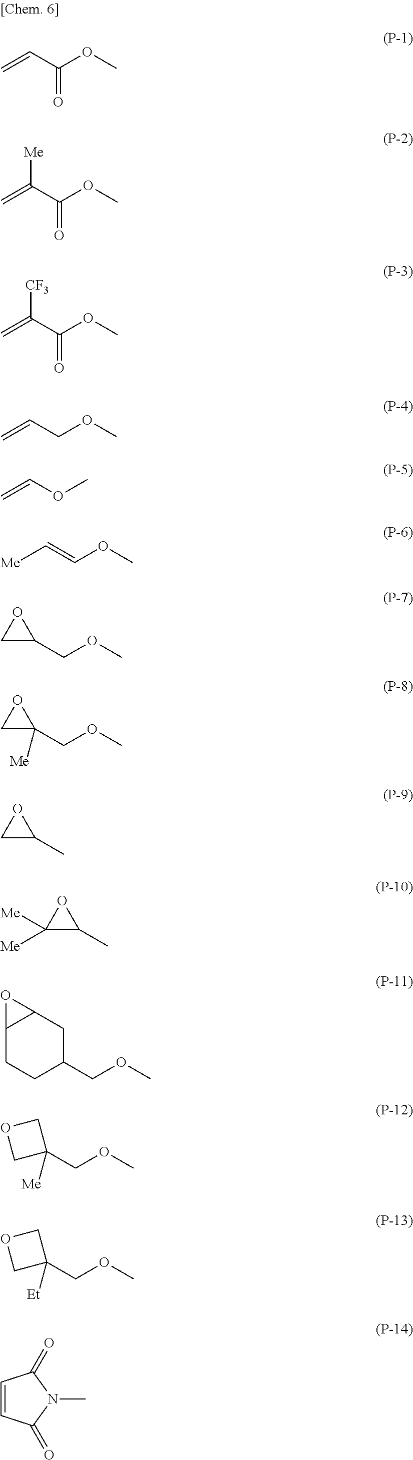

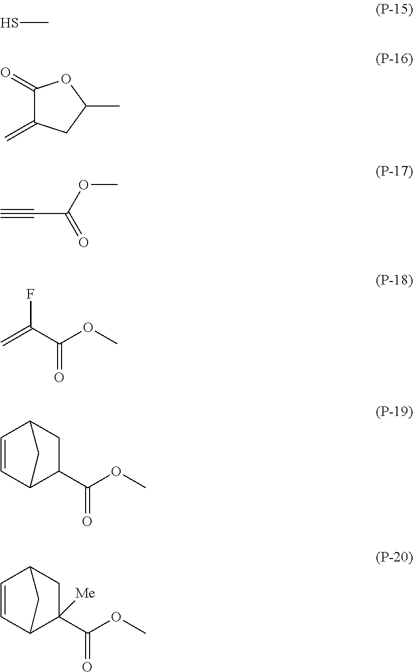

Particularly, in a case where ultraviolet polymerization is performed as a polymerization method, Formula (P-1), Formula (P-2), Formula (P-3), Formula (P-4), Formula (P-5), Formula (P-7), Formula (P-11), Formula (P-13), Formula (P-15), or Formula (P-18) is preferable, Formula (P-1), Formula (P-2), Formula (P-7), Formula (P-11), or Formula (P-13) is more preferable, Formula (P-1), Formula (P-2), or Formula (P-3) is still more preferable, and Formula (P-1) or Formula (P-2) is particularly preferable.

S¹¹ represents a spacer group or a single bond, and in a case where a plurality of S¹¹ is present, these may be the same as or different from each other. Further, it is preferable that the spacer group is an alkylene group having 1 to 20 carbon atoms in which one —CH₂— or two or more (—CH₂—)'s which are not adjacent to each other may be each independently substituted with —O—, —COO—, —OCO—, —OCO—O—, —CO—NH—, —NH—CO—, —CH═CH—, or —C≡C—. From the viewpoints of easily obtaining raw materials and ease of synthesis, in a case where a plurality of S is present, these may be the same as or different from each other. It is more preferable that S¹¹'s each independently represent a single bond or an alkylene group having 1 to 10 carbon atoms in which one —CH₂— or two or more (—CH₂—)'s which are not adjacent to each other may be each independently substituted with —O—, —COO—, or —OCO—, and it is still more preferable that S¹¹'s each independently represent an alkylene group having 1 to 10 carbon atoms or a single bond. Further, in the case where a plurality of S¹¹ is present, these may be the same as or different from each other, and it is particularly preferable that S¹¹'s each independently represent an alkylene group having 1 to 8 carbon atoms.

X¹¹ represents —O—, —S—, —OCH₂—, —CH₂O—, —CO—, —COO—, —OCO—, —CO—S—, —S—CO—, —O—CO—O—, —CO—NH—, —NH—CO—, —SCH₂—, —CH₂S—, —CF₂O—, —OCF₂—, —CF₂S—, —SCF₂—, —CH═CH—COO—, —CH═CH—OCO—, —COO—H═CH—, —OCO—CH═H—, —COO—CH₂CH₂—, —OCO—CH₂CH₂—, —CH₂CH₂—COO—, —CH₂CH₂—OCO—, —COO—CH₂—, —OCO—CH₂—, —CH₂—COO—, —CH₂—OCO—, —CH═CH—, —N═N—, —CH═N—N═CH—, —CF═CF—, —C≡C—, or a single bond, and in a case where a plurality of X¹¹ is present, these may be the same as or different from each other, provided that P¹¹—(S¹¹—X¹¹)ₖ— does not have a —O—O— bond. From the viewpoints of easily obtaining raw materials and ease of synthesis, in the case where a plurality of X¹¹ is present, these may be the same as or different from each other, and it is preferable that X¹¹'s each independently represent —O—, —S—, —OCH₂—, —CH₂O—, —COO—, —OCO—, —CO—S—, —S—CO—, —O—CO—O—, —CO—NH—, —NH—CO—, —COO—CH₂CH₂—, —OCO—CH₂CH₂—, —CH₂CH₂—COO—, —CH₂CH₂—OCO—, or a single bond and more preferable that X¹¹'s each independently represent —O—, —OCH₂—, —CH₂O—, —COO—, —OCO—, —COO—CH₂CH₂—, —OCO—CH₂CH₂—, —CH₂CH₂—COO—, —CH₂CH₂—OCO—, or a single bond. In the case where a plurality of X¹¹ is present, these may be the same as or different from each other, and it is particularly preferable that X¹¹'s each independently represent —O—, —COO—, —OCO—, or a single bond.

A¹¹ and A¹² each independently represent a 1, 4-phenylene group, a 1,4-cyclohexylene group, a pyridine-2,5-diyl group, a pyrimidine-2,5-diyl group, a naphthalene-2, 6-diyl group, a naphthalene-1, 4-diyl group, a tetrahydronaphthalene-2,6-diyl group, a decahydronaphthalene-2, 6-diyl group, or a 1, 3-dioxane-2,5-diyl group, these groups may be unsubstituted or substituted with one or more of L¹'s, and in a case where a plurality of each of A¹¹ and A¹² is present, these may be the same as or different from each other.

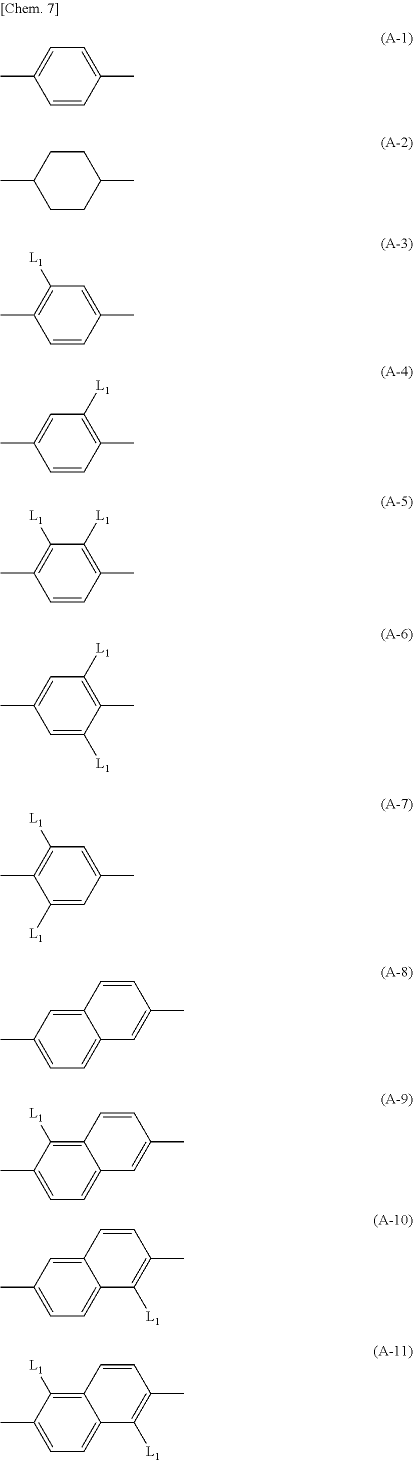

From the viewpoints of easily obtaining raw materials and ease of synthesis, it is preferable that A¹¹ and A¹² each independently represent a 1,4-phenylene group, a 1, 4-cyclohexylene group, or a naphthalene-2,6-diyl group which may be unsubstituted or substituted with one or more of L¹'s, more preferable that A¹¹ and A¹² each independently represent a group selected from groups represented by Formulae (A-1) to (A-11), still more preferable that A¹¹ and A¹² each independently represent a group selected from groups represented by Formulae (A-1) to (A-8), and particularly preferable that A¹¹ and A¹² each independently represent a group selected from groups represented by Formulae (A-1) to (A-4).

Z¹¹ and Z¹² each independently represent —O—, —S—, —OCH₂—, —CH₂O—, —CH₂CH₂—, —CO—, —COO—, —OCO—, —CO—S—, —S—CO—, —O—CO—O—, —CO—NH—, —NH—CO—, —OCO—NH—, —NH—COO—, —NH—CO—NH—, —NH—O—, —O—NH—, —SCH₂—, —CH₂S—, —CF₂O—, —OCF₂—, —CF₂S—, —SCF₂—, —CH═CH—COO—, —CH═CH—OCO—, —COO—CH═CH—, —OCO—CH═CH—, —COO— CH₂CH₂—, —OCO—CH₂CH₂—, —CH₂CH₂—COO—, —CH₂CH₂—OCO—, —COO—CH₂—, —OCO—CH₂—, —CH₂—COO—, —CH₂—OCO—, —CH═CH—, —N═N—, —CH═N—, —N═CH—, —CH═N—N═CH—, —CF═CF—, —C≡C—, or a single bond, and in a case where a plurality of each of Z¹¹ and Z¹² is present, these may be the same as or different from each other. From the viewpoints of liquid crystallinity, easily obtaining raw materials, and ease of synthesis, it is preferable that Z¹¹ and Z¹² each independently represent a single bond, —OCH₂—, —CH₂—O—, —COO—, —OCO—, —CF₂O—, —OCF₂—, —CH₂CH₂—, —CF₂CF₂—, —CH═CH—COO—, —CH═CH—OCO—, —COO—CH═CH—, —OCO—CH═CH—, —COO—CH₂CH₂—, —OCO—CH₂CH₂, —CH₂CH₂—COO—, —CH₂CH₂—OCO—, —CH═CH—, —CF═CF—, —C≡C—, or a single bond, more preferable that Z¹¹ and Z¹² each independently represent —OCH₂—, —CH₂O—, —CH₂CH₂—, —COO—, —OCO—, —COO—CH₂CH₂—, —OCO—CH₂CH₂—, —CH₂CH₂—COO—, —CH₂CH₂—OCO—, —CH═CH—, —C≡C—, or a single bond, still more preferable that Z¹¹ and Z¹² each independently represent —CH₂CH₂—, —COO—, —OCO—, —COO—CH₂CH₂—, —OCO—CH₂CH₂—, —CH₂CH₂—COO—, —CH₂CH₂—OCO—, or a single bond, and particularly preferable that Z¹¹ and Z¹² each independently represent —CH₂CH₂—, —COO—, —OCO—, or a single bond.

k represents an integer of c to 8. From the viewpoints of liquid crystallinity, easily obtaining raw materials, and ease of synthesis, k represents preferably an integer of 0 to 4, more preferably an integer of 0 to 2, still more preferably 0 or 1, and particularly preferably 1.

m1 and m2 each independently represent an integer of 0 to 5 and m1+m2 represents an integer of 1 to 5. From the viewpoints of liquid crystallinity, ease of synthesis, and storage stability, m1 and m2 each independently represent preferably an integer of 1 to 4, more preferably an integer of 1 to 3, and particularly preferably 1 or 2. m1+m2 represents preferably an integer of 1 to 4 and particularly preferably 2 or 3.

M represents a group selected from groups represented by Formula (M-1) to Formula (M-8), and these groups may be unsubstituted or substituted with one or more of L¹'s.

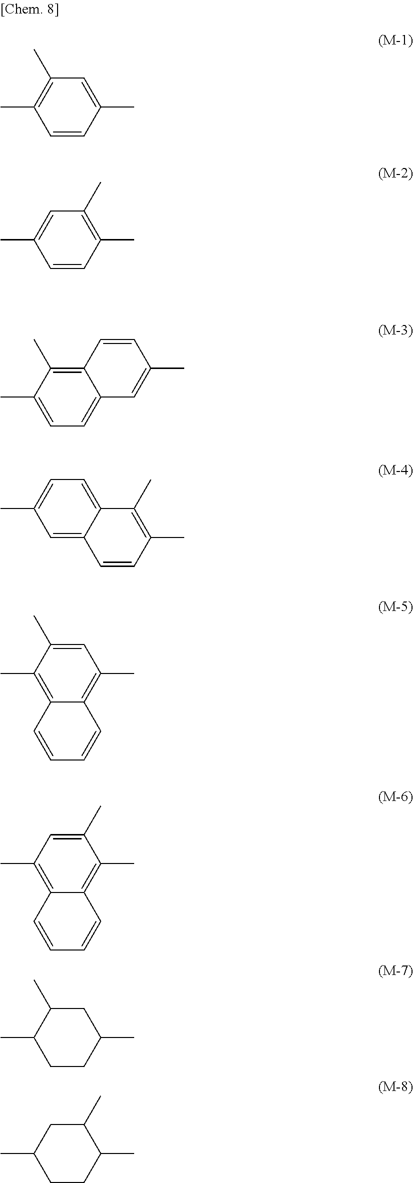

From the viewpoints of easily obtaining raw materials and ease of synthesis, it is preferable that M's each independently represent a group selected from groups represented by Formula (M-1) and (M-2) which may be unsubstituted or substituted with one or more of L¹'s or Formulae (M-3) to (M-6) which are unsubstituted, more preferable that M's each independently represent a group selected from groups represented by Formula (M-1) and (M-2) which may be unsubstituted or substituted with one or more of L's, and particularly preferable that M's each independently represent a group selected from groups represented by Formula (M-1) and (M-2) which are unsubstituted.

R¹¹ represents a hydrogen atom, a fluorine atom, a chlorine atom, a bromine atom, an iodine atom, a pentafluorosulfuranyl group, a cyano group, a nitro group, an isocyano group, a thioisocyano group, or a linear or branched alkyl group having 1 to 20 carbon atoms in which one —CH₂— or two or more (—CH₂—)'s which are not adjacent to each other may be each independently substituted with —O—, —S—, —CO—, —COO—, —OCO—, —CO—S—, —S—CO—, —O—CO—O—, —CO—NH—, —NH—CO—, or —C≡C—, and one or more of arbitrary hydrogen atoms in the alkyl group may be substituted with a fluorine atom. From the viewpoint of liquid crystallinity and ease of synthesis, it is preferable that R¹¹ represents a hydrogen atom, a fluorine atom, a chlorine atom, a cyano group, or a linear or branched alkyl group having 1 to 12 carbon atoms in which one —CH₂— or two or more (—CH₂—)'s which are not adjacent to each other may be each independently substituted with —O—, —COO—, —OCO—, or —O—CO—O—, more preferable that R¹¹ represents a hydrogen atom, a fluorine atom, a chlorine atom, a cyano group, or a linear alkyl group or a linear alkoxy group having 1 to 12 carbon atoms, and particularly preferable that R¹¹ represents a linear alkyl group or a linear alkoxy group having 1 to 12 carbon atoms.

G represents a group selected from groups represented by Formulae (G-1) or (G-2).

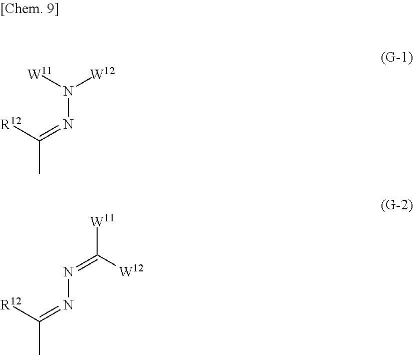

(In the formulae, R¹² represents a hydrogen atom or a linear or branched alkyl group having 1 to 20 carbon atoms in which one —CH₂— or two or more (—CH₂—)'s which are not adjacent to each other may be each independently substituted with —O—, —S—, —CO—, —COO—, —OCO—, —CO—S—, —S—CO—, —O—CO—O—, —CO—NH—, —NH—CO—, or —C≡C—, and one or more of arbitrary hydrogen atoms in the alkyl group may be substituted with a fluorine atom, W¹¹ represents a group having at least one aromatic group and 5 to 30 carbon atoms and the group may be unsubstituted or substituted with one or more of L¹'s, W¹² represents a hydrogen atom or a linear or branched alkyl group having 1 to 20 carbon atoms in which one —CH₂— or two or more (—CH₂—)'s which are not adjacent to each other may be each independently substituted with —O—, —S—, —CO—, —COO—, —OCO—, —CO—S—, —S—CO—, —O—CO—C—, —CO—NH—, —NH—CO—, —CH═CH—CO—, —CH═CH—CO—, —COO—CH═CH—, —OCO—CH═CH—, —CH═CH—, —CF═CF—, or —C≡C—, and one or more of arbitrary hydrogen atoms in the alkyl group may be substituted with a fluorine atom, W¹² may have the same definition as that for W¹¹, W¹¹ and W¹² may be linked to each other to form a ring structure, W¹² represents a group selected from groups represented by the following formula,

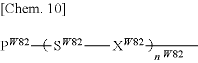

(in the formula, P^{W82} has the same definition as that for R¹¹, S^{W82} has the same definition as that for S¹¹, X^{W82} has the same definition as that for X¹¹, and n^{W82} has the same definition as that for k.))

R¹² represents a hydrogen atom or a linear or branched alkyl group having 1 to 20 carbon atoms in which one —CH₂— or two or more (—CH₂—)'s which are not adjacent to each other may be each independently substituted with —O—, —S—, —CO—, —COO—, —OCO—, —CO—S—, —S—CO—, —O—CO—O—, —CO—NH—, —NH—CO—, or —C≡C—, and one or more of arbitrary hydrogen atoms in the alkyl group may be substituted with a fluorine atom. From the viewpoint of liquid crystallinity and ease of synthesis, one or more of arbitrary hydrogen atoms may be substituted with a fluorine atom, it is preferable that R¹² represents a linear or branched alkyl group having 1 to 12 carbon atoms in which one —CH₂— or two or more (—CH₂—)'s which are not adjacent to each other may be each independently substituted with —O—, —COO—, or —CO—, more preferable that R¹² represents a linear or branched alkyl group having 1 to 12 carbon atoms in which one or more of arbitrary hydrogen atoms may be substituted with a fluorine atom, and particularly preferable that R¹² represents a linear alkyl group having 1 to 12 carbon atoms.

Further, W¹¹ represents a group having at least one aromatic group and 5 to 30 carbon atoms, and the group may be unsubstituted or substituted with one or more of L¹'s. The aromatic group included in the group as W¹¹ may be an aromatic hydrocarbon group or an aromatic heterocyclic group and the group may include both of an aromatic hydrocarbon group and an aromatic heterocyclic group. These aromatic groups may be bonded to each other through a single bond or a linking group and may form a fused ring. Further, in addition to an aromatic group, the group as W¹¹ may further have an acyclic structure and/or a cyclic structure other than the aromatic group. From the viewpoints of easily obtaining raw materials and ease of synthesis, the aromatic group included in the group as W¹¹ is a group represented by any of Formulae (W-1) to (W-19) which may be unsubstituted with one or more of L¹'s.

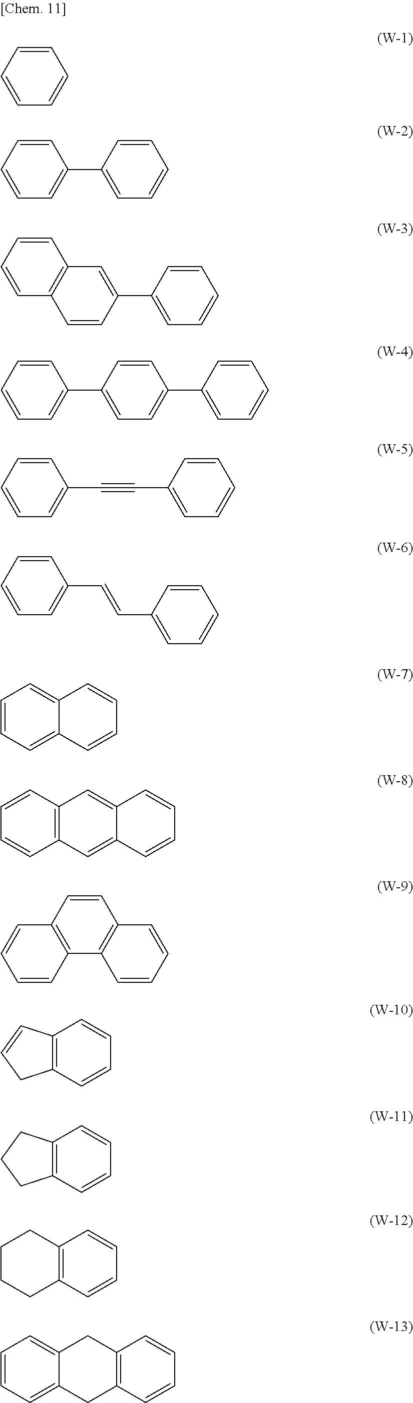

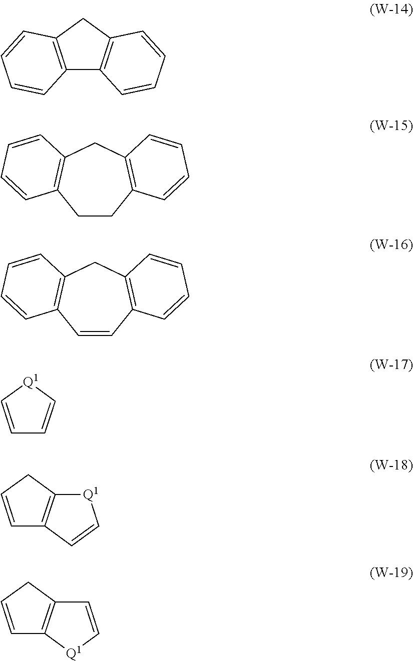

(In the formulae, these groups may have a binding site at an arbitrary position, a group formed by linking two or more aromatic groups selected from these groups with a single bond may be formed, and Q¹ represents —O—, —S—, —NR⁴— (in the formula, R⁴ represents a hydrogen atom or an alkyl group having 1 to 8 carbon atoms), or —CO—. (—CH═)'s in these aromatic groups may be each independently substituted with —N═, (—CH₂—)'s may be each independently substituted with —O—, —S—, —NR⁴—(in the formula, R⁴ represents a hydrogen atom or an alkyl group having 1 to 8 carbon atoms), or —CO— and does not have a —O—O— bond.)

It is preferable that the group represented by Formula (W-1) is a group selected from groups represented by Formulae (W-1-1) to (W-1-8) which may be unsubstituted or substituted with one or more of L¹'s.

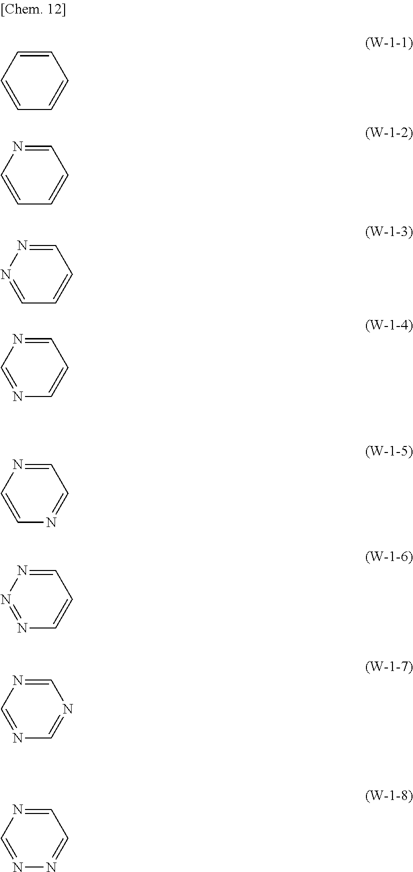

(In the formulae, these groups may have a binding site at an arbitrary position.)

It is preferable that the group represented by Formula (W-7) is a group selected from groups represented by Formulae (W-7-1) to (W-7-7) which may be unsubstituted or substituted with one or more of L¹'s.

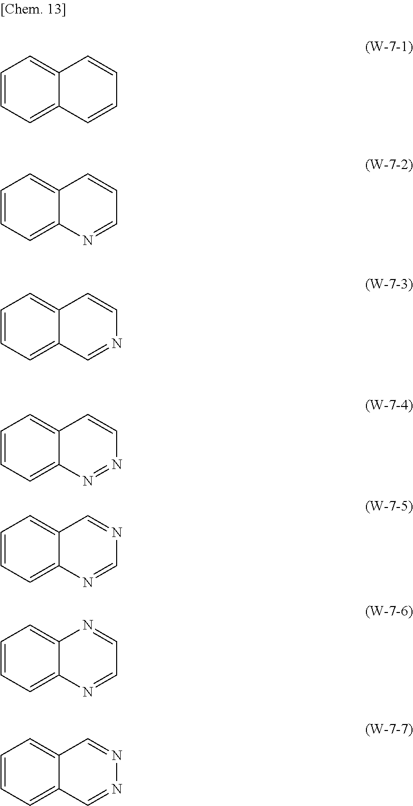

(In the formulae, these groups may have a binding site at an arbitrary position.)

It is preferable that the group represented by Formula (W-10) is a group selected from groups represented by Formulae (W-10-1) to (W-10-8) which may be unsubstituted or substituted with one or more of L¹'s.

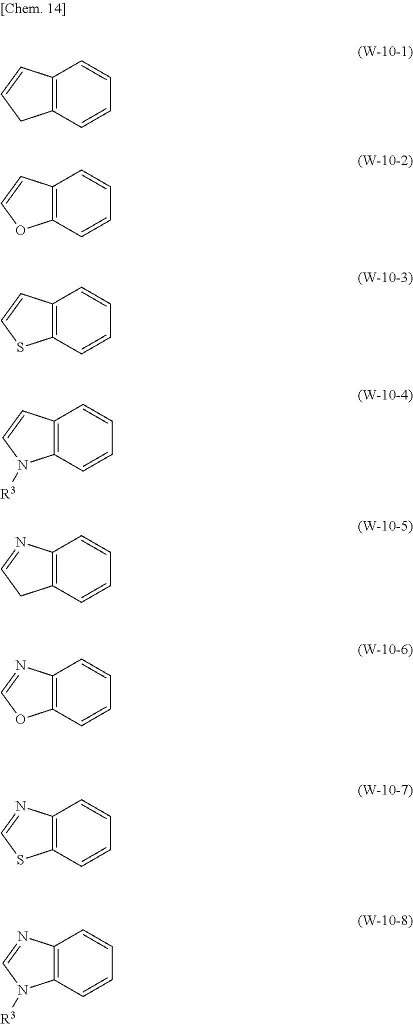

(In the formulae, these groups may have a binding site at an arbitrary position and R represents a hydrogen atom or an alkyl group having 1 to 8 carbon atoms.)

It is preferable that the group represented by Formula (W-11) is a group selected from groups represented by Formulae (W-11-1) to (W-11-13) which may be unsubstituted or substituted with one or more of L¹'s.

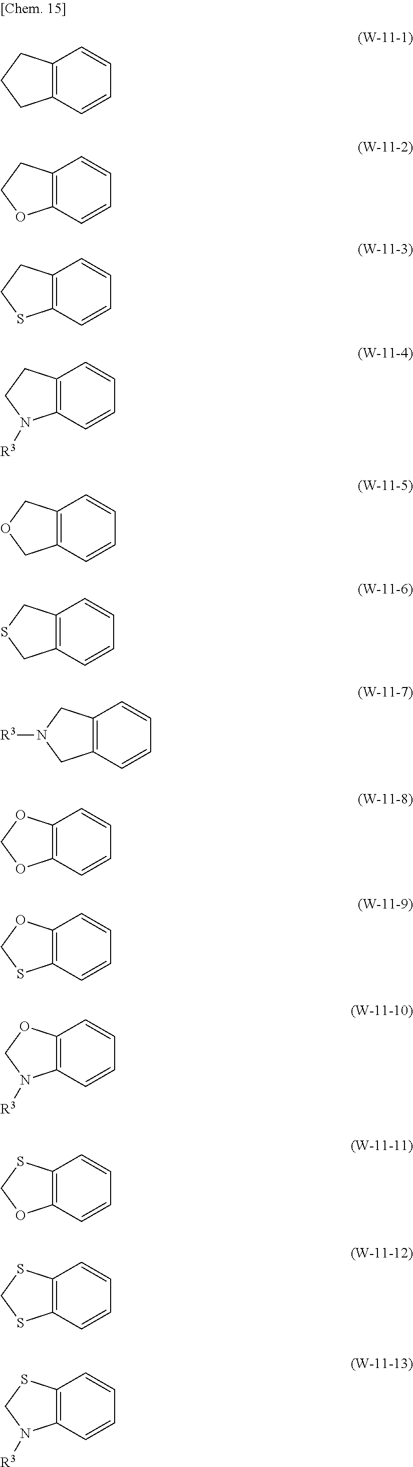

(In the formulae, these groups may have a binding site at an arbitrary position and R³ represents a hydrogen atom or an alkyl group having 1 to 8 carbon atoms.)

It is preferable that the group represented by Formula (W-12) is a group selected from groups represented by Formulae (W-12-1) to (W-12-19) which may be unsubstituted or substituted with one or more of L¹'s.

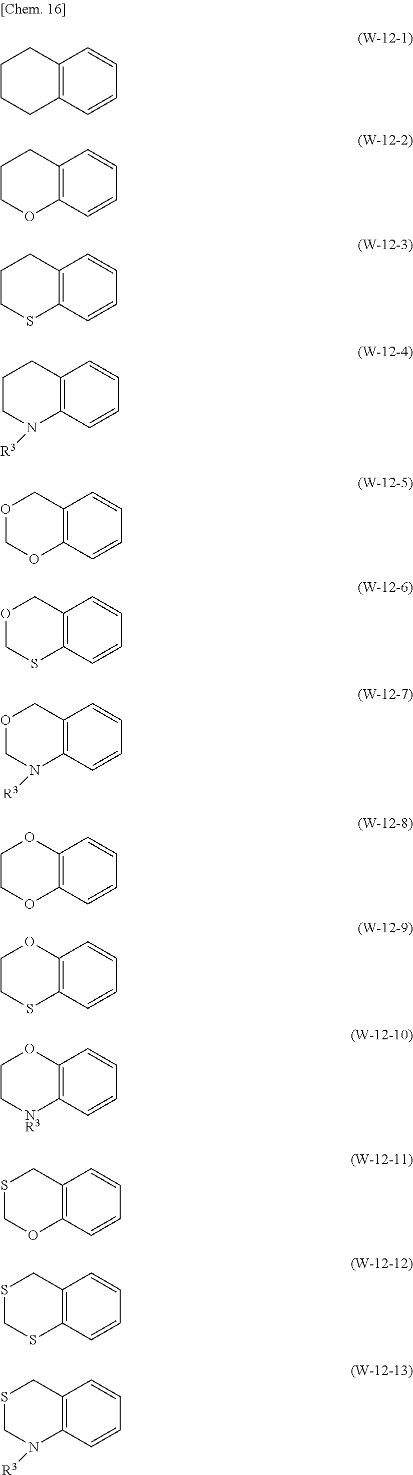

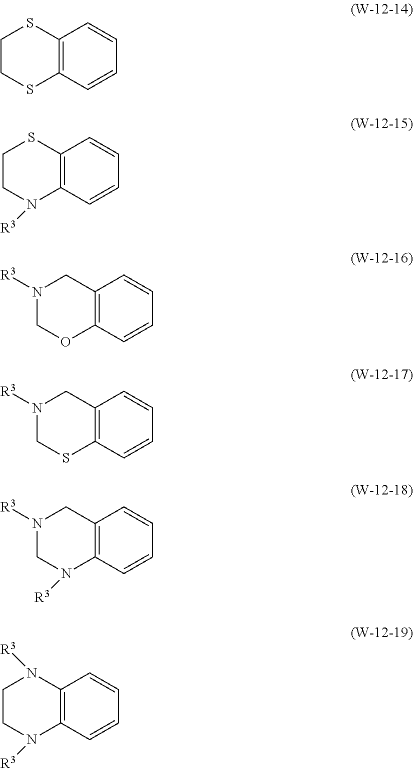

(In the formulae, these groups may have a binding site at an arbitrary position, R³ represents a hydrogen atom or an alkyl group having 1 to 8 carbon atoms.)

It is preferable that the group represented by Formula (W-13) is a group selected from groups represented by Formulae (W-13-1) to (W-13-10) which mar be unsubstituted or substituted with one or more of L¹'s.

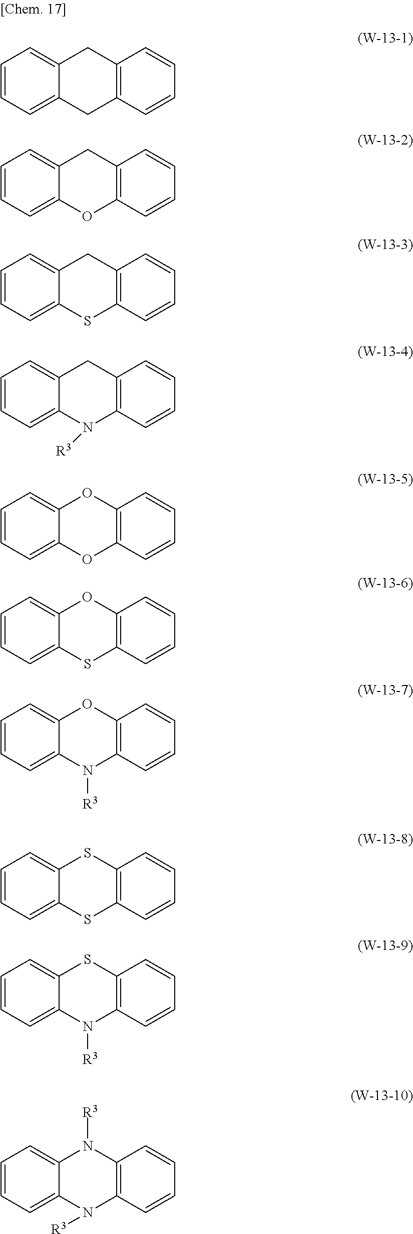

(In the formulae, these groups may have a binding site at an arbitrary position and R³ represents a hydrogen atom or an alkyl group having 1 to 8 carbon atoms.)

It is preferable that the group represented by Formula (W-14) is a group selected from groups represented by Formulae (W-14-1) to (W-14-4) which may be unsubstituted or substituted with one or more of L¹'s.

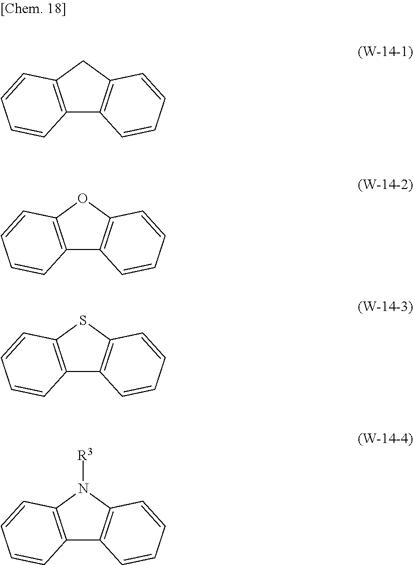

(In the formulae, these groups may have a binding site at an arbitrary position and R³ represents a hydrogen atom or an alkyl group having 1 to 8 carbon atoms.)

It is preferable that the group represented by Formula (W-15) is a group selected from groups represented by Formulae (W-15-1) to (W-15-18) which may be unsubstituted or substituted with one or more of L¹'s.

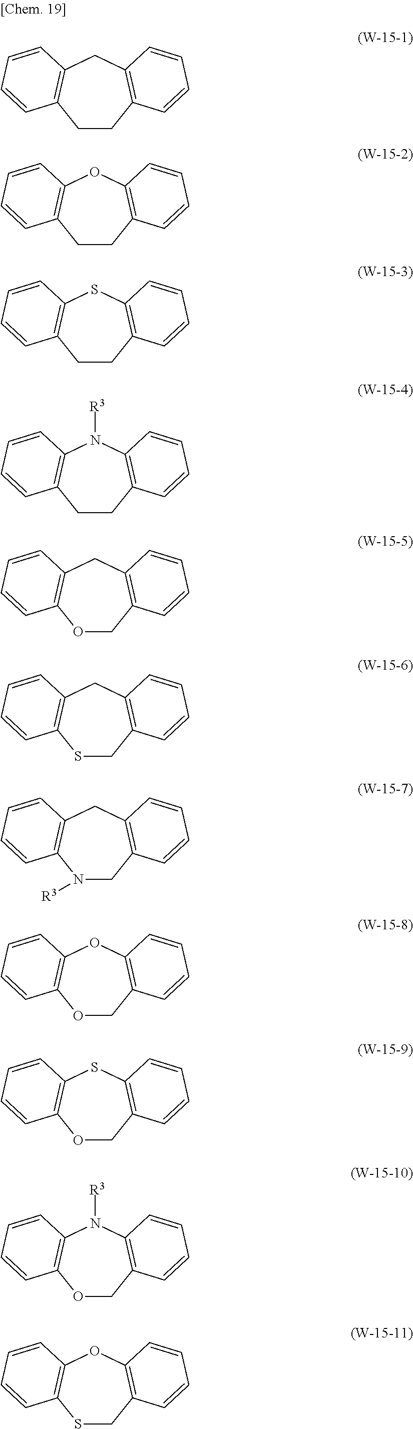

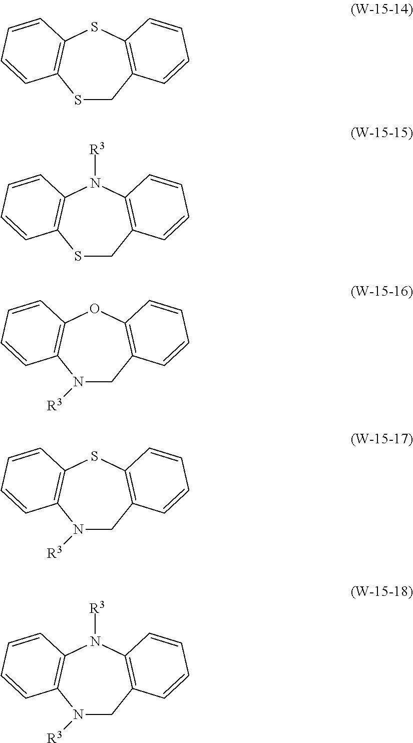

(In the formulae, these groups may have a binding site at an arbitrary position and R³ represents a hydrogen atom or an alkyl group having 1 to 8 carbon atoms.)

It is preferable that the group represented by Formula (W-16) is a group selected from groups represented by Formulae (W-16-1) to (W-16-4) which may be unsubstituted or substituted with one or more of L¹'s.

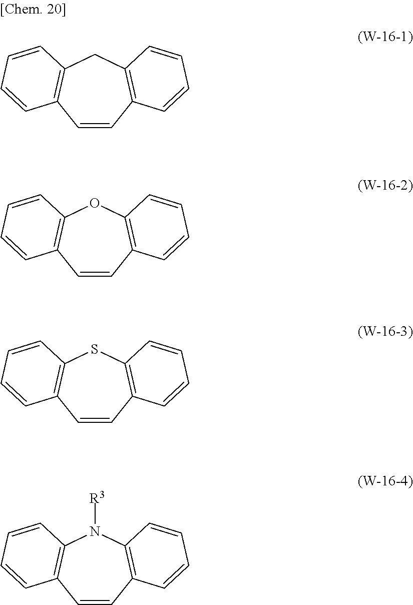

(In the formulae, these groups may have a binding site at an arbitrary position and R³ represents a hydrogen atom or an alkyl group having 1 to 8 carbon atoms.)

It is preferable that the group represented by Formula (W-17) is a group selected from groups represented by Formulae (W-17-1) to (W-17-6) which may be unsubstituted or substituted with one or more of L¹'s.

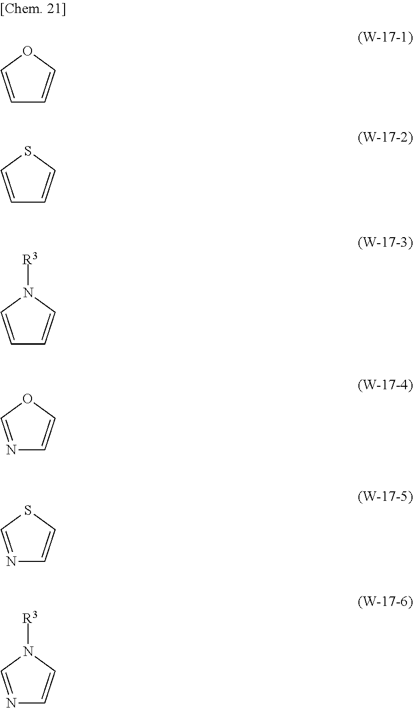

(In the formulae, these groups may have a binding site at an arbitrary position and R³ represents a hydrogen atom or an alkyl group having 1 to 8 carbon atoms.)

It is preferable that the group represented by Formula (W-18) is a group selected from groups represented by Formulae (W-18-1) to (W-18-6) which may be unsubstituted or substituted with one or more of L¹'s.

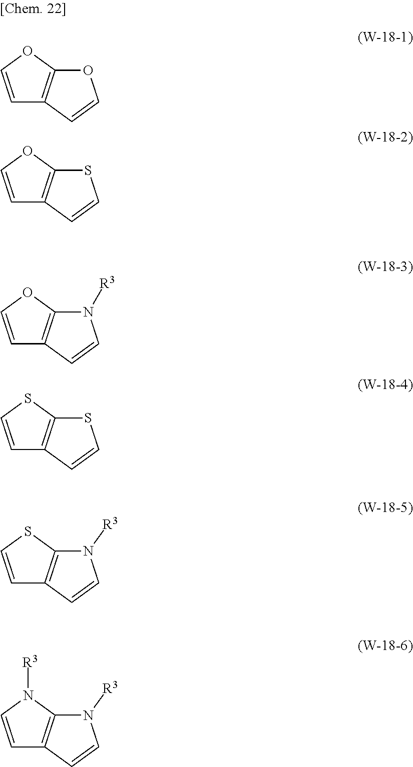

(In the formulae, these groups may have a binding site at an arbitrary position and R³ represents a hydrogen atom or an alkyl group having 1 to 8 carbon atoms.)

It is preferable that the group represented by Formula (W-19) is a group selected from groups represented by Formulae (W-19-1) to (W-19-9) which may be unsubstituted or substituted with one or more of L¹'s.

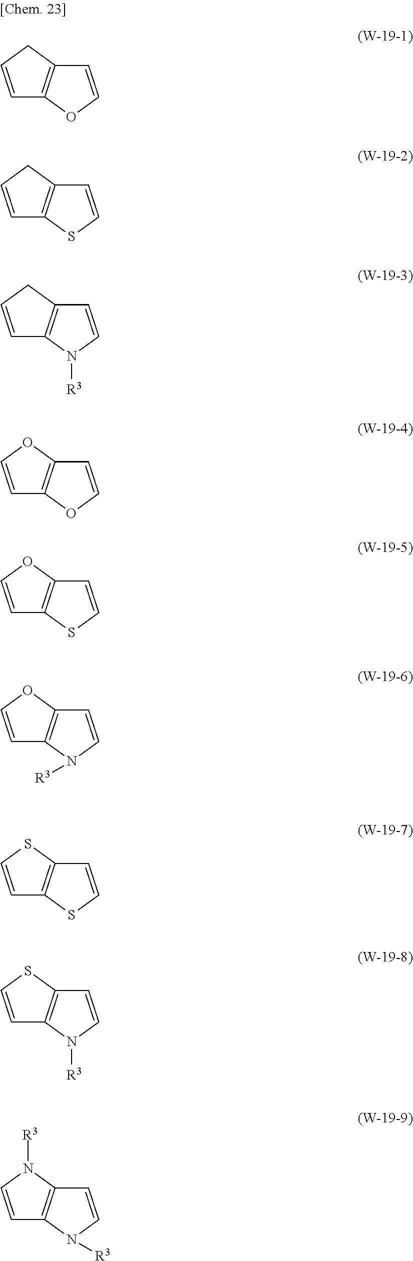

(In the formulae, these groups may have a binding site at an arbitrary position and R³ represents a hydrogen atom or an alkyl group having 1 to 8 carbon atoms.)

It is more preferable that the aromatic group included in the group represented by W¹ is a group selected from groups represented by Formulae (W-1-1), (W-7-1), (W-7-2), (W-7-7), (W-8), (W-10-6), (W-10-7), (W-10-8), (W-11-8), (W-11-9), (W-11-10), (W-11-11), (W-11-12), and (W-11-13) which may be unsubstituted or substituted with one or more of L¹'s and particularly preferable that the aromatic group included in the group represented by W¹ is a group selected from groups represented by Formulae (W-1-1), (W-7-1), (W-7-2), (W-7-7), (W-10-6), (W-10-7), and (W-10-8) which may be unsubstituted or substituted with one or more of L¹'s. Further, it is particularly preferable that W¹ represents a group selected from groups represented by Formulae (W-a-1) to (W-a-6).

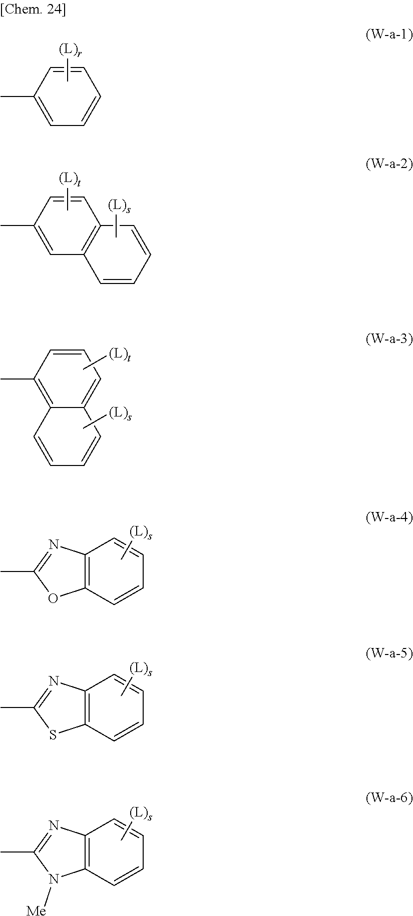

(In the formulae, r represents an integer of 0 to 5, s represents an integer of 0 to 4, and t represents an integer of 0 to 3.)

W¹² represents a hydrogen atom or a linear or branched alkyl group having 1 to 20 carbon atoms in which one —CH₂— or two or more (—CH₂—)'s which are not adjacent to each other may be each independently substituted with —O—, —S—, —CO—, —COO—, —OCO—, —CO—S—, —S—CO—, —O—CO—O—, —CO—NH—, —NH—CO—, —CH═CH—COO—, —CH═CH—OCO—, —COO—CH═CH—, —OCO—CH═CH—, —CH═CH—, —CF═CF—, or —C≡C—, one or more of arbitrary hydrogen atoms in the alkyl group may be substituted with a fluorine atom, W¹² may have the same definition as that for W¹¹, W¹¹ and W¹² may be linked to each other to form a ring structure, or W¹² represents a group represented by the following formula.

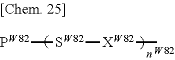

(In the formula, P^{W82} has the same definition as that for R¹¹, S^{W82} has the same definition as that for S¹¹, X^{W82} has the same definition as that for X¹¹, and n^{W82} has the same definition as that for k).

From the viewpoints of easily obtaining raw materials and ease of synthesis, it is preferable that W¹² represents a hydrogen atom or a linear or branched alkyl group having 1 to 20 carbon atoms in which one or more of arbitrary hydrogen atoms may be substituted with a fluorine atom and one —CH₂— or two or more (—CH₂—)'s which are not adjacent to each other may be each independently substituted with —O—, —CO—, —COO—, —OCO—, —CH═CH—COO—, —OCO—CH═CH—, —CH═CH—, —CF═CF—, or —C≡C—, more preferable that W¹² represents a hydrogen atom or a linear or branched alkyl group having 1 to 20 carbon atoms in which one —CH₂— or two or more (—CH₂—)'s which are not adjacent to each other may be each independently substituted with —O—, and particularly preferable that W¹² represents a hydrogen atom or a linear or branched alkyl group having 1 to 12 carbon atoms in which one —CH₂— or two or more (—CH₂—)'s which are not adjacent to each other may be each independently substituted with —O—. Further, in a case where W¹² has the same definition as that for W¹¹, W¹² and W¹¹ may be the same as or different from each other and preferable groups as W¹² are the same as those for W¹¹. Further, in a case where W¹¹ and W¹² are linked to each other to form a ring structure, it is preferable that the cyclic group represented by —NW¹¹W¹² is a group selected from groups represented by Formulae (W-b-1) to (W-b-42) which may be unsubstituted or substituted with one or more of L¹'s.

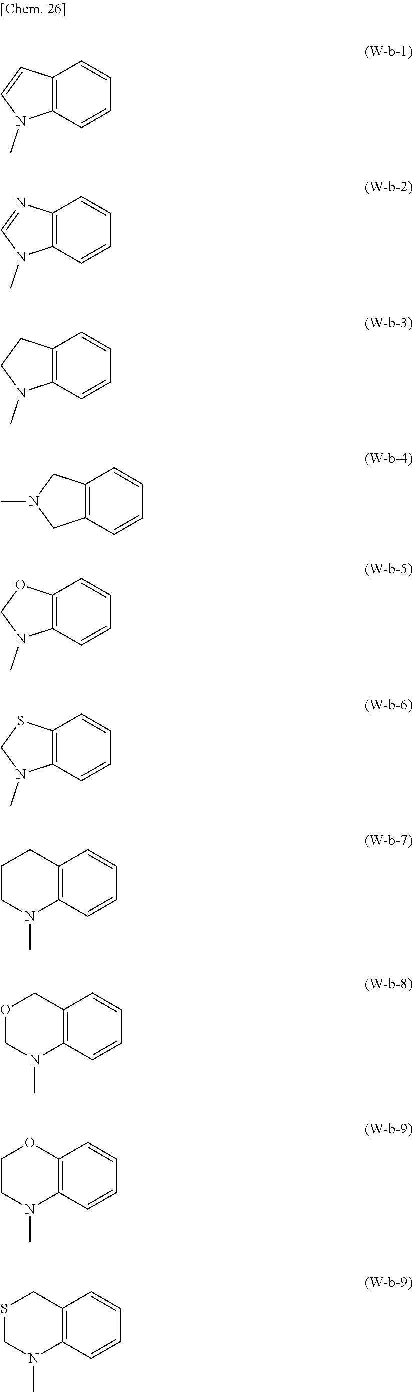

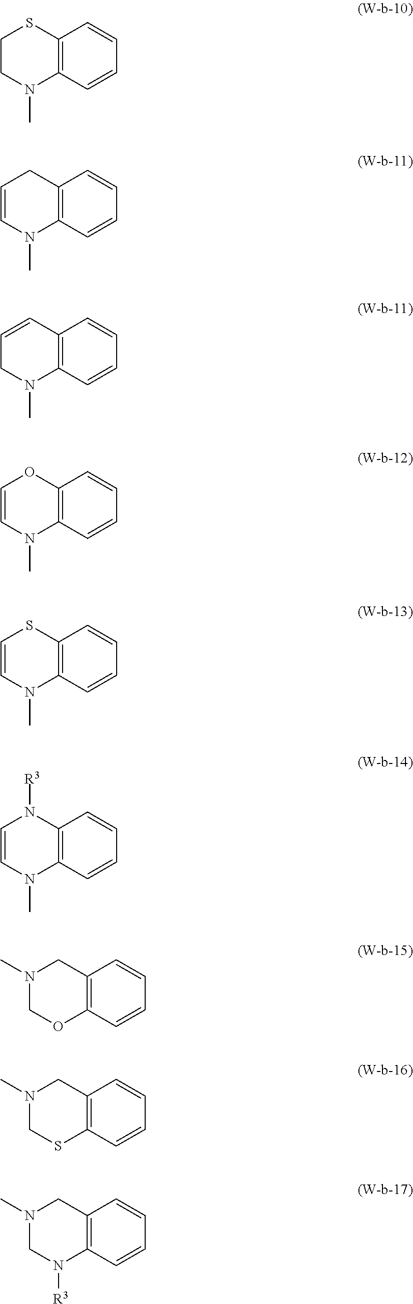

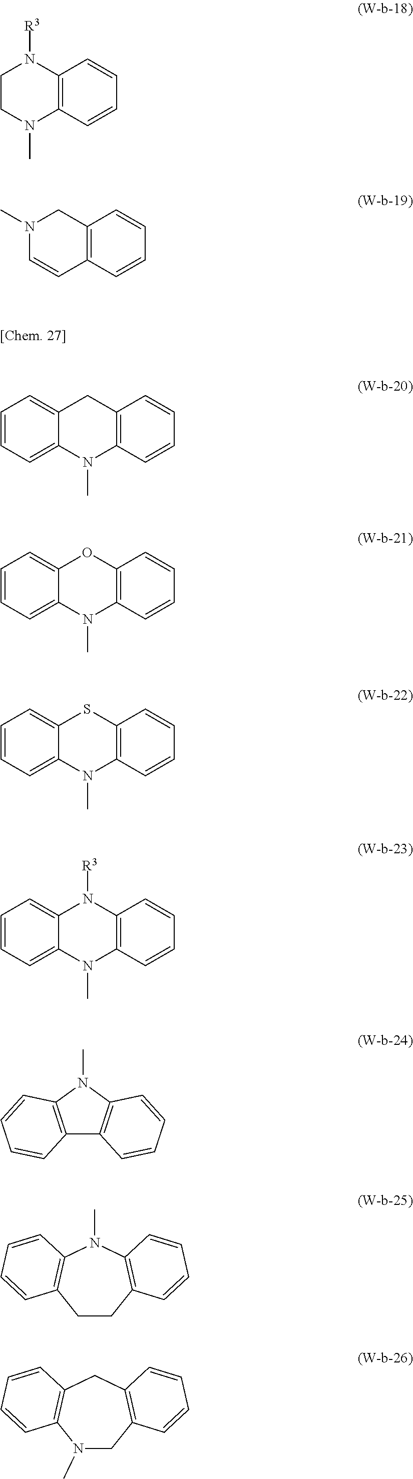

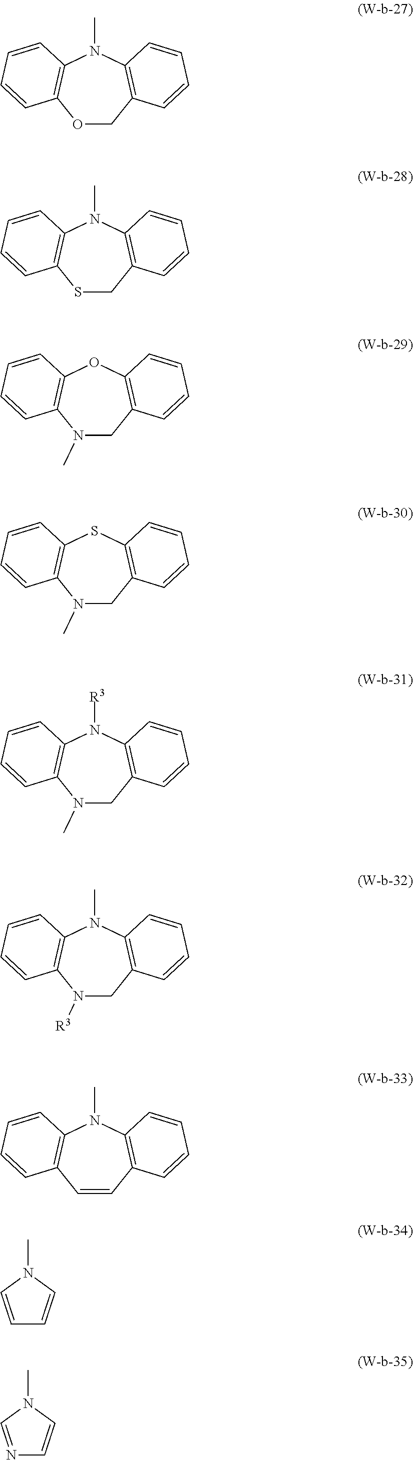

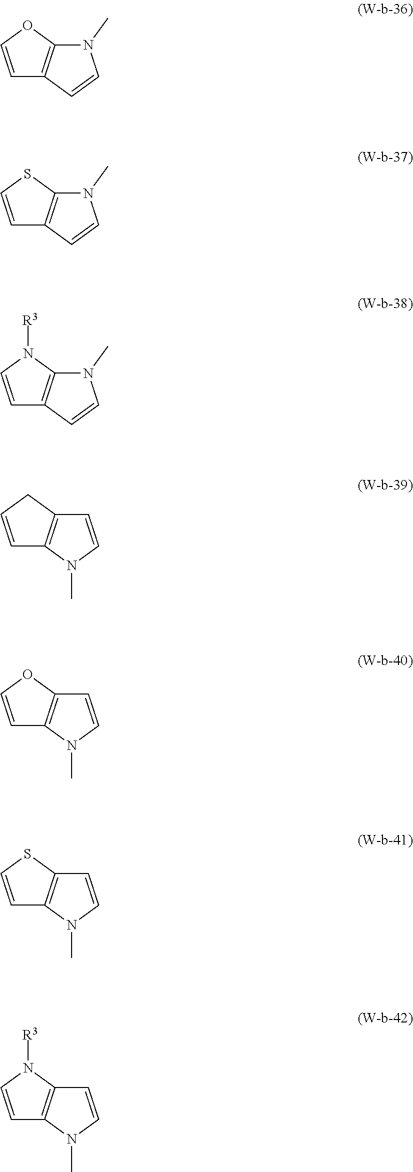

(In the formulae, R³ represents a hydrogen atom or an alkyl group having 1 to 8 carbon atoms.)

From the viewpoints of easily obtaining raw materials and ease of synthesis, it is particularly preferable that the cyclic group represented by —NW¹¹W¹² is a group selected from groups represented by Formulae (W-b-20), (W-b-21), (W-b-22), (W-b-23), (W-b-24), (W-b-25), and (W-b-33) which may be unsubstituted or substituted with one or more of L¹'s.

Further, it is preferable that the cyclic group represented by ═CW¹¹W¹² is a group selected from groups represented by Formulae (W-c-1) to (W-c-81) which may be unsubstituted or substituted with one or more of L¹'s.

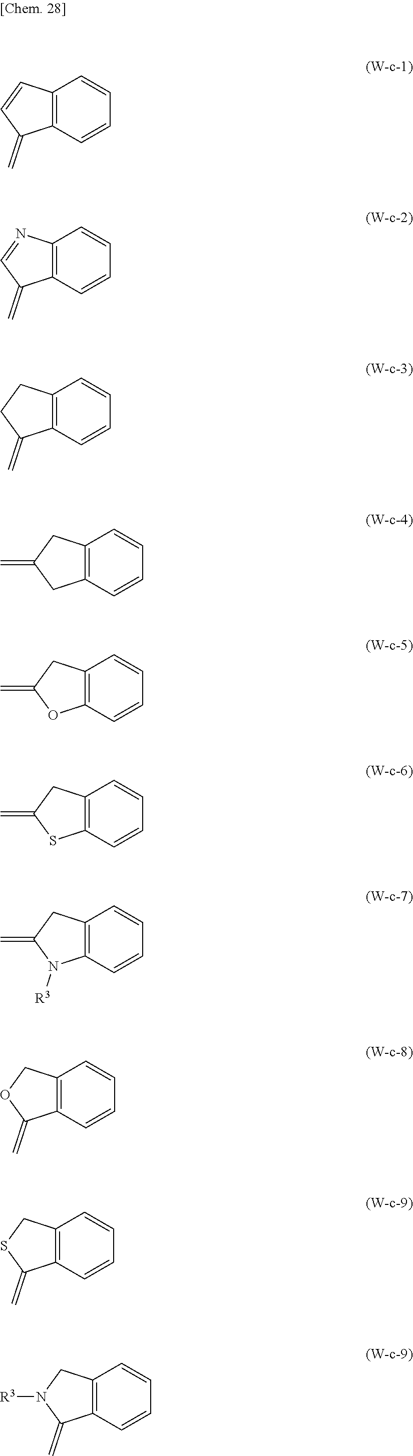

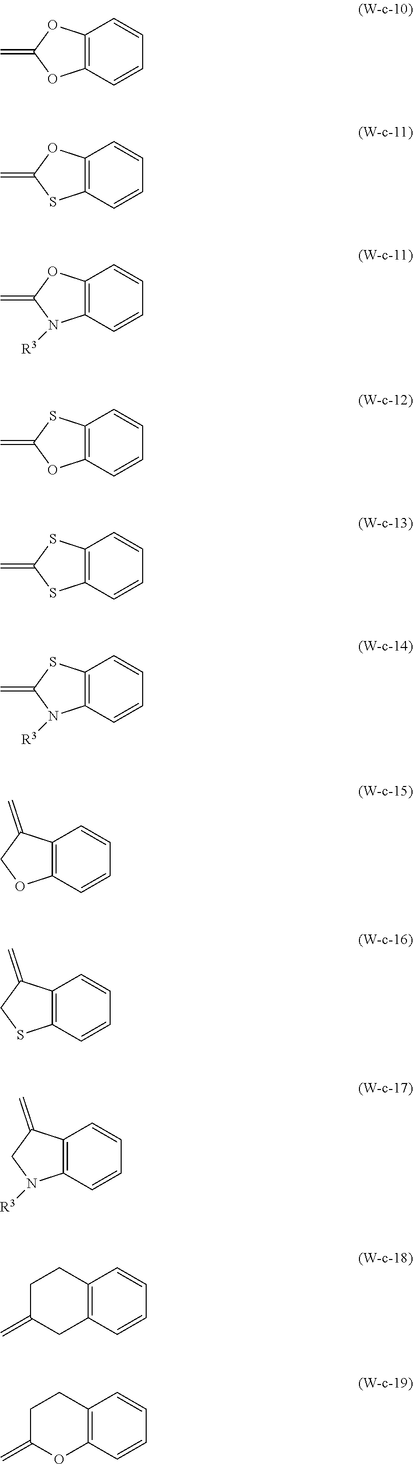

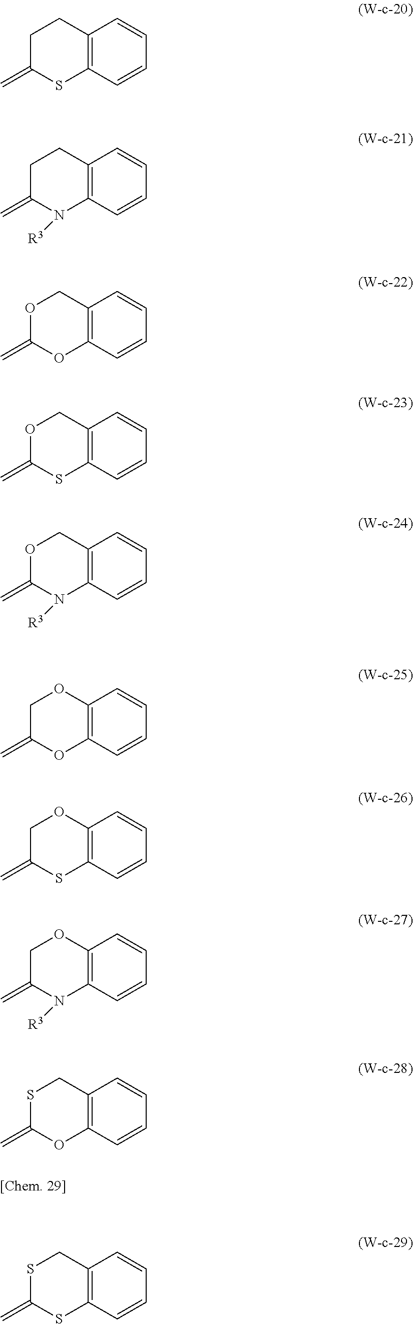

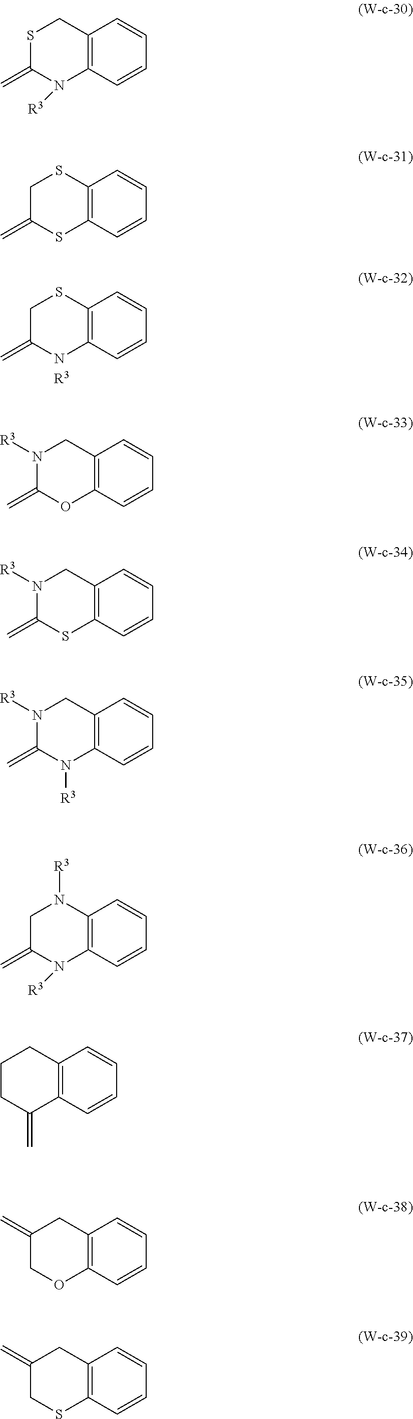

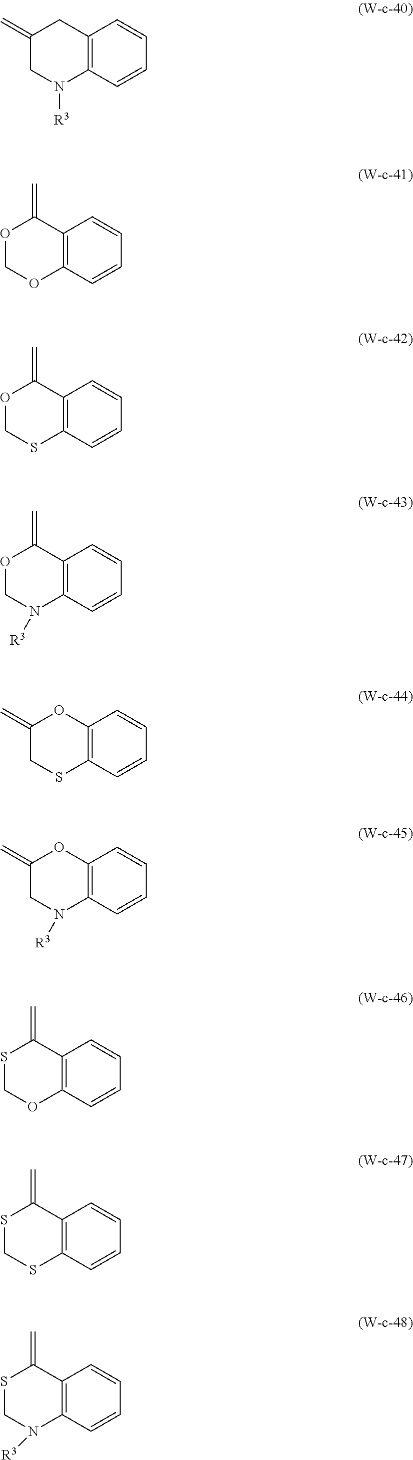

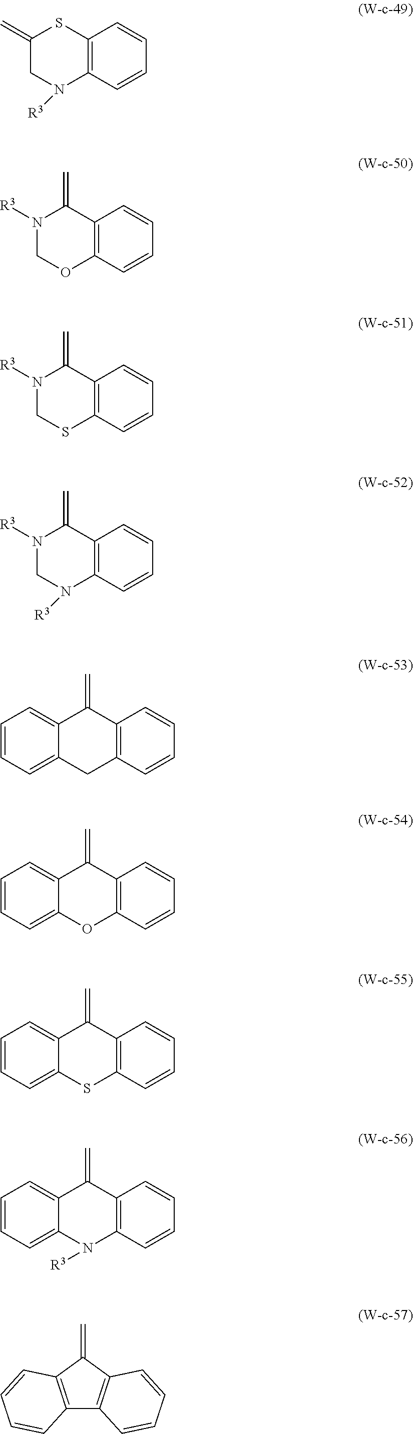

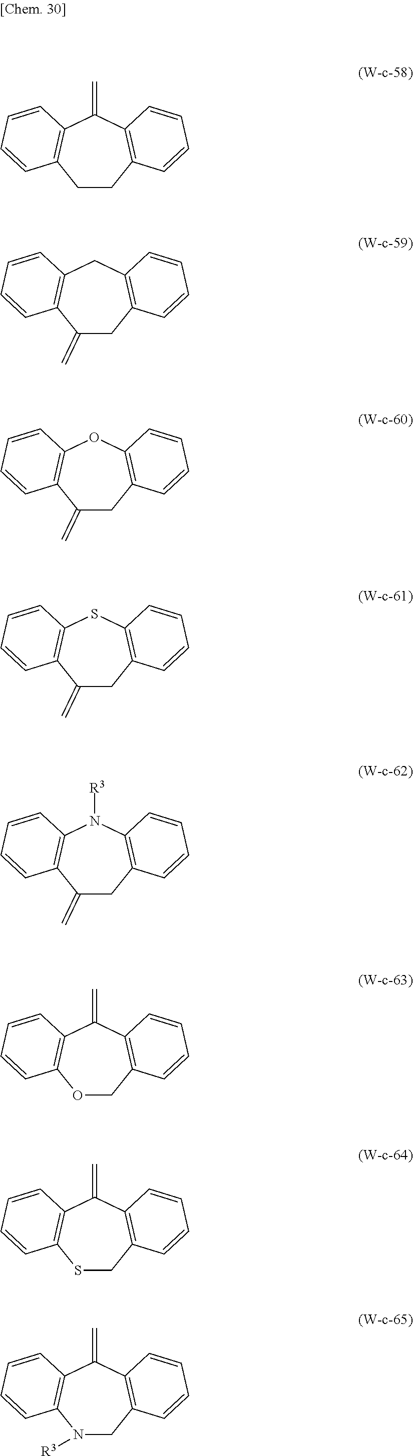

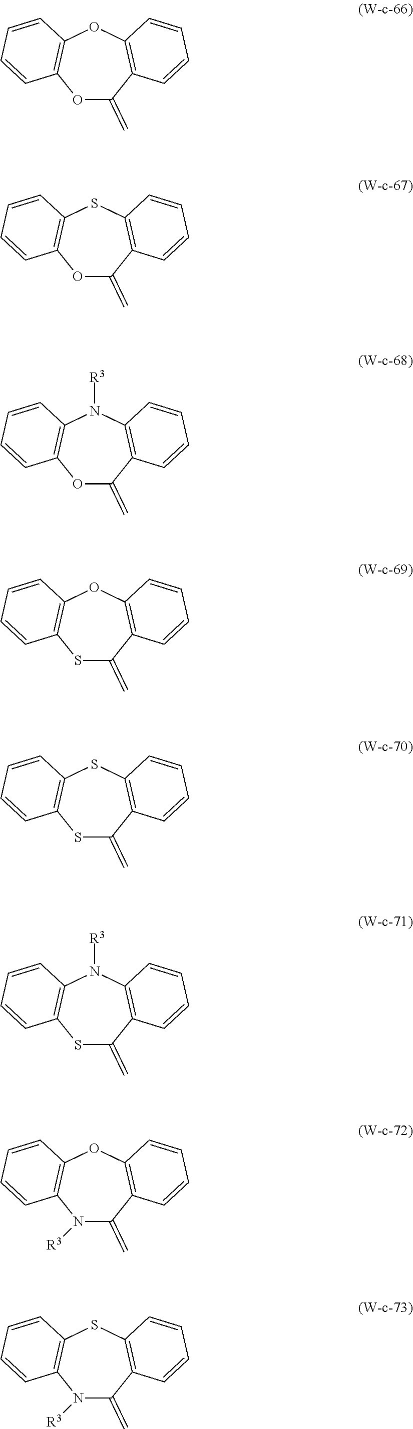

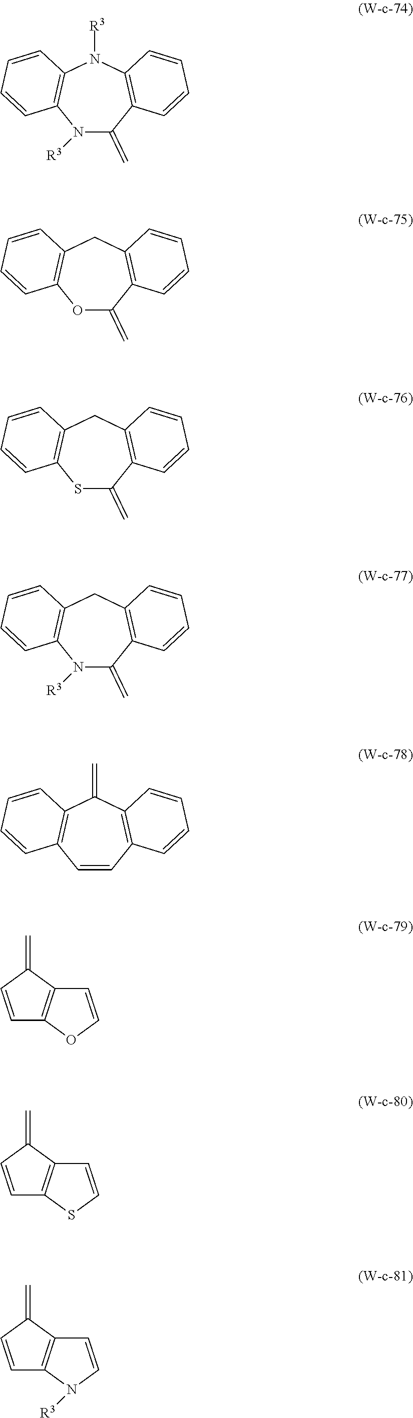

(In the formulae, R³ represents a hydrogen atom or an alkyl group having 1 to 8 carbon atoms.)

From the viewpoints of easily obtaining raw materials and ease of synthesis, it is particularly preferable that the cyclic group represented by ═CW¹¹W¹² is a group selected from groups represented by Formulae (W-c-11), (W-c-12), (W-c-13), (W-c-14), (W-c-53), (W-c-54), (W-c-55), (W-c-56), (W-c-57), and (W-c-78) which may be unsubstituted or substituted with one or more of L¹'s.

In a case where W¹² represents a group represented by the following formula, preferable groups as P^{W82} are the same as those for P¹¹.

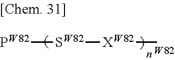

Further, preferable groups as S^{W82} are the same as those for S¹¹, preferable groups as X^{W82} are the same as those for X¹¹, and preferable groups as n^{W82} are the same as those for k.

The total number of π electrons included in the group represented by W¹¹ and W¹² is preferably 4 to 24 from the viewpoints of wavelength dispersion characteristics, storage stability, liquid crystallinity, and ease of synthesis.

L¹ represents a fluorine atom, a chlorine atom, a bromine atom, an iodine atom, a pentafluorosulfuranyl group, a nitro group, an isocyano group, an amino group, a hydroxyl group, a mercapto group, a methylamino group, a dimethylamino group, a diethylamino group, a diisopropylamino group, a trimethylsilyl group, a dimethylsilyl group, a thioisocyano group, or a linear or branched alkyl group having 1 to 20 carbon atoms in which one —CH₂— or two or more (—CH₂—)'s which are not adjacent to each other may be each independently substituted with —O—, —S—, —CO—, —COO—, —OCO—, —CO—S—, —S—CO—, —O—CO—O—, —CO—NH—, —NH—CO—, —CH═CO—, —CH═CH—COO—, —CH═CH—OCO—, —COO—CH═CH—, —OCO—CH═CH—, —CH═CH—, —CF═CF—, or —C≡C—, and one or more of arbitrary hydrogen atoms in the alkyl group may be substituted with a fluorine atom. From the viewpoints of liquid crystallinity and ease of synthesis, it is preferable that L represents a fluorine atom, a chlorine atom, a pentafluorosulfuranyl group, a nitro group, a methylamino group, a dimethylamino group, a diethylamino group, a diisopropylamino group, or a linear or branched alkyl group having 1 to 20 carbon atoms in which one or more of arbitrary hydrogen atoms may be substituted with a fluorine atom and one —CH₂— or two or more (—CH₂—)'s which are not adjacent to each other may be each independently substituted with a group selected from —O—, —S—, —CO—, —COO—, —OCO—, —O—CO—O—, —CH═CH—, —CF═CF—, and —C≡C—, more preferable that that L¹ represents a fluorine atom, a chlorine atom, or a linear or branched alkyl group having 1 to 12 carbon atoms in which one or more of arbitrary hydrogen atoms may be substituted with a fluorine atom and one —CH₂— or two or more (—CH₂—)'s which are not adjacent to each other may be each independently substituted with a group selected from —O—, —COO—, and —CO—, still more preferable that L¹ represents a fluorine atom, a chlorine atom, or a linear or branched alkyl group or alkoxy group having 1 to 12 carbon atoms in which one or more of arbitrary hydrogen atoms may be substituted with a fluorine atom, and particularly preferable that L¹ represents a fluorine atom, a chlorine atom, or a linear or branched alkyl group or a linear alkoxy group having 1 to 8 carbon atoms.

Further, in a case where a plurality of L¹ is present in the compound, these may be the same as or different from each other.

Preferred specific examples of the polymerizable liquid crystalline compound represented by General Formula (1) include compounds represented by Formulae (1-1) to (1-130)

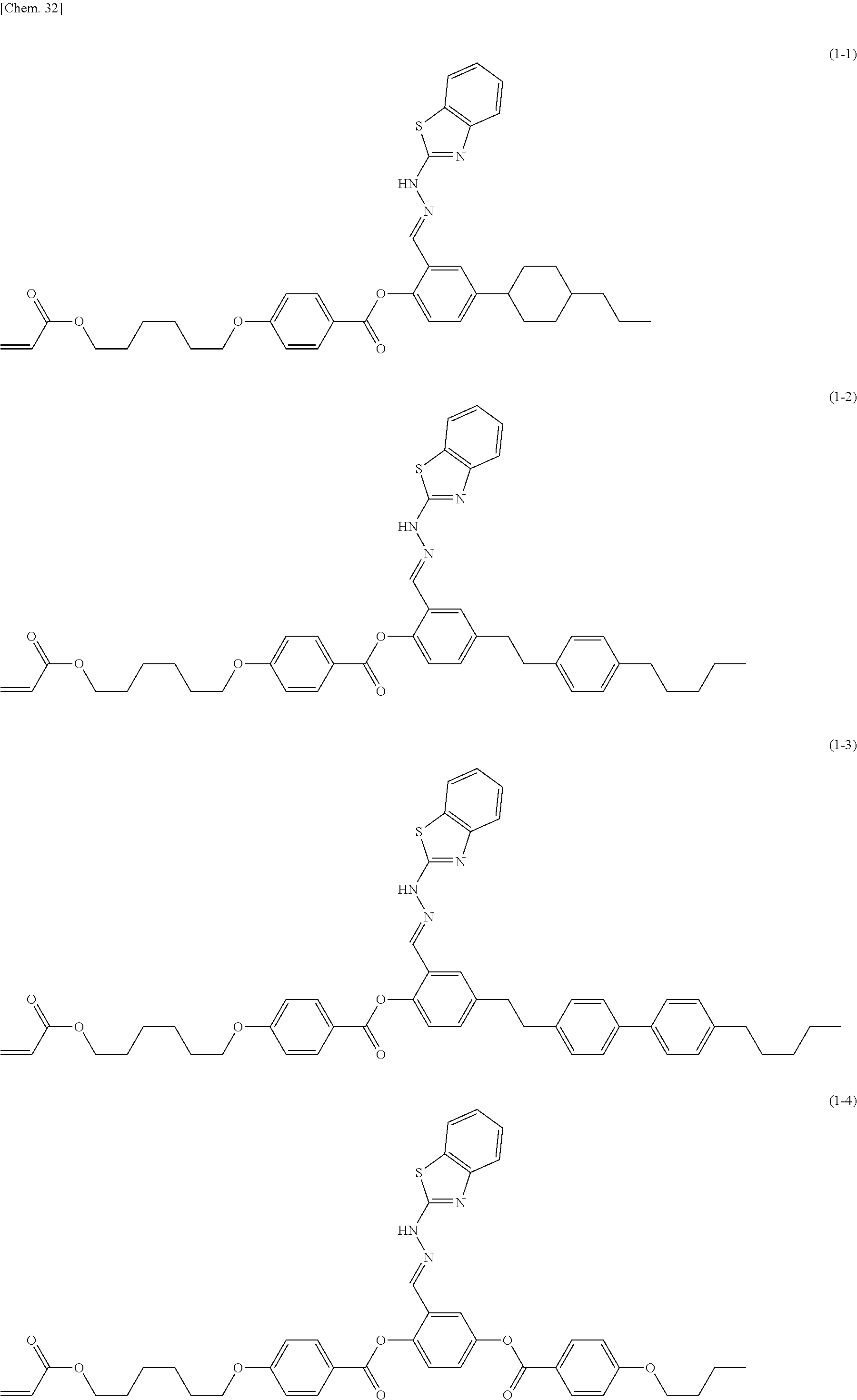

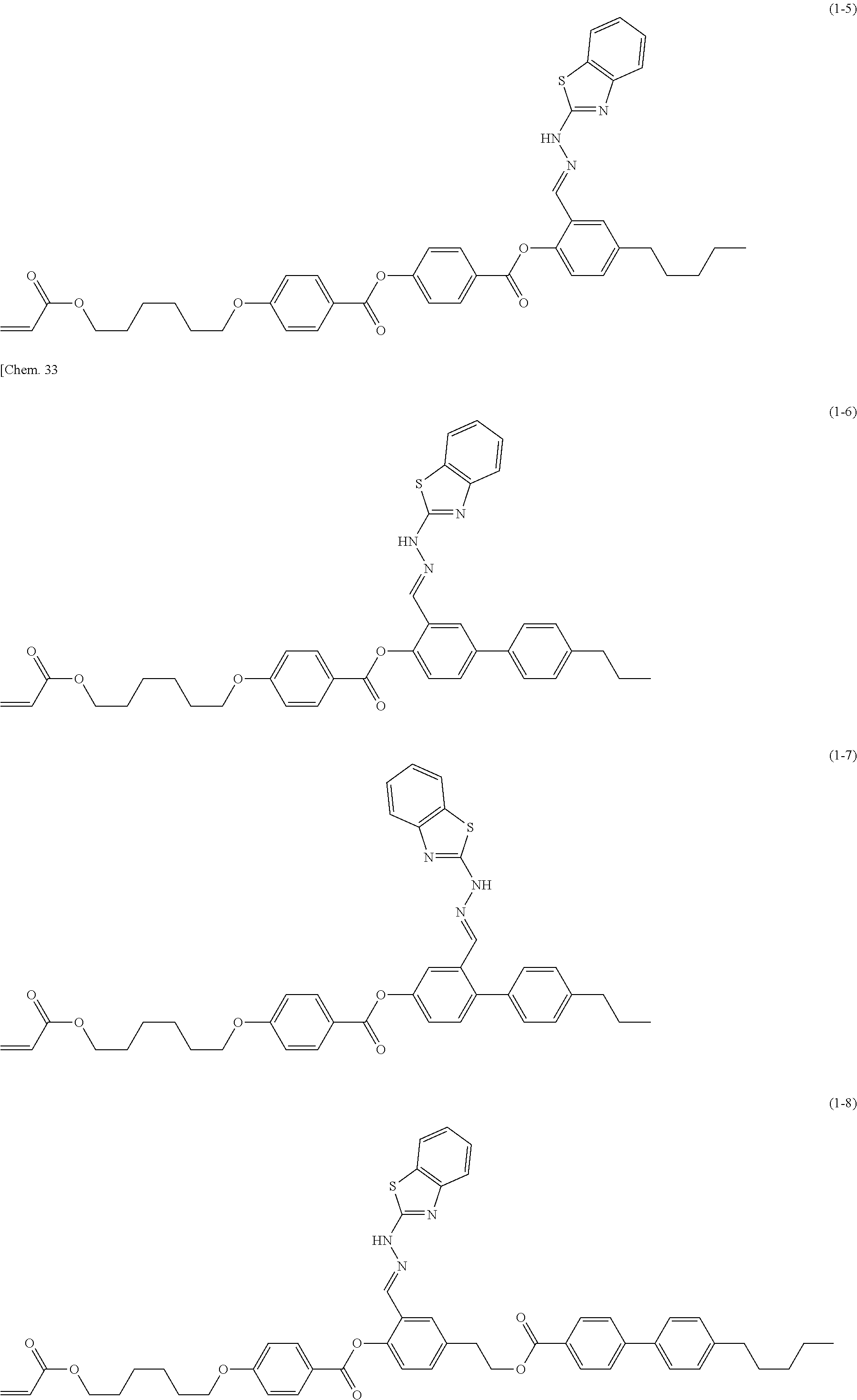

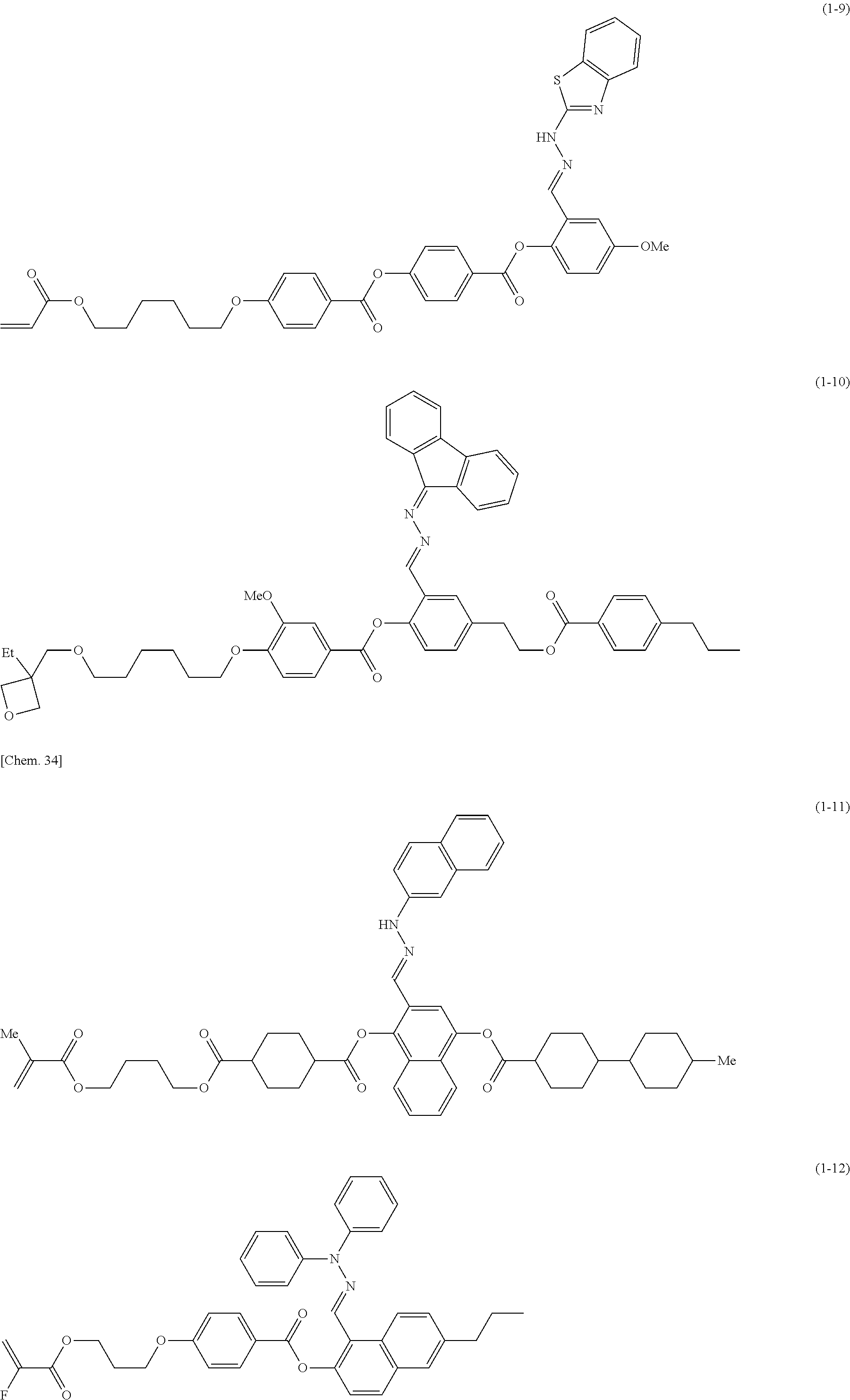

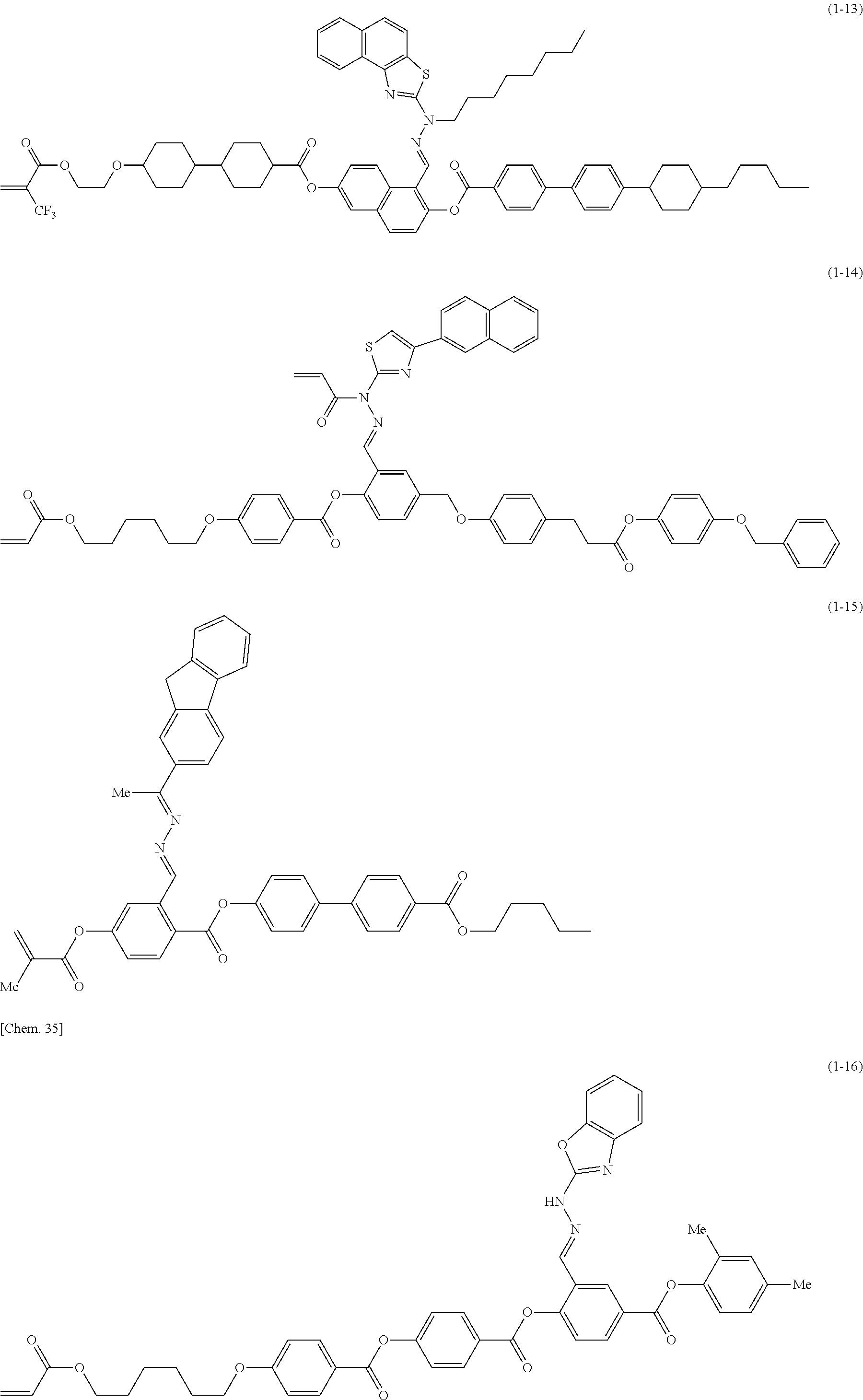

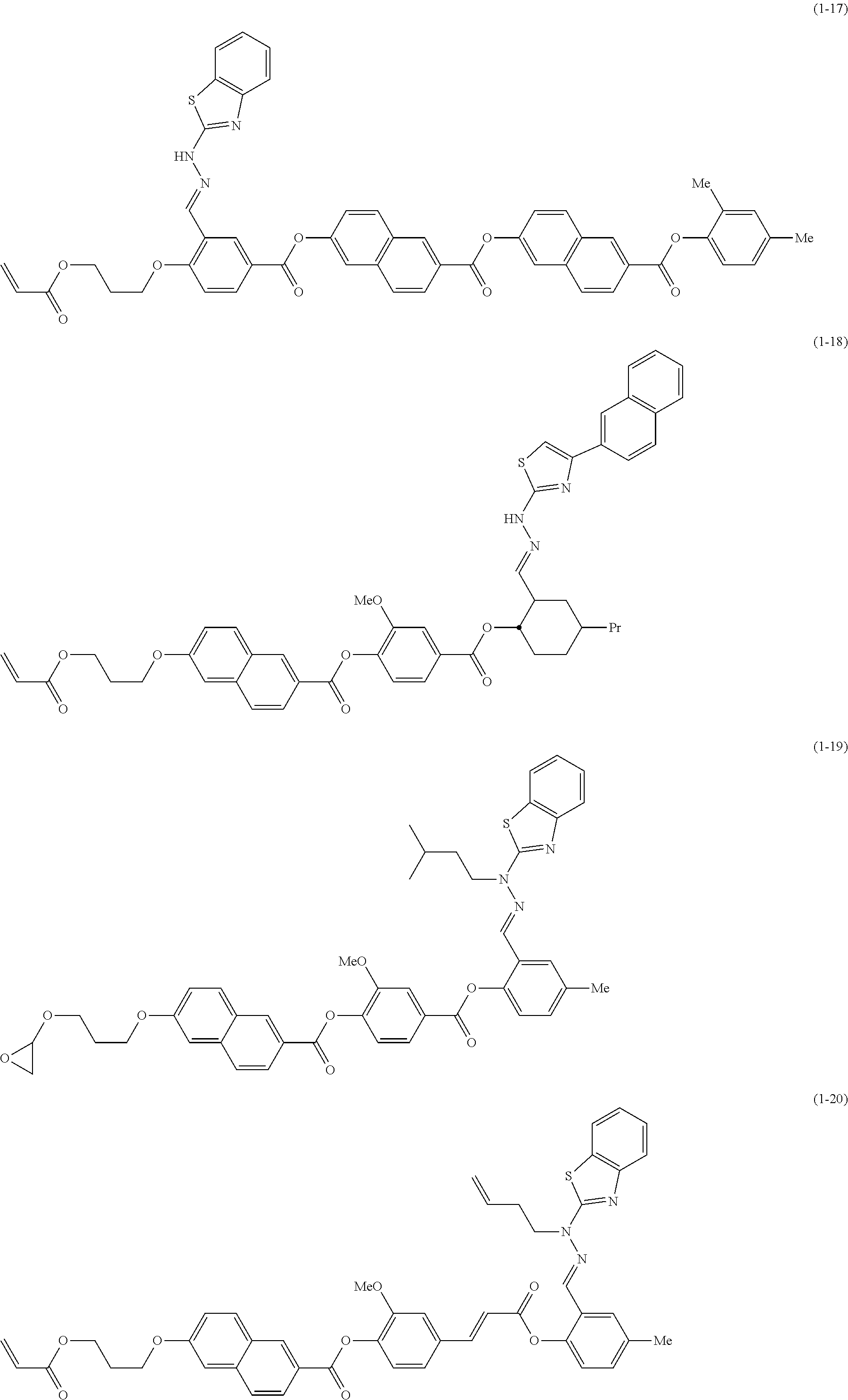

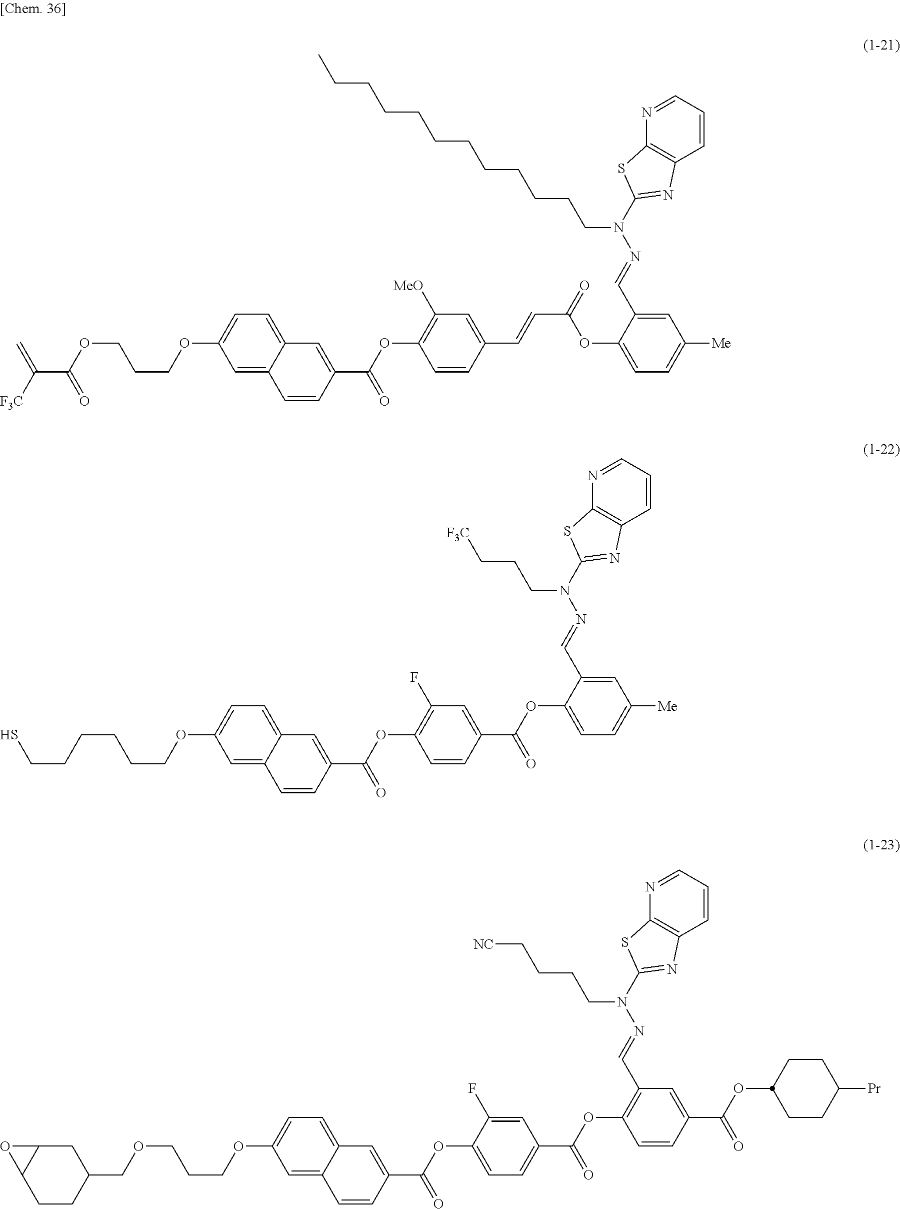

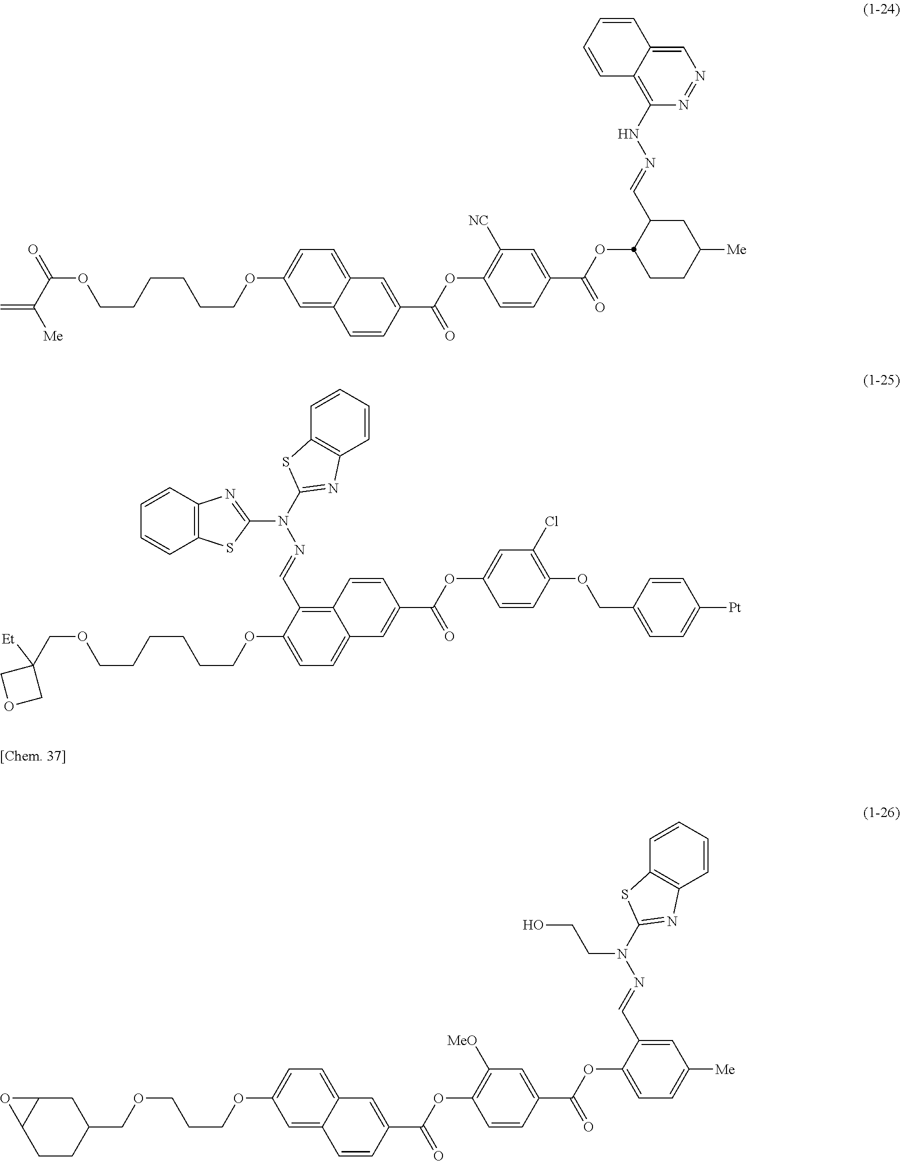

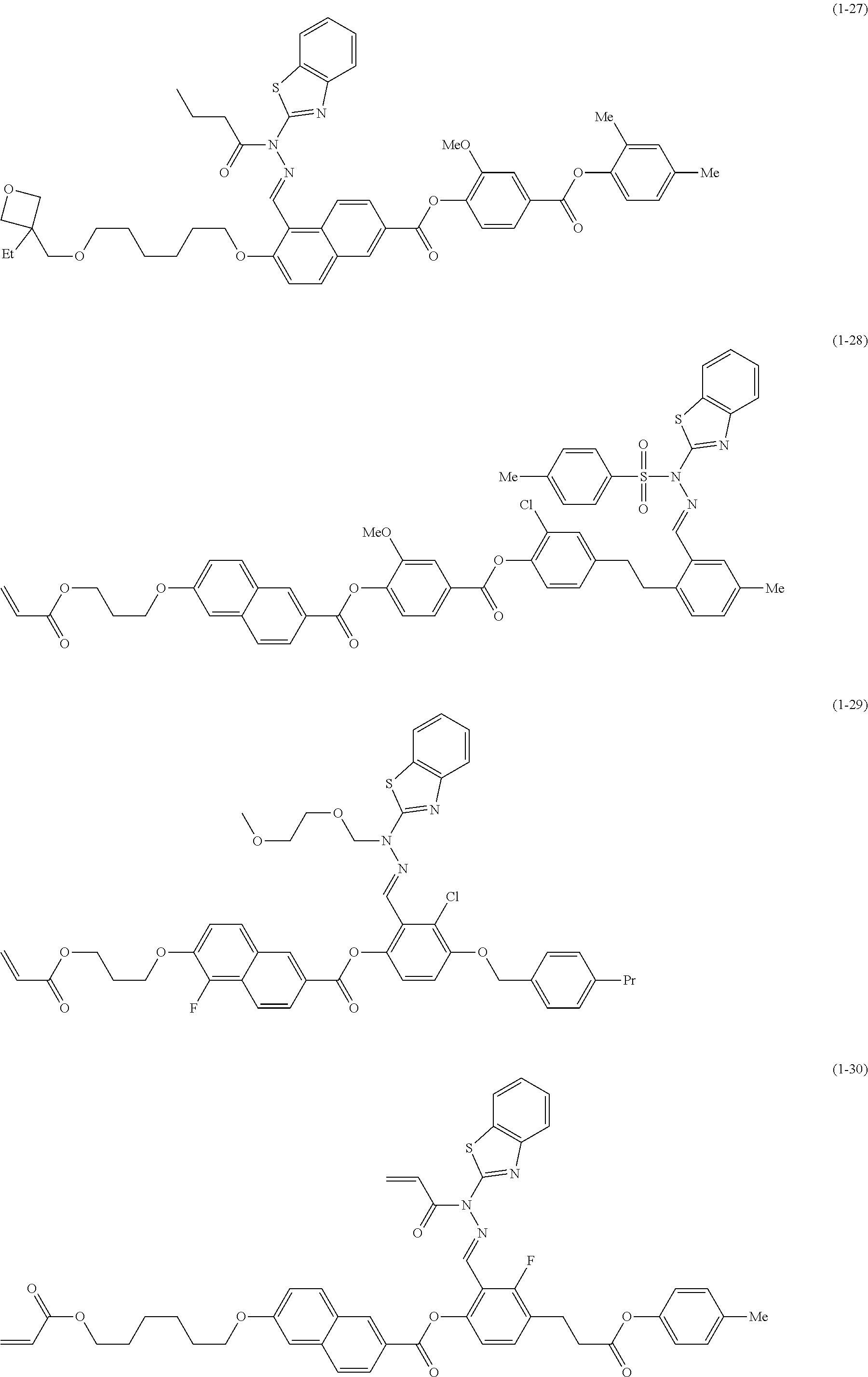

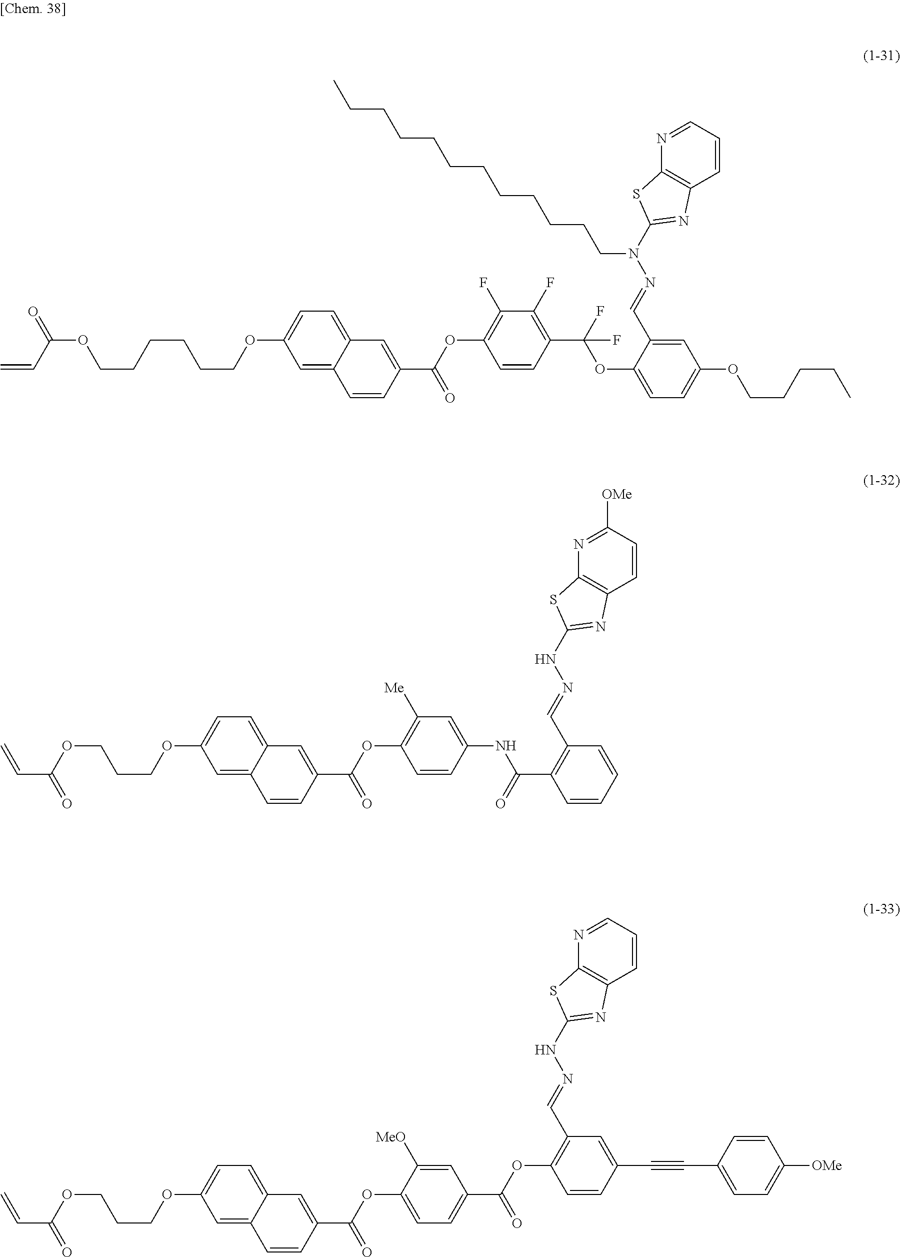

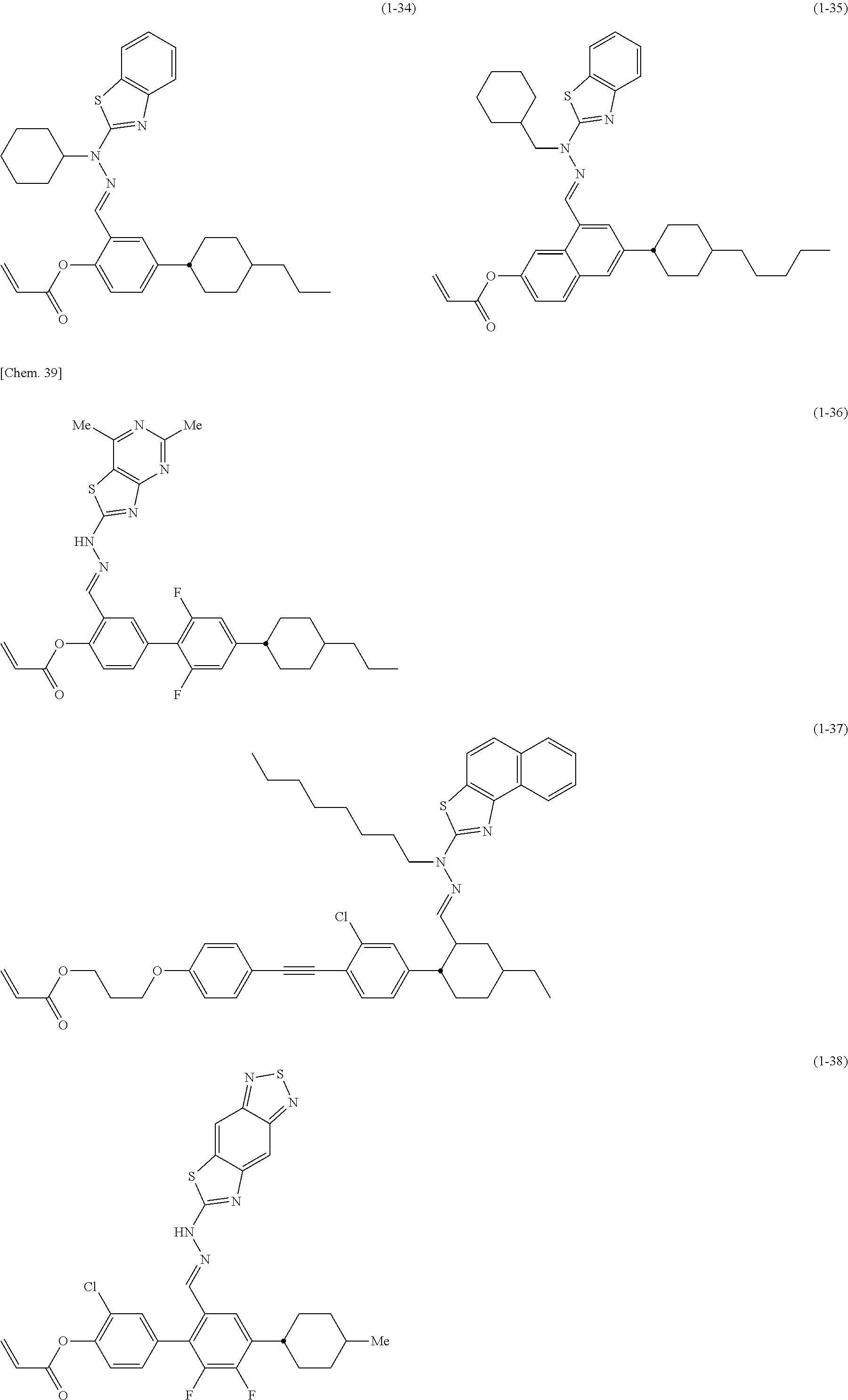

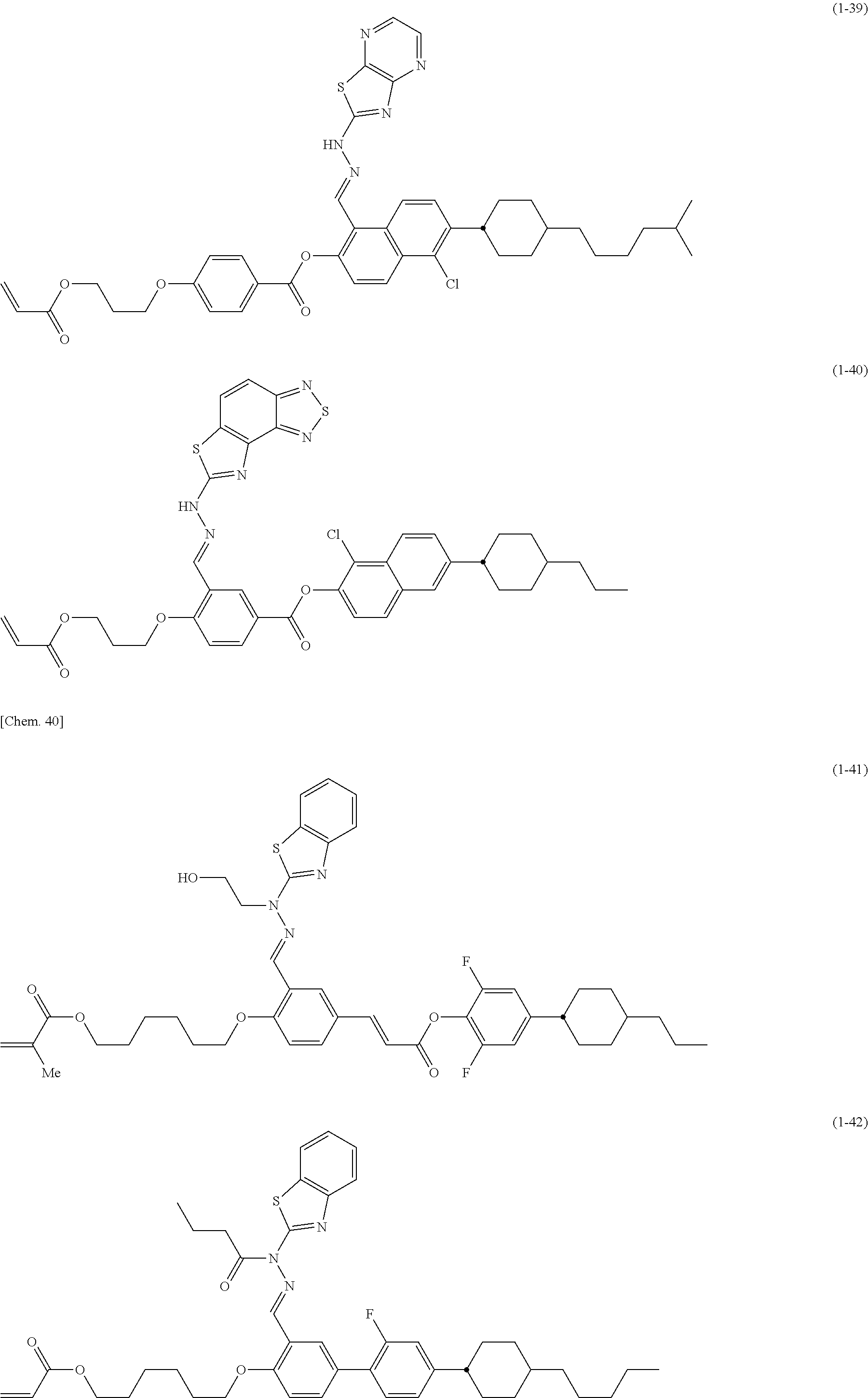

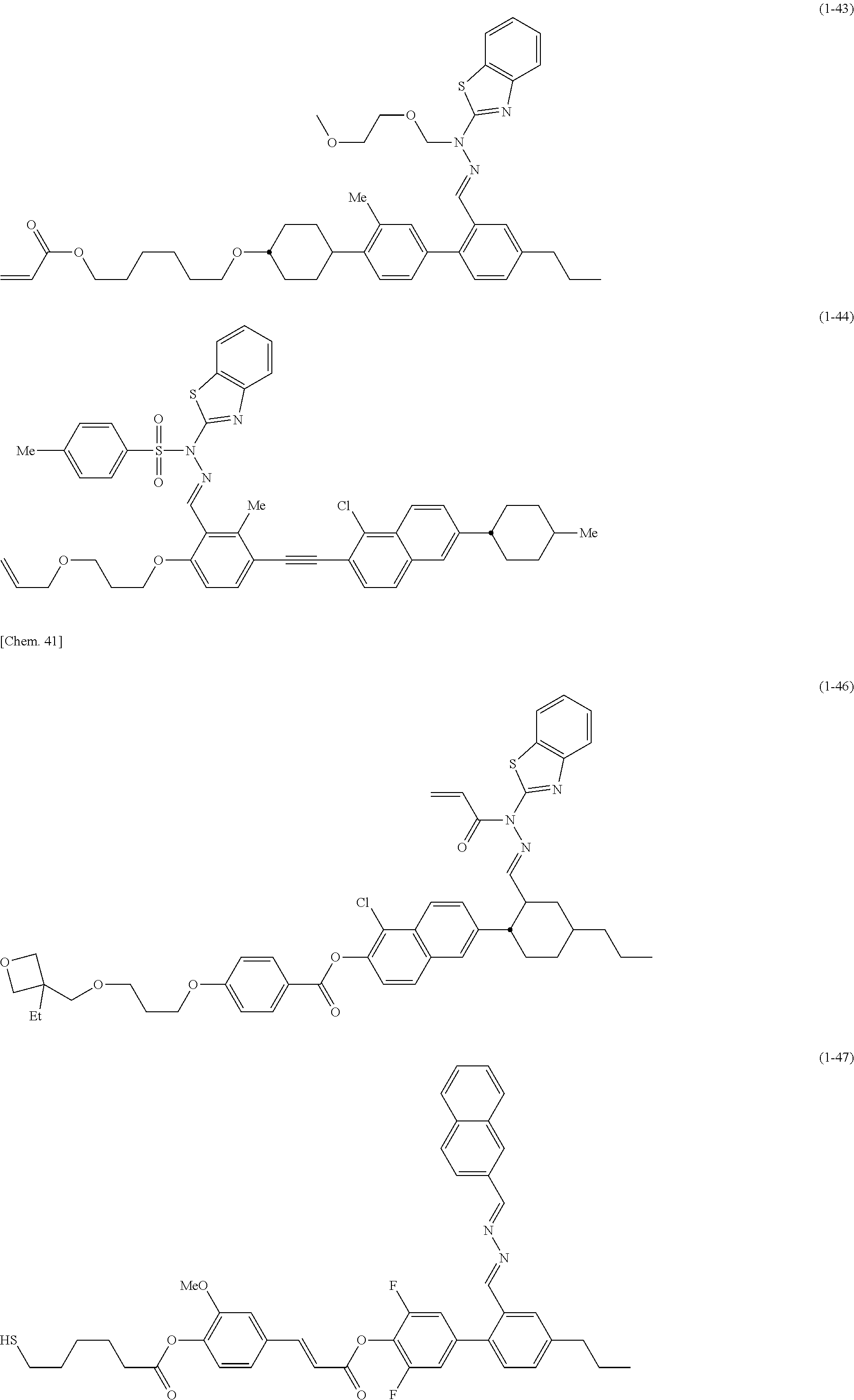

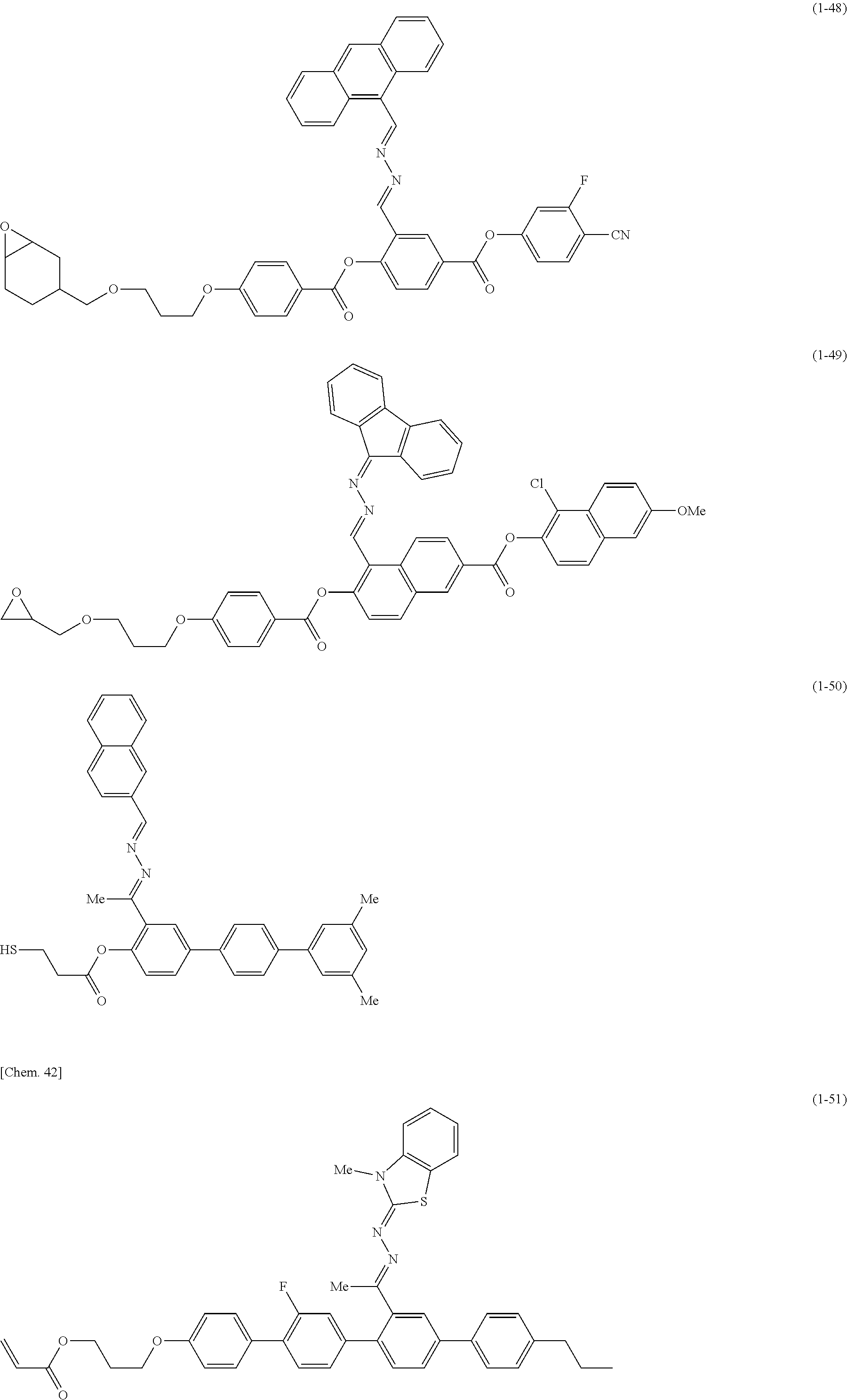

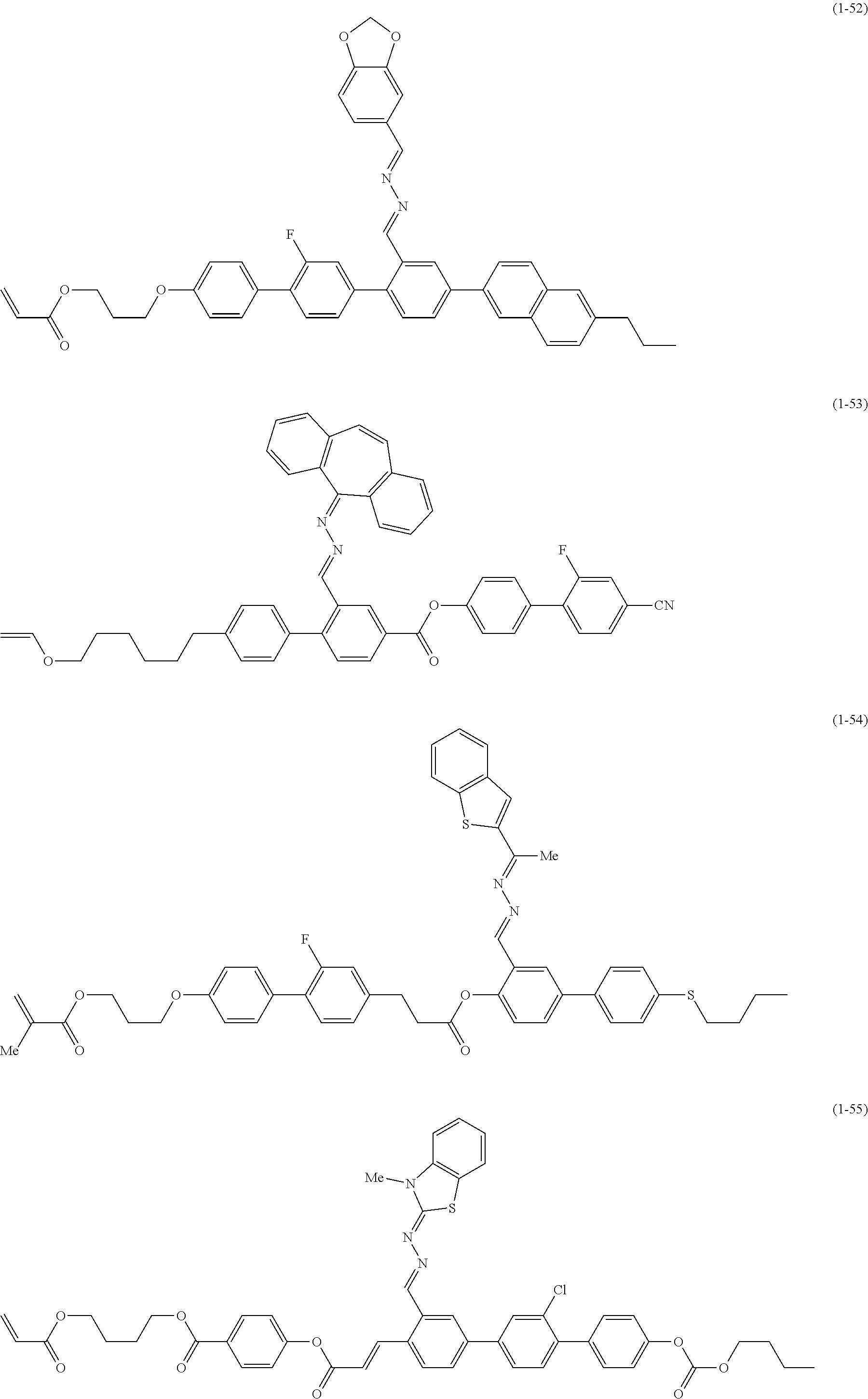

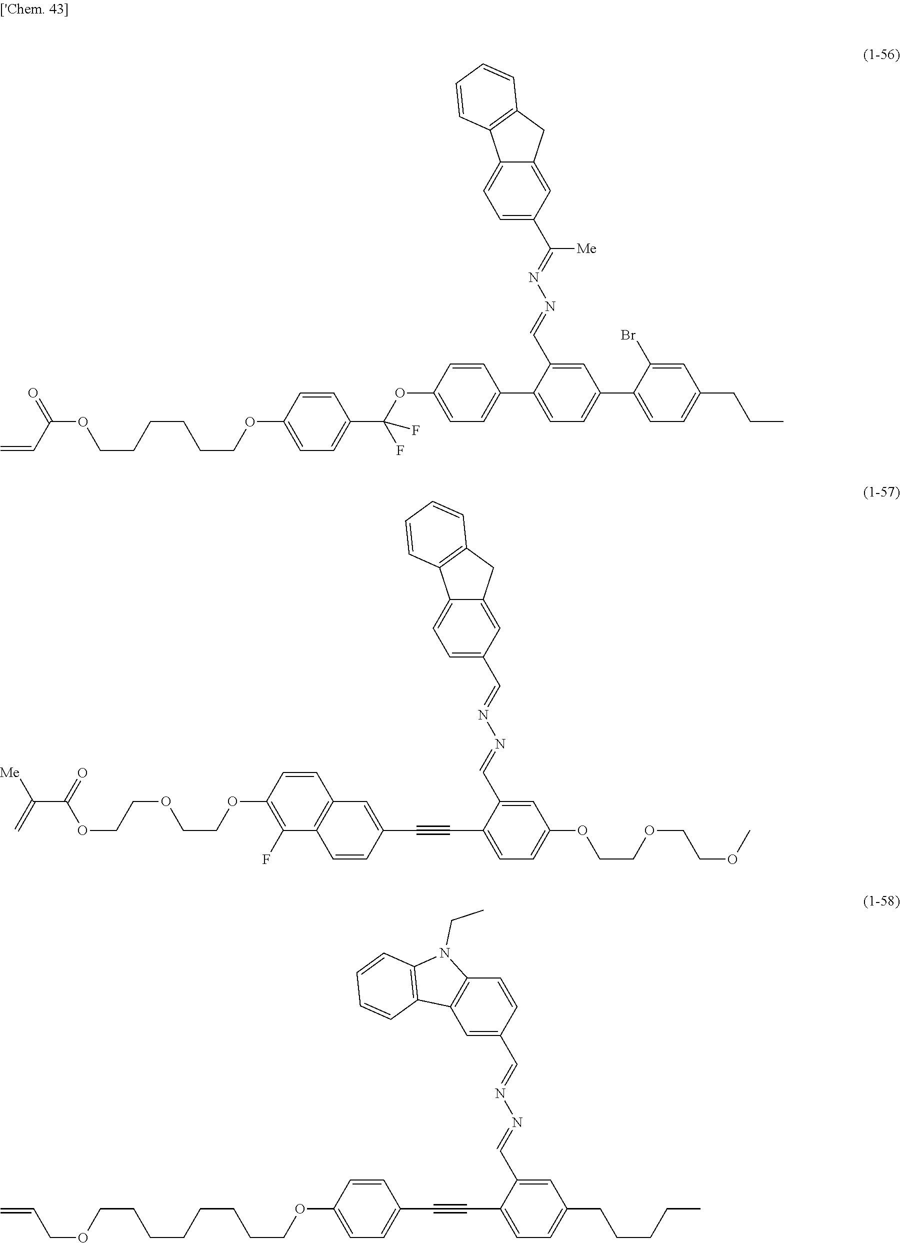

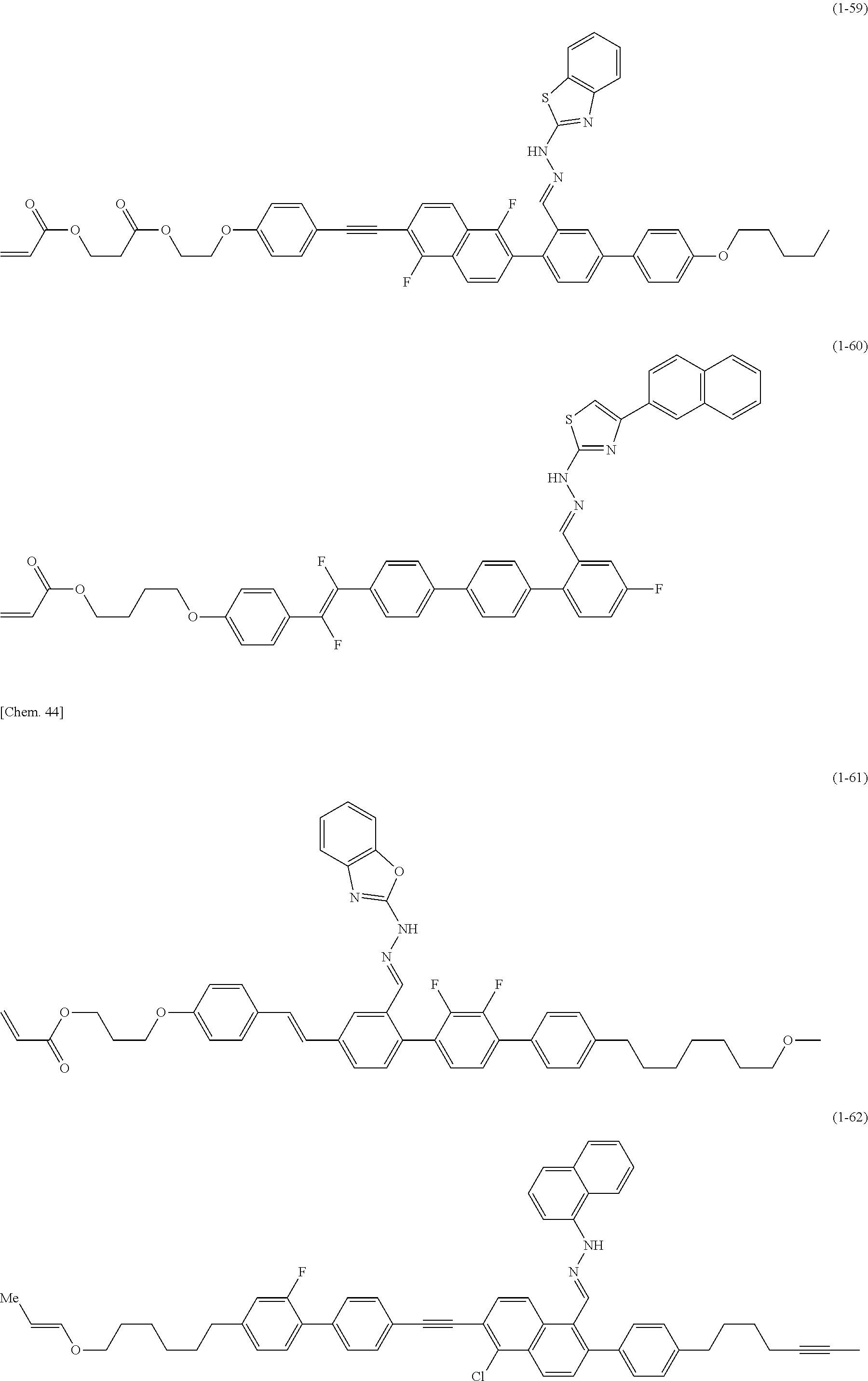

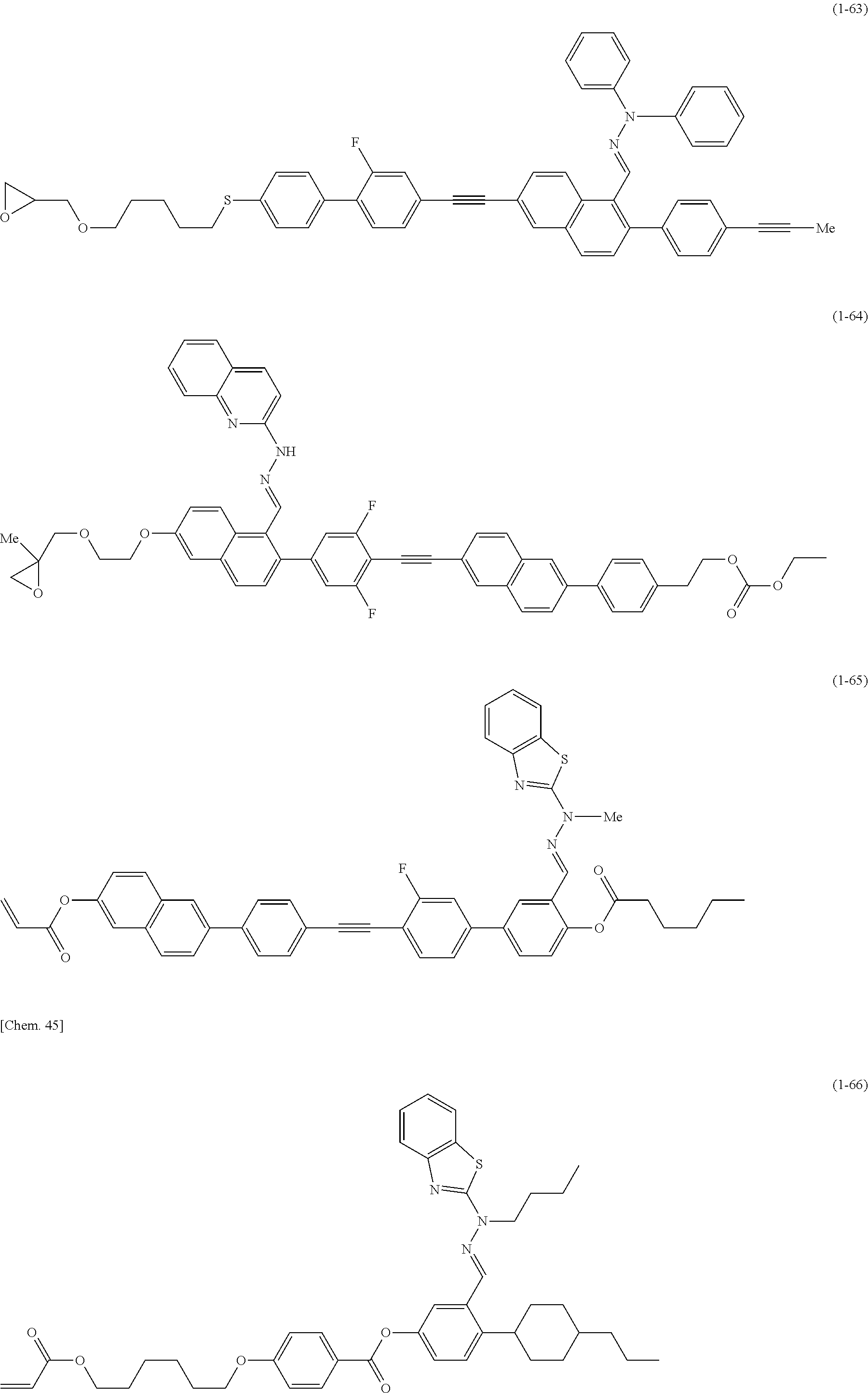

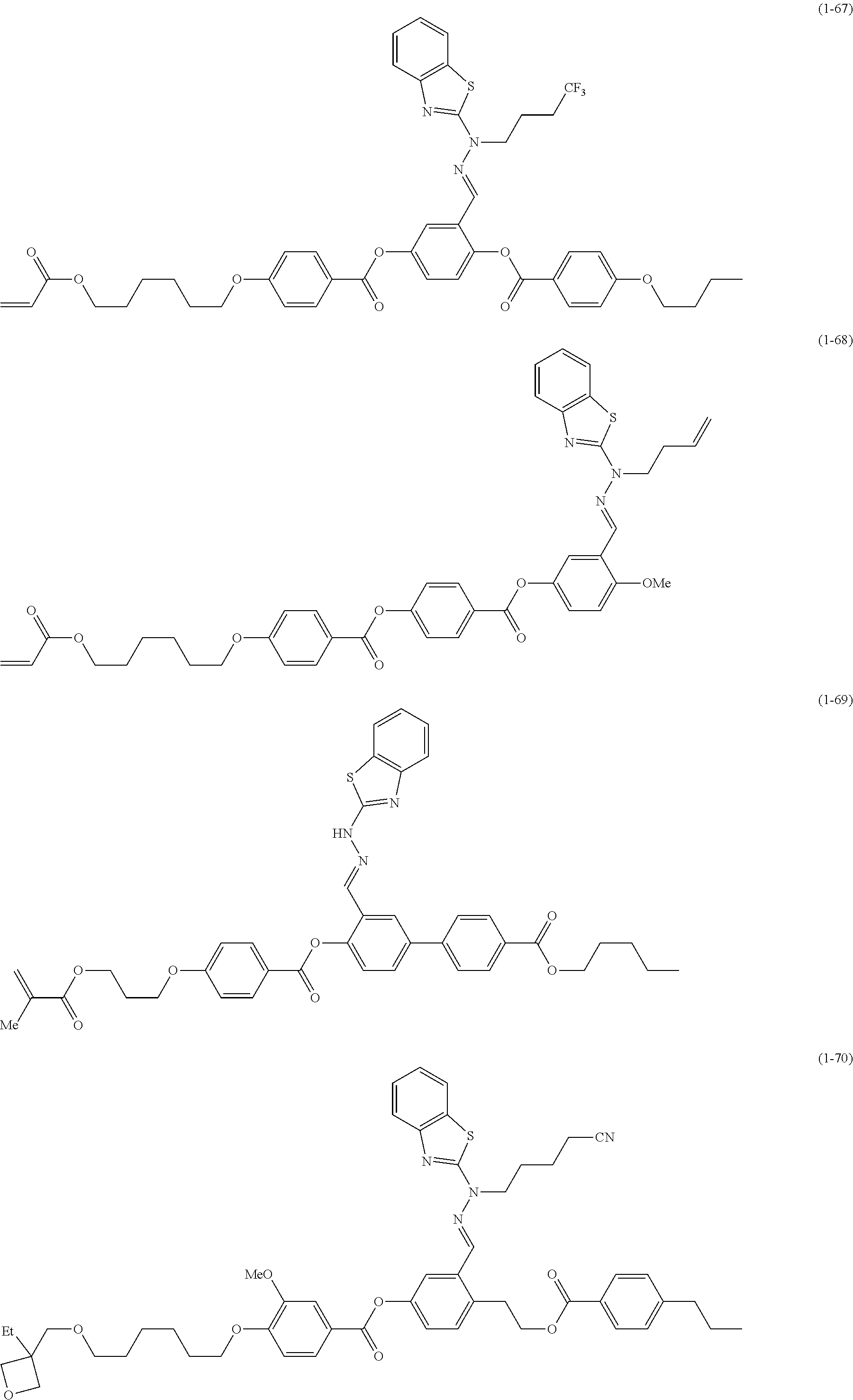

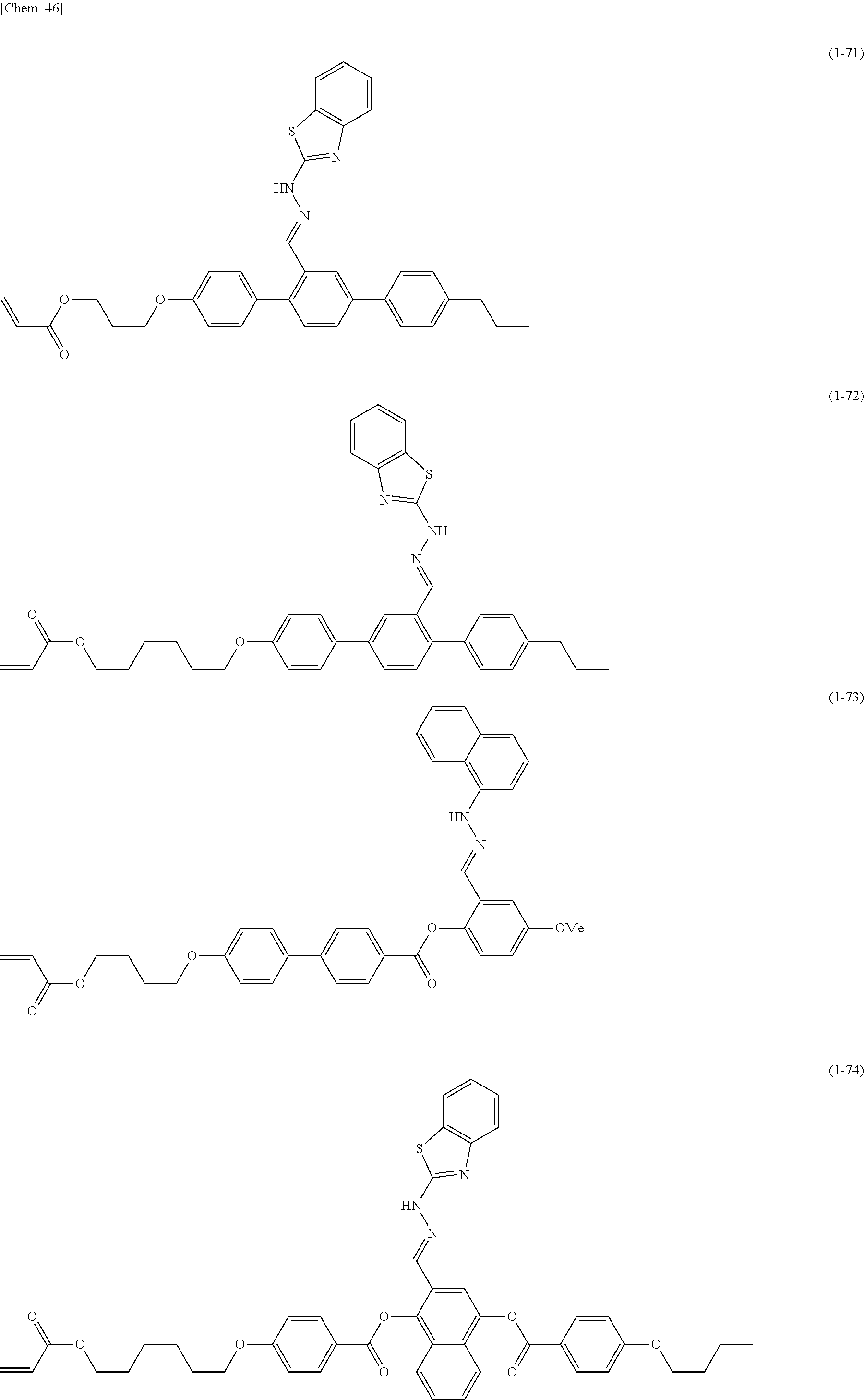

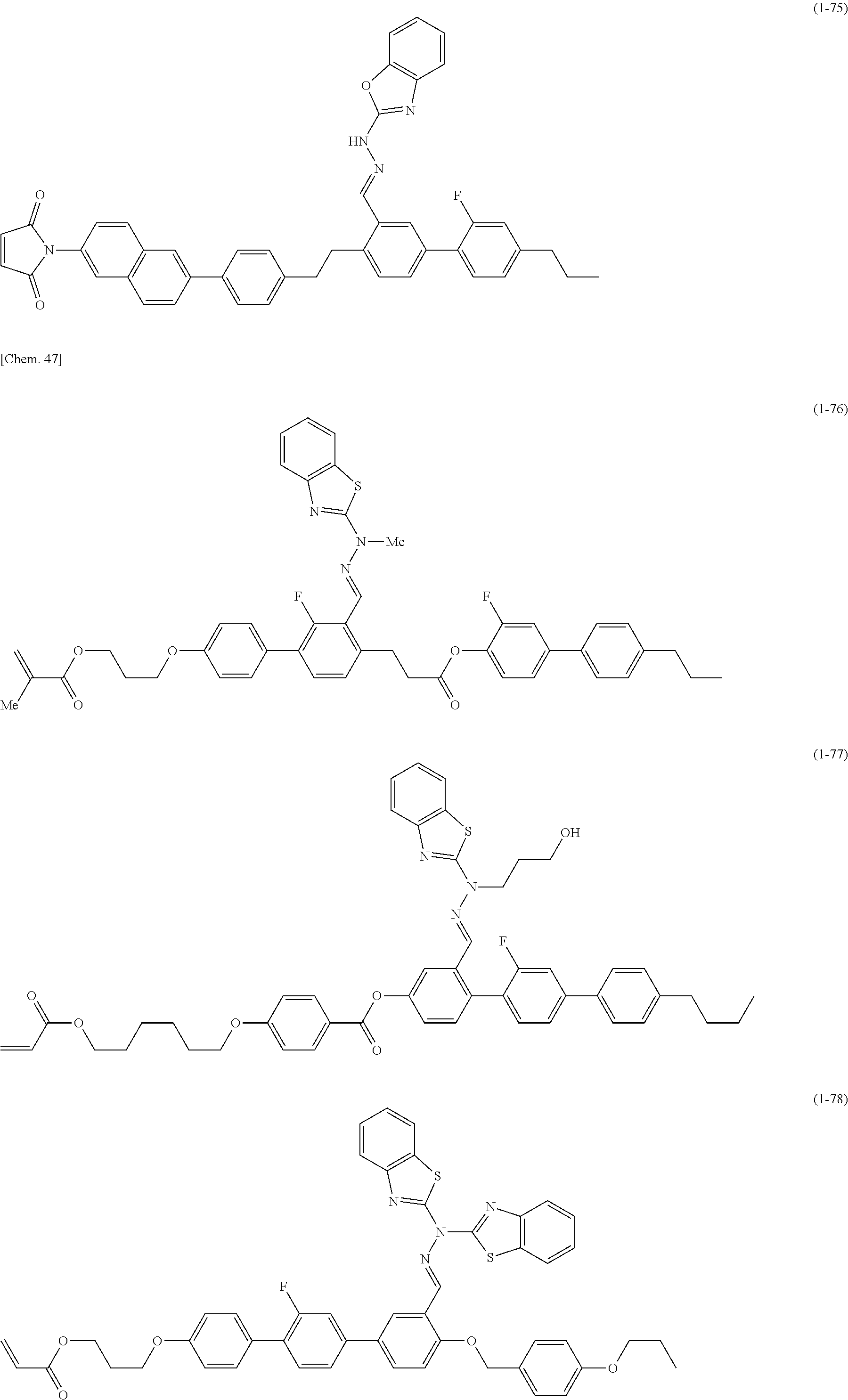

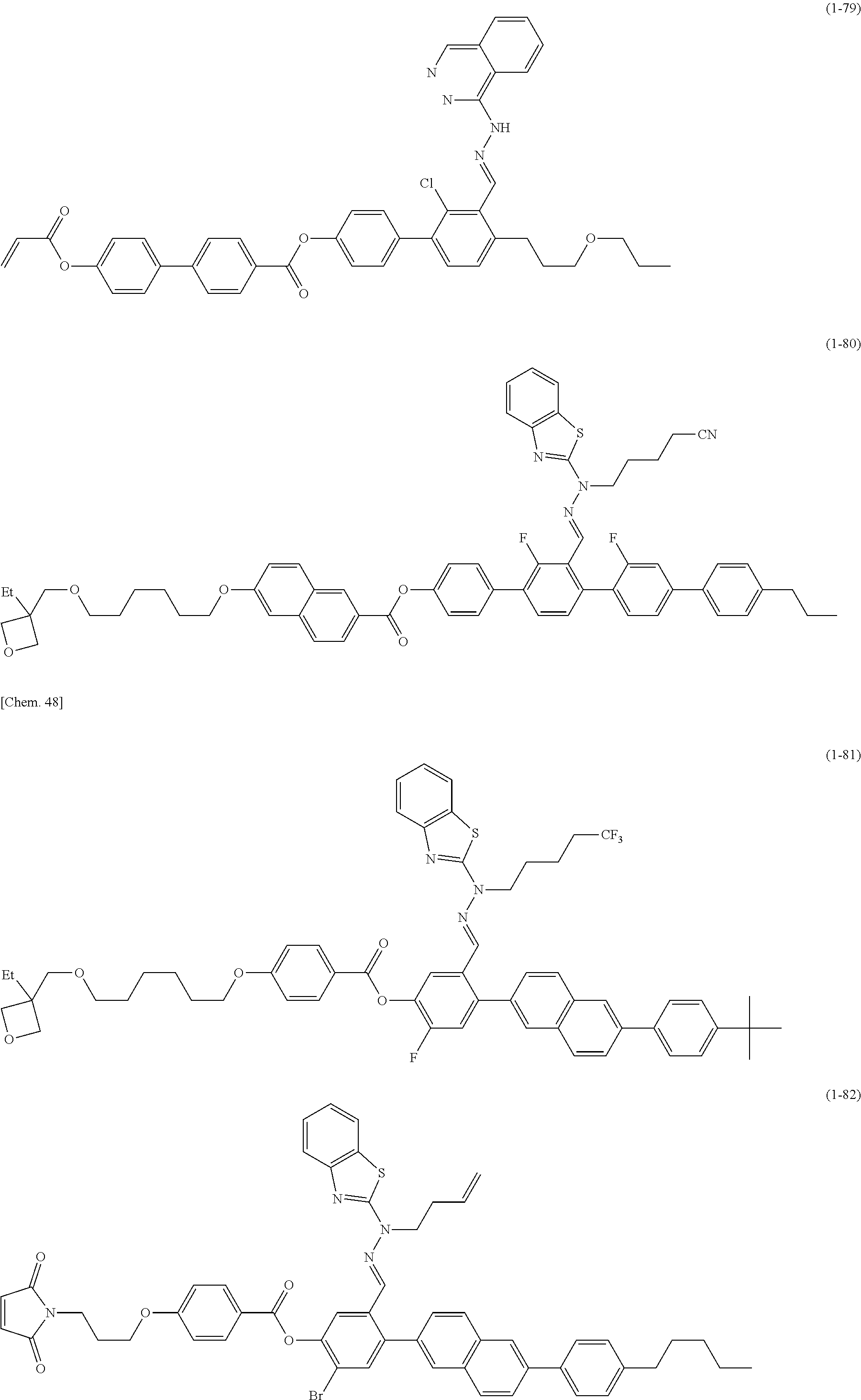

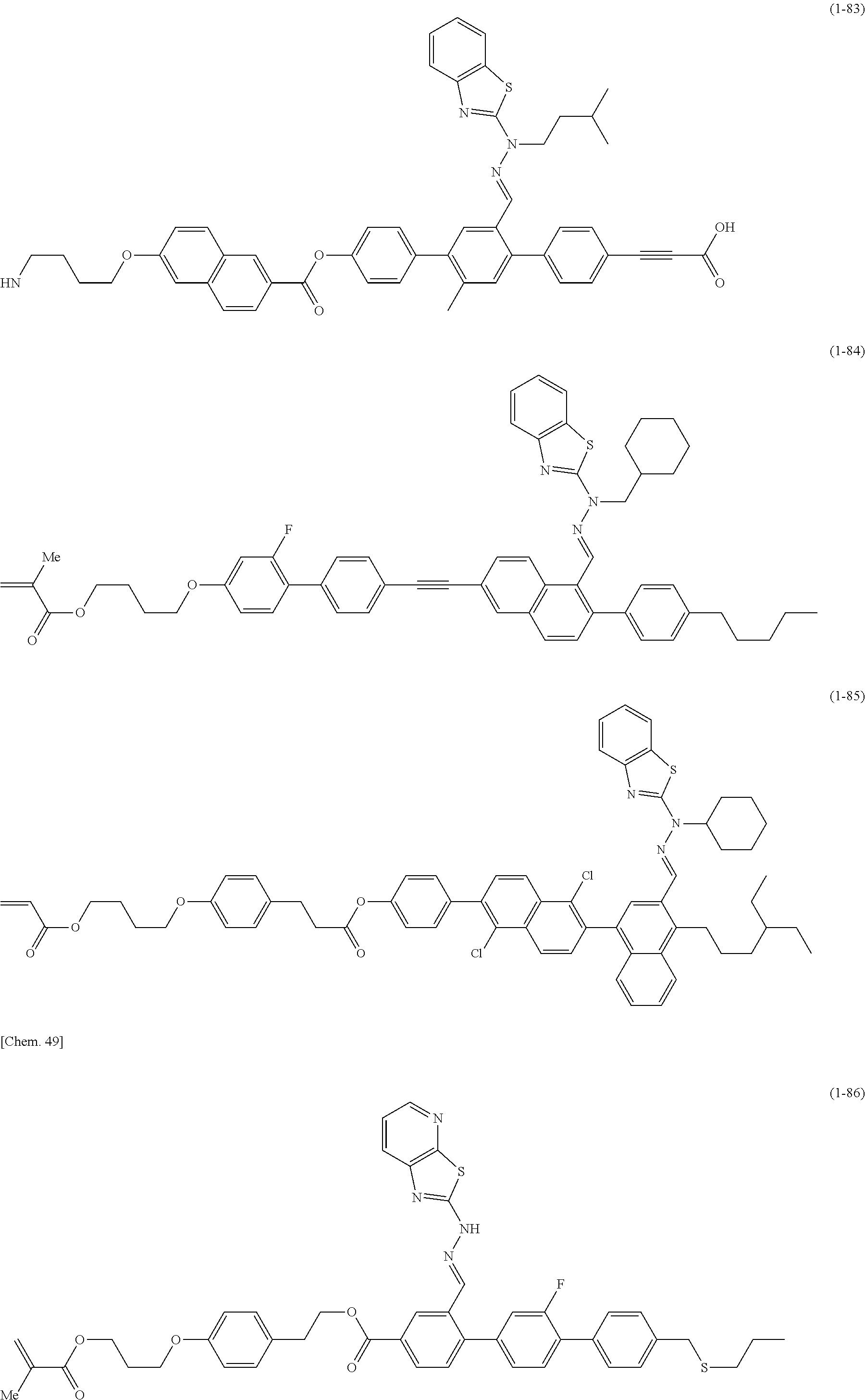

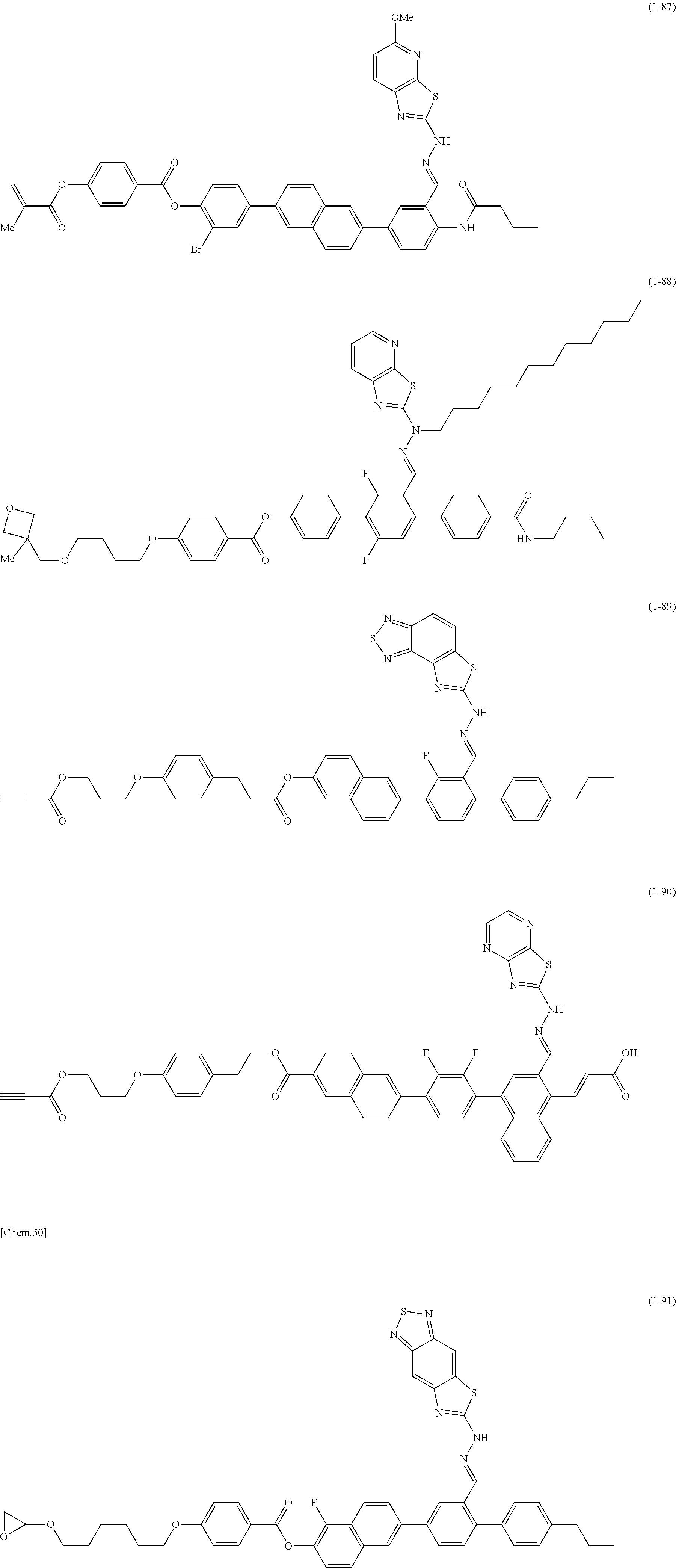

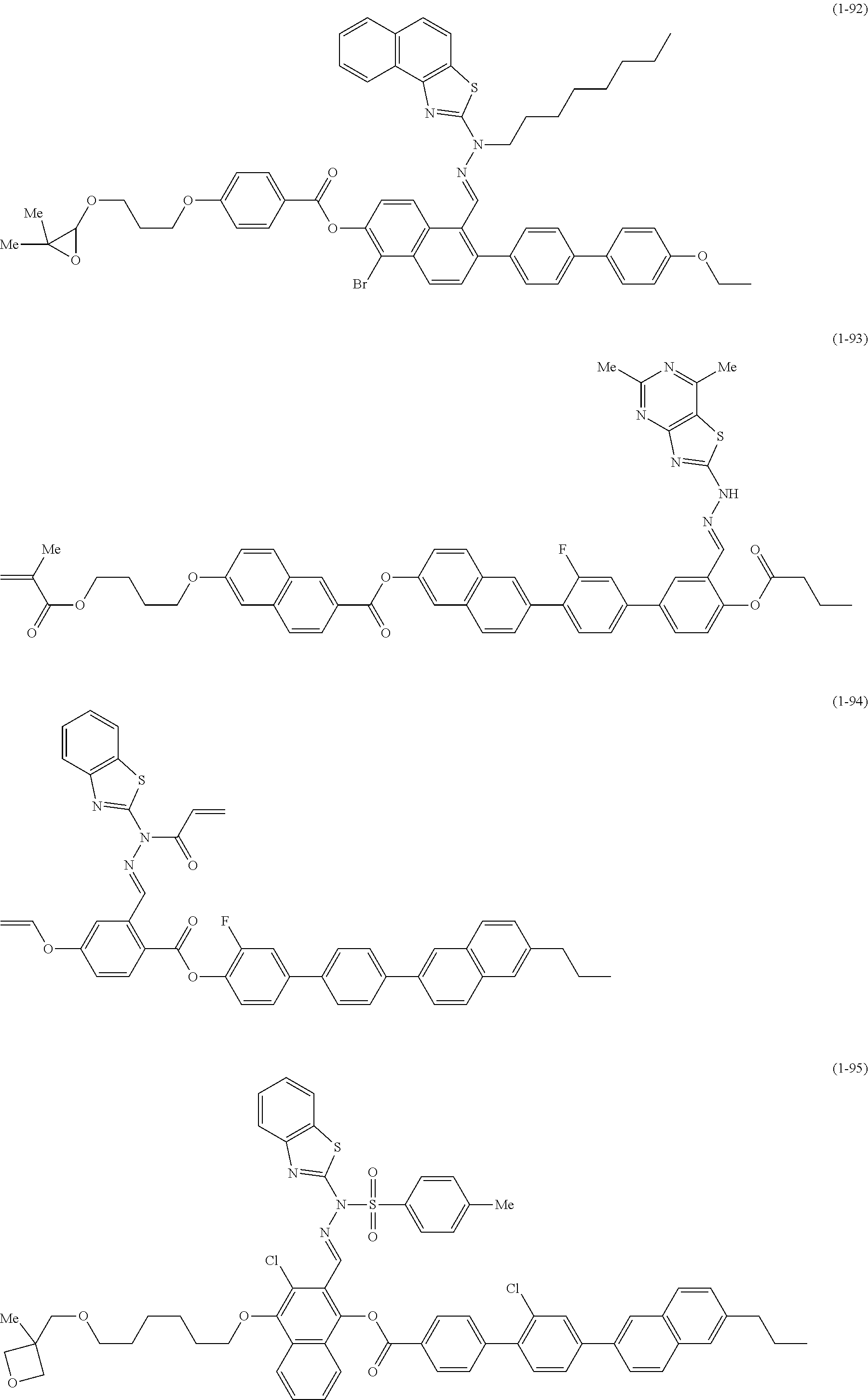

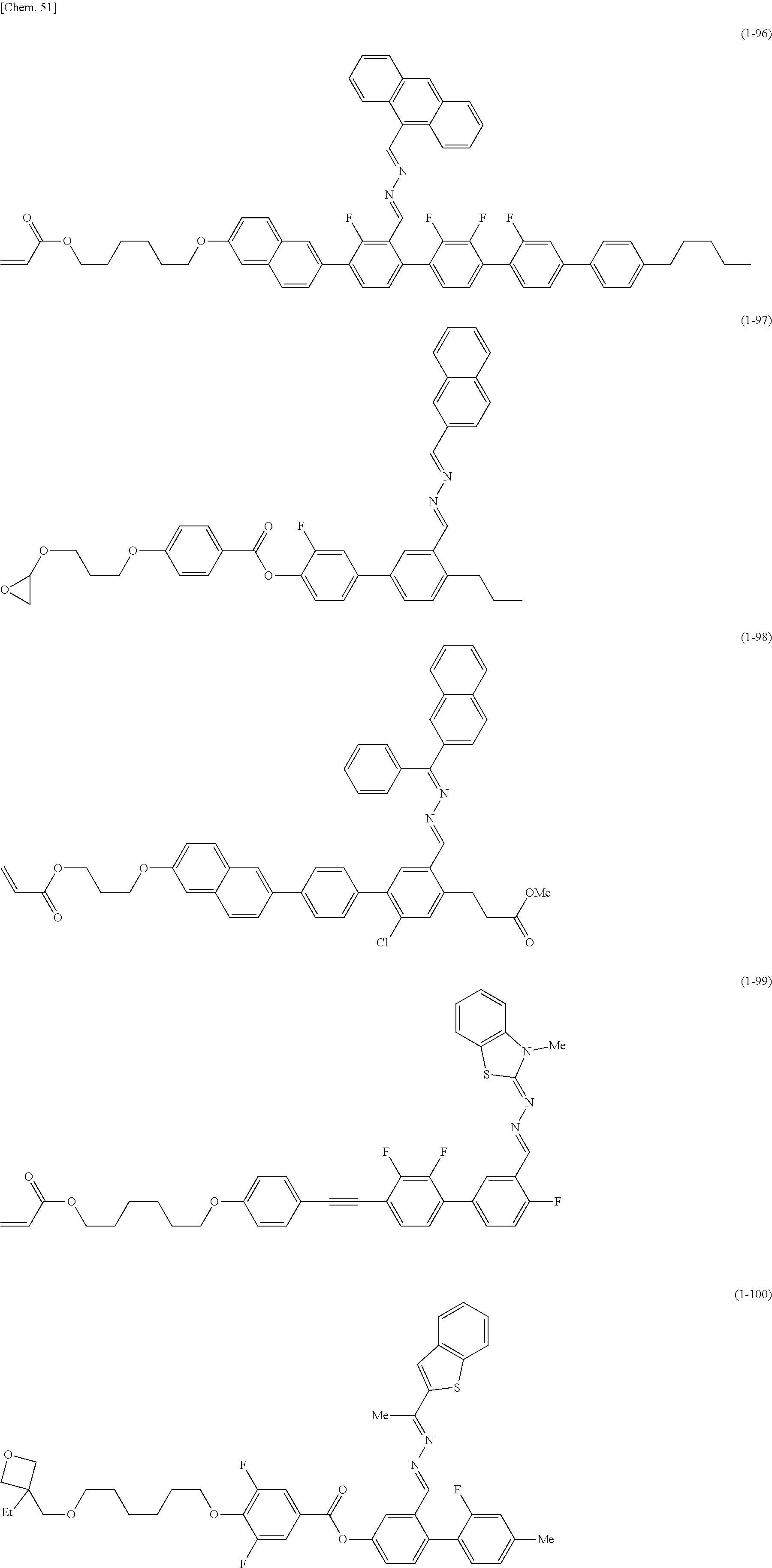

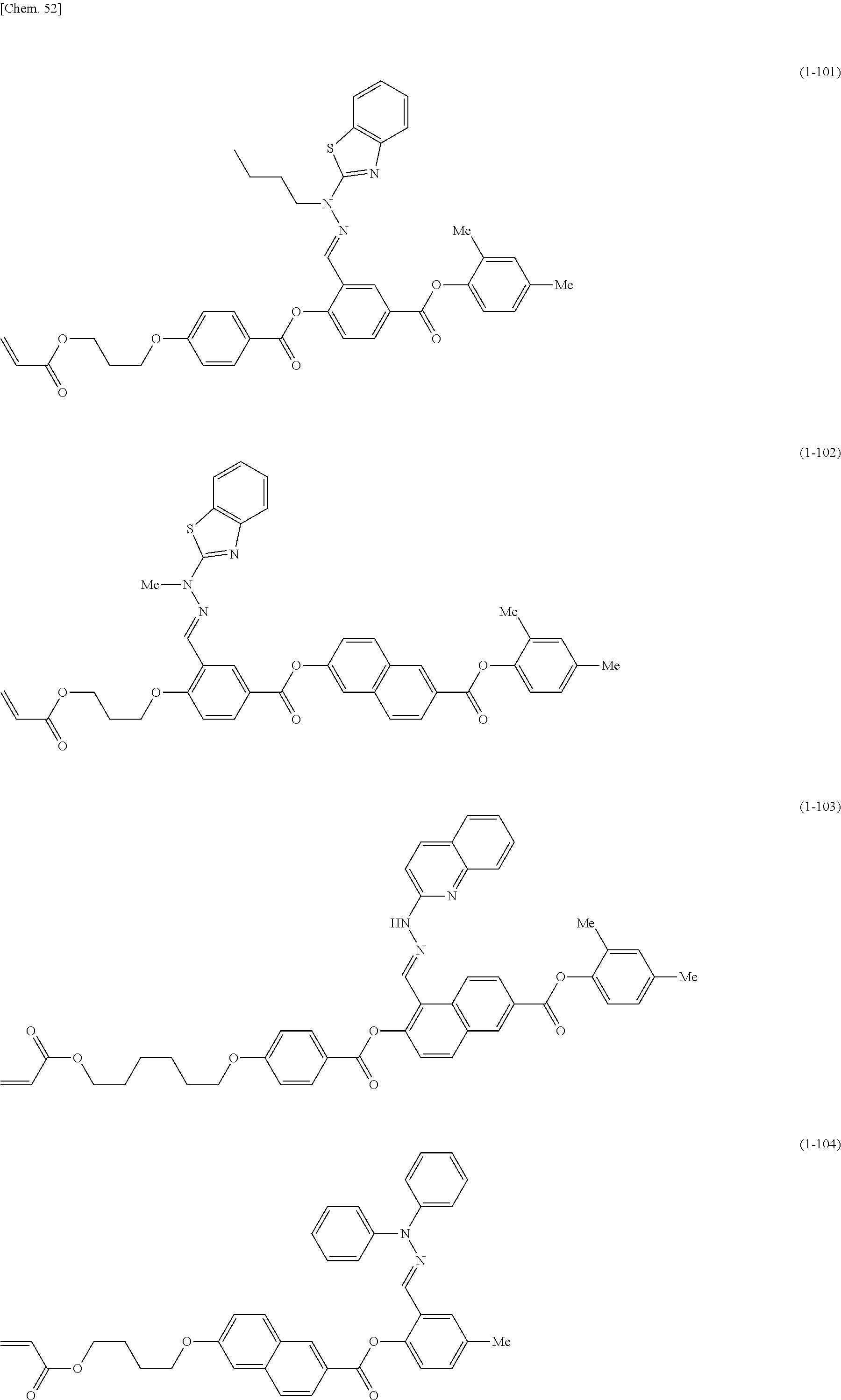

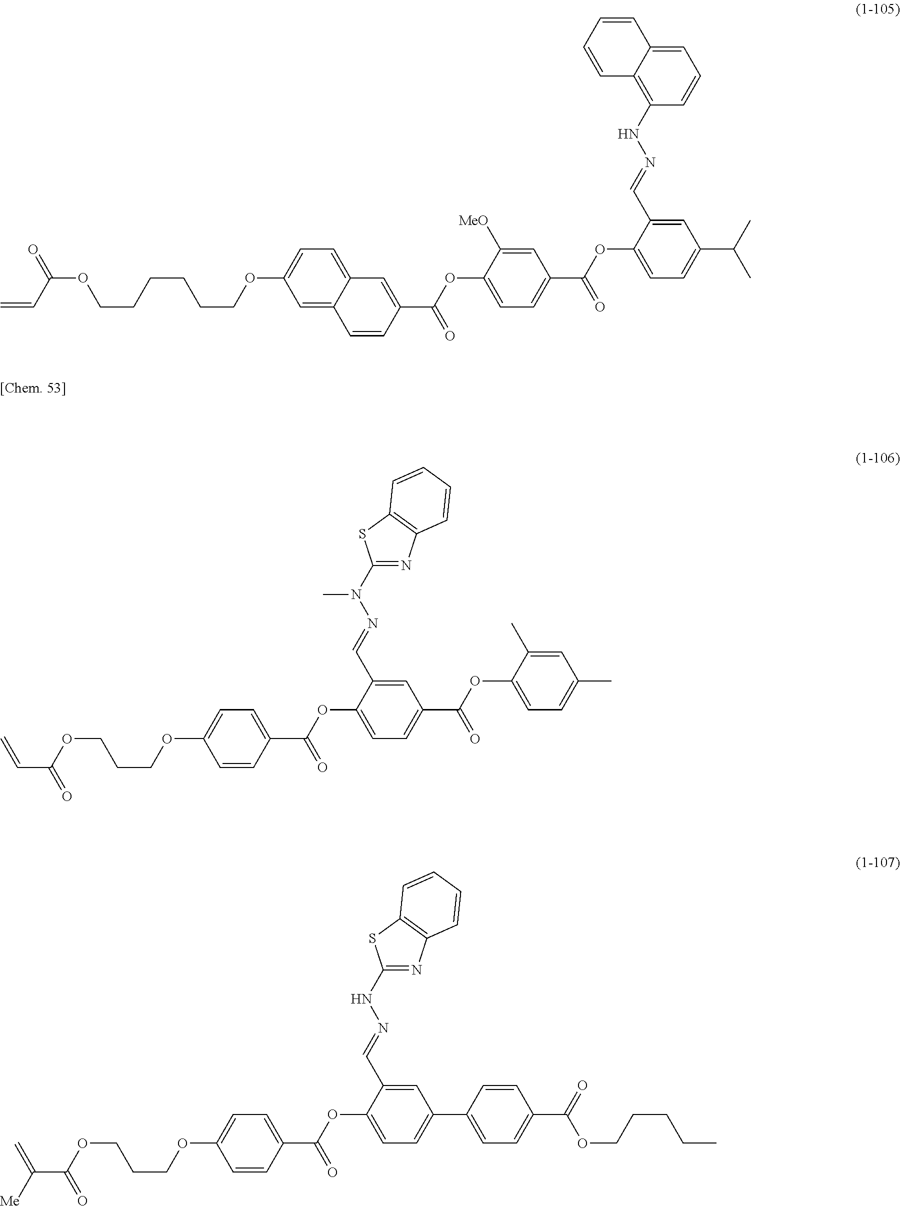

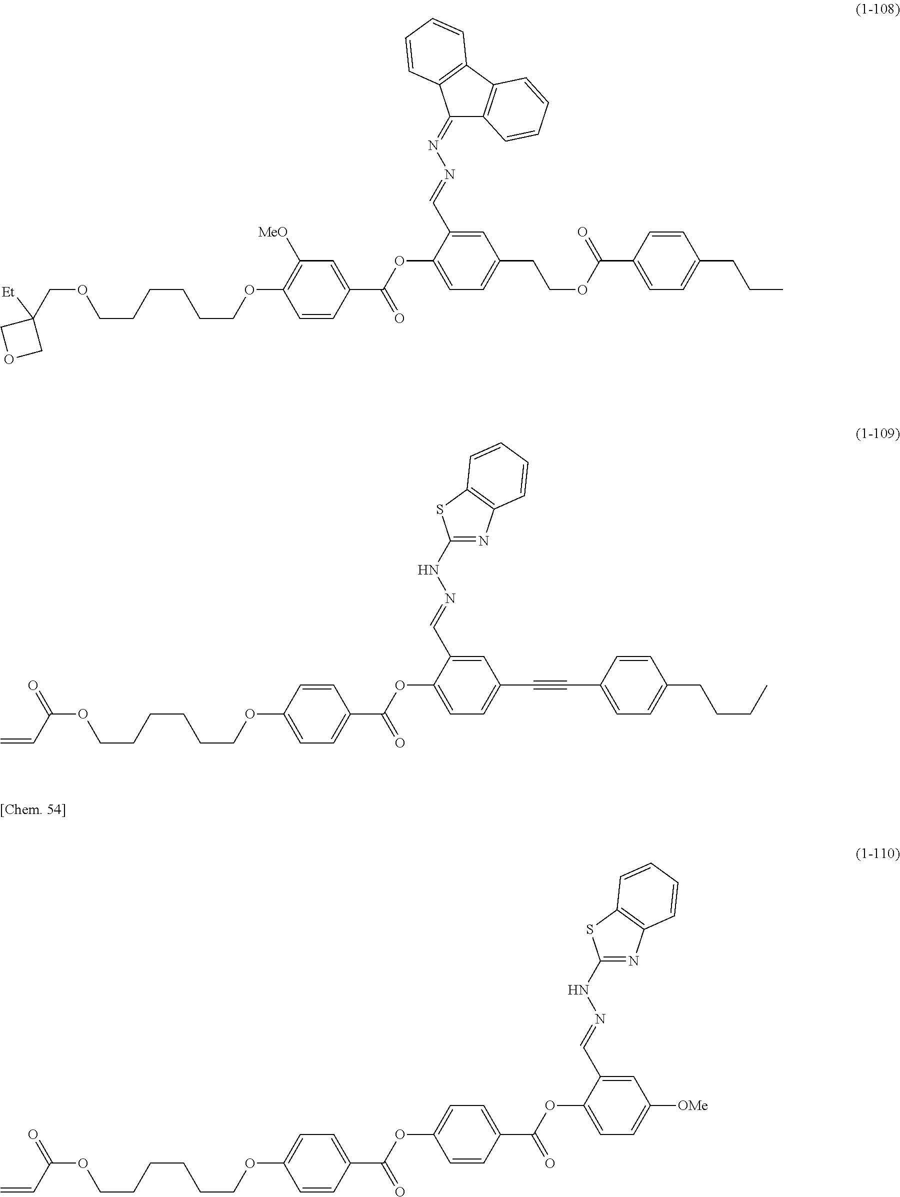

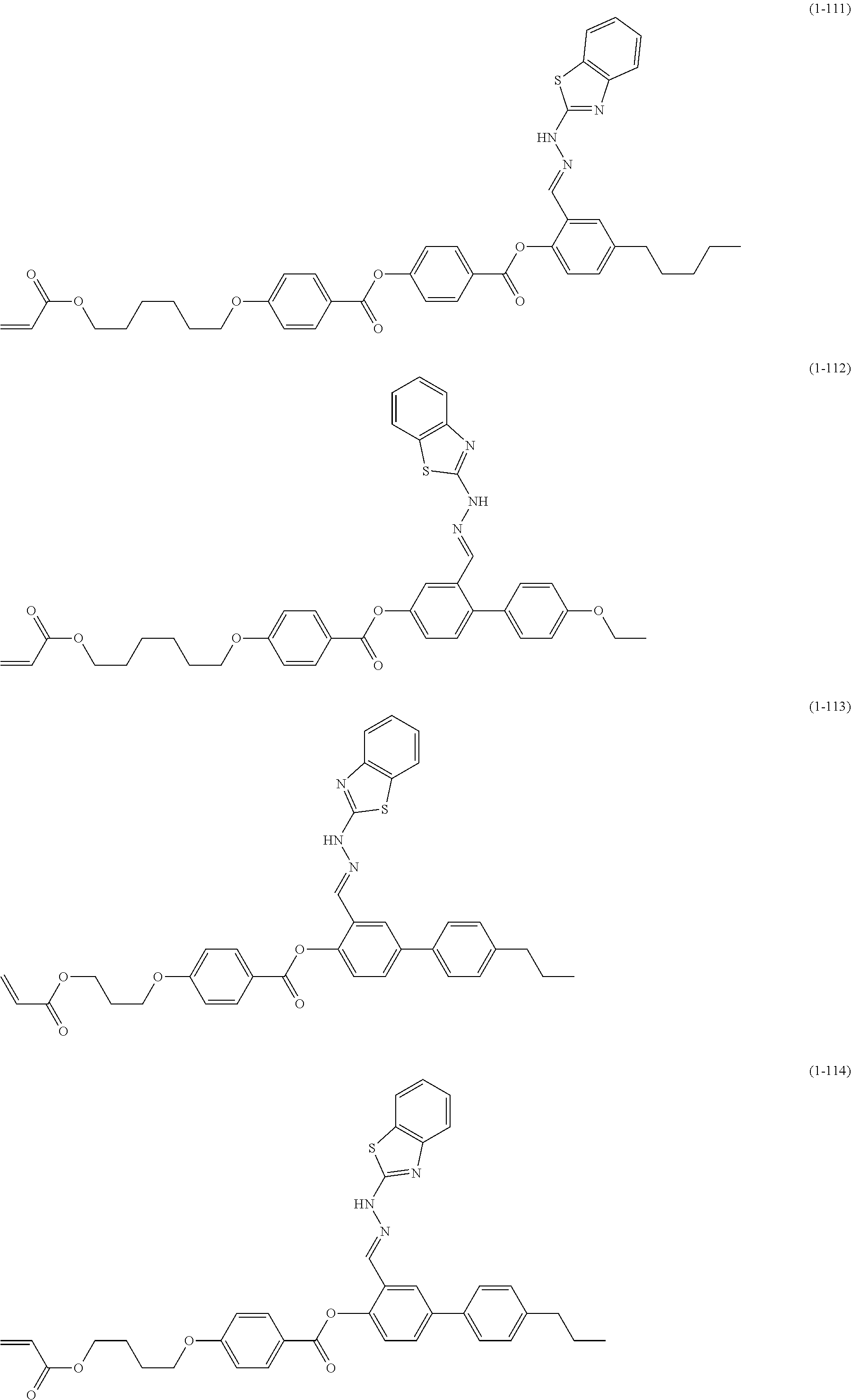

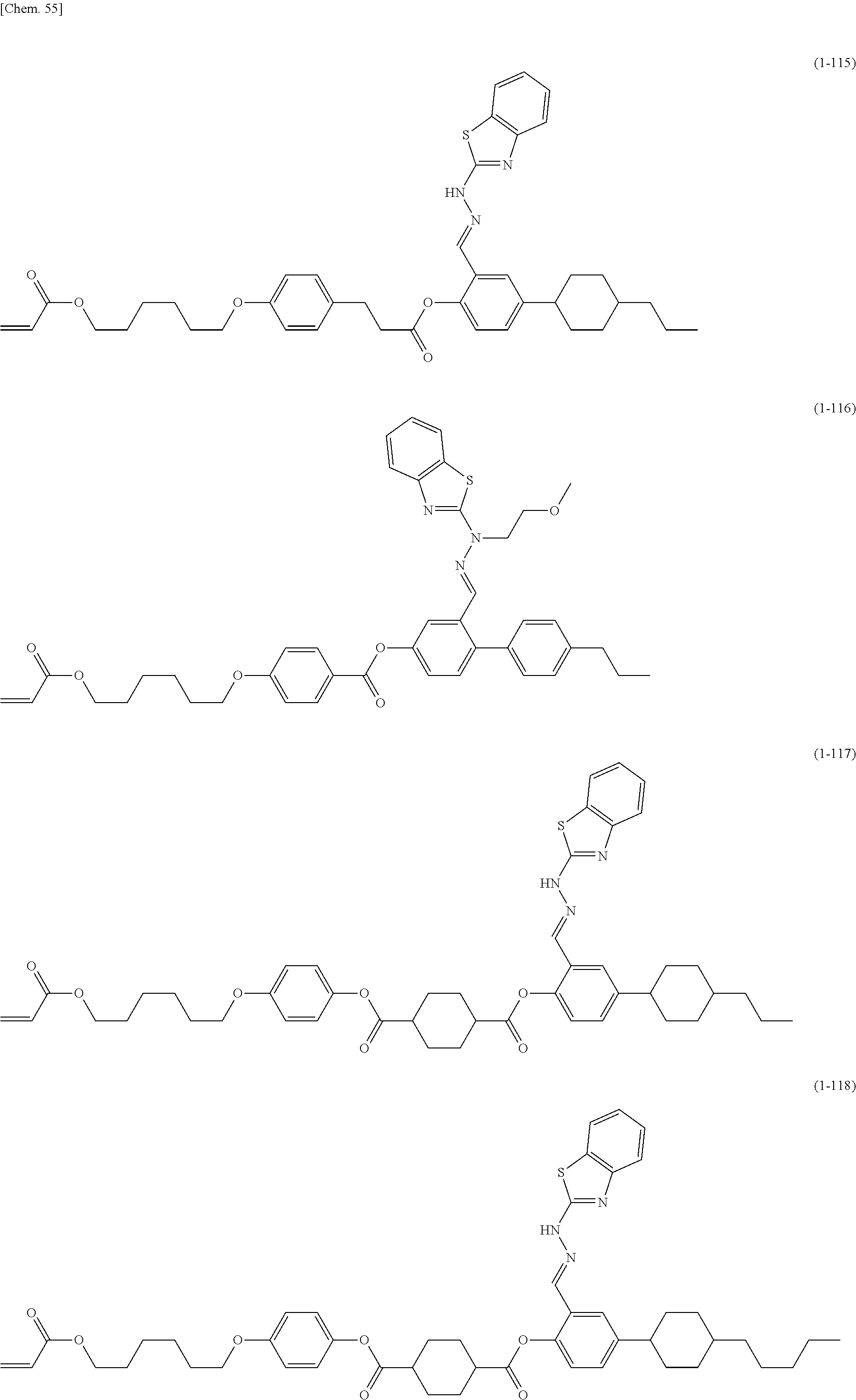

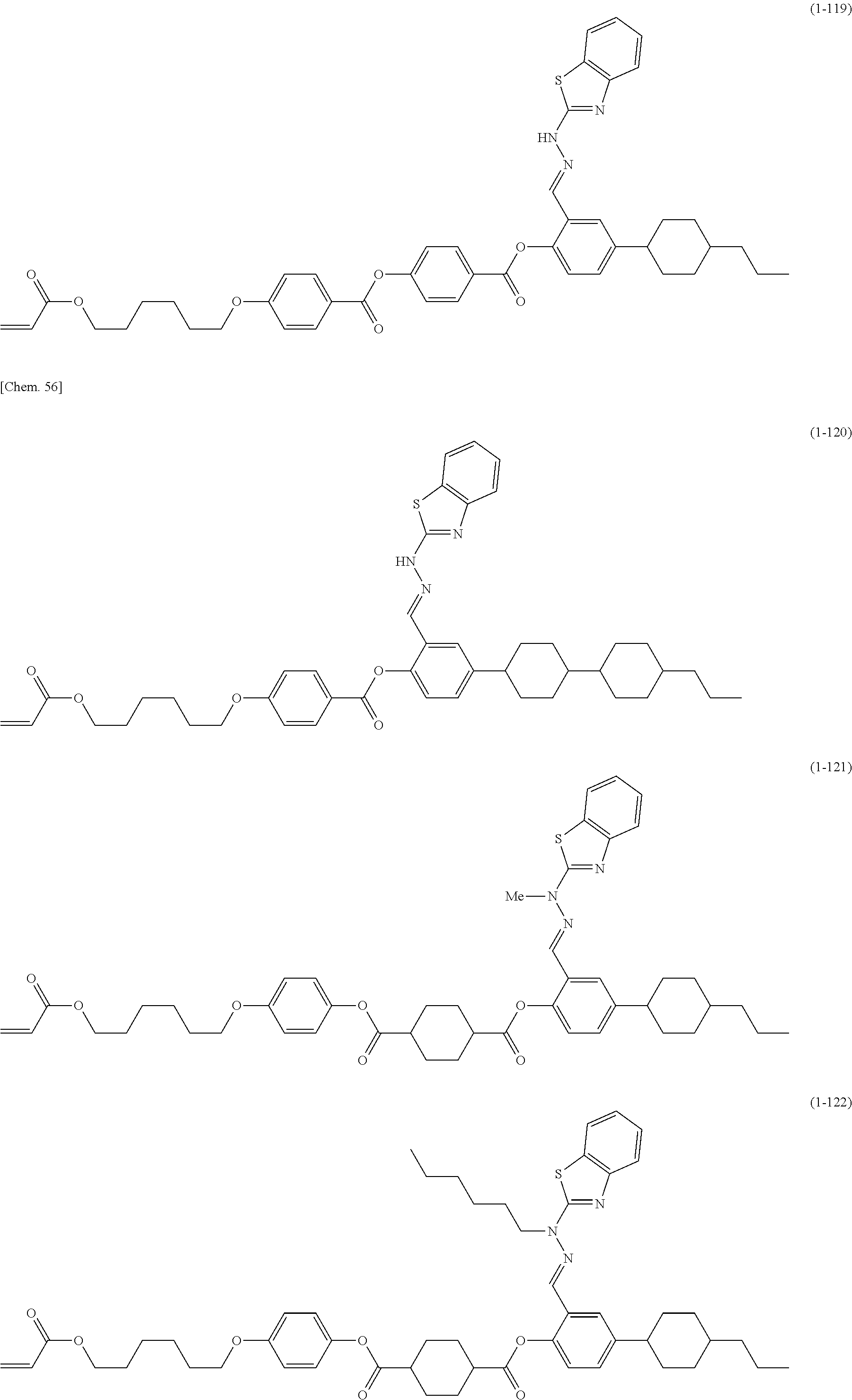

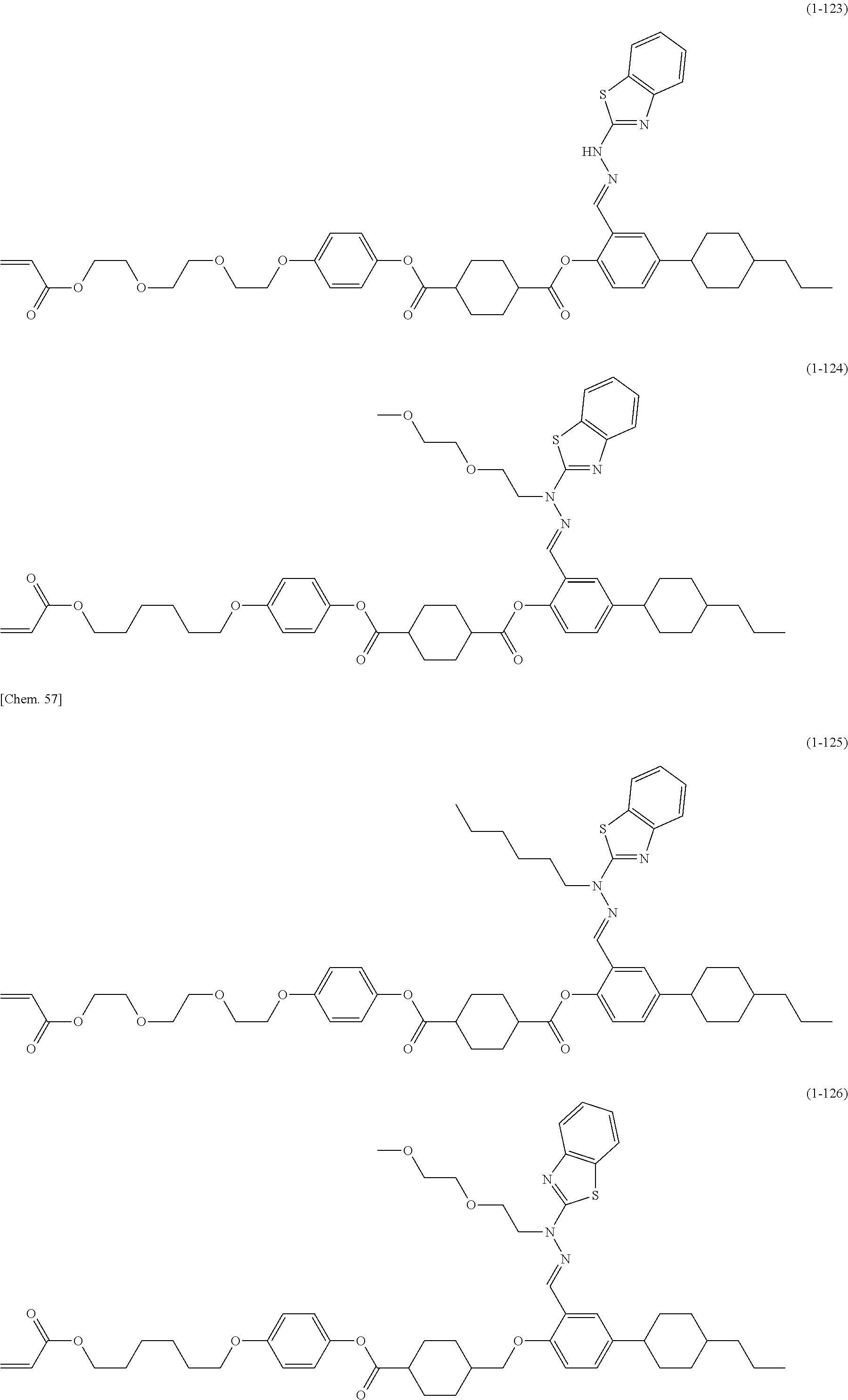

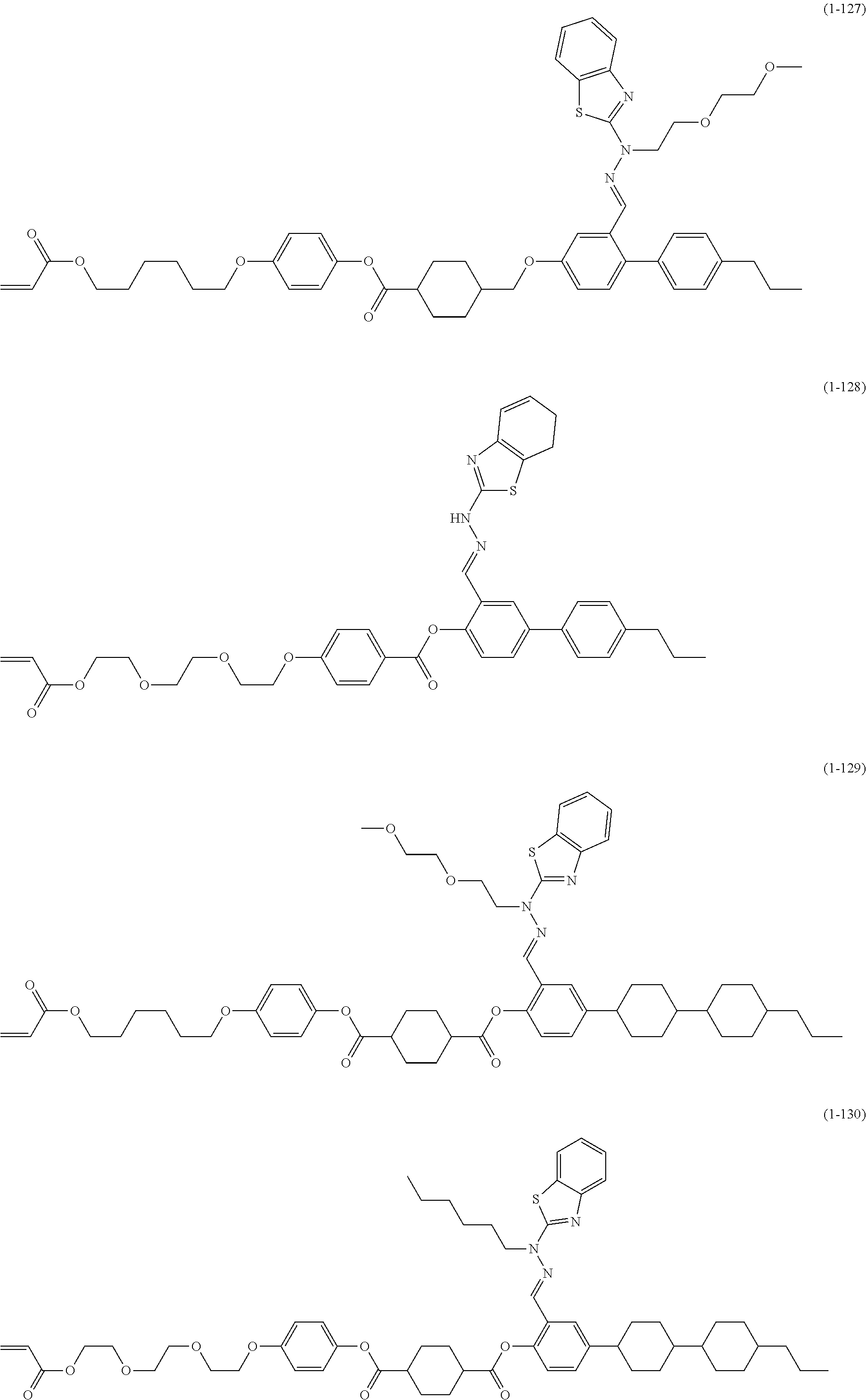

The total content of the polymerizable compound represented by General Formula (1) is preferably 2% to 99% by mass, more preferably 10% to 85% by mass, and particularly preferably 20% to 80% by mass with respect to the total amount of the polymerizable compound used in the polymerizable composition.

Further, in a case of emphasizing the storage stability of the polymerizable composition, the lower limit of the total content is set to be preferably 5% by mass or greater and more preferably 10% by mass or greater. In a case of emphasizing the curability of a coated film to be obtained, the upper limit of the total content is set to be preferably 80% by mass or less and more preferably 70% by mass or less.

Compound (b) Containing at Least Two or More Polymerizable Groups

The polymerizable composition of the present invention contains the compound containing at least two or more polymerizable groups as an indispensable component.

The polymerizable compound containing at least two or more polymerizable groups of the present invention is not particularly limited as long as the polymerizable compound has a mesogenic skeleton, and the compound alone may not exhibit liquid crystallinity.

Examples of the compound include a rigid portion which is referred to as mesogen formed by a plurality of structures such as a 1,4-phenylene group and a 1,4-cyclohexylene group being connected to each other and a rod-like polymerizable liquid crystal compound containing two or more polymerizable functional groups such as a vinyl group, an acrylic group, and a (meth)acrylic group, described in “Handbook of Liquid Crystals” (D. Demus, J. Goodby, G. W. Gray, H. W. Spiessm, edited by V. Vill, published by Willey-VCH, 1998), Quarterly Chemistry Review No. 22, Chemistry of Liquid Crystals (edited by The Chemical Society of Japan, 1994), JP-A-7-294735, JP-A-8-3111, JP-A-8-29618, JP-A-11-80090, JP-A-11-116538, and JP-A-11-148079, and a rod-like polymerizable liquid crystal compound which contains two or more polymerizable groups having a maleimide group, described in JP-A-2004-2373 and JP-2004-99446. Among these, a rod-like liquid crystal compound containing two or more polymerizable groups is preferable because the liquid crystal temperature range easily includes a low temperature around room temperature.

Specific examples of the polymerizable liquid crystalline compound containing at least two or more polymerizable groups include compounds represented by General Formulae (2) to (7). Further, the compound represented by any of General Formulae (2) to (7) does not have a —O—O— bond.

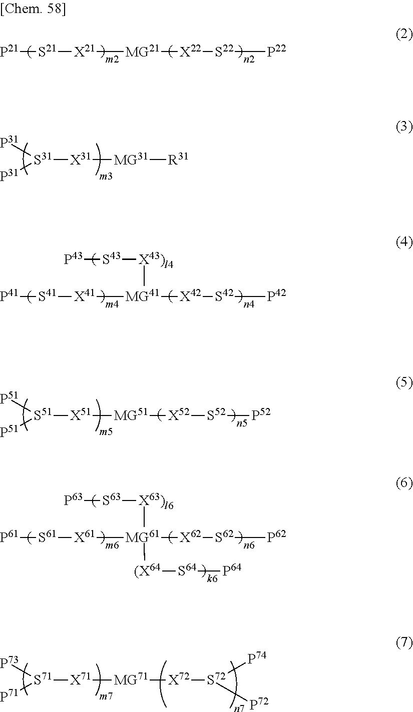

In the formulae, P²¹ to P⁷⁴ each independently represent a polymerizable group, S²¹ to S⁷² each independently represent a spacer group or a single bond, and in a case where a plurality or each of S²¹ to S⁷² is present, these may be the same as or different from each other, X²¹ to X⁷² each independently represent —O—, —S—, —OCH₂—, —CH₂O—, —CO—, —COO—, —OCO—, —CO—S—S—CO—, —O—CO—O—, —CO—NH—, —NH—CO—, —SCH₂—, —CH₂S—, —CF₂O—, —OCF₂—, —CF₂S—, —SCF₂—, —CH═CH—COO—, —CH═CH—OCO—, —COO—CH═CH—, —OCO—CH═CH—, —COO—CH₂CH₂—, —OCO—CH₂CH₂—, —CH₂CH₂—COO—, —CH₂CH₂—OCO—, —COO—CH₂—, —OCO—CH₂—, —CH₂—COO—, —CH₂—OCO—, —CH═CH—, —N═N—, —CH═N—N═CH—, —CF═CF—, —C≡C—, or a single bond, and in a case where a plurality of each of X²¹ to X⁷² is present, these may be the same as or different from each other, provided that each P— (S—X)— bond does not have —O—O—, MG²¹ to MG⁷¹ each independently represent a mesogenic group, R³ represents a hydrogen atom, a fluorine atom, a chlorine atom, a bromine atom, an iodine atom, a pentafluorosulfuranyl group, a cyano group, a nitro group, an isocyano group, a thioisocyano group, or an alkyl group having 1 to 20 carbon atoms, the alkyl group may be linear or branched, one or more of arbitrary hydrogen atoms in the alkyl group may be substituted with a fluorine atom, and one —CH₂— or two or more (—CH₂—)'s which are not adjacent to each other in the alkyl group may be each independently substituted with —O—, —S—, —CO—, —COO—, —OCO—, —CO—S—, —S—CO—, —O—CO—, —CO—NH—, —NH—CO—, or —C≡C—, and m2 to m7, n2 to n7, l4 to l6, and k6 each independently represent an integer of 0 to 5.

The spacer group as S²¹ to S⁷² is an alkylene group having 1 to 18 carbon atoms, the alkylene group may be substituted with one or more halogen atoms, a CN group, an alkyl group having 1 to 8 carbon atoms, or an alkyl group having a polymerizable functional group and 1 to 8 carbon atoms, and one —CH₂— or two or more (—CH₂—)'s which are not adjacent to each other in this group may be each independently substituted with —O—, —S—, —NH—, —N(CH₃)—, —CO—, —CH(OH)—, CH(COOH), —COO—, —OCO—, —OCOO—, —SCO—, —COS—, or —C≡C—. Among these spacer groups, from the viewpoint of alignment properties, a linear alkylene group having 2 to 8 carbon atoms, an alkylene group having 2 to 6 carbon atoms which is substituted with a fluorine atom, and an alkylene group having 5 to 14 carbon atoms in which a part thereof is substituted with —O— are preferable.

Further, it is preferable that the polymerizable group as P²¹ to P⁷⁴ is a group represented by any of Formulae (P-1) to (P-20).

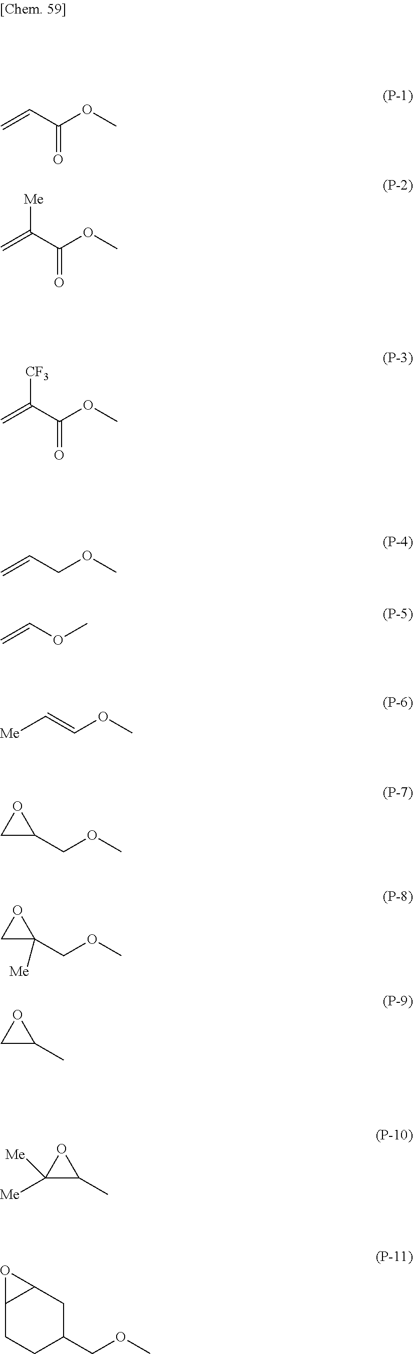

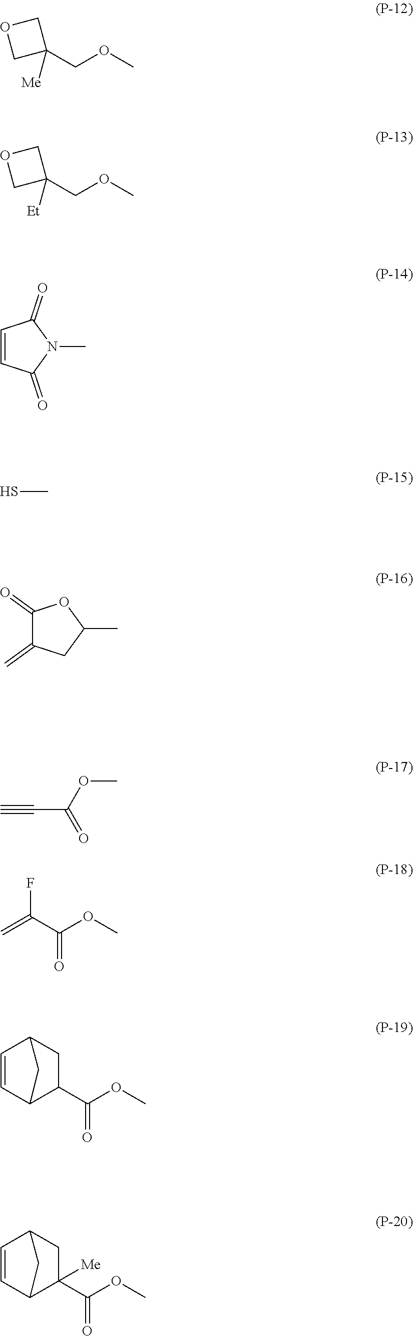

Among these polymerizable groups, from the viewpoint of improving polymerization properties and storage stability, a group represented by Formula (P-1), (P-2), (P-7), (P-12), or (P-13) is preferable and a group represented by Formula (P-1), (P-7), or (P-12) is more preferable.

The mesogenic group as MG²¹ to MG⁷¹ is a group represented by Formula (8-a).

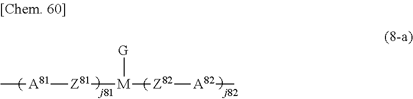

(In the formula, A⁸¹ and A⁸² each independently represent a 1,4-phenylene group, a 1, 4-cyclohexylene group, a pyridine-2,5-diyl group, a pyrimidine-2,5-diyl group, a naphthalene-2,6-diyl group, a naphthalene-1,4-diyl group, a tetrahydronaphthalene-2, 6-diyl group, a decahydronaphthalene-2,6-diyl group, or a 1, 3-dioxane-2,5-diyl group, these groups may be unsubstituted or substituted with one or more of L²'s, and in a case where a plurality of each of A⁸¹ and A⁸² is present, these may be the same as or different from each other,

Z⁸¹ and Z⁸² each independently represent —O—, —S—, —OCH₂—, —CH₂O—, —CH₂CH₂—, —O—, —COO—, —OCO—, —CO—S—, —S—CO—, —O—CO—O—, —CO—NH—, —NH—CO—, —SCH₂—, —CH₂S—, —CF₂O—, —OCF₂—, —CF₂S—, —SCF₂—, —CH═CH—COO—, —CH═CH—OCO—, —COO—CH═CH—, —OCO—CH═CH—, —COO—CH₂CH₂—, —OCO—CH₂CH₂—, —CH₂CH₂—COO—, —CH₂CH₂—OCO—, —COO—CH₂—, —OCO—CH₂—, —CH₂—COO—, —CH₂—OCO—, —CH═CH—, —N═N—, —CH═N—, —N═CH—, —CH═N—N═CH—, —CF═CF—, —C≡C—, or a single bond, and in a case where a plurality of each of Z⁸¹ and Z⁸² is present, these may be the same as or different from each other,

M represents a group selected from groups represented by Formula (M-1) to Formula (M-11), and these groups may be unsubstituted or substituted with one or more of L²'s.

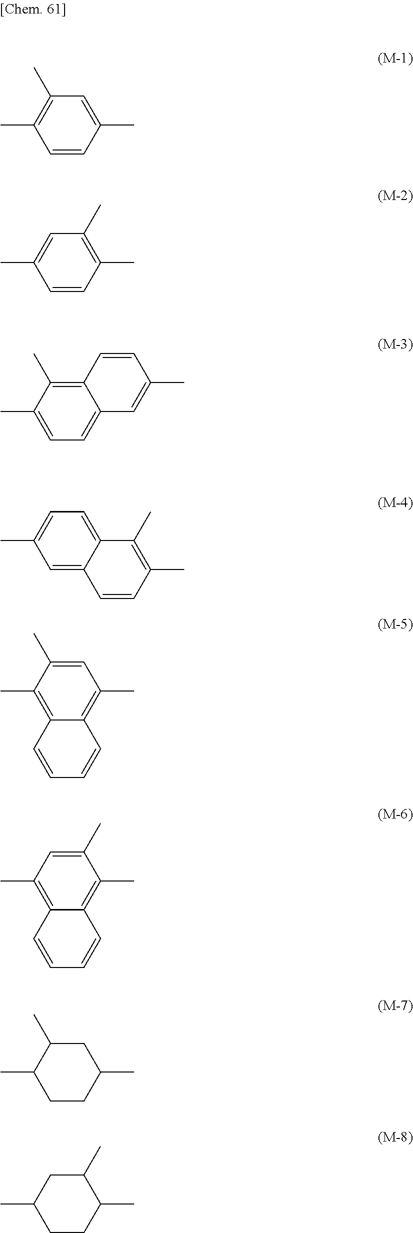

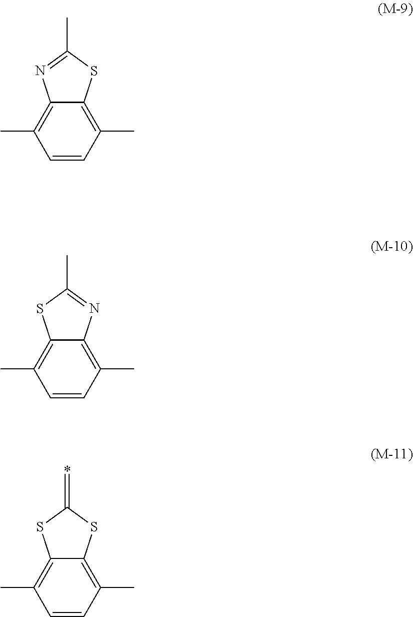

C represents a group selected from groups represented by Formula (G-1) to Formula (G-6).

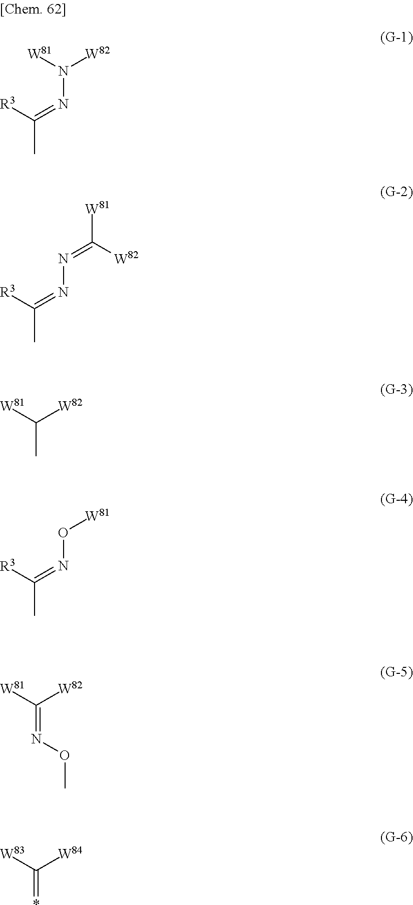

(In the formulae, R³ represents a hydrogen atom or an alkyl group having 1 to 20 carbon atoms, the alkyl group may be linear or branched, one or more of arbitrary hydrogen atoms in the alkyl group may be substituted with a fluorine atom, and one —CH₂— or two or more (—CH₂—)'s which are not adjacent to each other in the alkyl group may be each independently substituted with —O—, —S—, —CO—, —COO—, —OCO—, —CO—S—, —S—CO—, —O—CO—O—, —CO—NH—, —NH—CO—, or —C≡C—,

W⁸¹ represents a group having at least one aromatic group and 5 to 30 carbon atoms and the group may be unsubstituted or substituted with one or more of L²'s,

W⁸² represents a hydrogen atom or an alkyl group having 1 to 20 carbon atoms, the alkyl group may be linear or branched, one or more of arbitrary hydrogen atoms in the alkyl group may be substituted with a fluorine atom, one —CH₂— or two or more (—CH₂—)'s which are not adjacent to each other in the alkyl group may be each independently substituted with —O—, —S—, —CO—, —COO—, —OCO—, —CO—S—, —S—CO—, —O—CO—O—, —CO—NH—, —NH—CO—, —CH═CH—COO—, —CH═CH—OCO—, —COO—CH═CH—, —OCO—CH═CH—, —CH═CH—, —CF═CF—, or —C≡C—, W⁸² may have the same definition as that for W⁸¹, W⁸¹ and W⁸² may be linked to each other to form the same ring structure, and W⁸² represents a group represented by the following formula.

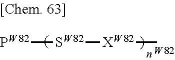

(In the formula, P^{W82} has the same definition as that for P¹¹, S^{W82} has the same definition as that for S¹¹, X^{W82} has the same definition as that for X¹¹, and n^{W82} has the same definition as that for k.)

W⁸³ and W⁸⁴ each independently represent a halogen atom, a cyano group, a hydroxy group, a nitro group, a carboxyl group, a carbamoyloxy group, an amino group, a sulfamoyl group, a group having at least one aromatic group and 5 to 30 carbon atoms, an alkyl group having 1 to 20 carbon atoms, a cycloalkyl group having 3 to 20 carbon atoms, an alkenyl group having 2 to 20 carbon atoms, a cycloalkenyl group having 3 to 20 carbon atoms, an alkoxy group having 1 to 20 carbon atoms, an acyloxy group having 2 to 20 carbon atoms, or an alkylcarbonyloxy group having 2 to 20 carbon atoms, one —CH₂— or two or more (—CH₂—)'s which are not adjacent to each other in the alkyl group, the cycloalkyl group, the alkenyl group, the cycloalkenyl group, the alkoxy group, the acyloxy group, and the alkylcarbonyloxy group may be each independently substituted with —O—, —S—, —CO—, —COO—, —OCO—, —CO—S—, —S—CO—, —O—CO—O—, —CO—NH—, —NH—CO—, or —C≡C—,

G represents a group selected from groups represented by Formula (G-1) to Formula (G-5) in a case where M represents a group selected from groups represented by Formula (M-1) to Formula (M-10) and G represents a group represented by Formula (G-6) in a case where N represents a group represented by Formula (M-11),

L² represents a fluorine atom, a chlorine atom, a bromine atom, an iodine atom, a pentafluorosulfuranyl group, a nitro group, an isocyano group, an amino group, a hydroxyl group, a mercapto group, a methylamino group, a dimethylamino group, a diethyl amino group, a diisopropylamino group, a trimethylsilyl group, a dimethylsilyl group, a thioisocyano group, or an alkyl group having 1 to 20 carbon atoms, and the alkyl group may be linear or branched, one or more of arbitrary hydrogen atoms may be substituted with a fluorine atom, one —CH₂— or two or more (—CH₂—)'s which are not adjacent to each other in the alkyl group may be each independently substituted with a group selected from —O—, —S—, —CO—, —COO—, —OCO—, —CO—S—, —S—CO—, —O—CO—O—, —CO—NH—, —NH—CO—, —CH═CH—COO—, —CH═CH—OCO—, —COO—CH═CH—, —OCO—CH═CH—, —CH═CH—, —CF═CF—, or —C≡C—, and j81 and j82 each independently represent an integer of 0 to 5, provided that j81+j82 represents an integer of 1 to 5.)

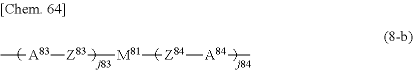

(In the formula, A⁸³ and A⁸⁴ each independently represent a 1,4-phenylene group, a 1, 4-cyclohexylene group, a pyridine-2,5-diyl group, a pyrimidine-2,5-diyl group, a naphthalene-2, 6-diyl group, a naphthalene-1,4-diyl group, a tetrahydronaphthalene-2, 6-diyl group, a decahydronaphthalene-2, 6-diyl group, or a 1, 3-dioxane-2,5-diyl group, these groups may be unsubstituted or substituted with one or more of L²'s, and in a case where a plurality of each of A⁸³ and A⁸⁴ is present, these may be the same as or different from each other,

Z⁸³ and Z⁸⁴ each independently represent —O—, —S—, —OCH₂—, —CH₂O—, —CH₂CH₂—, —CO—, —COO—, —OCO—, —CO—S—, —S—CO—, —O—CO—O—, —CO—NH—, —NH—CO—, —SCH₂—, —CH₂S—, —CF₂O—, —OCF₂—, —CF₂S—, —SCF₂—, —CH═CH— COO—, —CH═CH—OCO—, —COO— CH═CH—, —OCO—CH═CH—, —COO— CH₂CH₂—, —OCO—CH₂CH₂—, —CH₂CH₂—COO—, —CH₂CH₂—OCO—, —COO—CH₂—, —OCO—CH₂—, —CH₂—COO—, —CH₂—OCO—, —CH═CH—, —N═N—, —CH═N—, —N═CH—, —CH═N—N═CH—, —CF═CF—, —C≡C—, or a single bond, and in a case where a plurality of each of Z⁸³ and Z⁸⁴ is present, these may be the same as or different from each other,

M⁸¹ represents a group selected from a 1, 4-phenylene group, a 1,4-cyclohexylene group, a 1,4-cyclohexenyl group, a tetrahydropyran-2,5-diyl group, a 1,3-dioxane-2,5-diyl group, a tetrahydrothiopyran-2,5-diyl group, a 1, 4-bicyclo(2, 2,2)octylene group, a decahydronaphthalene-2,6-diyl group, a pyridine-2,5-diyl group, a pyrimidine-2,5-diyl group, a pyrazine-2,5-diyl group, a thiophene-2,5-diyl group, a 1,2,3, 4-tetrahydronaphthalene-2, 6-diyl group, a naphthylene-1,4-diyl group, a naphthylene-1, 5-diyl group, a naphthylene-1,6-diyl group, a naphthylene-2,6-diyl group, a phenanthrene-2, 7-diyl group, a 9, 10-dihydrophenanthrene-2, 7-diyl group, a 1,2,3,4,4a, 9,10a-octahydrophenanthrene-2,7-diyl group, a benzo[1,2-b:4,5-b′]dithiophene-2,6-diyl group, a benzo[1,2-b:4,5-b′]diselenophene-2,6-diyl group, a [1]benzothieno[3,2-b]thiophene-2,7-diyl group, a [1]benzoselenopheno[3, 2-b]selenophene-2, 7-diyl group, and a fluorene-2,7-diyl group, and these groups may be unsubstituted or substituted with one or more of L²'s,

L² represents a fluorine atom, a chlorine atom, a bromine atom, an iodine atom, a pentafluorosulfuranyl group, a nitro group, an isocyano group, an amino group, a hydroxyl group, a mercapto group, a methylamino group, a dimethylamino group, a diethylamino group, a diisopropylamino group, a trimethylsilyl group, a dimethylsilyl group, a thioisocyano group, or a linear or branched alkyl group having 1 to 20 carbon atoms in which one —CH₂— or two or more (—CH₂—)'s which are not adjacent to each other may be each independently substituted with —O—, —S—, —CO—, —COO—, —OCO—, —CO—S—, —S—CO—, —O—CO—O—, —CO—NH—, —NH—CO—, —CH═CH—COO—, —CH═CH—CO—, —COO—CH═CH—, —OCO—CH═CH—, —CH═CH—, —CF═CF—, or —C≡C—, and one or more of arbitrary hydrogen atoms may be substituted with a fluorine atom, and j83 and j84 each independently represent an integer of 0 to 5, provided that j83+j84 represents an integer of 1 to 5.)

Further, General Formulae (2) to (7) are represented by General Formula (2-a), General Formula (2-b), General Formula (3-a), General Formula (3-b), General Formula (4-a), General Formula (4-b), General Formula (5-a), General Formula (5-b), General Formula (6-a), General Formula (6-b), General Formula (7-a), or General Formula (7-b).

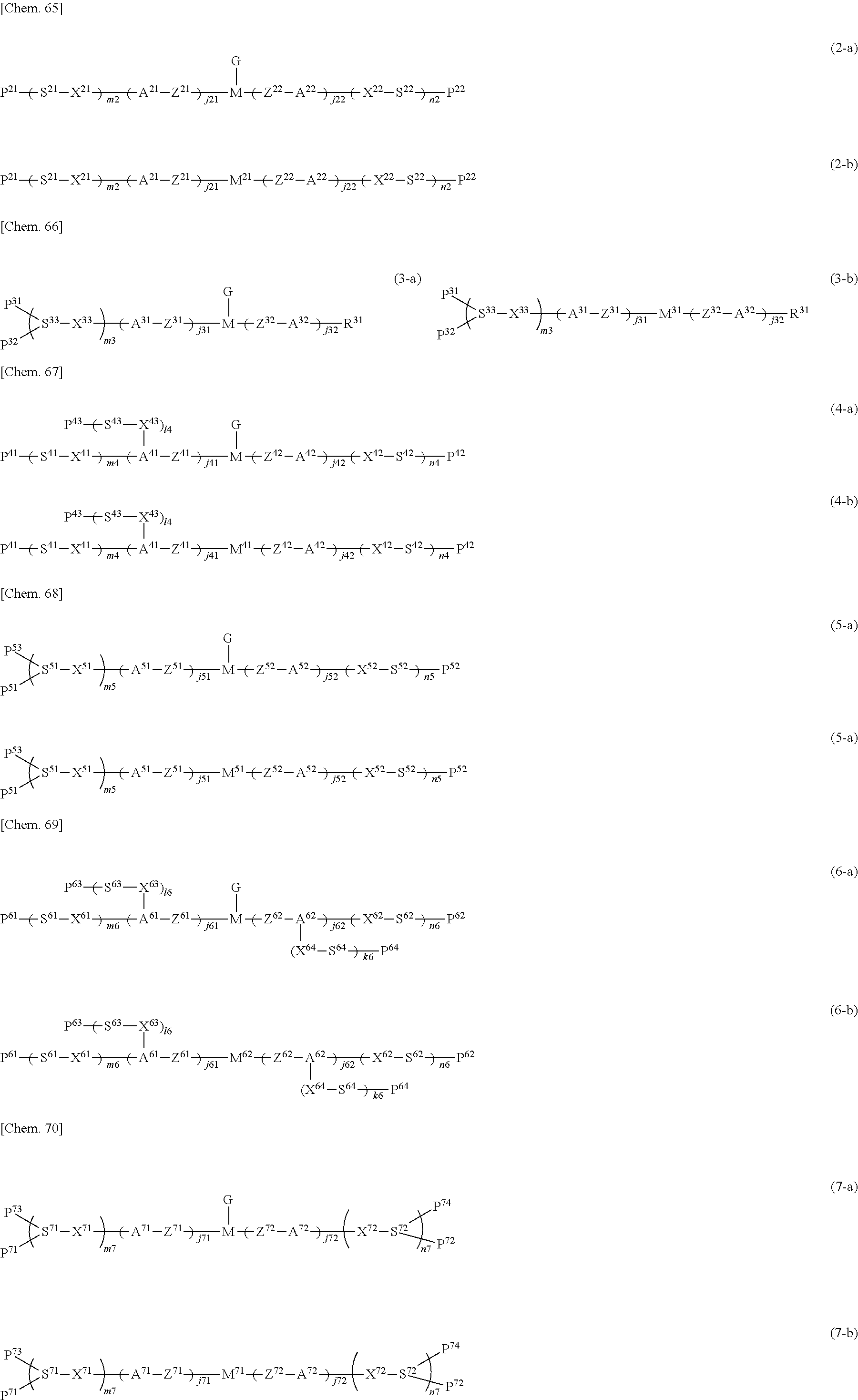

In General Formula (2-a), General Formula (2-b), General Formula (3-a), General Formula (3-b), General Formula (4-a), General Formula (4-b), General Formula (5-a), General Formula (5-b), General Formula (6-a), General Formula (6-b), General Formula (7-a), or General Formula (7-b), it is preferable that polymerizable groups P²¹ to P⁷⁴ each independently represent a group represented by any of Formulae (P-1) to (P-20).

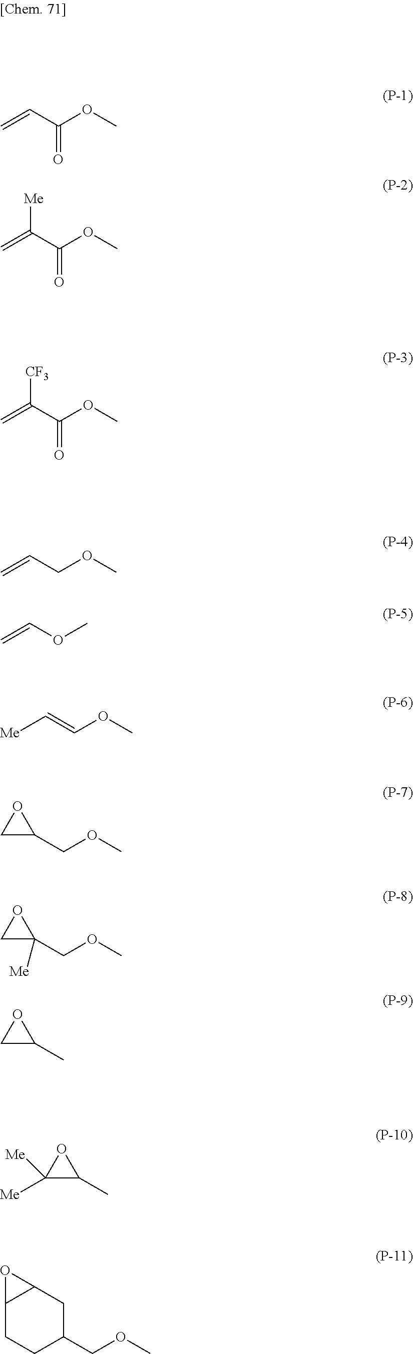

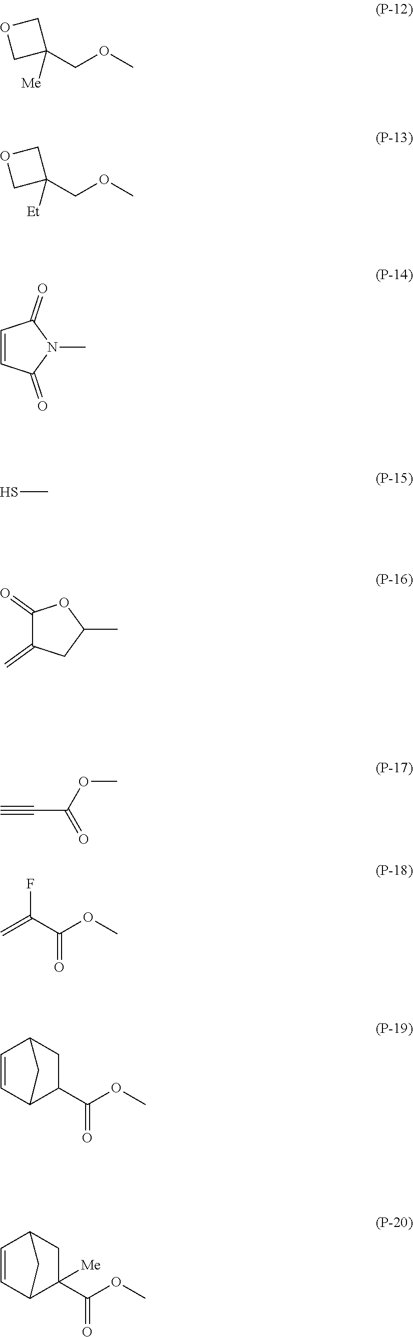

Among these polymerizable groups, from the viewpoint of improving polymerization properties and storage stability, a group represented by Formula (P-1), (P-2), (P-7), (P-12), or (P-13) is preferable and a group represented by Formula (P-1), (P-7), or (P-12) is more preferable.

In General Formula (2-a), General Formula (2-b), General Formula (3-a), General Formula (3-b), General Formula (4-a), General Formula (4-b), General Formula (5-a), General Formula (5-b), General Formula (6-a), General Formula (6-b), General Formula (7-a), or General Formula (7-b), S²¹ to S⁷² represent a spacer group or a single bond, and in a case where a plurality of each S²¹ to S⁷² is present, these may be the same as or different from each other. Further, the spacer group as S²¹ to S⁷² is an alkylene group having 1 to 18 carbon atoms, the alkylene group may be substituted with one or more halogen atoms, a CN group, an alkyl group having 1 to 8 carbon atoms, or an alkyl group having a polymerizable functional group and 1 to 8 carbon atoms, and one —CH₂— or two or more (—CH₂—)'s which are not adjacent to each other in this group may be each independently substituted with —O—, —S—, —NH—, —N(CH₃)—, —CO—, —CH(OH)—, CH(COOH), —COO—, —OCO—, —OCOO—, —SCO—, —COS—C≡C—, or a group represented by Formula (S-1) or (S-2) in the form in which oxygen atoms are not directly bonded to each other.

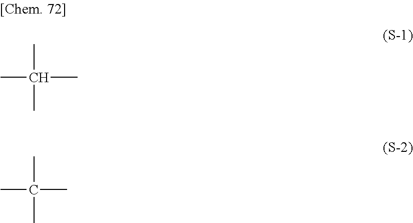

Among these spacer groups, from the viewpoint of alignment properties, a linear alkylene group having 2 to 8 carbon atoms, an alkylene group having 2 to 6 carbon atoms which is substituted with a fluorine atom, and an alkylene group having 5 to 14 carbon atoms in which a part thereof is substituted with —O— are preferable.

In General Formula (2-a), General Formula (2-b), General Formula (3-a), General Formula (3-b), General Formula (4-a), General Formula (4-b), General Formula (5-a), General Formula (5-b), General Formula (6-a), General Formula (6-b), General Formula (7-a), or General Formula (7-b), X²¹ to X⁷² each independently represent —O—, —S—, —OCH₂—, —CH₂O—, —CO—, —COO—, —CO—, —CO—S—, —S—CO—, —O—CO—O—, —CO—NH—, —NH—CO—, —SCH₂—, —CH₂S—, —CF₂O—, —OCF₂—, —CF₂S—, —SCF₂—, —CH═CH—COO—, —CH═CH—OCO—, —COO—CH═CH—, —OCO—CH═CH—, —COO— CH₂CH₂—, —OCO—CH₂CH₂—, —CH₂CH₂—COO—, —CH₂CH₂—OCO—, —COO—CH₂—, —OCO—CH₂—, —CH₂—COO—, —CH₂—OCO—, —CH═CH—, —N═N—, —CH═N—N═CH—, —CF═CF—, —C≡C—, or a single bond, and in a case where a plurality of each of X²¹ to X⁷² is present, these may be the same as or different from each other, provided that P— (S—X)— does not have a —O—O— bond.

From the viewpoints of easily obtaining raw materials and ease of synthesis, in a case where a plurality of each of X²¹ to X⁷² is present, these may be the same as or different from each other, it is preferable that X²¹ to X⁷² each independently represent —O—, —S—, —OCH₂—, —CH₂O—, —COO—, —OCO—, —CO—S—, —S—CO—, —O—CO—O—, —CO—NH—, —NH—CO—, —COO—CH₂CH₂—, —OCO—CH₂CH₂—, —CH₂CH₂—COO—, —CH₂CH₂—OCO—, or a single bond, more preferable that X²¹ to X⁷² each independently represent —O—, —OCH₂—, —CH₂—, —COO—, —OCO—, —COO—CH₂CH₂—, —OCO— CH₂CH₂—, —CH₂CH₂—COO—, —CH₂CH₂—OCO—, or a single bond, and in a case where a plurality of each of X²¹ to X⁷² is present, these may be the same as or different from each other, and it is particularly preferable that X²¹ to X⁷² each independently represent —O—, —COO—, —OCO—, or a single bond.

In General Formula (2-a), General Formula (2-b), General Formula (3-a), General Formula (3-b), General Formula (4-a), General Formula (4-b), General Formula (5-a), General Formula (5-b), General Formula (6-a), General Formula (6-b), General Formula (7-a), or General Formula (7-b), A²¹ to A⁷² each independently represent a 1,4-phenylene group, a 1, 4-cyclohexylene group, a pyridine-2,5-diyl group, a pyrimidine-2,5-diyl group, a naphthalene-2,6-diyl group, a naphthalene-1, 4-diyl group, a tetrahydronaphthalene-2, 6-diyl group, a decahydronaphthalene-2, 6-diyl group, or a 1, 3-dioxane-2,5-diyl group, these groups may be unsubstituted or substituted with one or more of L's, and in a case where a plurality of each of A²¹ to A⁷² is present, these may be the same as or different from each other. From the viewpoints of easily obtaining raw materials and ease of synthesis, it is preferable that A²¹ to A⁷² each independently represent a 1, 4-phenylene group, a 1,4-cyclohexylene group, or a naphthalene-2, 6-diyl group which may be unsubstituted or substituted with one or more of L²'s and more preferable that A²¹ to A⁷² each independently represent a group selected from groups represented by Formulae (A-1) to (A-11).

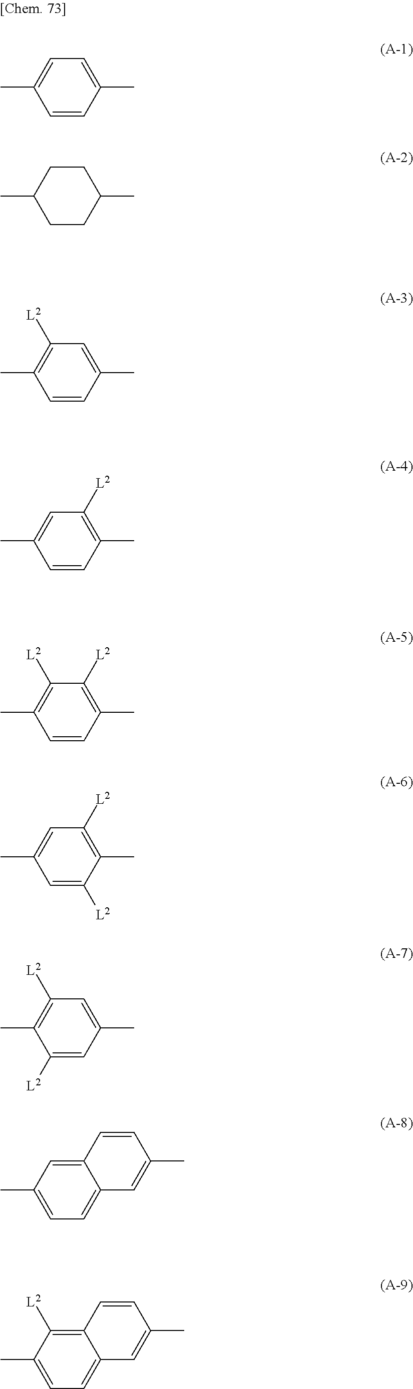

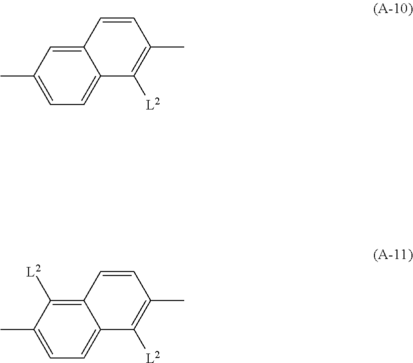

It is still more preferable that A²¹ to A⁷² each independently represent a group selected from groups represented by Formulae (A-1) to (A-8) and particularly preferable that A²¹ to A⁷² each independently represent a group selected from groups represented by Formulae (A-1) to (A-4).

In General Formula (2-a), General Formula (2-b), General Formula (3-a), General Formula (3-b), General Formula (4-a), General Formula (4-b), General Formula (5-a), General Formula (5-b), General Formula (6-a), General Formula (6-b), General Formula (7-a), or General Formula (7-b), Z²¹ and Z⁷² each independently represent —O—, —S—, —OCH₂—, —CH₂O—, —CH₂CH₂—, —CO—, —COO—, —OCO—, —CO—S—, —S—CO—, —O—CO—O—, —CO—NH—, —NH—CO—, —OCO—NH—, —NH—COO—, —NH—CO—NH—, —NH—O—, —O—NH—, —SCH₂—, —CH₂S—, —CF₂O—, —OCF₂—, —CF₂S—, —SCF₂—, —CH═CH—COO—, —CH═CH—OCO—, —COO—CH═CH—, —OCO—CH═CH—, —COO—CH₂CH—, —OCO—CH₂CH₂—, —CH₂CH₂—COO—, —CH₂CH₂—OCO—, —COO—CH₂—, —OCO—CH₂—, —CH₂—COO—, —CH—OCO—, —CH═CH—, —N═N—, —CH═N—, —N═CH—, —CH═N—N═CH—, —CF═CF—, —C≡C—, or a single bond, and in a case where a plurality of each of Z²¹ to Z⁷² is present, these may be the same as or different from each other. From the viewpoints of liquid crystallinity of the compound, easily obtaining raw materials, and ease of synthesis, it is preferable that Z²¹ to Z⁷² each independently represent a single bond, —OCH₂—, —CH₂O—, —COO—, —OCO—, —CF₂O—, —OCF₂—, —CF₂CF₂—, —CF₂CF₂—, —CH═CH—COO—, —CH═CH—OCO—, —COO—CH═CH—, —OCO—CH═CH—, —COO—CH₂CH₂—, —OCO—CH₂CH₂—, —CH₂CH₂—COO—, —CH₂CH₂—OCO—, —CH═CH—, —CF═CF—, —C≡C—, or a single bond, more preferable that Z²¹ to Z⁷² each independently represent —OCH₂—, —CH₂O—, —CH₂CH₂—, —COO—, —OCO—, —COO—CH₂CH₂—, —OCO—CH₂CH₂—, —CH₂CH₂—COO—, —CH₂CH₂—OCO—, —CH═CH—, —C≡C—, or a single bond, still more preferable that Z²¹ to Z⁷² each independently represent —CH₂CH₂—, —COO—, —OCO—, —COO— CH₂CH₂—, —OCO—CH₂CH₂—, —CH₂CH₂—COO—, —CH₂CH₂—OCO—, or a single bond, and particularly preferable that Z²¹ to Z⁷² each independently represent —CH₂CH₂—, —COO—, —OCO—, or a single bond.

In Formula (3-a) and Formula (3-b), R³¹ represents a hydrogen atom, a fluorine atom, a chlorine atom, a bromine atom, an iodine atom, a pentafluorosulfuranyl group, a cyano group, a nitro group, an isocyano group, a thioisocyano group, or a linear or branched alkyl group having 1 to 20 carbon atoms in which one —CH₂— or two or more (—CH₂—)'s which are not adjacent to each other may be each independently substituted with —O—, —S—, —CO—, —COO—, —OCO—, —CO—S—, —S—CO—, —O—CO—O—, —CO—NH—, —NH—CO—, or —C≡C—, and one or more of arbitrary hydrogen atoms in the alkyl group may be substituted with a fluorine atom. From the viewpoints of liquid crystallinity and ease of synthesis, it is preferable that R³¹ represents a hydrogen atom, a fluorine atom, a chlorine atom, a cyano group, or a linear or branched alkyl group having 1 to 12 carbon atoms in which one —CH₂— or two or more (—CH₂—)'s which are not adjacent to each other may be each independently substituted with —O—, —COO—, —OCO—, or —O—CO—O—, more preferable that R³¹ represents a hydrogen atom, a fluorine atom, a chlorine atom, a cyano group, or a linear alkyl group or linear alkoxy group having 1 to 12 carbon atoms, and particularly preferable that R³¹ represents a linear alkyl group or linear alkoxy group having 1 to 12 carbon atoms.

In General Formula (2-a), General Formula (3-a), General Formula (4-a), General Formula (5-a), General Formula (6-a), and General Formula (7-a), N represents a group represented by any of Formulae (M-1) to (M-11)

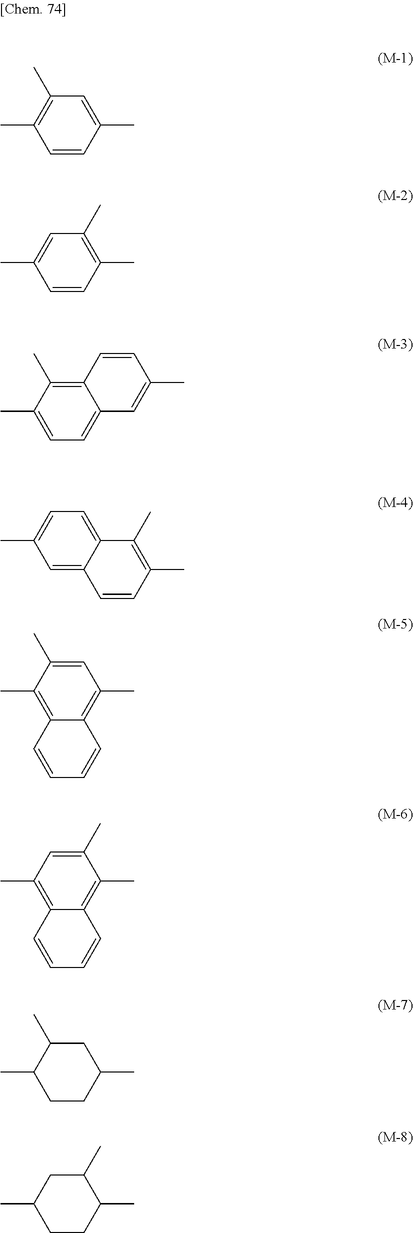

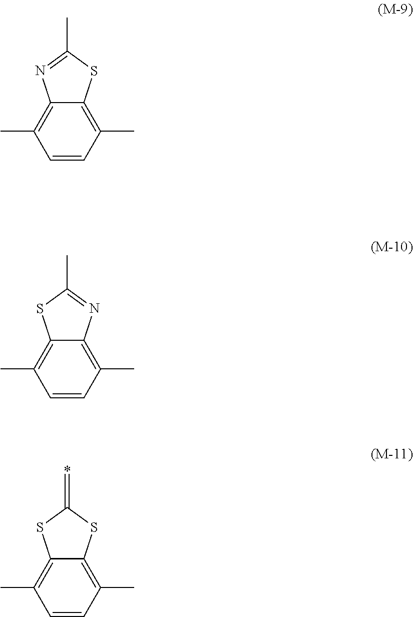

These groups may be unsubstituted or substituted with one or more of L²'s. From the viewpoints of easily obtaining raw materials and ease of synthesis, it is preferable that M's each independently represent a group selected from groups represented by Formula (M-1) and Formula (M-2) which may be unsubstituted or substituted with one or more of L²'s and groups represented by Formulae (M-3) to (M-6) which may be unsubstituted, more preferable that M's each independently represent a group selected from groups represented by Formula (M-1) and Formula (M-2) which may be unsubstituted or substituted with one or more of L²'s, and particularly preferable that M's each independently represent a group selected from groups represented by Formula (M-1) and Formula (M-2) which may be unsubstituted.

In General Formula (2-a), General Formula (3-a), General Formula (4-a), General Formula (5-a), General Formula (6-a), and General Formula (7-a), G represents a group selected from groups represented by Formulae (G-1) to (G-6)

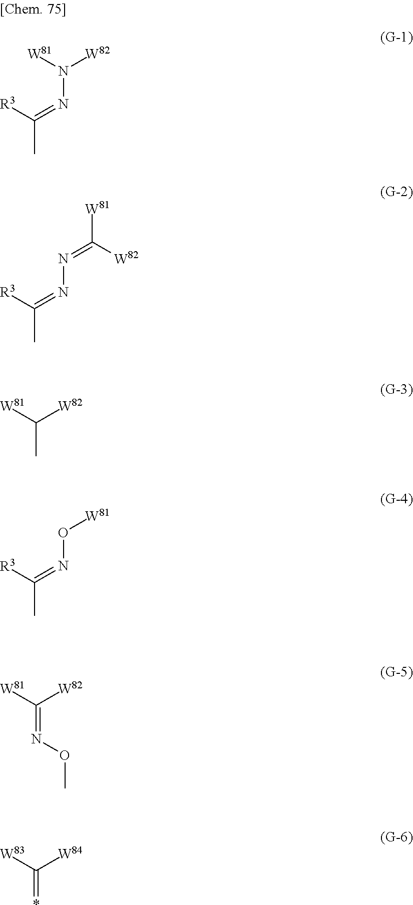

In the formulae, R³ represents a hydrogen atom or an alkyl group having 1 to 20 carbon atoms, the alkyl group may be linear or branched, one or more of arbitrary hydrogen atoms in the alkyl group may be substituted with a fluorine atom, and one —CH₂— or two or more (—CH₂—)'s which are not adjacent to each other in the alkyl group may be each independently substituted with —O—, —S—, —CO—, —COO—, —OCO—, —CO—S—, —S—CO—, —O—CO—O—, —CO—NH—, —NH—CO—, or —C≡C—,

W⁸¹ represents a group having at least one aromatic group and 5 to 30 carbon atoms and the group may be unsubstituted or substituted with one or more of L²'s,

W⁸² represents a hydrogen atom or an alkyl group having 1 to 20 carbon atoms, the alkyl group may be linear or branched, one or more of arbitrary hydrogen atoms in the alkyl group may be substituted with a fluorine atom, one —CH₂— or two or more (—CH₂—)'s which are not adjacent to each other in the alkyl group may be each independently substituted with —O—, —S—, —CO—, —COO—, —OCO—, —CO—S—, —S—CO—, —O—CO—O—, —CO—NH—, —NH—CO—, —CH═CH—COO—, —CH═CH—OCO—, —COO—CH═CH—, —OCO—CH═CH—, —CH═CH—, —CF═CF—, or —C≡C—, W⁸² may have the same definition as that for W⁸¹, W⁸¹ and W⁸² may be linked to each other to form the same ring structure, and W⁸² represents a group represented by the following formula.

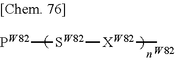

(In the formula, P^{W82} has the same definition as that for P¹¹, S^{W82} has the same definition as that for S¹¹, X^{W82} has the same definition as that for X¹¹, and n^{W82} has the same definition as that for k.)

W⁸³ and W⁸⁴ each independently represent a halogen atom, a cyano group, a hydroxy group, a nitro group, a carboxyl group, a carbamoyloxy group, an amino group, a sulfamoyl group, a group having at least one aromatic group and 5 to 30 carbon atoms, an alkyl group having 1 to 20 carbon atoms, a cycloalkyl group having 3 to 20 carbon atoms, an alkenyl group having 2 to 20 carbon atoms, a cycloalkenyl group having 3 to 20 carbon atoms, an alkoxy group having 1 to 20 carbon atoms, an acyloxy group having 2 to 20 carbon atoms, or an alkylcarbonyloxy group having 2 to 20 carbon atoms, one —CH₂— or two or more (—CH₂—)'s which are not adjacent to each other in the alkyl group, the cycloalkyl group, the alkenyl group, the cycloalkenyl group, the alkoxy group, the acyloxy group, and the alkylcarbonyloxy group may be each independently substituted with —O—, —S—, —CO—, —COO—, —OCO—, —CO—S—, —S—CO—, —O—CO—O—, —CO—NH—, —NH—CO—, or —C≡C—.

The aromatic group included in the group represented by W⁸¹ may be an aromatic hydrocarbon group or an aromatic heterocyclic group and the group may include both of an aromatic hydrocarbon group and an aromatic heterocyclic group. These aromatic groups may be bonded to each other through a single bond or a linking group (—OCO—, —COO—, —CO—, or —O—) and may form a fused ring. Further, in addition to an aromatic group, the group represented by W⁸¹ may further have an acyclic structure and/or a cyclic structure other than the aromatic group. From the viewpoints of easily obtaining raw materials and ease of synthesis, it is preferable that the aromatic group included in the group represented by W⁸¹ is a group represented by any of Formulae (W-1) to (W-19) which may be unsubstituted or substituted with one or more of L²'s.

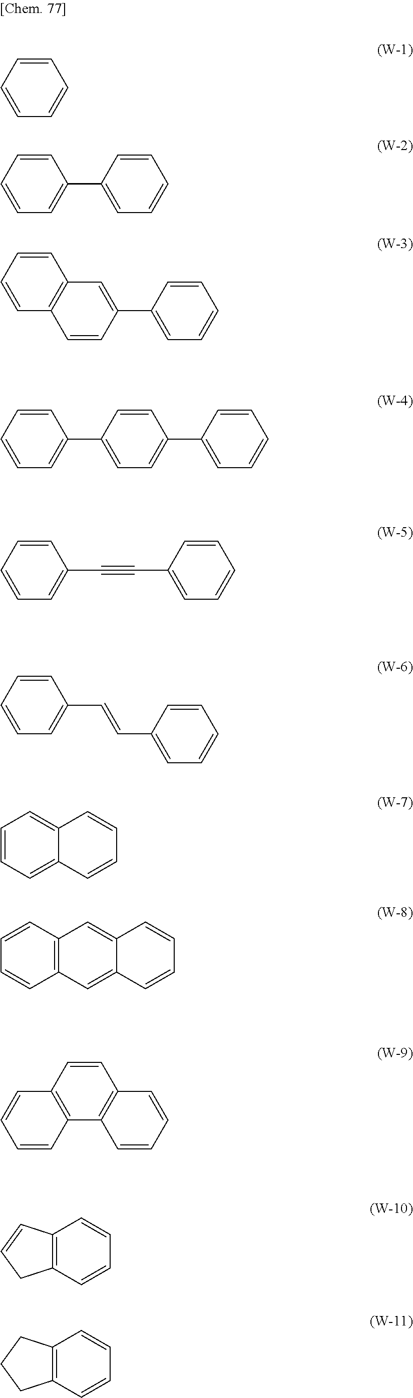

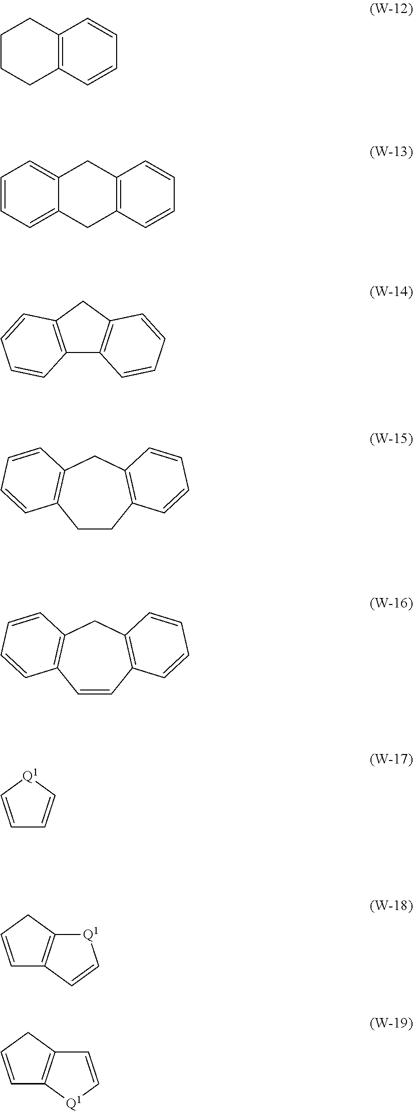

(In the formulae, these groups may have a binding site at an arbitrary position, a group formed by linking two or more aromatic groups selected from these groups with a single bond may be formed, and Q¹ represents —O—, —S—, —NR⁵— (in the formula, R⁵ represents a hydrogen atom or an alkyl group having 1 to 8 carbon atoms), or —CO—. (—CH═)'s in these aromatic groups may be each independently substituted with —N═, (—CH₂—)'s may be each independently substituted with —O—, —S—, —NR⁴—(in the formula, R⁴ represents a hydrogen atom or an alkyl group having 1 to 8 carbon atoms), or —CO— and does not have a —O—O— bond.)

It is preferable that the group represented by Formula (W-1) is a group selected from groups represented by Formulae (W-1-1) to (W-1-8) which may be unsubstituted or substituted with one or more of L²'s.

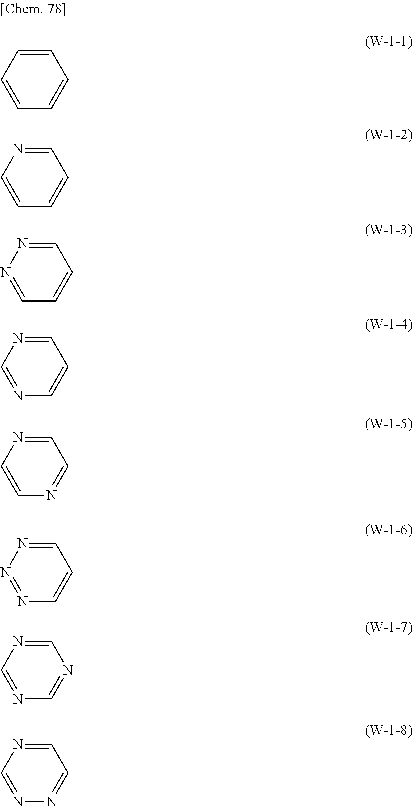

(In the formulae, these groups may have a binding site at an arbitrary position.)

It is preferable that the group represented by Formula (W-7) is a group selected from groups represented by Formulae (W-7-1) to (W-7-7) which may be unsubstituted or substituted with one or more of L²'s.

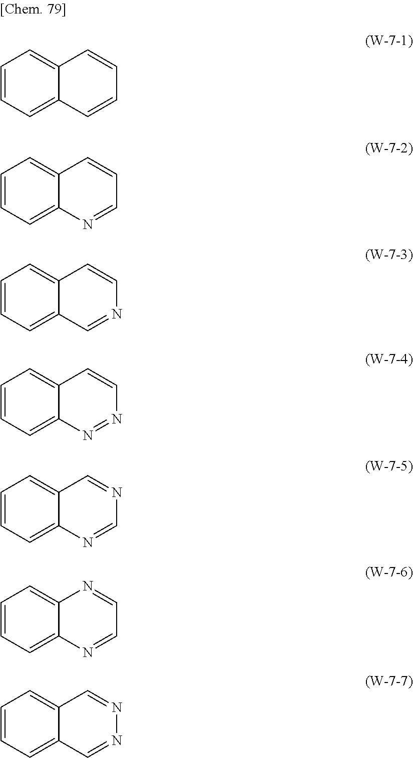

(In the formulae, these groups may have a binding site at an arbitrary position.)

It is preferable that the group represented by Formula (W-10) is a group selected from groups represented by Formulae (W-10-1) to (W-10-8) which may be unsubstituted or substituted with one or more of L²'s.

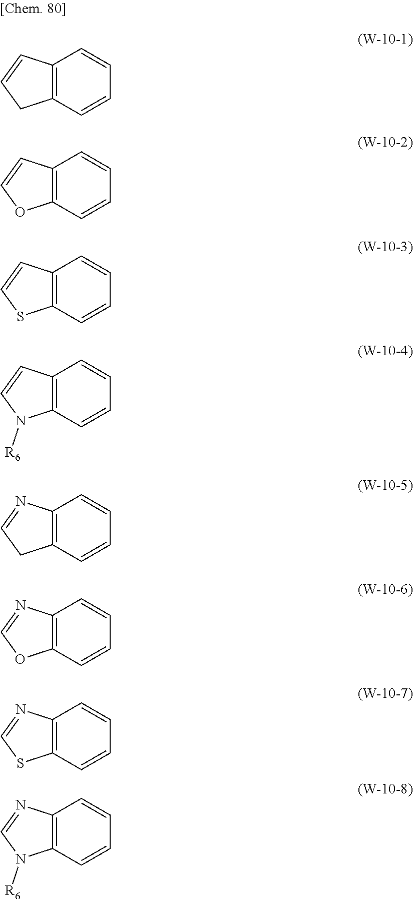

(In the formulae, these groups may have a binding site at an arbitrary position and R⁶ represents a hydrogen atom or an alkyl group having 1 to 8 carbon atoms.)

It is preferable that the group represented by Formula (W-11) is a group selected from groups represented by Formulae (W-11-1) to (W-11-13) which may be unsubstituted or substituted with one or more of L²'s.

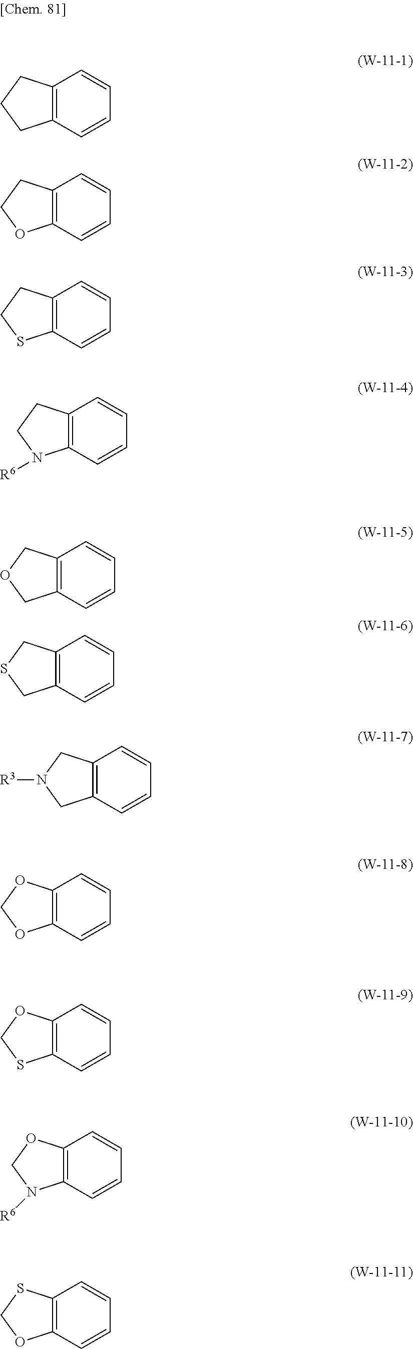

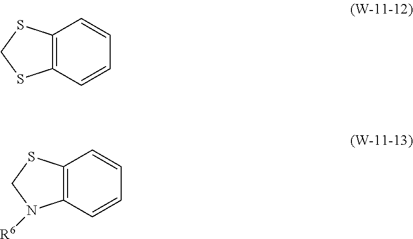

(In the formulae, these groups may have a binding site at an arbitrary position and R⁶ represents a hydrogen atom or an alkyl group having 1 to 8 carbon atoms.)

It is preferable that the group represented by Formula (W-12) is a group selected from groups represented by Formulae (W-12-1) to (W-12-19) which may be unsubstituted or substituted with one or more of L²'s.

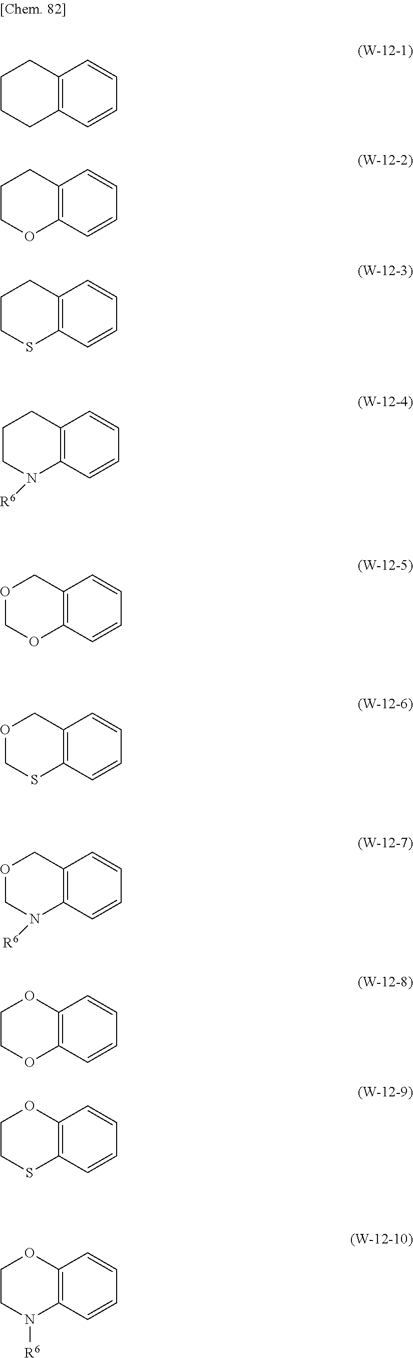

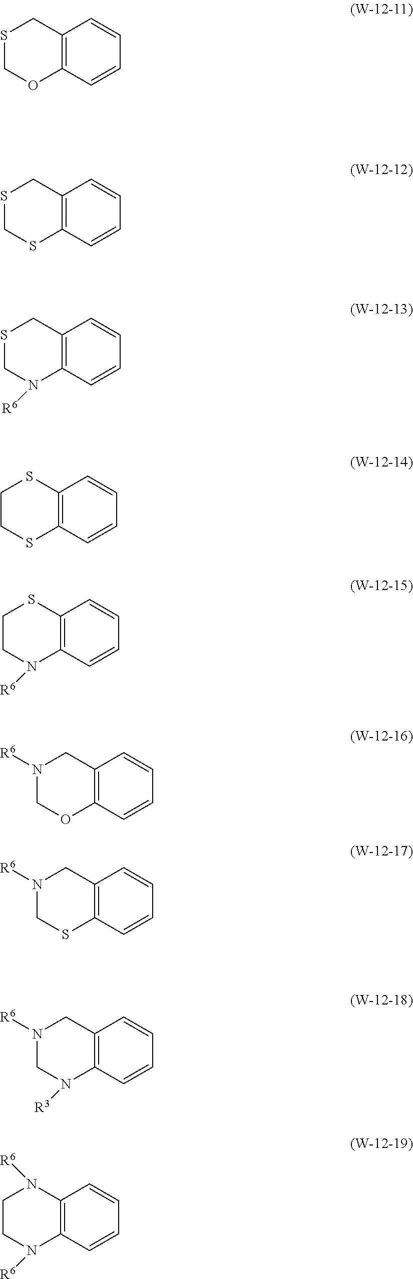

(In the formulae, these groups may have a binding site at an arbitrary position, R⁶ represents a hydrogen atom or an alkyl group having 1 to 8 carbon atoms, and in a case where a plurality of R⁶ is present, these may be the same as or different from each other.)

It is preferable that the group represented by Formula (W-13) is a group selected from groups represented by Formulae (W-13-1) to (W-13-10) which may be unsubstituted or substituted with one or more of L²'s.

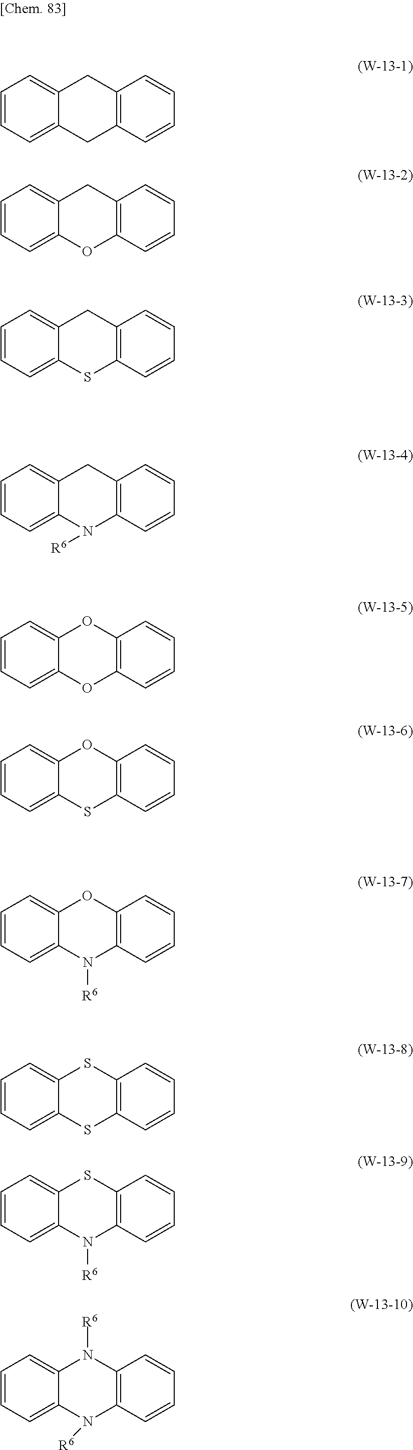

(In the formulae, these groups may have a binding site at an arbitrary position, R⁶ represents a hydrogen atom or an alkyl group having 1 to 8 carbon atoms, and in a case where a plurality of R⁶ is present, these may be the same as or different from each other.)

It is preferable that the group represented by Formula (W-14) is a group selected from groups represented by Formulae (W-14-1) to (W-14-4) which may be unsubstituted or substituted with one or more of L's.

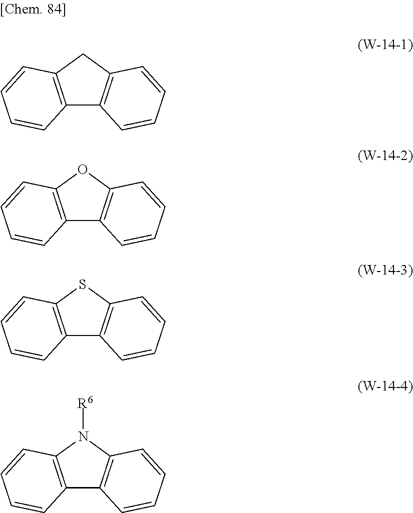

(In the formulae, these groups may have a binding site at an arbitrary position and R⁶ represents a hydrogen atom or an alkyl group having 1 to 8 carbon atoms.)

It is preferable that the group represented by Formula (W-15) is a group selected from groups represented by Formulae (W-15-1) to (W-15-18) which may be unsubstituted or substituted with one or more of L²'s.

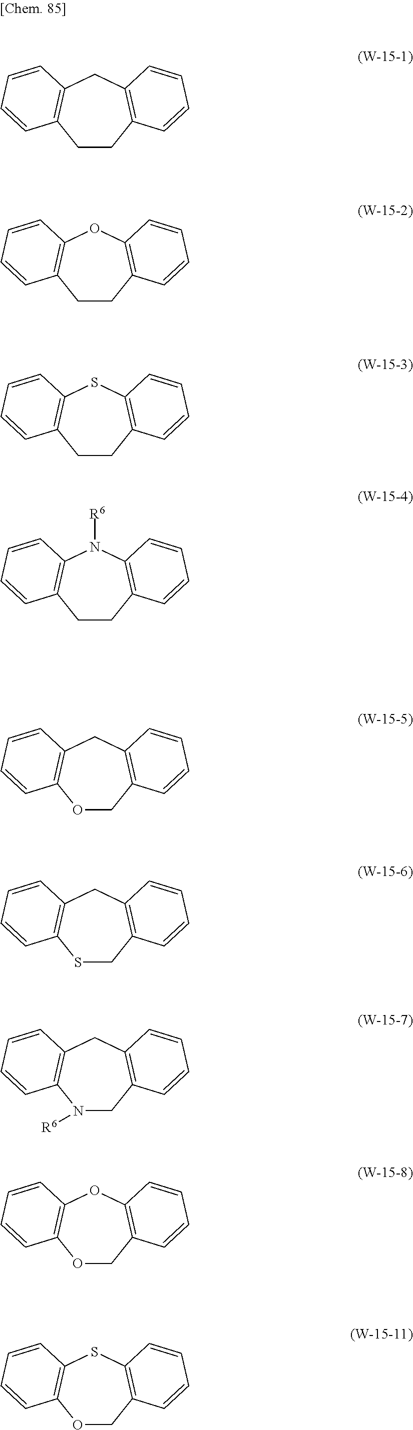

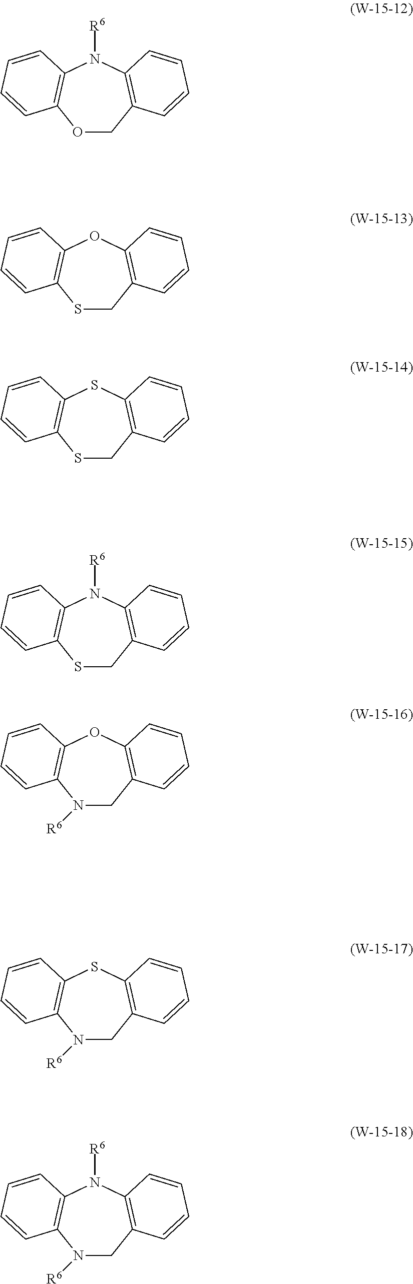

(In the formulae, these groups may have a binding site at an arbitrary position, R⁶ represents a hydrogen atom or an alkyl group having 1 to 8 carbon atoms, and in a case where a plurality of R⁶ is present, these may be the same as or different from each other.)

It is referable that the group represented by Formula (W-16) is a group selected from groups represented by Formulae (W-16-1) to (W-16-4) which may be unsubstituted or substituted with one or more of L²'s.

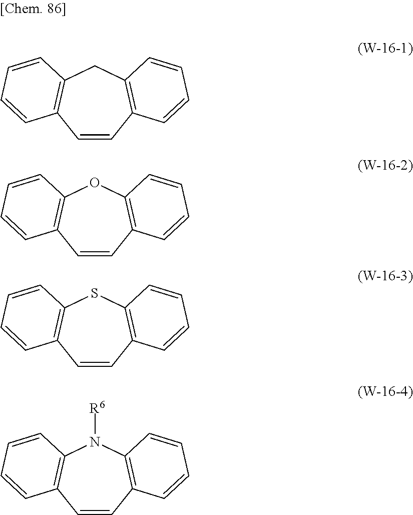

(In the formulae, these groups may have a binding site at an arbitrary position and R⁶ represents a hydrogen atom or an alkyl group having 1 to 8 carbon atoms.)

It is preferable that the group represented by Formula (W-17) is a group selected from groups represented by Formulae (W-17-1) to (W-17-6) which may be unsubstituted or substituted with one or more of L²'s.

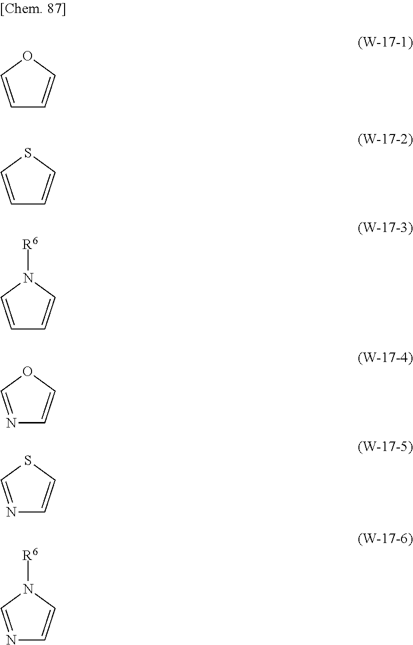

(In the formulae, these groups may have a binding site at an arbitrary position and R⁶ represents a hydrogen atom or an alkyl group having 1 to 8 carbon atoms.)

It is preferable that the group represented by Formula (W-18) is a group selected from groups represented by Formulae (W-18-1) to (W-18-6) which may be unsubstituted or substituted with one or more of L¹'s.

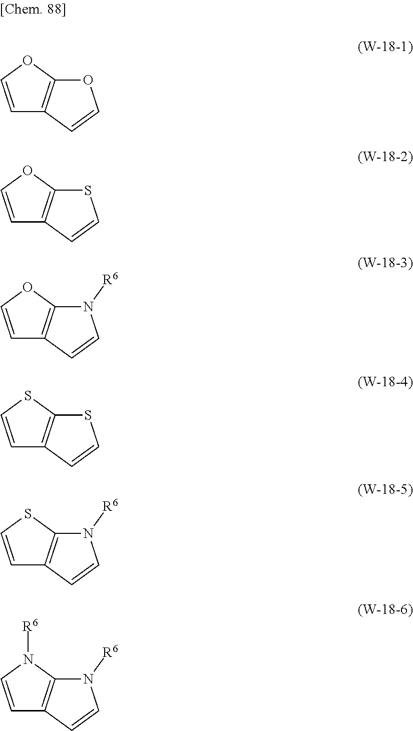

(In the formulae, these groups may have a binding site at an arbitrary position, R⁶ represents a hydrogen atom or an alkyl group having 1 to 8 carbon atoms, and in a case where a plurality of R⁶ is present, these may be the same as or different from each other.)

It is preferable that the group represented by Formula (W-19) is a group selected from groups represented by Formulae (W-19-1) to (W-19-9) which may be unsubstituted or substituted with one or more of L²'s.

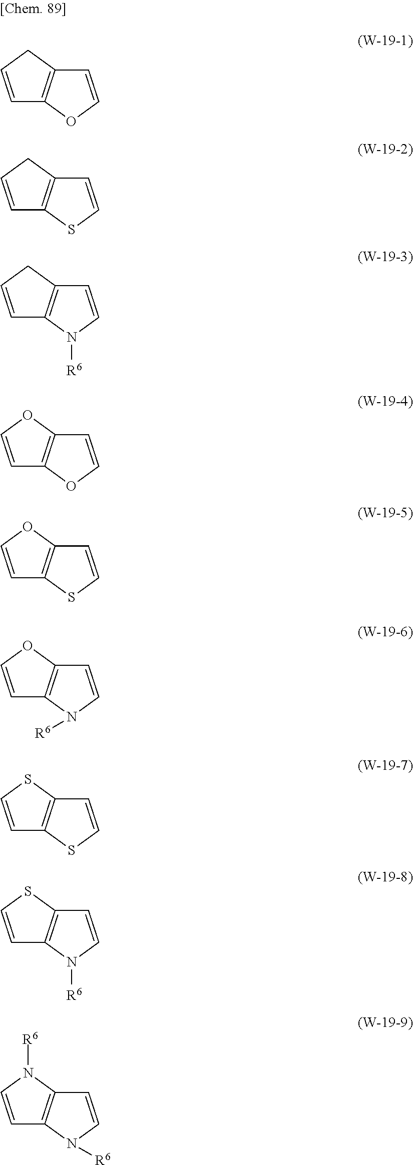

(In the formulae, these groups may have a binding site at an arbitrary position, R⁶ represents a hydrogen atom or an alkyl group having 1 to 8 carbon atoms, and in a case where a plurality of R⁶ is present, these may be the same as or different from each other.)

It is more preferable that the aromatic group included in the group represented by W⁸¹ is a group selected from groups represented by Formulae (W-1-1), (W-7-1), (W-7-2), (W-7-7), (W-8), (W-10-6), (W-10-7), (W-10-8), (W-11-8), (W-11-9), (W-11-10), (W-11-11), (W-11-12), and (W-11-13) which may be unsubstituted or substituted with one or more of L²'s and particularly preferable that the aromatic group included in the group represented by W⁸¹ is a group selected from groups represented by Formulae (W-1-1), (W-7-1), (W-7-2), (W-7-7), (W-10-6), (W-10-7), and (W-10-8) which may be unsubstituted or substituted with one or more of L's. Further, it is particularly preferable that W⁸¹ represents a group selected from groups represented by Formulae (W-a-1) to (W-a-6)

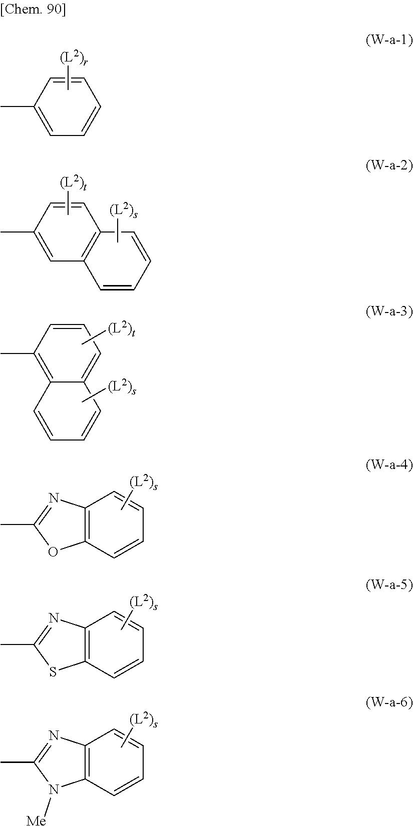

(In the formulae, r represents an integer of 0 to 5, s represents an integer of 0 to 4, and t represents an integer of 0 to 3.)

W⁸² represents a hydrogen atom or a linear or branched alkyl group having 1 to 20 carbon atoms in which one —CH₂— or two or more (—CH₂—)'s which are not adjacent to each other may be each independently substituted with —O—, —S—, —CO—, —COO—, —CO—, —CO—S—, —S—CO—, —O—CO—O—, —CO—NH—, —NH—CO—, —CH═CH—COO—, —CH═CH—OCO—, —COO—CH═CH—, —OCO—CH═CH—, —CH═CH—, —CF═CF—, or —C≡C—, one or more of arbitrary hydrogen atoms in the alkyl group may be substituted with a fluorine atom, W⁸² may have the same definition as that for W⁸¹, W⁸¹ and W⁸² may be linked to each other to form a ring structure, and W⁸² represents a group represented by the following formula.

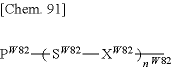

(In the formula, P^{W82} has the same definition as that for P¹¹, S^{W82} has the same definition as that for S¹¹, X^{W82} has the same definition as that for X¹¹, and n^{W82} has the same definition as that for k.)

From the viewpoints of easily obtaining raw materials and ease of synthesis, it is preferable that W⁸² represents a hydrogen atom or a linear or branched alkyl group having 1 to 20 carbon atoms in which one or more of arbitrary hydrogen atoms may be substituted with a fluorine atom and one —CH₂— or two or more (—CH₂—)'s which are not adjacent to each other may be each independently substituted with —O—, —CO—, —COO—, —OCO—, —CH═CH—COO—, —OCO—CH═CH—, —CH═CH—, —CF═CF—, or —C≡C— or W⁸² represents a group represented by the following formula.

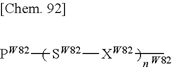

(In the formula, P^{W82} has the same definition as that for P¹¹, S^{W82} has the same definition as that for S¹¹, X^{W82} has the same definition as that for X¹¹, and n^{W82} has the same definition as that for k.)

It is more preferable that W represents a hydrogen atom or a linear or branched alkyl group having 1 to 20 carbon atoms, in which one —CH₂— or two or more (—CH₂—)'s which are not adjacent to each other may be each independently substituted with —O— or W⁸² represents a group represented by the following formula.

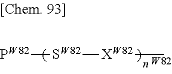

In the formula, P^{W82} has the same definition as that for P¹¹, S^{W82} has the same definition as that for S¹¹, X^{W82} has the same definition as that for X¹¹, and n^{W82} has the same definition as that for k.)

It is particularly preferable that W⁸² represents a hydrogen atom or a linear or branched alkyl group having 1 to 20 carbon atoms, in which one —CH₂— or two or more (—CH₂—)'s which are not adjacent to each other may be each independently substituted with —O— or W⁸² represents a group represented by the following formula.

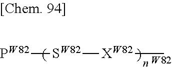

(in the formula, P^{W82} has the same definition as that for P¹¹, S^{W82} has the same definition as that for S¹¹, X^{W82} has the same definition as that for X¹¹, and n^{W82} has the same definition as that for k.)

Further, in a case where W⁸² has the same definition as that for W⁸¹, W⁸² and W⁸¹ may be the same as or different from each other and preferable groups as W⁸² are the same as those for W⁸¹. Further, in a case where W⁸¹ and W⁸² are linked to each other to form a ring structure, it is preferable that the cyclic group represented by —NW⁸¹W⁸² is a group selected from groups represented by Formulae (W-b-1) to (W-b-42) which may be unsubstituted or substituted with one or more of L²'s.

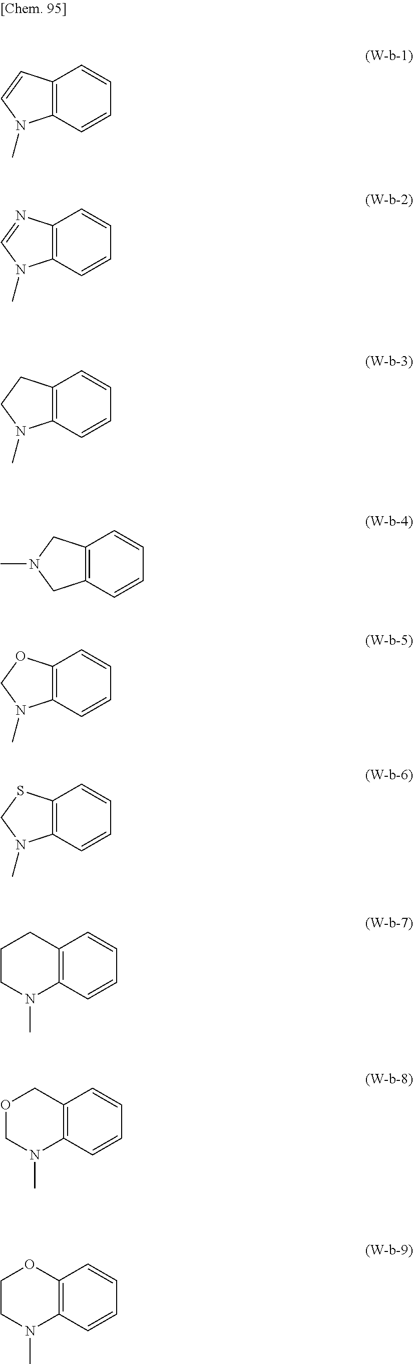

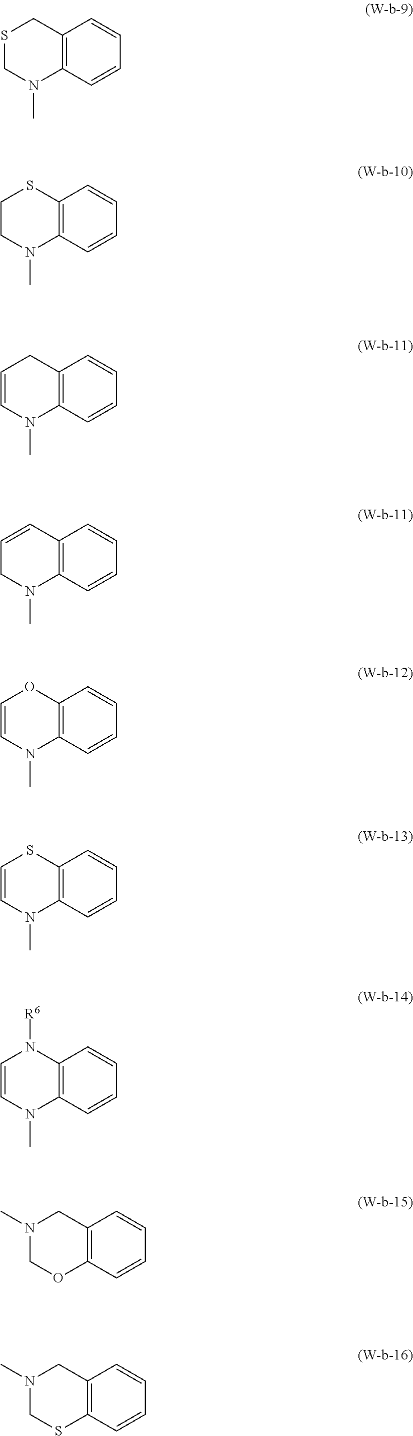

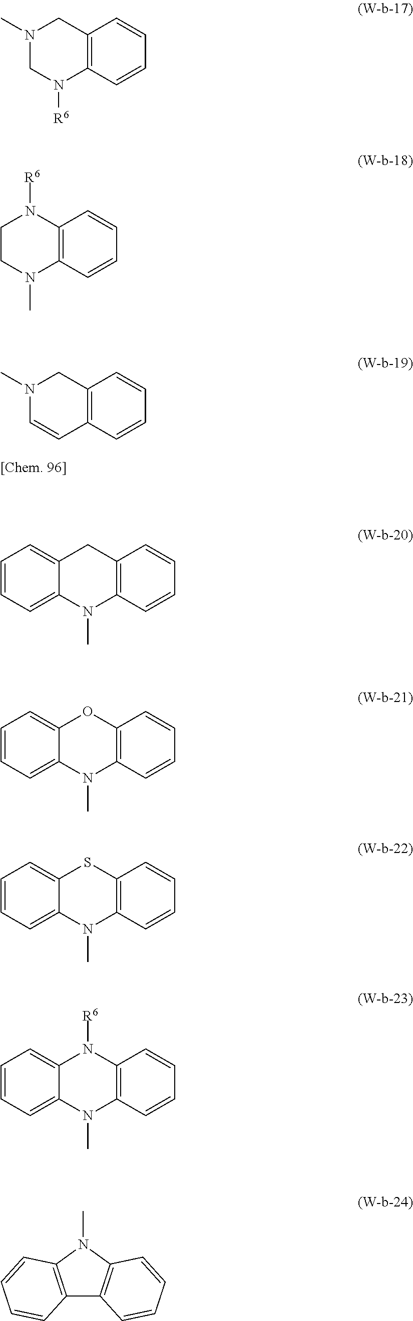

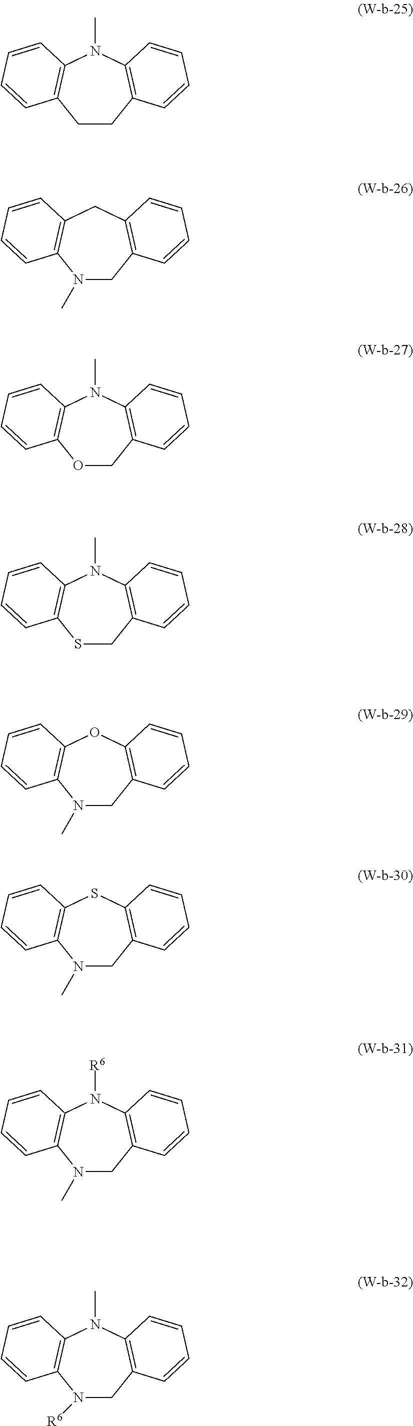

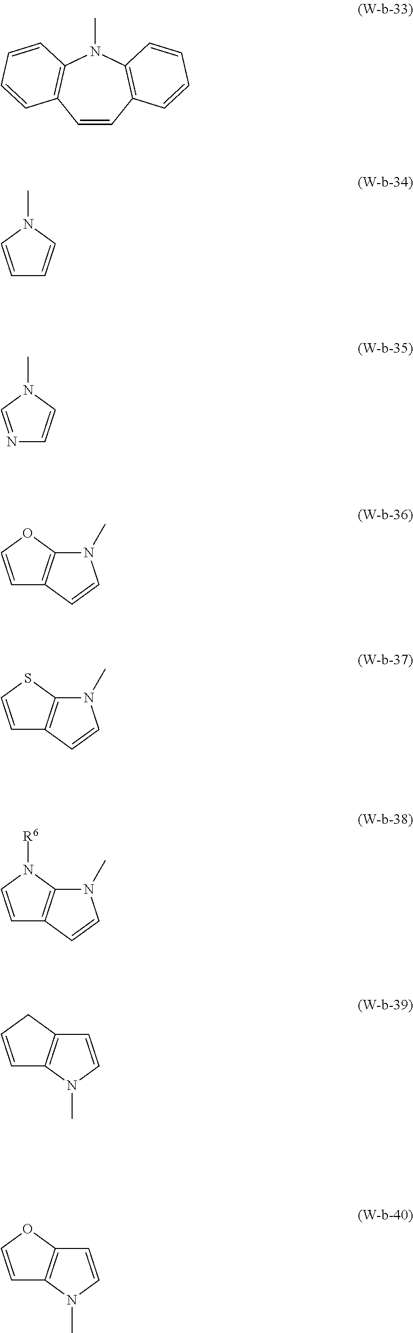

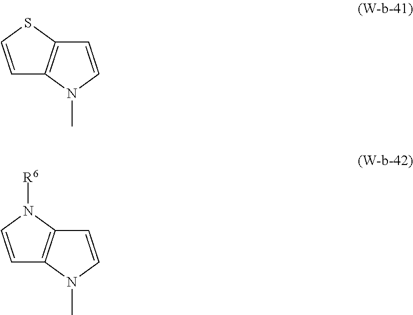

(in the formulae, R⁶ represents a hydrogen atom or an alkyl group having 1 to 8 carbon atoms.)

From the viewpoints of easily obtaining raw materials and ease of synthesis, it is particularly preferable that the cyclic group represented by —NW⁸¹W⁸² is a group selected from groups represented by Formulae (W-b-20), (W-b-21), (W-b-22), (W-b-23), (W-b-24), (W-b-25), and (W-b-33) which may be unsubstituted or substituted with one or more of L²'s.

Further, it is preferable that the cyclic group represented by ═CW⁸¹W⁸² is a group selected from groups represented by Formulae (W-c-1) to (W-c-81) which may be unsubstituted or substituted with one or more of L²'s.

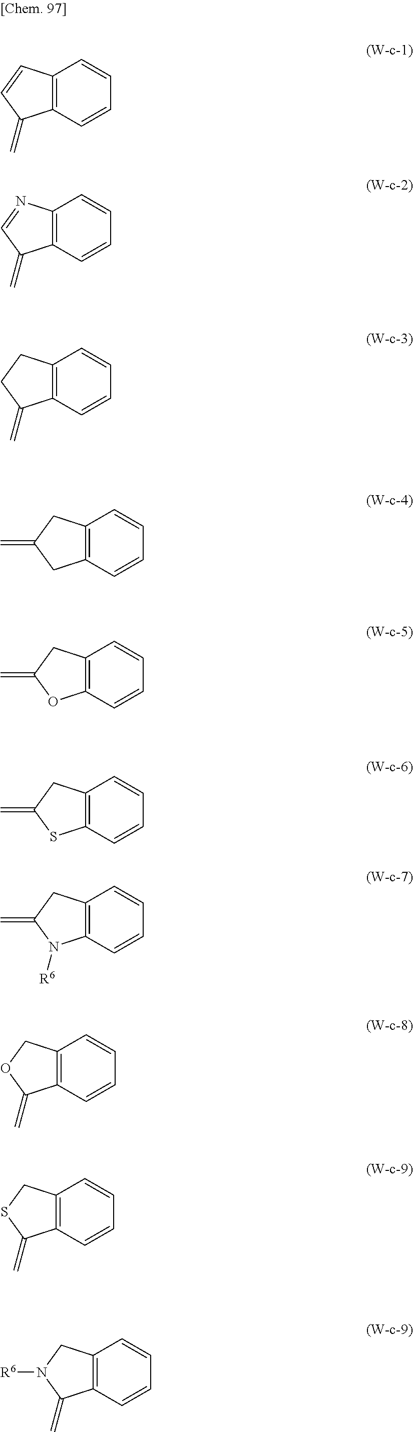

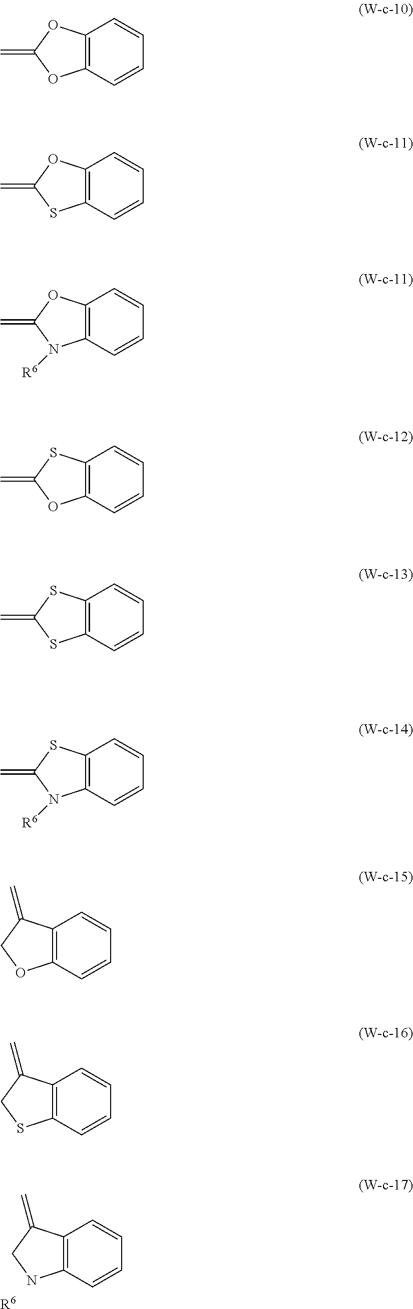

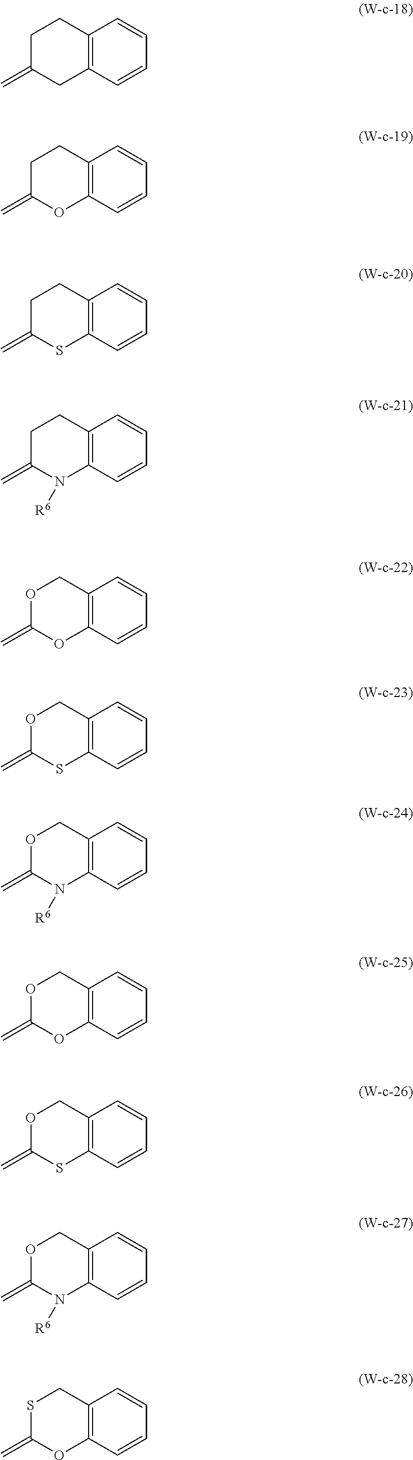

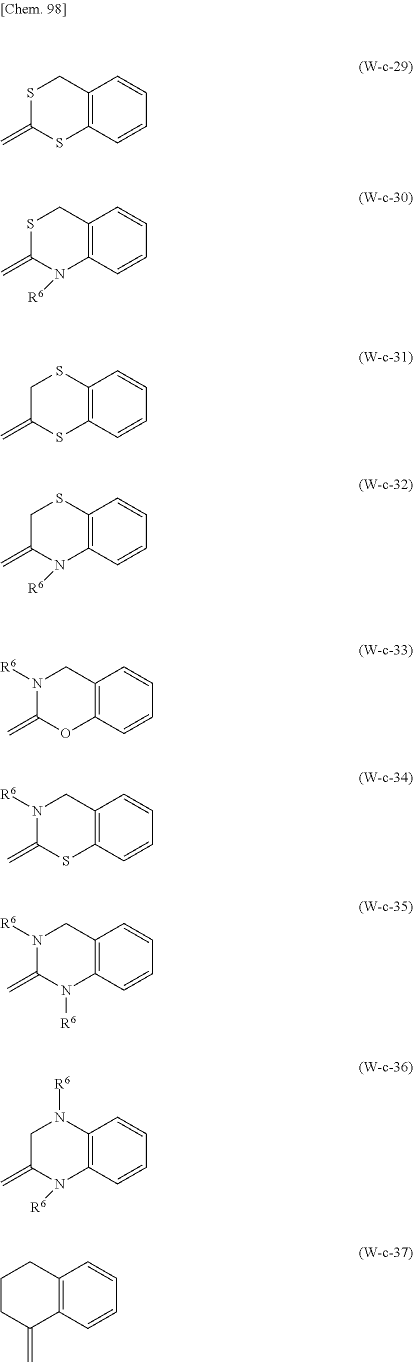

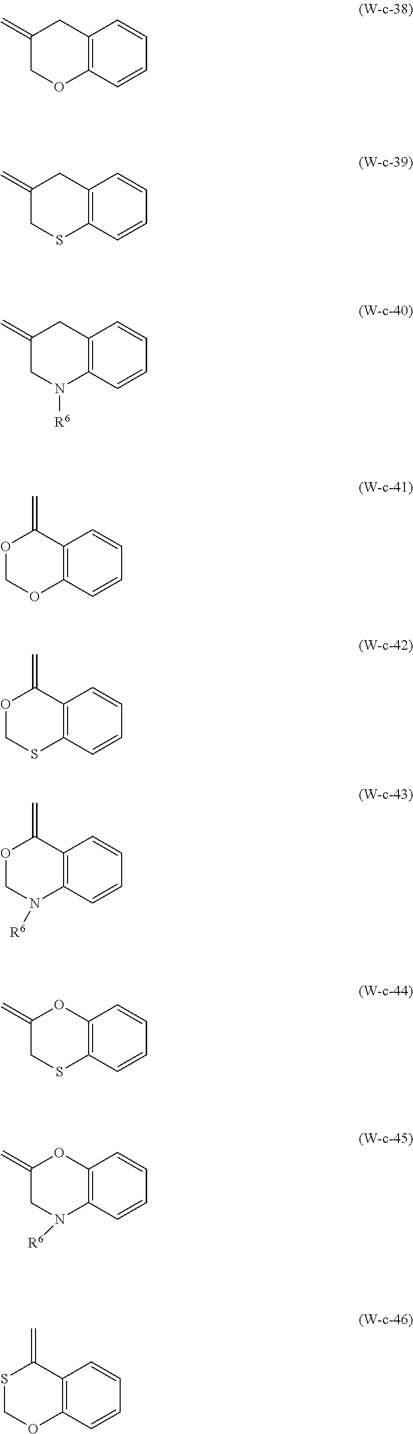

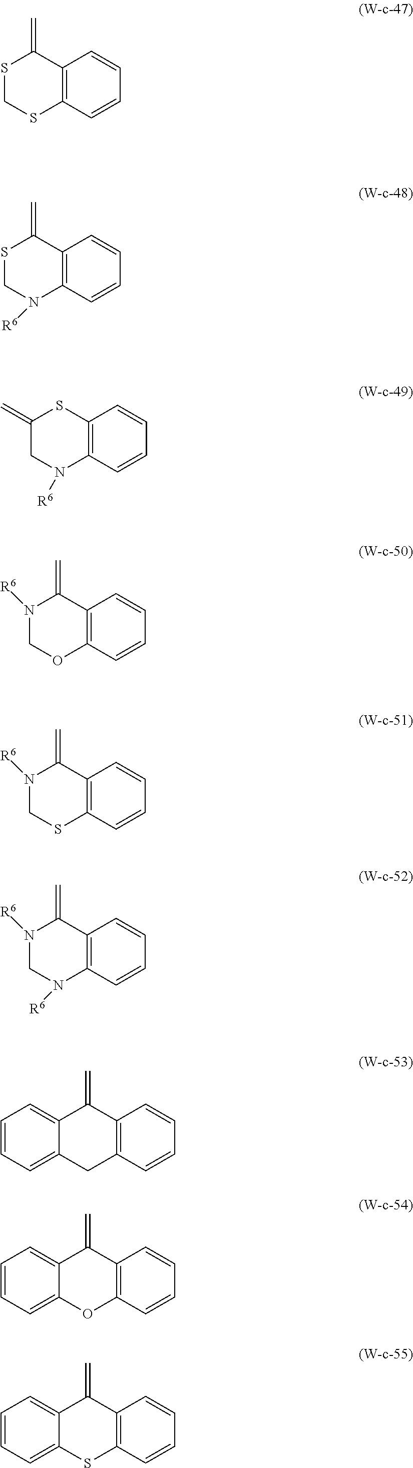

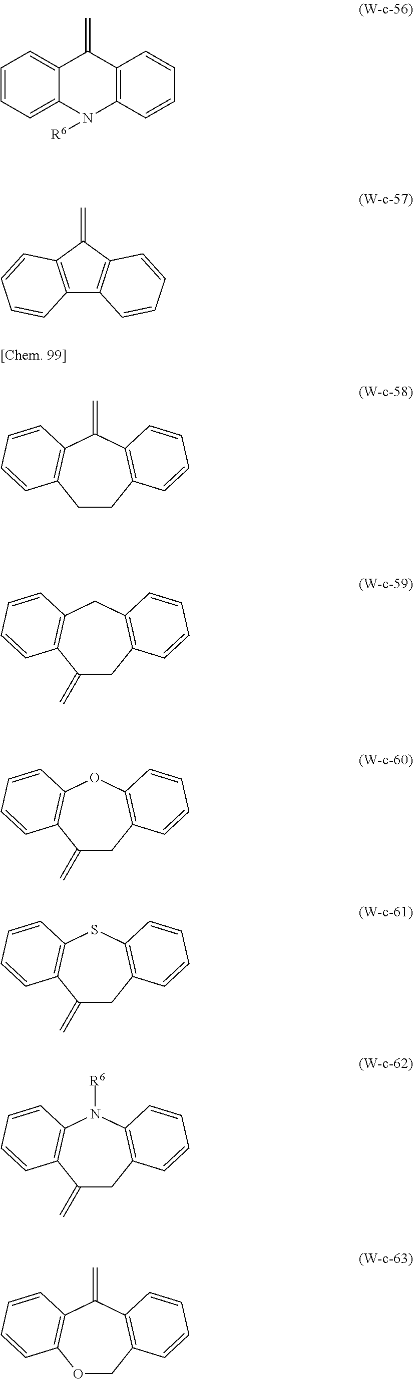

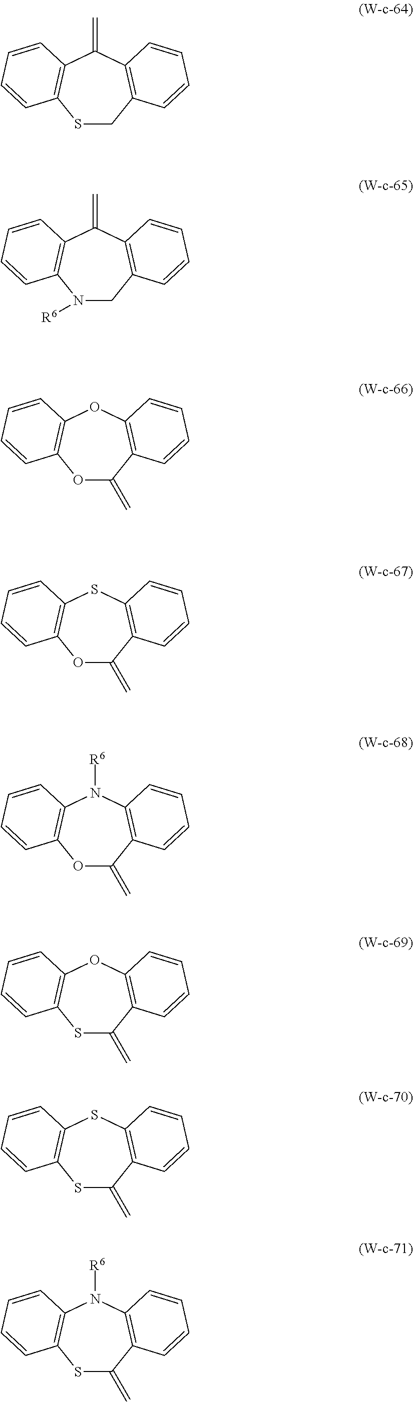

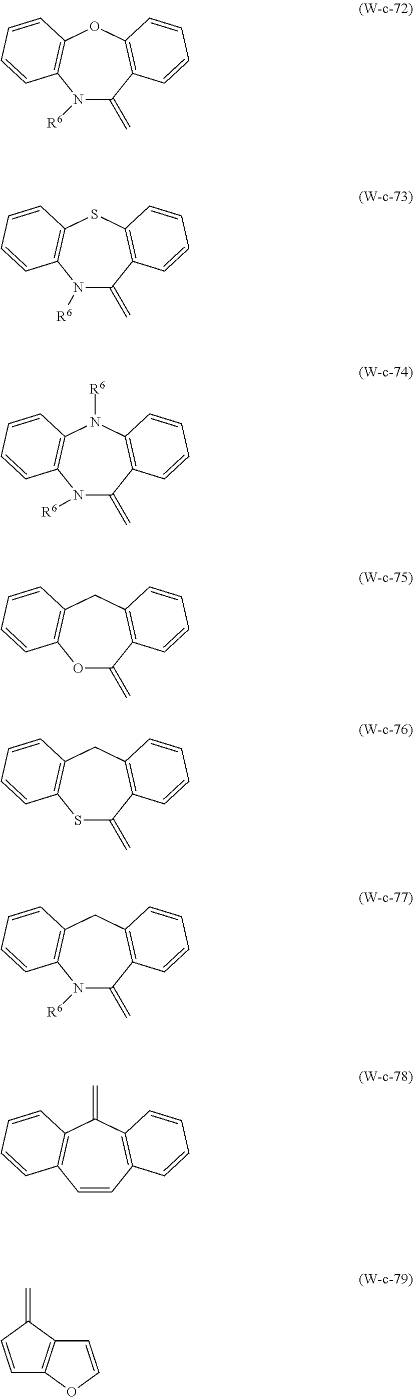

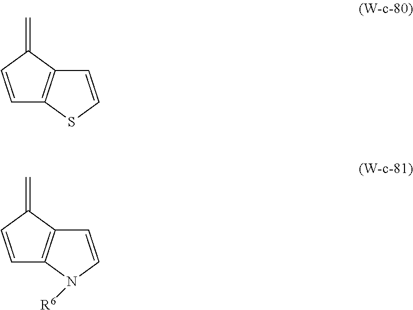

(In the formulae, R⁶ represents a hydrogen atom or an alkyl group having 1 to 8 carbon atoms, and in a case where a plurality of R⁶ is present, these may be the same as or different from each other.)

From the viewpoints of easily obtaining raw materials and ease of synthesis, it is particularly preferable that the cyclic group represented by ═CW⁸¹W⁸² is a group selected from groups represented by Formulae (W-c-11), (W-c-12), (W-c-13), (W-c-14), (W-c-53), (W-c-54), (W-c-55), (W-c-56), (W-c-57), and (W-c-78) which may be unsubstituted or substituted with one or more of L's.

In a case where W⁸² represents a group represented by the following formula, preferable groups as P^{W82} are the same as those for P¹¹.

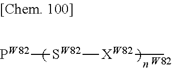

Further, preferable groups as S^{W82} are the same as those for S¹¹, preferable groups as X^{W82} are the same as those for X¹¹, and preferable groups as n^{W82} are the same as those for k.

The total number of π electrons included in the group represented by W⁸¹ and W⁸² is preferably 4 to 24 from the viewpoints of wavelength dispersion characteristics, storage stability, liquid crystallinity, and ease of synthesis.

W⁸³ and W⁸⁴ each independently represent a halogen atom, a cyano group, a hydroxy group, a nitro group, a carboxyl group, a carbamoyloxy group, an amino group, a sulfamoyl group, a group having at least one aromatic group and 5 to 30 carbon atoms, an alkyl group having 1 to 20 carbon atoms, a cycloalkyl group having 3 to 20 carbon atoms, an alkenyl group having 2 to 20 carbon atoms, a cycloalkenyl group having 3 to 20 carbon atoms, an alkoxy group having 1 to 20 carbon atoms, an acyloxy group having 2 to 20 carbon atoms, or an alkylcarbonyloxy group having 2 to 20 carbon atoms, one —CH₂— or two or more (—CH₂—)'s which are not adjacent to each other in the alkyl group, the cycloalkyl group, the alkenyl group, the cycloalkenyl group, the alkoxy group, the acyloxy group, and the alkylcarbonyloxy group may be each independently substituted with —O—, —S—, —CO—, —COO—, —OCO—, —CO—S—, —S—CO—, —O—CO—O—, —CO—NH—, —NH—CO—, or —C≡C—, it is more preferable that W⁸³ represents a group selected from a cyano group, a nitro group, a carboxyl group, and an alkyl group having 1 to 20 carbon atoms, an alkenyl group, an acyloxy group, and an alkylcarbonyloxy group in which one —CH₂— or two or more (—CH₂—)'s which are not adjacent to each other may be each independently substituted with —O—, —S—, —CO—, —COO—, —OCO—, —CO—S—, —S—CO—, —O—CO—O—, —CO—NH—, —NH—CO—, or —C≡C— and particularly preferable that W⁸³ represents a group selected from a cyano group, a carboxyl group, and an alkyl group having 1 to 20 carbon atoms, an alkenyl group, an acyloxy group, and an alkylcarbonyloxy group in which one —CH₂— or two or more (—CH₂—)'s which are not adjacent to each other may be each independently substituted with —CO—, —COO—, —OCO—, —O—CO—O—, —CO—NH—, —NH—CO—, or —C≡C—, and it is more preferable that W⁸⁴ represents a group selected from a cyano group, a nitro group, a carboxy group, and an alkyl group having 1 to 20 carbon atoms, an alkenyl group, an acyloxy group, and an alkylcarbonyloxy group in which one —CH₂— or two or more (—CH₂—)'s which are not adjacent to each other may be each independently substituted with —O—, —S—, —CO—, —COO—, —OCO—, —CO—S—, —S—CO—, —O—CO—O—, —CO—NH—, —NH—CO—, or —C≡C— and particularly preferable that W⁸⁴ represents a group selected from a cyano group, a carboxyl group, and an alkyl group having 1 to 20 carbon atoms, an alkenyl group, an acyloxy group, and an alkyl carbonyloxy group in which one —CH₂— or two or more (—CH₂—)'s which are not adjacent to each other may be each independently substituted with —CO—, —COO—, —OCO—, —O—CO—O—, —CO—NH—, —NH—CO—, or —C≡C—.

L² represents a fluorine atom, a chlorine atom, a bromine atom, an iodine atom, a pentafluorosulfuranyl group, a nitro group, an isocyano group, an amino group, a hydroxyl group, a mercapto group, a methylamino group, a dimethylamino group, a diethylamino group, a diisopropylamino group, a trimethylsilyl group, a dimethylsilyl group, a thioisocyano group, or a linear or branched alkyl group having 1 to 20 carbon atoms in which one —CH₂— or two or more (—CH₂—)'s which are not adjacent to each other may be each independently substituted with —O—, —S—, —CO—, —COO—, —OCO—, —CO—S—, —S—CO—, —O—CO—O—, —CO—NH—, —NH—CO—, —CH═CH—COO—, —CH═CH—OCO—, —COO—CH═CH—, —OCO—CH═CH—, —CH═CH—, —CF═CF—, or —C≡C—, and one or more of arbitrary hydrogen atoms in the alkyl group may be substituted with a fluorine atom. From the view-points of liquid crystallinity and ease of synthesis, it is preferable that L represents a fluorine atom, a chlorine atom, a pentafluorosulfuranyl group, a nitro group, a methylamino group, a dimethylamino group, a diethylamino group, a diisopropylamino group, a linear or branched alkyl group having 1 to 20 carbon atoms in which one or more of arbitrary hydrogen atoms may be substituted with a fluorine atom and one —CH₂— or two or more (—CH₂—)'s which are not adjacent to each other may be each independently substituted with a group selected from —O—, —S—, —CO— —COO—, —OCO—, —O—C—O—, —CH═CH—, —CF═CF—, and —C≡C—, or a group represented by Formula (1-c), more preferable that that L represents a fluorine atom, a chlorine atom, or a linear or branched alkyl group having 1 to 12 carbon atoms in which one or more of arbitrary hydrogen atoms may be substituted with a fluorine atom and one —CH₂— or two or more (—CH₂—)'s which are not adjacent to each other may be each independently substituted with a group selected from —O—, —COO—, and —OCO—, still more preferable that L¹ represents a fluorine atom, a chlorine atom, or a linear or branched alkyl group or alkoxy group having 1 to 12 carbon atoms in which one or more of arbitrary hydrogen atoms may be substituted with a fluorine atom, and particularly preferable that L² represents a fluorine atom, a chlorine atom, or a linear alkyl group or a linear alkoxy group having 1 to 8 carbon atoms.

In General Formula (2-b), General Formula (3-b), General Formula (4-b), General Formula (5-b), General Formula (6-b), and General Formula (7-b), M²¹ to M⁷¹ represent a group selected from a 1,4-phenylene group, a 1,4-cyclohexylene group, a 1,4-cyclohexenyl group, a tetrahydropyran-2,5-diyl group, a 1, 3-dioxane-2,5-diyl group, a tetrahydrothiopyran-2,5-diyl group, a 1, 4-bicyclo(2,2,2)octylene group, a decahydronaphthalene-2,6-diyl group, a pyridine-2,5-diyl group, a pyrimidine-2,5-diyl group, a pyrazine-2,5-diyl group, a thiophene-2,5-diyl group, a 1,2,3, 4-tetrahydronaphthalene-2,6-diyl group, a naphthylene-1, 4-diyl group, a naphthylene-1, 5-diyl group, a naphthylene-1,6-diyl group, a naphthylene-2,6-diyl group, a phenanthrene-2,7-diyl group, a 9, 10-dihydrophenanthrene-2,7-diyl group, a 1,2,3,4,4a,9,10a-octahydrophenanthrene-2,7-diyl group, a benzo[1, 2-b:4,5-b′]dithiophene-2,6-diyl group, a benzo[1, 2-b:4, 5-b′]diselenophene-2, 6-diyl group, a [1]benzothieno[3,2-b]thiophene-2,7-diyl group, a [1]benzoselenopheno[3, 2-b]selenophene-2,7-diyl group, and a fluorene-2,7-diyl group, and these groups may be unsubstituted or substituted with one or more of L²'s. From the viewpoints of easily obtaining raw materials and ease of synthesis, it is preferable that M²¹ to M⁷¹ each independently represent a 1, 4-phenylene group, a naphthylene-1, 4-diyl group, or a naphthylene-2, 6-diyl group which may be unsubstituted or substituted with one or more of L's and more preferable that M²¹ to M⁷¹ represent a 1,4-phenylene group which may be unsubstituted or substituted with one or more of L's.

L² represents a fluorine atom, a chlorine atom, a bromine atom, an iodine atom, a pentafluorosulfuranyl group, a nitro group, an isocyano group, an amino group, a hydroxyl group, a mercapto group, a methylamino group, a dimethylamino group, a diethylamino group, a diisopropylamino group, a trimethylsilyl group, a dimethylsilyl group, a thioisocyano group, or a linear or branched alkyl group having 1 to 20 carbon atoms in which one —CH₂— or two or more (—CH₂—)'s which are not adjacent to each other may be each independently substituted with —O—, —S—, —CO—, —COO—, —OCO—, —CO—S—, —S—CO—, —O—CO—O—, —CO—NH—, —NH—CO—, —CH═CH—COO, —CH═CH—OCO—, —COO—CH═CH—, —OCO—CH═CH—, —CH═CH—, —CF═CF—, or —C≡C—, and one or more of arbitrary hydrogen atoms in the alkyl group may be substituted with a fluorine atom. From the viewpoints of liquid crystallinity and ease of synthesis, it is preferable that L² represents a fluorine atom, a chlorine atom, a pentafluorosulfuranyl group, a nitro group, a methylamino group, a dimethylamino group, a diethylamino group, a diisopropylamino group, a linear or branched alkyl group having 1 to 20 carbon atoms in which one or more of arbitrary hydrogen atoms may be substituted with a fluorine atom and one —CH₂— or two or more (—CH₂—)'s which are not adjacent to each other may be each independently substituted with a group selected from —O—, —S—, —CO—, —COO—, —OCO—, —O—CO—O—, —CH═CH—, —CF═CF—, and —C≡C—, more preferable that that L represents a fluorine atom, a chlorine atom, or a linear or branched alkyl group having 1 to 12 carbon atoms in which one or more of arbitrary hydrogen atoms may be substituted with a fluorine atom and one —CH₂— or two or more (—CH₂—)'s which are not adjacent to each other may be each independently substituted with a group selected from —O—, —COO—, and —OCO—, still more preferable that L represents a fluorine atom, a chlorine atom, or a linear or branched alkyl group or alkoxy group having 1 to 12 carbon atoms in which one or more of arbitrary hydrogen atoms may be substituted with a fluorine atom, and particularly preferable that L represents a fluorine atom, a chlorine atom, or a linear alkyl group or a linear alkoxy group having 1 to 8 carbon atoms.

In General Formula (2-a), General Formula (2-b), General Formula (3-a), General Formula (3-b), General Formula (4-a), General Formula (4-b), General Formula (5-a), General Formula (5-b), General Formula (6-a), General Formula (6-b), General Formula (7-a), and General Formula (7-b), m2 to m7, n2 to n7, l4 to l6, and k6 each independently represent an integer of 0 to 5. From the viewpoints of liquid crystallinity, easily obtaining raw materials, and ease of synthesis, m2 to m7, n2, n4 to n7, 14 to 16, and k6 represent preferably an integer of 0 to 4, more preferably an integer of 0 to 2, and still more preferably 0 or 1.

j21, j22, j31, j32, j41, j42, j51, j52, j61, j62, j71, and j72 each independently represent an integer of 0 to 5, j21+j22 represents an integer of 1 to 5, j31+j32 represents an integer of 1 to 5, j41+j42 represents an integer of 1 to 5, j51+j52 represents an integer of 1 to 5, j61+j62 represents an integer of 1 to 5, and j71+j72 represents an integer of 1 to 5. From the viewpoints of liquid crystallinity, ease of synthesis, and storage stability, j21, j22, j31, j32, j41, j42, j51, j52, j61, j62, j71, and j72 each independently represent preferably an integer of 1 to 4, more preferably an integer of 1 to 3, and particularly preferably 1 or 2. j21+j22, j31+j32, j41+j42, j51+j52, j61+j62, and j71+j72 each independently represent an integer of 1 to 4 and particularly preferably 2 or 3.

Preferred specific examples of the compound represented by General Formula (2-a) include compounds represented by Formulae (2-a-1) to (2-a-64).

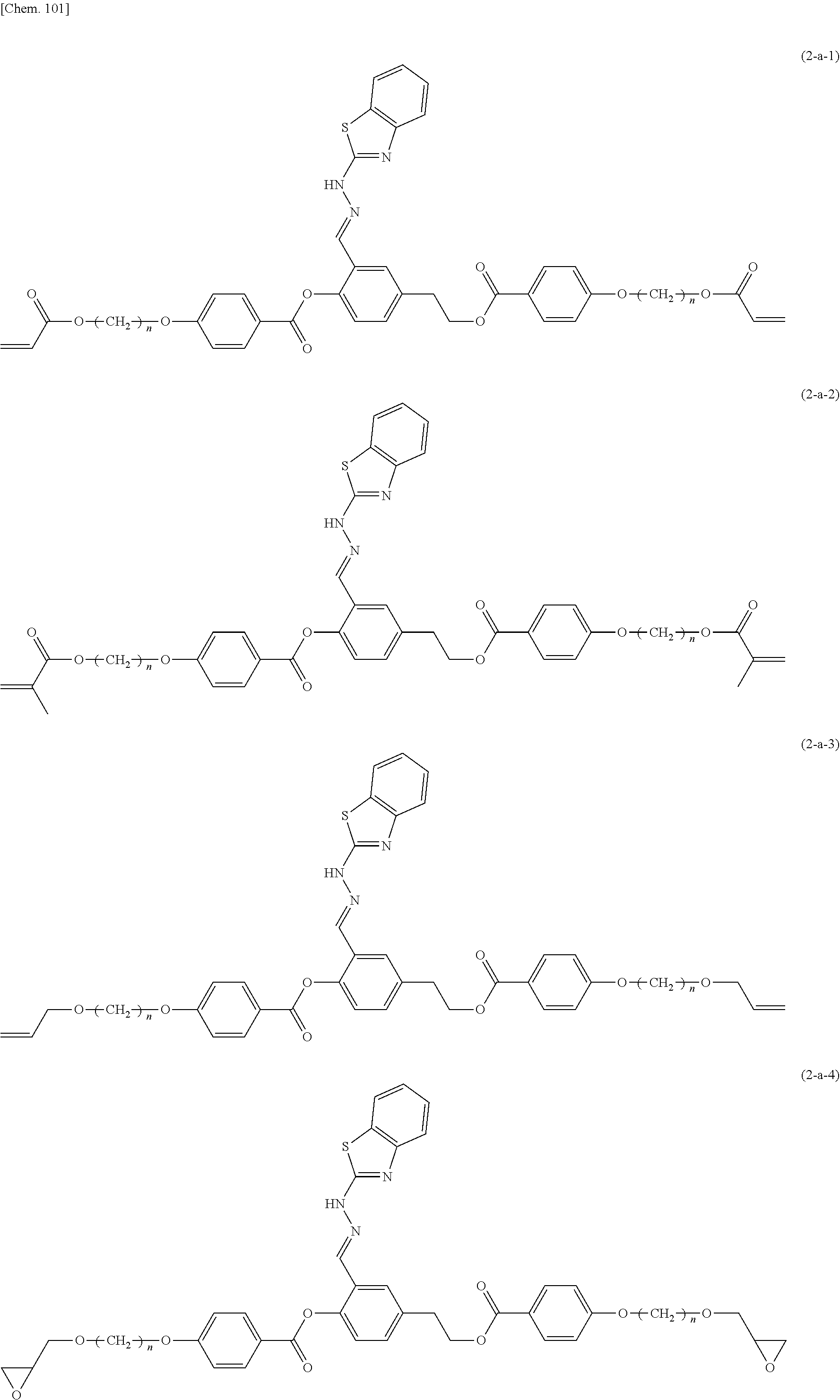

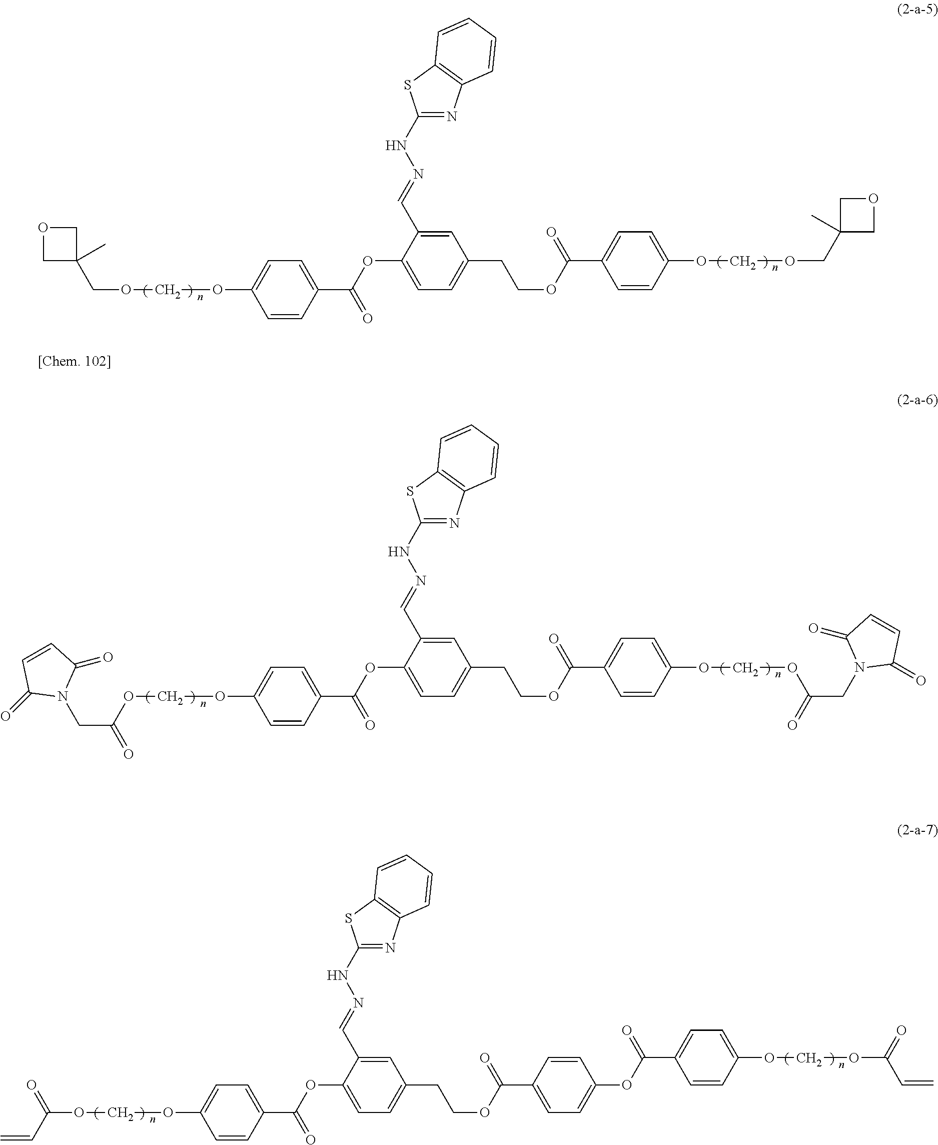

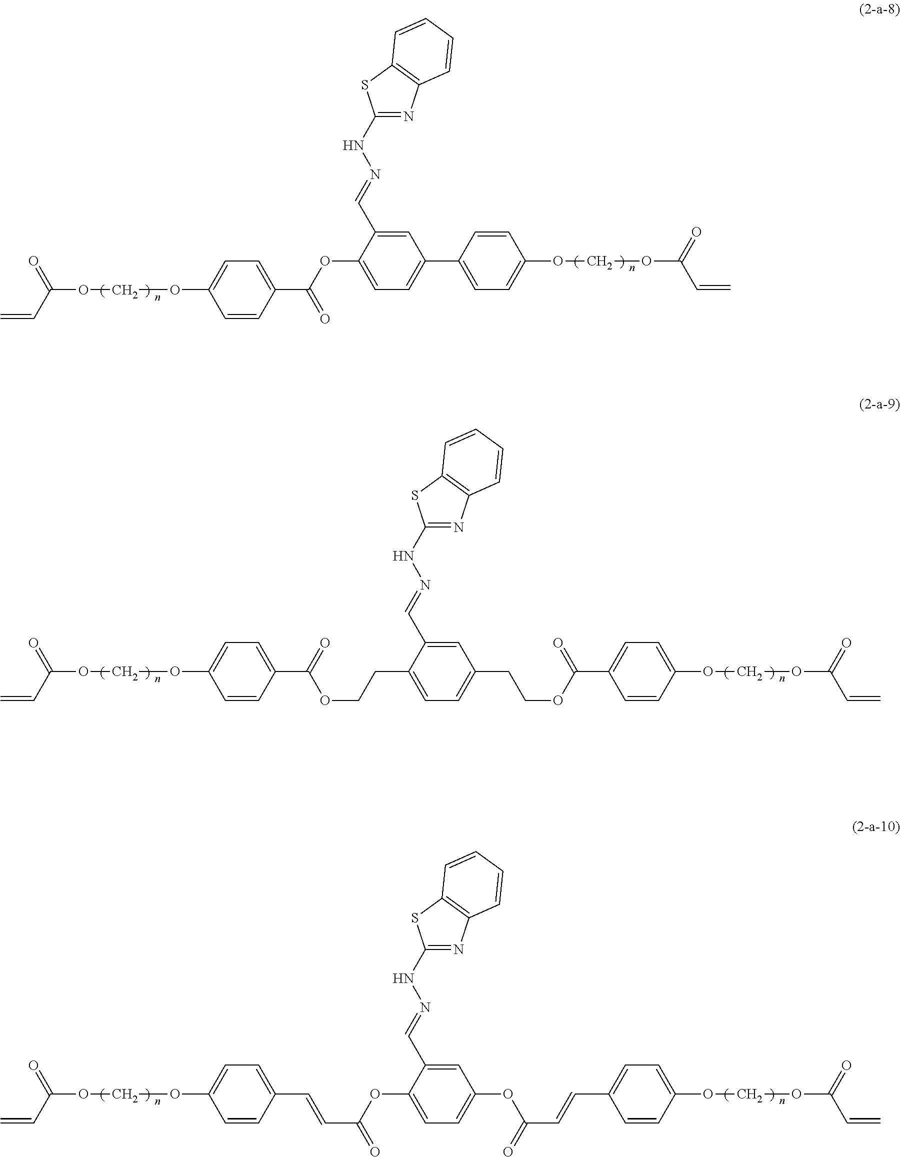

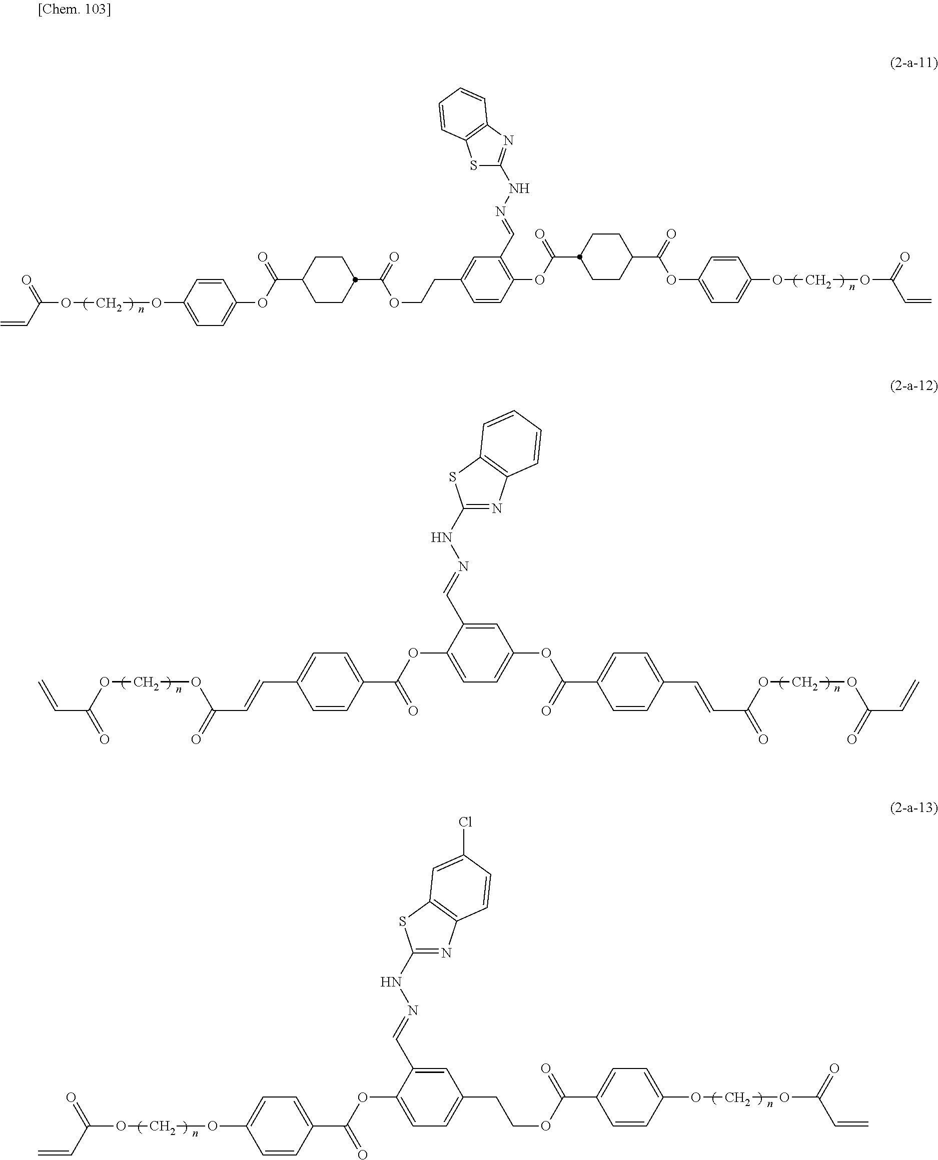

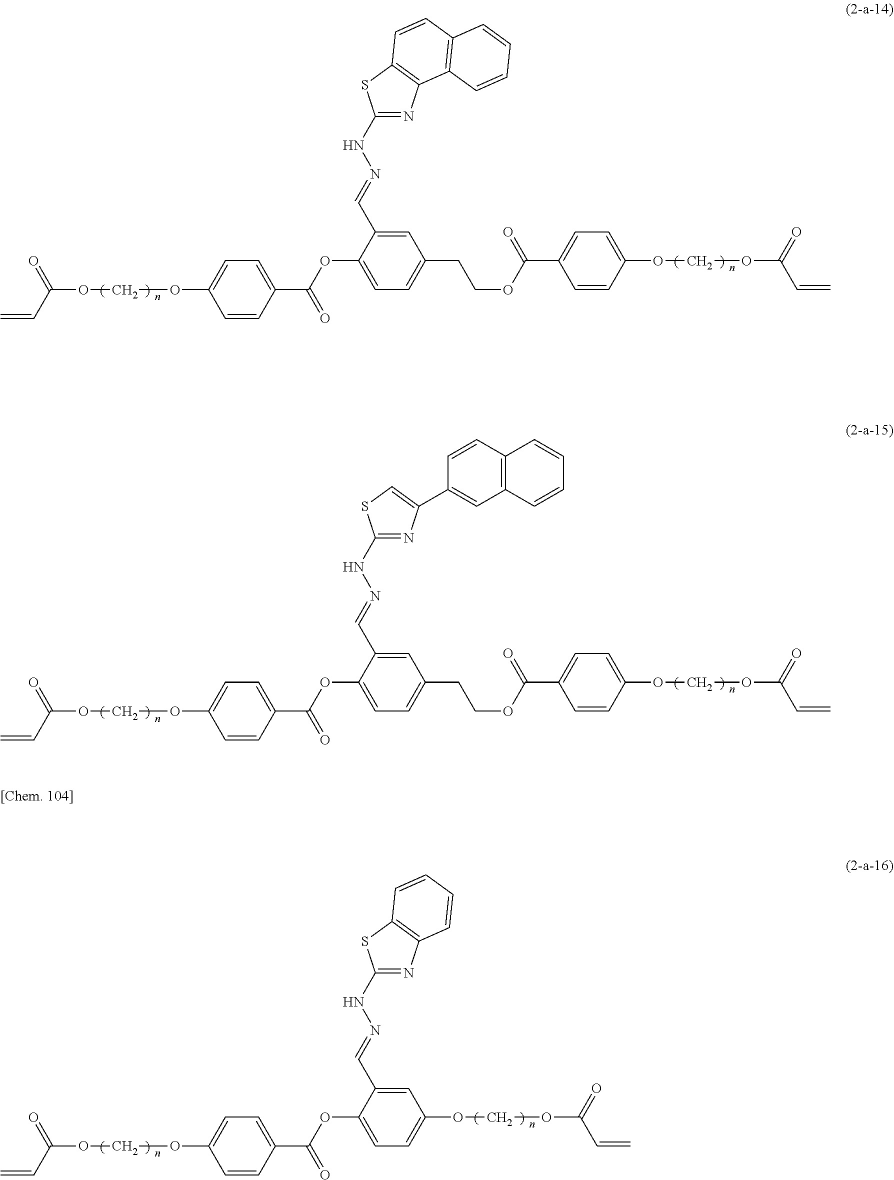

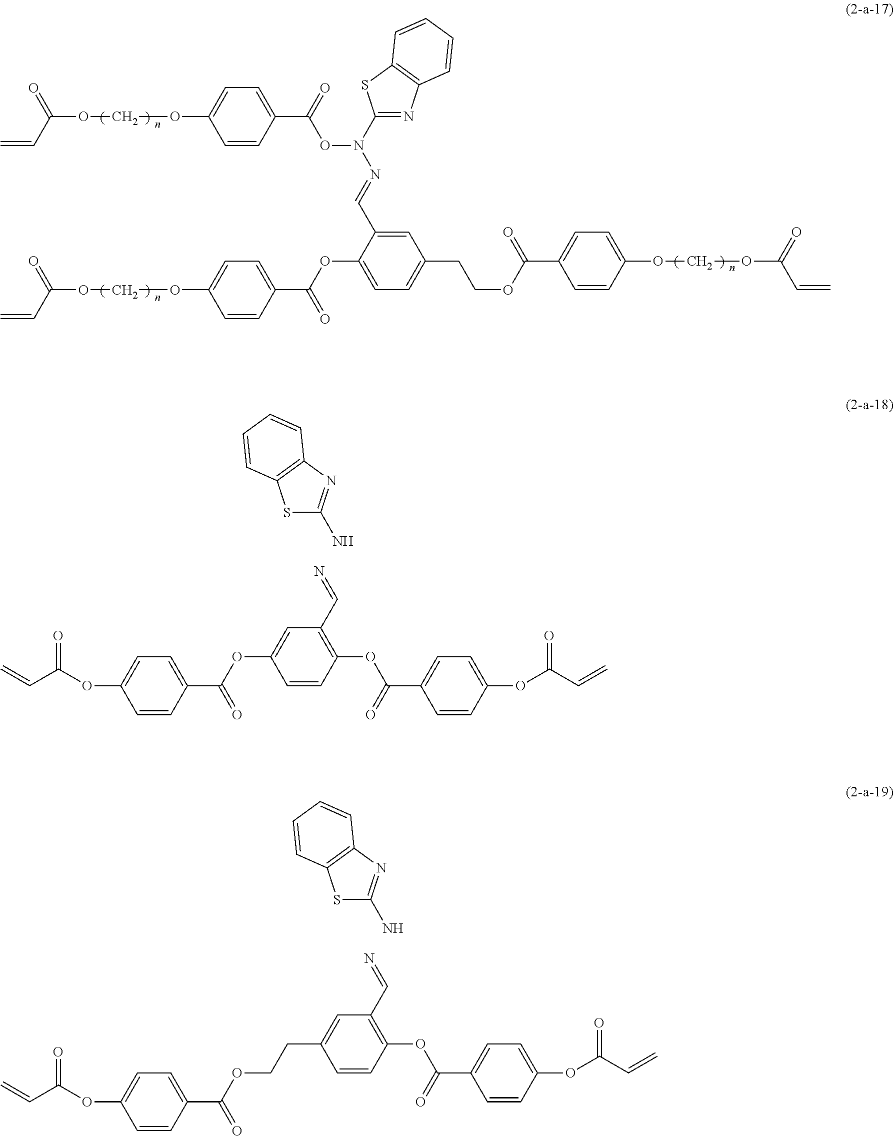

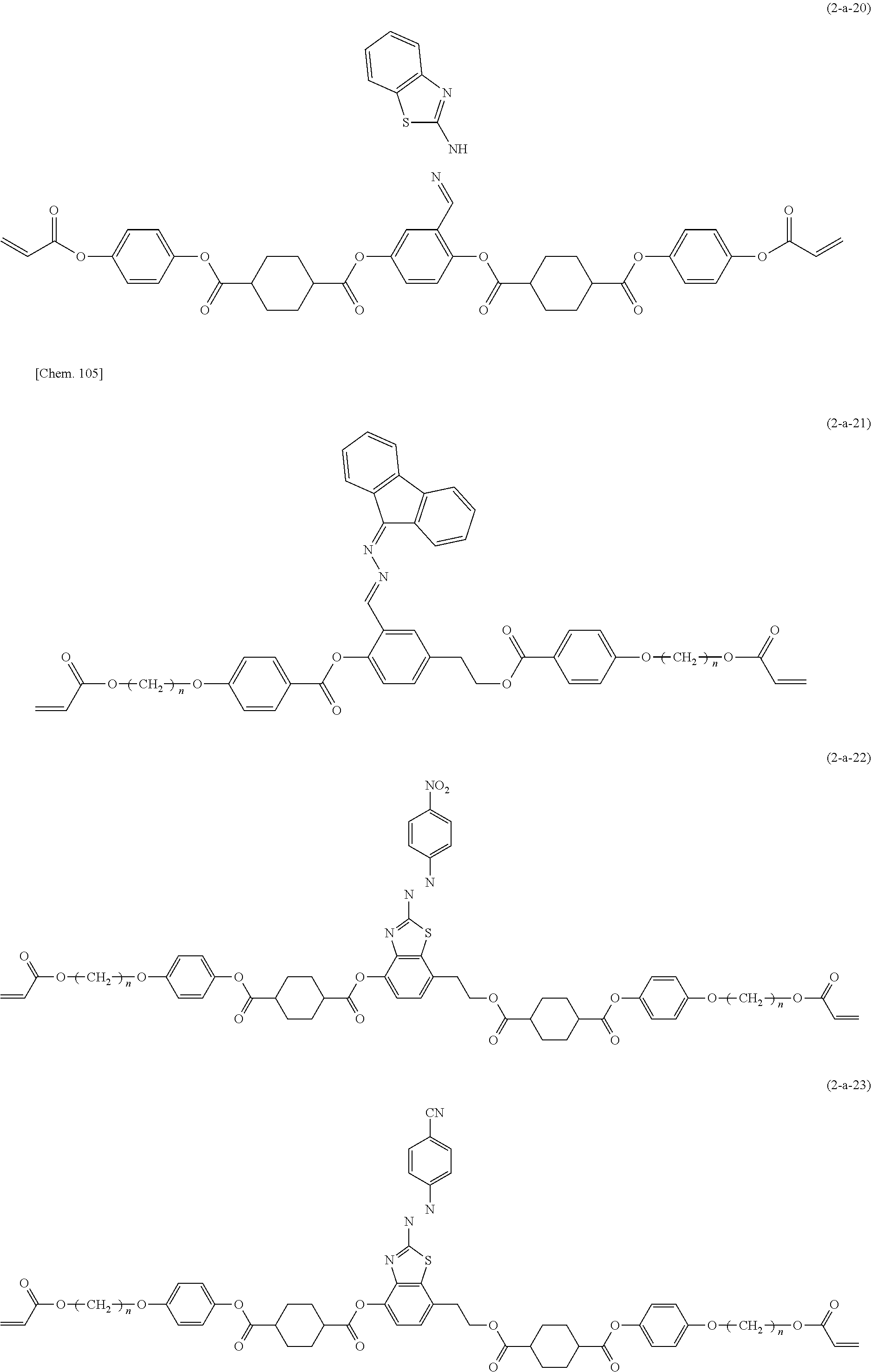

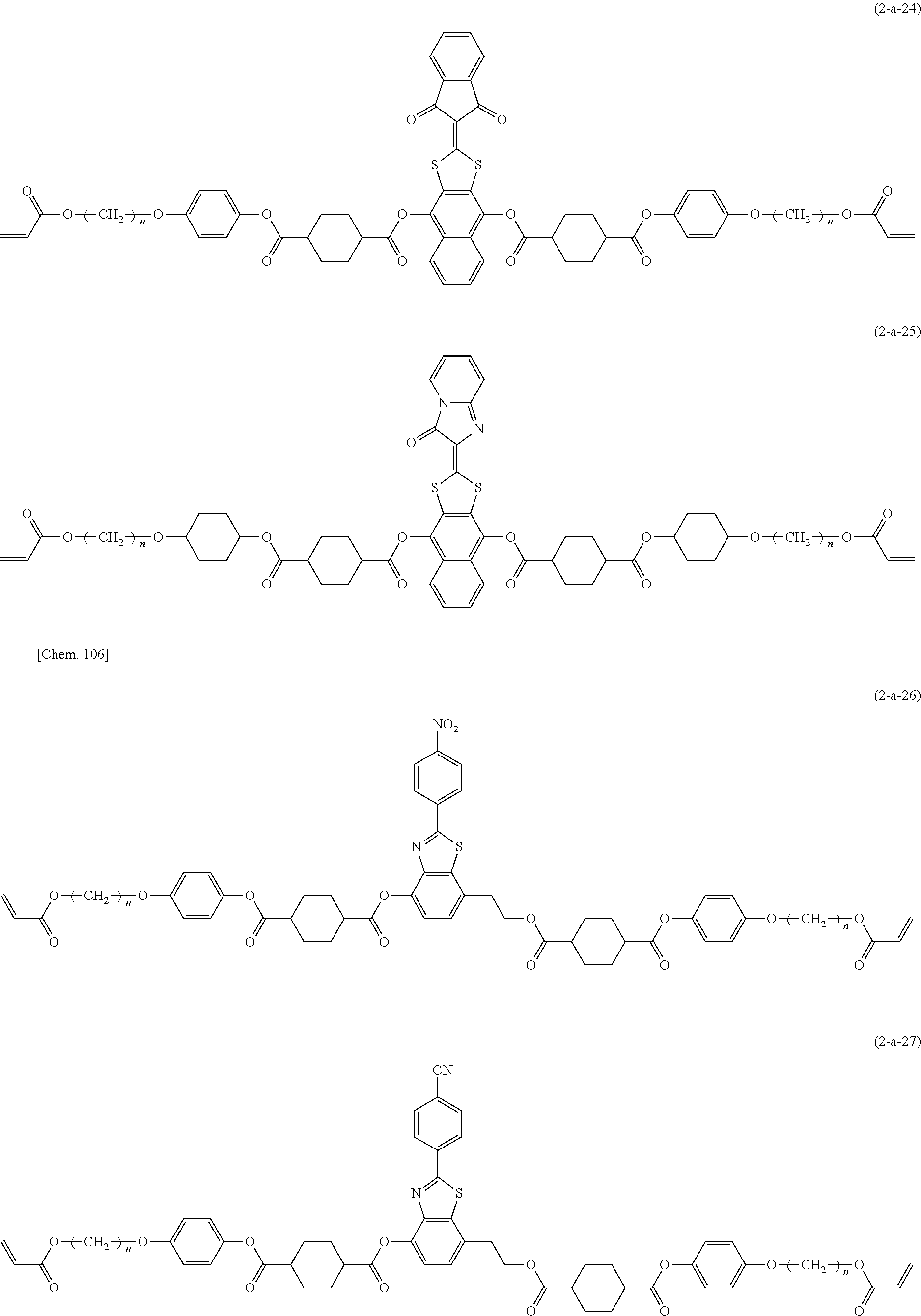

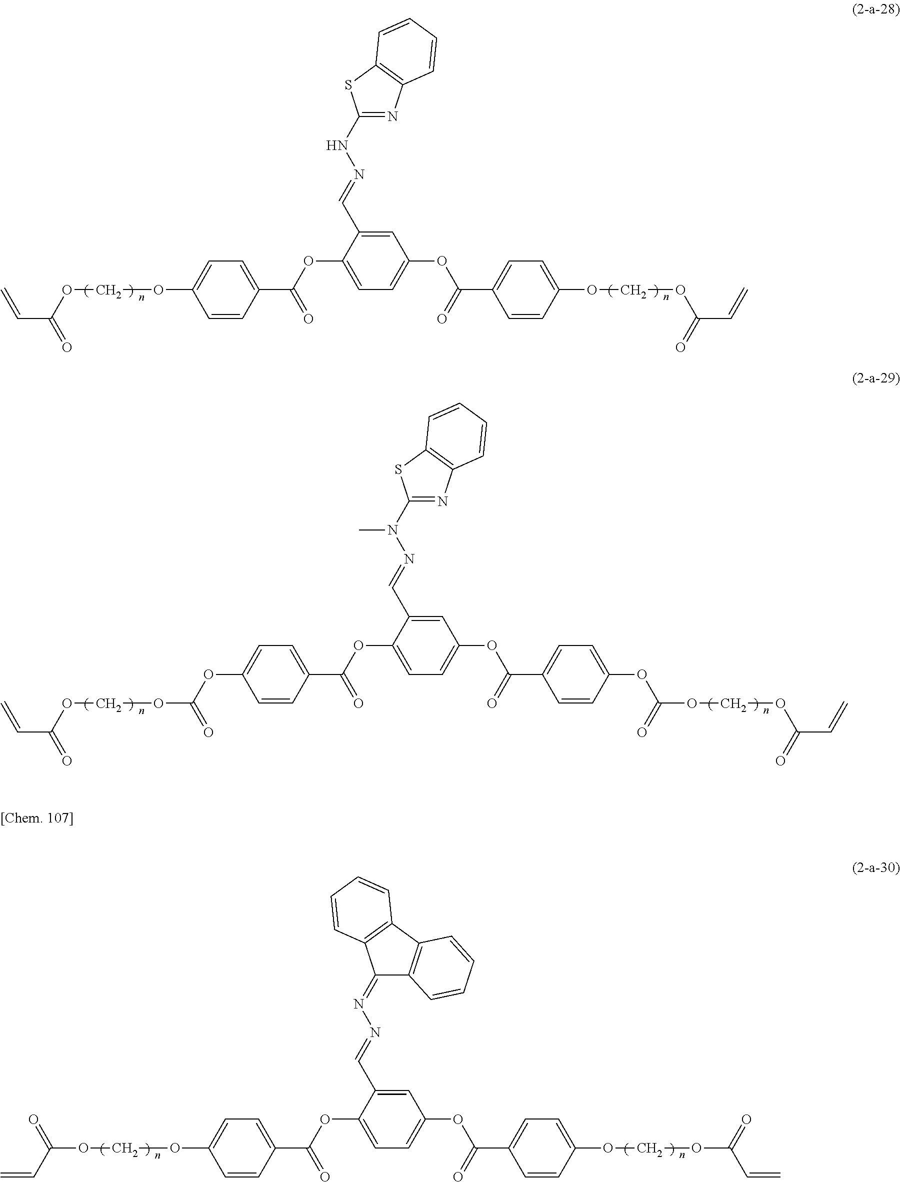

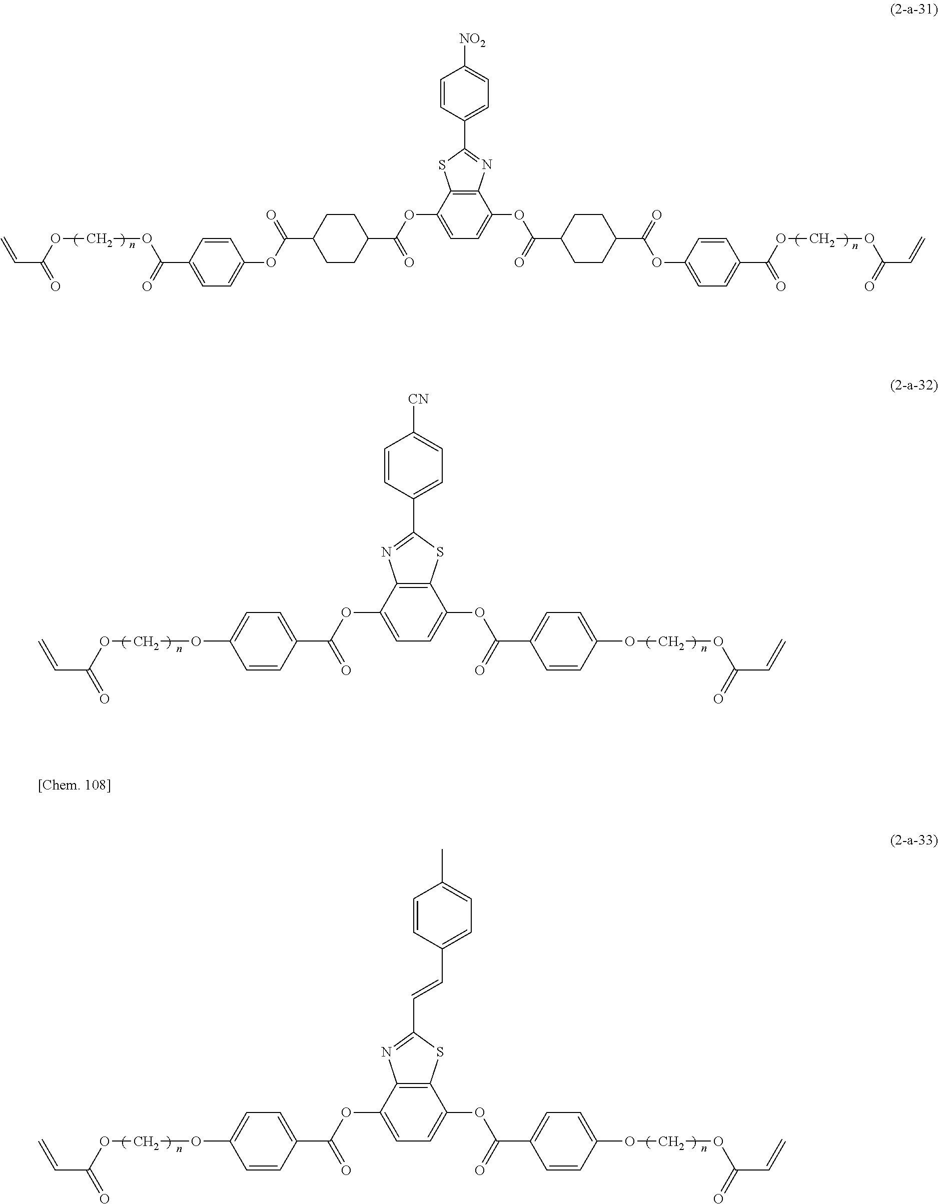

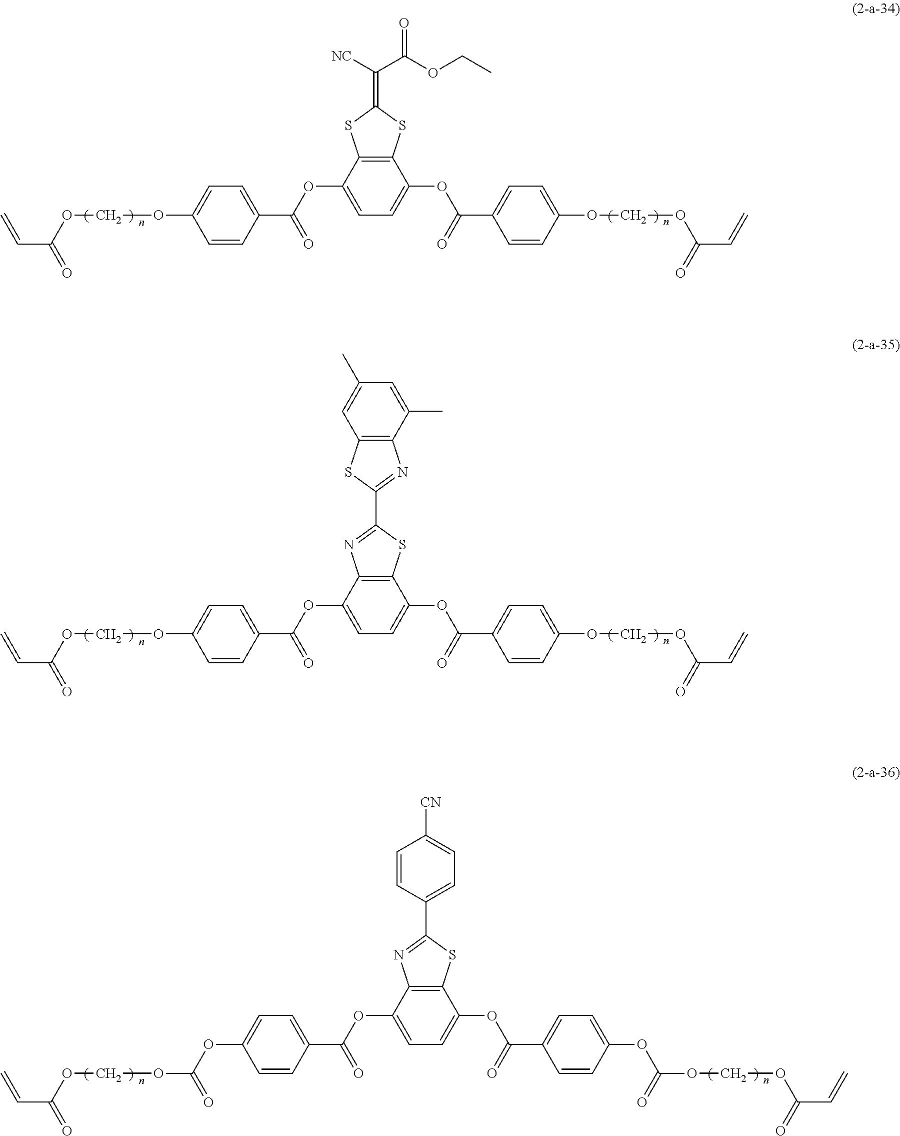

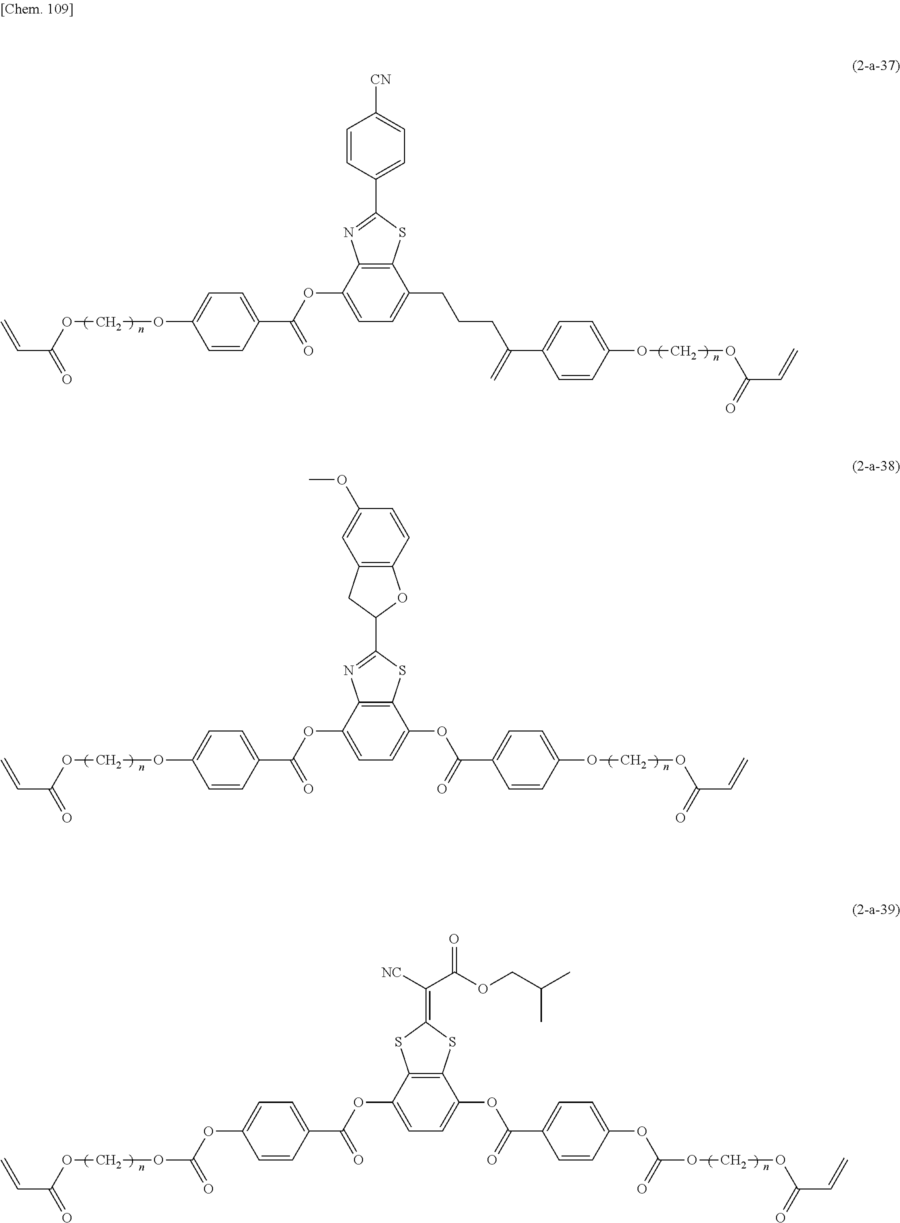

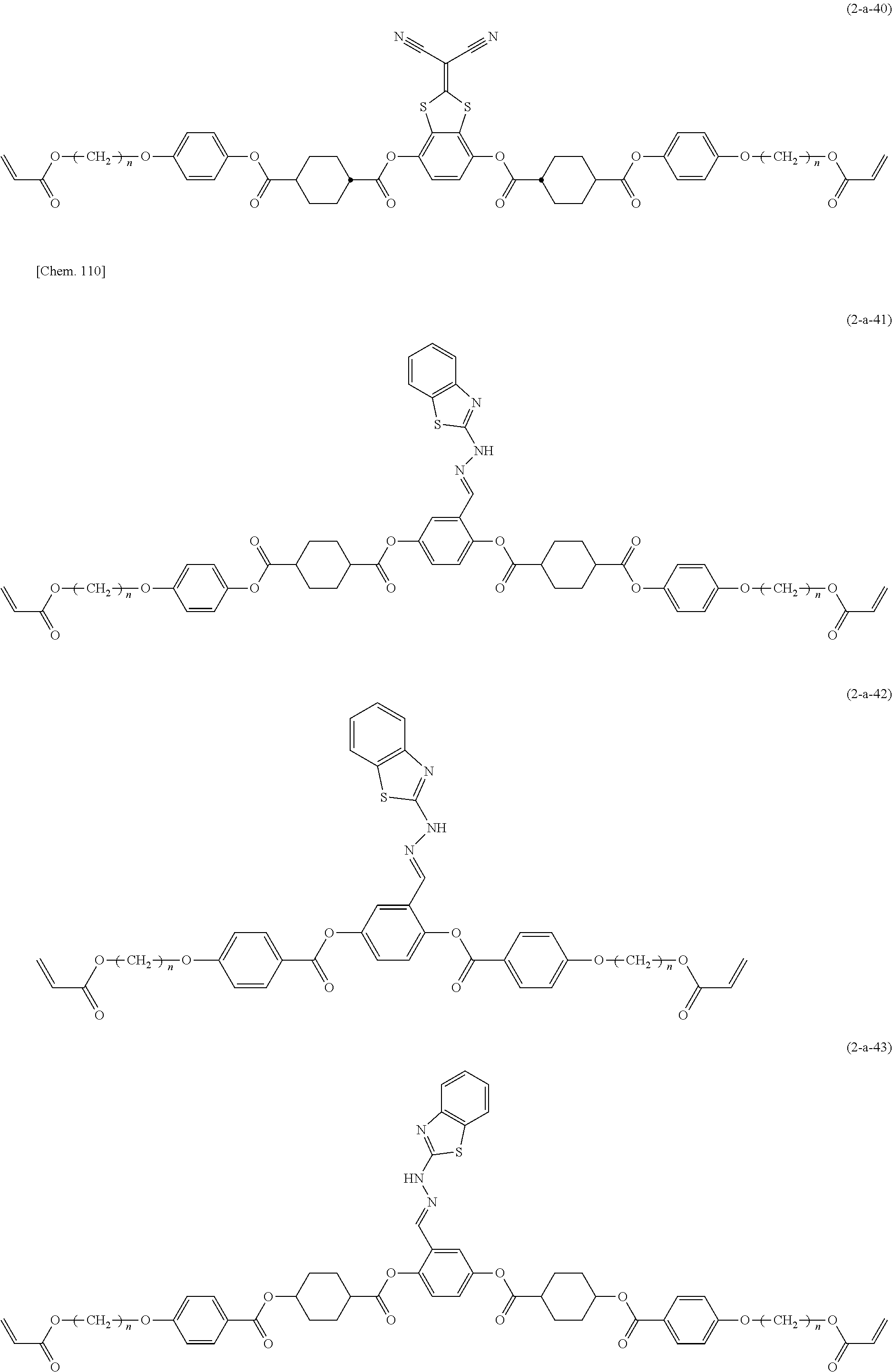

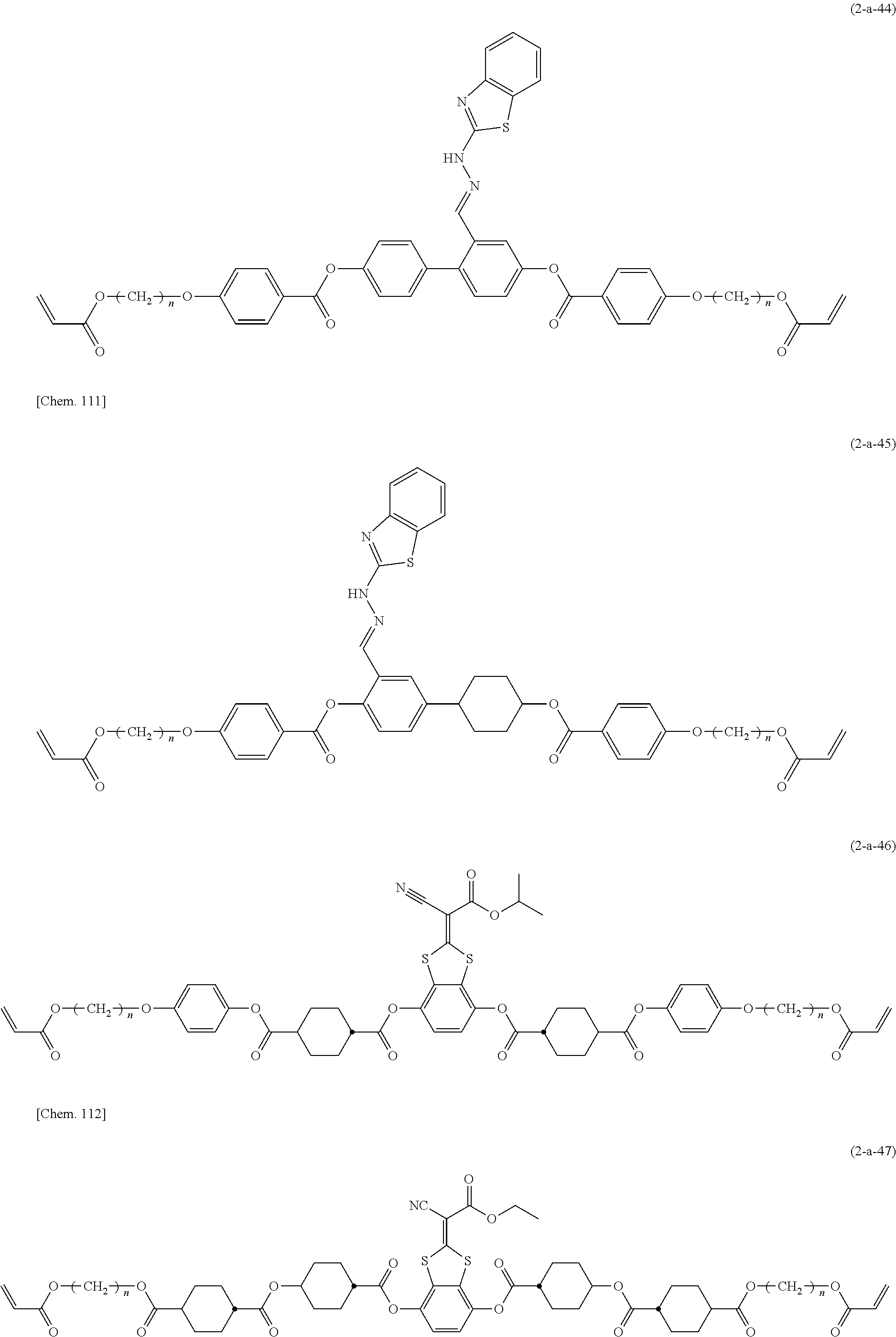

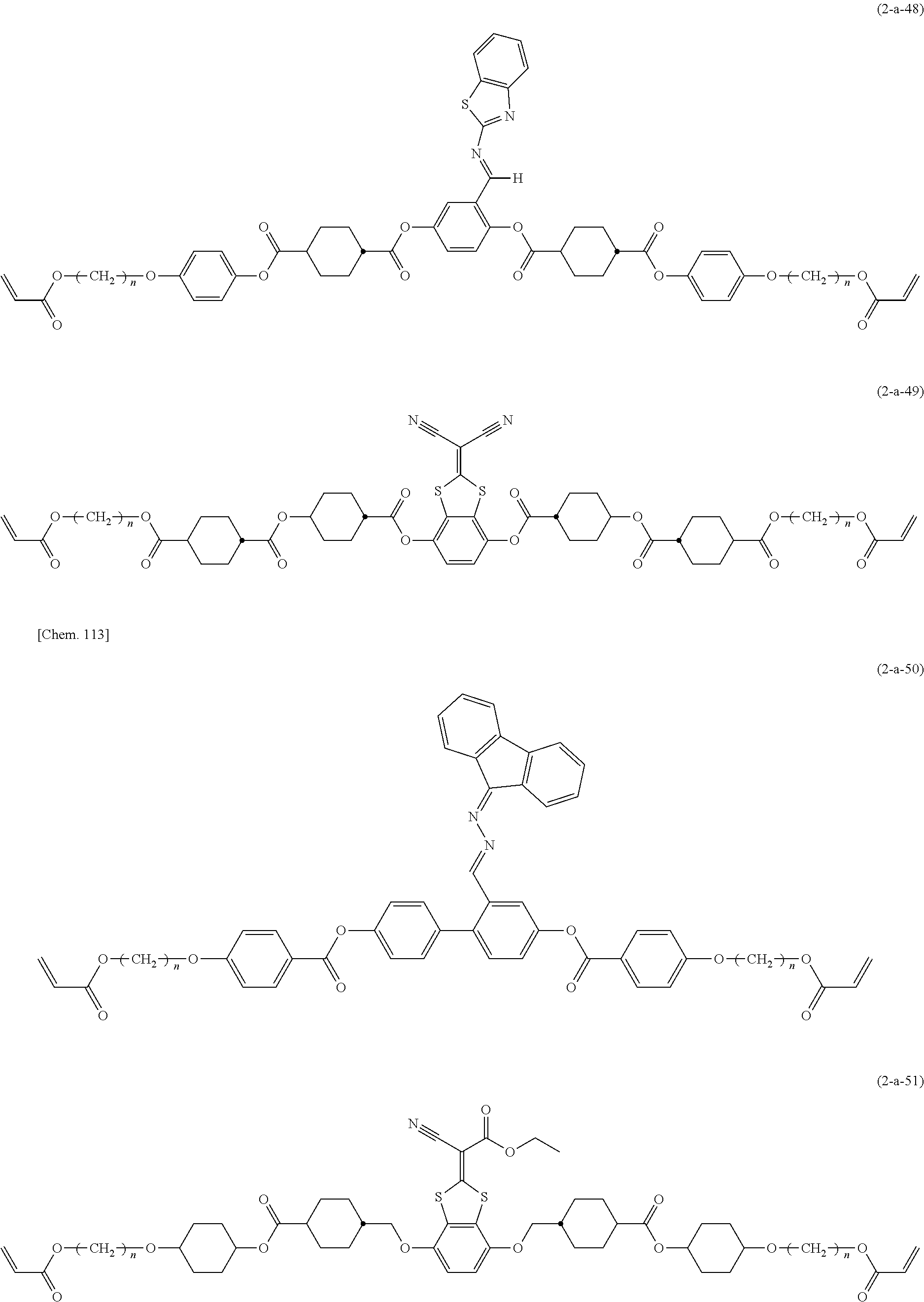

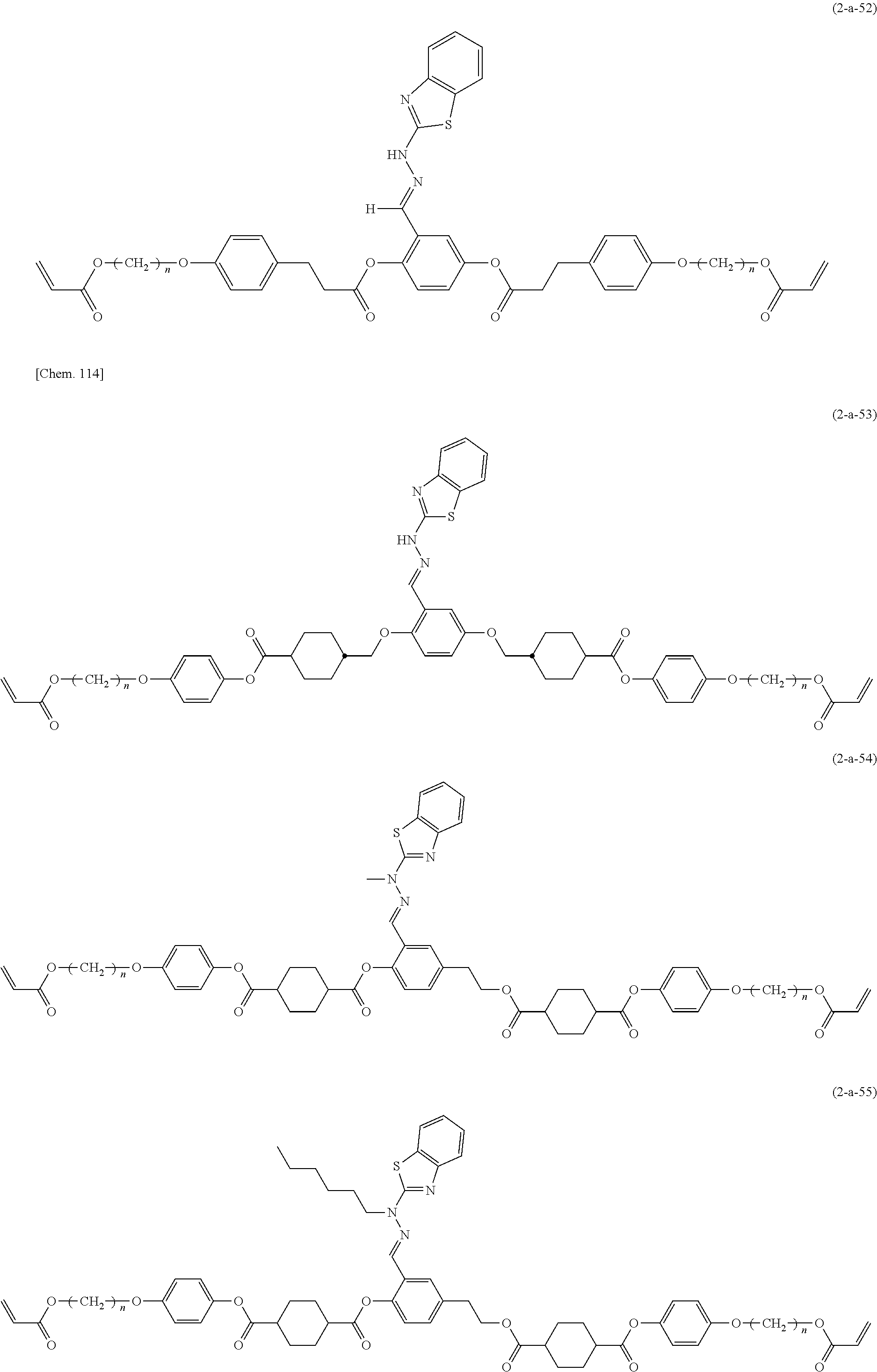

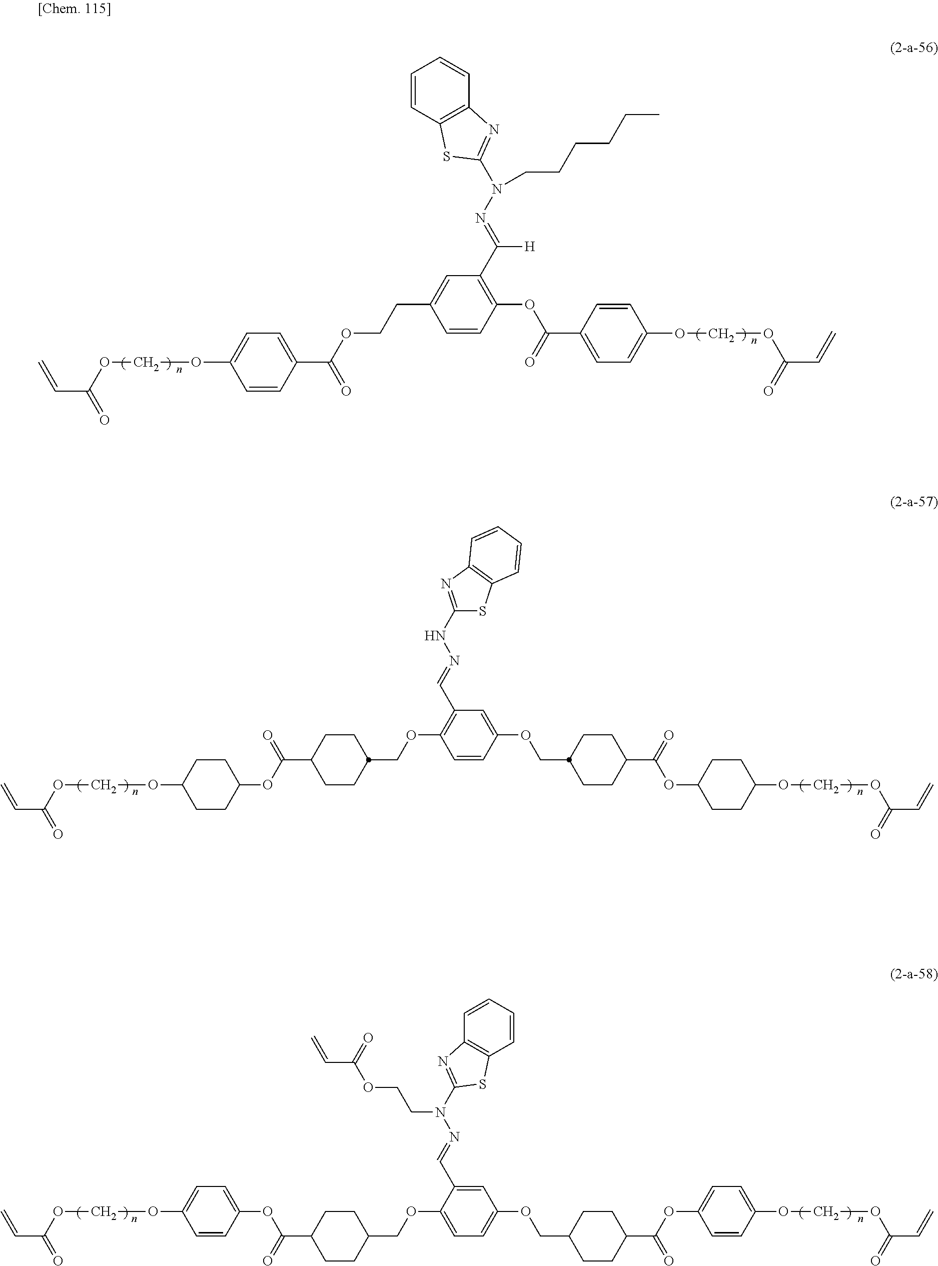

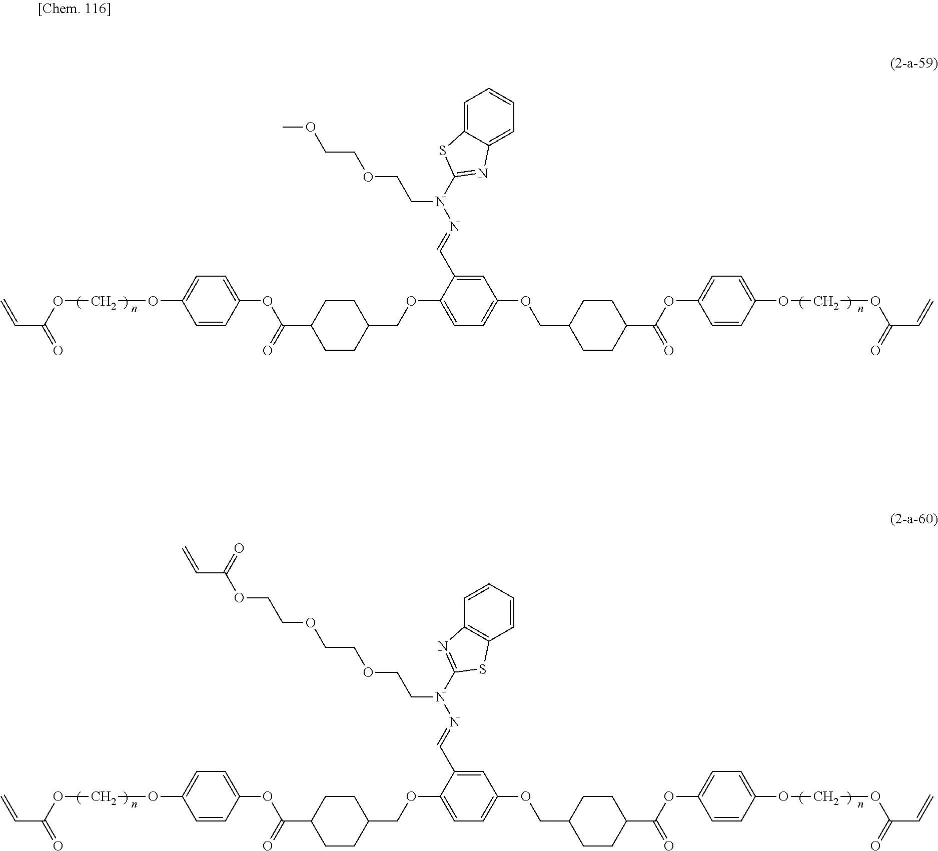

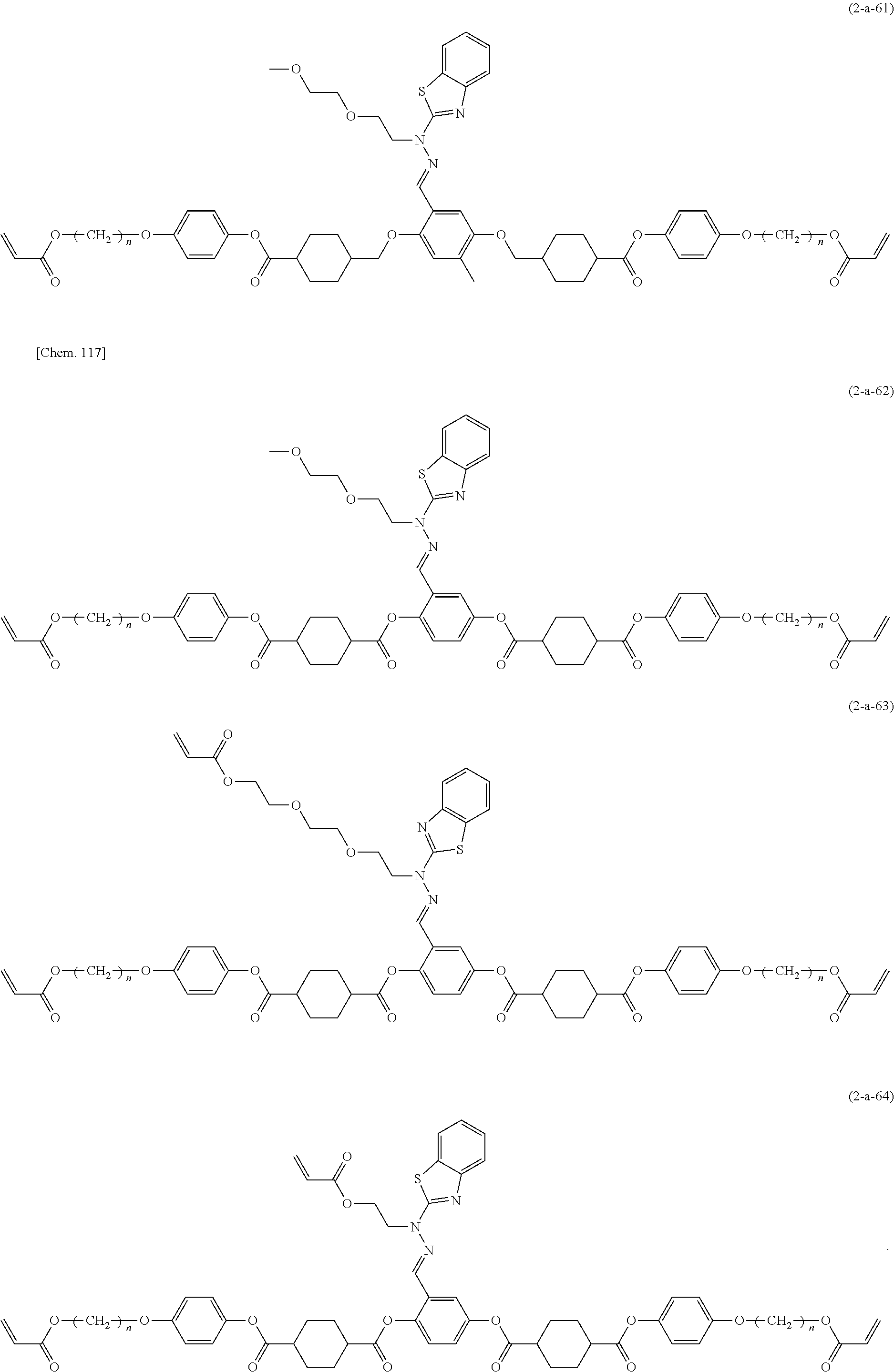

(In the formulae, n represents an integer of 1 to 10.)

Preferred specific example, of the compound represented by the Formula (2-b) include compounds represented by formulae (2-b-1) to (2-b-33).

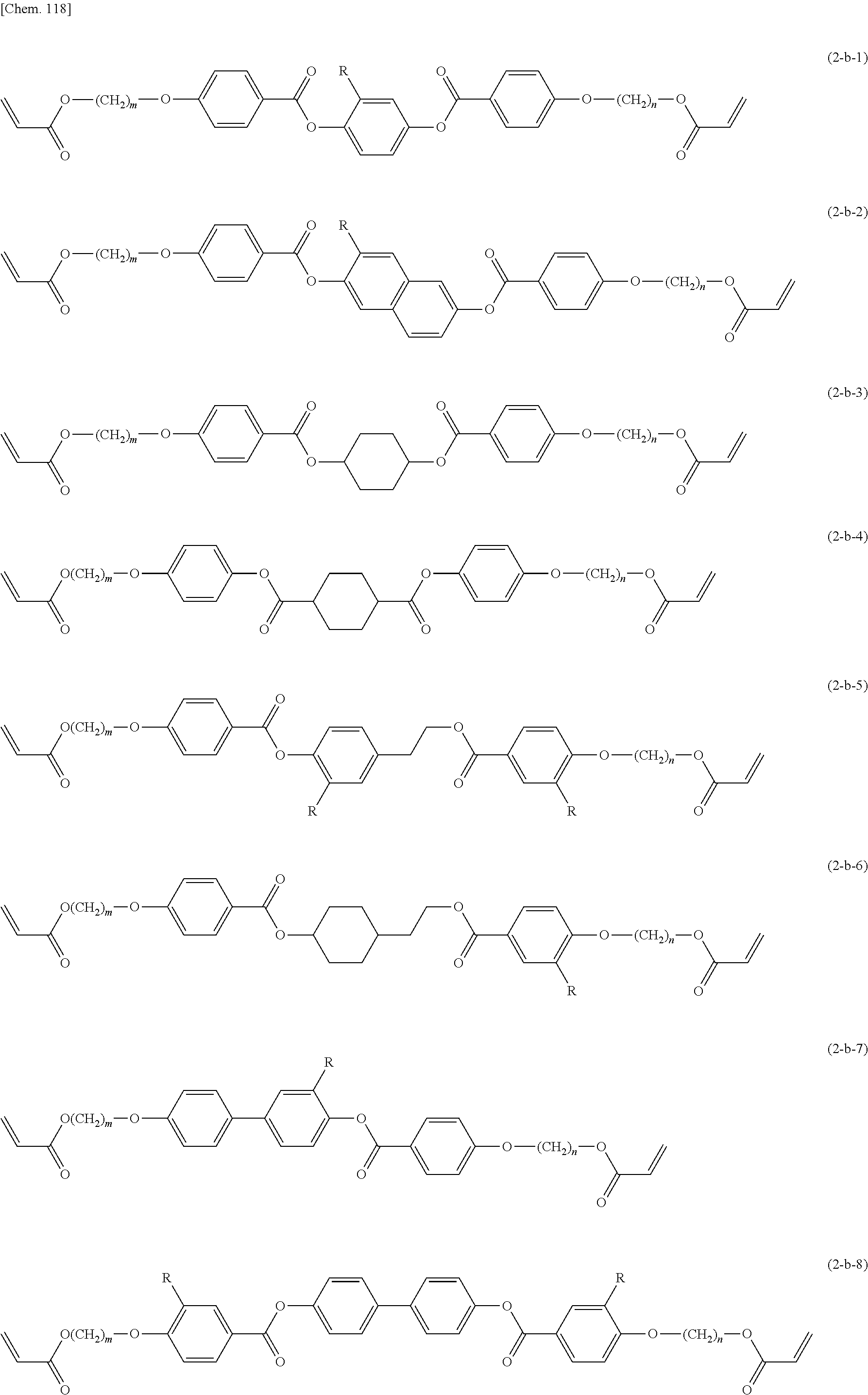

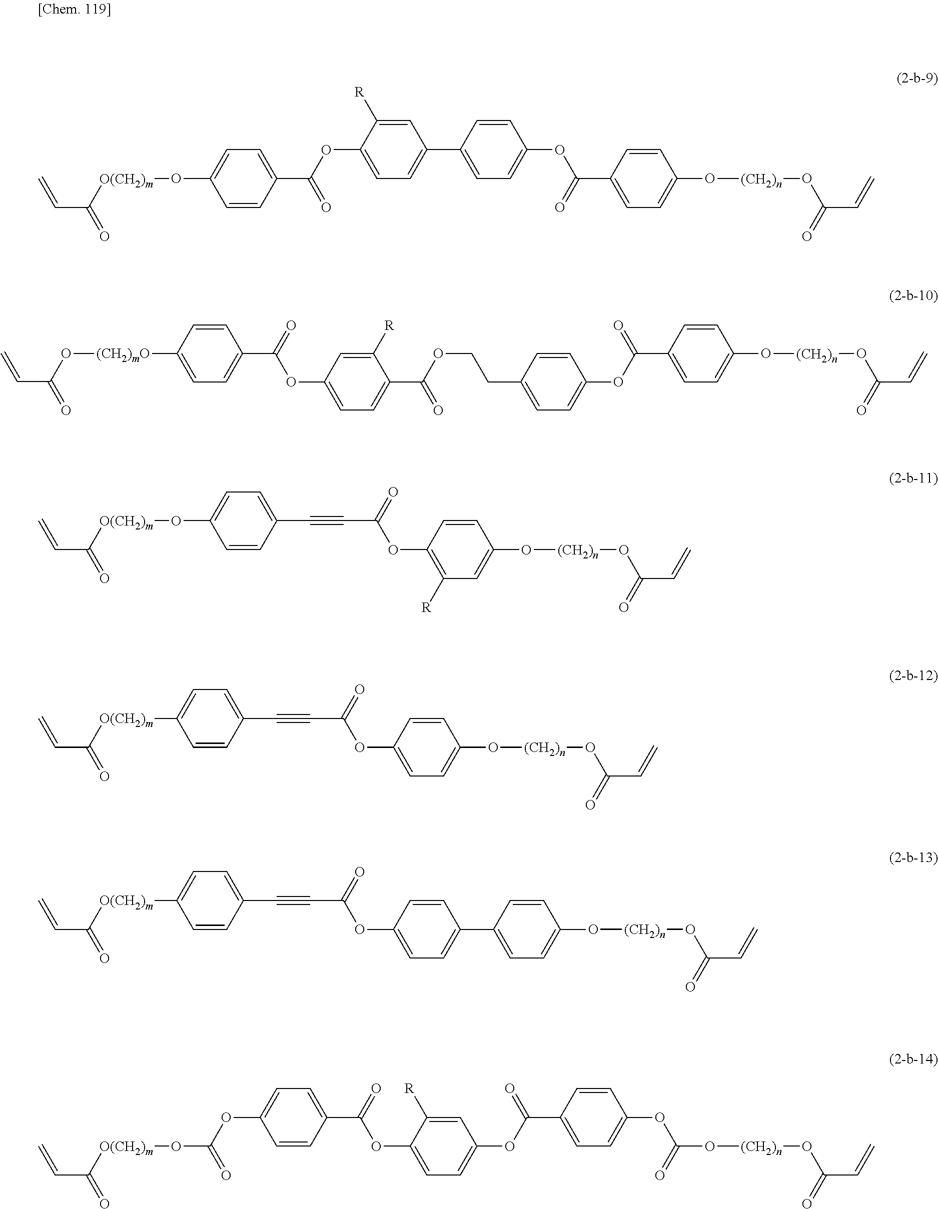

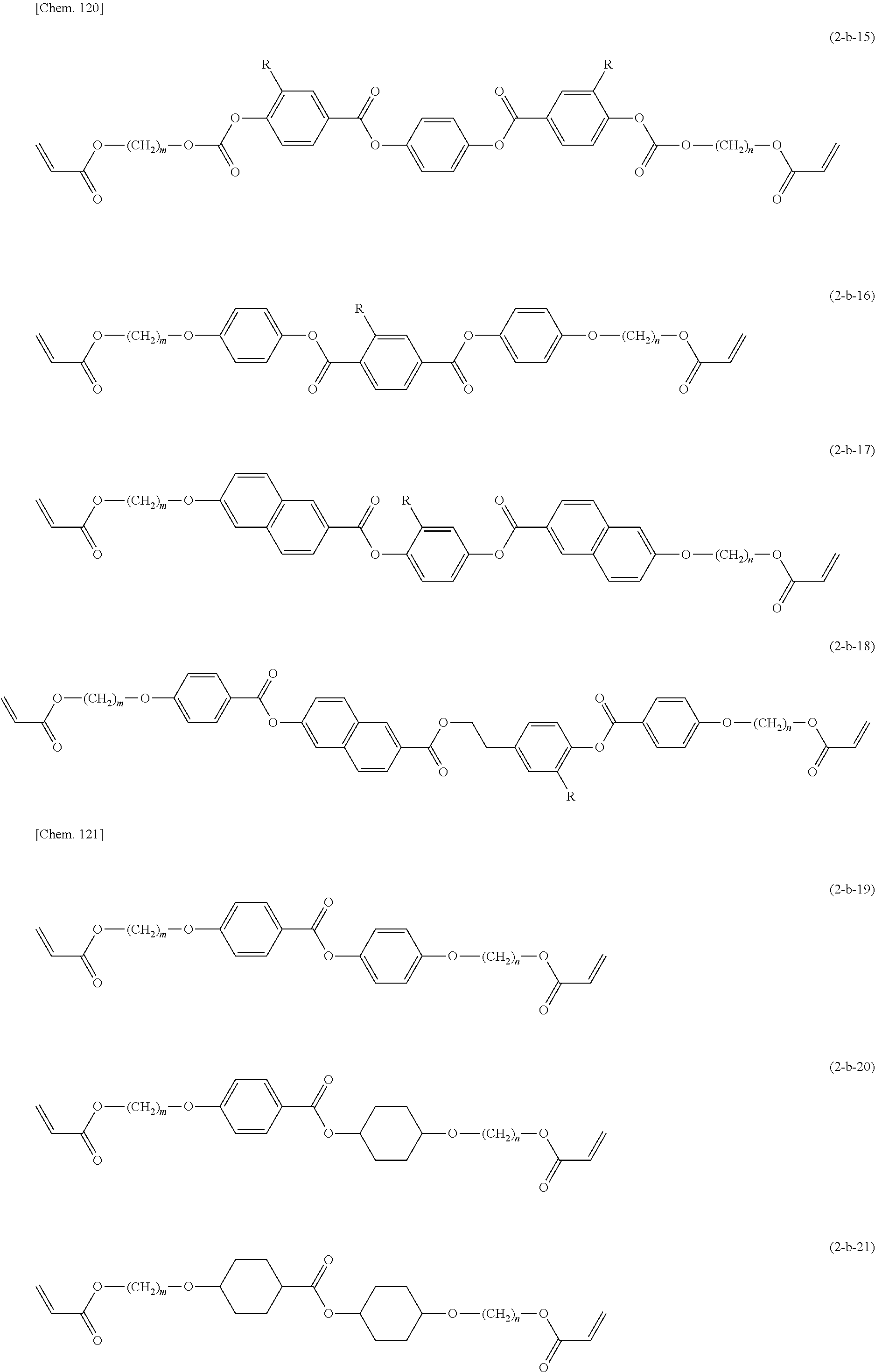

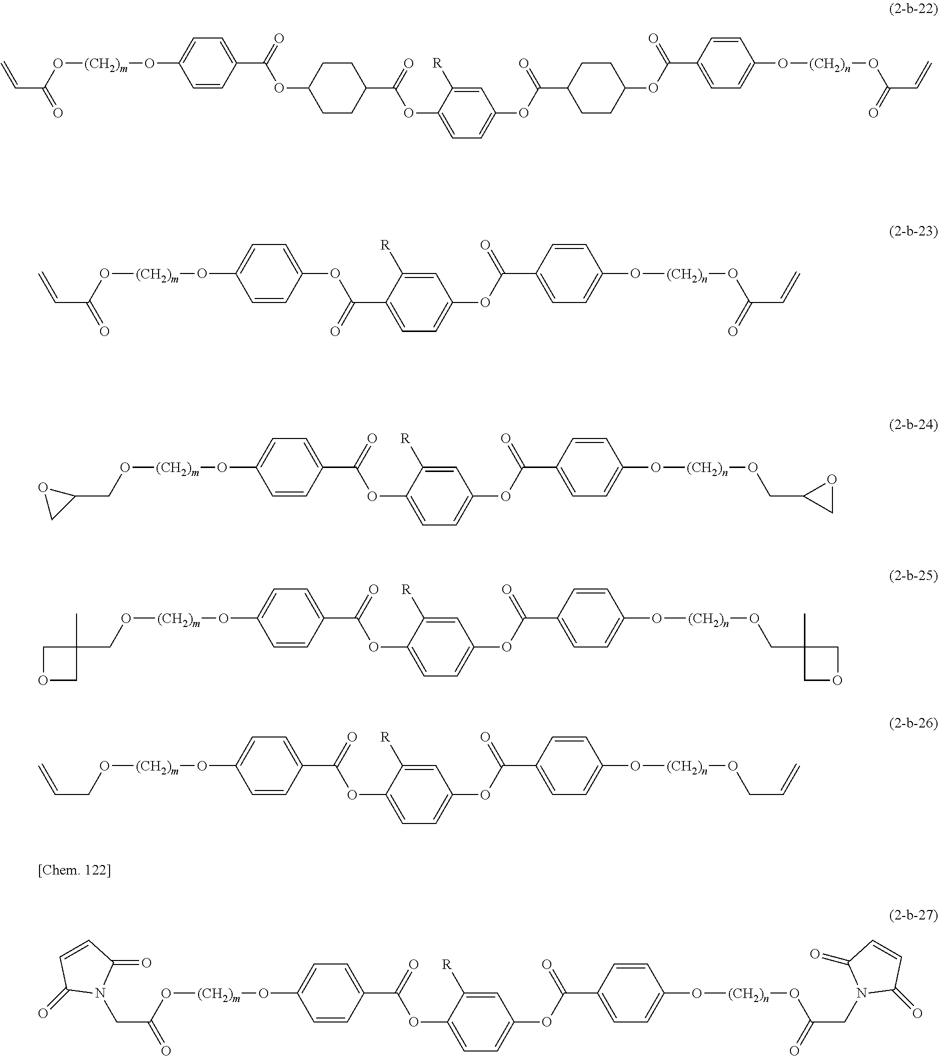

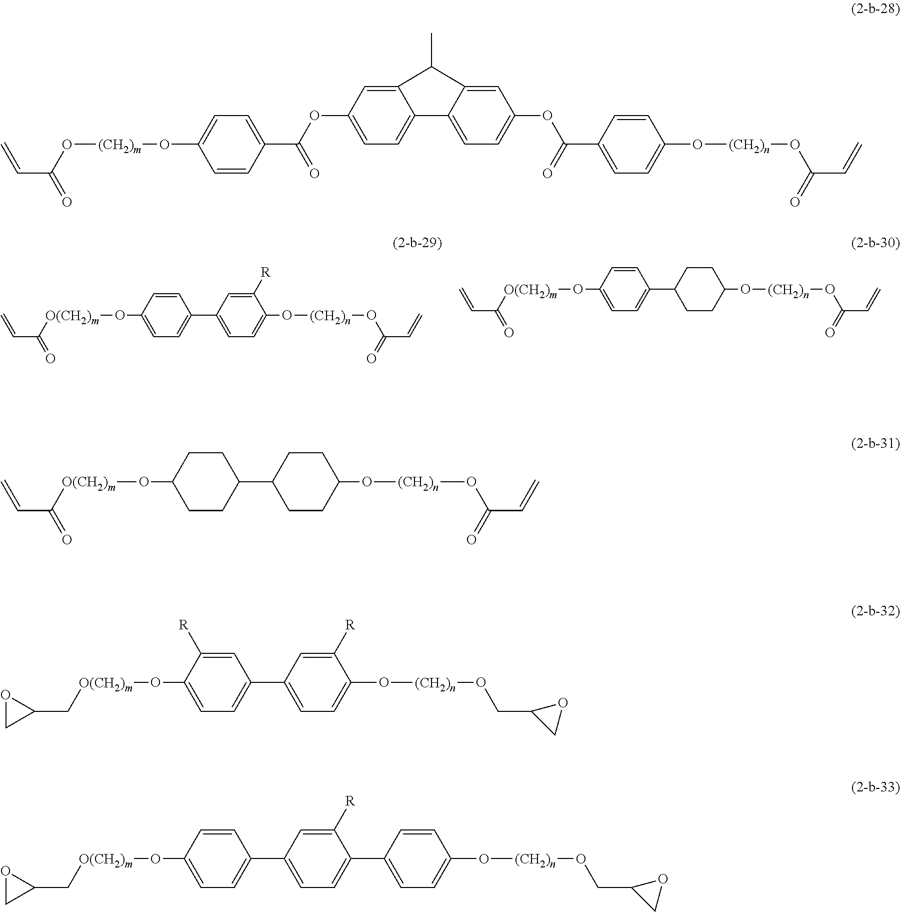

(In the formulae, m and n each independently represent an integer of 1 to 18, R represents a hydrogen atom, a halogen atom, an alkyl group having 1 to 6 carbon atoms, an alkoxy group having 1 to 6 carbon atom, or a cyano group. In a case where these groups represent an alkyl group having 1 to 6 carbon atoms or an alkoxy group having 1 to 6 carbon atoms, all groups may be unsubstituted or substituted with one or two or more halogen atoms.)

These liquid crystal compounds may be used alone or in combination of two or more kinds thereof.

Specific examples of the compound represented by Formula (3-a) include compounds represented by Formulae (3-a-1) to (3-a-17).

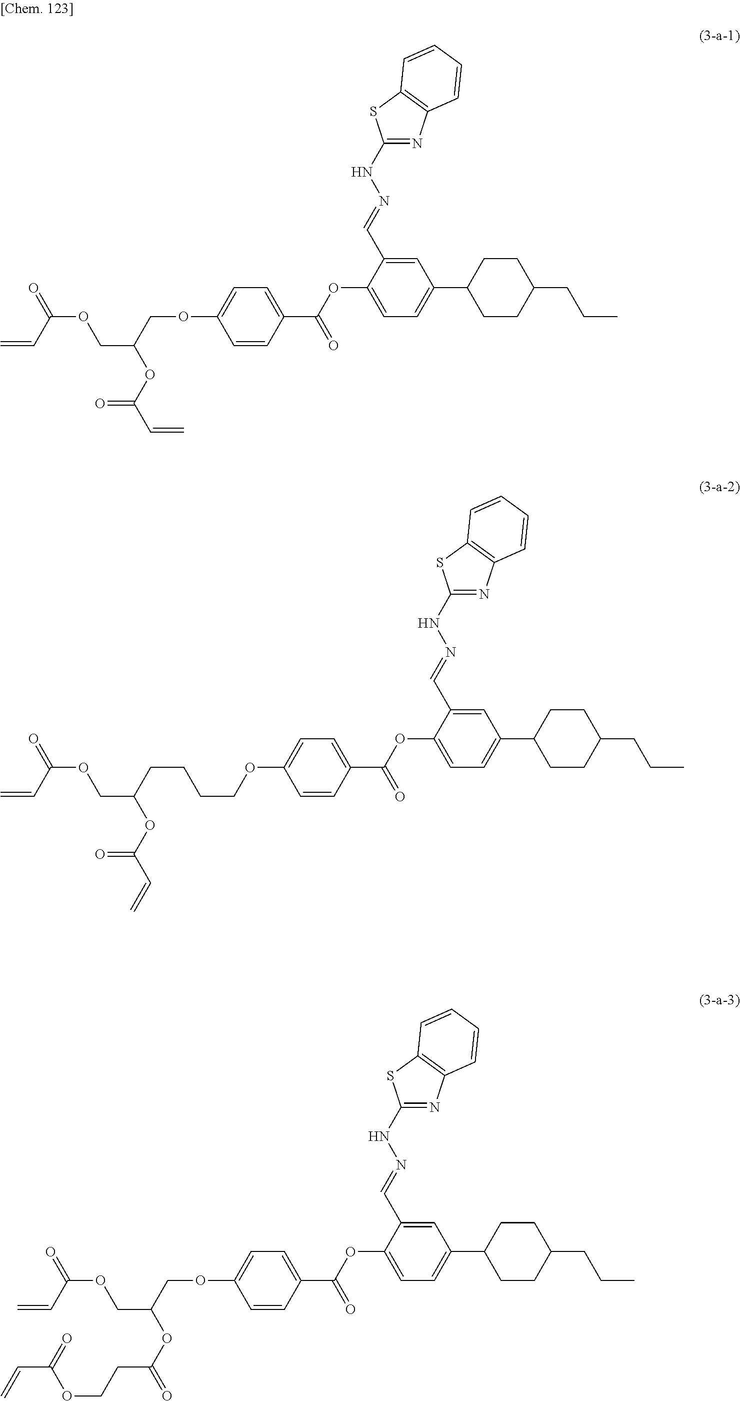

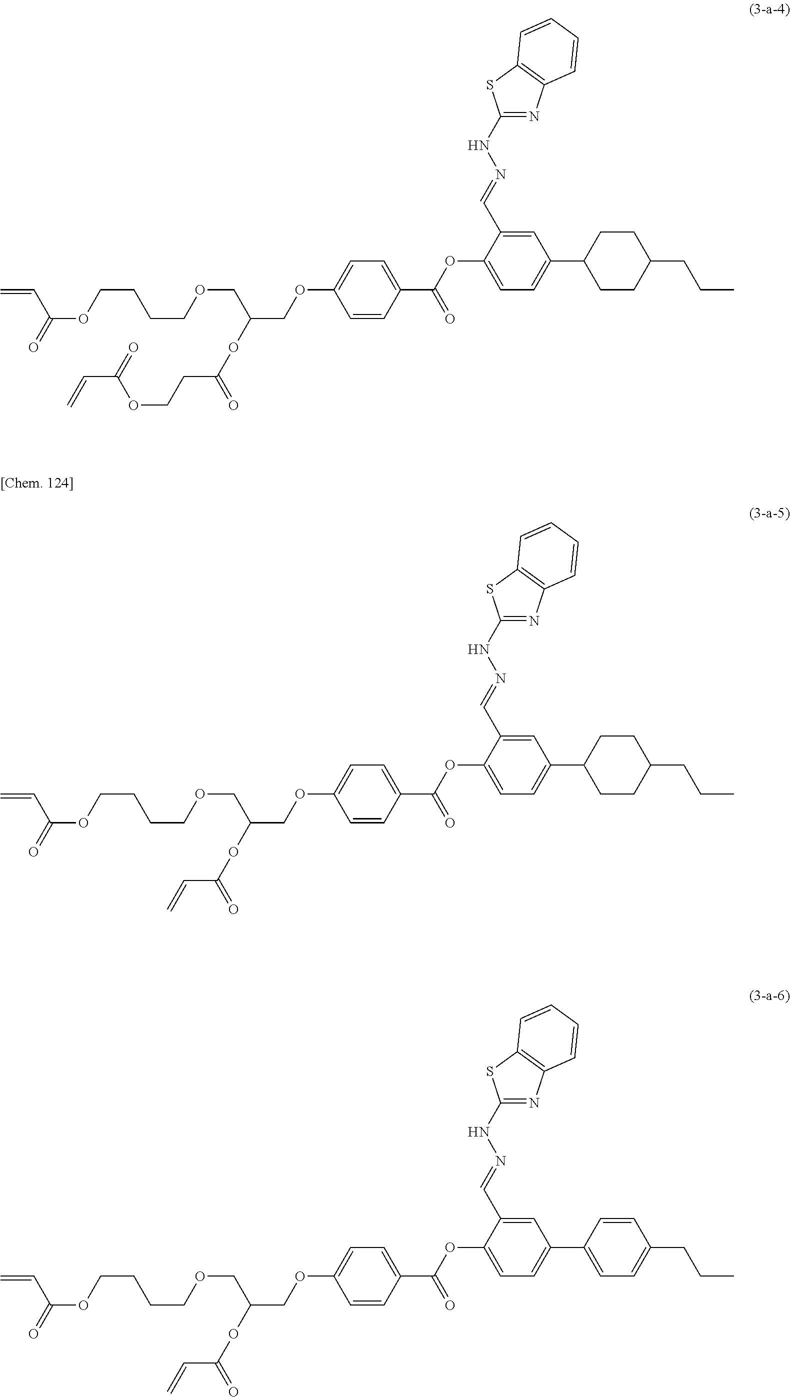

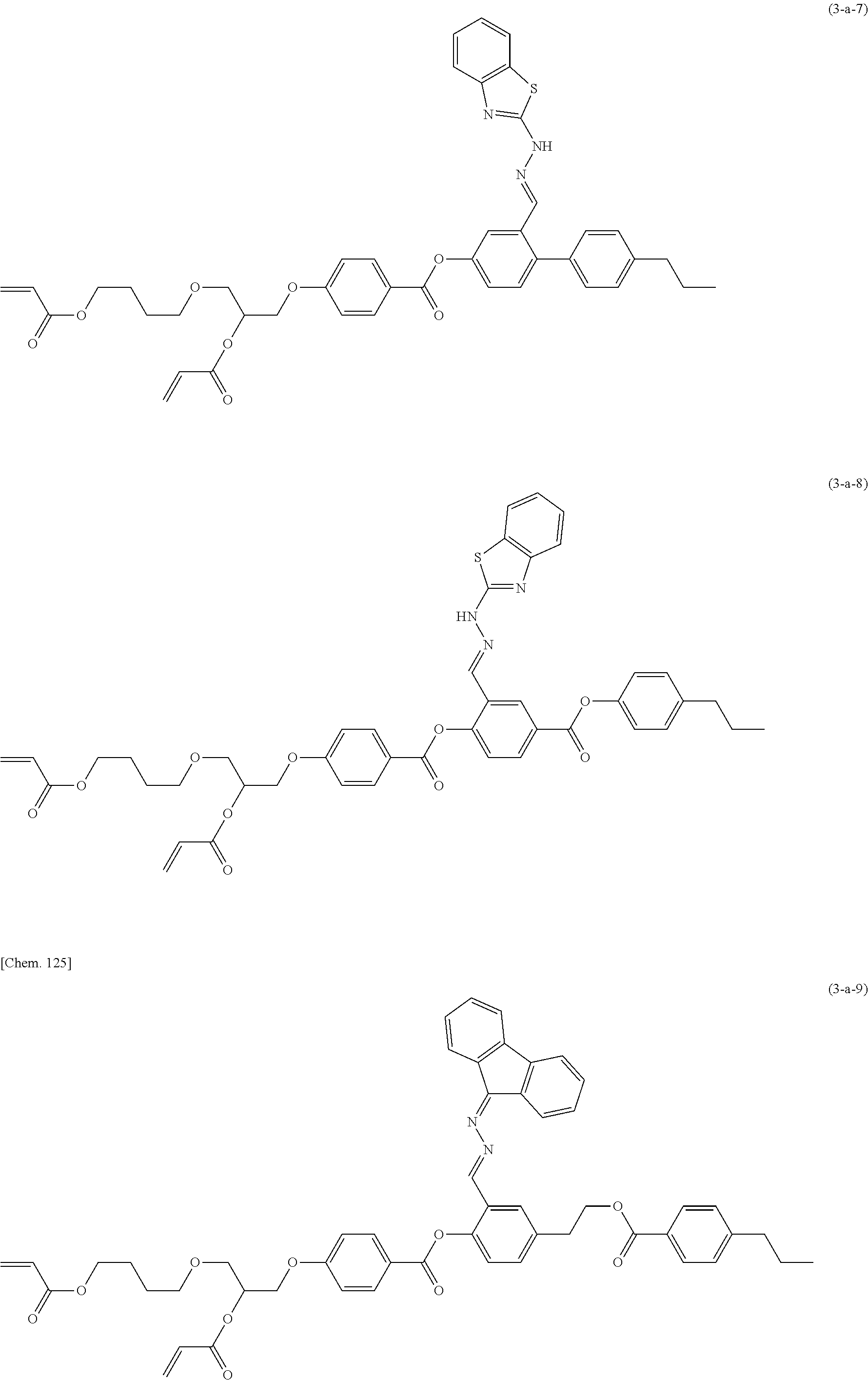

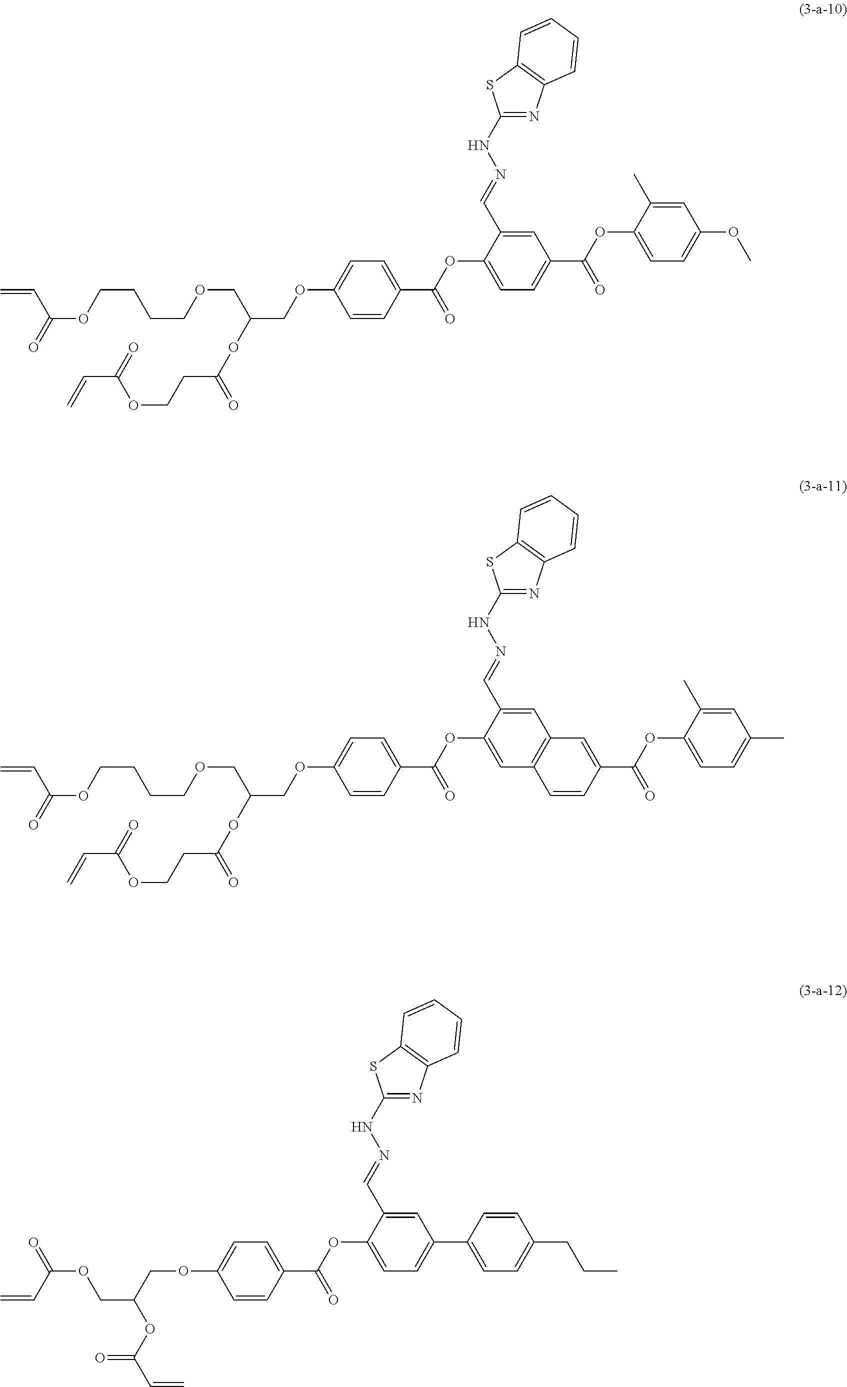

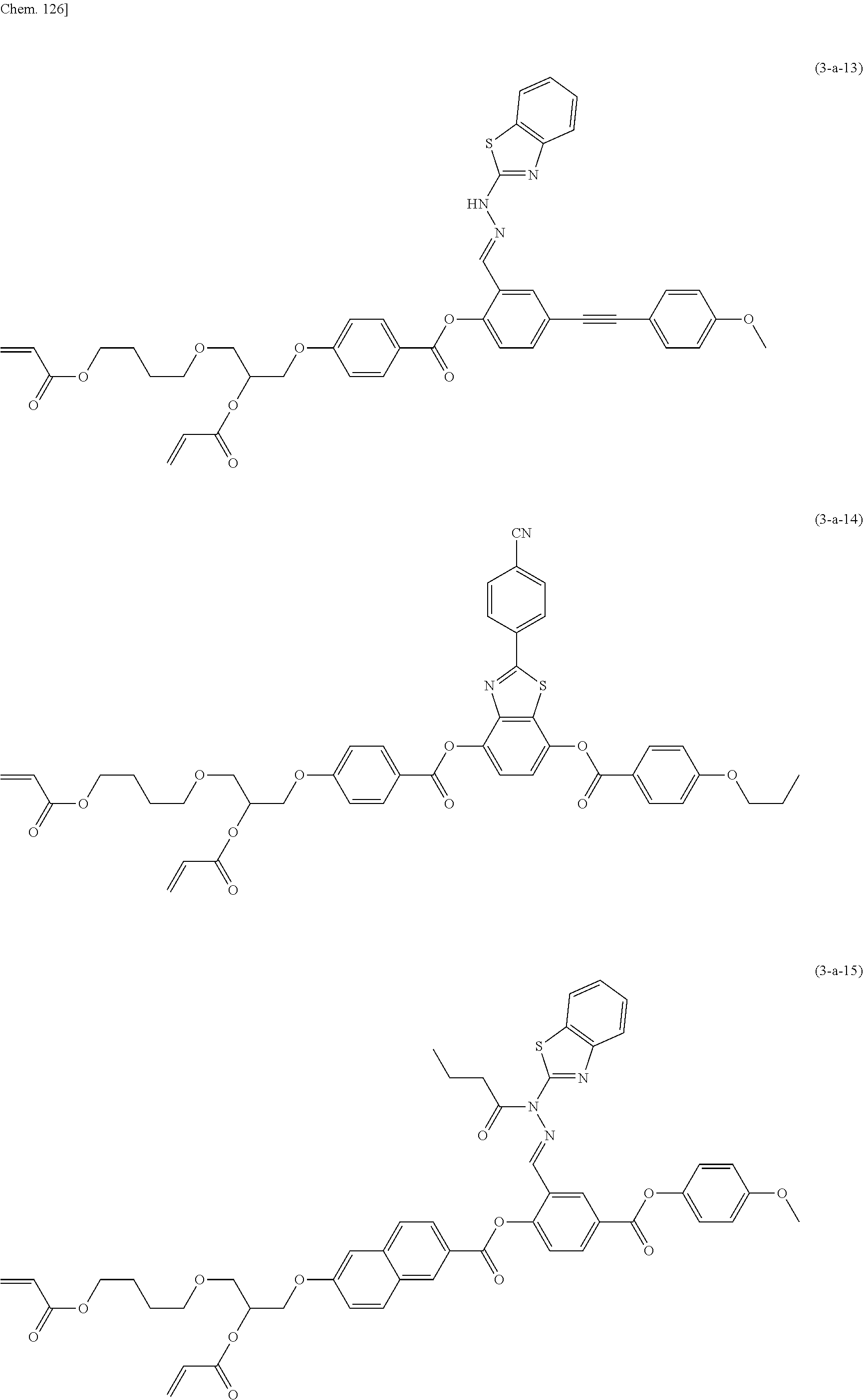

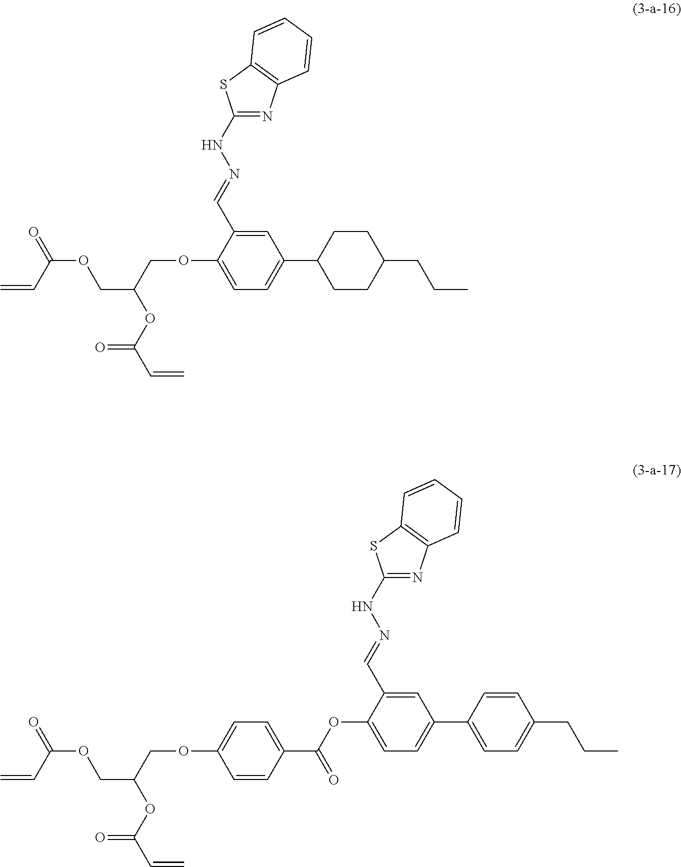

These liquid crystalline compounds may be used alone or in combination of two or more kinds thereof.

Specific examples of the compound represented by Formula (3-b) include compounds represented by Formulae (3-b-1) to (3-b-16)

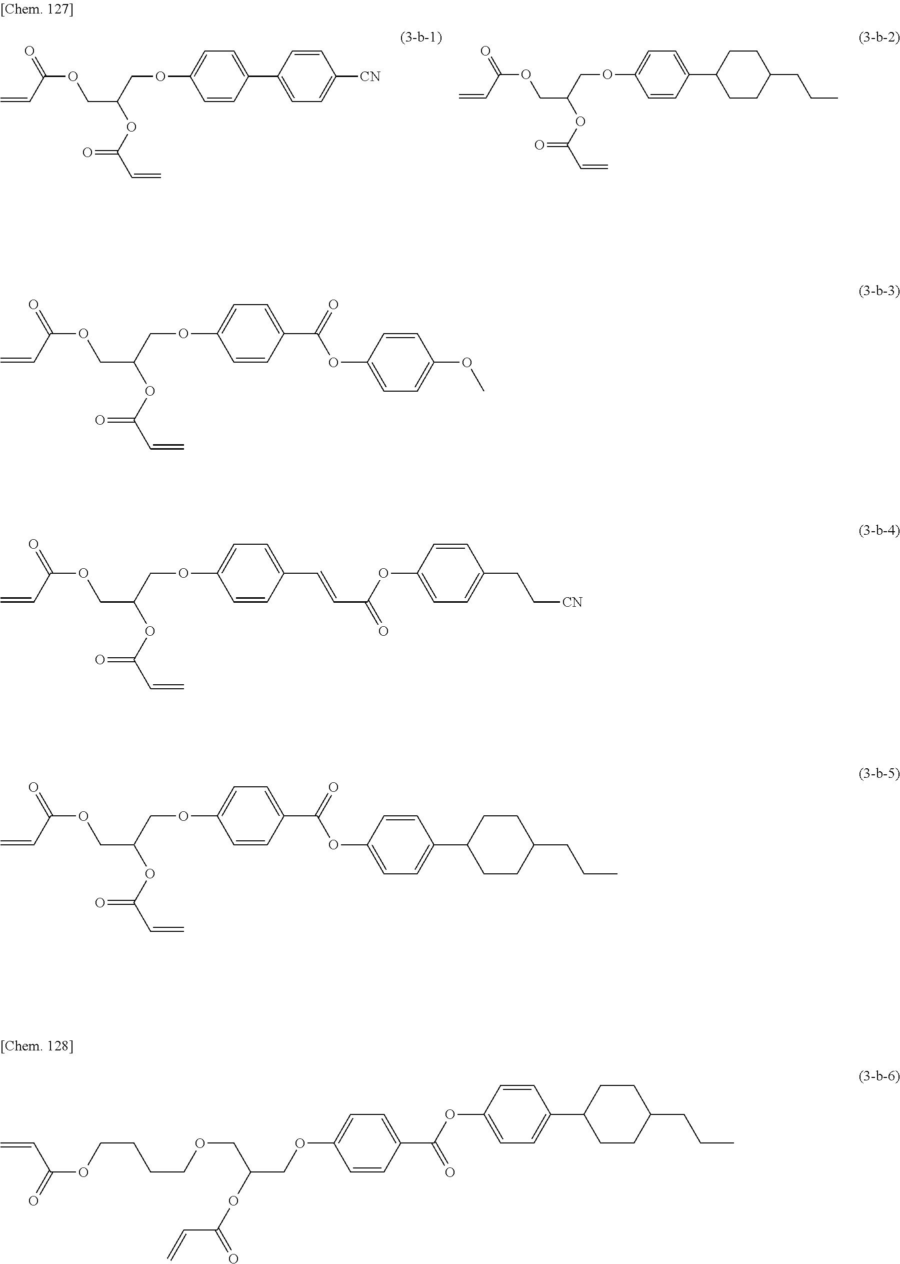

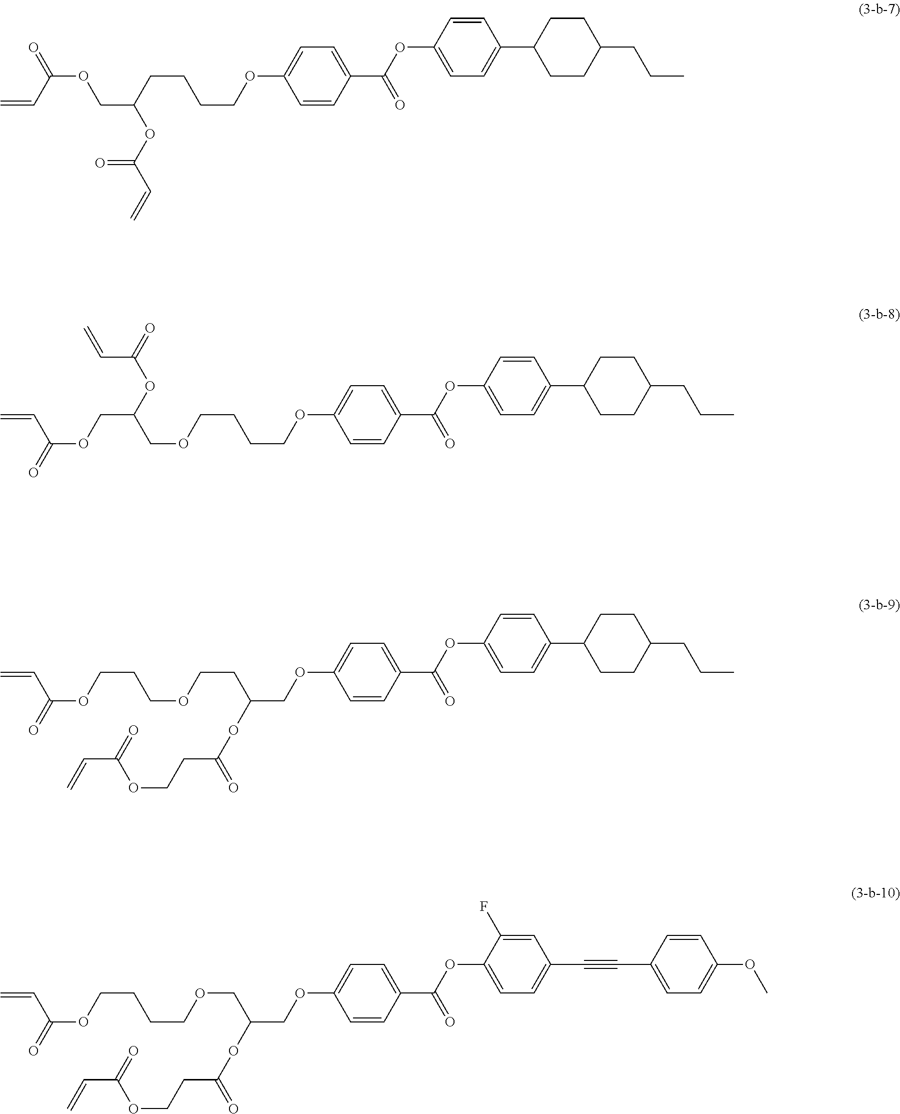

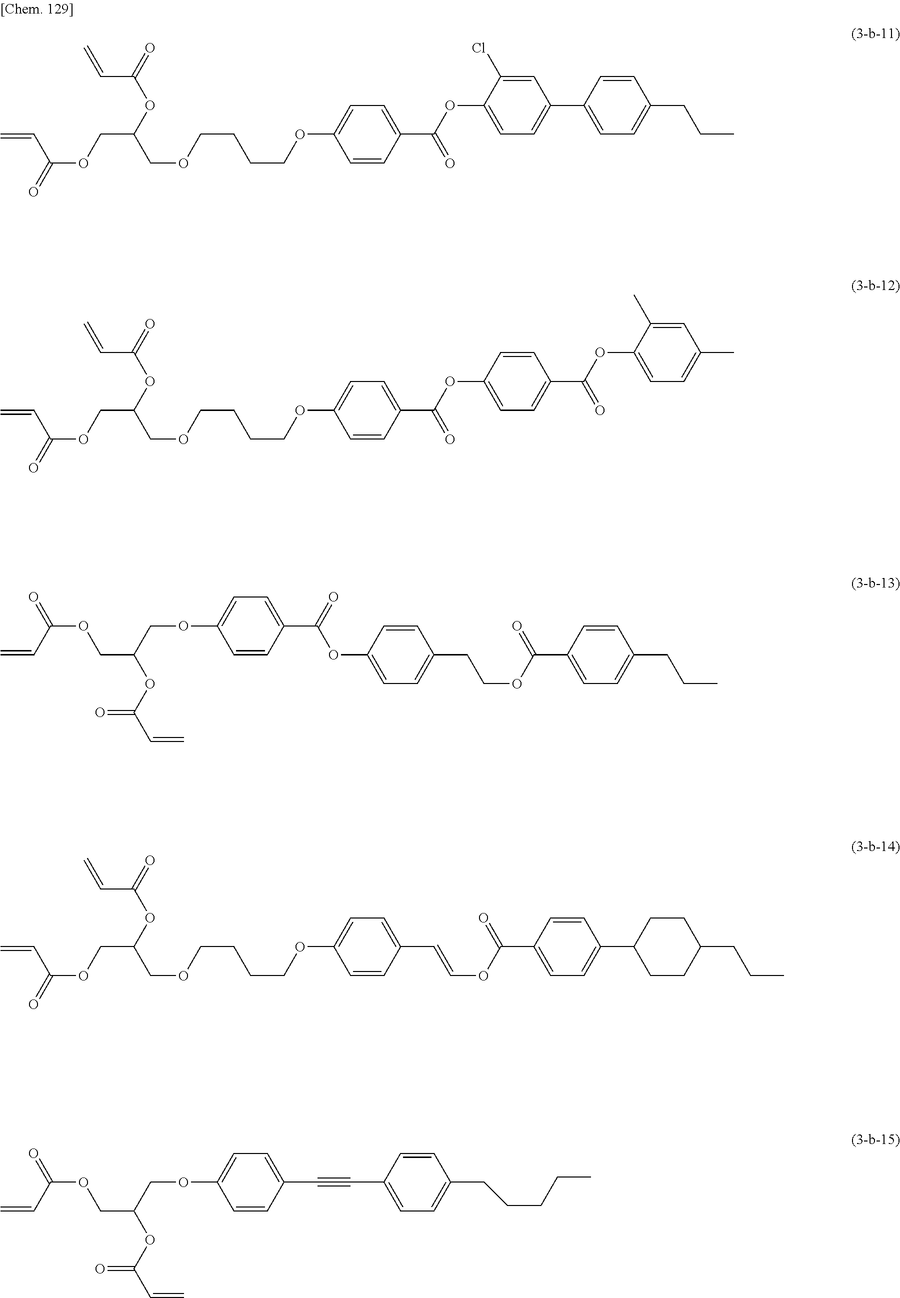

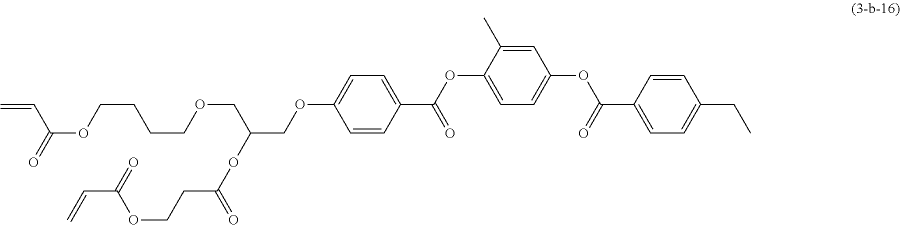 [SMILES: C=CC(=O)OCCCCOCC(COc1ccc(C(=O)Oc2ccc(OC(=O)c3ccc(CC)cc3)cc2C)cc1)OC(=O)CCOC(=O)C=C]

These liquid crystalline compounds may be used alone or in combination of two or more kinds thereof.

Specific examples of the compound represented by Formula (4-a) include compounds represented by Formulae (4-a-1) to (4-a-26).

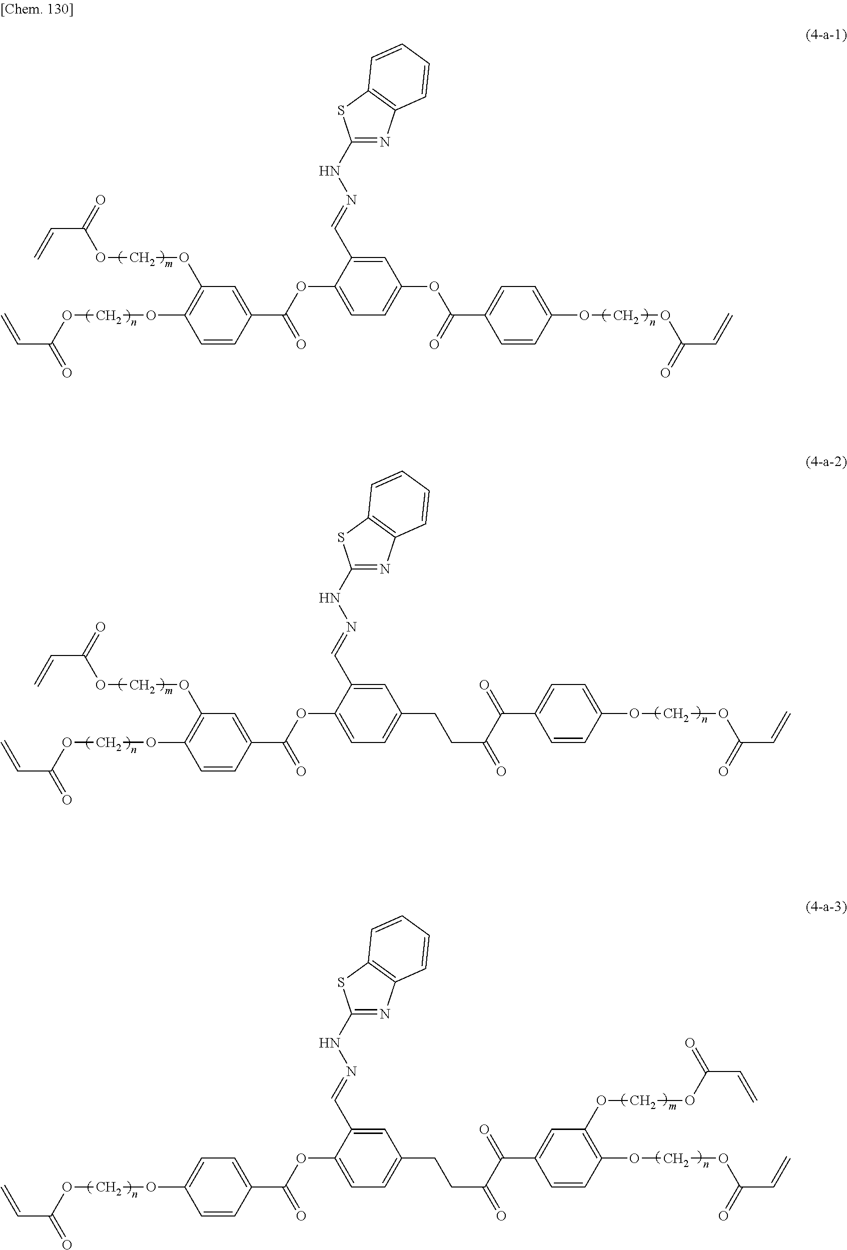

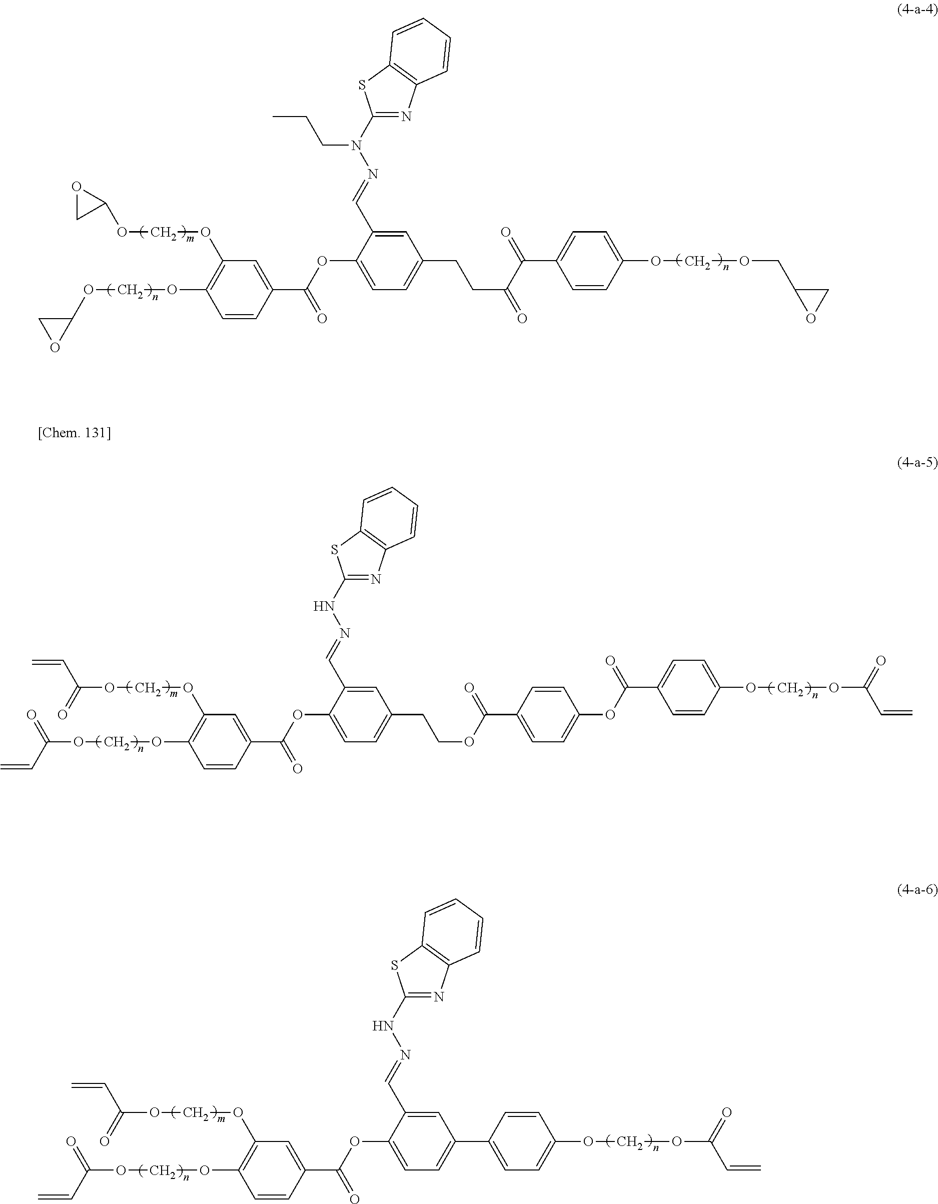

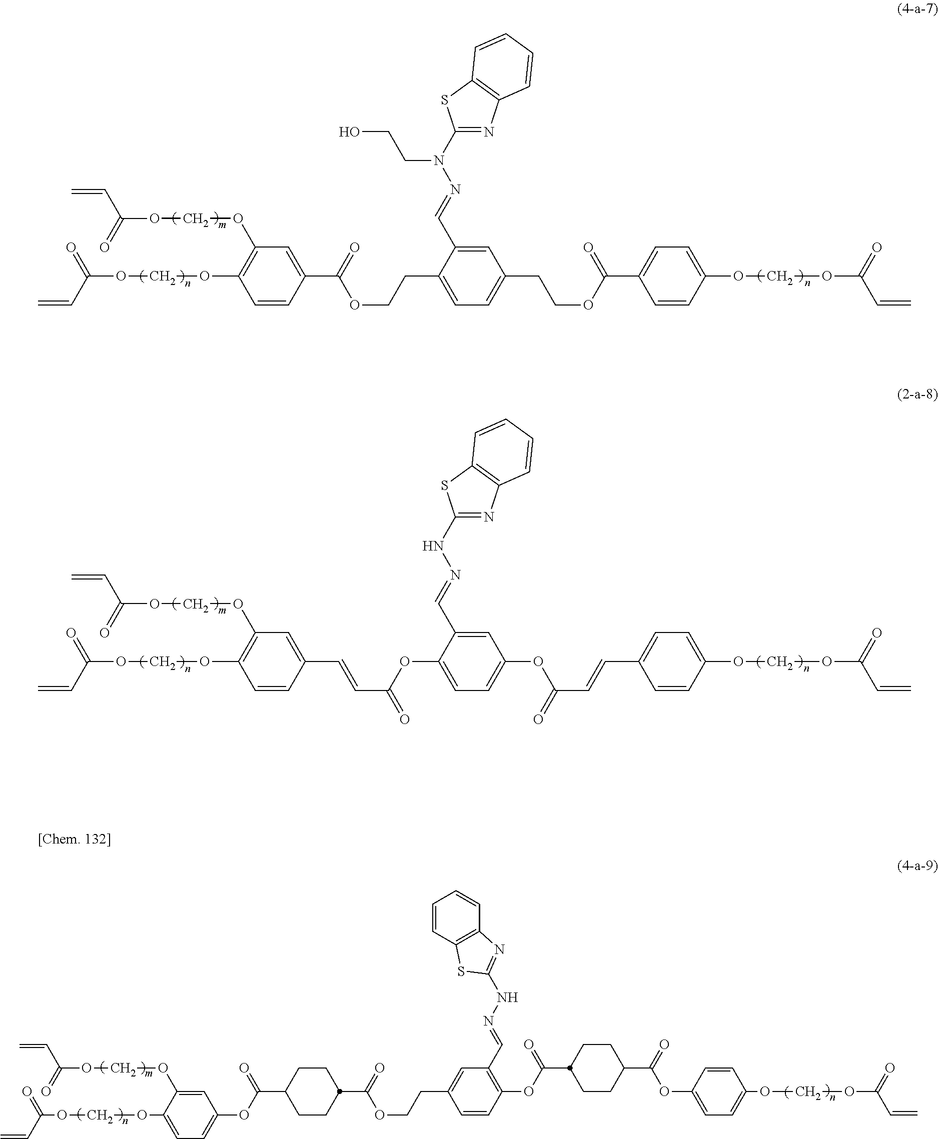

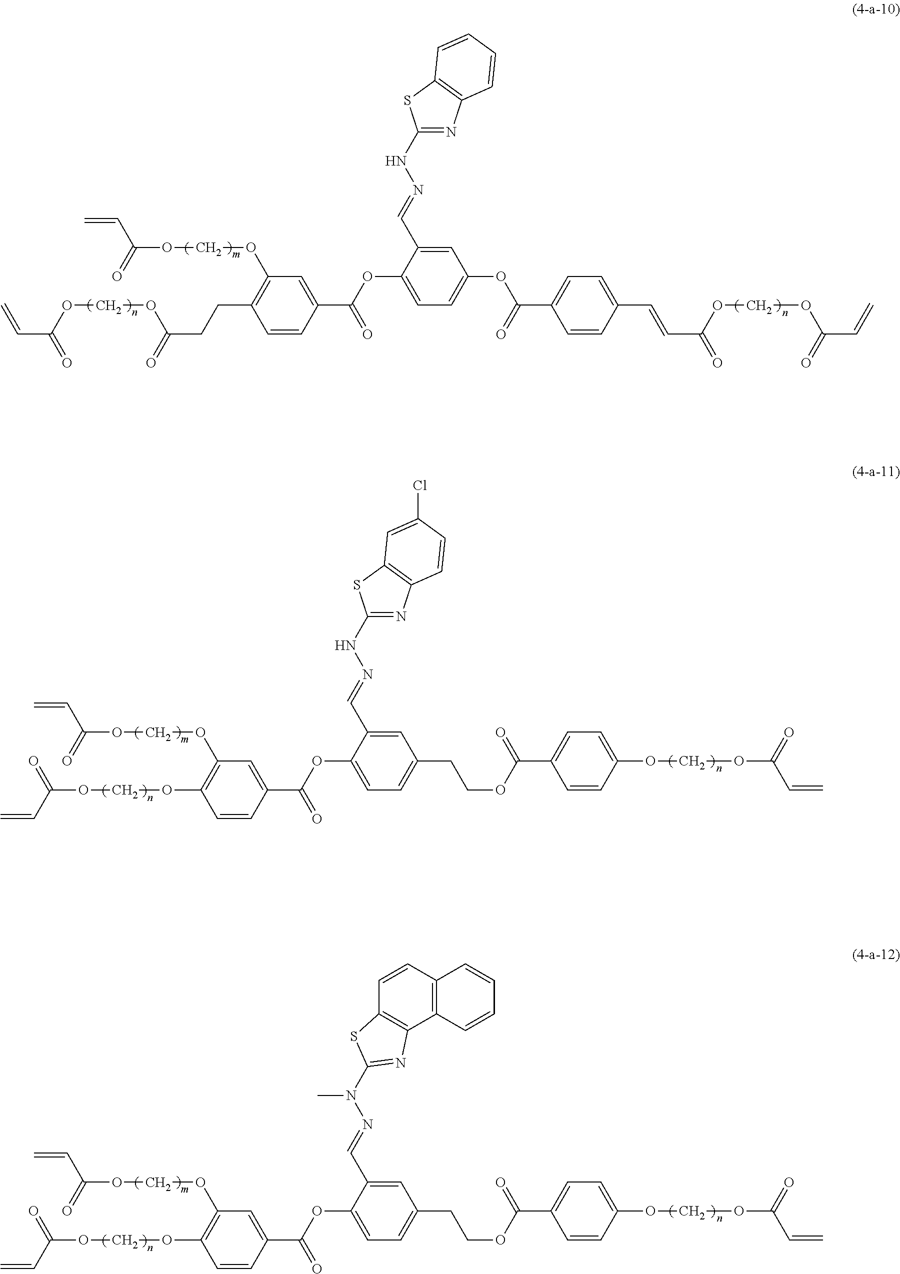

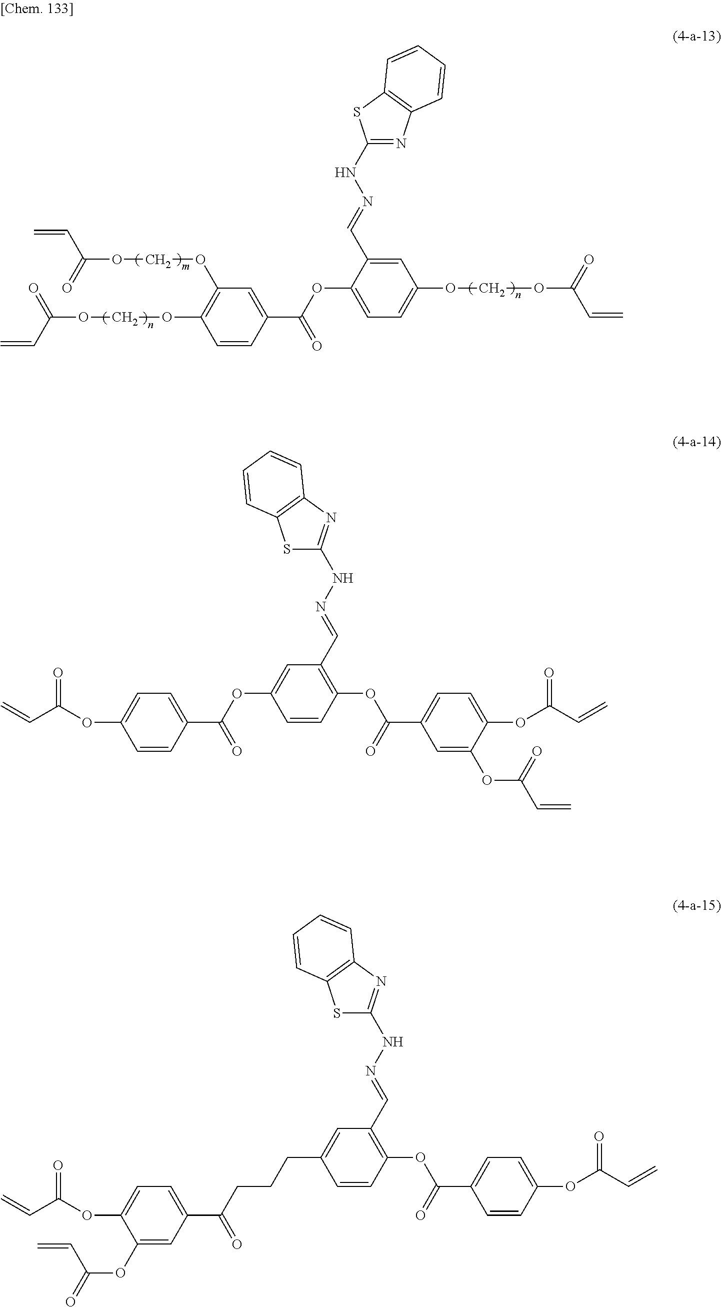

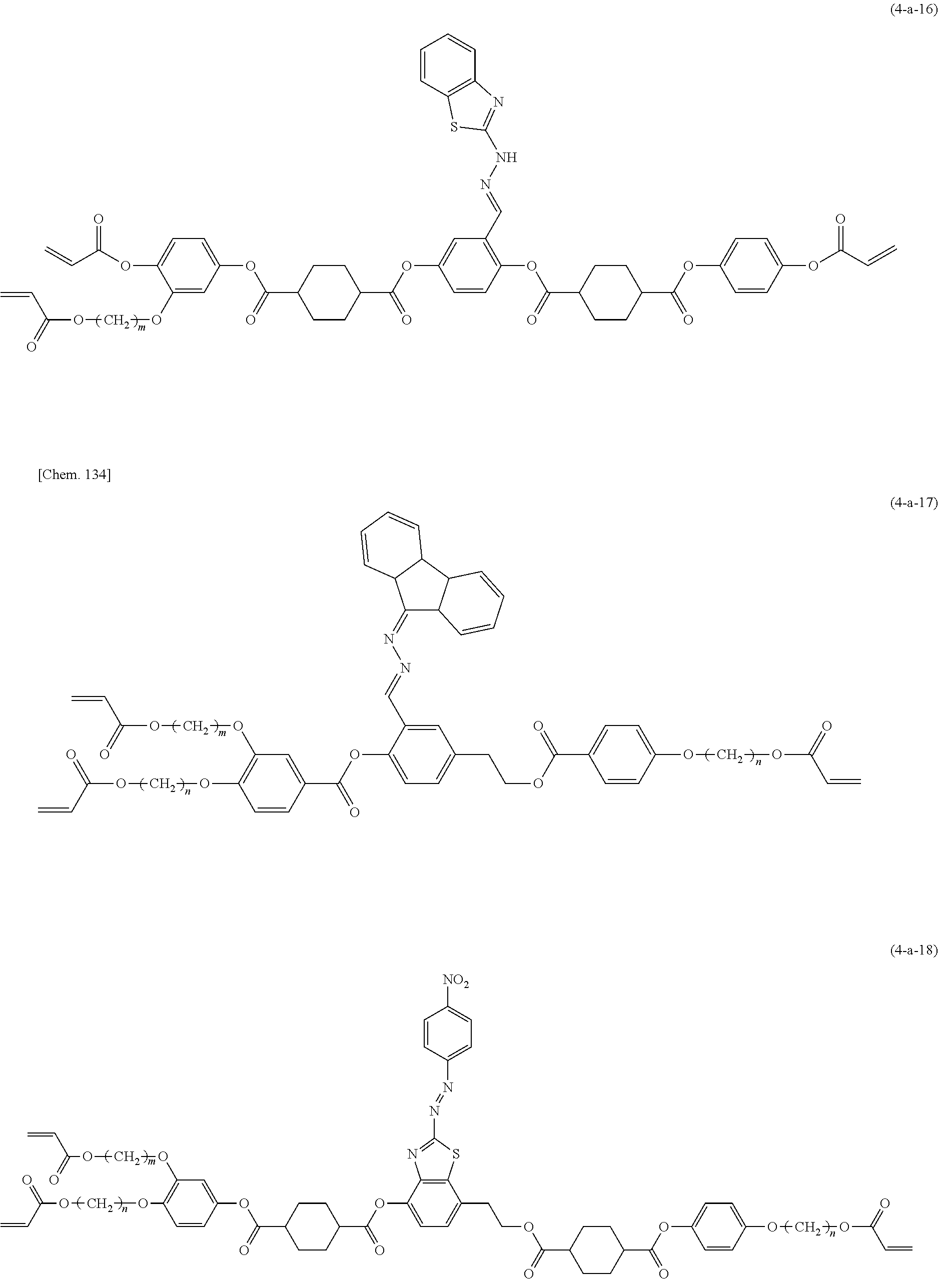

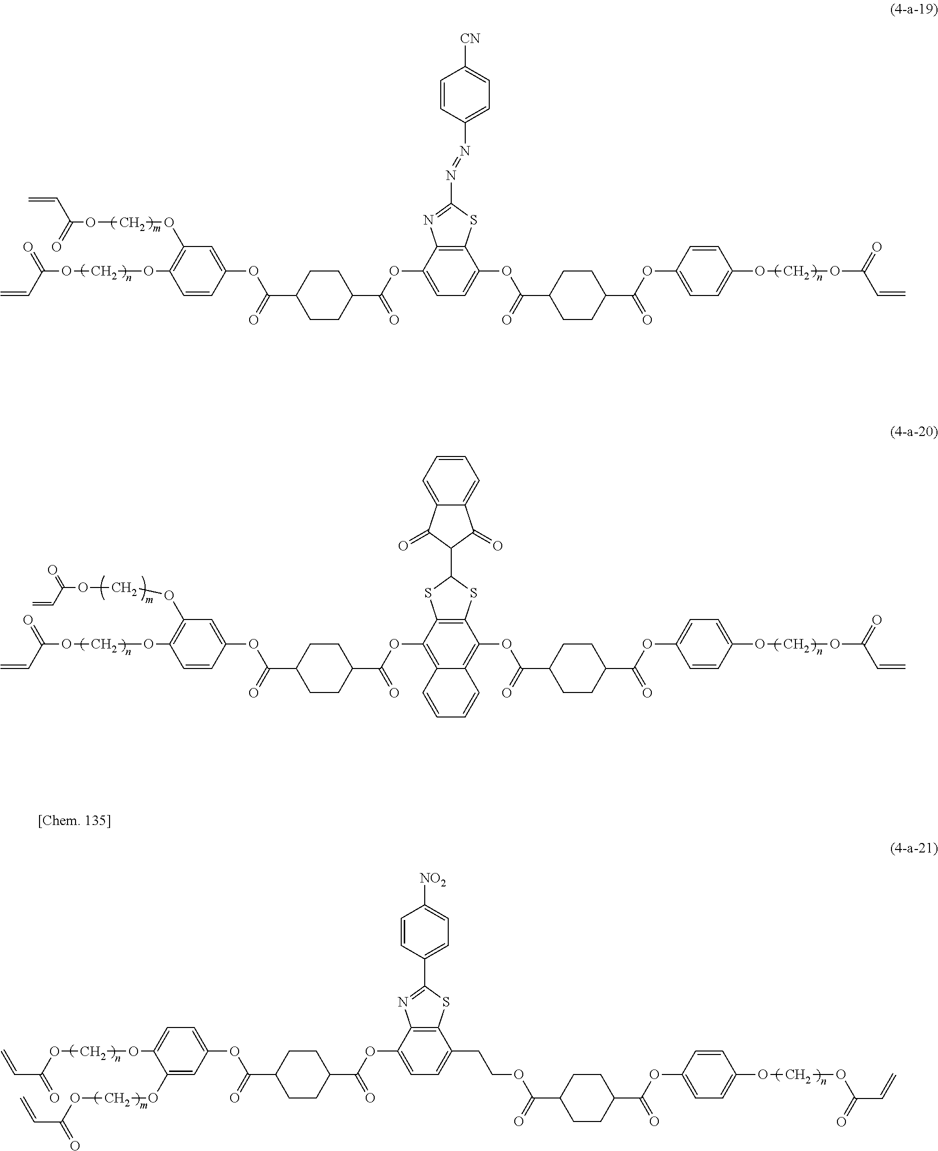

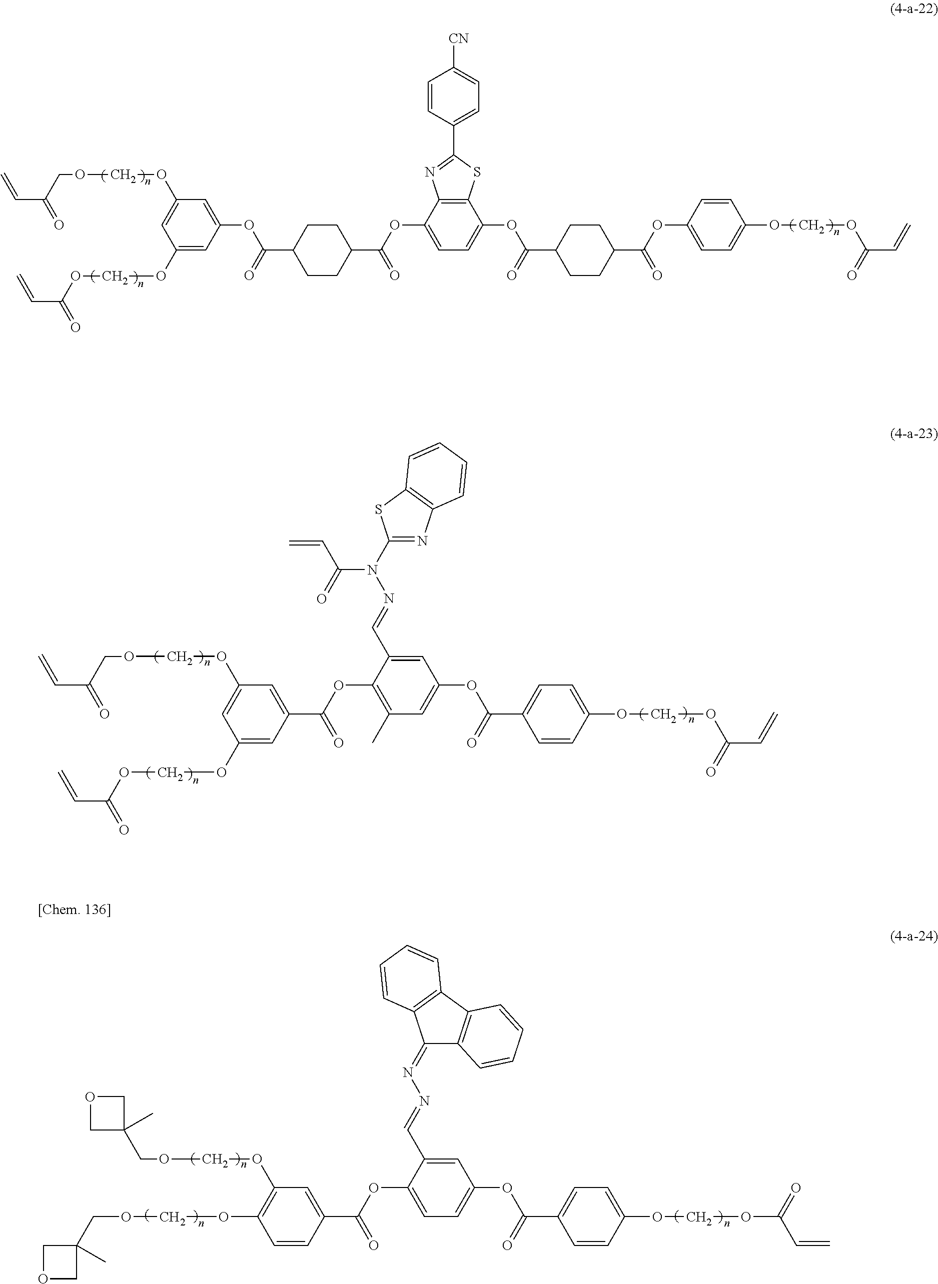

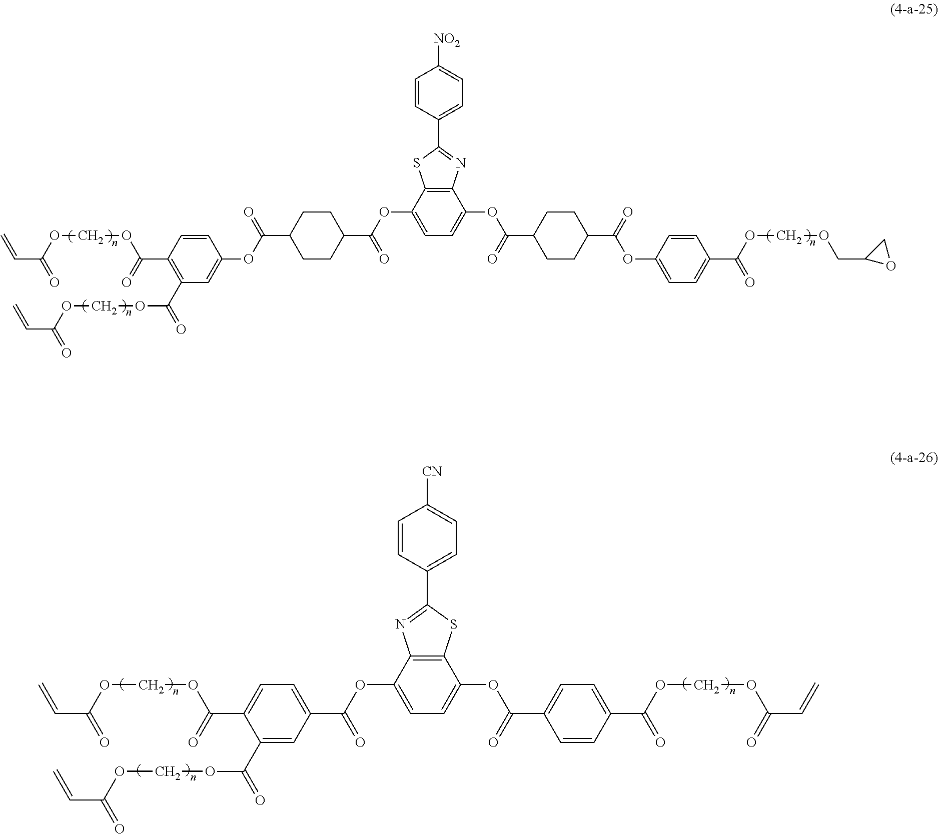 [SMILES: C=CC(=O)OCOC(=O)c1ccc(OC(=O)C2CCC(C(=O)Oc3ccc(OC(=O)C4CCC(C(=O)Oc5ccc(C(=O)OCOCC6CO6)cc5)CC4)c4nc(-c5ccc([N+](=O)[O-])cc5)sc34)CC2)cc1C(=O)OCOC(=O)C=C ; C=CC(=O)OCOC(=O)c1ccc(C(=O)Oc2ccc(OC(=O)c3ccc(C(=O)OCOC(=O)C=C)c(C(=O)OCOC(=O)C=C)c3)c3nc(-c4ccc(C#N)cc4)sc23)cc1]

(In the formulae, m and n each independently represent an integer of 1 to 10.)

These liquid crystalline compounds may be used alone or in combination of two or more kinds thereof.

Preferred specific examples of the compound represented by Formula (4-b) include compounds represented by Formulae (4-b-1) to (4-b-29).

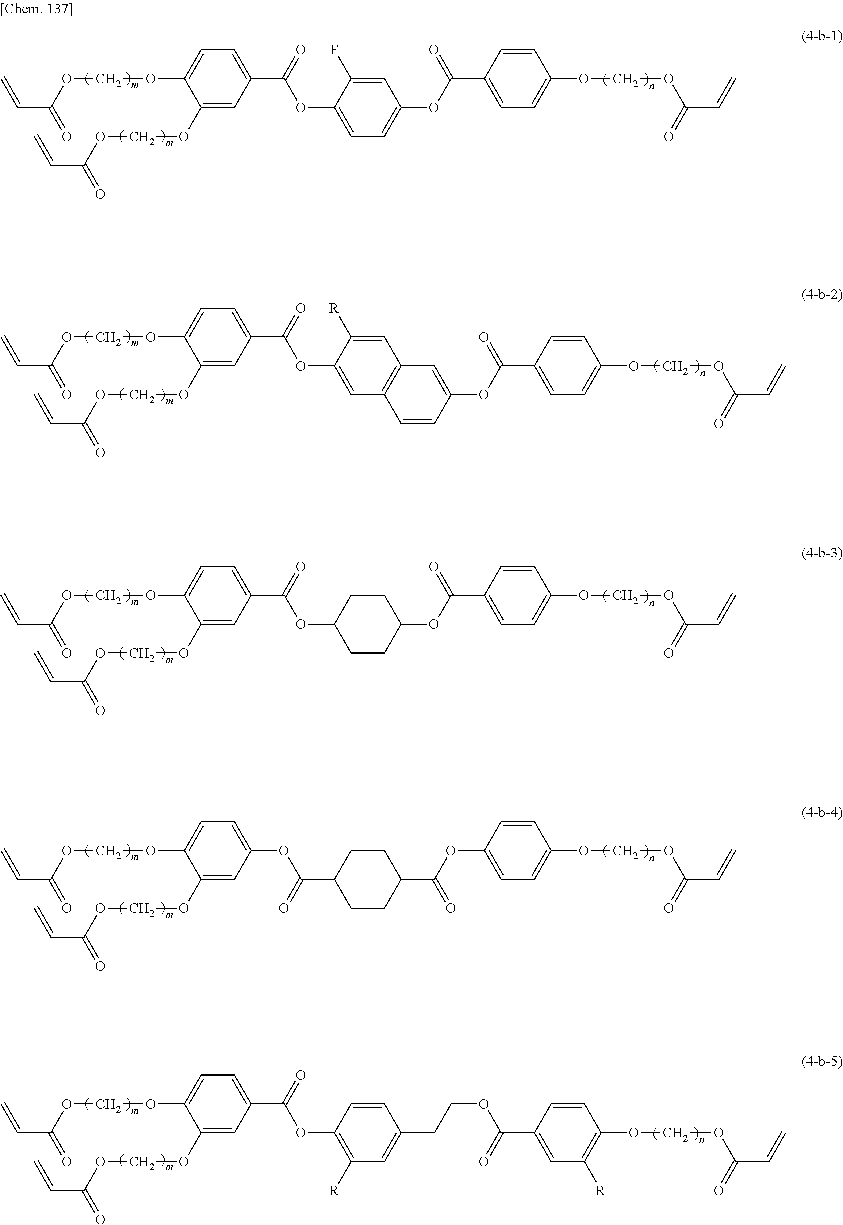

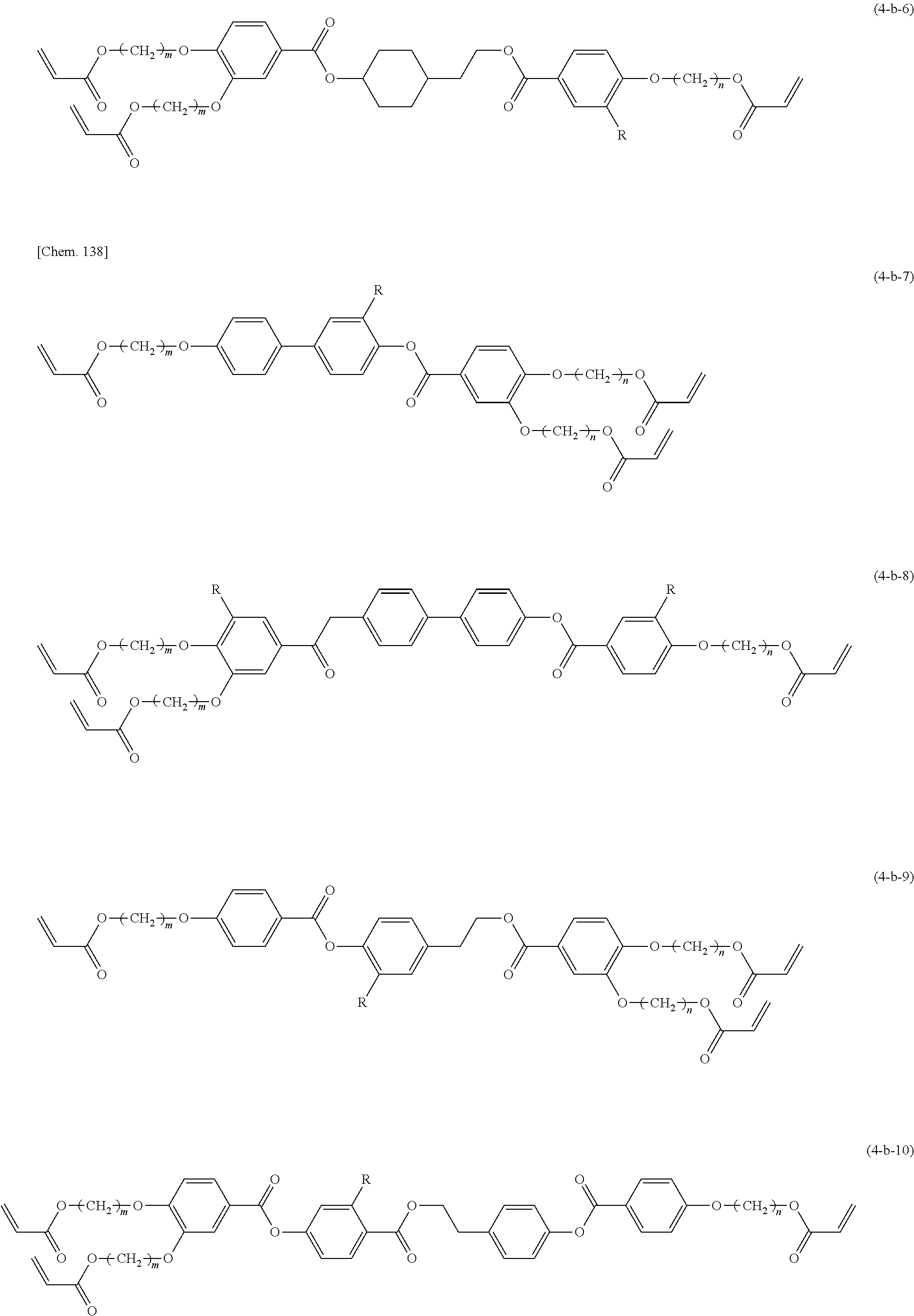

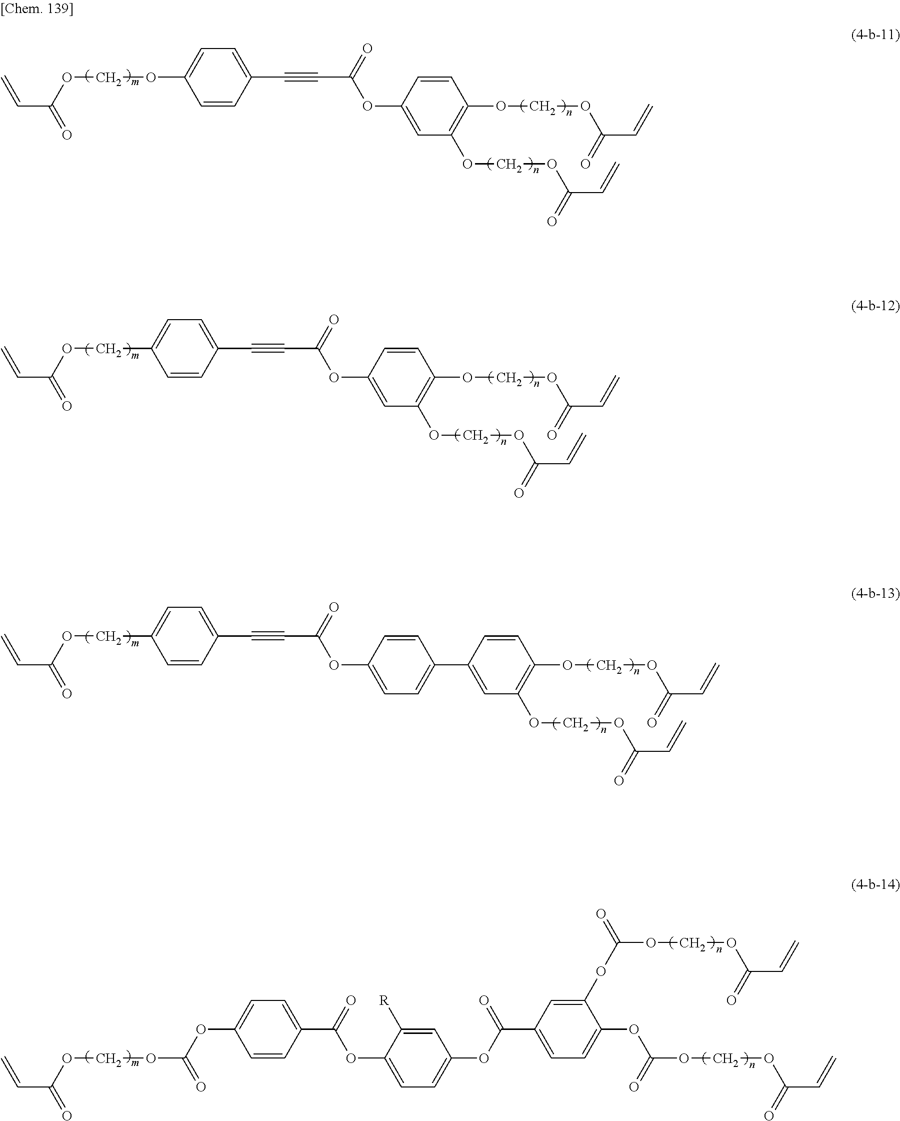

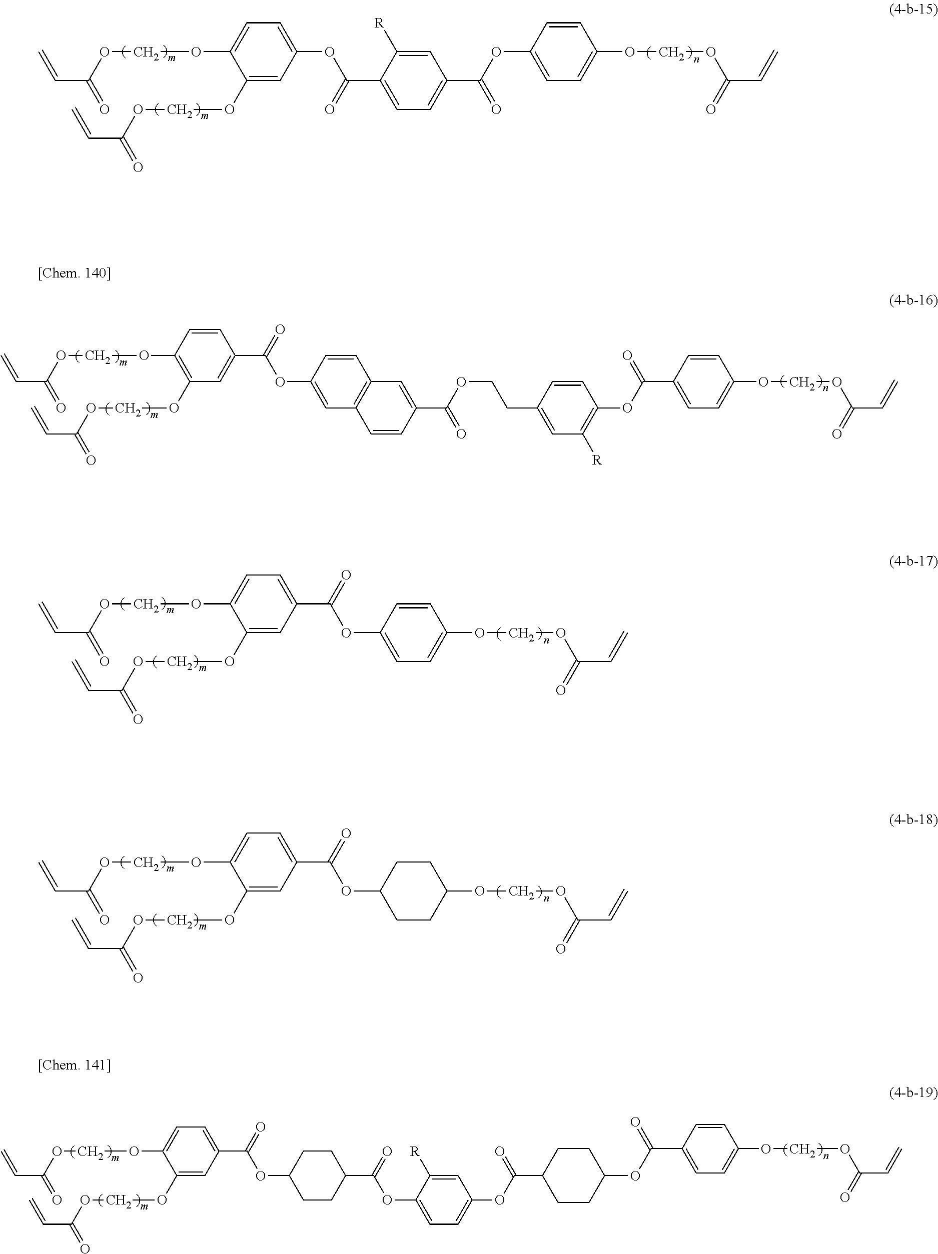

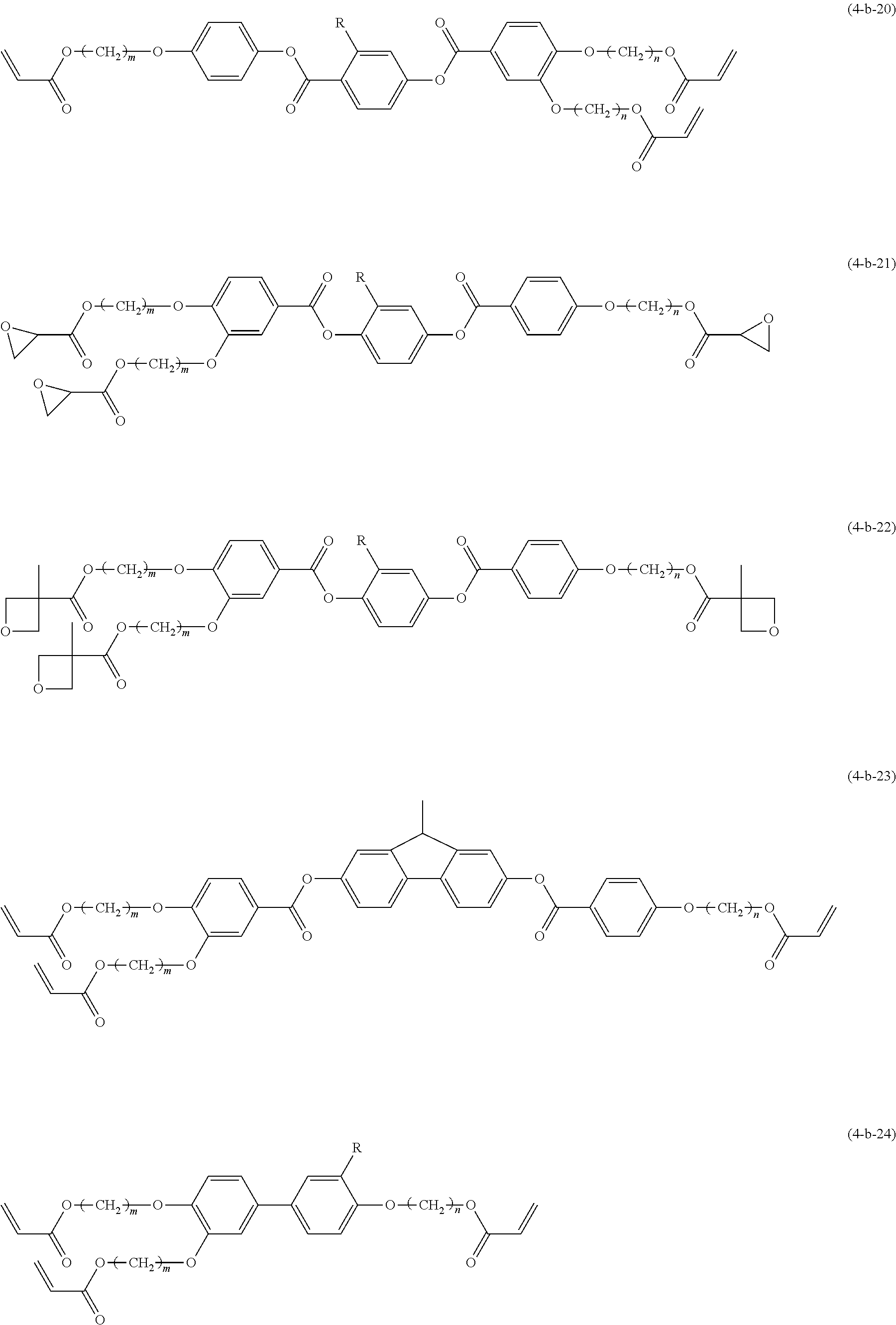

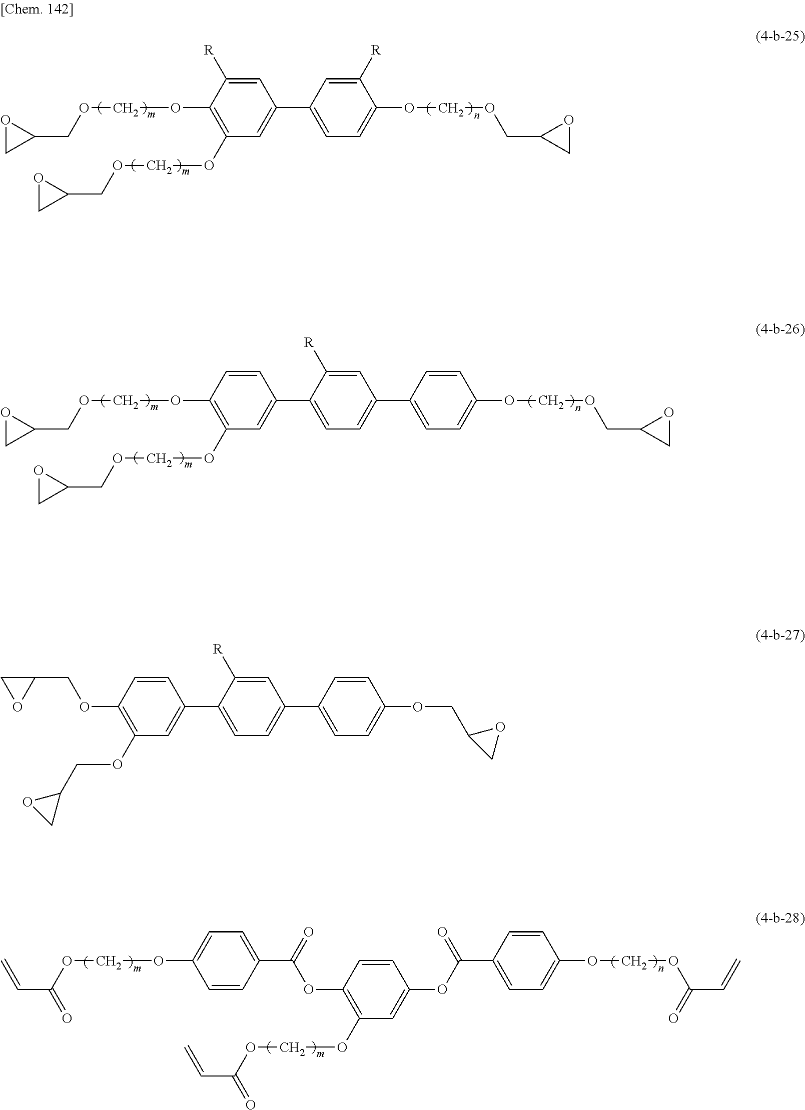

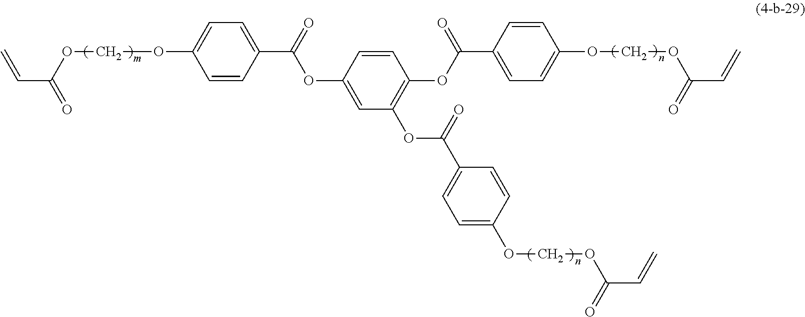 [SMILES: C=CC(=O)OCOc1ccc(C(=O)Oc2ccc(OC(=O)c3ccc(OCOC(=O)C=C)cc3)c(OC(=O)c3ccc(OCOC(=O)C=C)cc3)c2)cc1]

(In the formulae, m and n each independently represent an integer of 1 to 10. R represents a hydrogen atom, a halogen atom, an alkyl group having 1 to 6 carbon atoms, an alkoxy group having 1 to 6 carbon atom, or a cyano group. In a case where these groups represent an alkyl group having 1 to 6 carbon atoms or an alkoxy group having 1 to 6 carbon atoms, all groups may be unsubstituted or substituted with one or two or more halogen atoms.)

These liquid crystalline compounds may be used alone or in combination of two or more kinds thereof.

Specific examples of the compound represented by Formula (5-a) include compounds represented by Formulae (5-a-1) to (5-a-29).

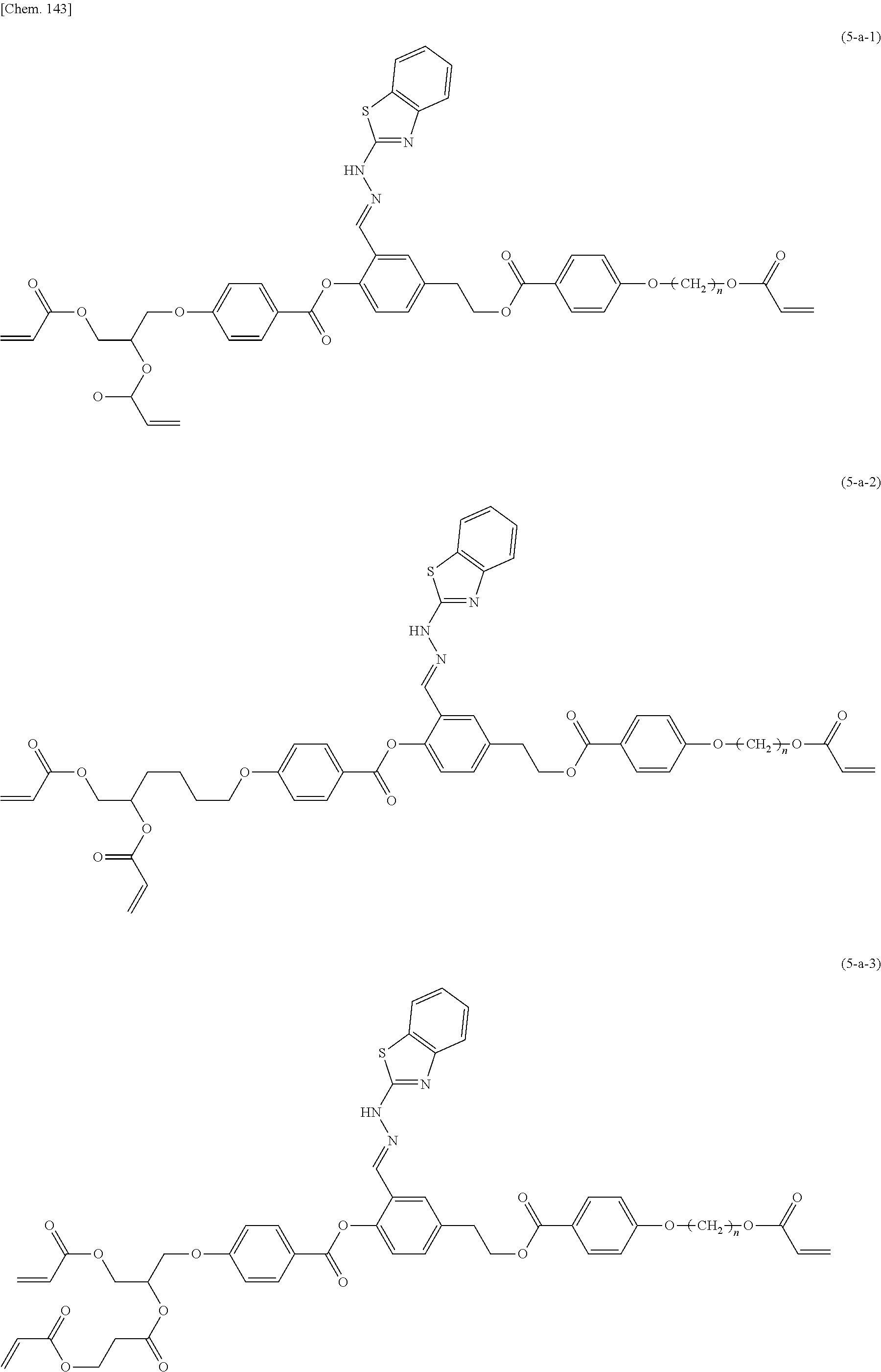

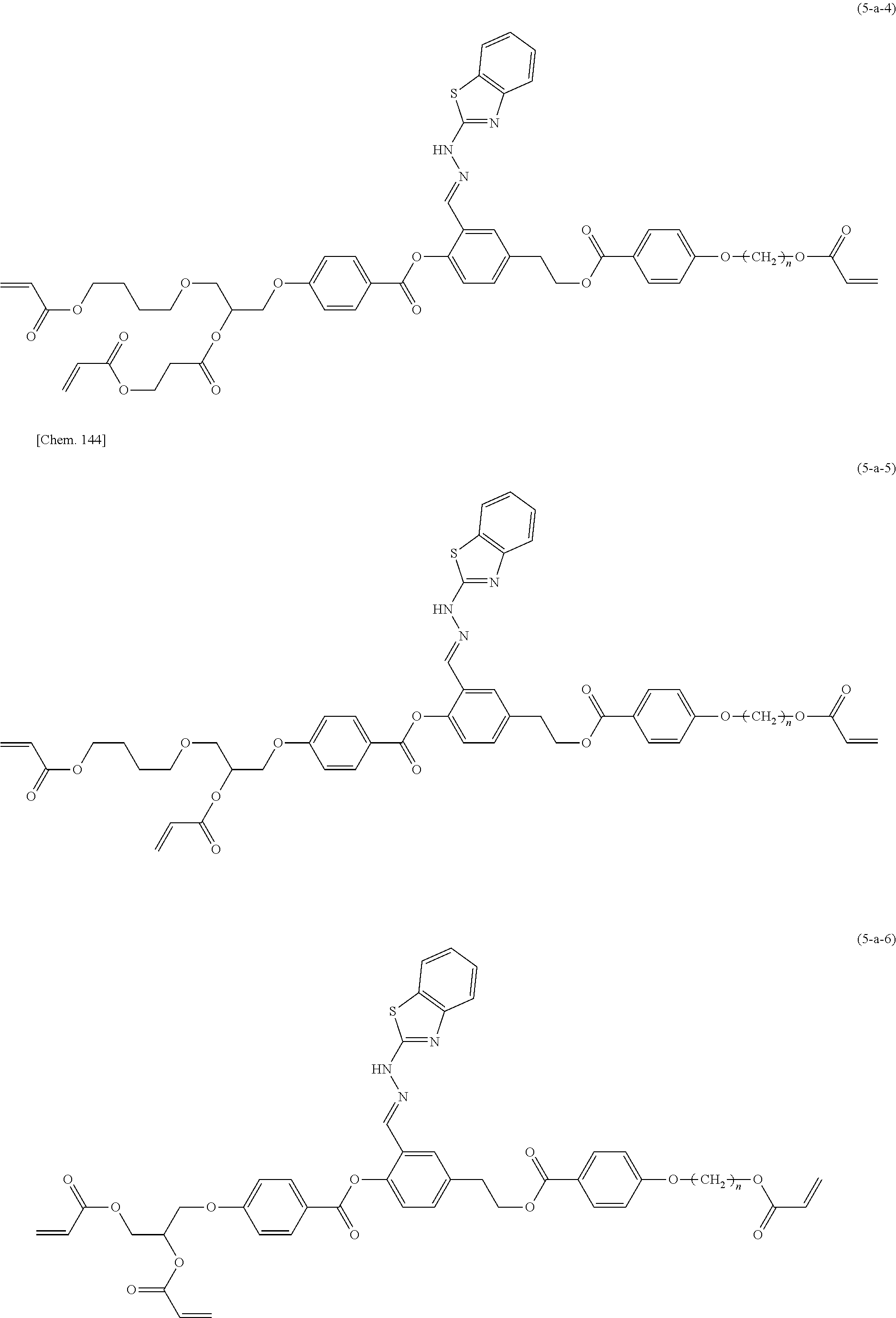

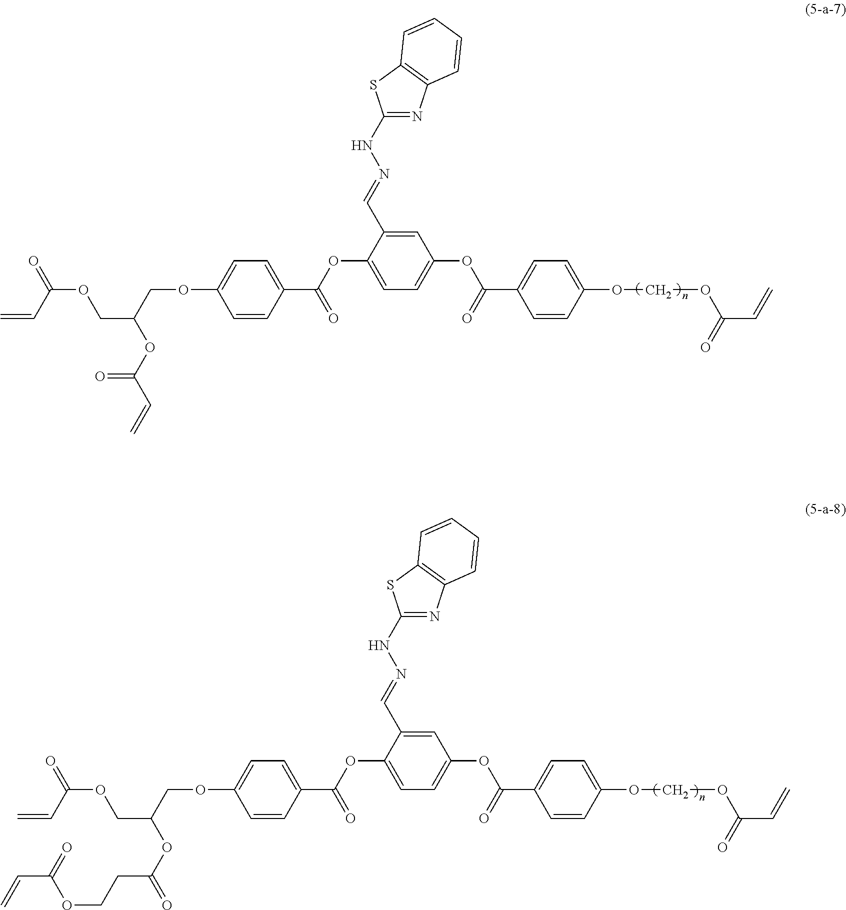

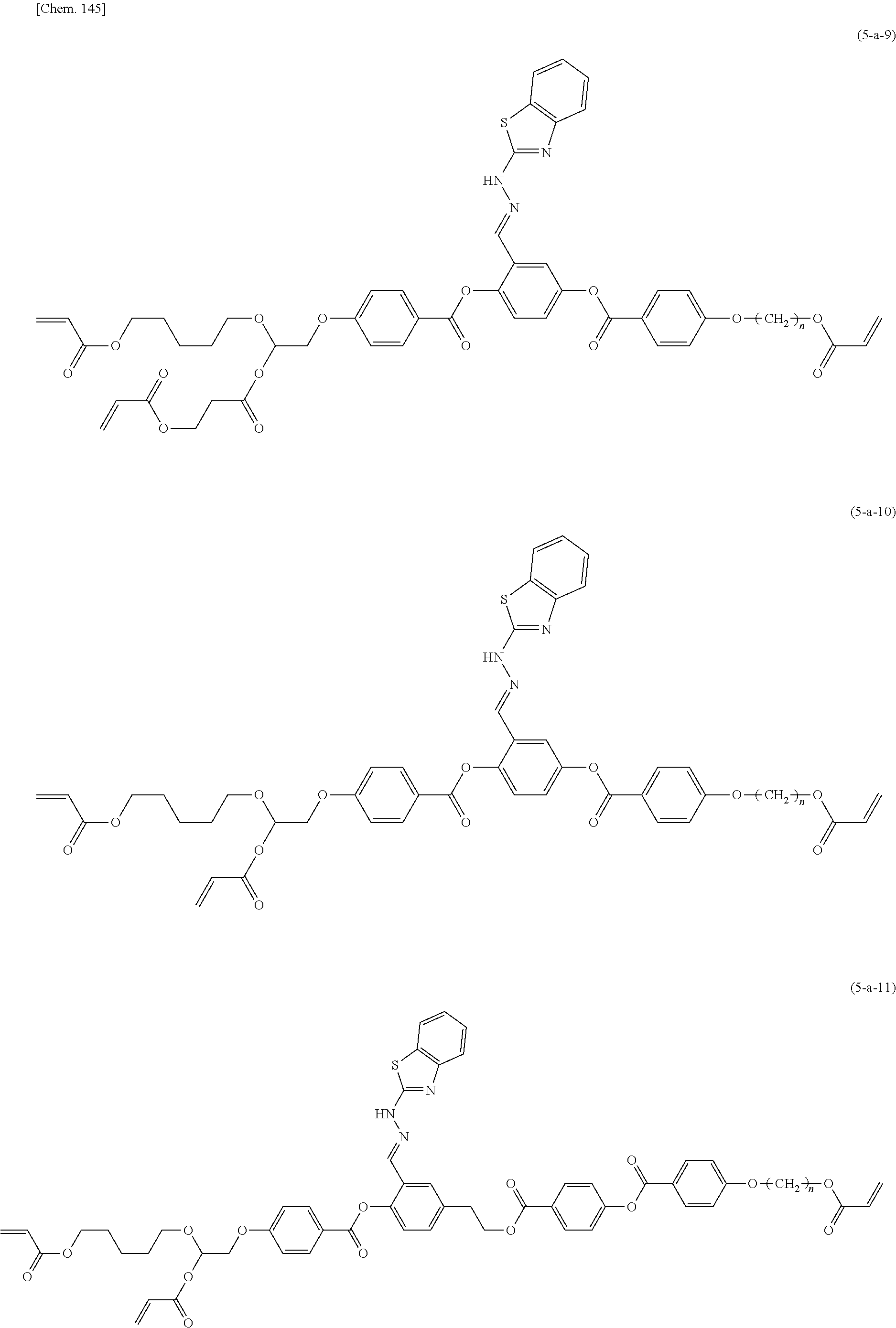

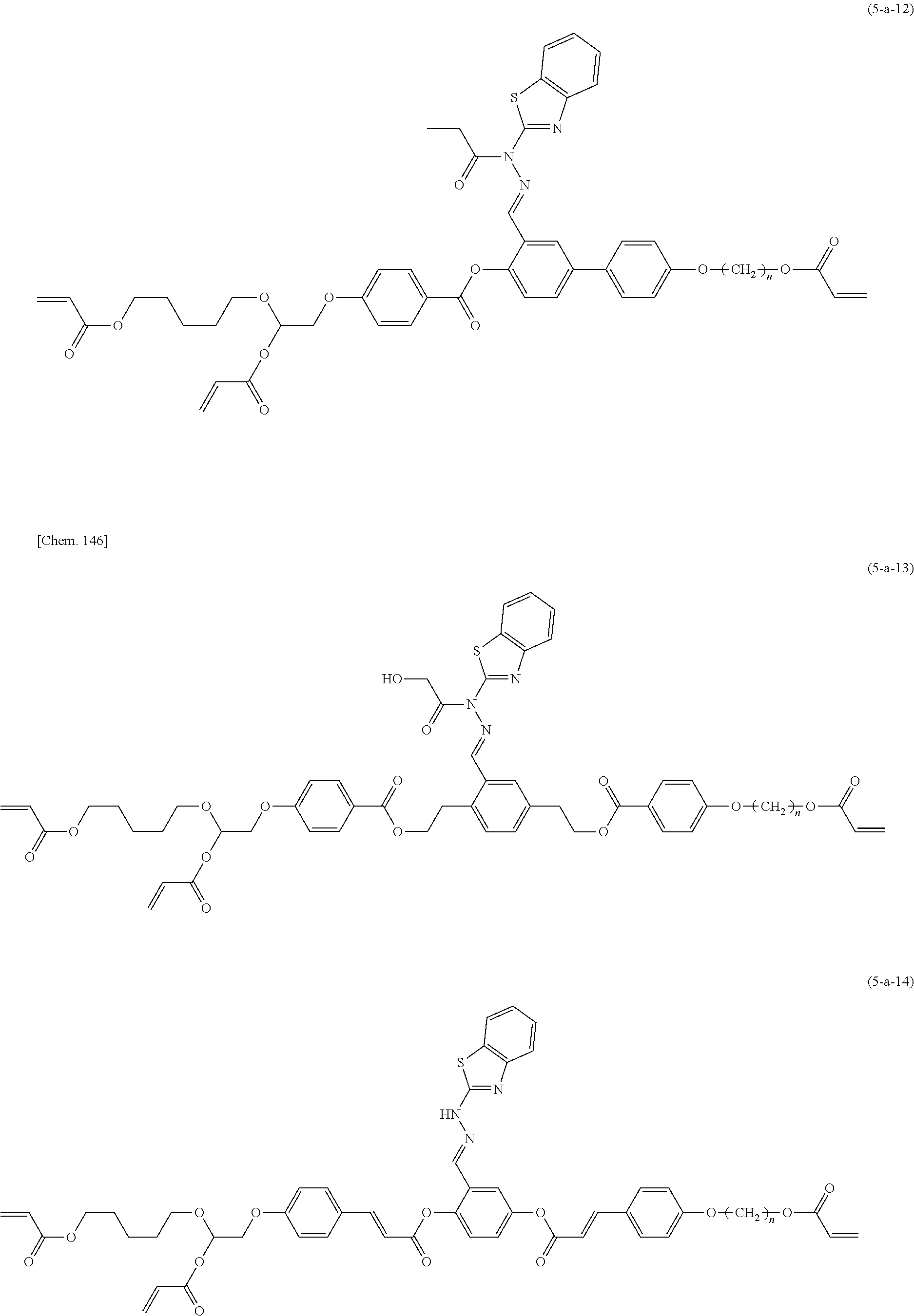

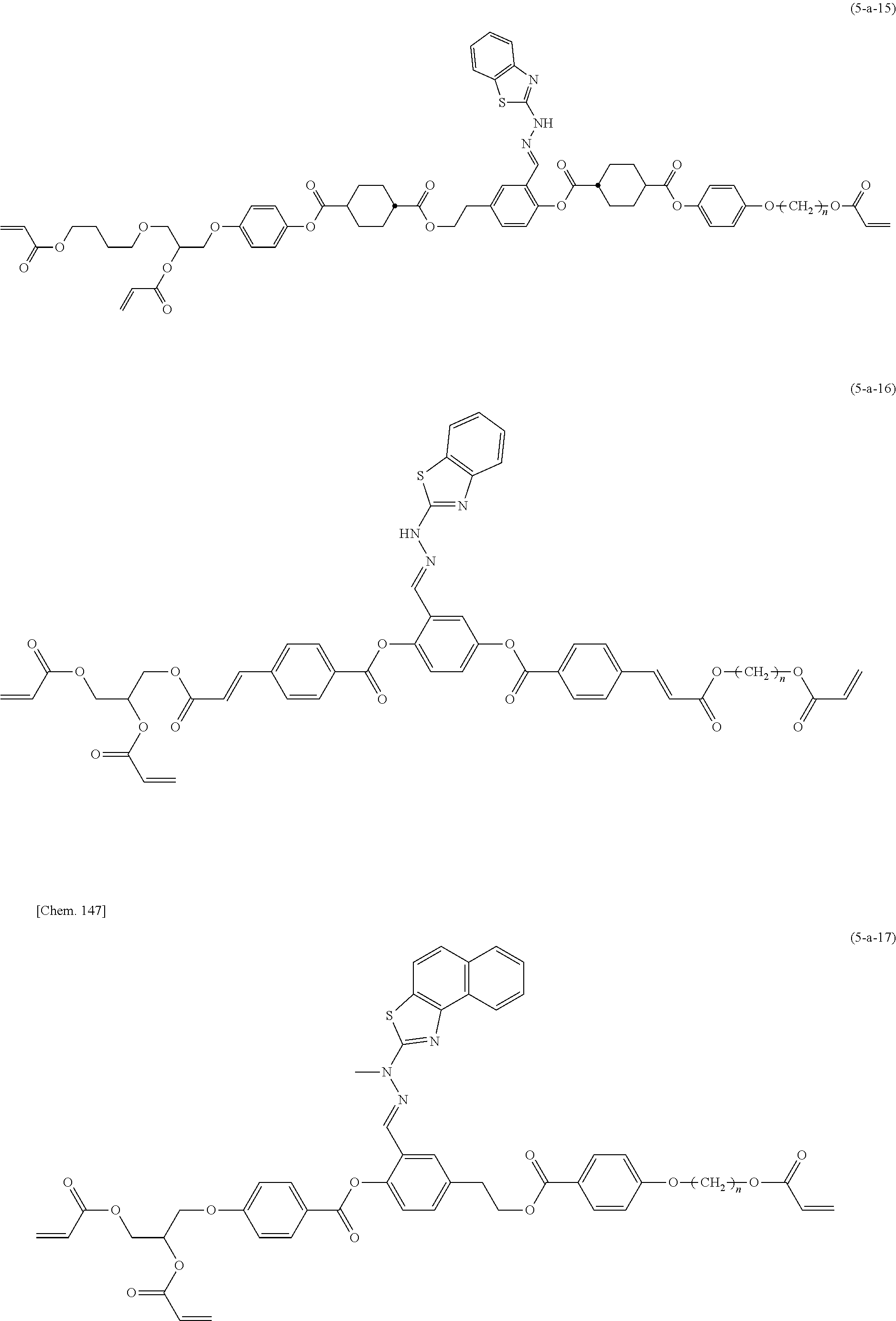

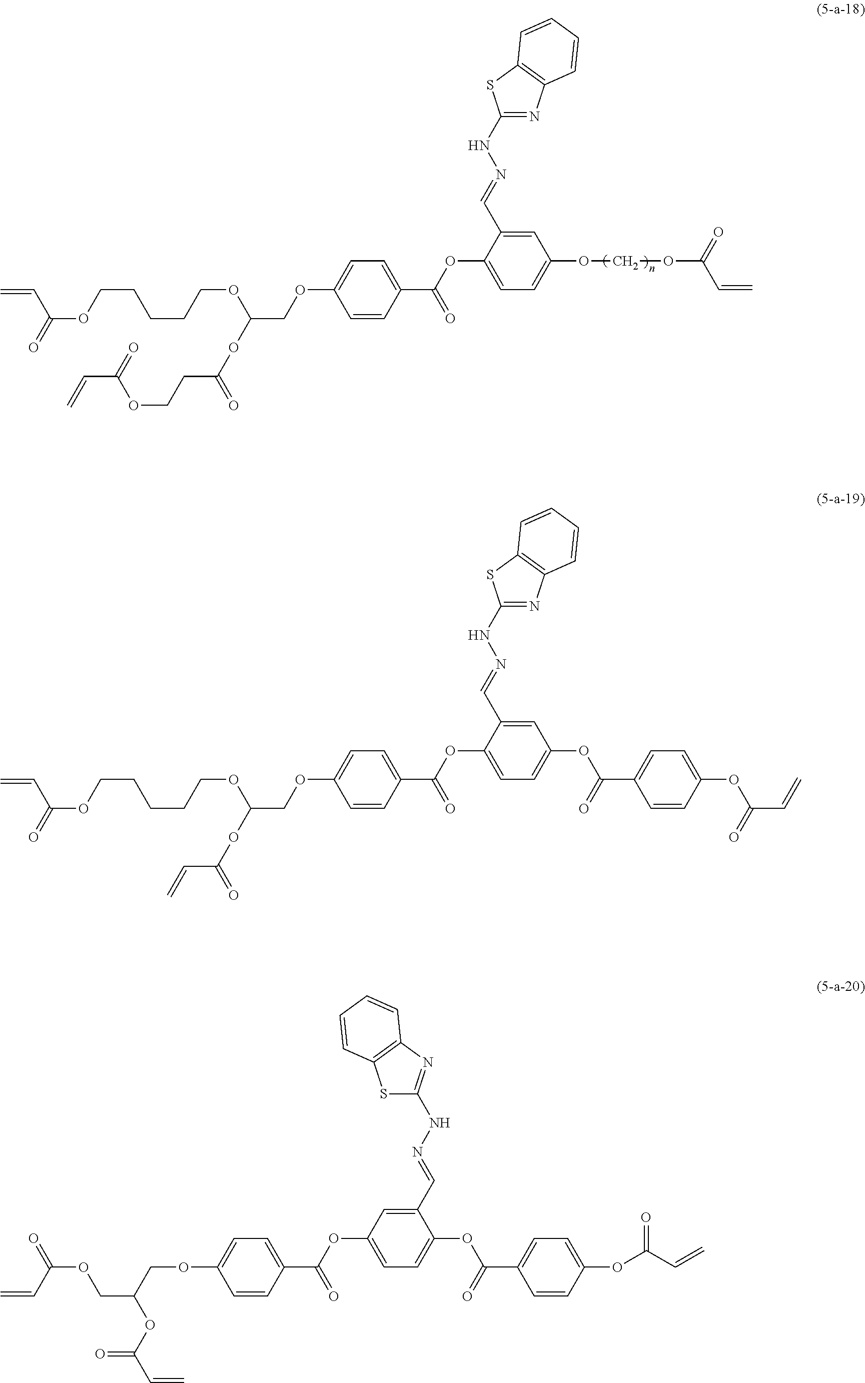

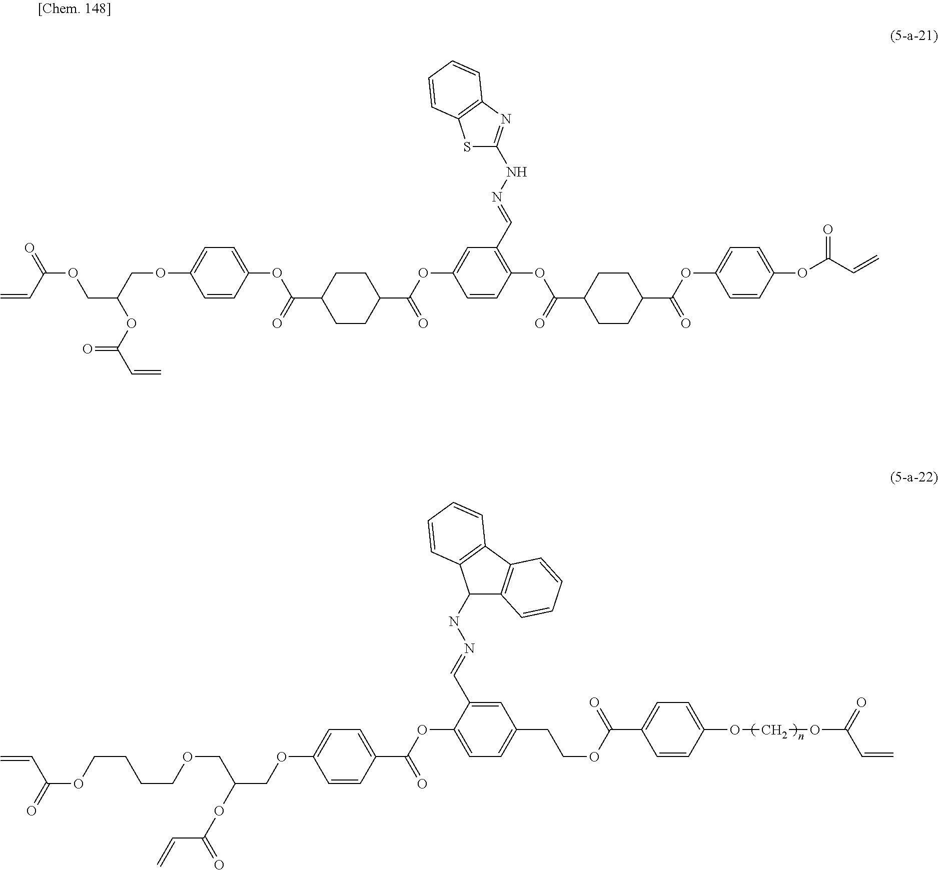

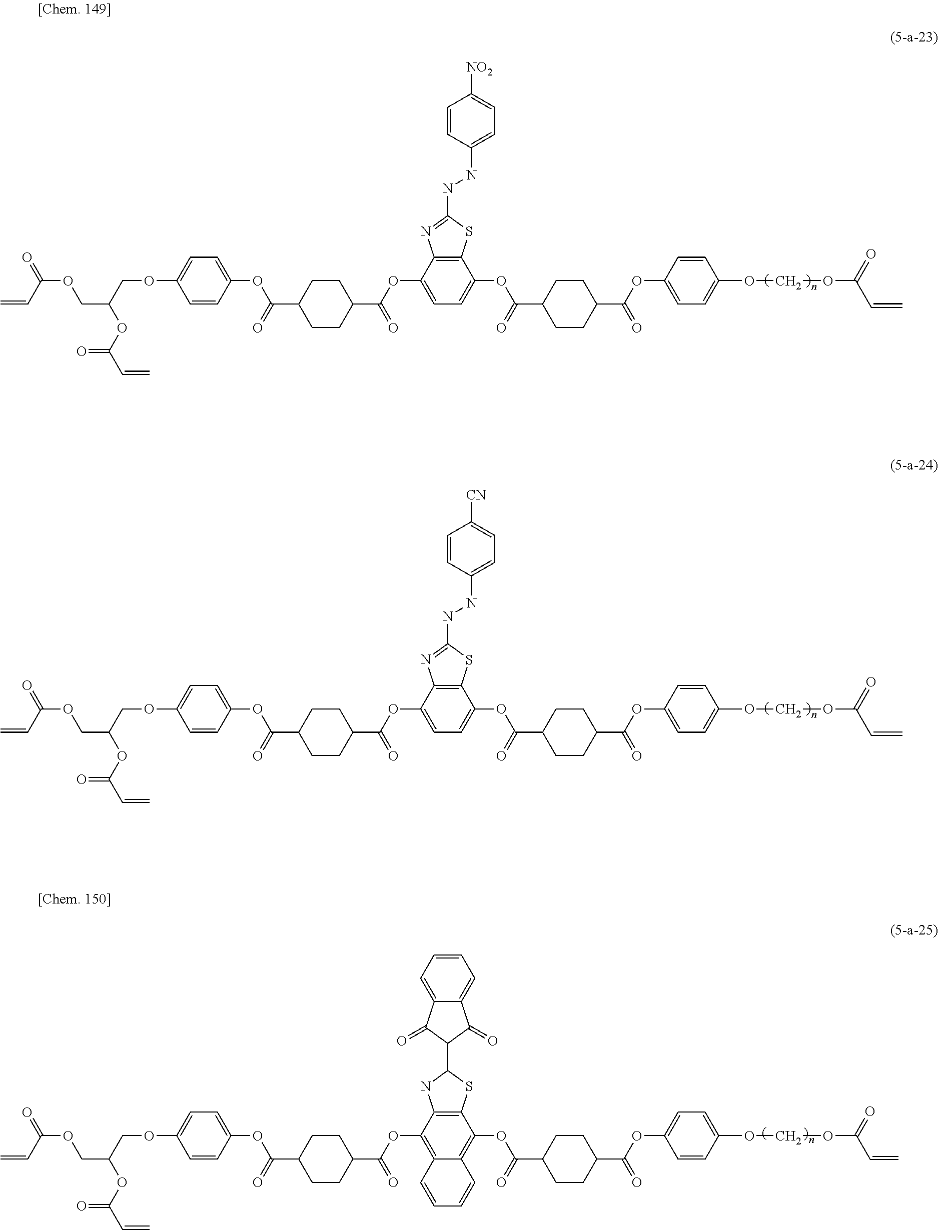

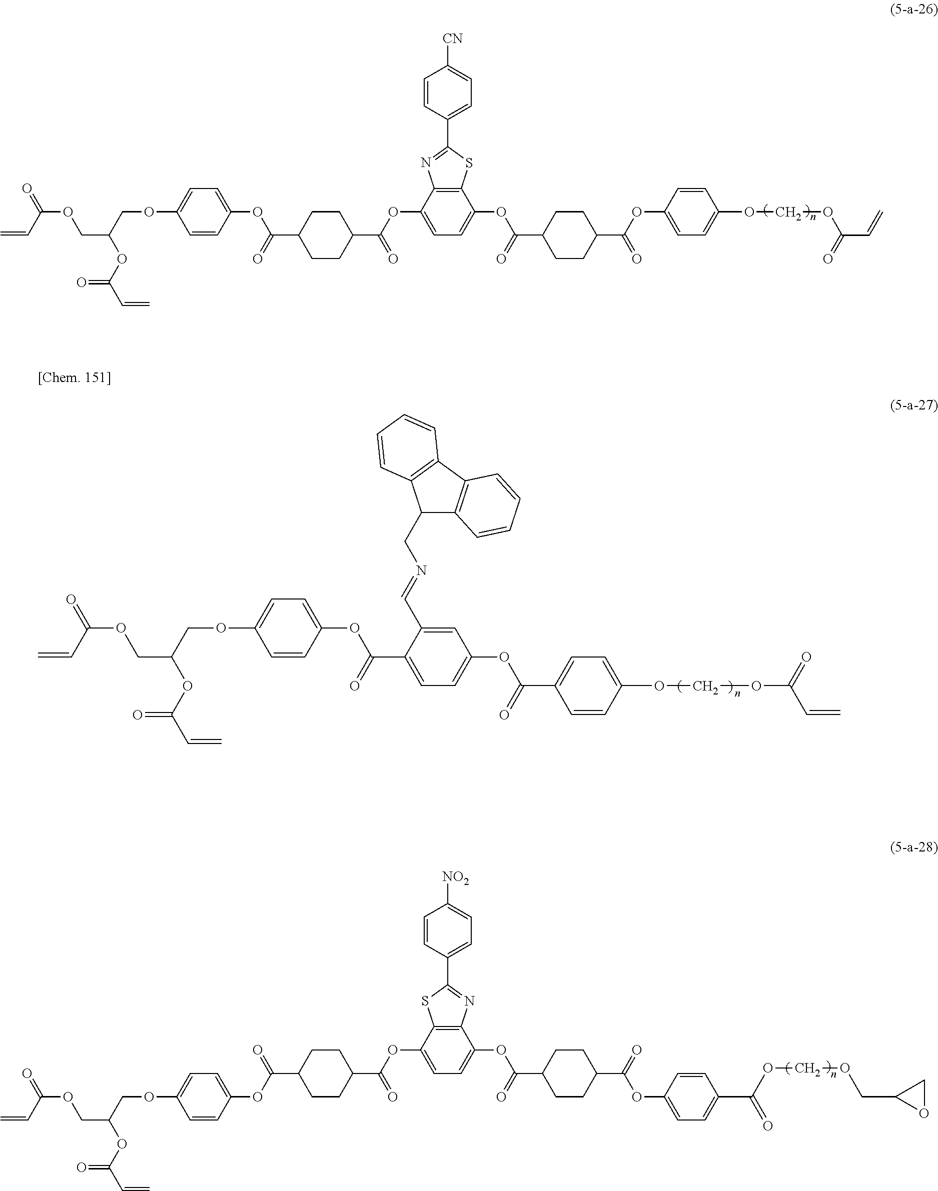

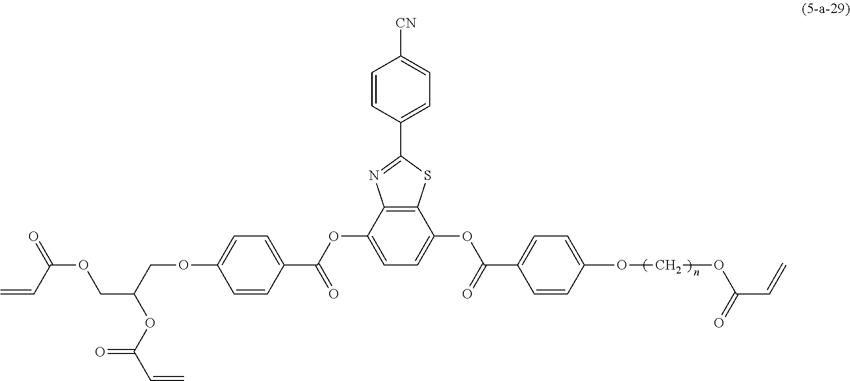 [SMILES: C=CC(=O)OCOc1ccc(C(=O)Oc2ccc(OC(=O)c3ccc(OCC(COC(=O)C=C)OC(=O)C=C)cc3)c3nc(-c4ccc(C#N)cc4)sc23)cc1]

(In the formulae, m and n each independently represent an integer of 1 to 10.)

These liquid crystalline compounds may be used alone or in combination of two or more kinds thereof.

Specific examples of the compound represented by Formula (5-b) include compounds represented by Formulae (5-b-1) to (5-b-26).

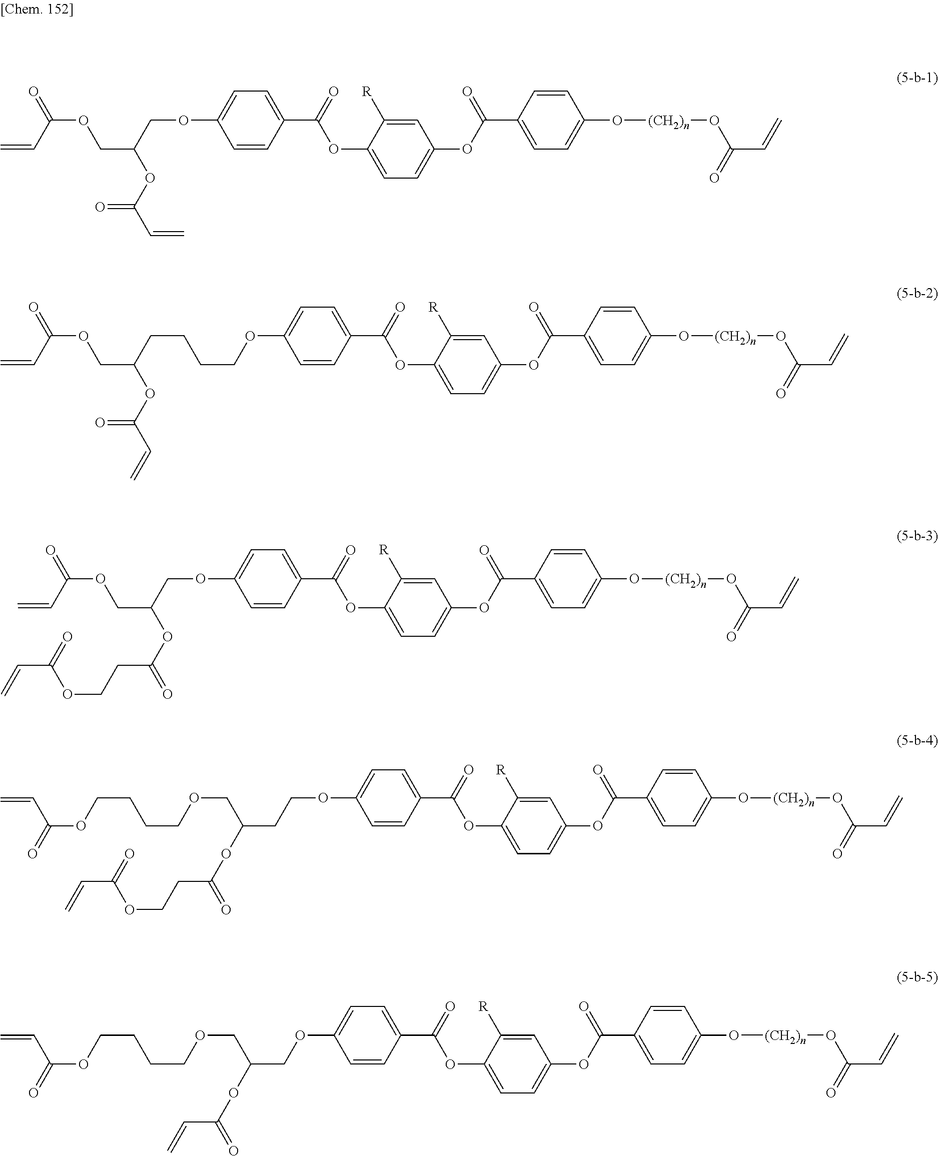

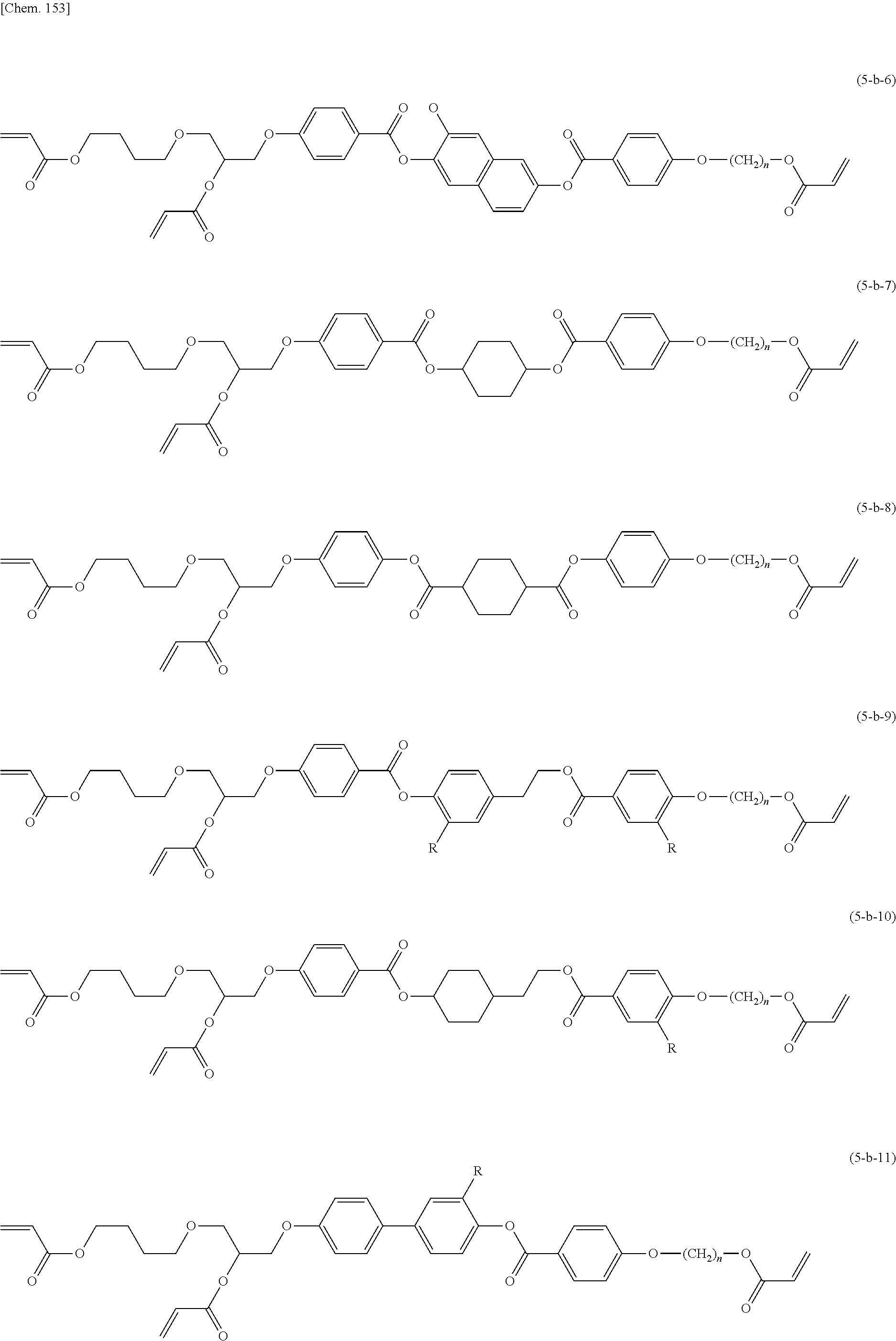

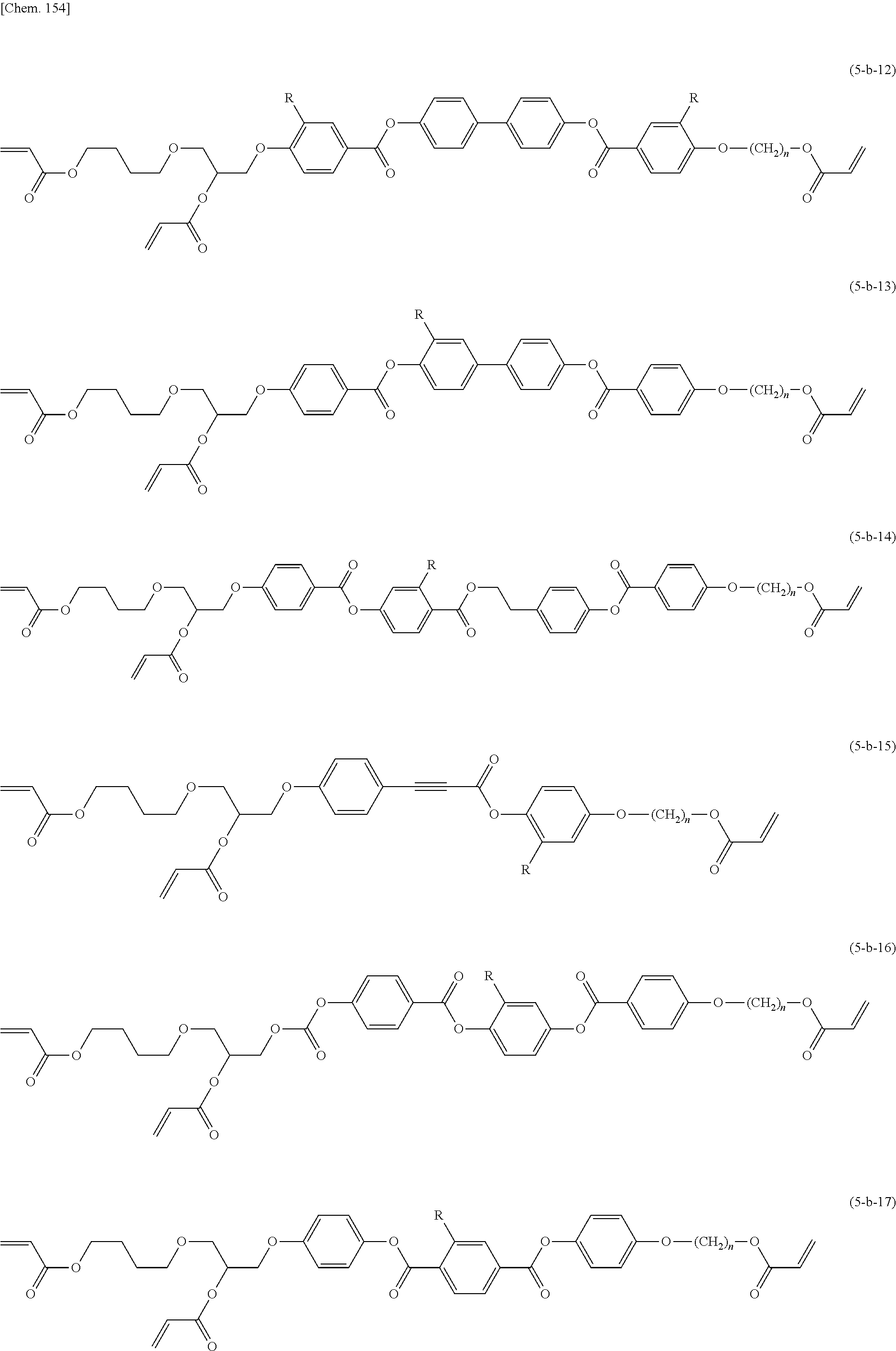

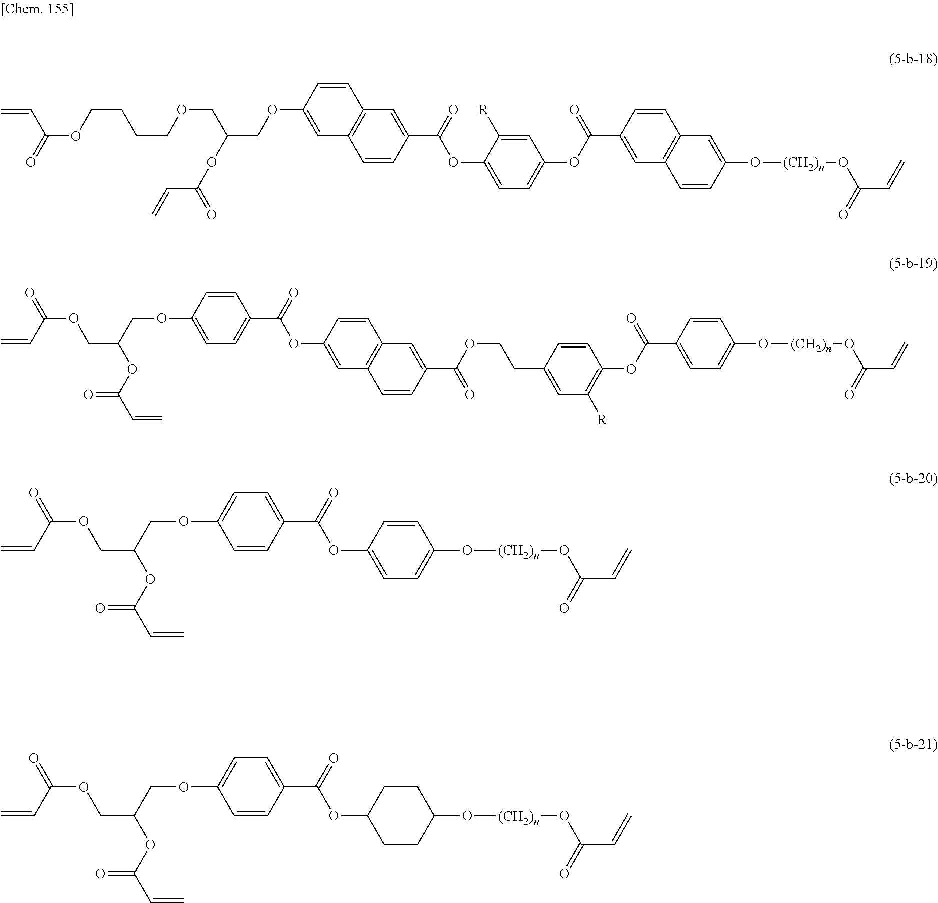

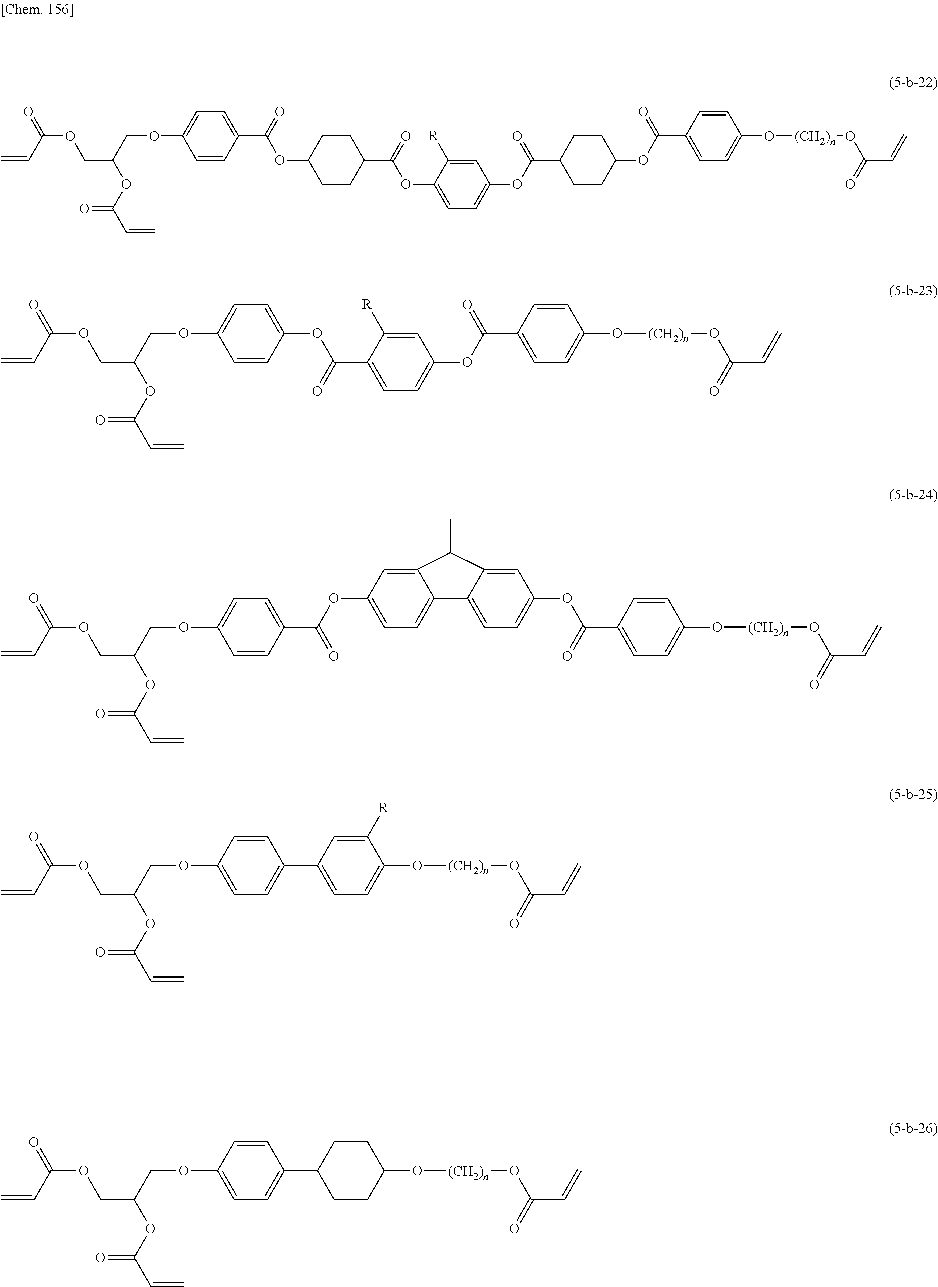

(In the formulae, n's each independently represent an integer of 1 to 10. R represents a hydrogen atom, a halogen atom, an alkyl group having 1 to 6 carbon atoms, an alkoxy group having 1 to 6 carbon atom, or a cyano group. In a case where these groups represent an alkyl group having 1 to 6 carbon atoms or an alkoxy group having 1 to 6 carbon atoms, all groups may be unsubstituted or substituted with one or two or more halogen atoms.)

These liquid crystalline compounds may be used alone or in combination of two or more kinds thereof.

Specific examples of the compound represented by Formula (6-a) include compounds represented by Formulae (6-a-1) to (6-a-25).

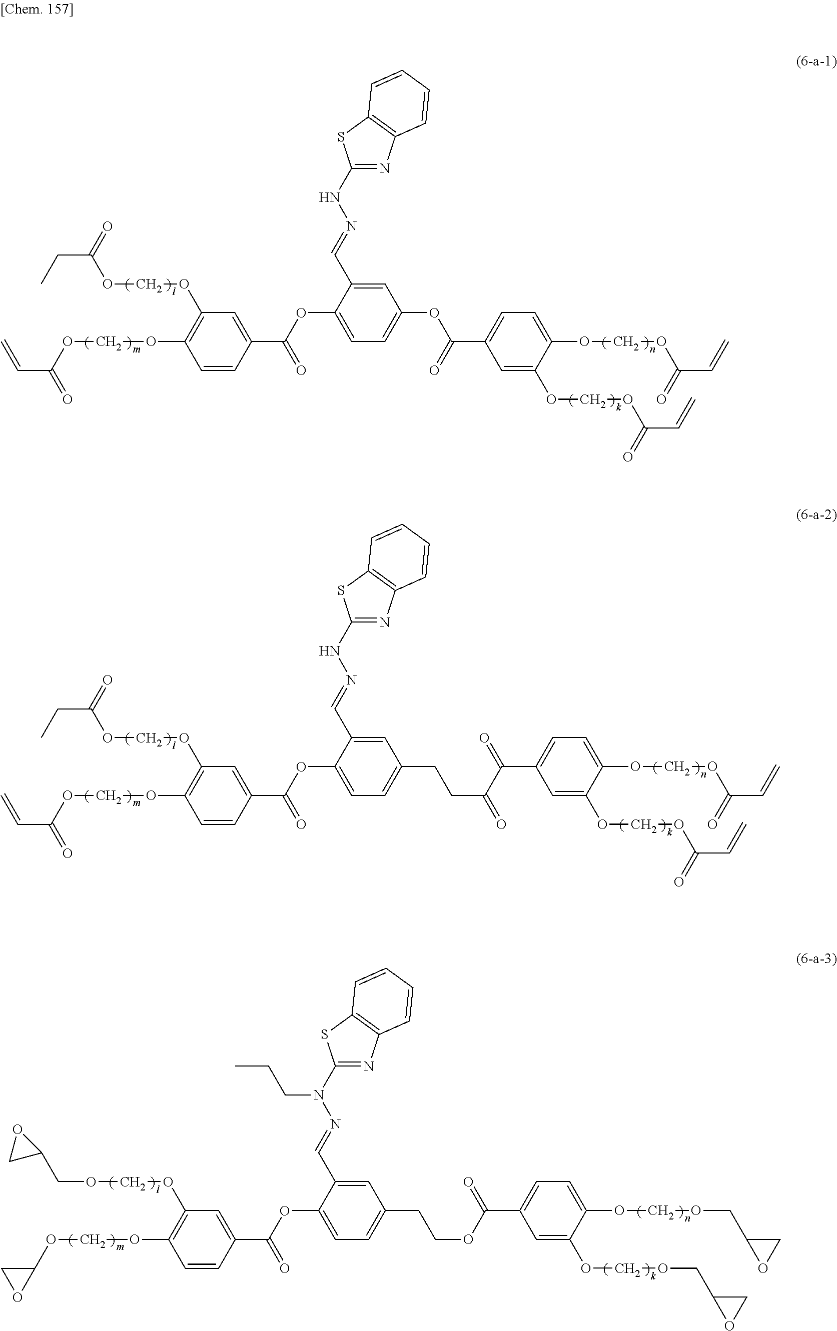

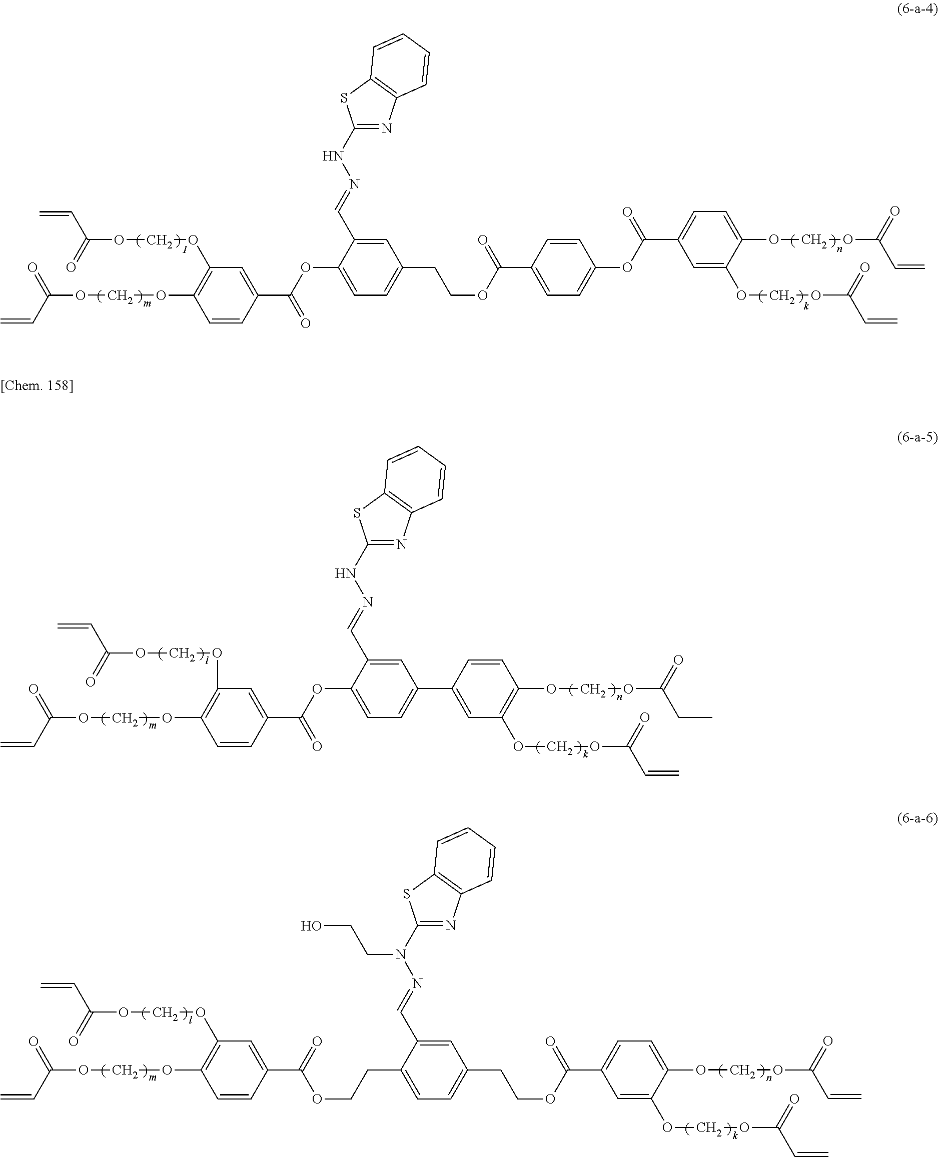

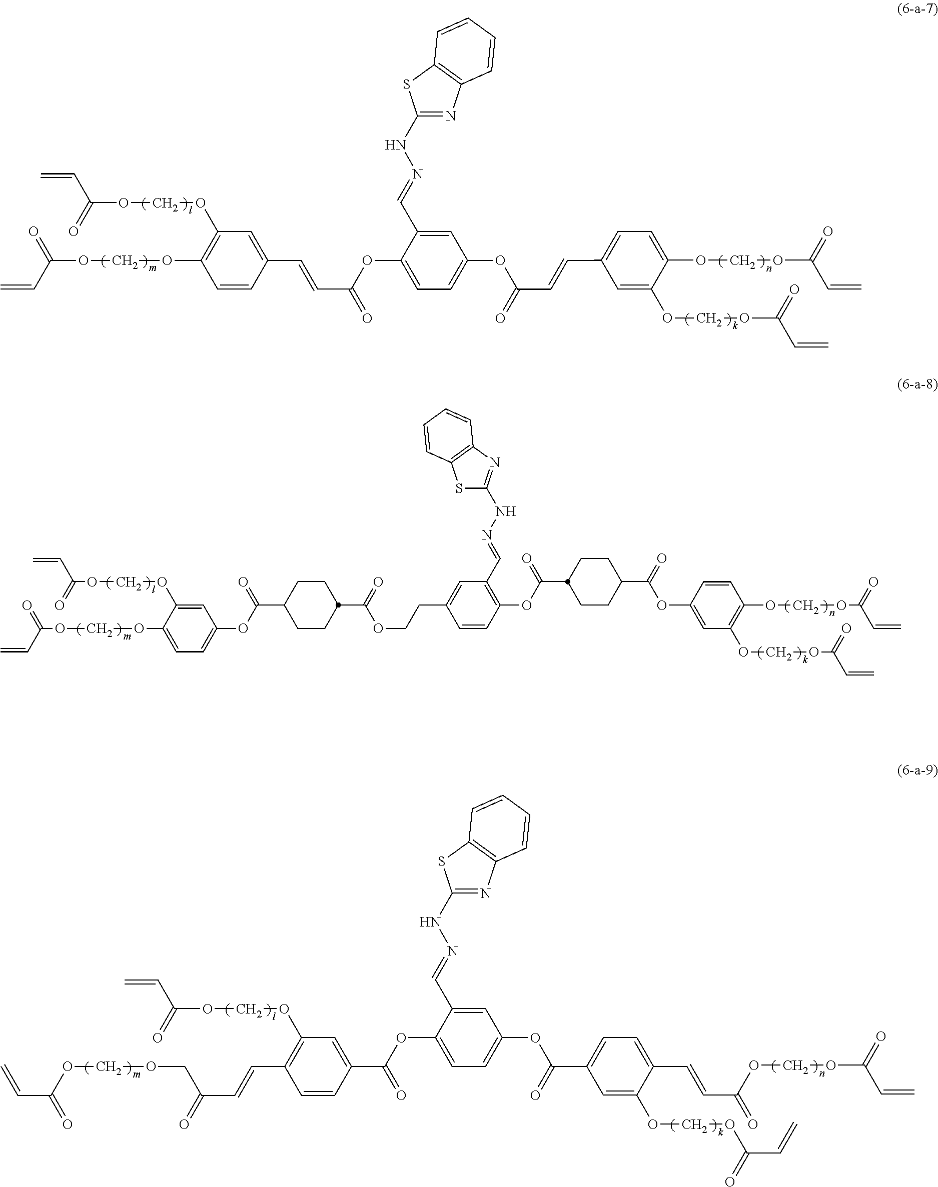

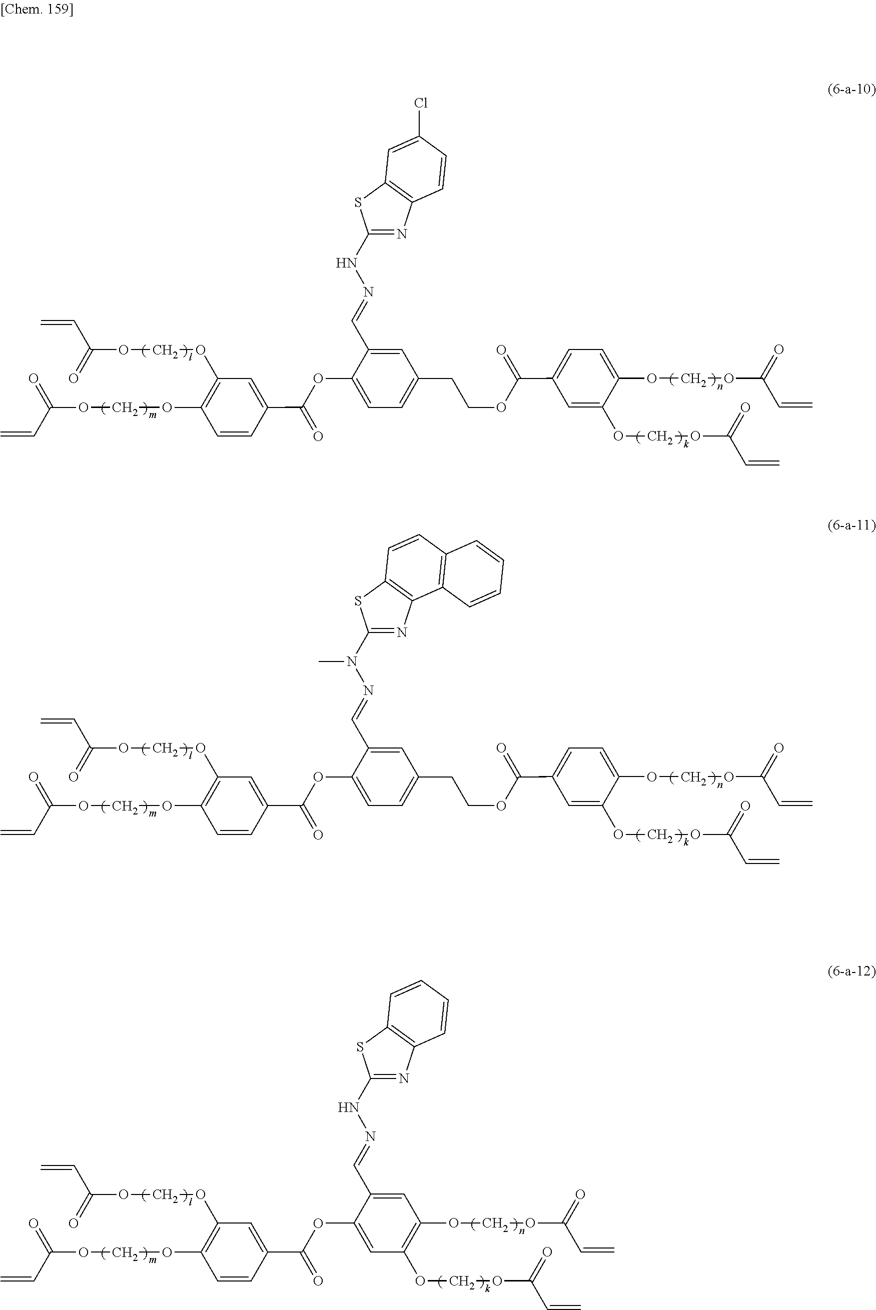

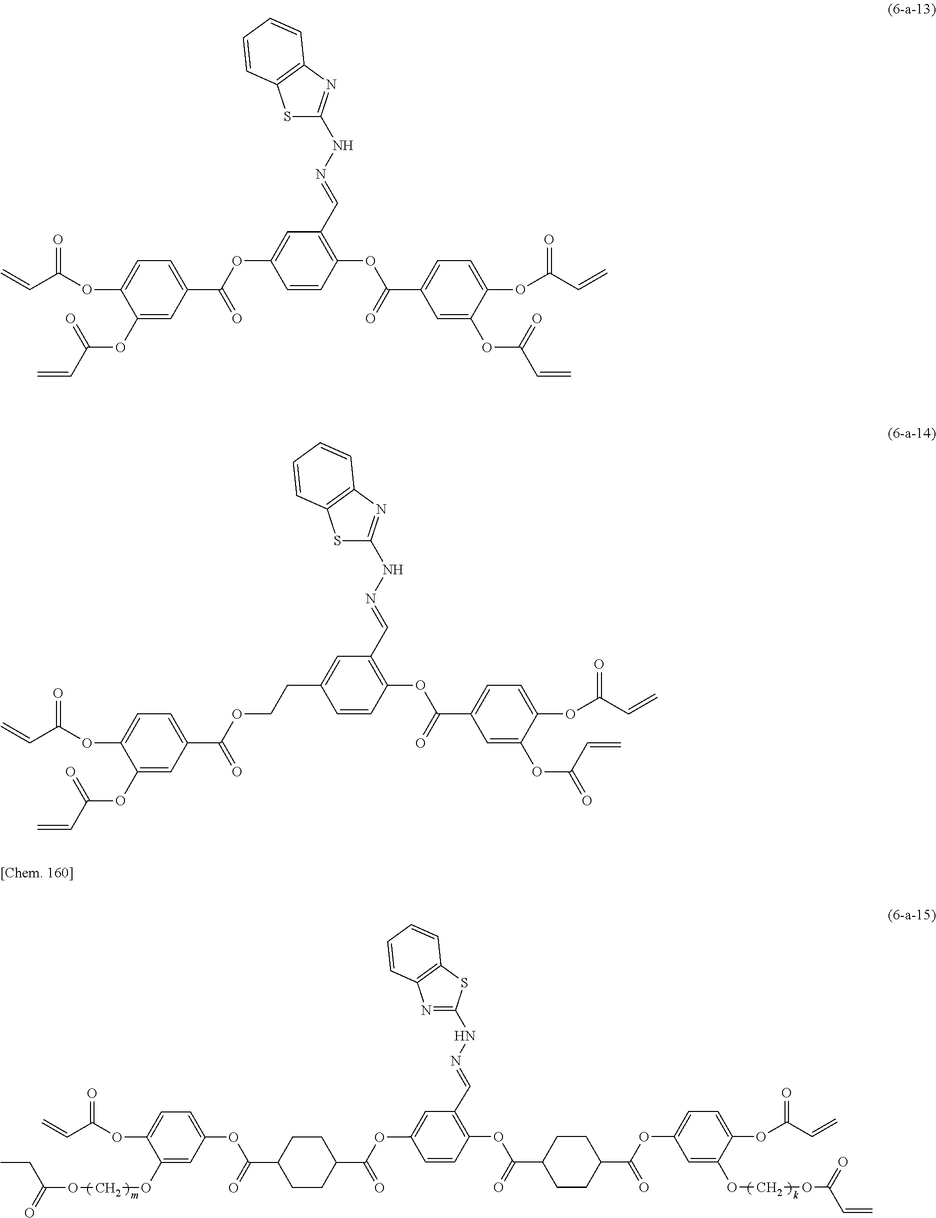

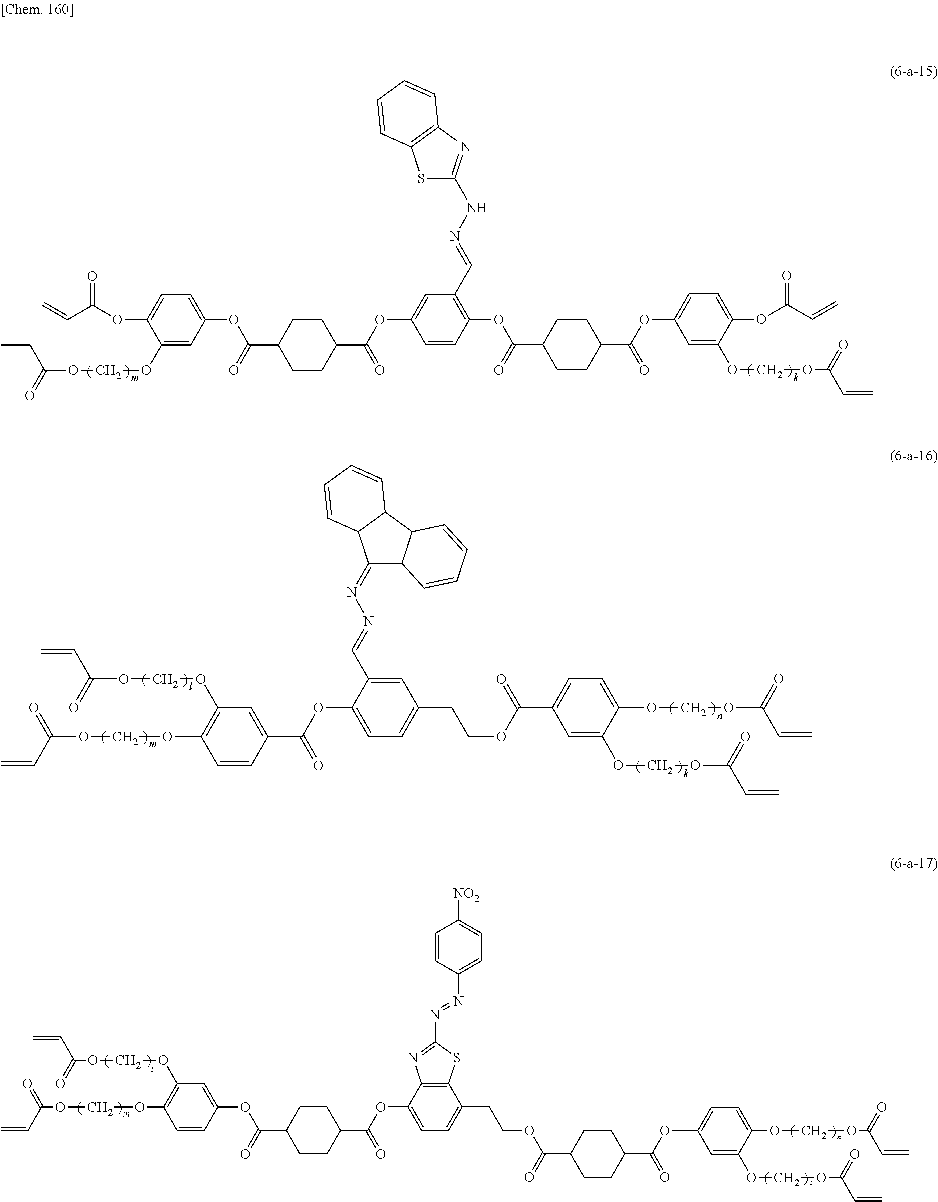

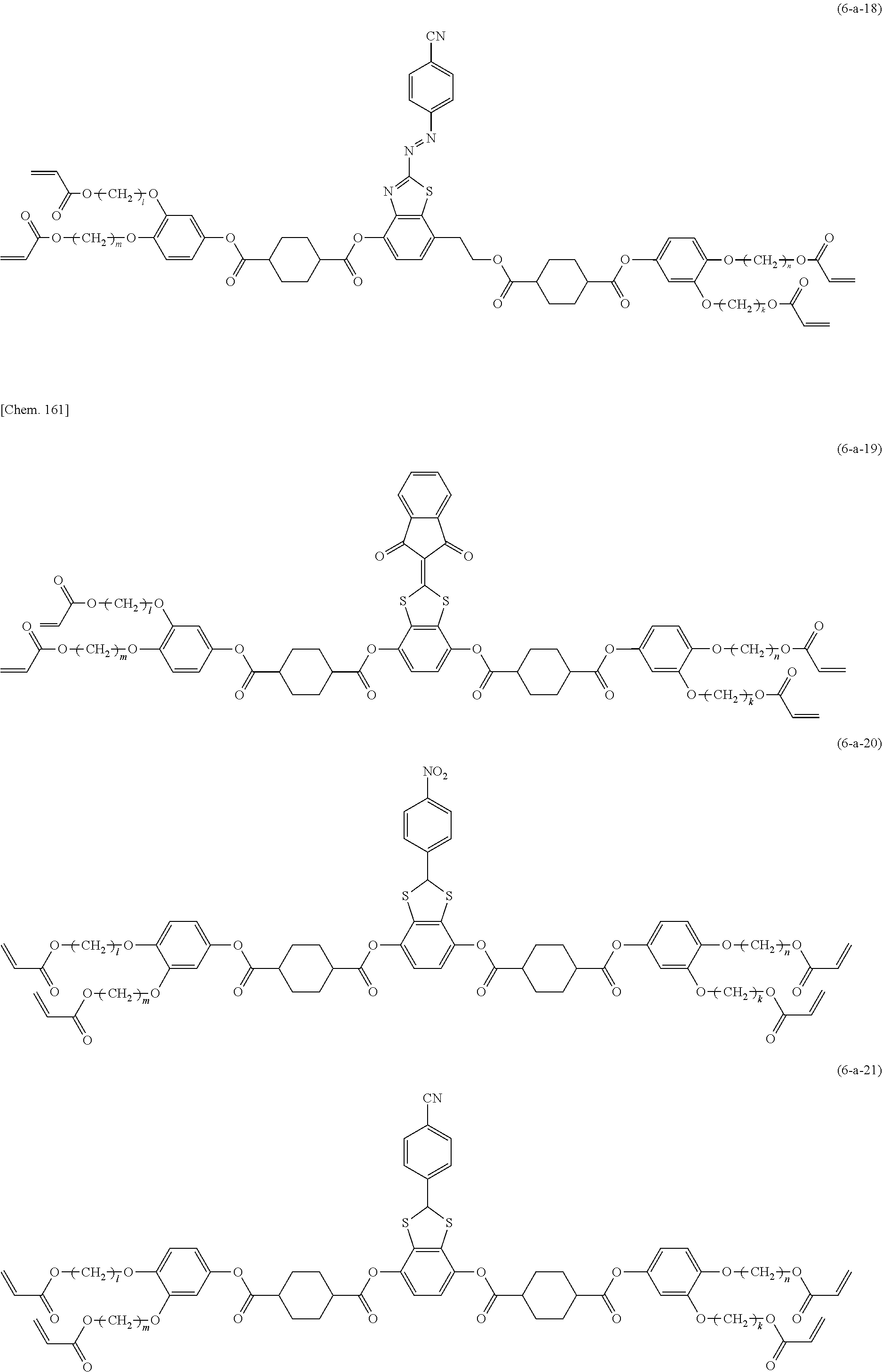

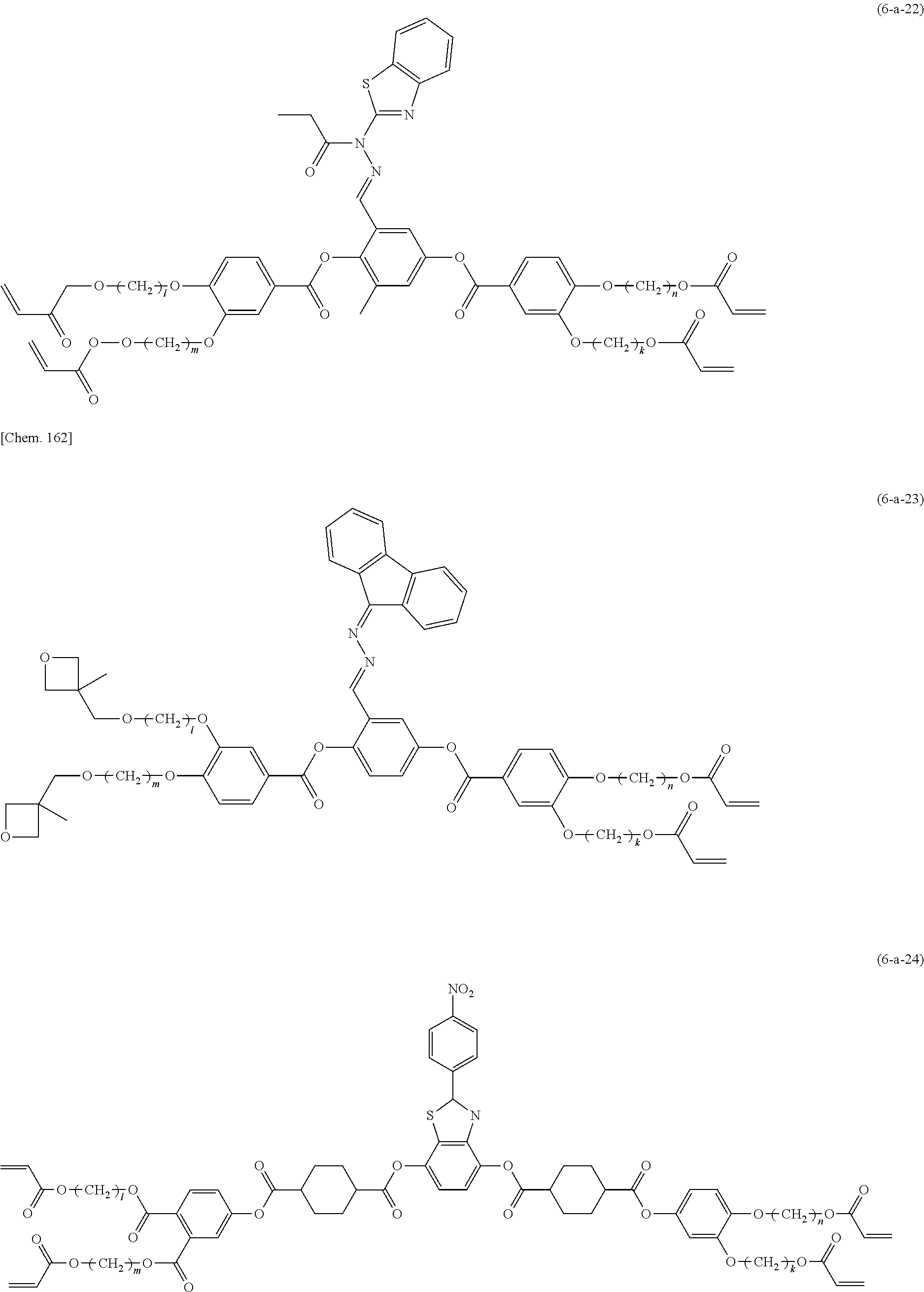

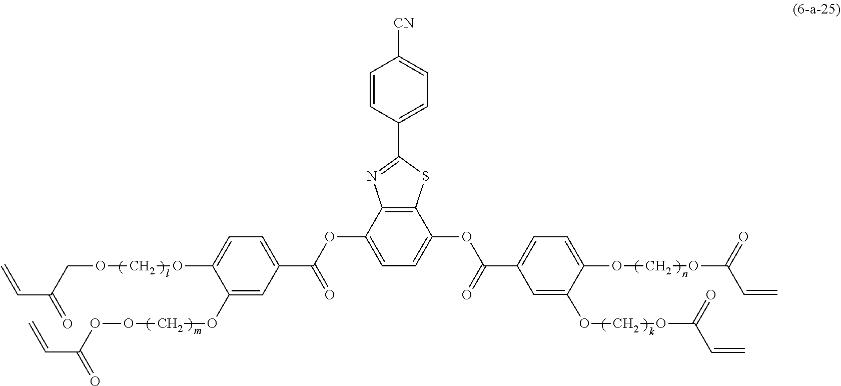

(In the formulae, k, l, m, and n each independently represent the number of carbon atoms of 1 to 10.)

These liquid crystalline compounds may be used alone or in combination of two or more kinds thereof.

Preferred specific examples of the compound represented by Formula (6-b) include compounds represented by Formulae (6-b-1) to (6-b-23).

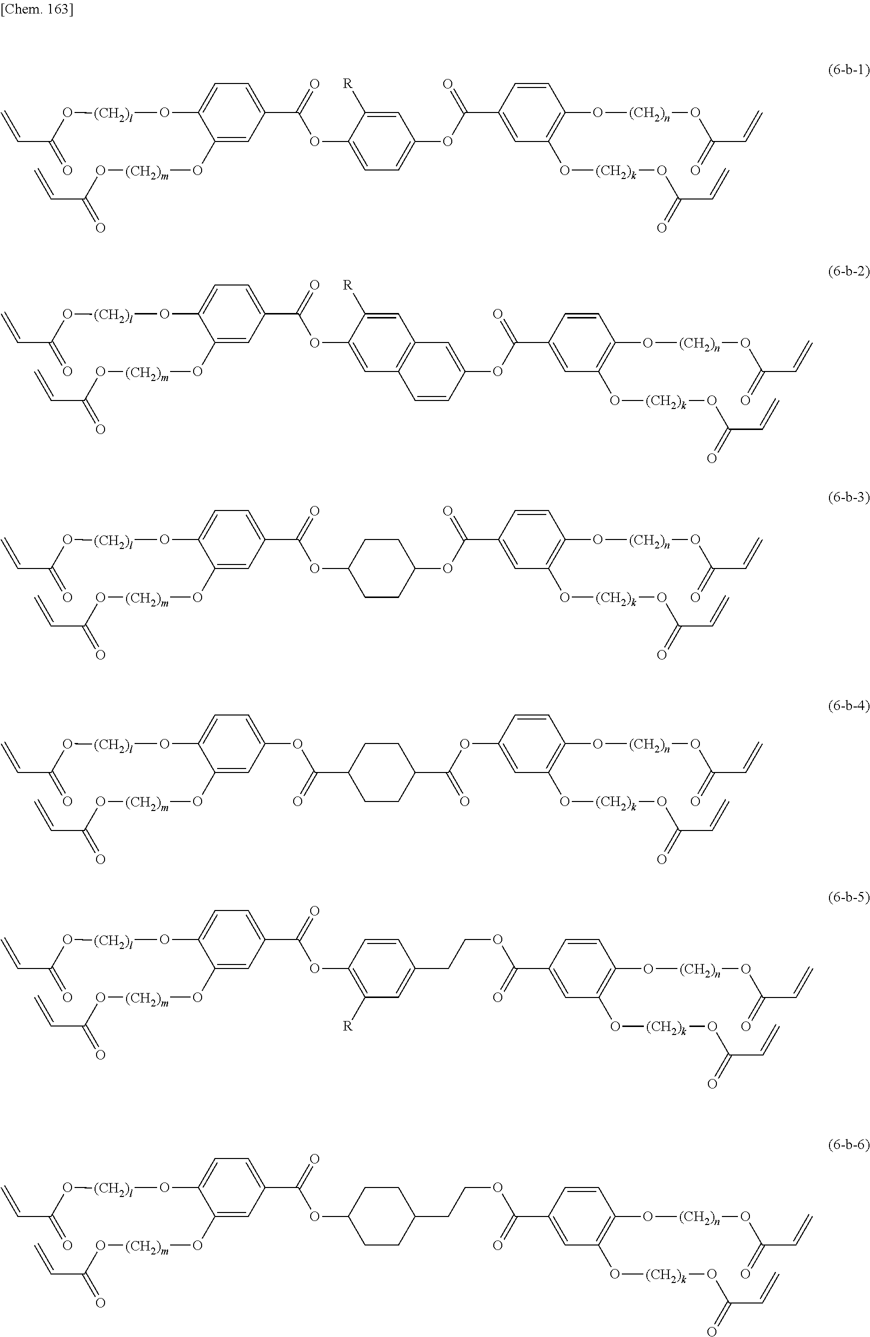

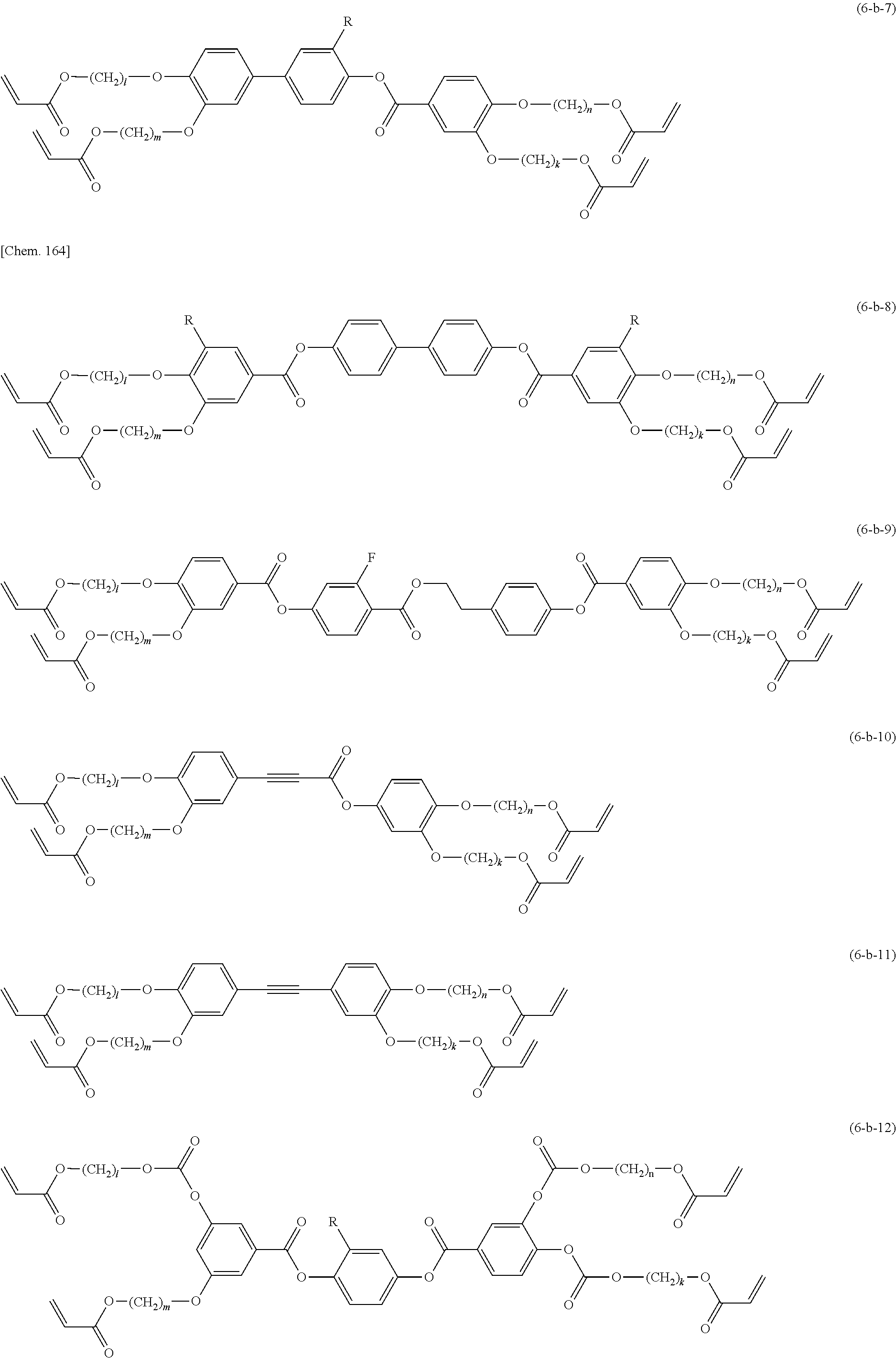

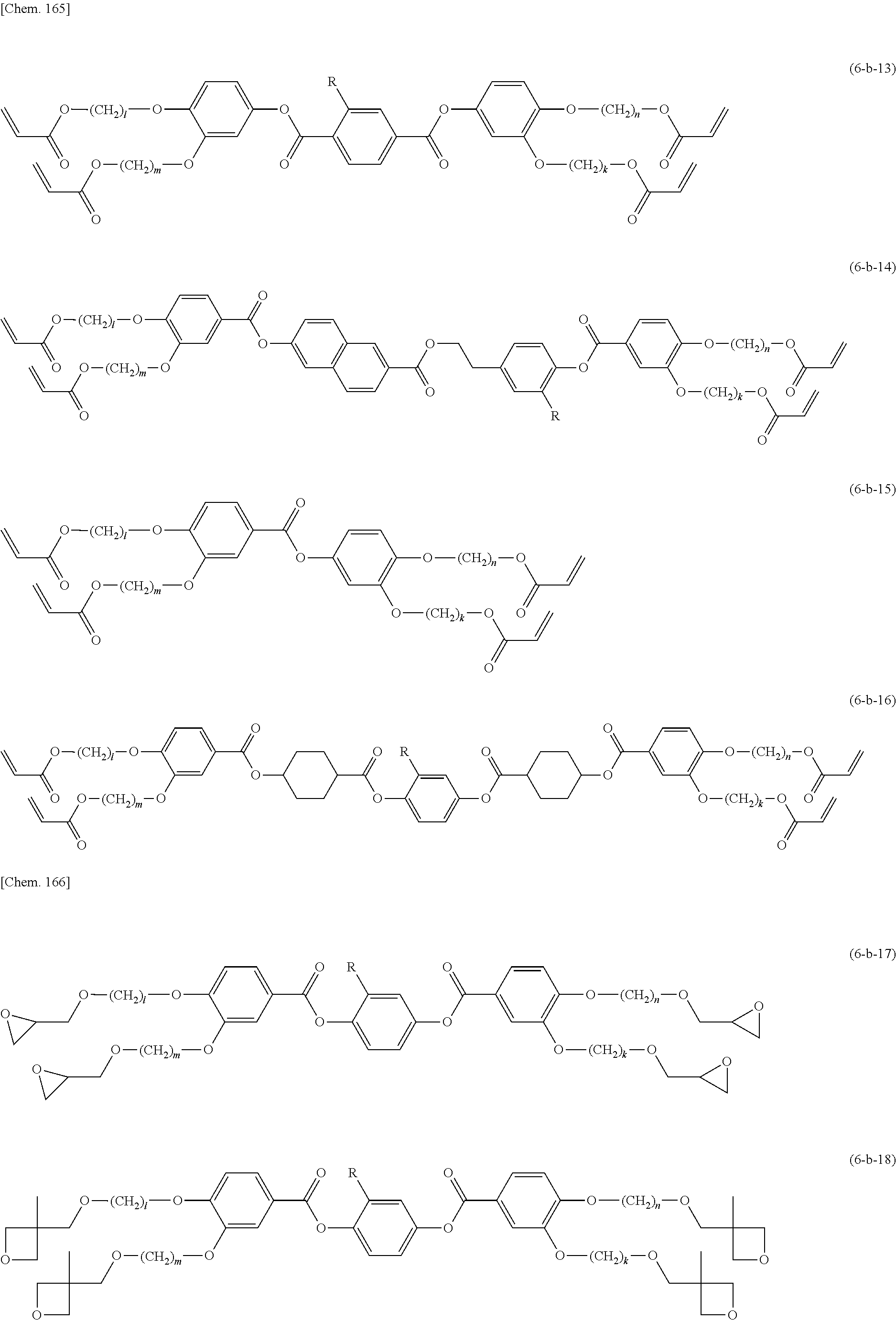

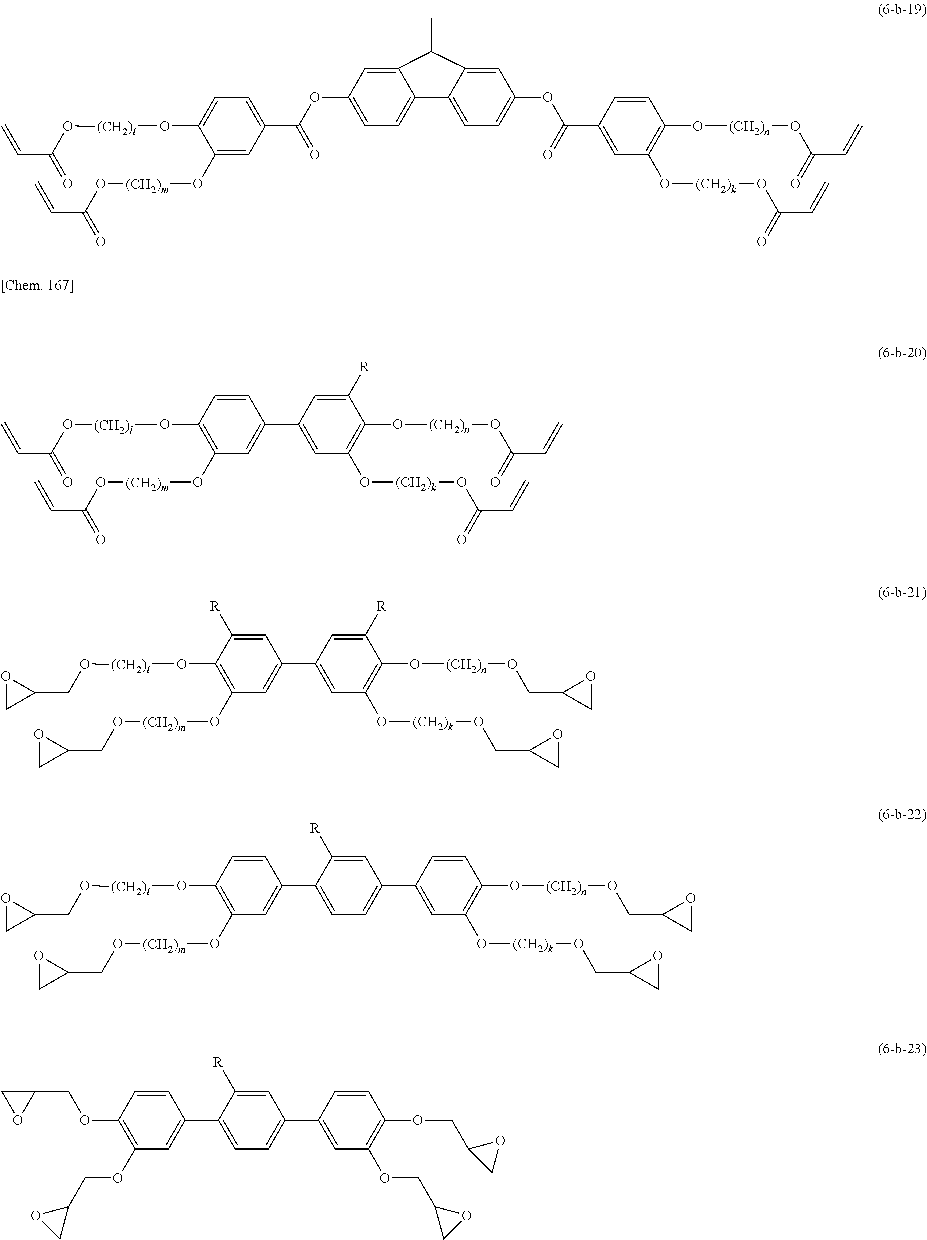

(In the formulae, k, l, m, and n each independently represent an integer of 1 to 10. R represents a hydrogen atom, a halogen atom, an alkyl group having 1 to 6 carbon atoms, an alkoxy group having 1 to 6 carbon atom, or a cyano group. In a case where these groups represent an alkyl group having 1 to 6 carbon atoms or an alkoxy group having 1 to 6 carbon atoms, all groups may be unsubstituted or substituted with one or two or more halogen atoms.)

These liquid crystalline compounds may be used alone or in combination of two or more kinds thereof.

Specific examples of the compound represented by Formula (7-a) include compounds represented by Formulae (7-a-1) to (7-a-26)

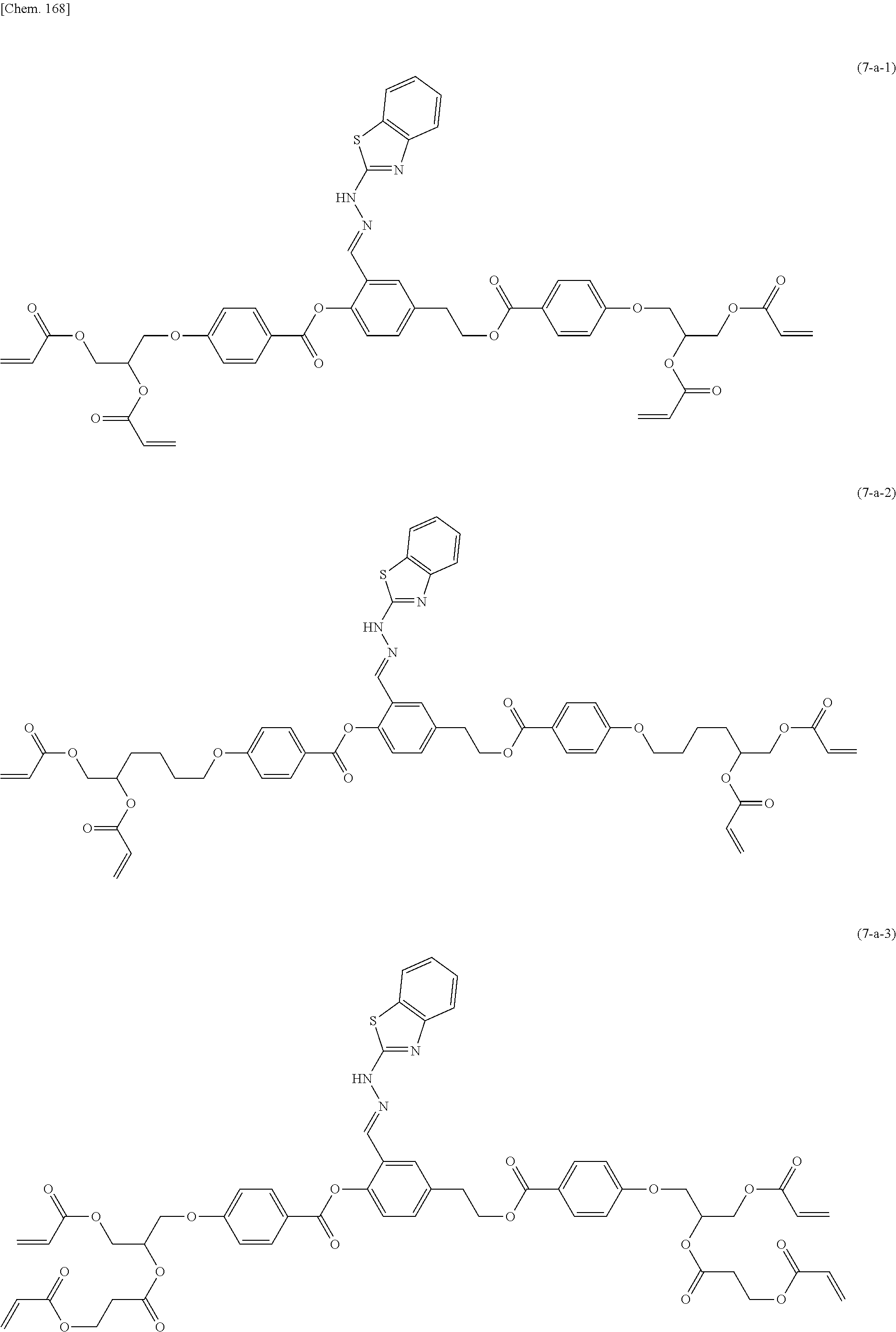

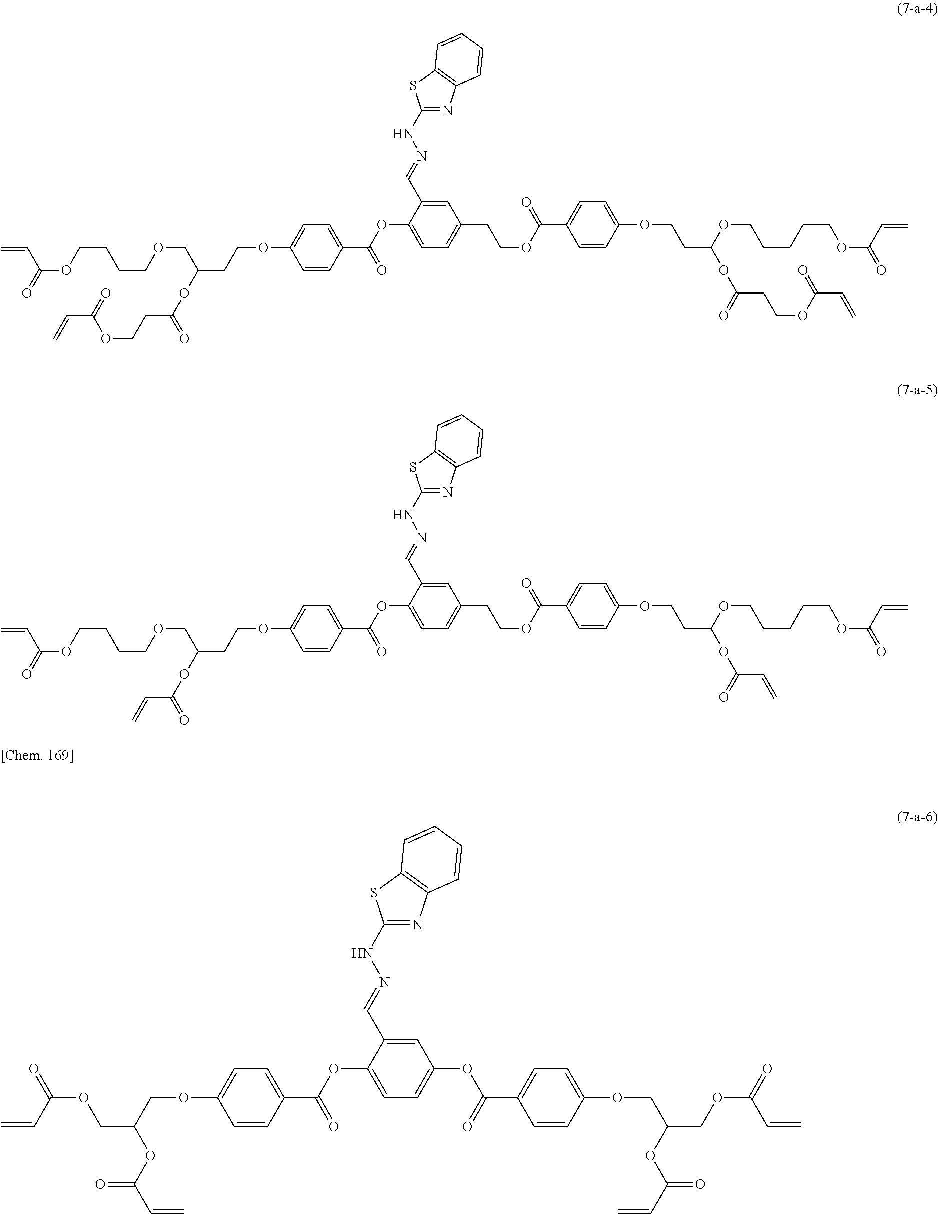

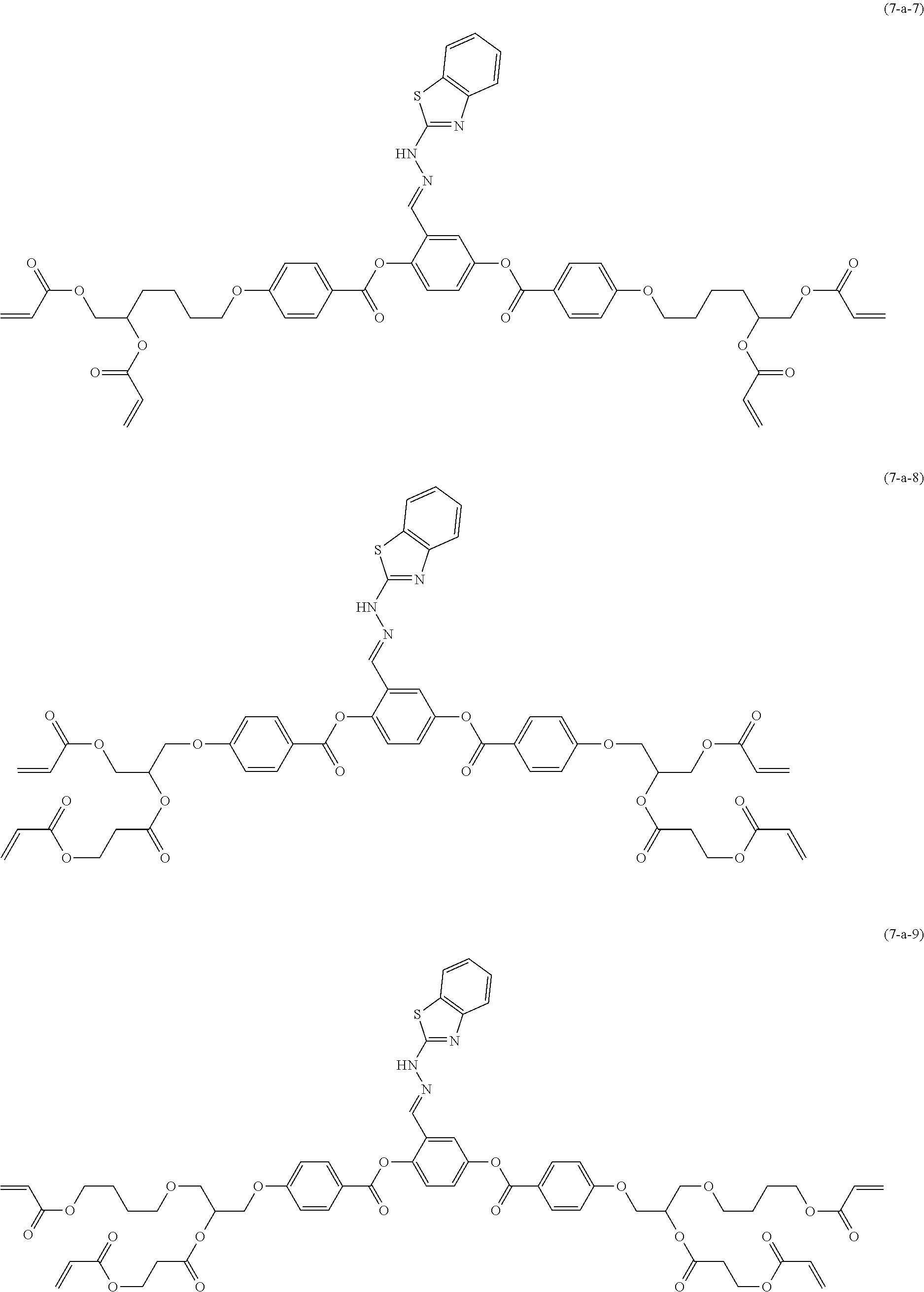

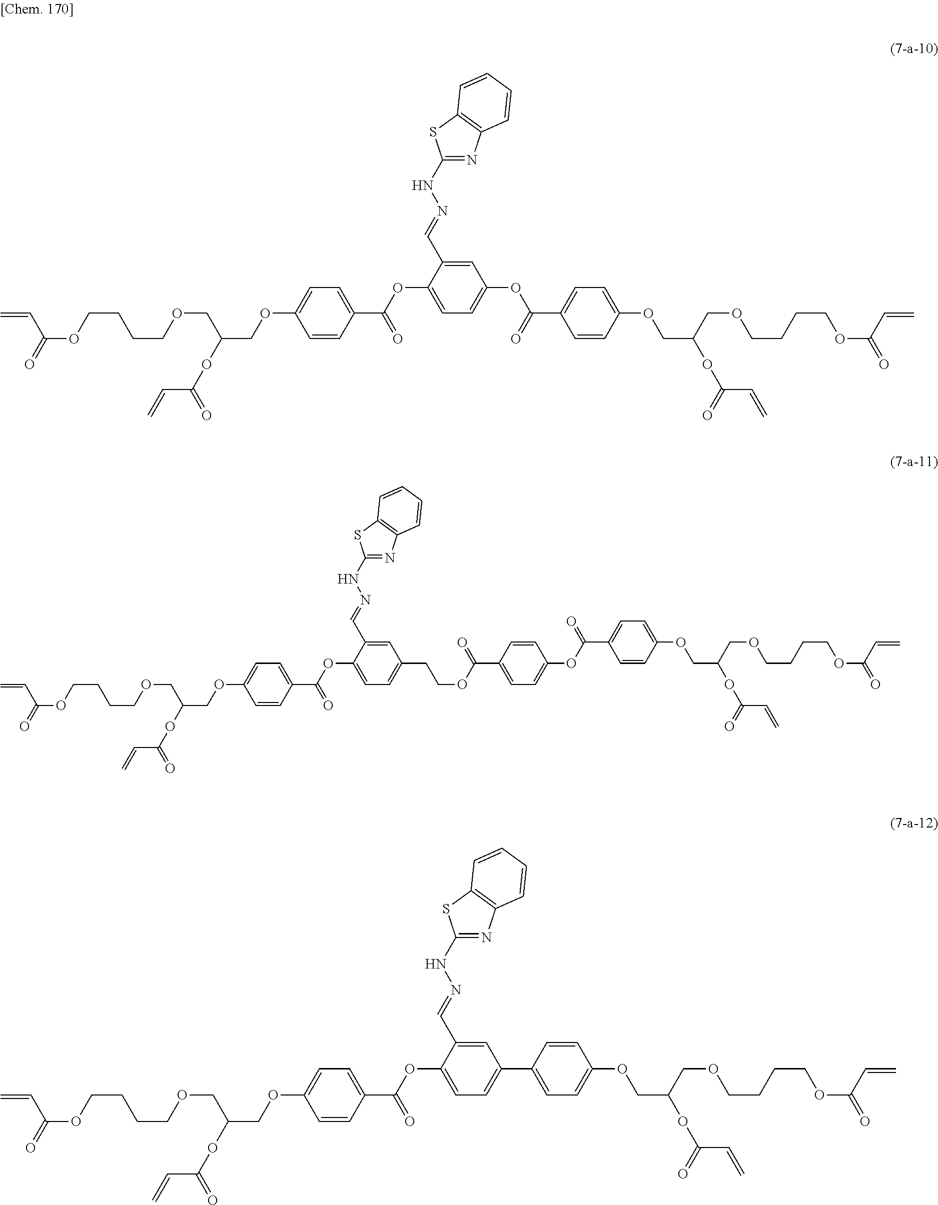

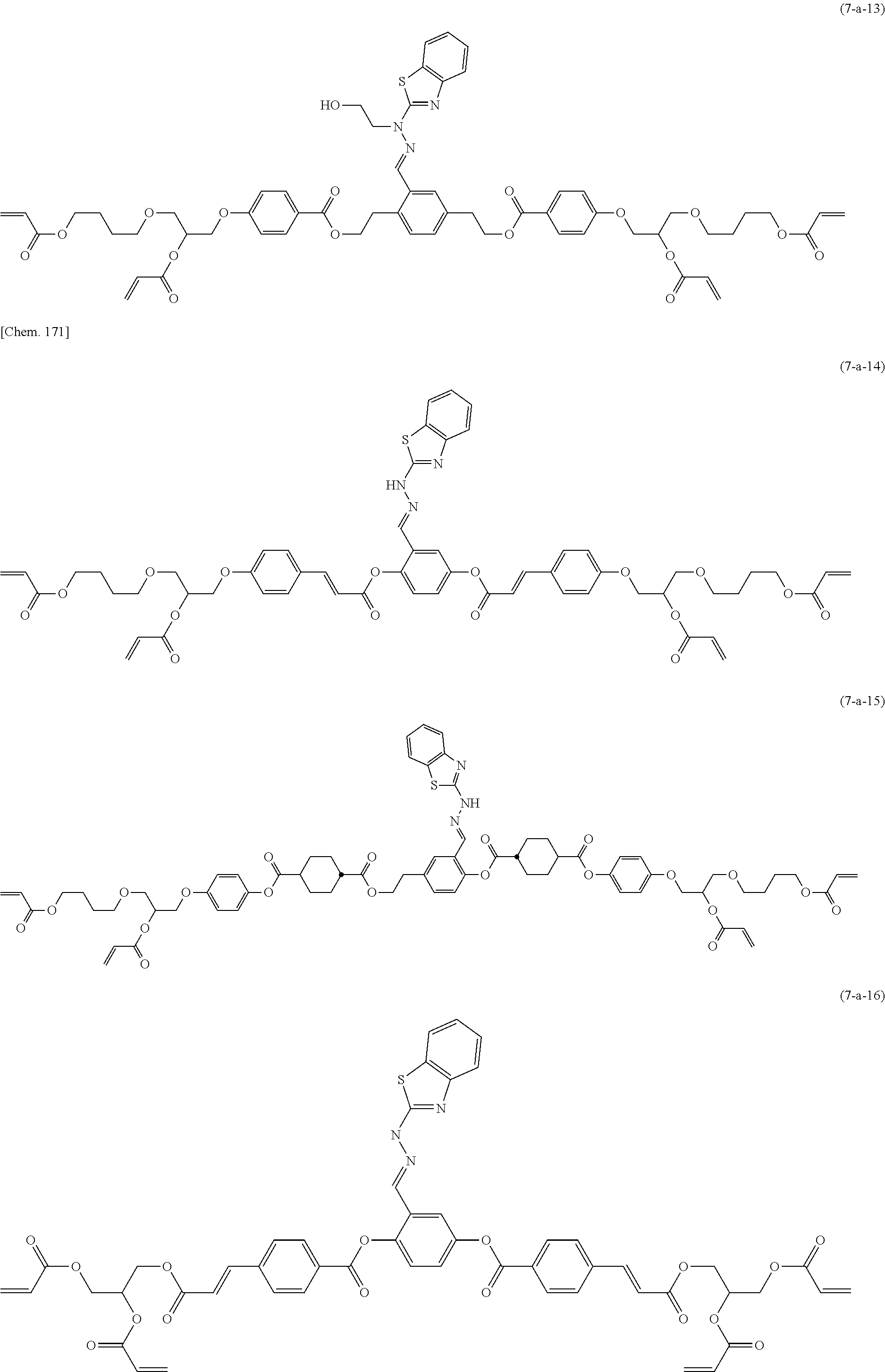

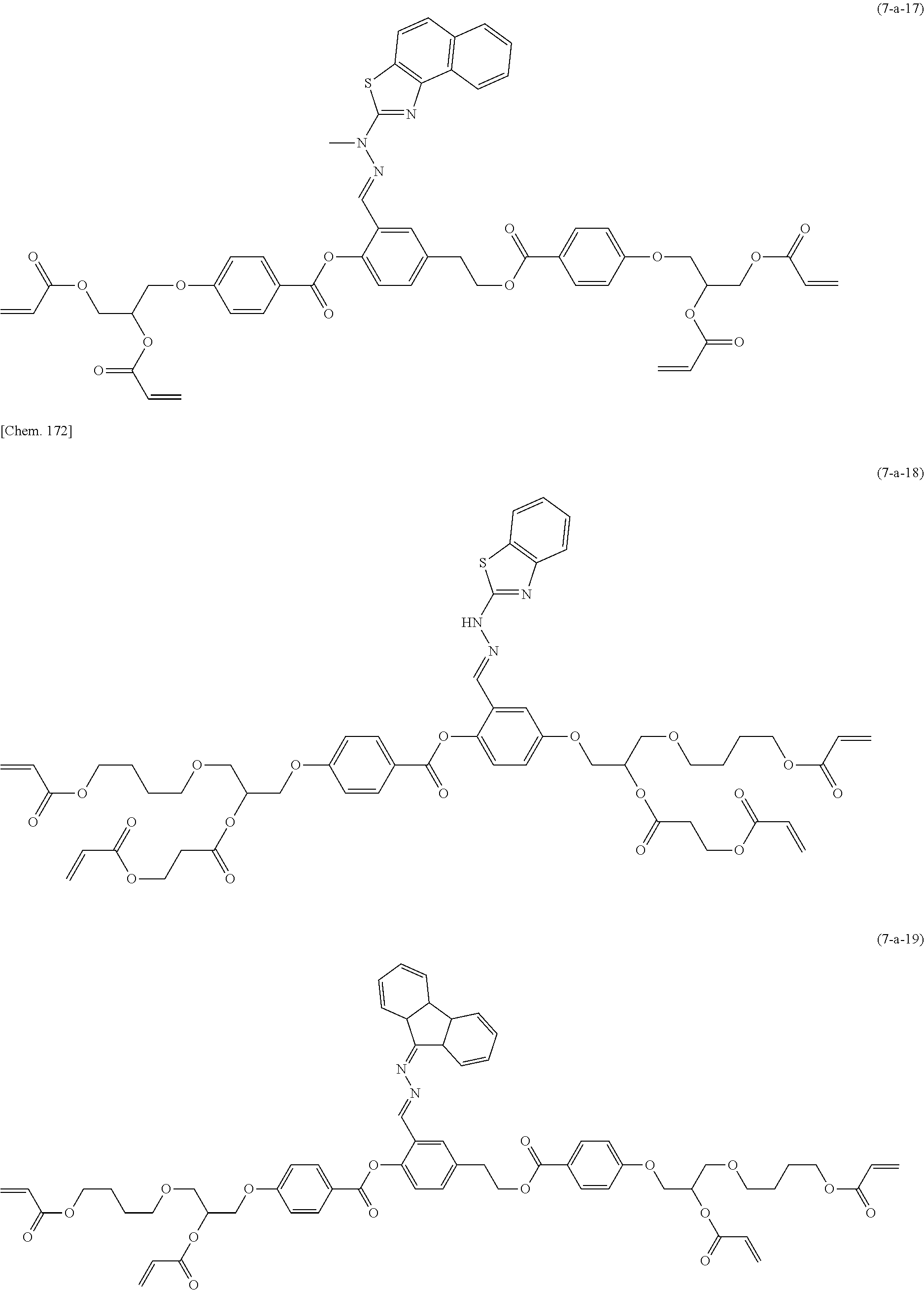

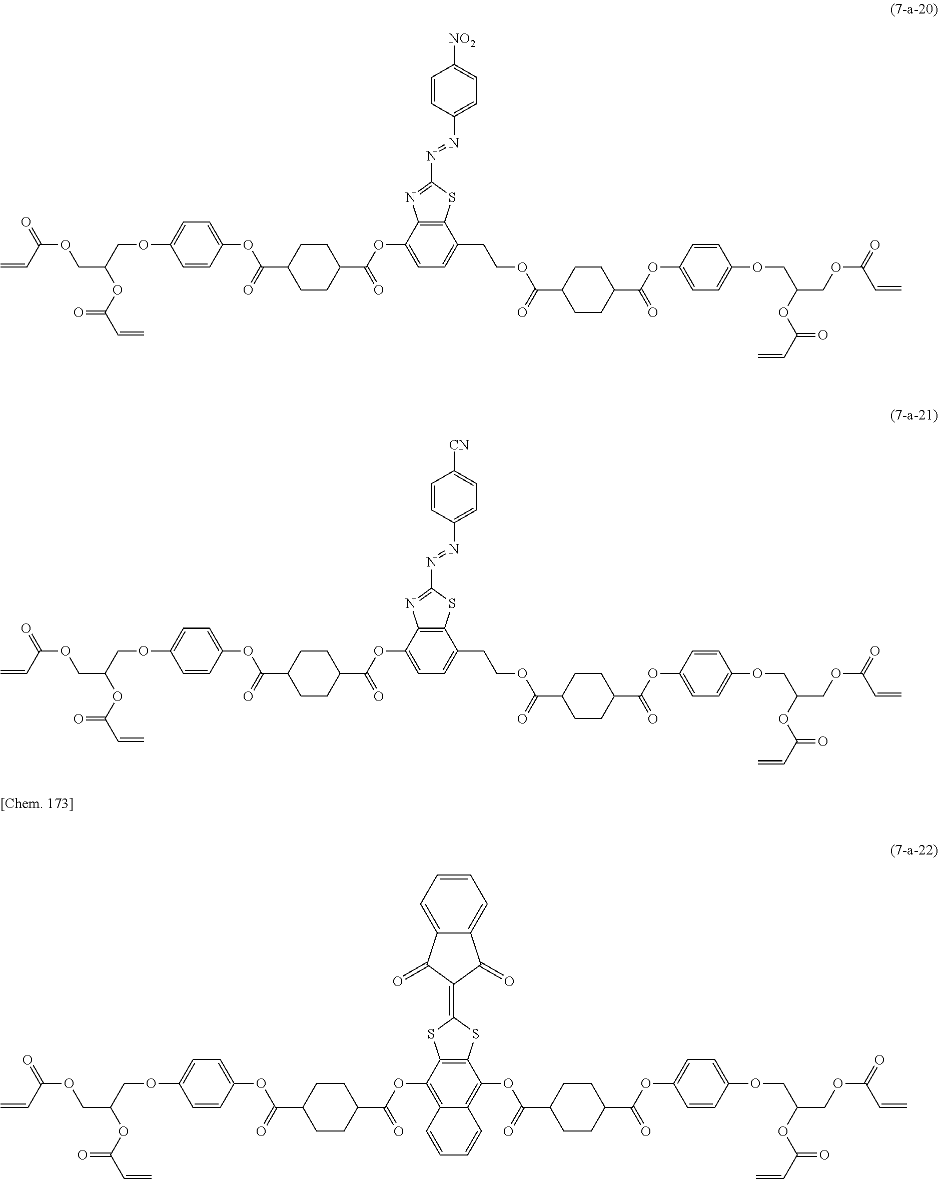

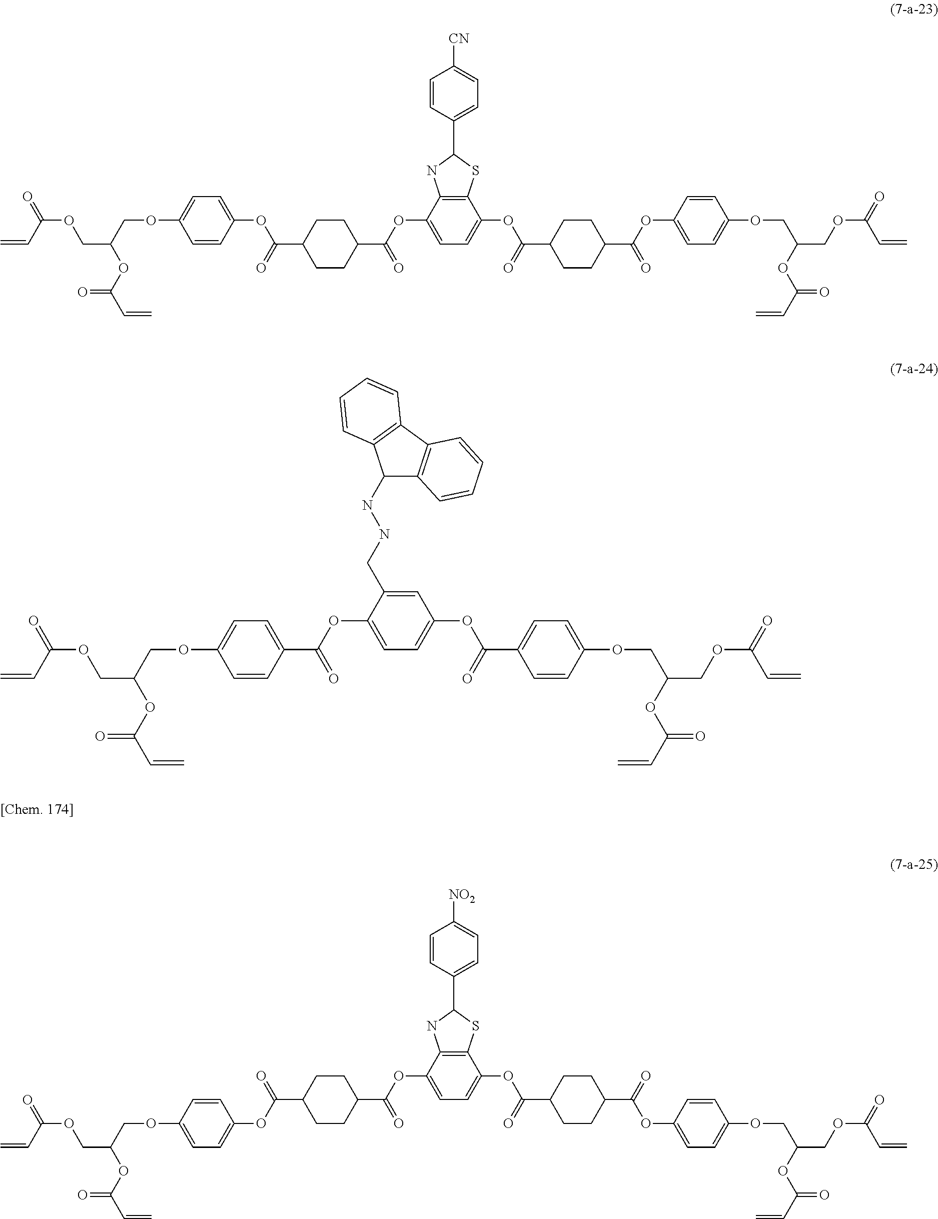

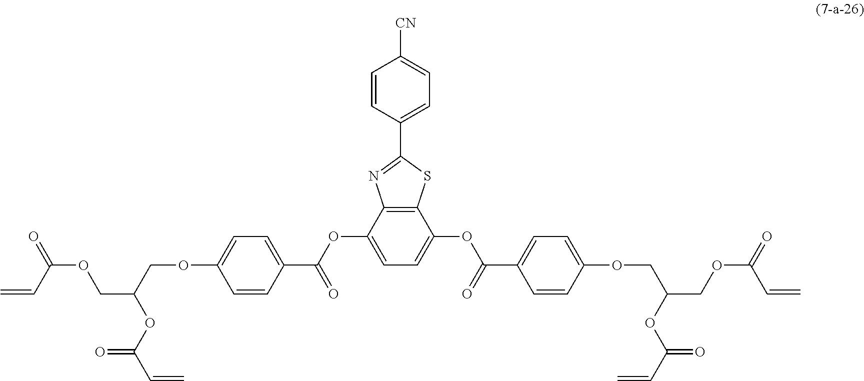 [SMILES: C=CC(=O)OCC(COc1ccc(C(=O)Oc2ccc(OC(=O)c3ccc(OCC(COC(=O)C=C)OC(=O)C=C)cc3)c3sc(-c4ccc(C#N)cc4)nc23)cc1)OC(=O)C=C]

These liquid crystalline compounds may be used alone or in combination of two or more kinds thereof.

Specific examples of the compound represented by Formula (7-b) include compounds represented by Formulae (7-b-1) to (7-b-25).

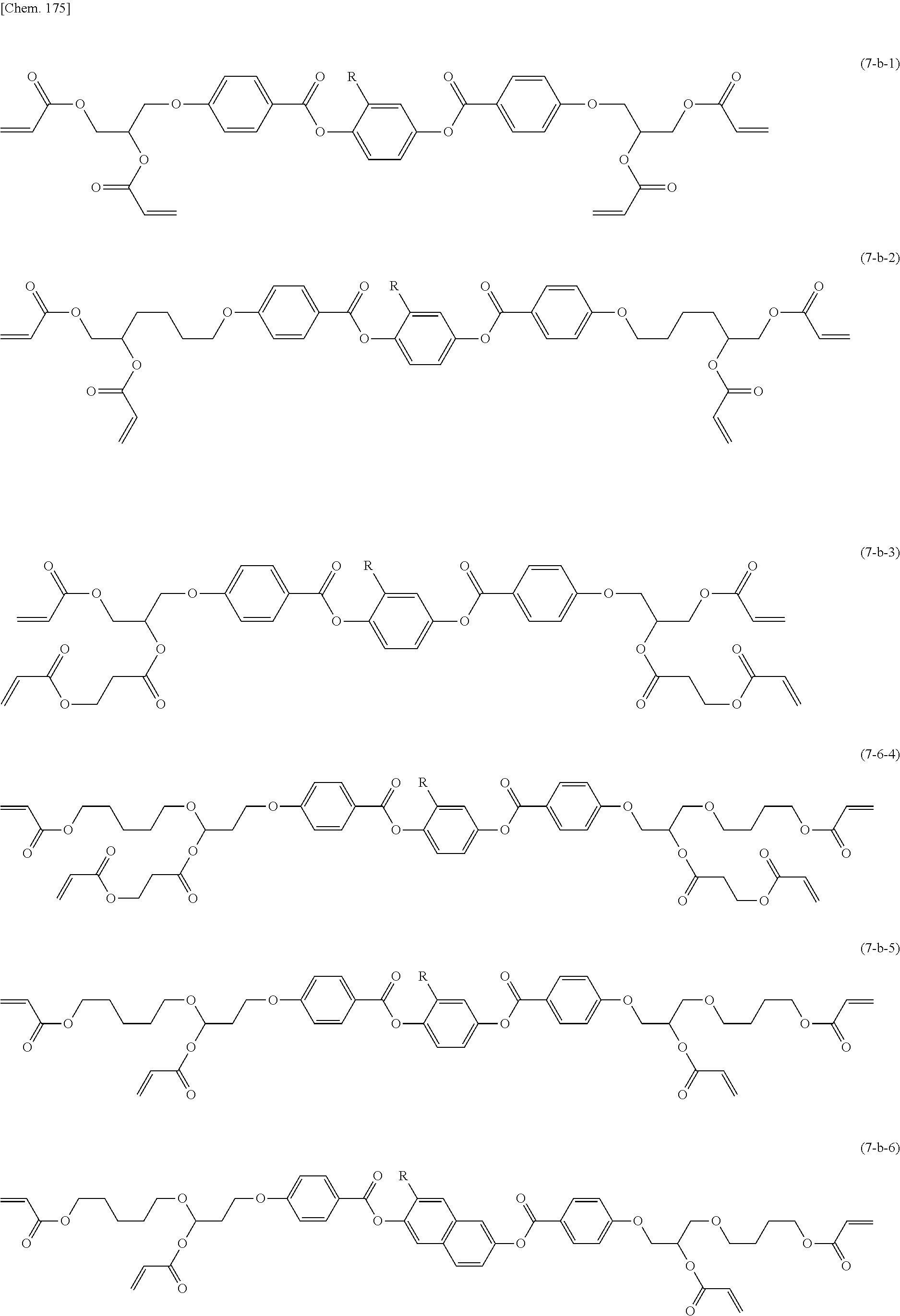

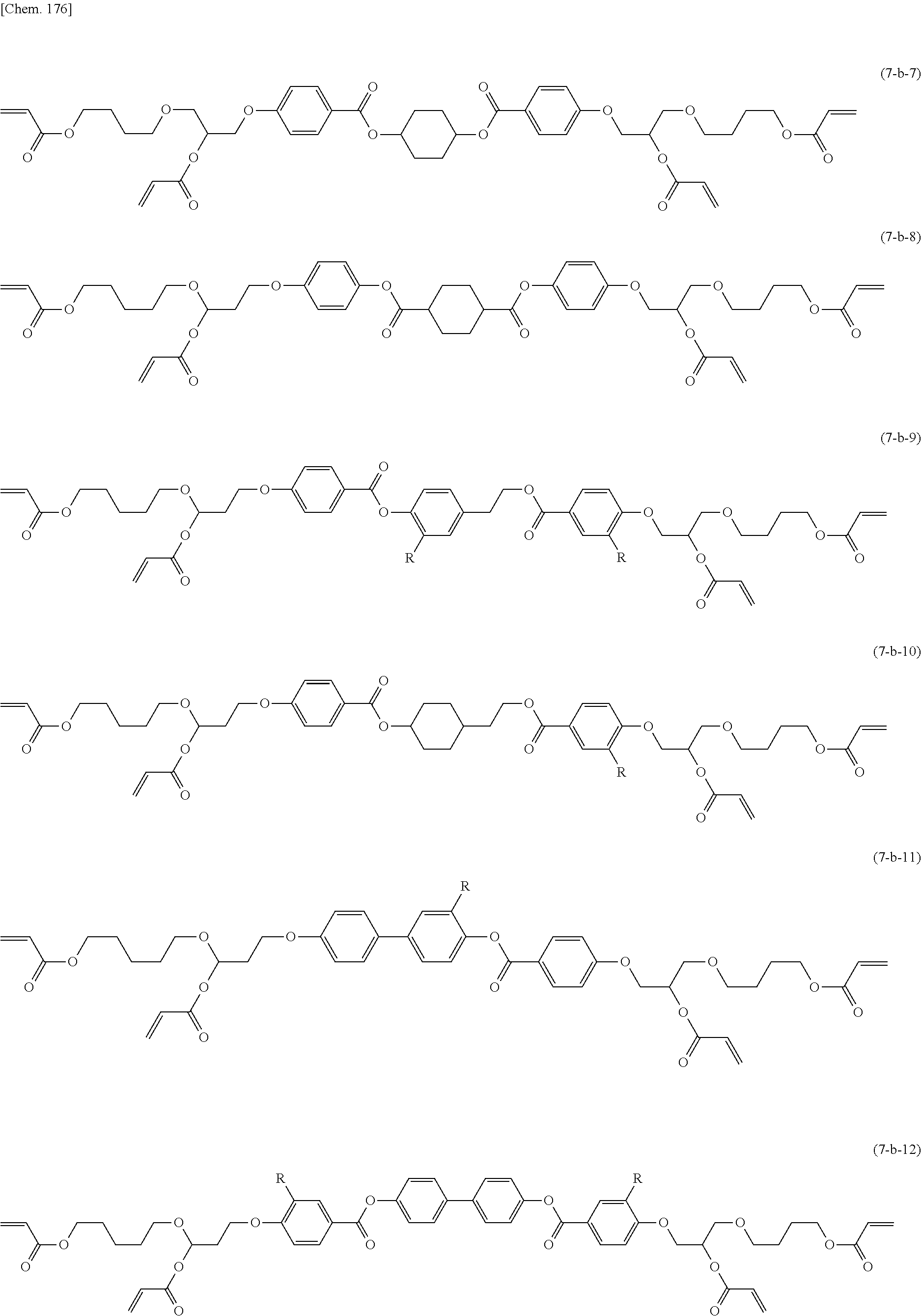

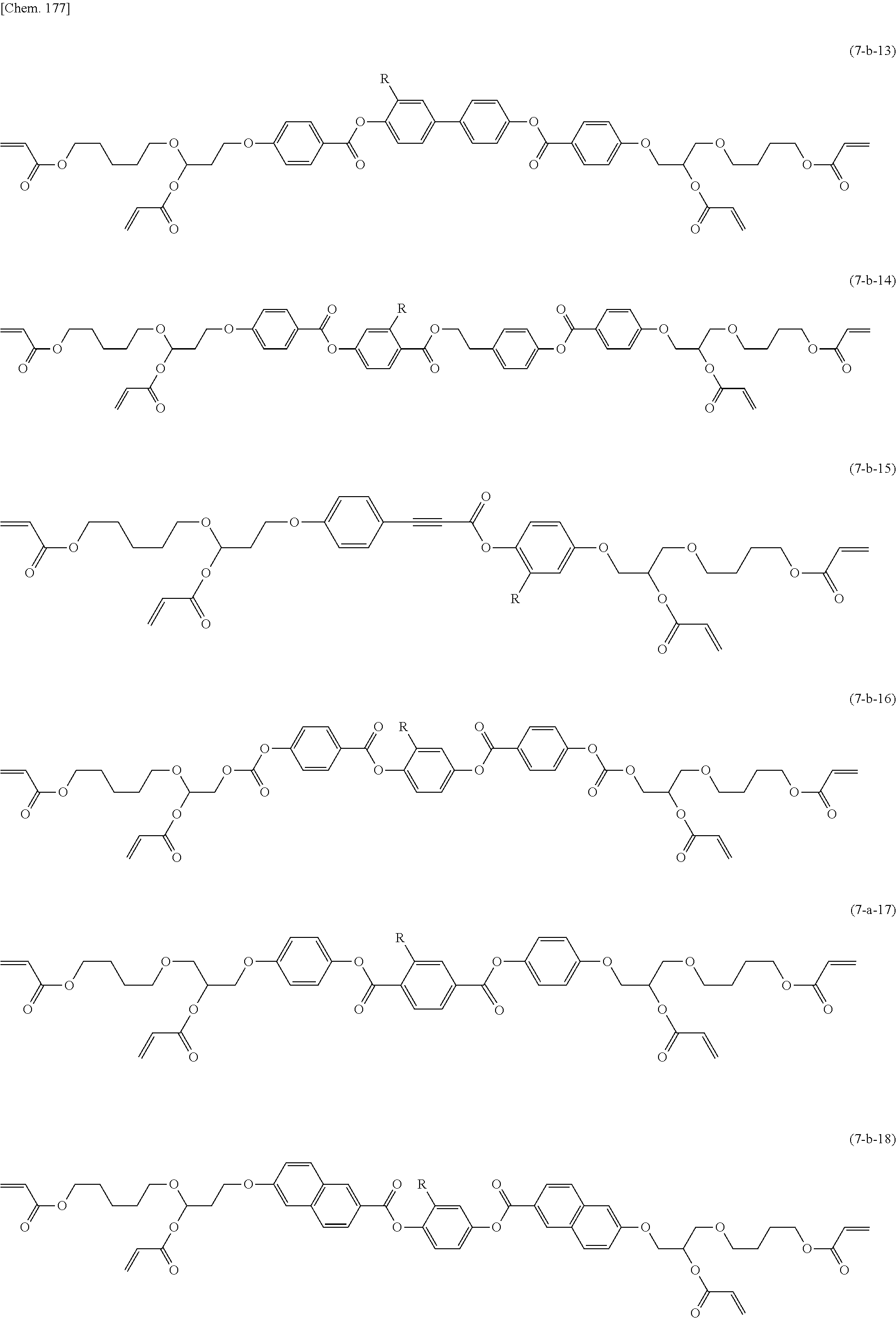

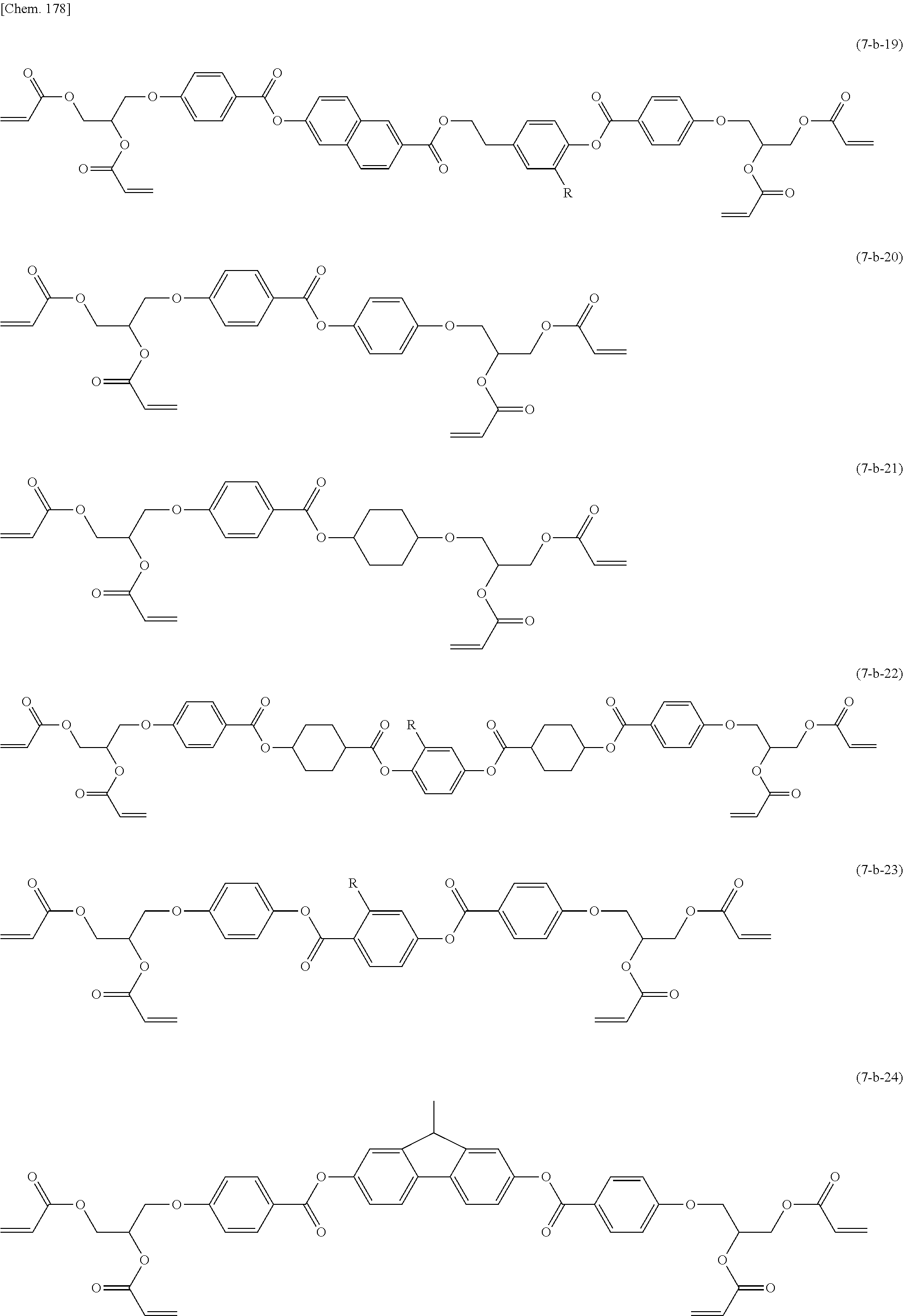

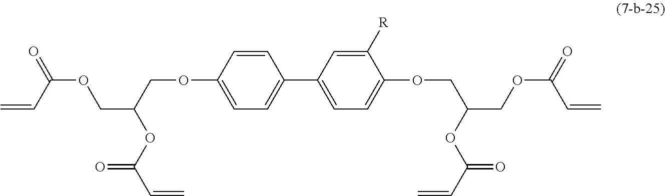

(In the formulae, R represents a hydrogen atom, a halogen atom, an alkyl group having 1 to 6 carbon atoms, an alkoxy group having 1 to 6 carbon atom, or a cyano group. In a case where these groups represent an alkyl group having 1 to 6 carbon atoms or an alkoxy group having 1 to 6 carbon atoms, all groups may be unsubstituted or substituted with one or two or more halogen atoms.)

These liquid crystalline compounds may be used alone or in combination of two or more kinds thereof.

It is preferable that the polymerizable compound represented by any of Formulae (2-a) to (7-a) satisfies Formula (I).

Re(450 nm)/Re(550 nm)<1.0 (I)

(In the formula, Re (450 nm) represents an in-plane phase difference of the compound containing at least two polymerizable groups at a wavelength of 450 nm when the polymerizable compound is aligned on a substrate such that a long axis direction of the molecule is substantially horizontal with respect to the substrate and Re (550 nm) represents an in-plane phase difference of the compound containing at least two polymerizable groups at a wavelength of 550 nm when the polymerizable compound is aligned on a substrate such that a long axis direction of the molecule is substantially horizontal with respect to the substrate.) In order to improve the reversed wavelength dispersion of the optically anisotropic body obtained by polymerizing the polymerizable composition, Re (450 nm)/Re (550 nm) is more preferably less than 0.98 and still more preferably 0.95.

The total content of the compound containing at least two or more polymerizable groups is preferably 2% to 99% by mass, more preferably 10% to 85% by mass, and particularly preferably 20% to 80% by mass with respect to the total amount of the polymerizable compound used in the polymerizable composition (in other words, the total content of the compound represented by General Formula (1) and the compound containing two or more polymerizable groups).

Particularly in a case where the birefringence of a polymer obtained by polymerizing the polymerizable composition becomes larger on a long wavelength side, that is, in a case where the reversed wavelength dispersion is intended to be improved, it is preferable that the compound selected from compounds represented by Formulae (2-a) to (7-a) is used alone or in combination of two or more kinds thereof, and the content of the compound is preferably 2% to 99% by mass, more preferably 5% to 90% by mass, and particularly preferably 20% to 80% by mass with respect to the total amount of the polymerizable compound used in the polymerizable composition.

Further, in a case where the alignment properties of the polymer obtained by polymerizing the polymerizable composition is intended to be further improved, it is preferable that the compound selected from compounds represented by Formulae (2-b) to (7-b) is used alone or in combination of two or more kinds thereof, and the content of the compound is preferably 2% to 80% by mass, more preferably 10% to 90% by mass, and particularly preferably 20% to 99% by mass with respect to the total amount of the polymerizable compound used in the polymerizable composition.

Further, in a case where the heat resistance of the polymer obtained by polymerizing the polymerizable composition is intended to be emphasized, it is preferable that one or two or more compounds selected from compounds represented by Formulae (2-a) to (7-a) and one or two or more compounds selected from compounds represented by Formulae (2-b) and (7-b) are used in combination, and the content of the compound selected from compounds represented by Formulae (2-a) to (7-a) is preferably 25% to 95% by mass, more preferably 35% to 95% by mass, and particularly preferably 50% to 95% by mass with respect to the total amount of the polymerizable compound used in the polymerizable composition and the content of the compound selected from compounds represented by Formulae (2-b) to (7-b) is preferably 25% to 95% by mass, more preferably 35% to 90% by mass, and particularly preferably 50% to 80% by mass with respect to the total amount of the polymerizable compound used in the polymerizable composition.

Initiator (c)

The polymerizable composition of the present invention may contain an initiator as necessary. A polymerization initiator used in the polymerizable composition of the present invention is used for polymerizing the polymerizable composition of the present invention. A photopolymerization initiator used in a case where the polymerization is performed by irradiation with light is not particularly limited, but conventionally known initiators can be used to the extent that does not inhibit the alignment state of the polymerizable liquid crystalline compound represented by General Formula (1) and the alignment state of the polymerizable liquid crystalline compound containing at least two polymerizable groups.

Examples of the conventionally known initiators include 1-hydroxycyclohexylphenylketone “IRGACURE 184”, 1-(4-isopropylphenyl)-2-hydroxy-2-methylpropane-1-one “DAROCURE 1116”, 2-methyl-1-[(methylthio)phenyl]-2-morpholinopropane-1 “IRGACURE 907”, 2,2-dimethoxy-1,2-diphenylethane-1-one “IRGACURE 651”, 2-benzyl-2-dimethylamino-1-(4-morpholinophenyl)-butanone “IRGACURE 369”), 2-dimethylamino-2-(4-methylbenzyl)-1-(4-morpholino-phenyl) butane-1-one “IRGACURE 369”, 2, 2-dimethoxy-1, 2-diphenylethane-1-one, bis(2, 4, 6-trimethylbenzoyl)-diphenylphosphine oxide “LUCIRIN TPO”, 2, 4, 6-trimethylbenzoyl-phenyl-phosphine oxide “IRGACURE 819”, 1, 2-octanedione, 1-[4-(phenylthio)-, 2-(O-benzoyloxime)], ethanone “IRGACURE OXE01”, 1-[9-ethyl-6-(2-methylbenzoyl)-9H-carbazole-3-yl]-, 1-(O-acetyloxime) “IRGACURE OXE02” (all manufactured by BASF SE), a mixture of 2,4-diethylthioxanthone (“KAYACURE DETX”, manufactured by Nippon Kayaku Co., Ltd.) and ethyl p-dimethylamino benzoate (“KAYACURE EPA”, manufactured by Nippon Kayaku Co., Ltd.), a mixture of isopropylthioxanthone (“QUANTACURE ITX”, manufactured by Ward Blenkinsop Co., Ltd.) and ethyl p-dimethylamino benzoate, “ESACURE ONE”, “ESACURE KIP150”, “ESACURE KIP160”, “ESACURE 1001M”, “ESACURE A198”, “ESACURE KIP IT”, “ESACURE KTO46”, “ESACURE TZT” (all manufactured by Fratelli-Lamberti SpA”), “SPEEDCURE BMS”, “SPEEDCURE PBZ”, and “benzophenone” (manufactured by LAMBSON Ltd.). In addition, a photoacid generator can be used as a photocationic initiator. Examples of the photoacid generator include a diazodisulfone-based compound, a triphenylsulfonium-based compound, a phenylsulfone-based compound, a sulfonylpyridine-based compound, a triazine-based compound, and a diphenyliodonium compound.

The content of the photopolymerization initiator is preferably 0.1% to 10% by mass and particularly preferably 1% to 6% by mass with respect to the total amount of the total content of the compound represented by General Formula (1) and the total content of the compound containing two or more polymerizable groups, which are used in the polymerizable composition of the present invention. These may be used alone or in combination of two or more kinds thereof.

Further, as a thermal polymerization initiator used for thermal polymerization, conventionally known initiators can be used, and examples thereof include an organic peroxide such as methyl acetoacetate peroxide, cumene hydroperoxide, benzoyl peroxide, bins (4-t-butylcyclohexyl) peroxy dicarbonate, t-butylperoxy benzoate, methyl ethyl ketone peroxide, 1, i-his (t-hexylperoxy) 3, 3,5-trimethylcyclohexane, p-pentahydroperoxide, t-butylhydroperoxide, dicumyl peroxide, isobutyl peroxide, di(3-methyl-3-methoxybutyl)peroxy dicarbonate, or 1, 1-bis(t-butylperoxy)cyclohexane; an azonitrile compound such as 2,2′-azobisisobutyronitrile or 2,2′-azobis(2,4-dimethylvaleronitrile); an azoamidine compound such as 2,2′-azobis(2-methyl-N-phenylpropion-amidine)dihydrochloride; an azoamide compound such as 2,2′ azobis{2-methyl-N-[1,1-bis(hydroxymethyl)-2-hydroxyethyl]propionamide}; and an alkylazo compound such as 2,2′ azobis(2,4, 4-trimethylpentane). The content of the thermal polymerization initiator is preferably 0.1 to 10 by mass and particularly preferably 1% to 6% by mass with respect to the total amount of the total content of the compound represented by General Formula (1) and the total content of the compound containing two or more polymerizable groups, which are used in the polymerizable composition of the present invention. These may be used alone or in combination of two or more kinds thereof.

Organic Solvent (d)

The polymerizable composition of the present invention may contain an organic solvent as necessary. The organic solvent to be used is not particularly limited, but an organic solvent that satisfactorily dissolves the polymerizable compound is preferable and an organic solvent which can be dried at a temperature of 100° C. or lower is preferable. Examples of such solvents include aromatic hydrocarbon such as toluene, xylene, cumene, or mesitylene, an ester-based solvent such as methyl acetate, ethyl acetate, propyl acetate, butyl acetate, cyclohexyl acetate, 3-butoxymethyl acetate, or ethyl lactate, a ketone-based solvent such as methyl ethyl ketone, methyl isobutyl ketone, cyclohexanone, or cyclopentanone, an ether-based solvent such as tetrahydrofuran, 1,2-dimethoxyethane, or anisole, an amide-based solvent such as N,N-dimethylformamide or N-methyl-2-pyrrolidone, ethylene glycol monomethyl ether acetate, propylene glycol monomethyl ether acetate, propylene glycol monomethyl ether, propylene glycol diacetate, propylene glycol monomethyl propyl ether, diethylene glycol monomethyl ether acetate, y-butyrolactone, and chlorobenzene. These may be used alone or in combination of two or more kinds thereof. From the viewpoint of solution stability, it is preferable to use one or more solvents selected from a ketone-based solvent, an ether-based solvent, an ester-based solvent, and an aromatic hydrocarbon-based solvent.

Since the polymerizable composition used in the present invention is typically used by application, the proportion of the organic solvent to be used is not particularly limited as long as the applied state is not significantly impaired, but the content of the organic solvent is preferably used such that the total amount of the total content of the compound represented by General Formula (1) and the total content of the compound containing two or more polymerizable groups, which are used in the polymerizable composition of the present invention is 0.1% to 99% by mass, more preferably 5% to 60% by mass, and particularly preferably 10% to 50% by mass.

Further, it is preferable that the compound represented by General Formula (1) and the compound containing two or more polymerizable groups are dissolved in the organic solvent by heating and stirring the solution in order for the compound to be uniformly dissolved therein. The heating temperature during the heating and the stirring may be adjusted as appropriate by considering the dissolution of the polymerizable liquid crystal composition in the organic solvent, but is preferably 15° C. to 130° C., more preferably 30° C. to 110° C., and particularly preferably 50° C. to 100° C. from the viewpoint of productivity.

Additive (e)

The polymerizable composition of the present invention may include general-purpose additives for uniform application or depending on various purposes thereof. For example, additives such as a polymerization inhibitor, an antioxidant, an ultraviolet absorbing agent, a leveling agent, an alignment controlling agent, a chain transfer agent, an infrared absorbing agent, a thixotropic agent, an antistatic agent, a dye, a filler, a chiral compound, a non-liquid crystalline compound having a polymerizable group, a liquid crystal compound, and an alignment material can be added to the extent that does not significantly degrade alignment properties of liquid crystals.

Polymerization Inhibitor (f)

The polymerizable composition of the present invention may contain a polymerization inhibitor as necessary. The polymerization inhibitor to be used is not particularly limited, and conventionally known polymerization inhibitors can be used.

Examples thereof include a phenol-based compound such as p-methoxyphenol, cresol, t-butyl catechol, 3,5-di-t-butyl-4-hydroxytoluene, 2,2′-methylenebis(4-methyl-6-t-butylphenol) 2,2′-methylenebis(4-ethyl-6-t-butylphenol), 4,4′-thiobis(3-methyl-6-t-butylphenol), 4-methoxy-1-naphthol, or 4,4′-dialkoxy-2,2′-bi-1-naphthol; a quinone-based compound such as hydroquinone, methylhydroquinone, tert-butylhydroquinone, p-benzoquinone, methyl-p-benzoquinone, tert-butyl-p-benzoquinone, 2,5-diphenylbenzoquinone, 2-hydroxy-1,4-naphthoquinone, 1,4-naphthoquinone, 2,3-dichloro-1,4-naphthoquinone, anthraquinone, or diphenoquinne; an amine-based compound such as p-phenylenediamine, 4-aminodiphenylamine, N, N′-diphenyl-p-phenylenediamine, N-i-propyl-N′-phenyl-p-phenylenediamine, N-(1,3-dimethylbutyl)-N′-phenyl-p-phenylenediamine, N,N′-di-2-naphthyl-p-phenylenediamine, diphenylamine, N-phenyl-β-naphthylamine, 4,4′-dicumyl-diphenylamine, or 4,4′-dioctyl-diphenylamine; a thioether-based compound such as phenothiazine or distearyl thiodipropionate; and a nitroso compound such as N-nitrosodiphenylamine, N-nitrosophenyinaphthylamine, N-nitrosodinaphthyiamine, p-nitrosophenol, nitrosobenzene, p-nitrosodiphenyiamine, α-nitroso-β-naphthol, N,N-dimethyl p-nitrosoaniline, p-nitrosodiphenylamine, p-nitrosodimethylamine, p-nitroso-N,N-diethylamine, N-nitrosoethanolamine, N-nitrosodi-n-butylamine, N-nitroso-N-n-butyl-4-butanolamine, N-nitroso-diisopropanolamine, N-nitroso-N-ethyl-4-butanolamine, 5-nitroso-8-hydroxyquinoline, N-nitrosomorpholine, N-nitroso-N-phenylhydroxyamine ammonium salt, nitrosobenzene, 2,4,6-tri-tert-butylnitrobenzene, N-nitroso-N-methyl-p-toluenesulfonamide, N-nitroso-N-ethylurethane, N-nitroso-N-n-propylurethane, 1-nitroso-2-naphthol, 2-nitroso-1-naphthol, sodium 1-nitroso-2-naphthol-3, 6-sulfonate, sodium 2-nitroso-1-naphthol-4-sulfonate, 2-nitroso-5-methylaminophenol hydrochloride, or 2-nitroso-5-methylaminophenol hydrochloride.

The amount of the polymerization inhibitor to be added is preferably 0.01% to 2.0% by mass and more preferably 0.05% to 1.0% by mass with respect to the total amount of the total content of the compound represented by General Formula (1) and the total content of the compound containing two or more polymerizable groups, which are used in the polymerizable composition of the present invention.

Antioxidant (g)

The polymerizable composition of the present invention may contain an antioxidant as necessary. Examples of such a compound include a hydroquinone derivative, a nitrosoamine-based polymerization inhibitor, and a hindered phenol-based antioxidant, and more specific examples thereof include tert-butylhydroquinone, “Q-1300” and “Q-1301” (both manufactured by Wako Pure Chemical Industries, Ltd.), pentaerythritol tetrakis[3-(3,5-di-tert-butyl-4-hydroxyphenyl)propionate “IRGANOX 1010”, thiodiethylene bis[3-(3,5-di-tert-butyl-4-hydroxyphenyl) propionate “IRGANOX 1035”, octadecyl-3-(3,5-di-tert-butyl-4-hydroxyphenyl)propionate “IRGANOX 1076”, “IRGANOX 1135”, “IRGANOX 1330”, 4, 6-bis (octylthiomethyl)-o-cresol “IRGANOX 1520L”, “IRGANOX 1726”, “IRGANOX 245”, “IRGANOX 259”, “IRGANOX 3114”, “IRGANOX 3790”, “IRGANOX 5057”, “IRGANOX 565” (all manufactured by BASF SE), ADEKA STAB AO-20, AO-30, AO-40, AO-50, AO-60, AO-80 (all manufactured by ADEKA CORPORATION), SUMILIZER BHT, SUMILIZER BBE-S, and SUMILIZER GA-80 (manufactured by Sumitomo Chemical Industries Co., Ltd.)

The amount of the antioxidant to be added is preferably 0.01% to 2.0% by mass and more preferably 0.05% to 1.0% by mass with respect to the total amount of the total content of the compound represented by General Formula (1) and the total content of the compound containing two or more polymerizable groups, which are used in the polymerizable composition of the present invention.

Ultraviolet Absorbing Agent (h)

The polymerizable composition of the present invention may contain an ultraviolet absorbing agent and a light stabilizer as necessary. The ultraviolet absorbing agent or the light stabilizer to be used is not particularly limited, but it is preferable to use an optically anisotropic body or an optical film in order to improve light resistance.

Examples of the ultraviolet absorbing agent include 2-(2-hydroxy-5-t-butylphenyl)-2H-benzotriazole “TINUVIN PS”, “TINUVIN 99-2”, “TINUVIN 109”, “TINUVIN 213”, “TINUVIN 234”, “TINUVIN 326”, “TINUVIN 328”, “TINUVIN 329”, “TINUVIN 384-2”, “TINUVIN 571”, 2-(2H-benzotriazole-2-yl)-4, 6-bis(1-methyl-1-phenylethyl)phenol “TINUVIN 900”, 2-(2H-benzotriazole-2-yl)-6-(1-methyl-1-phenylethyl)-4-(1, 1, 3, 3-tetramethylbutyl) phenol “TINUVIN 928”, “TINUVIN 1130”, “TINUVIN 400”, “TINUVIN 405”, 2,4-bis[2-hydroxy-4-butoxyphenyl]-6-(2,4-dibutoxyphenyl-1, 3,5-triazine “TINUVIN 460”, “TINUVIN 479”, “TIN VIN 5236” (all manufactured by BASF SE), “ADEKA STAB LA-32”, “ADEKA STAB LA-34”, “ADEKA STAB LA-36”, “ADEKA STAB LA-31”, “ADEKA STAB LA-1413”, and “ADEKA STAB LA-51” (all manufactured by ADEKA CORPORATION).

Examples of the light stabilizer include “TINUVIN 111FDL”, “TINUVIN 123”, “TINUVIN 144”, “TINUVIN 152”, “TINUVIN 292”, “TINUVIN 622”, “TINUVIN 770”, “TINUVIN 765”, “TINUVIN 780”, “TINUVIN 905”, “TINUVIN 5100”, “TINUVIN 5050”, “TINUVIN 5060”, “TINUVIN 5151”, “CHIMASSORB 119FL”, “CHIMASSORB 944FL”, “CHIMASSORB 944LD” (all manufactured by BASF SE), “ADEKA STAB LA-52”, “ADEKA STAB LA-57”, “ADEKA STAB LA-62”, “ADEKA STAB LA-67”, “ADEKA STAB LA-63P”, “ADEKA STAB LA-68LD”, “ADEKA STAB LA-77”, “ADEKA STAB LA-82”, and “ADEKA STAB LA-87” (all manufactured by ADEKA CORPORATION).

Leveling Agent (i)

The polymerizable composition of the present invention may contain a leveling agent as necessary. The leveling agent to be used is not particularly limited, but an agent which can reduce film thickness unevenness in a case where a thin film such as an optically anisotropic body or an optical film is formed is preferable. Examples of the leveling agent include alkyl carboxylate, alkyl phosphate, alkyl sulfonate, fluoroalkyl carboxylate, fluoroalkyl phosphate, fluoroalkyl sulfonate, a polyoxyethylene derivative, a fluoroalkyl ethylene oxide derivative, a polyethylene glycol derivative, alkyl ammonium salts, and fluoroalkyl ammonium salts.

Specific examples thereof include “MEGAFACE F-114”, “MEGAFACE F-251”, “MEGAFACE F-281”, “MEGAFACE F-410”, “MEGAFACE F-430”, “MEGAFACE F-444”, “MEGAFACE F-472F”, “MEGAFACE F-477”, “MEGAFACE F-510”, “MEGAFACE F-511”, “MEGAFACE F-552”, “MEGAFACE F-553”, “MEGAFACE F-554”, “MEGAFACE F-555”, “MEGAFACE F-556”, “MEGAFACE F-557”, “MEGAFACE F-558”, “MEGAFACE F-559”, “MEGAFACE F-560”, “MEGAFACE F-561”, “MEGAFACE F-562”, “MEGAFACE F-563”, “MEGAFACE F-565”, “MEGAFACE F-567”, “MEGAFACE F-568”, “MEGAFACE F-569”, “MEGAFACE F-570”, “MEGAFACE F-571”, “MEGAFACE R-40”, “MEGAFACE R-41”, “MEGAFACE R-43”, “MEGAFACE R-94”, “MEGAFACE RS-72-K”, “MEGAFACE RS-75”, “MEGAFACE RS-76-E”, “MEGAFACE RS-76-NS”, “MEGAFACE RS-90”, “MEGAFACE EXP. TF-1367”, “MEGAFACE EXP. TF1437”, “MEGAFACE EXP. TF1537”, “MEGAFACE EXP. TF-2066” (all manufactured by DIG Corporation), “FTERGENT 100”, “FTERGENT 100C”, “FTERGENT 110”, “FTERGENT 150”, “FTERGENT 150CH”, “FTERGENT 100A-K”, “FTERGENT 300”, “FTERGENT 310”, “FTERGENT 320”, “FTERGENT 400SW”, “FTERGENT 251”, “FTERGENT 215M”, “FTERGENT 212M”, “FTERGENT 215M”, “FTERGENT 250”, “FTERGENT 222F”, “FTERGENT 212D”, “FTX-218”, “FTERGENT 209F”, “FTERGENT 245F”, ““FTERGENT 208G”, “FTERGENT 240G”, “FTERGENT 212P”, “FTERGENT 220P”, “FTERGENT 228P”, “DFX-18”, “FTERGENT 601AD”, “FTERGENT 602A”, “FTERGENT 650A”, “FTERGENT 750FM”, “FTX-730FM”, “FTERGENT 730FL”, “FTERGENT 710FS”, “FTERGENT 710FM”, “FTERGENT 710FL”, “FTERGENT 750LL”, “FTX-730LS”, and “FTERGENT 730LM” (all manufactured by NEOS COMPANY LIMITED), “BYK-300”, “BYK-302”, “BYK-306”, “BYK-307”, “BYK-31”, “BYK-315”, “BYK-320”, “BYK-322”, “BYK-323”, “BYK-325”, “BYK-330”, “BYK-331”, “BYK-333”, “BYK-337”, “BYK-340”, “BYK-344”, “BYK-370”, “BYK-375”, “BYK-377”, “BYK-350”, “BYK-352”, “BYK-354”, “BYK-355”, “BYK-356”, “BYK-358N”, “BYK-361N”, “BYK 357”, “BYK-390”, “BY K-392”, “BYK-UV3500”, “BYK-UV3510”, “BYK-UV3570”, and “BYK-Silclean3700” (all manufactured by BYK Additives and Instruments), “TEGO Rad 2100”, “TEGO Rad 2011”, “TEGO Rad 2200N”, “TEGO Rad 2250”, “TEGO Rad 2300”, “TEGO Rad2500”, “TEGO Rad 2600”, “TEGO Rad2650”, “TEGO Rad 2700”, “TEGO Flow 300”, “TEGO Flow 370”, “TEGO Flow 425”, “TEGO Flow ATF2”, “TEGO Flow ZFS460”, “TEGO Glide 100”, “TEGO Glide 110”, “TEGO Glide 130”, “TEGO Glide 410”, “TEGO Glide 411”, “TEGO Glide 415”, “TEGO Glide 432”, “TEGO Glide 440”, “TEGO Glide 450”, “TEGO Glide 482”, “TEGO Glide A115”, “TEGO Glide B484”, “TEGO Glide B1454”, “TEGO Glide ZG400”, “TEGO Twin 4000”, “TEGO Twin 4100”, “TEGO Twin 4200”, “TEGO Wet 240”, “TEGO Wet 250”, “TEGO Wet 260”, “TEGO Wet 265”, “TEGO Wet 270”, “TEGO Wet 280”, “TEGO Wet 280”, “TEGO Wet 500”, “TEGO Wet 505”, “TEGO Wet 510”, “TEGO Wet 520”, and “TEGO Wet KL245” (all manufactured by Evenik Industries AG), “FC-4430”, “FC-4432” (both manufactured by 3M Japan Limited), “UNIDYNE NS” (manufactured by DAIKIN INDUSTRIES, LTD.), “SURFLON S-241”, “SURFLON S-242”, “SURFLON S-243”, “SURFLON S-420”, “SURFLON S-61l”, “SURFLON S-651”, and “SURFLON S-386” (all manufactured by AGC SEMI CHEMICAL CO., LTD.), “DISPARLON OX-880-EF”, “DISPARLON OX-881”, “DISPARLON OX-883”, “DISPARLON OX-77 EF”, “DISPARLON OX-710”, “DISPARLON 1922”, “DISPARLON 1927”, “DISPARLON 1958”, “DISPARLON P-410EF”, “DISPARLON 2-420”, “DISPARLON P-425”, “DISPARLON PD-7”, “DISPARLON 1970”, “DISPARLON 230”, “DISPARLON LF-1980”, “DISPARLON LF-1982”, “DISPARLON LF-1983”, “DISPARLON LF-1084”, “DISPARLON LF-985”, “DISPARLON LHP-90”, “DISPARLON LH-91”, “DISPARLON LHP-95”, “DISPARLON LHP-96”, “DISPARLON OX-715”, “DISPARLON 1930N”, “DISPARLON 1931”, “DISPARLON 1933”, “DISPARLON 1934”, “DISPARLON 1711EF”, “DISPARLON 1751N”, “DISPARLON 1761”, “DISPARLON LS-009”, “DISPARLON LS-001”, and “DISPARLON LS-050” (all manufactured by Kusumoto Chemicals, Ltd.), “PF-151N”, “PF-636”, “PF-6320” “PF-656”, “PF-6520”, “PF-652-NF”, and “PF-3320” (all manufactured by OMNOVA SOLUTION Inc.), “POLYFLOW NO. 7”, “POLYFLOW NO. 50E”, “POLYFLOW NO. 50EHF”, “POLYFLOW NO. 54N”, “POLYFLOW NO. 75”, “POLYFLOW NO. 77”, “POLYFLOW NO. 85”, “POLYFLOW NO. 85HF”, “POLYFLOW NO. 90”, “POLYFLOW NO. 90D-50”, “POLYFLOW NO. 95”, “POLYFLOW NO. 99C”, “POLYFLOW KL-400K”, “POLYFLOW KL-400HF”, “POLYFLOW KL-401”, “POLYFLOW KL-402”, “POLYFLOW KL-403”, “POLY FLOW KL-404”, “POLYFLOW KL-100”, “POLYFLOW LE-604”, “POLYFLOW KL-700”, “FLOWLEN AC-300”, “FLOWLEN AC-303”, “FLOWLEN AC-324”, “FLOWLEN AC-326F”, “FLOWLEN AC-530”, “FLOWLEN AC-90”, “FLOWLEN AC-903HF”, “FLOWLEN AC-1160”, “FLOWLEN AC-1190”, “FLOWLEN AC-2000”, “FLOWLEN AC-2300C”, “FLOWLEN AO-82”, “FLOWLEN AO-98”, and “FLOWLEN AO-108” (all manufactured by KYOEISHA CHEMICAL CO., LTD.), “L-7001”, “L-7002”, “8032ADDITIVE”, “57ADDTIVE”, “L-7064”, “FZ-2110”, “FZ-2105”, “67ADDTIVE”, and “8616ADDTIVE” (all manufactured by Dow Corning Toray Co., Ltd.).

The amount of the leveling agent to be added is preferably 0.01% to 2% by mass and more preferably 0.05% to 0.5% by mass with respect to the total amount of the total content of the compound represented by General Formula (1) and the total content of the compound containing two or more polymerizable groups, which are used in the polymerizable composition of the present invention.

Further, in a case where an optically anisotropic body is used as the polymerizable composition of the present invention, the tilt angle between the interface of the air and the optically anisotropic body can be effectively reduced by using the leveling agent.

Alignment Controlling Agent (j)

The polymerizable composition of the present invention may contain an alignment controlling agent in order to control the alignment state of the liquid crystalline compound. As the alignment controlling agent to be used, agents used for substantial horizontal alignment, substantial vertical alignment, or substantial hybrid alignment of the liquid crystalline compound with respect to the base material may be exemplified. Further, in a case where a chiral compound is added, agents used for substantial plane alignment of the liquid crystalline compound with respect to the base material may be exemplified. As described above, horizontal alignment or plane alignment may be induced by a surfactant in some cases, the alignment controlling agent is not particularly limited as long as the alignment state of each liquid crystalline compound is induced, and conventionally known ones can be used.

As such an alignment controlling agent, a compound which has an effect of effectively reducing the tilt angle between the interface of the air and an optically anisotropic body in a case where an optically anisotropic body is used as the polymerizable liquid crystal composition, has a repeating unit represented by Formula (8), and has a weight-average molecular weight of 100 to 100000 may be exemplified.

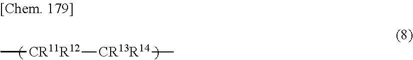

(In the formula, R¹¹, R¹², R¹³, and R¹⁴ each independently represent a hydrogen atom, a halogen atom, or a hydrocarbon group having 1 to 20 carbon atoms, and the hydrogen atoms in the hydrocarbon group may be substituted with one or more halogen atoms.)

In addition, examples of the compound include a rod-like liquid crystalline compound modified with a fluoroalkyl group, a discotic liquid crystalline compound, and a polymerizable compound containing a long-chain aliphatic alkyl group which may have a branched structure.

Examples of the compound which has an effect of effectively reducing the tilt angle between the interface of the air and an optically anisotropic body in a case where an optically anisotropic body is used as the polymerizable liquid crystal composition include cellulose nitrate, cellulose acetate, cellulose propionate, cellulose butyrate, a rod-like liquid crystalline compound modified with a heteroaromatic ring salt, a cyano group, and a rod-like liquid crystalline compound modified with a cyanoalkyl group.

Chain Transfer Agent (k)

The polymerizable composition of the present invention may contain a chain transfer agent in order to further improve adhesiveness among the polymer, the optically anisotropic body, and the base material. Examples of the chain transfer agent include aromatic hydrocarbons, halogenated hydrocarbons such as chloroform, carbon tetrachloride, carbon tetrabromide, and bromotrichloromethane, a mercaptan compound such as octyl mercaptan, n-butyl mercaptan, n-pentyl mercaptan, n-hexadecyl mercaptan, n-tetradecyl, n-dodecyl mercaptan, t-tetradecyl mercaptan, or t-dodecyl mercaptan, a thiol compound such as hexanedithiol, decanedithiol, 1,4-butanediol bisthioproprionate, 1, 4-butanediol bisthioglycolate, ethylene glycol bisthioglycolate, ethylene glycol bisthiopropionate, trimethylolpropane tristhioglycolate, trimethylolpropane tristhiopropionate, trimethylolpropane tris(3-mercaptobutyrate), pentaerythritol tetrakisthioglycolate, pentaerythritol tetrakisthiopropionate, trimercaptopropionic acid tris(2-hydroxyethyl)isocyanurate, 1,4-dimethyl mercaptobenzene, 2,4,6-trimercapto-s-triazine, or 2-(N,N-dibutylamino)-4,6-dimercapto-s-triazine, a sulfide compound such as dimethyl xanthogen disulfide, diethyl xanthogen disulfide, diisopropyl xanthogen disulfide, tetramethyl thiuram disulfide, tetraethyl thiuram disulfide, or tetrabutyl thiuram disulfide, N, N-dimethylaniline, N, N-divinylaniline, pentaphenylethane, an a-methylstyrene dimer, acrolein, allyl alcohol, terpineol, a-terpinene, y-terpinene, and dipentene. Among these, 2, 4-diphenyl-4-methyl-1-pentene and a thiol compound are more preferable.

Specifically, compounds represented by Formulae (9-1) to (9-12) are preferable.

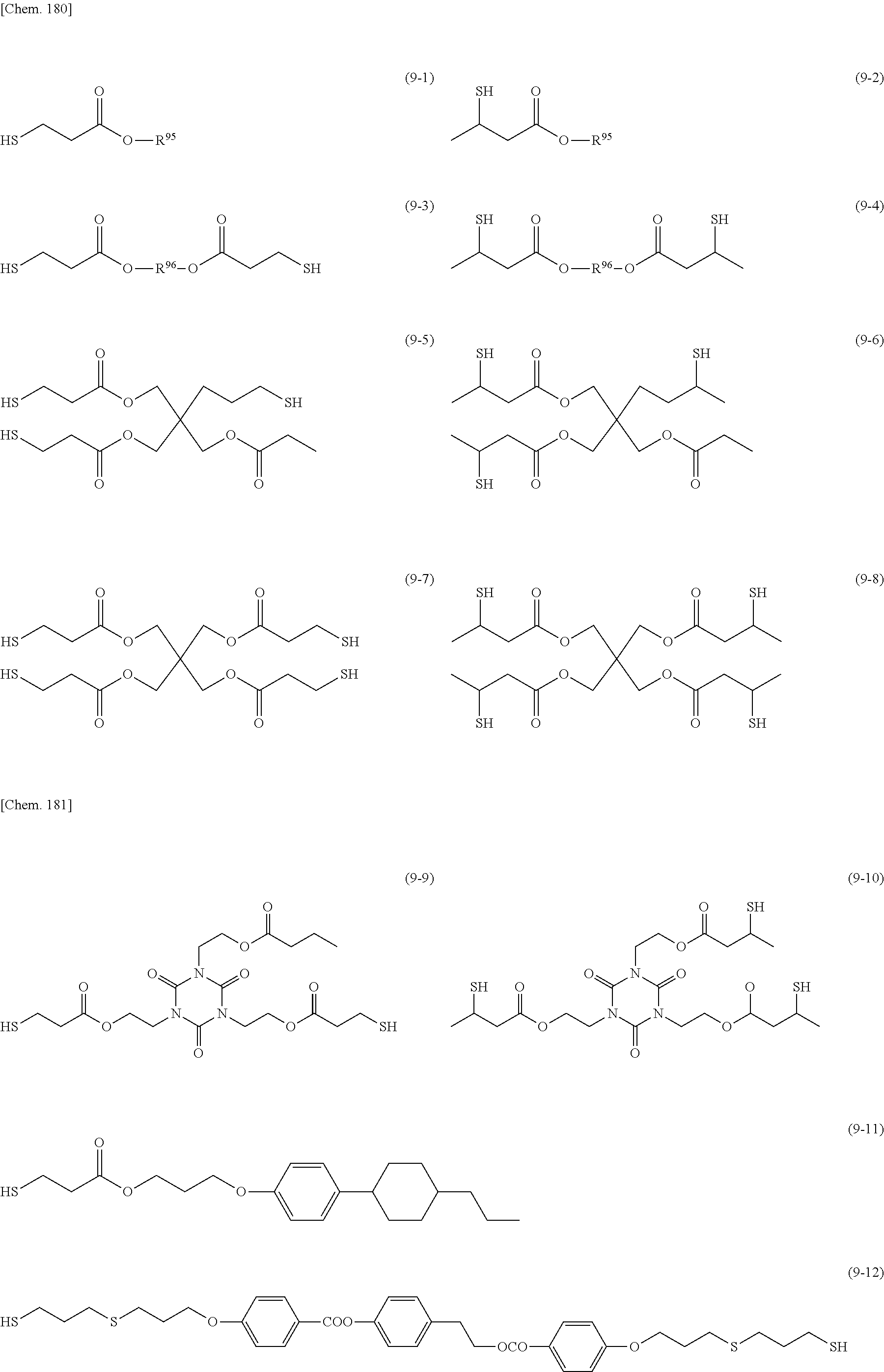

In the formulae, R⁹⁵ represents an alkyl group having 2 to 18 carbon atoms, the alkyl group may be linear or branched, one or more methylene groups in the alkyl group may be substituted with an oxygen atom, a sulfur atom, —CO—, —OCO—, —COO—, or —CH═CH— by assuming that an oxygen atom and a sulfur atom are not directly bonded to each other, R⁹⁶ reprvesents an alkylene group having 2 to 148 carbon atoms, and one or more methylene groups in the alkylene group may be substituted with an oxygen atom, a sulfur atom, —CO—, —OCO—, —COO—, or —CH═CH— by assuming that an oxygen atom and a sulfur atom are not directly bonded to each other.

It is preferable that the chain transfer agent is added during a step of preparing a polymerizable solution by mixing the polymerizable liquid crystal compound in an organic solvent and heating and stirring the solution, but the chain transfer agent may be added during the subsequent step of mixing a polymerization initiator into the polymerizable solution or may be added during both steps.

The amount of the chain transfer agent to be added is preferably 0.1% to 10% by mass and more preferably 1.0% to 5.0% by mass with respect to the total amount of the total content of the compound represented by General Formula (1) and the total content of the compound containing two or more polymerizable groups, which are used in the polymerizable composition of the present invention.

Further, a liquid crystal compound or the like which is not polymerizable can be added as necessary for the purpose of adjusting physical properties. It is preferable that the polymerizable compound which does not have liquid crystallinity is added during a step of preparing a polymerizable solution by mixing the polymerizable compound in an organic solvent and heating and stirring the solution, but the liquid crystal compound which is not polymerizable may be added during the subsequent step of mixing a polymerization initiator into the polymerizable solution or may be added during both steps. The amount of these compounds to be added is preferably 20% by mass or less, more preferably 10% by mass or less, and still more preferably 5% by mass or less with respect to the total amount of the total content of the compound represented by General Formula (1) and the total content of the compound containing two or more polymerizable groups, which are used in the polymerizable composition of the present invention.

Infrared Absorbing Agent (l)

The polymerizable composition of the present invention may contain an infrared absorbing agent as necessary. The infrared absorbing agent to be used is not particularly limited and the polymerizable liquid crystal composition may contain conventionally known ones within the range that does not impair the alignment properties.

Examples of the infrared absorbing agent include a cyanine compound, a phthalocyanine compound, a naphthoquinone compound, a dithiol compound, a diimmonium compound, an azo compound, and an ammonium salt.

Specific examples thereof include diimmonium salt type “NIR-IM1”, ammonium salt type “NIR-AM1” (both manufactured by Nagase ChemteX Corporation), “KARENZ IR-T”, “KARENZ IR-13F” (both manufactured by SHOWA DENKO K.K.), “YKR-2200”, “YKR-2100” (both manufactured by Yamamoto Chemicals Inc.), “IRA908”, “IRA931”, “IRA955”, and “IRA1034” (all manufactured by INDECO Co., Ltd.).

Antistatic Agent (m)

The polymerizable composition of the present invention may contain an antistatic agent as necessary. The antistatic agent to be used is not particularly limited and the polymerizable liquid crystal composition may contain conventionally known ones within the range that does not impair the alignment properties.

Examples of such an antistatic agent include a polymer compound containing at least one or more sulfonate groups or phosphate groups in a molecule, a compound containing a quaternary ammonium salt, and a surfactant containing a polymerizable group.

Among these, a surfactant containing a polymerizable group is preferable, and examples of an anionic surfactant containing a polymerizable group include alkyl ether-based surfactants such as “ANTOX SAD”, “ANTOX MS-2N” (both manufactured by Nippon Nyukazai Co., Ltd.), “AQUALON KH-05”, “AQUALON KH-10”, “AQUALON KH-20”, “AQUALON KH-0530”, “AQUALON KH-1025” (all manufactured by Dai-ichi Kogyo Seiyaku Co., Ltd.), “ADEKA REASOAP SR-10N”, “ADEKA REASOAP BR-2N” (both manufactured by ADEKA CORPORATION), and “LATEMUL PD-104” (manufactured by Kao Corporation), sulfosuccinic acid ester-based surfactants such as “LATEMUL S-120”, “LATEMUL S-120A”, “LATEMUL S-180P”, “LATEMUL S-180A” (manufactured by Kao Corporation), and “ELEMINOL JS-2” (manufactured by Sanyo Chemical Industries, Ltd.), alkylphenylether-based or alkylphenylester-based surfactants such as “AQUALON H-2855A”, “AQUALON H-3855B”, “AQUALON H-3855C”, “AQUALON H-3856”, “AQUALON HS-05”, “AQUALON HS-10”, “AQUALON HS-20”, “AQUALON HS-30”, “AQUALN HS-1025”, “AQUALON BC-05”, “AQUALON BC-10”, “AQUALON BC-20”, “AQUALON BC-1025”, and “AQUALON BC-2020” (all manufactured by Dai-ichi Kogyo Seiyaku Co., Ltd.), “ADEKA REASOAP SDX-222”, “ADEKA REASOAP SDX-223”, “ADEKA REASOAP SDX-232”, “ADEKA REASOAP SDX-233”, “ADEKA REASOAP SDX-259”, “ADEKA REASOAP SE-10N”, and “ADEKA REASOAP SE-20N” (all manufactured by ADEKA CORPORATION), (meth)acrylate sulfuric acid ester-based surfactants such as “ANTOX MS-60”, “ANTOX MS-2N” (both manufactured by Nippon Nyukazai Co., Ltd.), “ELEMINOLRS-30” (manufactured by Sanyo Chemical Industries, Ltd.), and phosphoric acid ester-based surfactants such as “H-3330P” (manufactured by Dai-ichi Kogyo Seiyaku Co., Ltd.) and “ADEKA REASOAP PP-70” (manufactured by ADEKA CORPORATION).

Among the surfactants containing a polymerizable group, examples of a non-ionic surfactant include alkyl ether-based surfactants such as “ANTOX LMA-20”, “ANTOX LMA-27”, “ANTOX EMH-20”, “ANTOX LMH-20”, “ANTOX SMH-20” (all manufactured by Nippon Nyukazai Co., Ltd.), “ADEKA REASOAP ER-10”, “ADEKA REASOAP ER-20”, “ADEKA REASOAP ER-30”, “ADEKA REASOAP ER-40” (all manufactured by ADEKA CORPORATION), “LATEMUL PD-420”, “LATEMUL PD-430”, and “LATEMUL PD-450” (all manufactured by Kao Corporation), alkyl phenyl ether-based or alkyl phenyl ester-based surfactants such as “AQUALON RN-10”, “AQUALON RN-20”, “AQUALON RN-30”, “AQUALON RN-50”, “AQUALON RN-2025” (all manufactured by Dai-ichi Kogyo Seiyaku Co., Ltd.), “ADEKA REASOAP NE-10”, “ADEKA REASOAP NE-20”, “ADEKA REASOAP NE-30”, and “ADEKA REASOAP NE-40” (all manufactured by ADEKA CORPORATION), and (meth)acrylate sulfuric acid ester-based surfactants such as “RMA-564”, “MA-568”, and “RMA-1114” (all manufactured by Nippon Nyukazai Co., Ltd.).

Other examples of antistatic agents include polyethylene glycol (meth)acrylate, methoxy polyethylene glycol (meth)acrylate, ethoxy polyethylene glycol (meth)acrylate, propoxy polyethylene glycol (meth)acrylate, n-butoxy polyethylene glycol (meth)acrylate, n-pentaxy polyethylene glycol (meth)acrylate, phenoxy polyethylene glycol (meth)acrylate, polypropylene glycol (meth)acrylate, methoxy polypropylene glycol (meth)acrylate, ethoxy polypropylene glycol (meth)acrylate, propoxy polypropylene glycol (meth)acrylate, n-butoxy polypropylene glycol (meth)acrylate, n-pentaxy polypropylene glycol (meth)acrylate, phenoxy polypropylene glycol (meth)acrylate, polytetramethylene glycol (meth)acrylate, methoxy polytetramethylene glycol (meth)acrylate, phenoxy tetraethylene glycol (meth)acrylate, hexaethylene glycol (meth)acrylate, and methoxy hexaethylene glycol (meth)acrylate.

The antistatic agent can be used alone or in combination of two or more kinds thereof. The amount of the antistatic agent to be added is preferably 0.001% to 10% by weight and more preferably 0.01% to 5% by weight with respect to the total amount of the total content of the compound represented by General Formula (1) and the total content of the compound containing two or more polymerizable groups, which are used in the polymerizable composition of the present invention.

Dye (n)

The polymerizable composition of the present invention may contain a dye as necessary. The dye to be used is not particularly limited and the polymerizable liquid crystal composition may contain conventionally known ones within the range that does not impair the alignment properties.

Examples of the dye include dichroic dyes and fluorescent dyes. Examples of such dyes include a polyazo dye, an anthraquinone dye, a cyanine dye, a phthalocyanine dye, a perylene dye, and a perinone dye, and a squarylium dye. From the viewpoint of addition, a dye exhibiting liquid crystallinity is preferable as the dye.

For example, dyes described in U.S. Pat. No. 2,400,877, Dreyer J. F., Phys. and Colloid Chem., 1948, 52, 808, “The Fixing of Molecular Orientation”, Dreyer J. F., Journal de Physique, 1969, 4, 114, “Light Polarization from Films of Lyotropic Nematic Liquid Crystals”, J. Lydon, “Chromonics” in “Handbook of Liquid Crystals Vol. 2B: Low Molecular Weight Liquid Crystals II”, D. Demus, J. Goodby, G. W. Gray, H. W. Spiessm, V. VIII ed, Willey-VCH, pp. 981-1007 (1998), Dichroic Dyes for Liquid Crystal Display A. V. Ivashchenko CRC Press, 1994, and “New Development of Functional Dye Market”, Chapter 1, pp. 1, 1994, published by CMC Corporation can be used.

Examples of the dichroic dyes include dyes represented by Formulae (d-1) to (d-8).

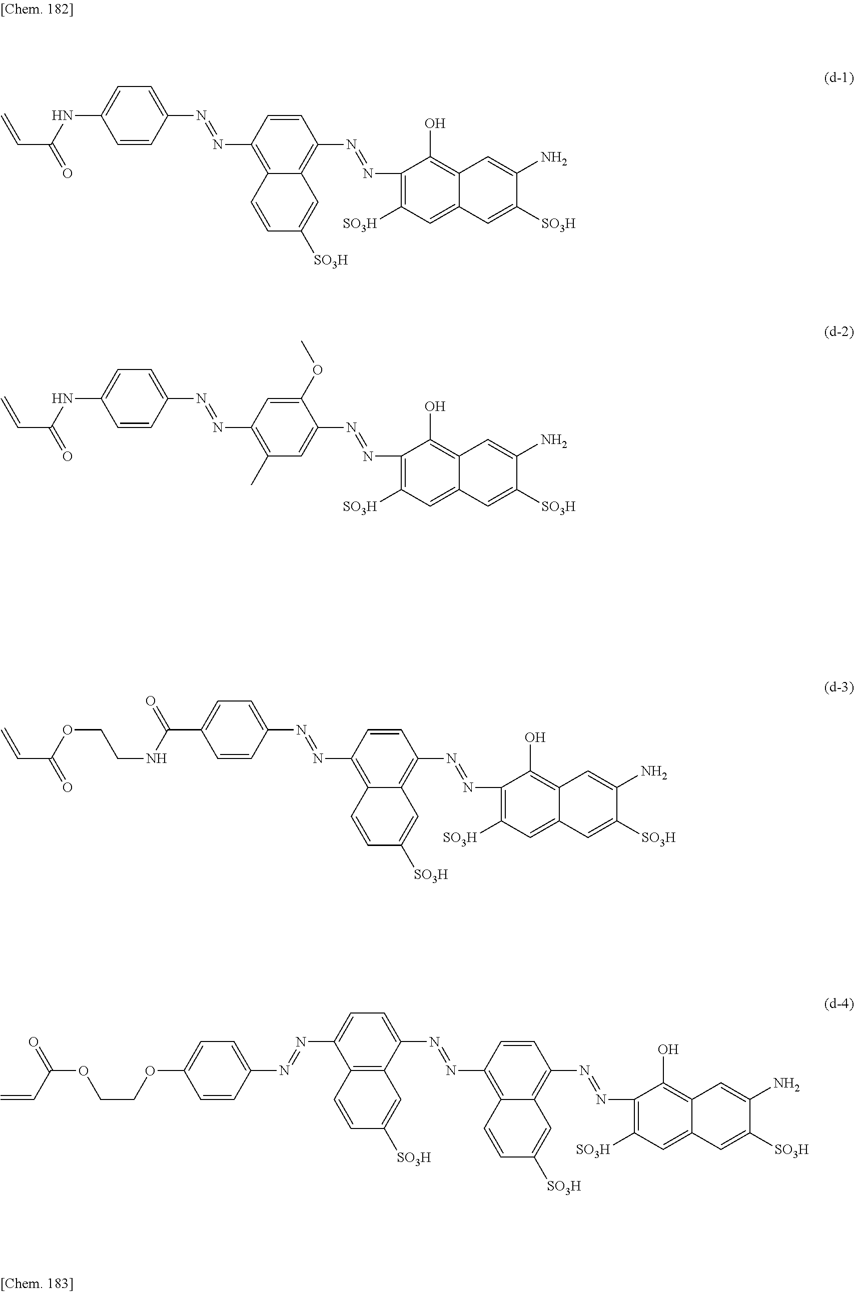 [SMILES: C=CC(=O)Nc1ccc(/N=N/c2ccc(/N=N/c3c(S(=O)(=O)O)cc4cc(S(=O)(=O)O)c(N)cc4c3O)c3cc(S(=O)(=O)O)ccc23)cc1 ; C=CC(=O)Nc1ccc(/N=N/c2cc(OC)c(/N=N/c3c(S(=O)(=O)O)cc4cc(S(=O)(=O)O)c(N)cc4c3O)cc2C)cc1 ; C=CC(=O)OCCNC(=O)c1ccc(/N=N/c2ccc(/N=N/c3c(S(=O)(=O)O)cc4cc(S(=O)(=O)O)c(N)cc4c3O)c3cc(S(=O)(=O)O)ccc23)cc1 ; C=CC(=O)OCCOc1ccc(/N=N/c2ccc(/N=N/c3ccc(/N=N/c4c(S(=O)(=O)O)cc5cc(S(=O)(=O)O)c(N)cc5c4O)c4cc(S(=O)(=O)O)ccc34)c3cc(S(=O)(=O)O)ccc23)cc1]

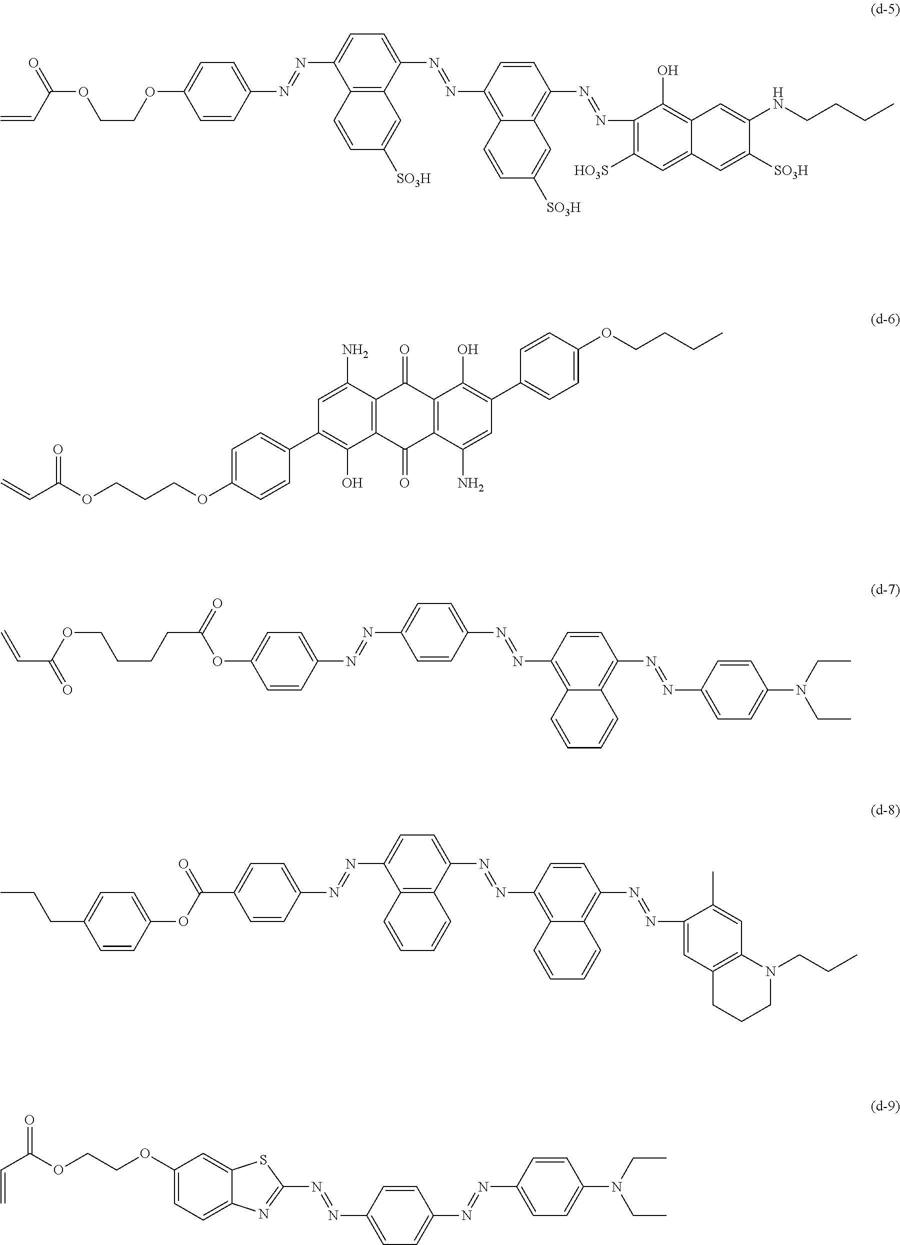

The amount of dyes such as the dichroic dye to be added is preferably 0.001% to 20% by weight and more preferably 0.01% to 10% by weight with respect to the total amount of the total content of the compound represented by General Formula (1) and the total content of the compound containing two or more polymerizable groups, which are used in the polymerizable composition of the present invention.

Filler (o)

The polymerizable composition of the present invention may contain a filler as necessary. The filler to be used is not particularly limited, and the polymerizable liquid crystal composition may contain conventionally known ones within the range that does not degrade the thermal conductivity of the obtained polymer.

Examples of the filler include inorganic fillers such as alumina, titanium white, aluminum hydroxide, talc, clay, mica, barium titanate, zinc oxide, and glass fibers, thermally conductive fillers such as metal powder, for example, silver powder or copper powder, aluminum nitride, boron nitride, silicon nitride, gallium nitride, silicon carbide, magnesia (aluminum oxide), silica, crystalline silica (silicon oxide), fused silica (silicon oxide), graphite, and carbon fibers containing carbon nanofibers, and silver nanoparticles.

Specifically, examples of alumina include DAM-70, DAM-45, DAM-07, DAM-05, DAW-45, DAW-05, DAW-03, ASFP-20 (all manufactured by Denka Company Limited), AL-43-KT, AL-47-H, AL-47-1, AL-160SG-3, AL-43-BE, AS-30, AS-40, AS-50, AS-400, CB-P02, CB-P05 (all manufactured by SHOWA DENKO K.K.), A31, A31B, A32, A33F, A41A, A43A, MM-22, MM-26, MM-P, MM-23B, LS-110F, LS-130, LS-210, LS-242C, LS-250, AHP300 (all manufactured by Nippon Light Metal Company, Ltd.), AA-03, AA-04, AA-05, AA-07, A2, A-5, AA-10, and AA-18 (all manufactured by Sumitomo Chemical Company, Limited); examples of titanium white include G-1, G-10, F-2, F-4, F-6 (all manufactured by SHOWA DENKO K.K.), TAF-520, TAF-500, TAF-1500, TM-1, TA-100C, TA-100CT (all manufactured by FUJI TITANIUM INDUSTRY CO., LTD.), MT-01, MT-10EX, MT-05, MT-100S, MT-100TV, MT-100Z, MT-150EX, MT-100AQ, MT-100WP, MT-100SA, MT-100HD, MT-300HD, MT-500SA, MT-600SA, MT-700HD (all manufactured by TAYCA CORPORATION), TTO-51 (A), TTO-51 (C), TTO-55 (A), TTO-55(B), TTO-55(C), TTO-55(D), TTO-S-1, TTO-S-2, TTO-S-3, TTO-S-4, MPT-136, and TTO-V-3 (all manufactured by ISHIHARA SANGYO KAISHA, LTD.); examples of aluminum hydroxide include B-309, B-309 (manufactured by TOMOE ENGINEERING CO., LTD.), BA173, BA103, B703, B1403, BF013, BE033, BX103, and BX043 (all manufactured by Nippon Light Metal Company, Ltd.); and examples of talc include NANO ACE D-1000, NANO ACE D-800, MICRO ACE SG-95, MICRO ACE P-8, MICRO ACE P-6 (all manufactured by NIPPON TALC Co., Ltd.), FH104, FH105, FL108, FG106, MG115, FH104S, and ML112S (all manufactured by FUJI TALC INDUSTRIAL CO., LTD.); examples of mica include Y-1800, TM-10, A-11, and SJ-005 (all manufactured by YAMAGUCHI MICA CO., LTD.); examples of barium titanate include BT-H9DX, HF-9, HF-37N, HF-90D, HF-120D, HT-F (all manufactured by KCM Corporation), BT-100, HPBT series (manufactured by FUJI TITANIUM INDUSTRY CO., LTD.), BT series (manufactured by Sakai Chemical Industry Co., Ltd.), and BESPA BT (manufactured by Nippon Chemical Industrial Co., Ltd.); examples of zinc oxide include FINEX-30, FINEX-30W-LP2, FINEX-50, FINEX-50S-LF2, XZ-100F (manufactured by Sakai Chemical Industry Co., Ltd.), FZO-50 (manufactured by ISHIHARA SANGYO KISHA, LTD.), MZ-300, MZ-306X, MZY-505S, MZ-506X, and MZ-510HPSX (all manufactured by TAYCA CORPORATION); examples of glass fibers include CS6SK-406, CS13C-897, CS3PC-455, CS3LCP-256 (all manufactured by Nitto Boseki Co., Ltd.), ECS03-615, ECS03-650, EFDE50-01, EFDE50-31 (all manufactured by Central Glass Co., Ltd.), ACS6H-103, and ACS6S-750 (both manufactured by Nippon Electric Glass Company, Limited); examples of silver powder include spherical silver powder AG3 and AG4, flake silver powder FA5 and FA2 (all manufactured by DOWA HIGHTECH CO., LTD.), SPQ03R, SPN05N, SPN08S, Q03R (all manufactured by Mitsui Mining & Smelting Co., Ltd.), AY-6010, AY-6080 (both manufactured by Tanaka Kikinzoku Kogyo K.K.), ASP-100 (manufactured by Aida Chemical Industries Co., Ltd.), and Ag coated powder AG/SP (manufactured by Mitsubishi Materials Electronic Chemicals Co., Ltd.); examples of copper powder include MA-O015K, MA-O02K, MA-O025K (all manufactured by Mitsui Mining & Smelting Co., Ltd.), electrolytic copper powder #52-C and #6 (both manufactured by JX Nippon Mining & Metals Corporation), 10% Ag coated Cu-HWQ (manufactured by FUKUDA METAL FOIL & POWDER CO., LTD.), copper powder Type-A and Type-B (both manufactured by DOWA Electronics Materials Co., Ltd.), and UCP-030 (manufactured by Sumitomo Metal Mining Co., Ltd.); examples of aluminum nitride include H Grade, E Grade, H-T Grade (all manufactured by Tokuyama Corporation), TOYAL TecFiller TFS-A05P, TOYAL TecFiller TFZ-A2P (both manufactured by Toyo Aluminum K.K.), ALN020BF, ALN050BF, ALN020AF, ALN050AF, ALN020SF (all manufactured by TOMOE ENGINEERING CO., LTD.), FAN-f05, and FAN-f30 (both manufactured by FURUKAWA DENSHI CO., LTD.); examples of boron nitride include Denka Boron Nitride SGP, Denka Boron Nitride MGP, Denka Boron Nitride GP, Denka Boron Nitride HGP, Denka Boron Nitride SP-2, Denka Boron Nitride SGPS (all manufactured by Denka Company Limited), UHP-S1, UHP-1K, UHP-2, and UHP-EX (all manufactured by SHOWA DENKO K.K.); examples of silicon nitride include SN-9, SN-9S, SN-9FWS, SN-F1, SN-F2 (all manufactured by Denka Company Limited), CF0027, CF0093, CF0018, and CF0033 (all manufactured by INFINITE POWER & CREATIVE MATERIAL); examples of silicon carbide include GMF-H Type, GMF-H2 Type, GMF-LC Type (all manufactured by Pacific Rundum Co., Ltd.), HSC1200, HSC1000, HSC059, HSC059I, and HSC007 (all manufactured by TOMOE ENGINEERING CO., LTD.); examples of silica include SYLYSIA (manufactured by FUJI SILYSIACHEMICAL LTD.), AEROSIL R972, AEROSIL R104, AEROSIL R202, AEROSIL 805, AEROSIL R812, AEROSIL R7200 (all manufactured by NIPPON AEROSIL CO., LTD.), and REOLOSIL Series (manufactured by TOKUYAMA Corporation); examples of crystalline silica (silicon oxide) include CMC-12, VX-S, and VX-SR (all manufactured by TATUSMORI LTD.); examples of fused silica (silicon oxide) include FB-3SDC, FB-3SDX, SFP-30M, SFP-20M, SFP-30MHE, SFP-130MC, UFP-30 (all manufactured by Denka Company Limited), and EXCELICA series (manufactured by TOKUYAMA Corporation); examples of aluminum oxide include AEROXIDE Alu C and AEROXIDE Alu 65 (all manufactured by NIPPON AEROSIL CO., LTD.); examples of carbon fibers and graphite include Torayca Milled Fiber MLD-30, Torayca Milled Fiber MLD-300 (both manufactured by TORAY INDUSTRIES, INC.), CFMP-30X, CFMP-150X (both manufactured by Nippon Polymer Sangyo Co., Ltd.), XN-100, HC-600 (both manufactured by Nippon Graphite Fiber Corporation), SWeNT SG65, SWeNT SGi, IsoNanoTubes-M, IsoNanoTubes-S, PureTubes, Pyrograf PR-25-XT-PS, and PR-25XT-LHT (all manufactured by Sigma-Aldrich Co., LLC).

The filler can be used alone or in combination of two or more kinds thereof. The amount of the filler to be added is preferably 0.01 to 80% by weight and more preferably 0.1% to 50% by weight with respect to the total amount of the total content of the compound represented by General Formula (1) and the total content of the compound containing two or more polymerizable groups, which are used in the polymerizable composition of the present invention.

Chiral Compound (p)

The polymerizable composition of the present invention may contain a chiral compound for the purpose of obtaining a chiral nematic phase. The chiral compound itself does not need to exhibit liquid crystallinity and may or may not contain a polymerizable group. Further, the orientation of the spiral of the chiral compound can be appropriately selected depending on the applications of the polymer.

The chiral compound containing a polymerizable group is not particularly limited, and conventionally known compounds can be used. Among those, a chiral compound with large helical twisting power (HTP) is preferable. Further, as the polymerizable group, a vinyl group, a vinyloxy group, an allyl group, an allylyxy group, an acryloyloyoxy group, a methacryloyloxy group, a glycidyl group, and an oxetanyl group are preferable and an acryloyloxy group, a glycidyl group, and an oxetanyl group are particularly preferable.

It is necessary that the amount of the chiral compound to be blended is adjusted as appropriate by the spiral inductive force of the compound, and the amount thereof is preferably 0.5% to 80% by mass, more preferably 3% to 50% by mass, and particularly preferably 5% to 30% by mass with respect to the total amount of the liquid crystalline compound containing a polymerizable group and the chiral compound containing a polymerizable group.

Specific examples of the chiral compound include compounds represented by General Formulae (10-1) to (10-4), but the examples are not limited to the compounds represented by the following general formulae.

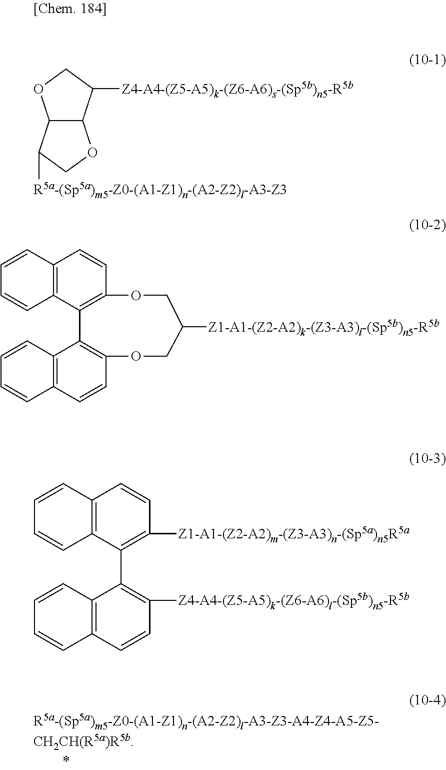

in the formulae, Sp^{5a} and Sp^{5b} each independently represent an alkylene group having 0 to 18 carbon atoms, the alkylene group may be substituted with one or more halogen atoms, a CN group, or an alkyl group having a polymerizable functional group and 1 to 8 carbon atoms, and one —CH₂— or two or more (—CH₂—)'s which are not adjacent to each other in this group may be each independently substituted with —O—, —S—, —NH—, —N(CH₃)—, —CO—, —COO—, —OCO—, —OCOO—, —SCO—, —COS—, or —C≡C— in the form in which oxygen atoms are not directly bonded to each other.

A1, A2, A3, A4, A5, and A6 each independently represent a 1,4-phenylene group, a 1,4-cyclohexylene group, a 1,4-cyclohexenyl group, a tetrahydropyran-2,5-diyl group, a 1,3-dioxane-2,5-diyl group, a tetrahydrothiopyran-2,5-diyl group, a 1,4-bicyclo(2,2,2)octylene group, a decahydronaphthalene-2,6-diyl group, a pyridine-2,5-diyl group, a pyrimidine-2,5-diyl group, a pyrazine-2,5-diyl group, a thiophene-2,5-diyl group, a 1,2,3,4-tetrahydronaphthalene-2,6-diyl group, a 2,6-naphthylene group, a phenanthrene-2,7-diyl group, a 9,10-dihydrophenanthrene-2,7-diyl group, a 1,2,3,4,4a,9,10a-octahydrophenanthrene-2,7-diyl group, a 1,4-naphthylene group, a benzo[1,2-b:4,5-b′]dithiophene-2,6-diyl group, a benzo[1,2-b:4,5-b′]diselenophene-2,6-diyl group, a [1]benzothieno[3,2-b]thiophene-2,7-diyl group, a [1]benzoselenopheno[3,2-b]selenophene-2, 7-diyl group, or a fluorene-2,7-diyl group, n, l, and k each independently represent 0 or 1, n+l+k is greater than or equal to 0 and less than or equal to 3,

m5 represents 0 or 1,

Z0, Z1, Z2, Z3, Z4, Z5, and Z6 each independently represent —COO—, —OCO—, —CH₂CH₂—, —OCH₂—, —CH₂O—, —CH═CH—, —C≡C—, —CH═CHCOO—, —OCOCH═CH—, —CH₂CH₂COO—, —CH₂CH₂OCO—, —COOCH₂CH₂—, —OCOCH₂CH₂—, —CONH—, —NHCO—, an alkyl group which may have halogen atoms with 2 to 10 carbon atoms, or a single bond,

R^{5a} and R^{5b} each independently represent a hydrogen atom, a halogen atom, a cyano group, or an alkyl group having 1 to 18 carbon atoms, the alkyl group may be substituted with one or more halogen atoms or CN, one —CH₂— or two or more (—CH₂—)'s which are not adjacent to each other in this group may be each independently substituted with —O—, —S—, —NH—, —N(CH₃)—, —CO—, —COO—, —OCO—, —OCOO—, —SCO—, —COS—, or —C≡C— in the form in which oxygen atoms are not directly bonded to each other. Alternatively, R^{5a} and R^{5b} represent a group represented by Formula (10-a).

[Chem. 185]

—P^{5a} (10-a)

(In the formula, P^{5a} represents a polymerizable functional group and Sp^{5a} has the same definition as that for Sp¹.)

P^{5a} represents a substituent selected from polymerizable groups represented by Formulae (P-1) to (P-20).

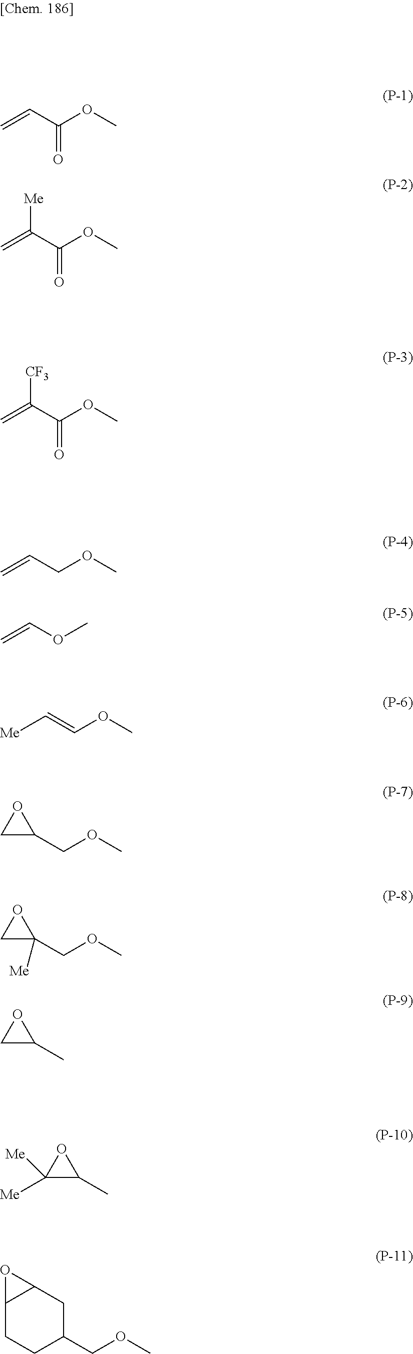

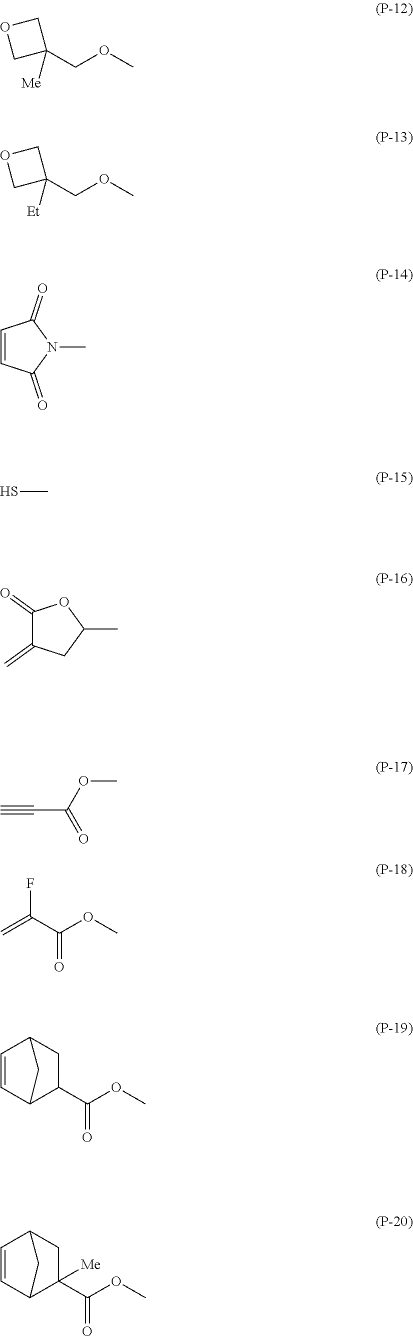

Other specific examples of the chiral compound include compounds represented by General Formulae (10-5) to (10-38).

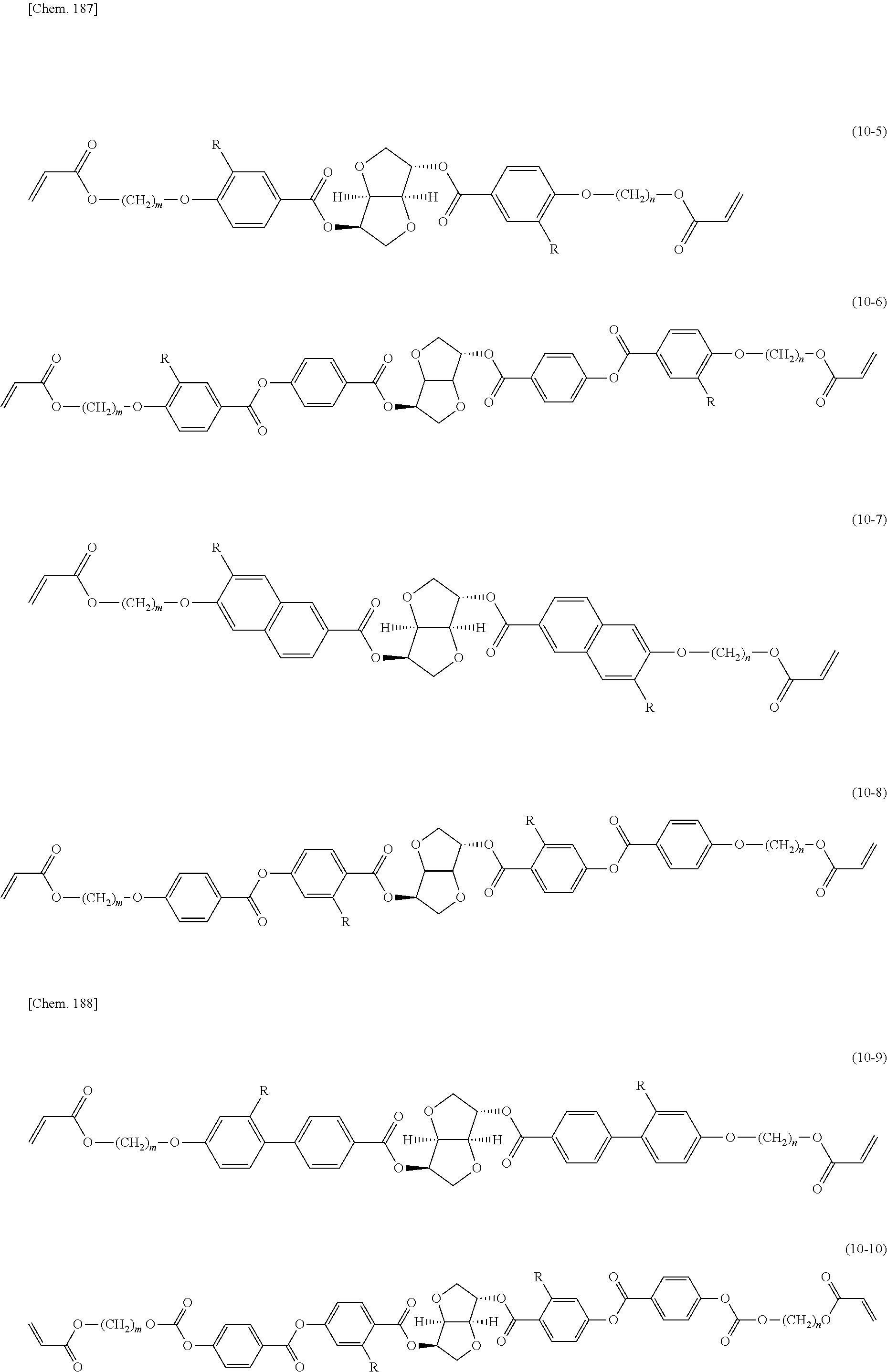

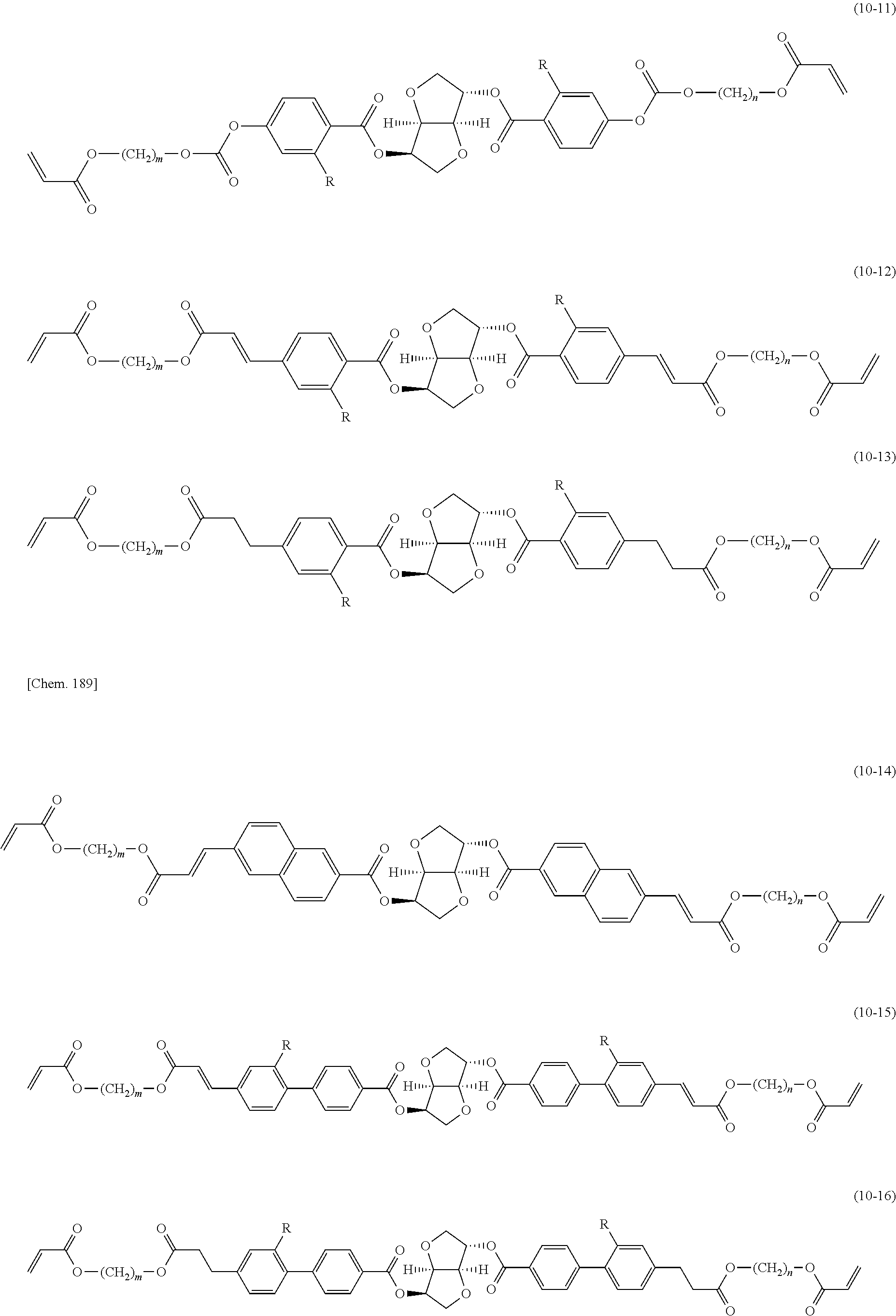

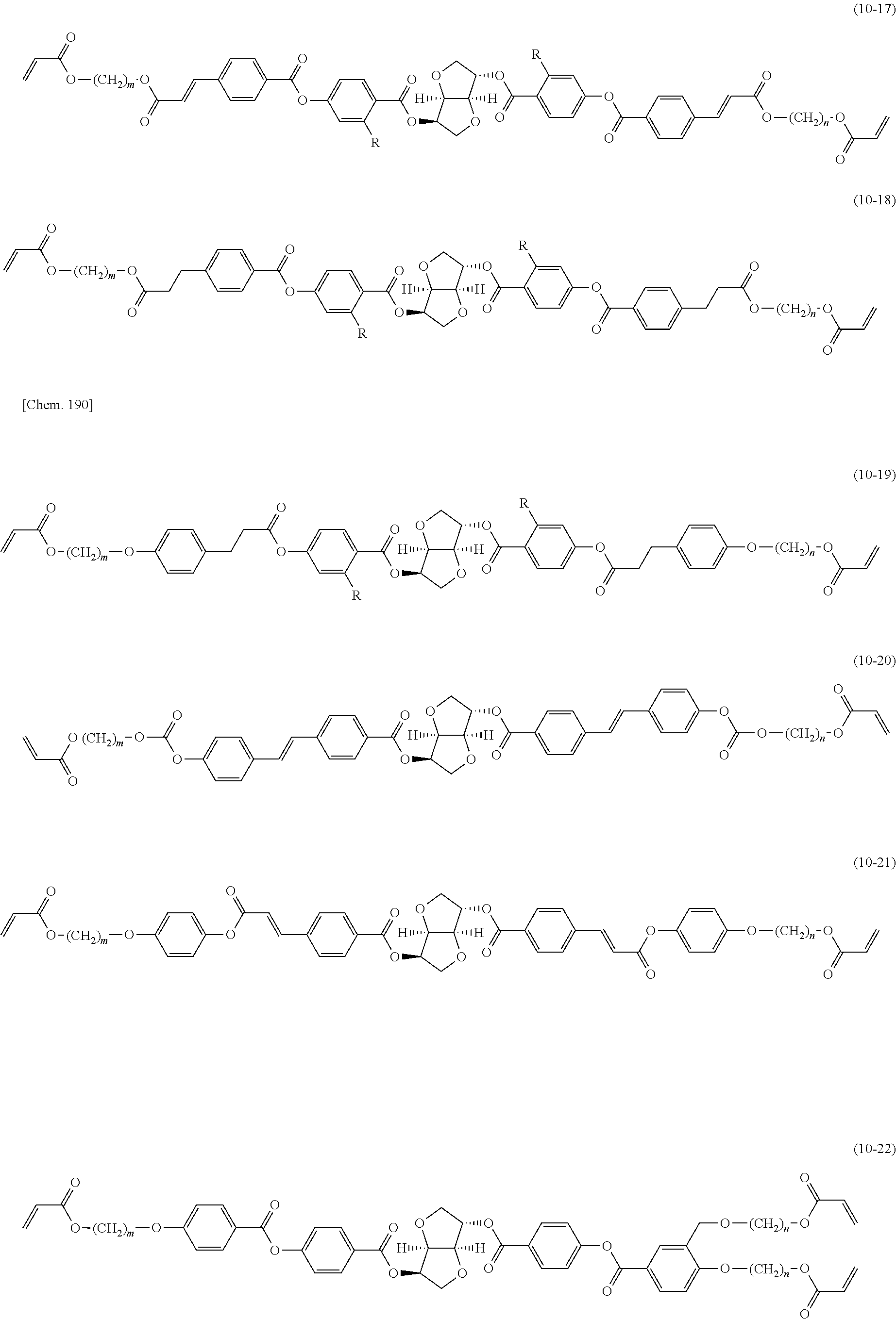

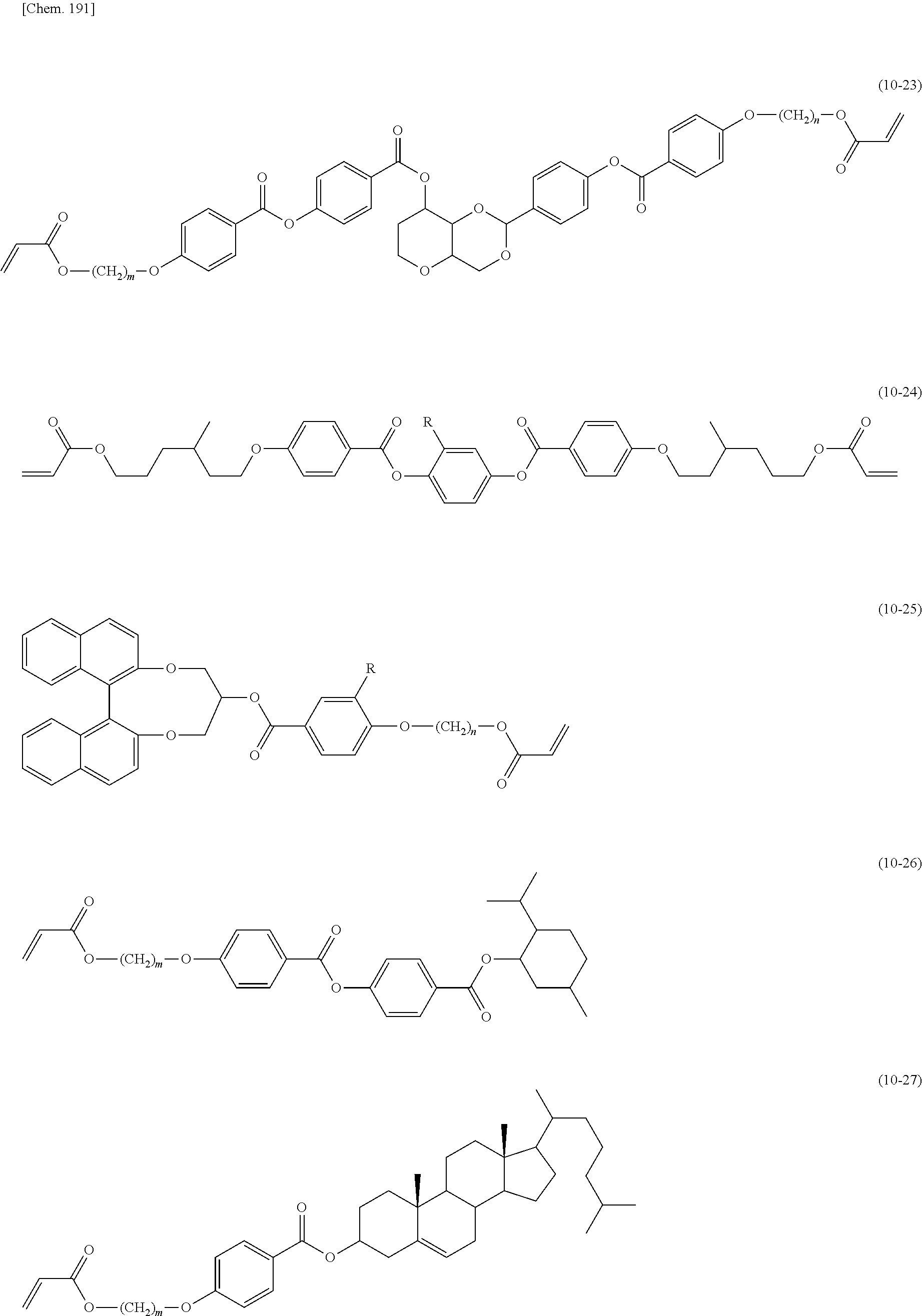

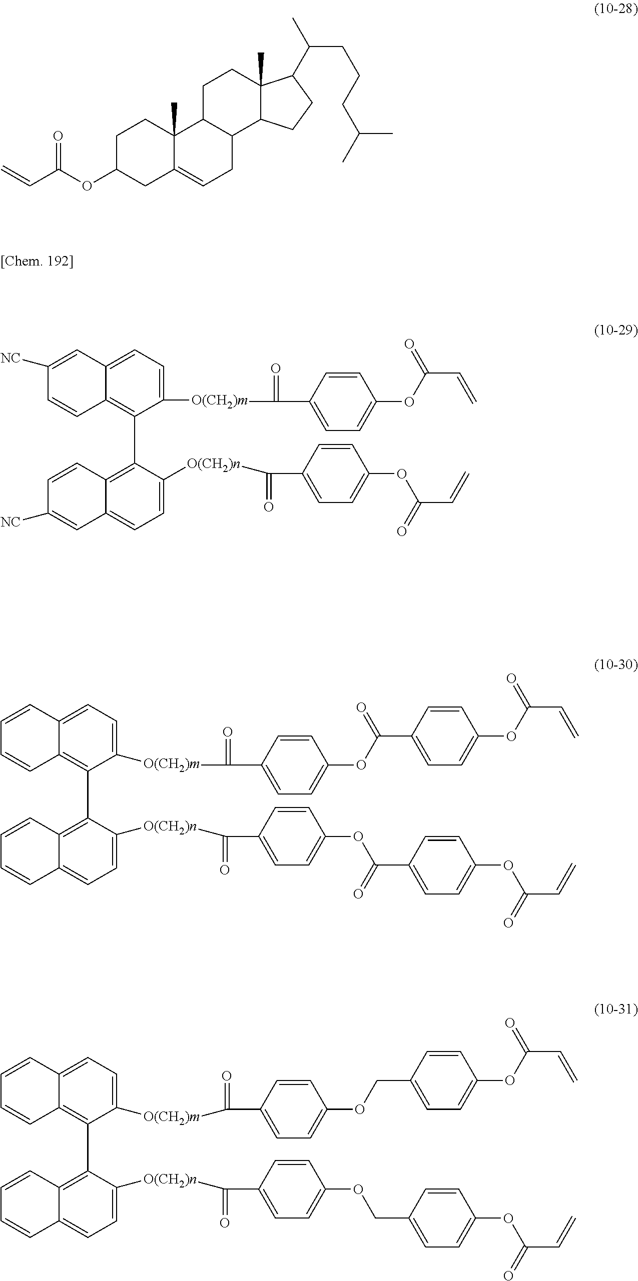

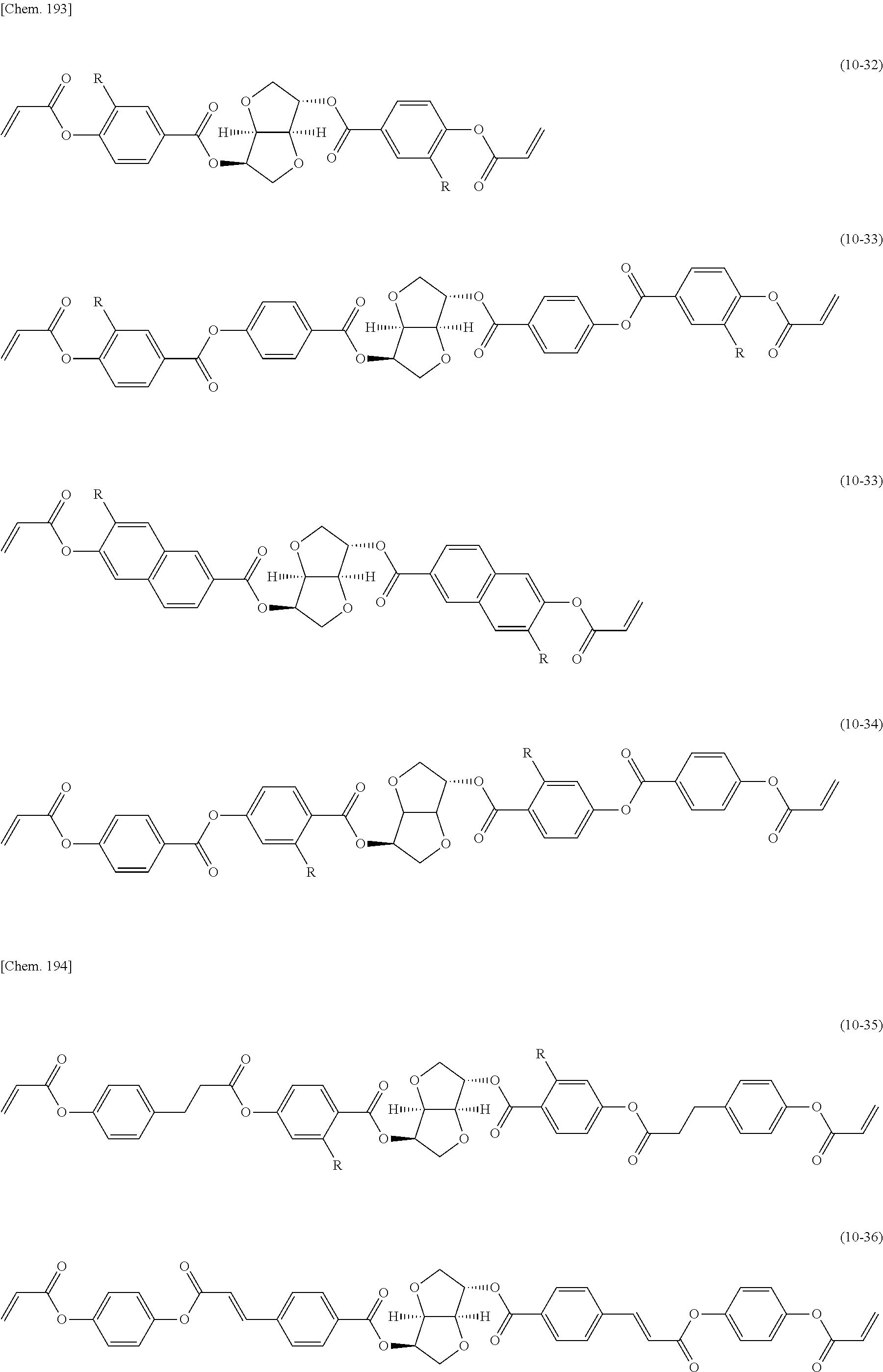

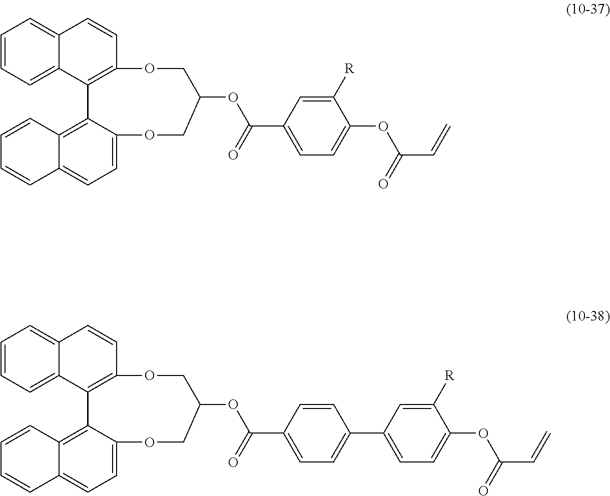

In the formulae, m and n each independently represent an integer of 1 to 10, R represents a hydrogen atom, an alkyl group having 1 to 10 carbon atoms, or a fluorine atom, and in a case where a plurality of R is present, these may be the same as or different from each other.

Specific examples of the chiral compound which does not and cholesterol stearate which contain a cholesteryl group as a chiral group; “CB-15”, “C-15” (manufactured by BDH Corporation), “S-1082” (manufactured by Merch Japan), “1CM-19”, “CM-20”, and “CM” (manufactured by CHISSO CORPORATION) which contain a 2-methylbutyl group as a chiral group; and “S-811” (manufactured by Merch Japan), “CM-21”, and “CM-22” (manufactured by CHISSO CORPORATION) which contain a 1-methylheptyl group as a chiral group.

In a case where the chiral compound is added, the amount of the chiral compound to be added may vary depending on the applications of the polymer of the polymerizable liquid crystal composition of the present invention, but the amount thereof is determined such that a value (d/P) obtained by dividing a thickness (d) of the polymer to be obtained by a spiral pitch (P) in the polymer is to be preferably 0.1 to 100 and more preferably 0.1 to 20.

Non-Liquid Crystalline Compound (q) Containing Polymerizable Group

A compound which is not a liquid crystal compound containing a polymerizable group can be added to the polymerizable composition of the present invention. Such a compound can be used without particular limitation as long as the compound is usually recognized as a polymerizable monomer or a polymerizable oligomer in the technical field. In a case where the compound is added, the content thereof is preferably 15% by mass or less and more preferably 10% by mass or less with respect to the total amount of the total content of the compound represented by General Formula (1) and the total content of the compound containing two or more polymerizable groups, which are used in the polymerizable composition of the present invention.

Specific examples of the compound include mono(meth)acrylate such as methyl (meth)acrylate, ethyl (meth)acrylate, 2-hydroxy ethyl acrylate, propyl (meth)acrylate, 2-hydroxy propyl (meth)acrylate, butyl (meth)acrylate, isobutyl (meth)acrylate, 4-hydroxy butyl (meth)acrylate, 2-hydroxy butyl (meth)acrylate, octyl (meth)acrylate, 2-ethyl hexyl (meth)acrylate, dodecyl (meth)acrylate, stearyl (meth)acrylate, cyclohexyl (meth)acrylate, dicyclopentanyloxyl ethyl (meth)acrylate, isobornyloxyl ethyl (meth)acrylate, isobornyl (meth)acrylate, adamantyl (meth)acrylate, dimethyl adamantly (meth)acrylate, dicyclopentanyl (meth)acrylate, dicyclopentenyl (meth)acrylate, methoxy ethyl (meth)acrylate, ethyl carbitol (meth)acrylate, tetrahydrofurfuryl (meth)acrylate, benzyl (meth)acrylate, phenoxy ethyl (meth)acrylate, 2-phenoxy diethylene glycol (meth)acrylate, 2-hydroxy-3-phenoxy ethyl (meth)acrylate, (2-methyl-2-ethyl-1, 3-dioxolan-4-yl) methyl (meth)acrylate, (3-ethyloxetan-3-yl) methyl (meth)acrylate, o-phenyl phenol ethoxy (meth)acrylate, dimethylamino (meth)acrylate, diethylamino (meth)acrylate, 2,2,3,3,3,-pentafluoropropyl (meth)acrylate, 2,2,3,4,4,4-hexafluorobutyl (meth)acrylate, 2,2,3,3,4,4,4-heptafluorobutyl (meth)acrylate, 2-(perfluorobutyl) ethyl (meth)acrylate, 2-(perfluorohexyl) ethyl (meth)acrylate, 1H,1H,3H-tetrafluoropropyl (meth)acrylate, 1H,1H,5H-octafluoropentyl (meth)acrylate, 1H,1H,7H-dodecafluoroheptyl (meth)acrylate, 1H-1-(trifluoromethyl) trifluoroethyl (meth)acrylate, 1H,1H,3H-hexafluorobutyl (meth)acrylate, 1,2,2,2-tetrafluoro-1-(trifluoromethyl) ethyl (meth)acrylate, 1H,1H-pentadecafluorooctyl (meth)acrylate, 1H,1H,2H,2H-tridecafluorooctyl (meth)acrylate, 2-(meth)acryloyloxy ethyl phthalic acid, 2-(meth)acryloyloxy ethyl hexahydrophthalic acid, glycidyl (meth)acrylate, 2-(meth)acryloyloxy ethyl phosphoric acid, acryloyl morpholine, dimethyl acrylamide, dimethylamino propyl acrylamide, isopropyl acrylamide, diethyl acrylamide, hydroxy ethyl acrylamide, or N-acryloyloxy ethyl hexahydrophthalimide; diacrylate such as 1,4-butanediol di(meth)acrylate, 1,6-hexanediol di(meth)acrylate, 1,9-nonanediol di(meth)acrylate, neopentyldiol di(meth)acrylate, tripropylene glycol di(meth)acrylate, ethylene glycol di(meth)acrylate, diethylene glycol di(meth)acrylate, triethylene glycol di(meth)acrylate, ethylene oxide-modified bisphenol A di(meth)acrylate, tricyclodecane dimethanol di(meth)acrylate, 9,9-bis[4-(2-acryloyloxyethoxy)phenyl]fluorene, glycerin di(meth)acrylate, 2-hydroxy-3-acryloyloxypropyl methacrylate, an acrylic acid adduct of 1,6-hexanediol diglycidyl ether, or an acrylic acid adduct of 1,4-butanediol diglycidyl ether; tri(meth)acrylate such as trimethylolpropane tri(meth)acrylate, ethoxylated isocyanuric acid triacrylate, pentaerythritol tri(meth)acrylate, or ε-caprolactone-modified tris(2-acryloyloxyethyl) isocyanurate; tetra(meth)acrylate such as pentaerythritol tetra(meth)acrylate or ditrimethylolpropane tetra(meth)acrylate; an ethoxy compound such as dipentaerythritol hexa(meth)acrylate, oligomer type (meth)acrylate, various urethane acrylates, various macromonomers, ethylene glycol diglycidyl ether, diethylene glycol diglycidyl ether, propylene glycol diglycidyl ether, neopentyl glycol diglycidyl ether, 1,6-hexanediol diglycidyl ether, glycerin diglycidyl ether, or bisphenol A diglycidyl ether; and maleimide. These may be used alone or in combination of two or more kinds thereof.

Other Liquid Crystalline Compounds (r)

The polymerizable composition of the present invention may contain a polymerizable compound containing one polymerizable group other than the polymerizable liquid crystalline compound represented by General Formula (1). However, the amount of the compound to be added is extremely large, the optical characteristics of the obtained optically anisotropic body may be degraded. Accordingly, in a case where the compound is added, the amount thereof is preferably 30% by mass or less, more preferably 10% by mass or less, and particularly preferably 5% by mass or less with respect to the total amount of the total content of the compound represented by General Formula (1) and the total content of the compound containing two or more polymerizable groups, which are used in the polymerizable composition of the present invention.

Examples of such a liquid crystalline compound include compounds represented by Formulae (11-1) to (11-43).

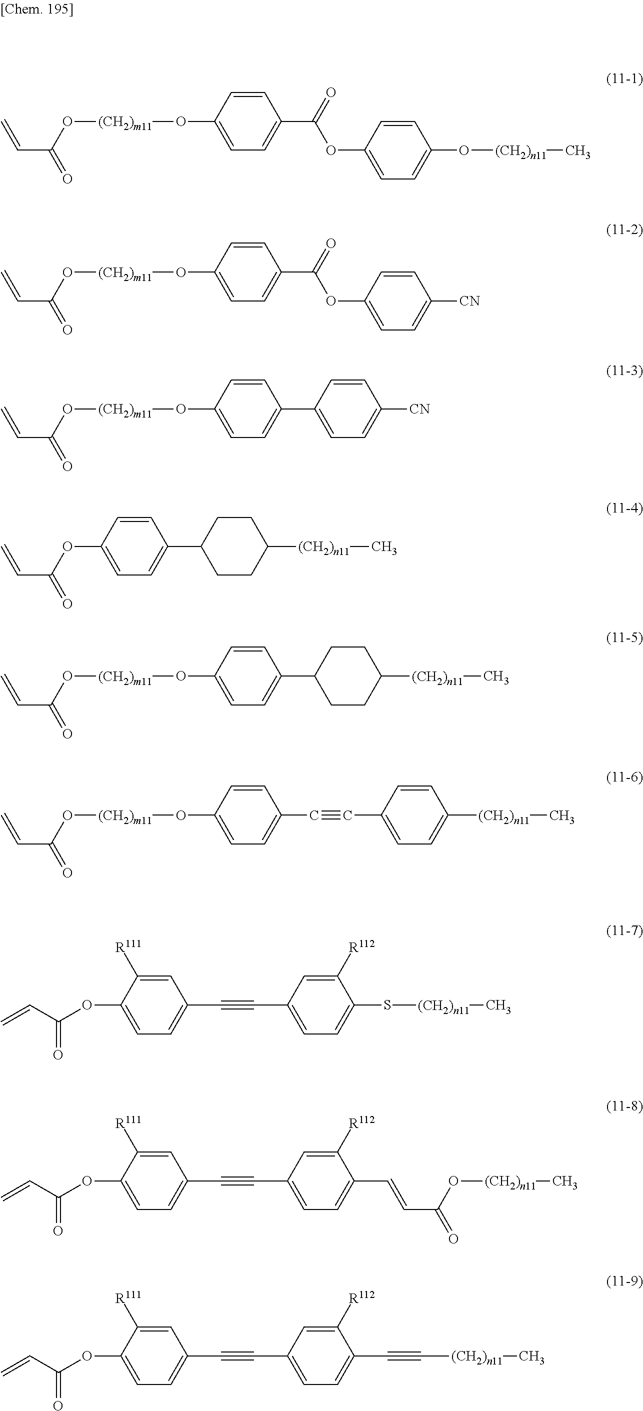

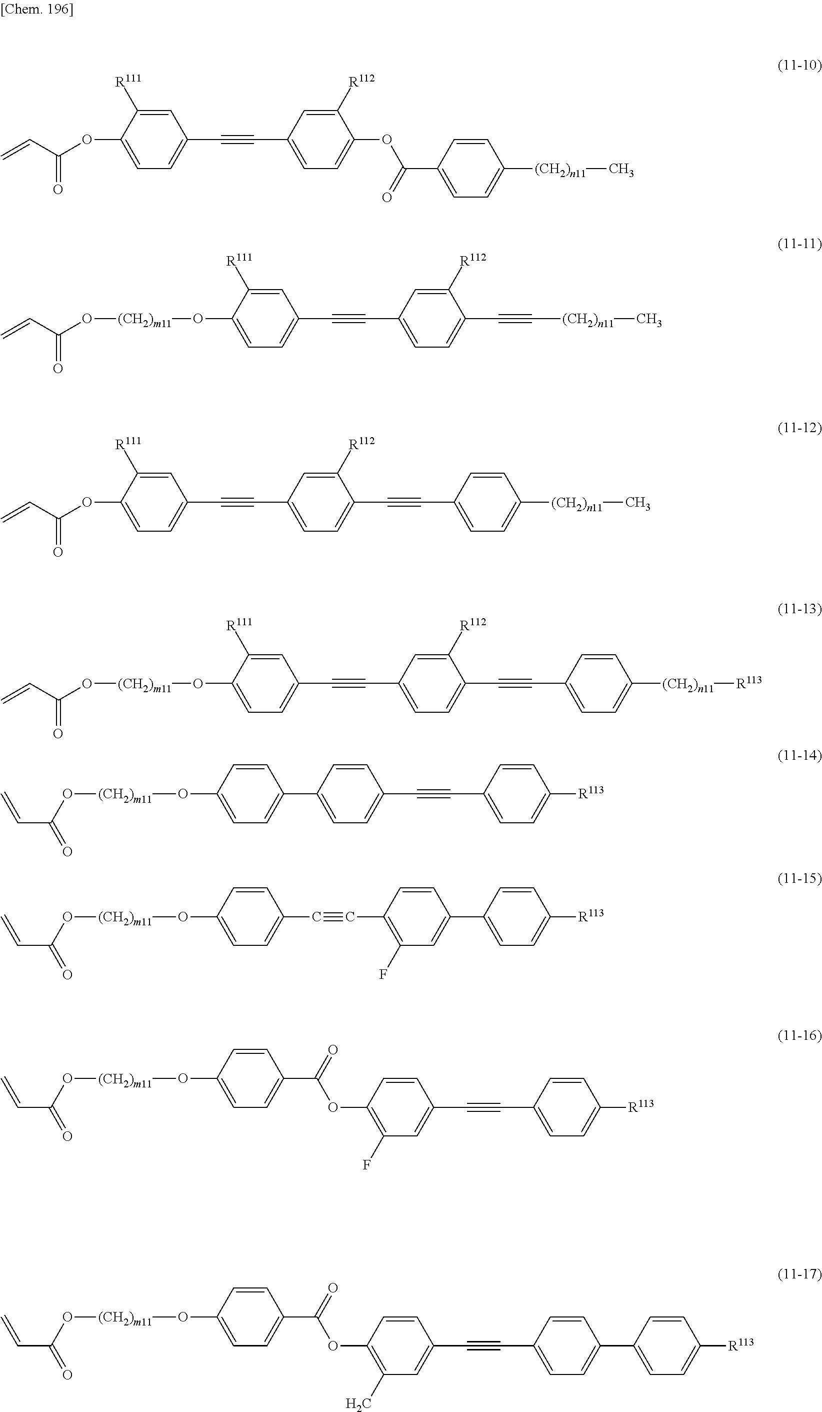

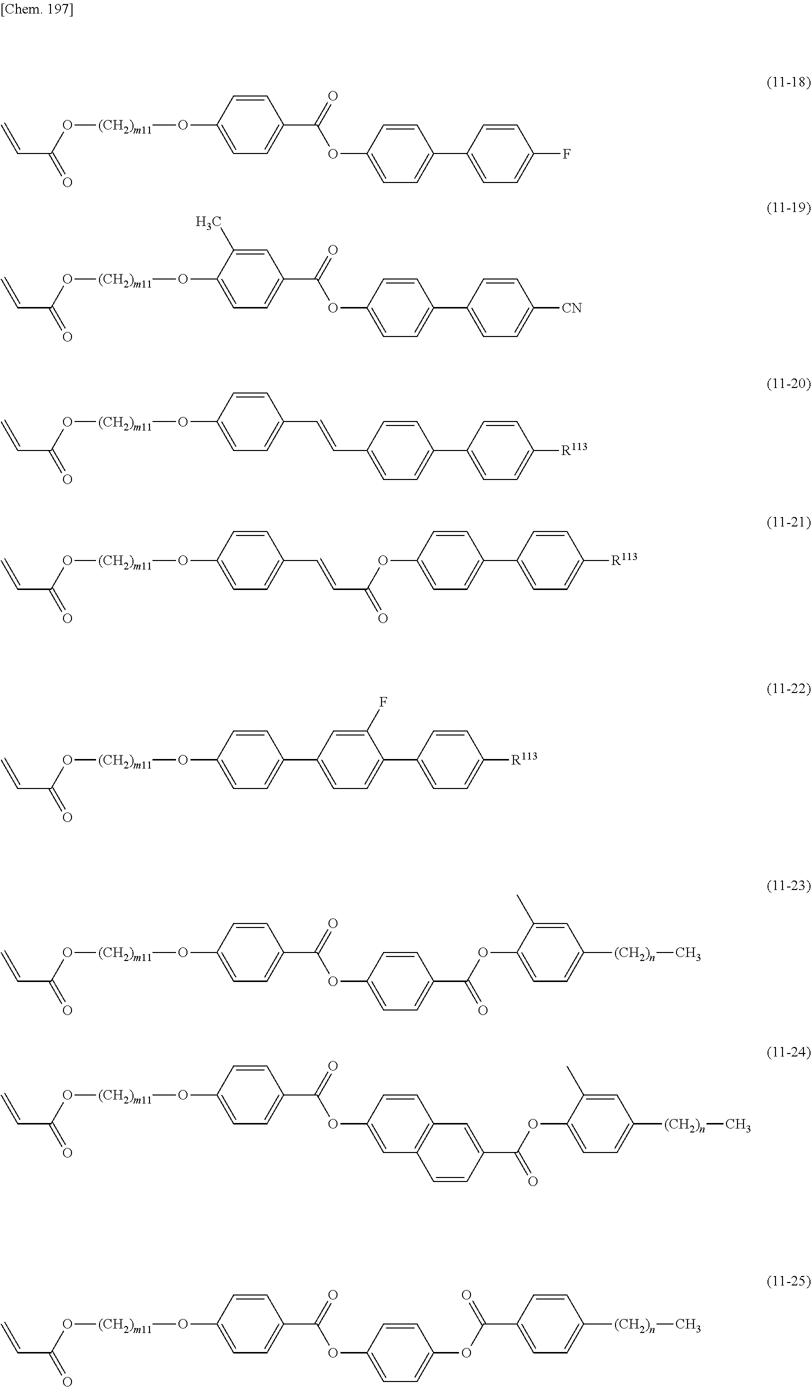

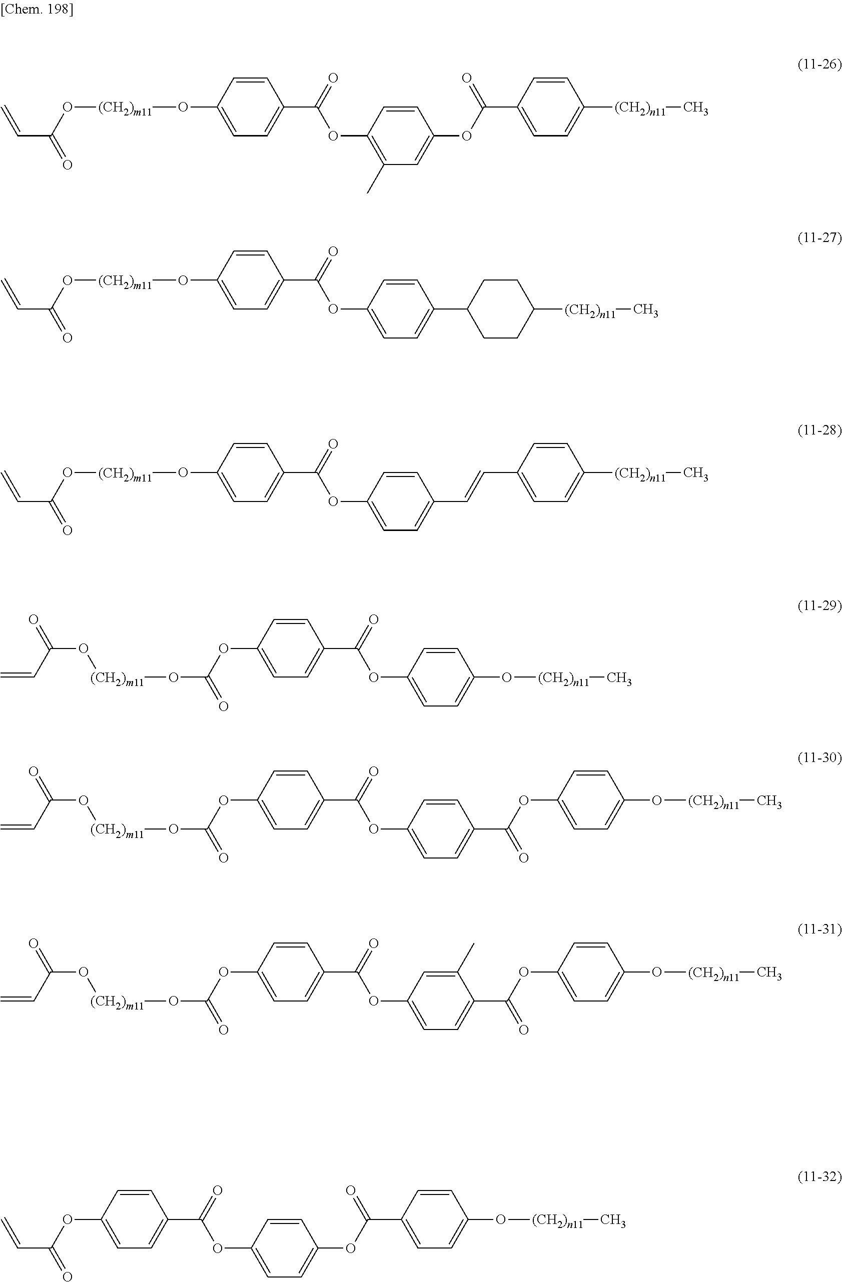

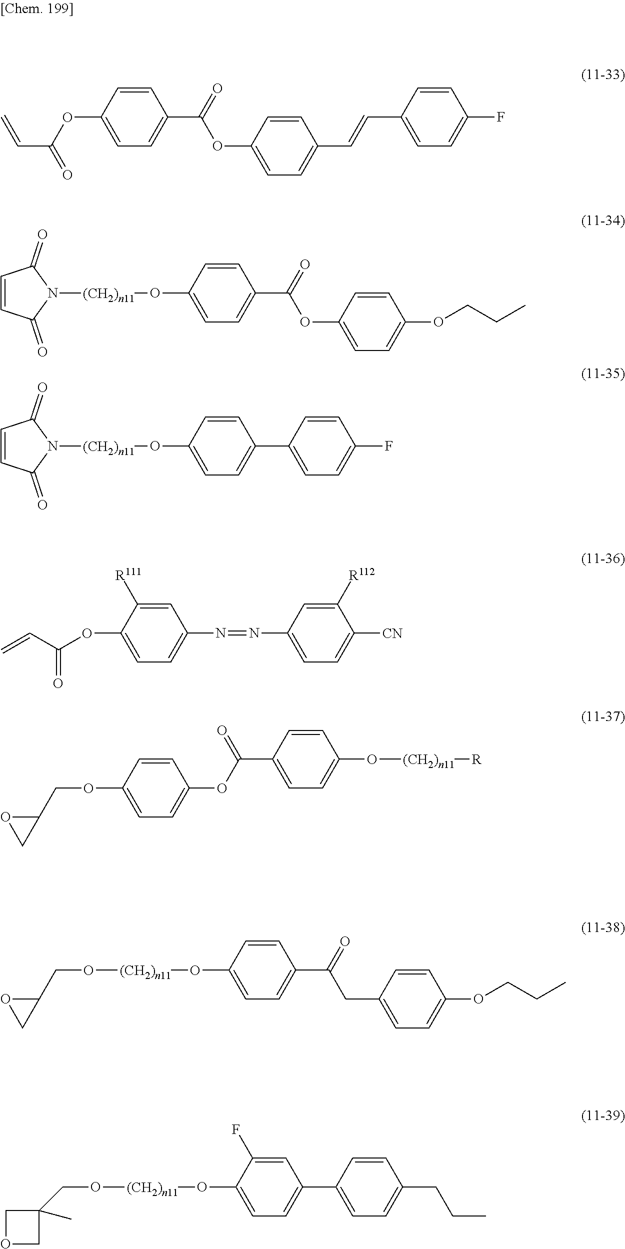

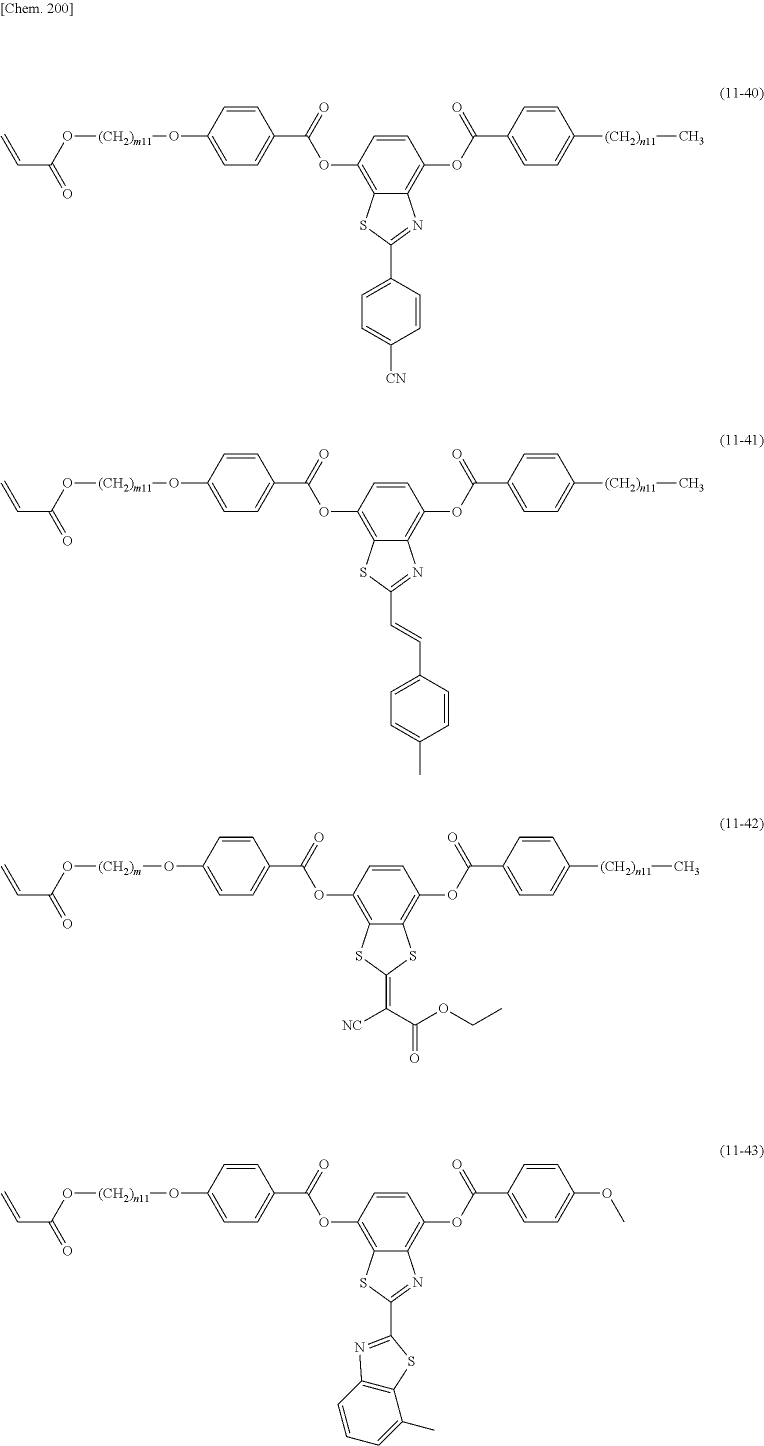

In the formulae, m11 and n11 each independently represent an integer of 1 to 10, R¹¹¹ and R¹¹² each independently represent a hydrogen atom, an alkyl group having 1 to 10 carbon atoms, or a fluorine atom, R¹¹³ represents a hydrogen atom, a fluorine atom, a chlorine atom, a bromine atom, an iodine atom, a pentafluorosulfuranyl group, a cyano group, a nitro group, an isocyano group, a thioisocyano group, or a linear or branched alkyl group having 1 to 20 carbon atoms in which one —CH₂— or two or more (—CH₂—)'s which are not adjacent to each other may be each independently substituted with —O—, —S—, —CO—, —COO—, OCO, —CO—S—, —S—CO—, —O—CO—O—, —CO—NH—, —NH—CO—, or —C≡C—, and one or more of arbitrary hydrogen atoms in the alkyl group may be substituted with a fluorine atom.

Alignment Material (s)

The polymerizable composition of the present invention may contain an alignment material that improves alignment properties in order to improve alignment properties. Conventionally known one can be used as the alignment material as long as the material is soluble in a solvent that dissolves the liquid crystalline compound containing a polymerizable group, which is used for the polymerizable composition of the present invention, and the alignment material can be added within the range that does not significantly degrade the alignment properties through addition. Specifically, the amount of the alignment material is preferably 0.05% to 30% by weight, more preferably 0.5% to 15% by weight, and particularly preferably 1% to 10% by weight with respect to the total amount of the total content of the compound represented by General Formula (1) and the total content of the compound containing two or more polymerizable groups, which are used in the polymerizable composition of the present invention.

Specific examples of the alignment material include photoisomerizing or photodimerizing compounds such as polyimide, polyamide, a benzocyclobutene (BCB) polymer, polyvinyl alcohol, polycarbonate, polystyrene, polyphenylene ether, polyacrylate, polyethylene terephthalate, polyether sulfone, an epoxy resin, an epoxy acrylate resin, an acrylic resin, a coumarin compound, a chalcone compound, a cinnamate compound, a fulgide compound, an anthraquinone compound, an azo compound, and an aryl ethene compound. Further, materials (photo-alignment materials) that are aligned by irradiation with ultraviolet rays or irradiation with visible light are preferable.

Examples of the photo-alignment materials include polyimide having cyclic cycloalkane, wholly aromatic polyarylate, polyvinyl cinnamate described in JP-A-5-232473, polyvinyl ester of paramethoxycinnamic acid, a cinnamate derivative described in JP-A-06-287453 and JP-06-289374, and a maleimide derivative described in JP-A-2002-265541. Specifically, compounds represented by Formulae (12-1) to (12-9) are preferable.

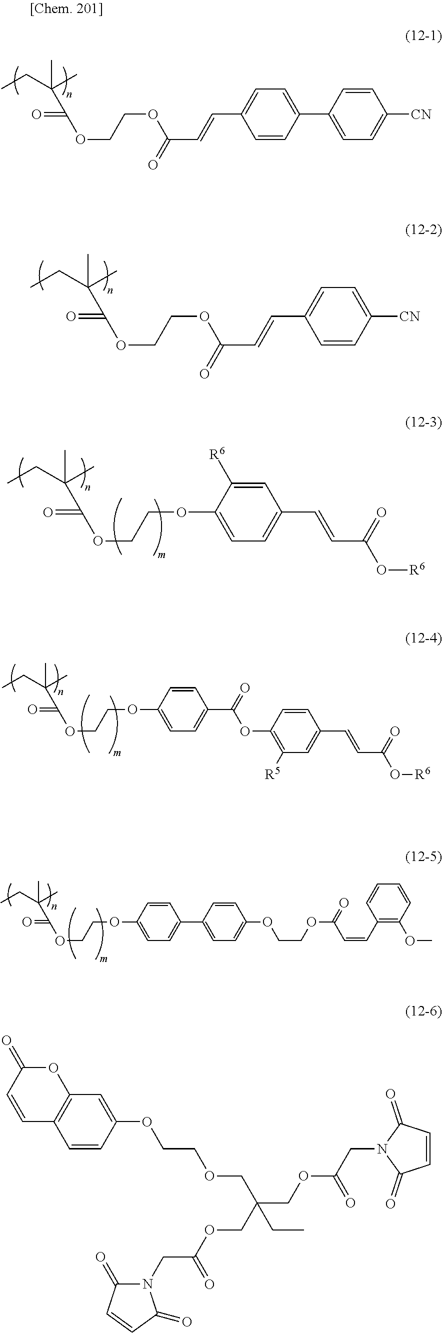

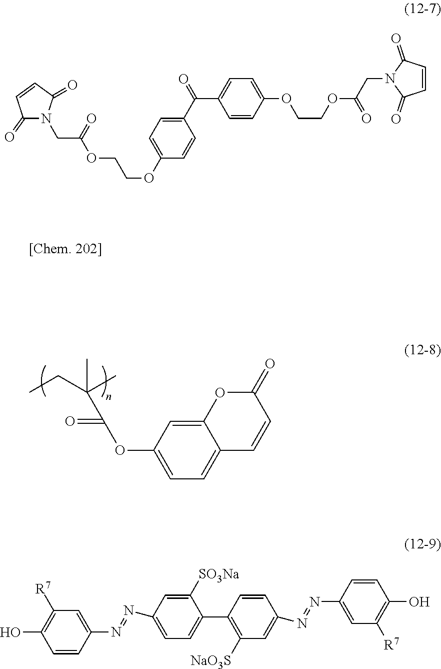

in the formulae, R⁵ represents a hydrogen atom, a halogen atom, an alkyl group having 1 to 3 carbon atoms, an alkoxy group, or a nitro group, R⁶ represents a hydrogen atom or an alkyl group having 1 to 10 carbon atoms, the alkyl group may be linear or branched, one or more of arbitrary hydrogen atoms in the alkyl group may be substituted with a fluorine atom, one —CH₂— or two or more (—CH₂—)'s which are not adjacent to each other in the alkyl group may be each independently substituted with —O—, —S—, —CO—, —COO—, —OCO—, —CO—S—, —S—CO—, —O—CO—O—, —CO—NH—, —NH—CO—, or —C≡C—, and CH₃ at the terminal may be substituted with CF3, CCl3, a cyano group, a nitro group, an isocyano group, a thioisocyano group. n represents an integer of 4 to 100000 and m represents an integer of 1 to 12.

R⁷ represents a polymerizable functional group selected from the group consisting of a hydrogen atom, a halogen atom, a halogenated alkyl group, an allyloxy group, a cyano group, a nitro group, an alkyl group, a hydroxyalkyl group, an alkoxy group, a carboxy group or an alkali metal salt thereof, an alkoxycarbonyl group, a halogenated methoxy group, a hydroxy group, a sulfonyloxy group or an alkali metal salt thereof, an amino group, a carbamoyl group, a sulfamoyl group or a (meth)acryloyl group, a (meth)acryloyloxy group, a (meth)acryloylamino group, a vinyl group, a vinyloxy group, and a maleimide group.

(Polymer)

The polymer of the present invention is obtained by performing polymerization in a state in which the polymerizable composition of the present invention contains an initiator. The polymer of the present invention is used for an optically anisotropic body, a retardation film, a lens, a colorant, a printed matter, and the like.

(Method of Producing Optically Anisotropic Body)

(Optically Anisotropic Body)

The optically anisotropic body of the present invention is obtained by coating a base material or a base material having an alignment function with the polymerizable composition of the present invention, uniformly aligning liquid crystalline compound molecules in the polymerizable composition of the present invention in a state in which a nematic phase or a smectic phase is maintained, and then performing polymerization.

Further, the optically anisotropic body of the present invention is obtained by coating a base material with the polymerizable composition of the present invention which contains a material having a photo-alignment function, such as an azo derivative, a chalcone derivative, a coumarin derivative, a cinnamate derivative, or a cycloalkane derivative, uniformly aligning liquid crystalline compound molecules in the polymerizable composition of the present invention in a state in which a nematic phase or a smectic phase is maintained, and then performing polymerization.

(Base Material)

A base material used for the optically anisotropic body of the present invention is a material that is typically used for a liquid crystal display element, an organic light-emitting display element, other display elements, an optical component, a colorant, a marking, printed matter, or an optical film and is not particularly limited as long as the material has heat resistance so that the material can withstand heating during the drying after the application of the polymerizable composition solution of the present invention. Examples of such a material include organic materials such as a glass base material, a metal base material, a ceramic base material, a plastic base material, and paper. Particularly in a case where the base material is an organic material, examples of the organic material include a cellulose derivative, polyolefin, polyester, polyolefin, polycarbonate, polyacrylate, polyarylate, polyether sulfone, polyimide, polyphenylene sulfide, polyphenylene ether, nylon, and polystyrene. Among these, plastic base materials such as polyester, polystyrene, polyolefin, a cellulose derivative, polyarylate, and polycarbonate are preferable. As the shape of the base material, a base material having a curved surface may be used in addition to a flat plate. These base materials may have an electrode layer, an anti-reflection function, or a reflection function as necessary.

In order to improve the coating properties of the polymerizable composition of the present invention or the adhesiveness between the base material and the polymer, the base material may be subjected to a surface treatment. Examples of the surface treatment include an ozone treatment, a plasma treatment, a corona treatment, and a silane coupling treatment. Further, in order to adjust the transmittance or reflectance of light, an organic thin film, an inorganic oxide thin film, or a metal thin film may be provided on the surface of the base material according to a vapor deposition method. Alternatively, the base material may be a pickup lens, a rod lens, an optical disc, a retardation film, a light diffusion film, or a color filter in order to add the optical added value. Among these, a pickup lens, a retardation film, a light diffusion film, and a color filter that increase the added value are preferable.

(Alignment Treatment)

Further, the base material may be subjected to a typical alignment treatment or provided with an alignment film so that the polymerizable composition is aligned when a polymerizable composition solution of the present invention is applied and dried. Examples of the alignment treatment include a stretching treatment, a rubbing treatment, a polarized ultraviolet visible light irradiation treatment, an ion beam treatment, and an oblique vapor deposition treatment of SiO₂ performed on a base material. In a case of using an alignment film, conventionally known alignment films are used. Examples of such alignment films include compounds such as polyimide, polysiloxane, polyamide, polyvinyl alcohol, polycarbonate, polystyrene, polyphenylene ether, polyarylate, polyethylene terephthalate, polyether sulfone, an epoxy resin, an epoxy acrylate resin, an acrylic resin, an azo compound, a coumarin compound, a chalcone compound, a cinnamate compound, a fulgide compound, an anthraquinone compound, an azo compound, and an aryl ethene compound and polymers or copolymers of these compounds. As a compound that is subjected to an alignment treatment through rubbing, a compound that promotes crystallization of a material by performing a heating process during or after the alignment treatment is preferable. Among the compounds that are subjected to alignment treatments other than the rubbing treatment, compounds for which photo-alignment materials are used are preferable.

In a case where the liquid crystal composition is brought into contact with a substrate having an alignment function, liquid crystal molecules are aligned along a direction in which the substrate has been subjected to the alignment treatment in the vicinity of the substrate. The method of the alignment treatment performed on the substrate greatly affects whether the liquid crystal molecules are aligned horizontally to the substrate or aligned obliquely or vertically to the base material. For example, a polymerizable liquid crystal layer that is aligned substantially horizontal is obtained when an alignment film having an extremely small tilt angle, such as a film used for an in-plane switching (IPS) type liquid crystal display element, is provided on the substrate.

Further, in a case where an alignment film, such as a film used for a TN type liquid crystal display element, is provided on the substrate, a polymerizable liquid crystal layer that is slightly obliquely aligned is obtained. In a case where an alignment film, such as a film used for an STN type liquid crystal display element, is used, a polymerizable liquid crystal layer that is largely obliquely aligned is obtained.

(Coating)

As a coating method used to obtain the optically anisotropic body of the present invention, conventionally known methods such as an applicator method, a bar coating method, a spin coating method, a roll coating method, a direct gravure coating method, a reverse gravure coating method, a flexo coating method, an inkjet method, a die coating method, a cap coating method, a dip coating method, a slit coating method, and a spray coating method can be used. The polymerizable composition is dried after the coating.

After the coating, it is preferable that the liquid crystal molecules of the polymerizable composition of the present invention are uniformly aligned in a state in which a smectic phase or a nematic phase is maintained. As an example for this, a heat treatment method may be exemplified. Specifically, the substrate is coated with the polymerizable composition of the present invention, the polymerizable composition is heated at an N (nematic phase)-I (isotropic liquid phase) transition temperature (hereinafter, abbreviated as the N-I transition temperature) of the liquid crystal composition or higher so that the liquid crystal composition enters an isotropic phase liquid state. Thereafter, the resultant is gradually cooled to exhibit a nematic phase. At this time, it is desirable that a liquid crystal phase domain is allowed to be sufficiently grown to obtain a monodomain by temporarily maintaining the temperature at which a liquid crystal phase appears. Alternatively, after the substrate is coated with the polymerizable composition of the present invention, the polymerizable composition may be subjected to a heat treatment of maintaining the temperature range, in which a nematic phase of the polymerizable composition of the present invention appears, for a certain period of time.

When the heating temperature is extremely high, there is a concern that the polymerizable liquid crystal compound may undergo an undesirable polymerizable reaction and deteriorate. Further, when the polymerizable composition is extremely cooled, phase separation occurs in the polymerizable composition, crystals are precipitated, and a high-order liquid crystal phase such as a smectic phase appears. Therefore, the alignment treatment may not be performed.

A homogeneous optically anisotropic body with few alignment defects can be prepared by performing such a heat treatment, compared to a coating method of only performing coating.

After the homogeneous alignment treatment is performed as described above, when the liquid crystal phase is cooled at the lowest temperature at which phase separation does not occur, in other words, the liquid crystal phase is cooled to enter a supercooled state, and polymerization is carried out in a state in which the liquid crystal phase is aligned at the temperature, an optically anisotropic body having a higher alignment order and excellent transparency can be obtained.

(Polymerization Process)

The polymerization treatment may be performed on the dried polymerizable composition typically by irradiation with light such as visible ultraviolet rays or by heating in a uniformly aligned state. In a case where the polymerization is performed by irradiation with light, it is preferable that visible ultraviolet light having a wavelength of 420 nm or less is applied and most preferable that ultraviolet light having a wavelength of 250 to 370 nm is applied. Here, in a case where decomposition or the like of the polymerizable composition is caused by visible ultraviolet light having a wavelength of 420 nm or less, it is preferable that a polymerization treatment is performed using visible ultraviolet light having a wavelength of 420 nm or greater in some cases.

(Polymerization Method)

As a method of polymerizing the polymerizable composition of the present invention, a method of applying active energy rays or a thermal polymerization method is exemplified. From the viewpoint that heating is not necessary and the reaction proceeds at room temperature, a method of applying active energy rays is preferable. Among the examples thereof, from the viewpoint of a simple operation, a method of applying light such as ultraviolet rays or the like is preferable. The application temperature is set to a temperature at which the liquid crystal phase of the polymerizable composition of the present invention can be maintained, and it is preferable that the temperature thereof is set to 30° C. or lower as much as possible in order to avoid induction of thermal polymerization of the polymerizable composition. Further, the polymerizable liquid crystal composition typically exhibits the liquid crystal phase in the process of raising the temperature, within the N-I transition temperature range from a C (solid phase)-N (nematic) transition temperature (hereinafter, abbreviated as the C-N transition temperature). Further, the polymerizable liquid crystal composition occasionally maintains the liquid crystal state thereof without being solidified at the C-N transition temperature or lower in the process of lowering the temperature, in order to obtain a thermodynamically non-equilibrium state. This state is referred to as a supercooled state. In the present invention, it can be said that the liquid crystal composition in the supercooled state is also in the state of maintaining the liquid crystal phase. Specifically, it is preferable to irradiate with ultraviolet light having a wavelength of 390 nm or less and most preferable to irradiate with light having a wavelength of 250 to 370 nm. In a case where decomposition or the like of the polymerizable composition is caused by the irradiation with ultraviolet light having a wavelength of 390 nm or less, it is preferable that the polymerization treatment is performed using ultraviolet light having a wavelength of 390 nm or greater in some cases. As this light, it is preferable to use diffusion light and non-polarized light. The intensity of irradiation with ultraviolet rays is preferably 0.05 kW/m² to 10 kW/m² and particularly preferably 0.2 kW/m² to 2 kW/m². In a case where the intensity of ultraviolet rays is less than 0.05 kW/m, it takes a long time to complete the polymerization. In addition, in a case where the intensity of ultraviolet rays is greater than 2 kW/m², there is a possibility that the liquid crystal molecules in the polymerizable composition tend to be photodecomposed, a large amount of polymerization heat is generated so that the temperature during the polymerization increases, the order parameter of the polymerizable liquid crystal changes, and the retardation of the film after the polymerization deviates.

The amount of ultraviolet rays to be applied is preferably 10 mJ/cm² to 20 J/cm², more preferably 50 mJ/cm² to 10 J/cm², and particularly preferably 100 mJ/cm² to 5 J/cm².

After only a specific portion is polymerized by irradiation with ultraviolet rays using a mask, when the alignment state of the unpolymerized portion is changed by applying an electric field or a magnetic field or raising the temperature and then the unpolymerized portion is polymerized, an optically anisotropic body having a plurality of regions with different alignment directions can be obtained.

Further, an optically anisotropic body having a plurality of regions with different alignment directions can also be obtained by means of restricting the alignment by applying an electric field or a magnetic field to the polymerizable liquid crystal composition in an unpolymerized state in advance and then polymerizing the unpolymerized portion by irradiation with light from the upper portion of a mask while the state is maintained when only a specific portion is polymerized by irradiation with ultraviolet rays using a mask.

An optically anisotropic body obtained by polymerizing the polymerizable composition of the present invention can be used alone by being peeled off from the substrate or can be used as it is without being peeled off from the substrate. Particularly, since other members are unlikely to be contaminated by the optically anisotropic body, it is useful that the optically anisotropic body is used as a substrate to be laminated or used by being bonded to another substrate.

The optically anisotropic body can be subjected to a heating and aging treatment in order to stabilize the solvent resistance and heat resistance of the obtained optically anisotropic body. In this case, it is preferable that the optically anisotropic body is heated at the glass transition temperature or higher of the polymerizable liquid crystal film. Typically, the temperature is preferably 50° C. to 300° C., more preferably 80′C to 240° C., and still more preferably 100° C. to 220° C.

(Retardation Film)

The retardation film of the present invention contains the optically anisotropic body and the liquid crystalline compound may form a uniform and continuous alignment state with respect to the base material so that the in-plane, the outer plane, both of the in-plane and the outer plane with respect to the base material or the in-plane has biaxiality. Further, an adhesive or an adhesive layer, a pressure sensitive adhesive or a pressure sensitive adhesive layer, a protective film, a polarizing film, or the like may be laminated on the retardation film.

As such a retardation film, for example, the alignment mode of a positive A plate formed by aligning a rod-like liquid crystalline compound substantially horizontally with respect to the base material, a negative A plate formed by aligning a discotic liquid crystalline compound vertically uniaxially with respect to the base material, a positive C plate formed by aligning a rod-like liquid crystalline compound substantially vertically with respect to the base material, a negative C plate formed by aligning a rod-like liquid crystalline compound cholesterically with respect to the base material or aligning a discotic liquid crystalline compound horizontally uniaxially with respect to the base material, a biaxial plate, a positive O plate formed by hybrid aligning a rod-like liquid crystalline compound with respect to the base material, or a negative O plate formed by hybrid aligning a discotic liquid crystalline compound with respect to the base material can be applied. In a case where the alignment mode thereof is used for an optical compensation film of a liquid crystal display element, the alignment mode is not particularly limited as long as the mode improves the viewing angle dependence and various alignment modes can be applied.

For example, the alignment mode of a positive A plate, a negative A plate, a positive C plate, a negative C plate, a biaxial plate, a positive O plate, or a negative O plate can be applied. Among these, in a case where a liquid crystal medium of a liquid crystal display element is in a vertical alignment mode (VA), it is preferable to use the alignment mode of a positive A plate or a negative C plate. Further, it is more preferable that a positive A plate or a negative C plate is laminated.

In a liquid crystal cell for which a retardation film is used, a positive A plate is preferably used as a first retardation layer in order to widen the viewing angle by compensating the viewing angle dependence of polarization axis orthogonality. Here, the positive A plate is a plate in which when the refractive index of the film in an in-plane slow axis direction is set to nx, the refractive index of the film in an in-plane fast axis direction is set to ny, and the refractive index of the film in a thickness direction is set to nz, nx, ny, and nz are in a relationship of “nx>ny=nz”. As the positive A plate, a plate in which the in-plane phase difference value at a wavelength of 550 nm is 30 nm to 500 nm is preferable. Further, the thickness direction phase difference value is not particularly limited. An Nz coefficient is preferably 0.5 to 1.5.

Further, in order to cancel the birefringence of the liquid crystal molecules, a so-called negative C plate having negative refractive index anisotropy is preferably used as a second retardation layer. Further, a negative C plate may be laminated on a positive A plate.

Here, the negative C plate is a retardation layer in which when the refractive index of the retardation layer in the in-plane slow axis direction is set to nx, the refractive index of the retardation layer in the in-plane fast axis direction is set to ny, and the refractive index of the retardation layer in the thickness direction is set to nz, nx, ny, and nz are in a relationship of “nx=ny>nz”. The thickness direction phase difference value of the negative C plate is preferably 20 to 400 nm.

Further, the refractive index anisotropy in the thickness direction is represented by a thickness direction phase difference value Rth defined by Equation (2). The thickness direction phase difference value Rth can be calculated by acquiring nx, ny, and nz through numerical calculation from Equation (1) and Equations (4) to (7) using an in-plane phase difference value R₀, a phase difference value R₅₀ measured by tilting the slow axis as a tilt axis by 50°, a thickness d of the film, and an average refractive index n₀ of the film and then substituting these values in Equation (2) Further, the Nz coefficient can be calculated from Equation (3). Hereinafter, the same applies to other descriptions in the present specification.

R₀=(nx−ny)×d (1)

Rth=[(nx+ny)/2−nz]×d (2)

Nz coefficient=(nx−nz)/(nx−ny) (3)

R₅₀=(nx−ny′)×d/cos(ϕ) (4)

(nx+ny+nz)/3=n0 (5)

Here,

ϕ=sin⁻¹[sin(50°)/n₀] (6)

ny′=ny×nz/[ny×sin²(ϕ)+nz²×cos²(ϕ)]^{1/2} (7)

In commercially available retardation measuring devices, many measuring devices are designed such that the numerical calculation shown here is automatically performed in the devices and the in-plane phase difference value R₀, the thickness direction phase difference value Rth, and the like are automatically displayed. Examples of such measuring devices include RETS-100 (manufactured by Otsuka Chemical Co., Ltd.).

Further, in a case where a liquid crystal medium of the liquid crystal display element is in an in-plane switching (IFS) mode or a fringe field switching (FFS) mode, it is preferable to use a positive A plate, a positive C plate, and/or a biaxial plate. Further, it is more preferable to use a positive A plate and/or a positive C plate and particularly preferable to laminate a positive A plate and a positive C plate.

In a liquid crystal cell, a positive A plate is preferably used as a first retardation layer. Here, the positive A plate is a plate in which when the refractive index of the film in the in-plane slow axis direction is set to nx, the refractive index of the film in the in-plane fast axis direction is set to ny, and the refractive index of the film in the thickness direction is set to nz, nx, ny, and nz are in a relationship of “nx>ny=nz”. As the positive A plate, a plate in which the in-plane phase difference value at a wavelength of 550 nm is 10 nm to 300 nm is preferable. Further, the thickness direction phase difference value is not particularly limited. An Nz coefficient is preferably 0.9 to 1.1.

Further, a so-called positive C plate having positive refractive index anisotropy is preferably used as the second retardation layer. Further, a positive C plate may be laminated on a positive A plate.

Here, the positive C plate is a retardation layer in which when the refractive index of the retardation layer in the in-plane direction is set to nx, the refractive index of the retardation layer in the in-plane direction is set to ny, and the refractive index of the retardation layer in the thickness direction is set to nz, nx, ny, and nz are in a relationship of “nx=ny<nz”. The thickness direction phase difference value of the positive C plate is preferably 10 to 300 nm.

Further, the refractive index anisotropy in the thickness direction is represented by the thickness direction phase difference value Rth defined by Equation (2). The thickness direction phase difference value Rth can be calculated by acquiring nx, ny, and nz through numerical calculation from Equation (1) and Equations (4) to (7) using the in-plane phase difference value R₀, the phase difference value R₅₀ measured by tilting the slow axis as a tilt axis by 50°, the thickness d of the film, and the average refractive index n₀ of the film and then substituting these values in Equation (2). Further, the Nz coefficient can be calculated from Equation (3). Hereinafter, the same applies to other descriptions in the present specification.

R₀=(nx−ny)×d (1)

Rth=[(nx+ny)/2−nz]×d (2)

Nz coefficient=(nx−nz)/(nx−ny) (3)

R₅₀=(nx−ny′)×d/cos(ϕ) (4)

(nx+ny+nz)/3=n0 (5)

Here,

ϕ=sin⁻¹[sin(50°)/n₀] (6)

ny′=ny×nz/[ny×sin²(ϕ)+nz²×cos²(ϕ)]^{1/2} (7)

Further, the retardation film of the present invention can be used as a circularly polarizing plate by being combined with a linearly polarizing plate. In a case where the retardation film is used as a circularly polarizing plate, the retardation film of the present invention is a positive A plate formed by aligning the polymerizable liquid crystalline compound substantially horizontally with respect to the base material and the angle between the polarizing axis of the linearly polarizing plate and the slow axis of the retardation film is substantially preferably 45°.

The retardation film of the present invention can be used as a wavelength plate. In a case where the retardation film is used as a wavelength plate, the retardation film of the present invention is a positive A plate formed by aligning the polymerizable liquid crystalline compound substantially horizontally with respect to the base material and it is preferable that the retardation film is used as a ½ wavelength plate or a ¼ wavelength plate.

The retardation film of the present invention can be used as a polarizing reflective film or an infrared reflective film. In this case, the retardation film of the present invention is formed by cholesterically aligning a rod-like liquid crystalline compound substantially horizontally with respect to the base material. In a case where the retardation film is used as a polarizing reflective film, it is preferable that the pitch is in a visible light region. In a case where the retardation film is used as an infrared reflective film, it is preferable that the pitch is in an infrared region.

(Lens)

The polymerizable composition of the present invention can be used as a lens of the present invention by coating a base material or a base material having an alignment function with the polymerizable composition of the present invention or pouring the polymerizable composition in a lens-shaped mold, uniformly aligning liquid crystal molecules in the polymerizable composition of the present invention in a state in which a nematic phase or a smectic phase is maintained, and then performing polymerization. Examples of the shape of the lens include a simple cell shape, a prism shape, and a lenticular shape.

(Liquid Crystal Display Element)

The polymerizable composition of the present invention can be used as a liquid crystal display element of the present invention by coating a base material or a base material having an alignment function with the polymerizable composition of the present invention, uniformly aligning liquid crystal molecules in the polymerizable composition of the present invention in a state in which a nematic phase or a smectic phase is maintained, and then performing polymerization. As the form of the display element to be used, an optical compensation film, a patterned retardation film of a liquid crystal stereoscopic display element, a retardation correction layer of a color filter, an overcoat layer, and an alignment film for a liquid crystal medium may be exemplified. The liquid crystal display element is formed by interposing at least a liquid crystal medium layer, a TFT drive circuit, a black matrix layer, a color filter layer, a spacer, or an electrode circuit corresponding to the liquid crystal medium layer between at least two base materials. An optical compensation layer, a polarizing plate layer, and a touch panel layer are typically aligned outside the two base materials, but an optical compensation layer, an overcoat layer, a polarizing plate layer, or an electrode layer for a touch panel may be interposed between two base materials in some cases.

Examples of the alignment mode of the liquid crystal display element include a TN mode, a VA mode, an IPS mode, an FFS mode, and an OCB mode. In a case where an optical compensation film or an optical compensation layer is used, a film having a retardation corresponding to the alignment mode can be produced. In a case where a patterned retardation film is used, the liquid crystalline compound in the polymerizable composition may be substantially horizontally aligned with respect to the base material. In a case where an overcoat layer is used, a liquid crystalline compound having a larger number of polymerizable groups in one molecule may be thermally polymerized. In a case where an alignment film for a liquid crystal medium is used, it is preferable to use a polymerizable composition into which a liquid crystalline compound containing an alignment material and a polymerizabie group is mixed. Further, a liquid crystalline compound can be mixed with a liquid crystalline medium, and various properties such as the response speed or the contrast can be improved by adjusting the ratio between the liquid crystal medium and the liquid crystalline compound.

(Organic Light-Emitting Display Element)

The polymerizable composition of the present invention can be used as an organic light-emitting display element of the present invention by coating a base material or a base material having an alignment function with the polymerizable composition of the present invention, uniformly aligning liquid crystal molecules in the polymerizable composition of the present invention in a state in which a nematic phase or a smectic phase is maintained, and then performing polymerization. As the form of the display element to be used, the retardation film and the polarizing plate obtained by the polymerization are combined so as to be used as an anti-reflective film of an organic light-emitting display element. In a case where the combination of the retardation film and the polarizing film is used as an anti-reflective film, the angle between the polarizing axis of the polarizing plate and the slow axis of the retardation film is preferably approximately 45°. The polarizing plate and the retardation film may be bonded to each other using an adhesive or a pressure sensitive adhesive. Further, the retardation film may be directly laminated on the polarizing plate by performing a rubbing treatment or an alignment treatment of laminating a photo-alignment film. The polarizing plate used at this time is not particularly limited as long as the film has a polarizing function and examples thereof include a film stretched by allowing a polyvinyl alcohol-based film to adsorb iodine or a dichroic dye, a film formed by stretching a polyvinyl alcohol-based film and allowing the film to adsorb iodine or a dichroic dye or a dichroic pigment, a film that forms a polarizing layer by coating a substrate with an aqueous solution containing a dichroic dye, and a wire grid polarizer.

As the polyvinyl alcohol based resin, a resin formed by saponifying a polyvinyl acetate resin can be used. Examples of the polyvinyl acetate resin include polyvinyl acetate which is a homopolymer of vinyl acetate and copolymers of vinyl acetate and other monomers which are copolymerizable with the vinyl acetate. Examples of other monomers include unsaturated carboxylic acids, olefins, vinyl ethers, unsaturated sulfonic acids, and acrylamides containing an ammonium group. A method of forming a film with a polyvinyl alcohol resin is not particularly limited and known methods can be used for film formation. The thickness of the polyvinyl alcohol-based original film is not particularly limited, but is approximately 10 to 150 μm.

In a case where iodine is used as a dichroic pigment, a method of performing dyeing by immersing a polyvinyl alcohol resin film in an aqueous solution containing iodine or potassium iodide is typically employed. In a case where a dichroic dye is used as a dichroic pigment, a method of performing dyeing by immersing a polyvinyl alcohol resin film in an aqueous solution containing a water-soluble dichroic dye is typically employed.

In a case of the film that forms a polarizing layer by coating a substrate with an aqueous solution containing a dichroic dye, the dichroic pigment to be applied varies depending on the type of the base material to be used, and examples thereof include water-soluble dyes such as direct dyes and acidic dyes, and salts thereof, and water-insoluble dyes such as dispersion dyes and oil-soluble pigments. These dyes are typically dissolved in water and organic solvents, occasionally added to surfactants, and then applied to a base material on which a rubbing treatment or a corona treatment has been performed. The organic solvents vary depending on the solvent resistance of the base material and examples thereof include alcohols such as methanol, ethanol, and isopropyl alcohol; cellosolves such as methyl cellosolve and ethyl cellosolve; ketones such as acetone and methyl ethyl ketone; amides such as dimethyl formamide and N-methylpyrrolidone; and aromatic organic solvents such as benzene and toluene. The amount of the dye to be applied varies depending on the polarization performance of the dye, but is typically 0.05 to 1.0 g and preferably 0.1 to 0.8 g. Examples of the method of coating the base material with a color PfJ solution include various coating methods such as a bar coating method, a spray coating method, a roll coating method, and a gravure coating method.

In a case where a wire grid polarizer is used, it is preferable to use a polarizer formed of a conductive material such as Al, Cu, Ag, Cu, Ni, Cr, or Si.

(Lighting Element)

A polymer polarized in a state in which the polymerizable composition of the present invention is aligned on a nematic phase, a smectic phase, or a base material having an alignment function can be used as a heat radiation material of a lighting element or particularly a light emitting diode element. Examples of the form of the heat radiation material include a prepreg, a polymer sheet, an adhesive, and a sheet provided with metal foil.

(Optical Component)

The polymerizable composition of the present invention can be used as an optical component of the present invention by performing polymerization in a state in which a nematic phase or a smectic phase is maintained or a state in which the polymerization composition and an alignment material are combined.

(Colorant)

The polymerizable composition of the present invention can be also used as a colorant by adding a colorant such as a dye or an organic pigment.

(Polarizing Film)

The polymerizable composition of the present invention can be also used as a polarizing film by combining the polymerizable composition with a dichroic dye, lyotropic liquid crystals, or chromonic liquid crystals or adding these to the polymerizable composition.

### EXAMPLES

Hereinafter, the present invention will be described with reference to examples and comparative examples, but the present invention is not limited to these. Further, “part” and “%” are on a mass basis unless otherwise noted.

(Preparation of Polymerizable Composition (1))

55 parts of a compound represented by Formula (1-6), 25 parts of a compound represented by Formula (1-7), and 20 parts of a compound represented by Formula (2-a-1-a) were added to 400 parts of cyclopentanone (CPN), heated to 60° C., and stirred so that the mixture was dissolved therein, the dissolution was confirmed, the temperature thereof was returned to room temperature, 3 parts of IRGACURE 907 (Irg907: manufactured by BASF SE), 0.2 parts of MEGAFACE F-554 (F-554: manufactured by DIC Corporation), and 0.1 parts of p-methoxyphenol (MEHQ) were added thereto, and the solution was further stirred, thereby obtaining a solution. The solution was transparent and uniform. The obtained solution was filtered using a membrane filter having a pore diameter of 0.20 μm, thereby obtaining a polymerizable composition (1) used in Example 1 and the like.

(Preparation of Polymerizable Compositions (2) to (29) and Comparative Polymerizable Compositions (C1) and (C2))

Polymerizable compositions (2) to (29) used in Examples 2 to 29 and the like and polymerizable compositions (C1) and (C2) of Comparative Examples 1 and 2 were obtained under the same conditions as the conditions for preparation of the polymerizable composition (1) of Example 1 except that the proportions of respective compounds listed in the following table were changed as listed in the following table.

Specific compositions of the polymerizable liquid crystal compositions (1) to (29) of the present invention and the comparative polymerizable liquid crystal compositions (C1) and (C2) are listed in the following tables.

TABLE 1

| | Composition | | | | | | | | | | |
|---|---|---|---|---|---|---|---|---|---|---|---|
| | (1) | (2) | (3) | (4) | (5) | (6) | (7) | (8) | (9) | (10) | (11) |
| 1-6 | 55 | 55 | 55 | 80 | 55 | | | | | | |
| 1-7 | 25 | 25 | 25 | | 25 | 50 | 50 | 50 | 50 | 55 | 55 |
| 1-1 | | | | | | 20 | | | | 25 | |
| 1-2 | | | | | | | 20 | | | | 25 |
| 1-5 | | | | | | | | 20 | | | |
| 1-109 | | | | | | | | | 20 | | |
| 2-a-1-a | 20 | | 10 | | | 15 | 15 | 15 | 15 | 10 | 10 |
| 2-a-1-b | | 20 | 10 | | | | | | | 10 | 10 |
| 2-a-31 | | | | | 10 | | | | | | |
| 2-a-40 | | | | | | | | | | | |
| 2-a-28 | | | | | 10 | 15 | 15 | 15 | 15 | | |
| 2-a-30 | | | | | | | | | | | |
| 3-a-7 | | | | | | | | | | | |
| 4-a-1 | | | | | | | | | | | |
| 5-a-6 | | | | | | | | | | | |
| 6-a-1 | | | | | | | | | | | |
| 7-a-8 | | | | | | | | | | | |
| 11-27 | | | | | | | | | | | |
| 11-1 | | | | | | | | | | | |
| 2-b-1-a | | | | 10 | | | | | | | |
| 2-b-1-b | | | | 10 | | | | | | | |
| 3-b-9 | | | | | | | | | | | |
| 4-b-1 | | | | | | | | | | | |
| 5-b-9 | | | | | | | | | | | |
| 6-b-1 | | | | | | | | | | | |
| 7-b-5 | | | | | | | | | | | |
| Irg907 | 3 | 3 | 3 | 3 | 3 | 3 | 3 | 3 | 3 | 3 | 3 |
| MEHQ | 0.1 | 0.1 | 0.1 | 0.1 | 0.1 | 0.1 | 0.1 | 0.1 | 0.1 | 0.1 | 0.1 |
| F-554 | 0.2 | 0.2 | 0.2 | 0.2 | 0.2 | 0.2 | 0.2 | 0.2 | 0.2 | 0.2 | 0.2 |
| CPN | 400 | 400 | 400 | 400 | 400 | 400 | 400 | 400 | 400 | 400 | 400 |

TABLE 2

| | Composition | | | | | | | | | | |
|---|---|---|---|---|---|---|---|---|---|---|---|
| | (12) | (13) | (14) | (15) | (16) | (17) | (18) | (19) | (20) | (21) | (22) |
| 1-6 | | | 30 | 30 | 30 | 30 | 30 | 30 | 30 | 30 | 30 |
| 1-7 | 55 | 55 | 40 | 40 | 40 | 40 | 40 | 40 | 40 | 40 | 40 |
| 1-1 | | | | | | | | | | | |
| 1-2 | | | | | | | | | | | |
| 1-5 | 25 | | | | | | | | | | |
| 1-109 | | 25 | | | | | | | | | |
| 2-a-1-a | 10 | 10 | 20 | 20 | 20 | 20 | 20 | 20 | 20 | 20 | 20 |
| 2-a-1-b | 10 | 10 | | | | | | | | | |
| 2-a-31 | | | | | | | | | | | |
| 2-a-40 | | | | | | | | | | | |
| 2-a-28 | | | | | | | | | | | |
| 2-a-30 | | | | | | | | | | | |
| 3-a-7 | | | 10 | | | | | | | | |
| 4-a-1 | | | | 10 | | | | | | | |
| 5-a-6 | | | | | 10 | | | | | | |
| 6-a-1 | | | | | | 10 | | | | | |
| 7-a-8 | | | | | | | 10 | | | | |
| 11-27 | | | | | | | | 10 | | | |
| 11-1 | | | | | | | | | 10 | | |
| 2-b-1-a | | | | | | | | | | 10 | |
| 2-b-1-b | | | | | | | | | | | 10 |
| 3-b-9 | | | | | | | | | | | |
| 4-b-1 | | | | | | | | | | | |
| 5-b-9 | | | | | | | | | | | |
| 6-b-1 | | | | | | | | | | | |
| 7-b-5 | | | | | | | | | | | |
| Irg907 | 3 | 3 | 3 | 3 | 3 | 3 | 3 | 3 | 3 | 3 | 3 |
| MEHQ | 0.1 | 0.1 | 0.1 | 0.1 | 0.1 | 0.1 | 0.1 | 0.1 | 0.1 | 0.1 | 0.1 |
| F-554 | 0.2 | 0.2 | 0.2 | 0.2 | 0.2 | 0.2 | 0.2 | 0.2 | 0.2 | 0.2 | 0.2 |
| CPN | 400 | 400 | 400 | 400 | 400 | 400 | 400 | 400 | 400 | 400 | 400 |

TABLE 3

| | Composition | | | | | | | | |
|---|---|---|---|---|---|---|---|---|---|
| | (23) | (24) | (25) | (26) | (27) | (28) | (29) | (C1) | (C2) |
| 1-6 | 30 | 30 | 30 | 30 | 30 | 30 | 30 | | |
| 1-7 | 40 | 40 | 40 | 40 | 40 | 40 | 40 | | |
| 1-1 | | | | | | | | | |
| 1-2 | | | | | | | | | |
| 1-5 | | | | | | | | | |
| 1-109 | | | | | | | | | |
| 2-a-1-a | 20 | 20 | 20 | 20 | 20 | 20 | 20 | | |
| 2-a-1-b | | | | | | | | | |
| 2-a-31 | | | | | | 10 | | 100 | |
| 2-a-40 | | | | | | | 10 | | 100 |
| 2-a-28 | | | | | | | | | |
| 2-a-30 | | | | | | | | | |
| 3-a-7 | | | | | | | | | |
| 4-a-1 | | | | | | | | | |
| 5-a-6 | | | | | | | | | |
| 6-a-1 | | | | | | | | | |
| 7-a-8 | | | | | | | | | |
| 11-27 | | | | | | | | | |
| 11-1 | | | | | | | | | |
| 2-b-1-a | | | | | | | | | |
| 2-b-1-b | | | | | | | | | |
| 3-b-9 | 10 | | | | | | | | |
| 4-b-1 | | 10 | | | | | | | |
| 5-b-9 | | | 10 | | | | | | |
| 6-b-1 | | | | 10 | | | | | |
| 7-b-5 | | | | | 10 | | | | |
| Irg307 | 3 | 3 | 3 | 3 | 3 | 3 | 3 | 3 | 3 |
| MEHQ | 0.1 | 0.1 | 0.1 | 0.1 | 0.1 | 0.1 | 0.1 | 0.1 | 0.1 |
| F-554 | 0.2 | 0.2 | 0.2 | 0.2 | 0.2 | 0.2 | 0.2 | 0.2 | 0.2 |
| CPN | 400 | 400 | 400 | 400 | 400 | 400 | 400 | 400 | 400 |

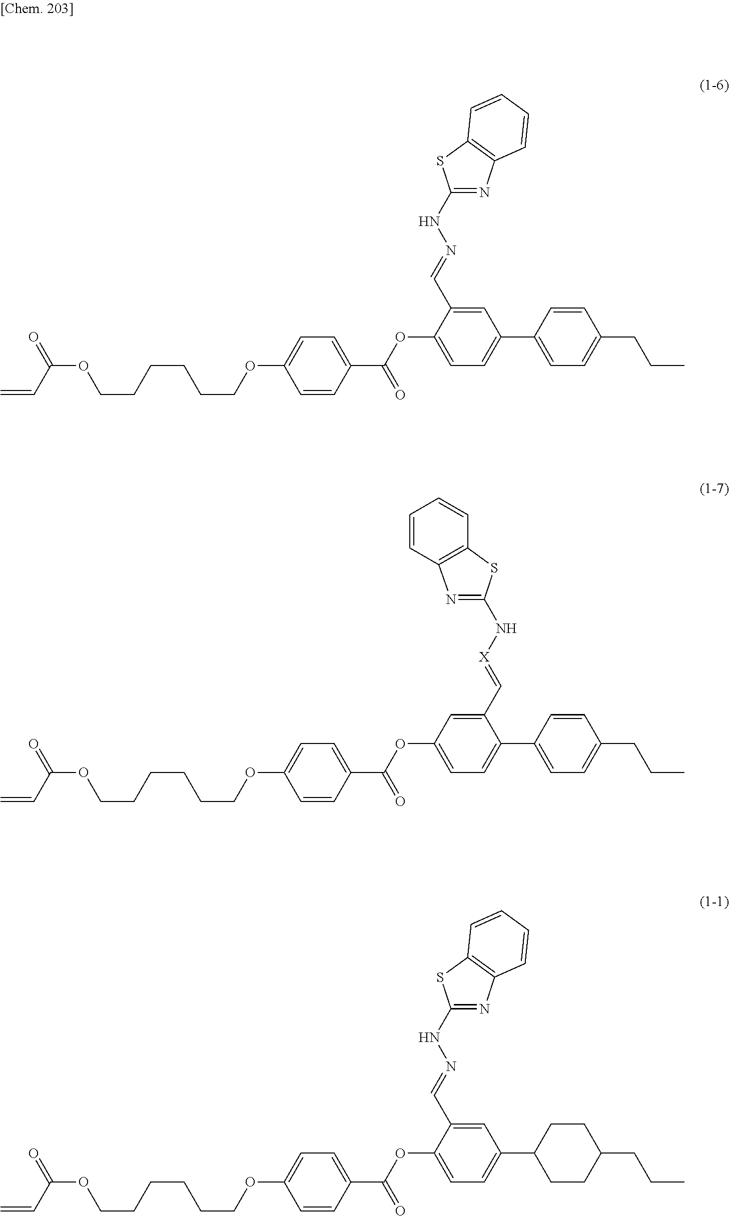

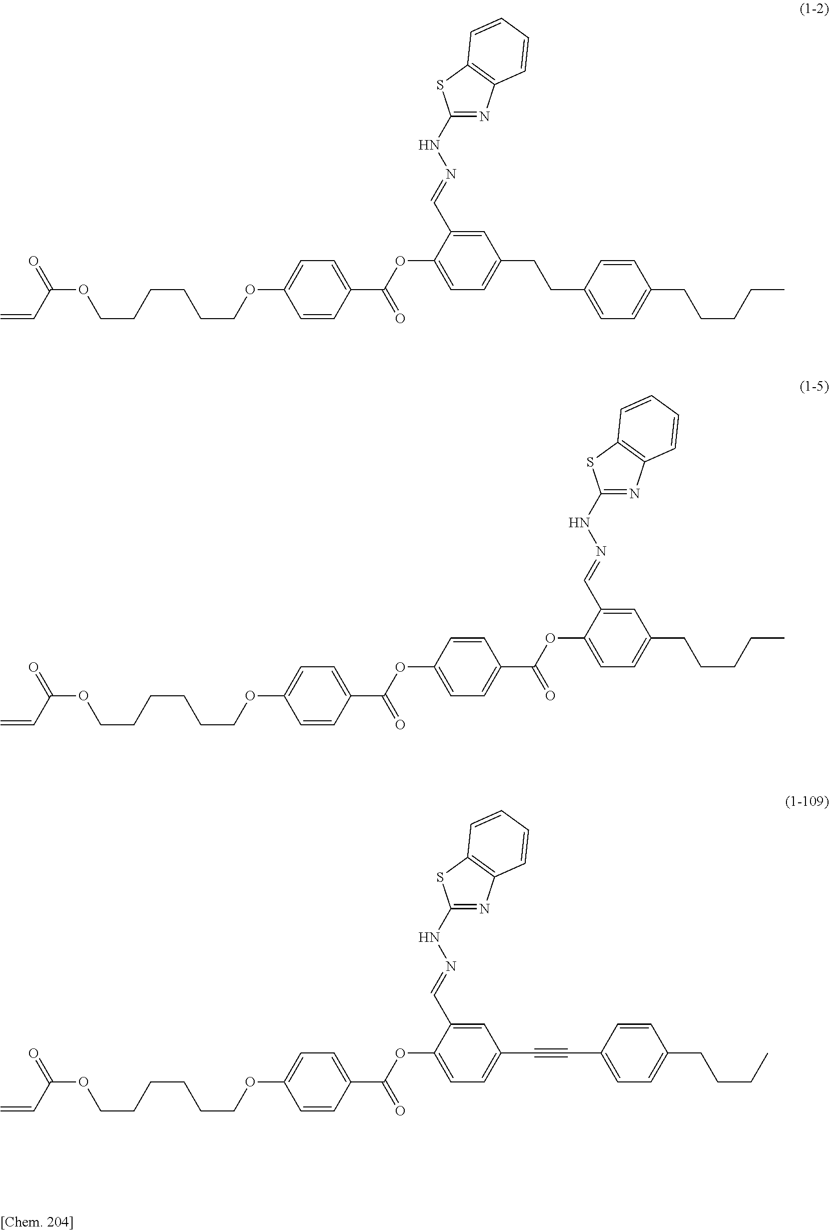

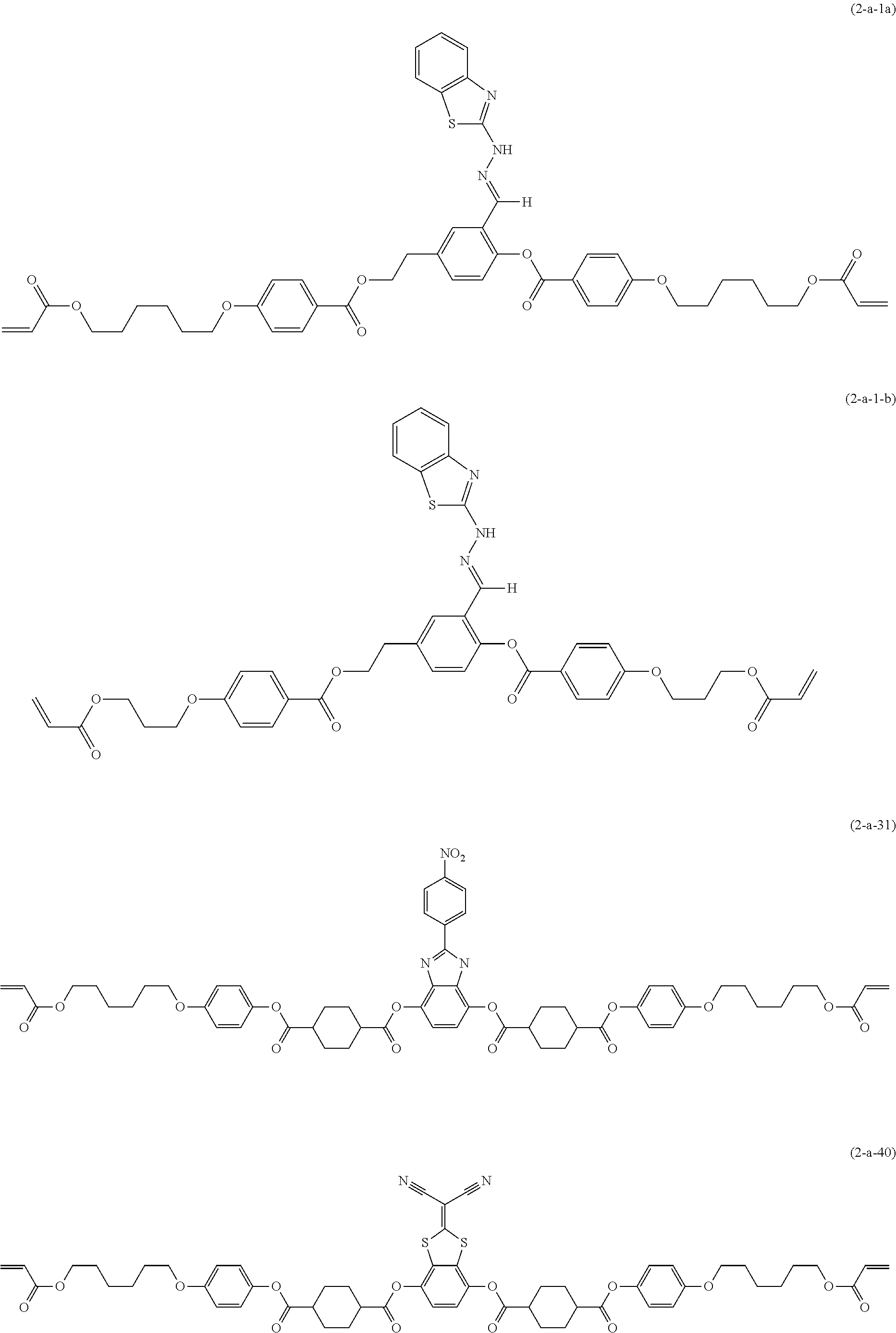

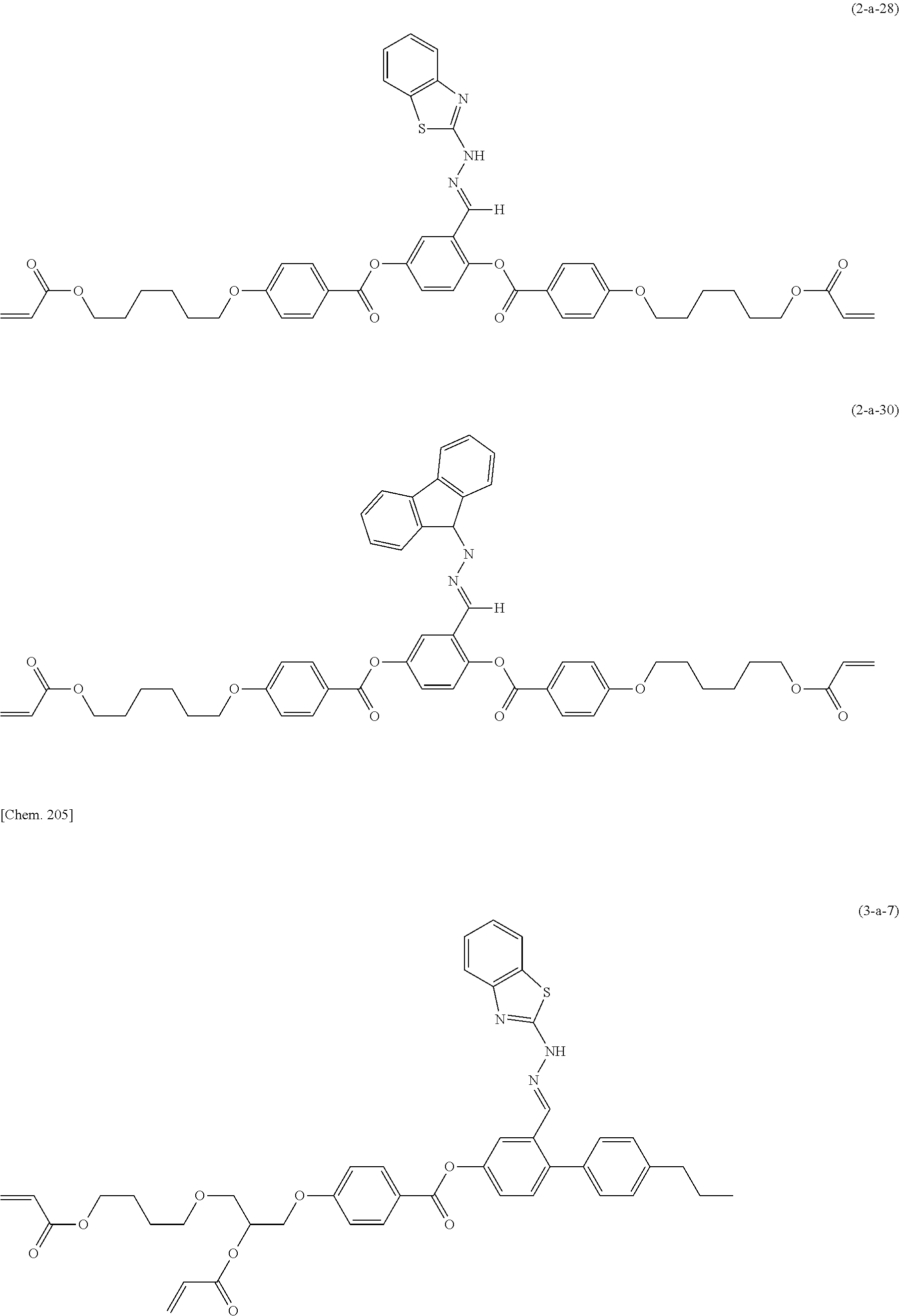

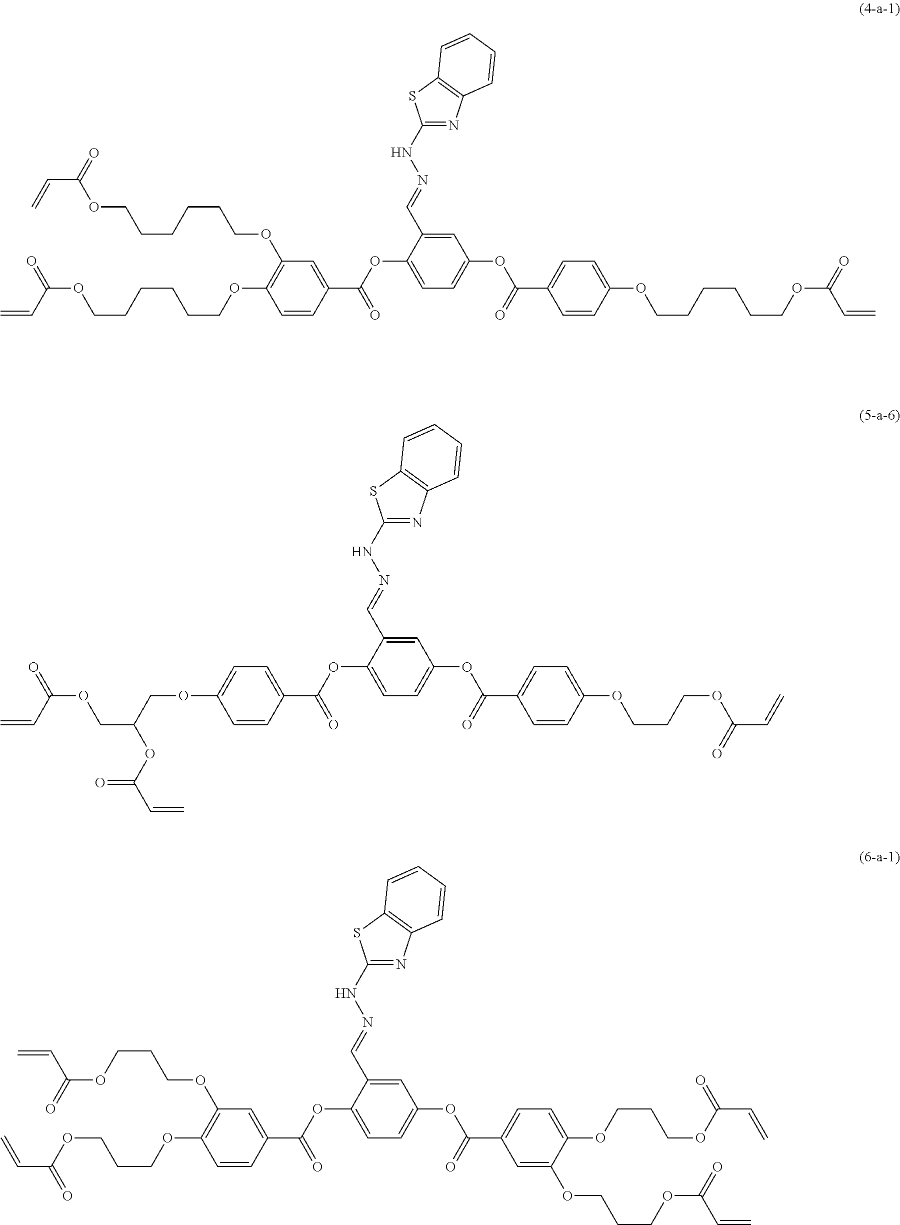

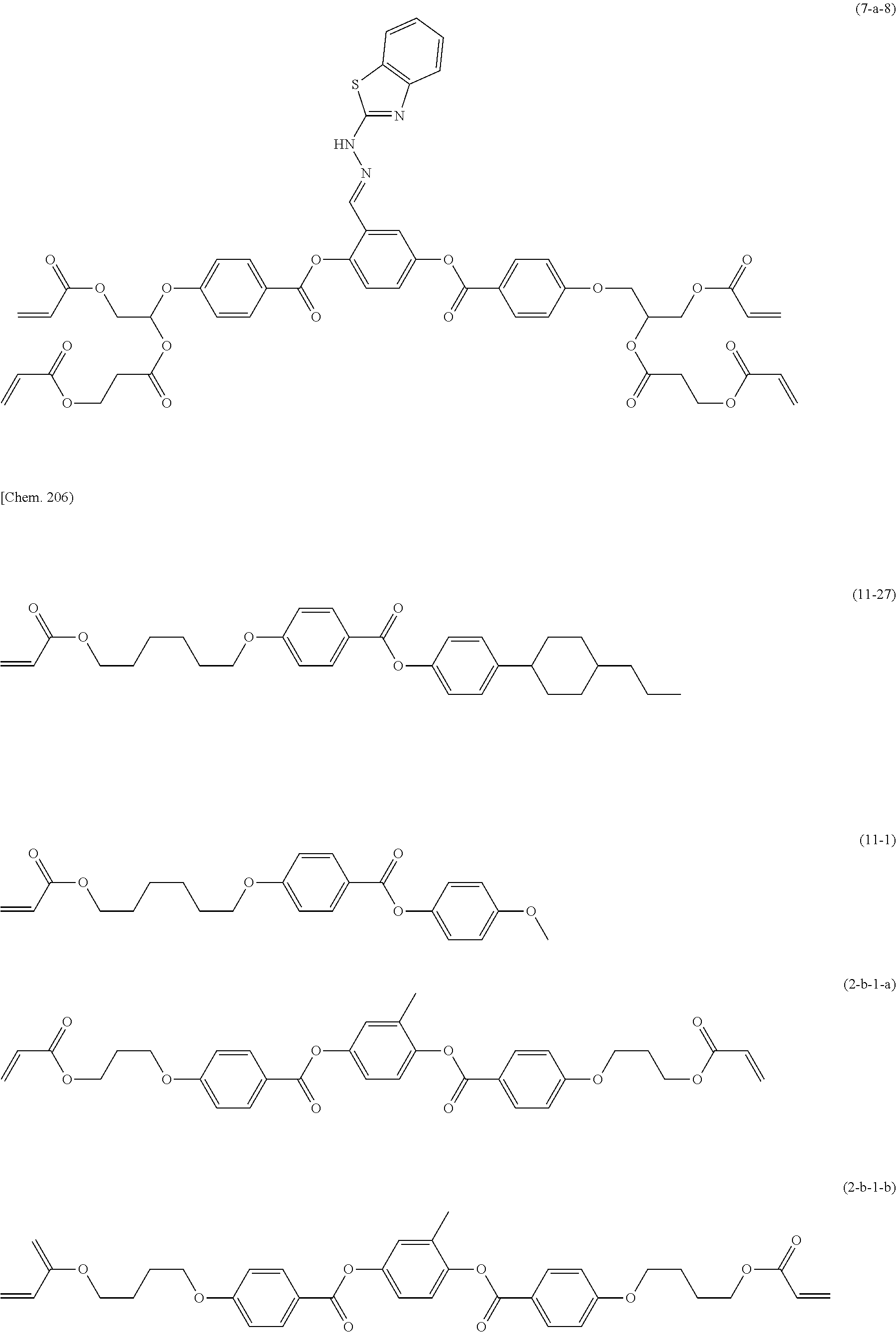

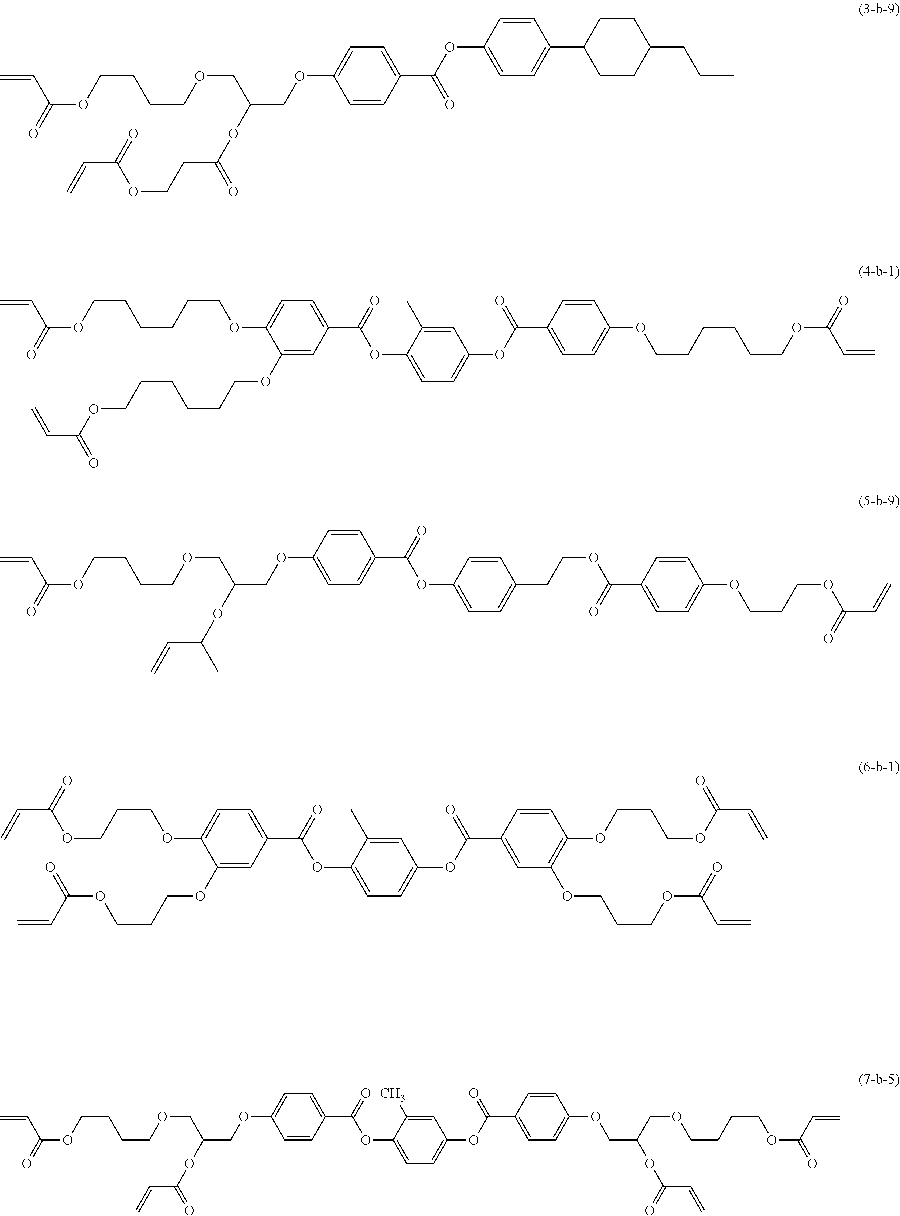

Re (450 nm)/Re (550 nm) of the compounds represented by Formulae (2-a-1-a), (2-a-1-b), (2-a-31), (2-a-40), (2-a-28), (2-a-30), (3-a-1), (4-a-1), (5-a-6), (6-a-1), and (7-a-8) are respectively 0.988, 0.802, 0.900, 0.832, 0.845, 0.901, 0.850, 0.860, 0.860, 0.880, and 0.880.

### Example 1

(Solubility)

The solubility of the polymerizable composition (1) of the present invention was evaluated based on the following evaluation criteria.

A: After the preparation, the state of the polymerizable composition of being transparent and uniform was able to be visually confirmed.

B: The state of the polymerizable composition of being transparent and uniform was able to be visually confirmed when the composition was heated and stirred, but precipitation of the compound was confirmed when the temperature was returned to room temperature.

C: The compound was not able to be uniformly dissolved even when heated and stirred.

(Storage Stability)

The state of the polymerizable composition (1) of the present invention after the polymerizable composition was allowed to stand for one week at room temperature was visually observed. The state of the polymerizable composition of being transparent and uniform was maintained even after 3 days. The evaluation of the storage stability was performed based on the following evaluation criteria.

A: The state of being transparent and uniform was maintained after the composition was allowed to stand at room temperature for 3 days.

B: The state of being transparent and uniform was maintained after the composition was allowed to stand at room temperature for 1 day.

C: The precipitation of the compound was confirmed after the composition was allowed to stand at room temperature for 1 hour.

The obtained results are listed in the following table.

TABLE 4

| | | | | | Phase |
|---|---|---|---|---|---|
| | | | | Alignment | difference |
| | Composition | Solubility | Storability | properties | ratio |
| Example 1, Example 55 | Composition (1) | A | A | A | 0.851 |
| Example 2, Example 56 | Composition (2) | A | A | A | 0.829 |
| Example 3, Example 57 | Composition (3) | A | A | A | 0.840 |
| Example 4, Example 58 | Composition (4) | A | A | A | 0.989 |
| Example 5, Example 59 | Composition (5) | A | A | A | 0.833 |
| Example 6, Example 60 | Composition (6) | A | A | A | 0.785 |
| Example 7, Example 61 | Composition (7) | A | A | A | 0.790 |
| Example 8, Example 62 | Composition (8) | A | A | A | 0.834 |
| Example 9, Example 63 | Composition (9) | A | A | A | 0.823 |
| Example 10, Example 64 | Composition (10) | A | A | A | 0.781 |
| Example 11, Example 65 | Composition (11) | A | A | A | 0.789 |
| Example 12, Example 66 | Composition (12) | A | A | A | 0.833 |
| Example 13, Example 67 | Composition (13) | A | A | A | 0.818 |
| Example 14, Example 68 | Composition (14) | A | A | A | 0.823 |
| Example 15, Example 69 | Composition (15) | A | A | A | 0.835 |
| Example 16, Example 70 | Composition (16) | A | A | A | 0.825 |
| Example 17, Example 71 | Composition (17) | A | A | A | 0.833 |
| Example 18, Example 72 | Composition (18) | A | A | A | 0.837 |
| Example 19, Example 73 | Composition (19) | A | A | A | 0.925 |
| Example 20, Example 74 | Composition (20) | A | A | A | 0.918 |
| Example 21, Example 75 | Composition (21) | A | A | A | 0.942 |
| Example 22, Example 76 | Composition (22) | A | A | A | 0.932 |
| Example 23, Example 77 | Composition (23) | A | A | A | 0.927 |
| Example 24, Example 78 | Composition (24) | A | A | A | 0.924 |
| Example 25, Example 79 | Composition (25) | A | A | A | 0.930 |
| Example 26, Example 80 | Composition (26) | A | A | A | 0.927 |
| Example 27, Example 81 | Composition (27) | A | A | A | 0.919 |
| Example 28, Example 82 | Composition (28) | A | A | A | 0.827 |
| Example 29, Example 83 | Composition (29) | A | A | A | 0.831 |
| Comparative Example 1 | Composition (C1) | C | C | B | 0.900 |
| Comparative Example 2 | Composition (C1) | C | C | C | 0.832 |

### Examples 2 to 29 and Comparative Examples 1 and 2

The solubility and the storability were measured using the polymerizable compositions (2) to (29) and comparative polymerizable compositions (C1) and (C2) The results are respectively listed in the table as the results of Examples 2 to 29 and Comparative Examples 1 and 2.

### (Example 55) Optically Anisotropic Body

A glass base material having a thickness of 0.7 mm was coated with a polyimide solution for an alignment film according to a spin coating method, dried at 100° C. for 10 minutes, and then baked at 200° C. for 60 minutes to obtain a coated film. Thereafter, the obtained coated film was subjected to a rubbing treatment. The rubbing treatment was performed using a commercially available rubbing device.

The rubbed base material was coated with the polymerizable composition (1) of the present invention according to a spin coating method and then dried at 100° C. for 2 minutes. The obtained coated film was cooled to room temperature and irradiated with ultraviolet rays at an intensity of 30 mW/cm for 30 seconds using a high-pressure mercury lamp, thereby obtaining an optically anisotropic body of Example 55. When the obtained optically anisotropic body was evaluated based on the following criteria, there were no defects found by visual observation and there were no defects found by observation using a polarizing microscope. In the following criteria, “A” indicates that the alignment properties were most excellent and “C” indicates that the alignment properties were not exhibited at all.

(Alignment Properties)

A: There were no defects found by visual observation and there were no defects found by observation using a polarizing microscope.

B: There were no defects found by visual observation, but non-aligned portions were present in the entire composition when the observation was made using a polarizing microscope.

C: There were defects found in the entire composition by visual observation.

(Phase Difference Ratio)

When the phase difference of the obtained optically anisotropic body was measured using a retardation film and optical material inspection device RETS-100 (manufactured by Otsuka Electronics Co., Ltd.), the in-plane phase difference (Re (550)) at a wavelength of 550 nm was 130 nm. Further, the ratio Re (450)/Re (550) of the in-plane phase difference (Re (450)) to the in-plane phase difference Re (550) at a wavelength of 450 nm was 0.851 and a retardation film with excellent uniformity was obtained.

Since the solubility of the polymerizable composition (C1) of Comparative Example 1 and the polymerizable composition (C2) of Comparative Example 2 in cyclopentanone was poor so that optically anisotropic bodies were not able to be obtained, optically anisotropic bodies were respectively obtained in the same manner as in Example 55 using chloroform in place of cyclopentanone. The alignment properties and the phase difference ratios of the obtained optically anisotropic bodies are as listed in the table. Further, the results obtained by measuring the phase difference ratios using optically anisotropic bodies with defects are also listed in the table.

### Examples 56 to 83

Optically anisotropic bodies of Examples 56 to 83 were obtained under the same conditions as in Example 55 except that the polymerizable compositions to be used were changed into the polymerizable compositions (2) to (29) of the present invention.

The obtained results are listed in the table.

(Preparation of Polymerizable Composition (30))

40 parts of a compound represented by Formula (1-6), 40 parts of a compound represented by Formula (1-7), 10 parts of a compound represented by Formula (2-a-1-a), and 10 parts of a compound represented by Formula (2-a-28) were added to 400 parts of methyl ethyl ketone (MEK), heated to 60° C., and stirred so that the mixture was dissolved therein, the dissolution was confirmed, the temperature thereof was returned to room temperature, 3 parts of IRGACURE 907 (Irg907: manufactured by BASF SE), 0.2 parts of MEGAFACE F-554 (F-554: manufactured by DIC Corporation), and 0.1 parts of p-methoxyphenol were added thereto, and the solution was further stirred, thereby obtaining a solution. The solution was transparent and uniform. The obtained solution was filtered using a membrane filter having a pore diameter of 0.20 μm, thereby obtaining a polymerizable composition (30) used in Example 30 and the like.

The state of the polymerizable composition (30) of the present invention after the polymerizable composition was allowed to stand for 3 days at room temperature was visually observed. The state of the polymerizable composition of being transparent and uniform was maintained even after one week.

(Preparation of Polymerizabie Compositions (31) to (50) and Comparative Polymerizable Compositions (C3) and (C4))

Polymerizable compositions (31) to (50) used in Examples 31 to 50 and the like and polymerizable compositions (C3) and (C4) used in Comparative Examples 3 and 4 were obtained under the same conditions as the conditions for preparation of the polymerizable composition (30) except that the proportions of respective compounds listed in the following tables were changed as listed in the following tables.

(Preparation of Polymerizable Compositions (51) and (52))

50 parts of a compound represented by Formula (1-7), 25 parts of a compound represented by Formula (1-2), and 25 parts of a compound represented by Formula (2-a-1-a), were added to 200 parts of methyl ethyl ketone (MEK) and 200 parts of methyl isobutyl ketone (MIBK), heated to 60′C, and stirred so that the mixture was dissolved therein, the dissolution was confirmed, the temperature thereof was returned to room temperature, 3 parts of IRGACURE 907 (manufactured by BASE SE), 0.2 parts of MEGAFACE F-554 (manufactured by DIG Corporation), and 0.1 parts of p-methoxyphenol were added thereto, and the solution was further stirred, thereby obtaining a solution. The solution was transparent and uniform. The obtained solution was filtered using a membrane filter having a pore diameter of 0.20 μm, thereby obtaining a polymerizable composition (51) used in Example 51 and the like.

A polymerizable composition (52) used in Example 52 and the like was obtained in the same manner as in Example 51.

The states of the polymerizable compositions (51) and (52) of the present invention after the polymerizable compositions were allowed to stand for 3 days at room temperature were visually observed. The states of the polymerizable compositions of being transparent and uniform were maintained even after one week.

(Preparation of Polymerizable Compositions (53) and (54))

40 parts of a compound represented by Formula (1-7), 20 parts of a compound represented by Formula (1-2), 20 parts of a compound represented by Formula (2-a-1-a), 10 parts of a compound represented by Formula (2-a-28), and 10 parts of a compound represented by Formula (2-b-1-a) were added to 300 parts of methyl ethyl ketone (NEK) and 100 parts of methyl isobutyl ketone (MIBK), heated to 60° C., and stirred so that the mixture was dissolved therein, the dissolution was confirmed, the temperature thereof was returned to room temperature, 3 parts of IRGACURE 907 (manufactured by BASF SE), 0.2 parts of MEGAFACE F-554 (manufactured by DIGC Corporation), and 0.1 parts of p-methoxyphenol were added thereto, and the solution was further stirred, thereby obtaining a solution. The solution was transparent and uniform. The obtained solution was filtered using a membrane filter having a pore diameter of 0.20 μm, thereby obtaining a polymerizable composition (53) used in Example 53 and the like.

A polymerizable composition (54) used in Example 54 and the like was obtained in the same manner as in Example 53.

The states of the polymerizable compositions (53) and (54) of the present invention after the polymerizable compositions were allowed to stand for 3 days at room temperature were visually observed. The states of the polymerizable compositions of being transparent and uniform were maintained even after one week.

In the polymerizable compositions (53) and (54) of the present invention, there were no defects found by visual observation and there were no defects found by observation using a polarizing microscope and the alignment properties thereof were excellent.

Specific compositions of the polymerizable liquid crystal compositions (30) to (54) of the present invention and the comparative polymerizabie liquid crystal compositions (C3) and (C4) are listed in the following tables.

TABLE 5

| | Composition | | | | | | | | | |
|---|---|---|---|---|---|---|---|---|---|---|
| | (30) | (31) | (32) | (33) | (34) | (35) | (36) | (37) | (38) | (39) |
| 1-6 | 40 | | | | | | | | | |
| 1-7 | 40 | 40 | 40 | 50 | 50 | 30 | 40 | 40 | 40 | 40 |
| 1-1 | | | | | | | | | | |
| 1-2 | | 40 | | 30 | | 30 | 30 | | | |
| 1-5 | | | | | | | | | | |
| 1-109 | | | 40 | | 30 | | | 30 | 30 | 30 |
| 2-a-1-a | 10 | 20 | 20 | 5 | 5 | 25 | 20 | 20 | 20 | 20 |
| 2-a-1-b | | | | | | | 10 | | | |
| 2-a-31 | | | | | | | | | | |
| 2-a-40 | | | | | | | | | | |
| 2-a-28 | 10 | | | 15 | 15 | 15 | | | | |
| 2-a-30 | | | | | | | | | | |
| 3-a-7 | | | | | | | | 10 | | |
| 4-a-1 | | | | | | | | | 10 | |
| 5-a-6 | | | | | | | | | | 10 |
| 6-a-1 | | | | | | | | | | |
| 7-a-8 | | | | | | | | | | |
| 11-27 | | | | | | | | | | |
| 11-1 | | | | | | | | | | |
| 2-b-1-a | | | | | | | | | | |
| 2-b-1-b | | | | | | | | | | |
| 3-b-9 | | | | | | | | | | |
| 4-b-1 | | | | | | | | | | |
| 5-b-9 | | | | | | | | | | |
| 6-b-1 | | | | | | | | | | |
| 7-b-5 | | | | | | | | | | |
| Irg907 | 3 | 3 | 3 | 3 | 3 | 3 | 3 | 3 | 3 | 3 |
| MEHQ | 0.1 | 0.1 | 0.1 | 0.1 | 0.1 | 0.1 | 0.1 | 0.1 | 0.1 | 0.1 |
| F-554 | 0.2 | 0.2 | 0.2 | 0.2 | 0.2 | 0.2 | 0.2 | 0.2 | 0.2 | 0.2 |
| MEK | 400 | 400 | 400 | 400 | 400 | 400 | 400 | 400 | 400 | 400 |
| MIBK | | | | | | | | | | |

TABLE 6

| | Composition | | | | | | | | | |
|---|---|---|---|---|---|---|---|---|---|---|
| | (40) | (41) | (42) | (43) | (44) | (45) | (46) | (47) | (48) | (49) |
| 1-6 | | | | | | | | | | |
| 1-7 | 40 | 40 | 40 | 40 | 40 | 40 | 40 | 40 | 40 | 40 |
| 1-1 | | | | | | | | | | |
| 1-2 | | | | | | | | | | |
| 1-5 | | | | | | | | | | |
| 1-109 | 30 | 30 | 30 | 30 | 30 | 30 | 30 | 30 | 30 | 30 |
| 2-a-1-a | 20 | 20 | 20 | 20 | 20 | 20 | 20 | 20 | 20 | 20 |
| 2-a-1-b | | | | | | | | | | |
| 2-a-31 | | | | | | | | | | |
| 2-a-40 | | | | | | | | | | |
| 2-a-28 | | | | | | | | | | |
| 2-a-30 | | | | | | | | | | |
| 3-a-7 | | | | | | | | | | |
| 4-a-1 | | | | | | | | | | |
| 5-a-6 | | | | | | | | | | |
| 6-a-1 | 10 | | | | | | | | | |
| 7-a-8 | | 10 | | | | | | | | |
| 11-27 | | | 10 | | | | | | | |
| 11-1 | | | | 10 | | | | | | |
| 2-b-1-a | | | | | 10 | | | | | |
| 2-b-1-b | | | | | | 10 | | | | |
| 3-b-9 | | | | | | | 10 | | | |
| 4-b-1 | | | | | | | | 10 | | |
| 5-b-9 | | | | | | | | | 10 | |
| 6-b-1 | | | | | | | | | | 10 |
| 7-b-5 | | | | | | | | | | |
| Irg907 | 3 | 3 | 3 | 3 | 3 | 3 | 3 | 3 | 3 | 3 |
| MEHQ | 0.1 | 0.1 | 0.1 | 0.1 | 0.1 | 0.1 | 0.1 | 0.1 | 0.1 | 0.1 |
| F-554 | 0.2 | 0.2 | 0.2 | 0.2 | 0.2 | 0.2 | 0.2 | 0.2 | 0.2 | 0.2 |
| MEK | 400 | 400 | 400 | 400 | 400 | 400 | 400 | 400 | 400 | 400 |
| MIBK | | | | | | | | | | |

TABLE 7

| | Composition | | | | | | |
|---|---|---|---|---|---|---|---|
| | (50) | (51) | (52) | (53) | (54) | (C3) | (C4) |
| 1-6 | | | | | | | |
| 1-7 | 40 | 50 | 50 | 40 | 50 | | |
| 1-1 | | | | | | | |
| 1-2 | | 25 | | 20 | | | |
| 1-5 | | | | | | | |
| 1-109 | 30 | | 25 | | 10 | | |
| 2-a-1-a | 20 | 25 | 25 | 20 | 20 | | |
| 2-a-1-b | | | | | | | |
| 2-a-31 | | | | | | | |
| 2-a-40 | | | | | | | |
| 2-a-28 | | | | 10 | 10 | 100 | |
| 2-a-30 | | | | | | | 100 |
| 3-a-7 | | | | | | | |
| 4-a-1 | | | | | | | |
| 5-a-6 | | | | | | | |
| 6-a-1 | | | | | | | |
| 7-a-8 | | | | | | | |
| 11-27 | | | | | | | |
| 11-1 | | | | | | | |
| 2-b-1-a | | | | 10 | 10 | | |
| 2-b-1-b | | | | | | | |
| 3-b-9 | | | | | | | |
| 4-b-1 | | | | | | | |
| 5-b-9 | | | | | | | |
| 6-b-1 | | | | | | | |
| 7-b-5 | 10 | | | | | | |
| Irg907 | 3 | 3 | 3 | 3 | 3 | 3 | 3 |
| MEHQ | 0.1 | 0.1 | 0.1 | 0.1 | 0.1 | 0.1 | 0.1 |
| F-554 | 0.2 | 0.2 | 0.2 | 0.2 | 0.2 | 0.2 | 0.2 |
| MEK | 400 | 200 | 200 | 300 | 300 | 400 | 400 |
| MIBK | | 200 | 200 | 100 | 100 | | |

### Example 30

(Solubility)

The solubility of the polymerizable composition (30) of the present invention was evaluated based on the following evaluation criteria.

A: After the preparation, the state of the polymerizable composition of being transparent and uniform was able to be visually confirmed.

B: The state of the polymerizable composition of being transparent and uniform was able to be visually confirmed when the composition was heated and stirred, but precipitation of the compound was confirmed when the temperature was returned to room temperature.

C: The compound was not able to be uniformly dissolved even when heated and stirred.

(Storage Stability)

The state of the polymerizable composition (30) of the present invention after the polymerizable composition was allowed to stand for one week at room temperature was visually observed. The state of the polymerizable composition of the present invention of being transparent and uniform was maintained even after three weeks. The evaluation of the storage stability was performed based on the following evaluation criteria.

A: The state of being transparent and uniform was maintained after the composition was allowed to stand at room temperature for 3 days.

B: The state of being transparent and uniform was maintained after the composition was allowed to stand at room temperature for 1 day.

C: The precipitation of the compound was confirmed after the composition was allowed to stand at room temperature for 1 hour.

The obtained results are listed in the following table.

TABLE 8

| | | | | | Phase |
|---|---|---|---|---|---|
| | | | | Alignment | difference |
| | Composition | Solubility | Storability | properties | ratio |
| Example 30, Example 84 | Composition (30) | A | A | A | 0.812 |
| Example 31, Example 85 | Composition (31) | A | A | A | 0.796 |
| Example 32, Example 86 | Composition (32) | A | A | A | 0.865 |
| Example 33, Example 87 | Composition (33) | A | A | A | 0.792 |
| Example 34, Example 88 | Composition (34) | A | A | A | 0.834 |
| Example 35, Example 89 | Composition (35) | A | A | A | 0.823 |
| Example 36, Example 90 | Composition (36) | A | A | A | 0.805 |
| Example 37, Example 91 | Composition (37) | A | A | A | 0.861 |
| Example 38, Example 92 | Composition (38) | A | A | A | 0.847 |
| Example 39, Example 93 | Composition (39) | A | A | A | 0.852 |
| Example 40, Example 94 | Composition (40) | A | A | A | 0.860 |
| Example 41, Example 95 | Composition (41) | A | A | A | 0.853 |
| Example 42, Example 96 | Composition (42) | A | A | A | 0.948 |
| Example 43, Example 97 | Composition (43) | A | A | A | 0.936 |
| Example 44, Example 98 | Composition (44) | A | A | A | 0.947 |
| Example 45, Example 99 | Composition (45) | A | A | A | 0.941 |
| Example 46, Example 100 | Composition (46) | A | A | A | 0.948 |
| Example 47, Example 101 | Composition (47) | A | A | A | 0.947 |
| Example 48, Example 102 | Composition (48) | A | A | A | 0.944 |
| Example 49, Example 103 | Composition (49) | A | A | A | 0.944 |
| Example 50, Example 104 | Composition (50) | A | A | A | 0.937 |
| Example 51, Example 105 | Composition (51) | A | A | A | 0.806 |
| Example 52, Example 106 | Composition (52) | A | A | A | 0.851 |
| Comparative Example 3 | Composition (C3) | C | C | B | 0.845 |
| Comparative Example 4 | Composition (C4) | C | C | B | 0.845 |

### Examples 31 to 52 and Comparative Examples 3 and 4

The solubility, the storability, and the alignment properties were measured using the polymerizable compositions (31) to (52) and comparative polymerizable compositions (C3) and (C4). The results are respectively listed in the table as the results of Examples 31 to 52 and Comparative Examples 3 and 4.

### (Example 84) Optically Anisotropic Body

A uniaxially stretched PET film having a thickness of 50 μm was subjected to a rubbing treatment using a commercially available rubbing device, and the film was coated with the polymerizable composition (30) of the present invention according to a bar coating method and then dried at 80° C. for 2 minutes. The obtained coated film was cooled to room temperature and irradiated with ultraviolet rays at a conveyor speed of 6 m/min using a UV conveyor device (manufactured by GS Yuasa Corporation), thereby obtaining an optically anisotropic body of Example 84. When the obtained optically anisotropic body was evaluated based on the following criteria, there were no defects found by visual observation and there were no defects found by observation using a polarizing microscope.

(Alignment Properties)

A: There were no defects found by visual observation and there were no defects found by observation using a polarizing microscope.

B: There were no defects found by visual observation, but non-aligned portions were present in the entire composition when the observation was made using a polarizing microscope.

C: There were defects found in the entire composition by visual observation.

(Phase Difference Ratio)

When the phase difference of the obtained optically anisotropic body was measured using a retardation film and optical material inspection device RETS-100 (manufactured by Otsuka Electronics Co., Ltd.), the in-plane phase difference (Re (550)) at a wavelength of 550 nm was 130 nm. Further, the ratio Re (450)/Re (550) of the in-plane phase difference (Re (450)) to the in-plane phase difference Re (550) at a wavelength of 450 nm was 0.851 and a retardation film with excellent uniformity was obtained.

Since the solubility of the polymerizable composition (C3) of Comparative Example 3 and the polymerizable composition (C4) of Comparative Example 4 in methyl ethyl ketone and methyl isobutyl ketone was poor so that optically anisotropic bodies were not able to be obtained, optically anisotropic bodies were respectively obtained in the same manner as in Example 55 using chloroform in place of methyl ethyl ketone and methyl isobutyl ketone. The alignment properties and the phase difference ratios of the obtained optically anisotropic bodies are as listed in Table 1.

### Examples 85 to 104

Optically anisotropic bodies of Examples 85 to 104 were obtained in the same manner as in Example 84 except that the polymerizable compositions to be used were changed into the polymerizable compositions (31) to (50) of the present invention.

### Example 105

A non-stretched cycloolefin polymer film “ZEONOR” (manufactured by ZEON CORPORATION) having a thickness of 40 μm was subjected to a rubbing treatment using a commercially available rubbing device, and the film was coated with the polymerizable composition (51) of the present invention according to a bar coating method and then dried at 80° C. for 2 minutes. The obtained coated film was cooled to room temperature and irradiated with ultraviolet rays at a conveyor speed of 6 m/min using a UN conveyor device (manufactured by GS Yuasa Corporation), thereby obtaining an optically anisotropic body of Example 105. When the obtained optically anisotropic body was evaluated based on the criteria, there were no defects found by visual observation and there were no defects found by observation using a polarizing microscope. Further, the in-plane phase difference (Re (550)) of the obtained optically anisotropic body was 121 nm, and the ratio Re (450)/Re (550) of the in-plane phase difference (Re (450)) to the in-plane phase difference Re (550) at a wavelength of 450 nm was 0.806 and a retardation film with excellent uniformity was obtained.

### Example 106

An optically anisotropic body of Example 106 was obtained under the same conditions as in Example 105 except that the polymerizable composition to be used was changed into the polymerizable composition (52) of the present invention.

The obtained results are listed in the table.

### Example 107

5 parts of a photo-alignment material (weight-average molecular weight: 250000) represented by Formula (12-4) was dissolved in 95 parts of cyclopentanone, thereby obtaining a solution. The obtained solution was filtered using a membrane filter having a pore diameter of 0.45 μm, thereby obtaining a photo-alignment solution (1). Next, a glass base material having a thickness of 0.7 mm was coated with the obtained solution according to a spin coating method, dried at 80° C. for 2 minutes, and then immediately irradiated with linearly polarized light having a wavelength of 313 nm at an intensity of 10 mW/cm² for 20 seconds, thereby obtaining a photo-alignment film (1). The obtained photo-alignment film was coated with the polymerizable composition (53) according to a spin coating method and then dried at 100° C. for 2 minutes. The obtained coated film was cooled to room temperature and irradiated with ultraviolet rays at an intensity of 30 mW/cm² for 30 seconds using a high-pressure mercury lamp, thereby obtaining an optically anisotropic body of Example 107. When the obtained optically anisotropic body was evaluated based on the following criteria, there were no defects found by visual observation and there were no defects found by observation using a polarizing microscope. Further, when the retardation of the obtained optically anisotropic body was measured using RETS-100 (manufactured by Otsuka Electronics Co., Ltd.), the in-plane phase difference (Re (550)) at a wavelength of 550 nm was 125 nm and a retardation film with excellent uniformity was obtained.

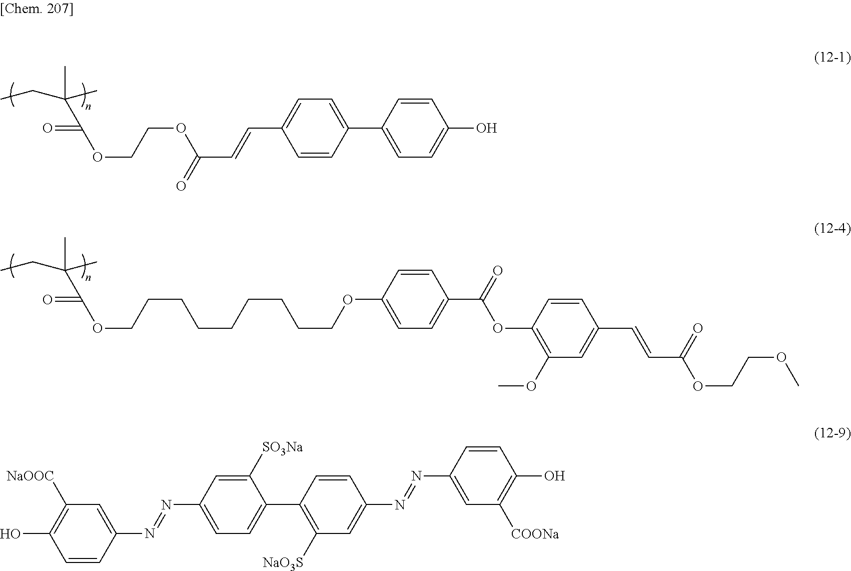

### Example 108

5 parts of a photo-alignment material (weight-average molecular weight: 200000) represented by Formula (12-1) was dissolved in 95 parts of N-methyl-2-pyrrolidone, and the obtained solution was filtered using a membrane filter having a pore diameter of 0.45 μm, thereby obtaining a photo-alignment solution (2). Next, a glass base material having a thickness of 0.7 mm was coated with the obtained solution according to a spin coating method, dried at 100° C. for 5 minutes, further dried at 1300 for 10 minutes, and then immediately irradiated with linearly polarized light having a wavelength of 313 nm at an intensity of 10 mW/cm² for 1 minute, thereby obtaining a photo-alignment film (2). The obtained photo-alignment film was coated with the polymerizable composition (53) according to a spin coating method and then dried at 100° C. for 2 minutes. The obtained coated film was cooled to room temperature and irradiated with ultraviolet rays at an intensity of 30 mW/cm for 30 seconds using a high-pressure mercury lamp, thereby obtaining an optically anisotropic body of Example 108. When the obtained optically anisotropic body was evaluated based on the following criteria, there were no defects found by visual observation and there were no defects found by observation using a polarizing microscope. Further, when the retardation of the obtained optically anisotropic body was measured using RETS-100 (manufactured by Otsuka Electronics Co., Ltd.), the in-plane phase difference (Re (550)) at a wavelength of 550 nm was 120 nm and a retardation film with excellent uniformity was obtained.

### Example 109

1 part of a photo-alignment material represented by Formula (12-9) was dissolved in 50 parts of (2-ethoxyethoxy) ethanol and 49 parts of 2-butoxyethanol, and the obtained solution was filtered using a membrane filter having a pore diameter of 0.45 urn, thereby obtaining a photo-alignment solution (3). Next, a polymethyl methacrylate (PMMA) film having a thickness of 80 μm was coated with the obtained solution according to a bar coating method, dried at 80° C. for 2 minutes, and then immediately irradiated with linearly polarized light having a wavelength of 365 nm at an intensity of 10 mW/cm² for 50 seconds, thereby obtaining a photo-alignment film (3). The obtained photo-alignment film was coated with the polymerizable composition (53) according to a spin coating method and then dried at 100° C. for 2 minutes. The obtained coated film was cooled to room temperature and irradiated with ultraviolet rays at an intensity of 30 mW/cm² for 30 seconds using a high-pressure mercury lamp, thereby obtaining an optically anisotropic body of Example 109. When the alignment properties of the obtained optically anisotropic body were evaluated based on the following criteria, there were no defects found by visual observation and there were no defects found by observation using a polarizing microscope. Further, when the retardation of the obtained optically anisotropic body was measured using RETS-100 (manufactured by Otsuka Electronics Co., Ltd.), the in-plane phase difference (Re (550)) at a wavelength of 550 nm was 137 nm and a retardation film with excellent uniformity was obtained.

### Examples 110 to 112

An optically anisotropic body of Examples 110 was obtained under the same conditions as in Example 107, an optically anisotropic body of Examples 111 was obtained under the same conditions as in Example 108, and an optically anisotropic body of Examples 112 was obtained under the same conditions as in Example 109 except that the polymerizable composition (54) was used. When the alignment properties of the obtained optically anisotropic bodies were evaluated based on the following criteria, there were no defects found by visual observation and there were no defects found by observation using a polarizing microscope, and a retardation film having an excellent uniformity is obtained.

### Example 113

10 parts of a compound represented by Formula (1-6), 55 parts of a compound represented by Formula (1-7), 10 parts of a compound represented by Formula (1-2), 7 parts of a compound represented by Formula (2-a-1-a), 10 parts of a compound represented by Formula (2-b-1-a), 8 parts of a compound represented by Formula (2-b-1-b), and 6 parts of a compound represented by Formula (10-10) were added to 200 parts of methyl ethyl ketone and 200 parts of methyl isobutyl ketone, heated to 60° C., and stirred so that the mixture was dissolved therein, the dissolution was confirmed, the temperature thereof was returned to room temperature, 3 parts of IRGACURE 907 (Irg907: manufactured by BASF SE), 0.05 parts of MEGAFACE F-554 (F-554: manufactured by DIC Corporation), 0.2 parts of polypropylene having a weight-average molecular weight of 1200, 0.1 parts of p-methoxyphenol, and 0.1 parts of IRGANOX 1076 were added thereto, and the solution was further stirred, thereby obtaining a solution. The solution was transparent and uniform. The obtained solution was filtered using a membrane filter having a pore diameter of 0.20 μm, thereby obtaining a polymerizable composition (113) of the present invention.

A uniaxially stretched PET film having a thickness of 180 μm was subjected to a rubbing treatment using a commercially available rubbing device, and the film was coated with the polymerizable composition (113) of the present invention according to a bar coating method and then dried at 80° C. for 2 minutes. The obtained coated film was cooled to room temperature and irradiated with ultraviolet rays at a conveyor speed of 4 m/min using a UV conveyor device (manufactured by GS Yuasa Corporation) having a lamp output of 2 kW (80 W/cm), thereby obtaining an optically anisotropic body of Example 113. When the alignment properties of the obtained optically anisotropic body were evaluated, there were no defects found by visual observation and there were no defects found by observation using a polarizing microscope. In addition, the obtained optically anisotropic body appeared to be green and it was understood that the film became a reflective film.

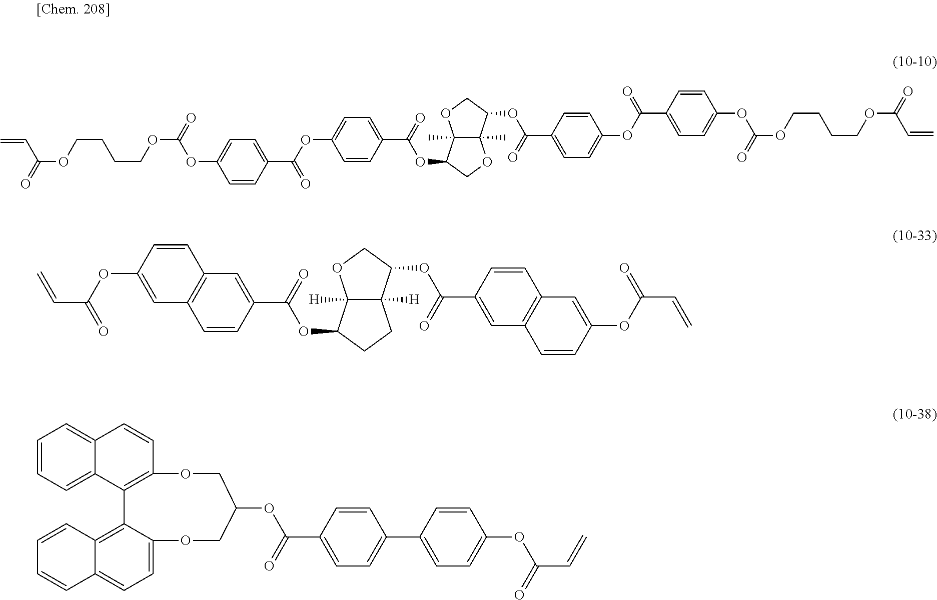

### Example 114

An optically anisotropic body of Example 114 was obtained under the same conditions as in Example 113 except that 6 parts of a compound represented by Formula (10-10) was changed into 3 parts of a compound represented by Formula (10-33). When the alignment properties of the obtained optically anisotropic body were evaluated, there were no defects found by visual observation and there were no defects found by observation using a polarizing microscope. Further, the obtained optically anisotropic body was transparent and a region in which the transmittance decreased was observed in the infrared region when the transmittance was measured using a spectrophotometer (manufactured by Hitachi High-Tech Science Corporation). Therefore, it was understood that the film became an infrared reflective film. Further, the retardation was measured by changing the angle of incident light from −50° to 50° by the unit of 10 using RETS-100. When the outer plane phase difference (Rth) at a wavelength of 550 nm was calculated from the obtained phase difference, the value was 130 nm, and it was understood that the film became a negative C plate.

### Example 115

An optically anisotropic body of Example 115 was obtained in the same manner as in Example 113 except that 6 parts of a compound represented by Formula (10-10) was changed into 8.5 parts of a compound represented by Formula (10-38). When the alignment properties of the obtained optically anisotropic body were evaluated, there were no defects found by visual observation and there were no defects found by observation using a polarizing microscope. Further, the obtained optically anisotropic body was transparent and a region in which the transmittance decreased was observed in the ultraviolet region when the transmittance was measured using a spectrophotometer (manufactured by Hitachi High-Tech Science Corporation). Therefore, it was understood that the film became a UV reflective film. Further, the phase difference was measured by changing the angle of incident light from −50° to 50 by the unit of 10° using RETS-100. When the outer plane phase difference (Rth) at a wavelength of 550 nm was calculated from the obtained phase difference, the value was 132 nm, and it was understood that the film became a negative C plate.

### Example 116

30 parts of a compound represented by Formula (1-6), 30 parts of a compound represented by Formula (1-7), 40 parts of a compound represented by Formula (2-a-28), and 1 part of a compound (weight-average molecular weight: 50000) represented by Formula (12-10) were added to 400 parts of cyclopentanone, heated to 40° C., and stirred so that the mixture was dissolved therein, the dissolution was confirmed, the temperature thereof was returned to room temperature, 0.3 parts of IRGACURE 907 (Irg907: manufactured by BASF SE), 0.1 parts of MEGAFACE F-554 (F-554: manufactured by DIC Corporation), and 0.1 parts of p-methoxyphenol were added thereto, and the solution was further stirred, thereby obtaining a solution. The solution was transparent and uniform. The obtained solution was filtered using a membrane filter having a pore diameter of 0.20 μm, thereby obtaining a polymerizable composition (116) of the present invention. A glass base material having a thickness of 0.7 mm was coated with the obtained polymerizable composition (116) according to a spin coating method, dried at 70° C. for 2 minutes, further dried at 100° C. for 2 minutes, and then irradiated with linearly polarized light having a wavelength of 313 nm at an intensity of 10 mW/cm² for 30 seconds. The obtained coated film was cooled to room temperature and irradiated with ultraviolet rays at an intensity of 30 mW/cm² for 30 seconds using a high-pressure mercury lamp, thereby obtaining an optically anisotropic body of Example 116. When the alignment properties of the obtained optically anisotropic body were evaluated based on the following criteria, there were no defects found by visual observation and there were no defects found by observation using a polarizing microscope. Further, when the retardation of the obtained optically anisotropic body was measured using RETS-100 (manufactured by Otsuka Electronics Co., Ltd.), the in-plane phase difference (Re (550)) at a wavelength of 550 nm was 137 nm and a retardation film with excellent uniformity was obtained.

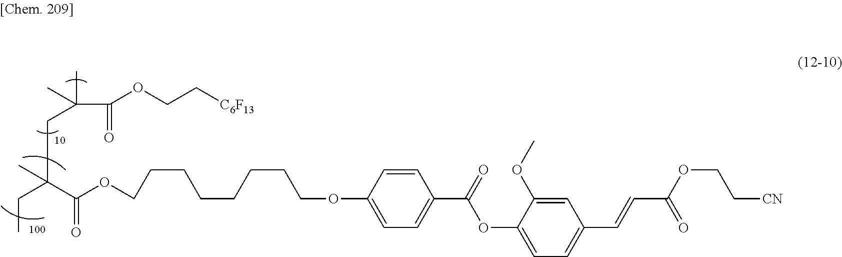

### Example 117

30 parts of a compound represented by Formula (1-6), 30 parts of a compound represented by Formula (1-7), 40 parts of a compound represented by Formula (2-a-28), and 0.6 parts of a compound (weight-average molecular weight: 100000) represented by Formula (12-4) were added to 400 parts of cyclopentanone, heated to 40° C., and stirred so that the mixture was dissolved therein, the dissolution was confirmed, the temperature thereof was returned to room temperature, 3 parts of IRGACURE 907 (Irg907: manufactured by BASF SE), 0.2 parts of MEGAFACE F-554 (F-554: manufactured by DIC Corporation), and 0.1 parts of p-methoxyphenol were added thereto, and the solution was further stirred, thereby obtaining a solution. The solution was transparent and uniform. The obtained solution was filtered using a membrane filter having a pore diameter of 0.20 μm, thereby obtaining a polymerizable composition (117) of the present invention. A glass base material having a thickness of 0.7 mm was coated with the obtained polymerizable composition (117) according to a spin coating method, dried at 60° C. for 2 minutes, further dried at 110° C. for 2 minutes, cooled to 60° C., and then irradiated with linearly polarized light having a wavelength of 313 nm at an intensity of 10 mW/cm² for 50 seconds. Thereafter, the obtained coated film was cooled to room temperature and irradiated with ultraviolet rays at an intensity of 30 mW/cm² for 30 seconds using a high-pressure mercury lamp, thereby obtaining an optically anisotropic body of Example 117. When the alignment properties of the obtained optically anisotropic body were evaluated based on the following criteria, there were no defects found by visual observation and there were no defects found by observation using a polarizing microscope. Further, when the retardation of the obtained optically anisotropic body was measured using RETS-100 (manufactured by Otsuka Electronics Co., Ltd.), the in-plane phase difference (Re (550)) at a wavelength of 550 nm was 130 nm and a retardation film with excellent uniformity was obtained.

### Example 118

30 parts of a compound represented by Formula (1-6), 30 parts of a compound represented by Formula (1-7), 40 parts of a compound represented by Formula (2-a-28), and 20 parts of a compound (weight-average molecular weight: 10000) represented by Formula (12-8) were added to 400 parts of cyclopentanone, heated to 40° C., and stirred so that the mixture was dissolved therein, the dissolution was confirmed, the temperature thereof was returned to room temperature, 3 parts of IRGACURE 907 (Irg907: manufactured by BASF SE), 0.2 parts of MEGAFACE F-554 (F-554: manufactured by DIC Corporation), and 0.1 parts of p-methoxyphenol were added thereto, and the solution was further stirred, thereby obtaining a solution. The solution was transparent and uniform. The obtained solution was filtered using a membrane filter having a pore diameter of 0.45 μm, thereby obtaining a polymerizable composition (118) of the present invention. A glass base material having a thickness of 0.7 mm was coated with the obtained polymerizable composition (118) according to a spin coating method, dried at 60° C. for 2 minutes, further dried at 110° C. for 2 minutes, cooled to 60° C., and then irradiated with linearly polarized light having a wavelength of 313 nm at an intensity of 10 mW/cm² for 100 seconds. Thereafter, the obtained coated film was cooled to room temperature and irradiated with ultraviolet rays at an intensity of 30 mW/cm² for 30 seconds using a high-pressure mercury lamp, thereby obtaining an optically anisotropic body of Example 118. When the alignment properties of the obtained optically anisotropic body were evaluated based on the following criteria, there were no defects found by visual observation and there were no defects found by observation using a polarizing microscope. Further, when the retardation of the obtained optically anisotropic body was measured using RETS-100 (manufactured by Otsuka Electronics Co., Ltd.), the in-plane phase difference (Re (550)) at a wavelength of 550 nm was 108 nm and a retardation film with excellent uniformity was obtained.

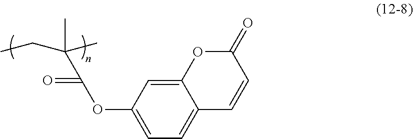

### Example 119

50 parts of a compound represented by Formula (1-7), 10 parts of a compound represented by Formula (2-a-1-a), 20 parts of a compound represented by Formula (2-b-1-a), 20 parts of a compound represented by Formula (2-b-1-b), and 6 parts of a compound represented by Formula (d-7) were added to 400 parts of cyclopentanone, heated to 60° 0, and stirred so that the mixture was dissolved therein, the dissolution was confirmed, the temperature thereof was returned to room temperature, 3 parts of IRGACURE OXE01 (manufactured by BASF SE), 0.2 parts of MEGAFACE F-554 (F-554: manufactured by DIC Corporation), 0.1 parts of p-methoxyphenol, 0.1 parts of IRGANOX 1076 (manufactured by BASF SE), and 2 parts of trimethylolpropane tris(3-mercaptopropionate) TMMP (manufactured by SC Organic Chemical Co., Ltd.) were added thereto, and the solution was further stirred, thereby obtaining a solution. The solution was uniform. The obtained solution was filtered using a membrane filter having a pore diameter of 0.5 m, thereby obtaining a polymerizable composition (119) of the present invention.

A glass base material having a thickness of 0.7 mm was coated with a polyimide solution for an alignment film according to a spin coating method, dried at 100° C. for 10 minutes, and then baked at 200° C. for 60 minutes to obtain a coated film. Thereafter, the obtained coated film was subjected to a rubbing treatment. The rubbing treatment was performed using a commercially available rubbing device.

The rubbed base material was coated with the polymerizable composition (119) of the present invention according to a spin coating method and then dried at 90° ° C. for 2 minutes. The obtained coated film was cooled to room temperature for 2 minutes and irradiated with ultraviolet rays at an intensity of 30 mW/cm² for 30 seconds using a high-pressure mercury lamp, thereby obtaining an optically anisotropic body of Example 119. When the polarization degree, the transmittance, and the contrast of the obtained optically anisotropic body were measured using RETS-100 (manufactured by Otsuka Electronics Co., Ltd.), the polarization degree was 99.0%, the transmittance was 44.5%, and the contrast was 93. Therefore, it was understood that the film functioned as a polarizing film.

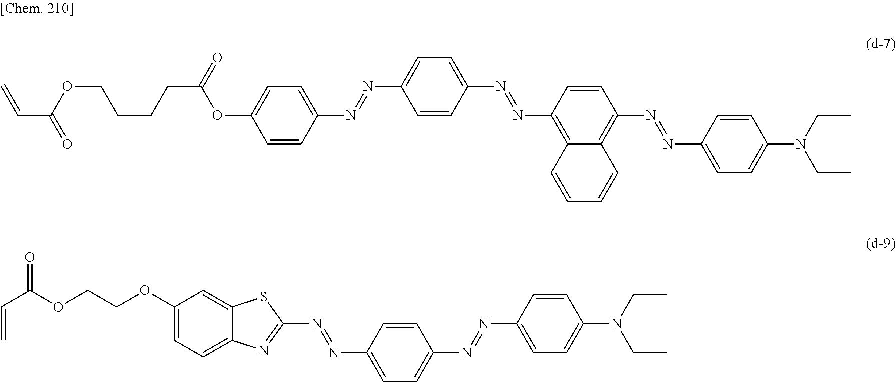 [SMILES: C=CC(=O)OCCCCC(=O)Oc1ccc(/N=N/c2ccc(/N=N/c3ccc(/N=N/c4ccc(N(CC)CC)cc4)c4ccccc34)cc2)cc1 ; C=CC(=O)OCCOc1ccc2nc(/N=N/c3ccc(/N=N/c4ccc(N(CC)CC)cc4)cc3)sc2c1]

### Example 120

An optically anisotropic body of Example 120 was obtained under the same conditions as in Example 119 except that a compound represented by Formula (d-7) was changed into a compound represented by Formula (d-9). When the polarization degree, the transmittance, and the contrast of the obtained optically anisotropic body were measured using RETS-100 (manufactured by Otsuka Electronics Co., Ltd.), the polarization degree was 98.5%, the transmittance was 44.3%, and the contrast was 91. Therefore, it was understood that the film functioned as a polarizing film.

### Example 121

40 parts of a compound represented by Formula (1-7), 40 parts of a compound represented by Formula (1-2), 10 parts of a compound represented by Formula (2-a-1-a), and 10 parts of a compound represented by Formula (2-b-1-a) were added to 100 parts of methyl ethyl ketone and 300 parts of methyl isobutyl ketone, heated to 60° C., and stirred so that the mixture was dissolved therein, the dissolution was confirmed, the temperature thereof was returned to room temperature, 3 parts of IRGACURE 907 (manufactured by BASF SE), 3 parts of Light Ester HOA(N) (manufactured by KYOEISHA CHEMICAL Co., LTD.), 0.2 parts of MEGAFACE F-554 (F-554: manufactured by DIC Corporation), 0.1 parts of p-methoxyphenol, 0.1 parts of IRGANOX 1035 (manufactured by BASE SE) were added thereto, and the solution was further stirred, thereby obtaining a solution. The solution was uniform. The obtained solution was filtered using a membrane filter having a pore diameter of 0.20 μm, thereby obtaining a polymerizable composition (121) of the present invention.

A protective film was bonded to one surface of a triacetyl cellulose (TAC) film having a thickness of 30 μm, and the other surface was subjected to a rubbing treatment using a commercially available rubbing device, coated with the polymerizable composition (121) of the present invention according to a bar coating method, and then dried at 70° C. for 2 minutes. The obtained coated film was cooled to room temperature and irradiated with ultraviolet rays at a conveyor speed of 5 n/min using a UV conveyor device (manufactured by GS Yuasa Corporation) having a lamp output of 2 kW (80 W/cm), thereby obtaining an optically anisotropic body of Example 121. When the alignment properties of the obtained optically anisotropic body were evaluated, there were no defects found by visual observation and there were no defects found by observation using a polarizing microscope. Further, when the retardation of the obtained optically anisotropic body was measured using RETS-100 (manufactured by Otsuka Electronics Co., Ltd.), the in-plane phase difference (Re (550)) at a wavelength of 550 nm was 128 nm and a retardation film with excellent uniformity was obtained.

### Examples 122 to 124

An optically anisotropic body of Example 122 was obtained under the same conditions as in Example 121 except that 3 parts of Light Ester HOA(N) was changed into 3 parts of Light Ester HOB-A (manufactured by KYOEISHA CHEMICAL Co., Ltd.). Similarly, an optically anisotropic body of Example 123 was obtained under the same conditions as in Example 121 except that 3 parts of Light Ester HOA(N) was changed into 3 parts of A-SA (manufactured by Shin-Nakamura Chemical Co., Ltd.) Similarly, an optically anisotropic body of Example 124 was obtained under the same conditions as in Example 121 except that 3 parts of Light Ester HOA(N) was changed into 2 parts of A-9300 (manufactured by Shin-Nakamura Chemical Co., Ltd.). When the alignment properties of the obtained optically anisotropic bodies of Examples 122 to 124 were evaluated, there were no defects found by visual observation and there were no defects found by observation using a polarizing microscope. Further, each of the obtained optically anisotropic bodies had a retardation and retardation films with excellent uniformity were obtained.

### Examples 125 and 126

40 parts of a compound represented by Formula (1-7), 40 parts of a compound represented by Formula (1-2), 10 parts of a compound represented by Formula (2-a-1-a), and 10 parts of a compound represented by Formula (2-b-1-a) were added to 100 parts of cyclopentanone and 300 parts of methyl isobutyl ketone, heated to 60° C., and stirred so that the mixture was dissolved therein, the dissolution was confirmed, the temperature thereof was returned to room temperature, 3 parts of IRGACURE 907 (manufactured by BASF SE), 0.2 parts of MEGAFACE F-554 (F-554: manufactured by DIC Corporation), 0.1 parts of p-methoxyphenol, 0.1 parts of TINUVIN 765, 4 parts TMMP (manufactured by SC Organic Chemical Co., Ltd.), and 0.05 parts of SANKONOL A600-50R (manufactured by Sanko Chemical Co., Ltd.) were added thereto, and the solution was further stirred, thereby obtaining a solution. The solution was uniform. The obtained solution was filtered using a membrane filter having a pore diameter of 0.20 μm, thereby obtaining a polymerizable composition (125) of the present invention. An optically anisotropic body of Example 125 was obtained under the same conditions as in Example 121 using the polymerizable composition (125).

Further, 40 parts of a compound represented by Formula (1-7), 40 parts of a compound represented by Formula (1-2), 10 parts of a compound represented by Formula (2-a-11), and 10 parts of a compound represented by Formula (2-b-11) were added to 100 parts of methyl ethyl ketone and 300 parts of methyl isobutyl ketone, heated to 60° C., and stirred so that the mixture was dissolved therein, the dissolution was confirmed, the temperature thereof was returned to room temperature, 3 parts of IRGACURE 907 (manufactured by BASF SE), 0.2 parts of MEGAFACE F-554 (manufactured by DIC Corporation), 0.1 parts of p-methoxyphenol, 0.1 parts of TINUVIN 765, 4 parts tetraethylene glycol bis(3-mercaptopropionate), and 0.05 parts of SANKONOL A600-5OR (manufactured by Sanko Chemical Co., Ltd.) were added thereto, and the solution was further stirred, thereby obtaining a solution. The solution was uniform. The obtained solution was filtered using a membrane filter having a pore diameter of 0.20 μm, thereby obtaining a polymerizable composition (126) of the present invention. An optically anisotropic body of Example 126 was obtained under the same conditions as in Example 121 using the polymerizable composition (126).

When the alignment properties of the obtained optically anisotropic bodies of Examples 125 and 126 were evaluated, there were no defects found by visual observation and there were no defects found by observation using a polarizing microscope. Further, each of the obtained optically anisotropic bodies had a retardation and retardation films with excellent uniformity were obtained.

### Example 127

3 parts of a compound represented by Formula (1-6), 3 parts of a compound represented by Formula (1-7), 3 parts of a compound represented by Formula (2-b-1-a), and 1 part of a compound represented by Formula (2-b-1-b) were added to 40 parts of cyclopentanone, heated to 60° C., and stirred so that the mixture was dissolved therein, the dissolution was confirmed, the temperature thereof was returned to room temperature, 0.5 parts of IRGACURE OXE01 (manufactured by BASF SE), 0.01 parts of p-methoxyphenol, 0.02 parts of MEGAFACE F-554 (F-554: manufactured by DIC Corporation), 0.01 parts IRGANOX 1076 (manufactured by BASF SE), 0.4 parts of TMMP (manufactured by SC Organic Chemical Co., Ltd.), 0.01 parts of TINUVIN 765 (manufactured by BASF SE), 8 parts of alumina particles AA-04 (manufactured by Sumitomo Chemical Company, Limited), and 38 parts of boron nitride particles HP-40 (manufactured by MIZUSHIMA FERROALLOY CO., LTD.) were added thereto, and the solution was further stirred and mixed, thereby obtaining a polymerizable composition (127) of the present invention. A PET film having a thickness of 180 μm was coated with the obtained polymerizable composition using an applicator, dried at 40° C. for 5 minutes, and further dried at 110° C. for 5 minutes. The obtained coated film was irradiated with ultraviolet rays at a conveyor speed of 3 m/min using a UV conveyor device (manufactured by GS Yuasa Corporation) having a lamp output of 2 kW (80 W/cm), thereby obtaining a polymer. The obtained polymer was peeled off from the PET film, interposed between two sheets of copper foil such that each mat surface of the copper foil faced a semi-cured epoxy resin composition, subjected to vacuum thermocompression bonding using a vacuum press machine under a pressing temperature condition of 200° C. at a vacuum degree of 1 kPa and at a pressing pressure of 4 MPa for a pressing time of 5 minutes, and then thermally cured. Thereafter, the resultant was heated at 230° C. for 1 hour under atmospheric pressure, thereby obtaining a polymer of Example 127.

Next, the copper foil of the obtained polymer was removed by etching and then a polymer film having a thickness of 50 μm was obtained. The polymer film was subjected to a blackening treatment by spraying graphite, the thermal diffusivity thereof was measured according to a xenon flash method (LFA447 nanoflash, manufactured by NETZSCH Japan K.K.), and then the thermal conductivity of the polymer film was acquired from the product of the thermal diffusivity, the density measured according to an Archimedes method, and the specific heat measured using DSC (DSC Pyrisl, manufactured by Perkin Elmer, Inc.). The thermal conductivity was 20.1 W/mK.

When the thermal conductivity of the polymerizable composition portion in the polymer film was acquired by conversion from the thermal conductivity of the obtained polymer film using the following equation, the value was 0.53 W/mK. Further, the thermal conductivity of the resin portion in the polymer film indicates a value obtained by removing the amount of contribution of a filler portion from the thermal conductivity of the polymer film.

1−ν=[(λmix−λres)/(λres−λfil)]×(λres/λmix)x

(here, x=1/(1+χ))

λmix: thermal conductivity (W/mK) of resin sheet

λres: thermal conductivity (W/mK) of resin portion in resin sheet

λfil: thermal conductivity (W/mK) of filler portion in resin sheet (the value was set to 30 in case of alumina and the value was set to 60 in case of boron nitride)

ν: volume fraction of filler (% by volume)

χ: shape parameter of filler (the value was set to 2.2 in case of alumina and the value was set to 2.2 in case of aluminum nitride)

For comparison with the polymerizable composition of the present invention, a polymerizable composition was prepared by removing 8 parts of alumina particles AA-04 (manufactured by Sumitomo Chemical Company, Limited) and 38 parts of boron nitride particles HP-40 (manufactured by MIZUSHIMA FERROALLOY CO., LTD.) from the polymerizable composition (127) of the present invention. A PET film having a thickness of 180 μm was coated with the obtained polymerizable composition using an applicator, dried at 40° C. for 5 minutes, and further dried at 110° C. for 5 minutes. The obtained coated film was irradiated with ultraviolet rays at a conveyor speed of 3 m/min using a UV conveyor device (manufactured by GS Yuasa Corporation) having a lamp output of 2 kW (80 W/cm), thereby obtaining a polymer. The obtained polymer was peeled off from the PET film, interposed between two sheets of copper foil such that each mat surface of the copper foil faced a semi-cured epoxy resin composition, subjected to vacuum thermocompression bonding using a vacuum press machine under a pressing temperature condition of 200° C. at a vacuum degree of 1 kPa and at a pressing pressure of 4 MPa for a pressing time of 5 minutes, and then thermally cured. Thereafter, the resultant was heated at 230° C. for 1 hour under atmospheric pressure, thereby obtaining a polymer. Next, the copper foil of the obtained polymer was removed by etching and then a polymer film having a thickness of 50 μm was obtained. The thermal diffusivity of the obtained polymer film was measured using a temperature wave thermal analyzer (ai-Phase mobile 1u, manufactured by ai-Phase Co., Ltd.). When the thermal conductivity of the polymer film without a filler was acquired from the product of the obtained thermal diffusivity, the density acquired according to the method described above, and the specific heat, the value was 0.43 W/mK.

It was understood that the thermal conductivity was high in all cases. In a semiconductor module in which a heat radiation base substrate, an adhesive layer, a metal plate, a solder layer, and a semiconductor are laminated in this order, the polymer sheet can be used as a heat radiation adhesive layer between the metal plate and the heat radiation base substrate.

### (Example 128) Liquid Crystal Display Element

30 parts of a compound represented by Formula (1-6), 30 parts of a compound represented by Formula (1-7), 10 parts of a compound represented by Formula (1-109), 20 parts of a compound represented by Formula (2-a-1-a), and 10 parts of a compound represented by Formula (2-b-1-b) were added to 400 parts of cyclopentanone, heated to 60° C., and stirred so that the mixture was dispersed and dissolved therein, the dispersion and dissolution were confirmed, the temperature thereof was returned to room temperature, 3 parts of IRGACURE 907 (manufactured by BASF SE), 0.2 parts of MEGAFACE F-554 (manufactured by DIC Corporation), 0.1 parts of p-methoxyphenol, 0.1 parts IRGANOX 1076 (manufactured by BASF SE) were added thereto, and the solution was further stirred, thereby obtaining a solution. The solution was uniform. The obtained solution was filtered using a membrane filter having a pore diameter of 0.20 μm, thereby obtaining a polymerizable composition (128) of the present invention.

Next, a base material obtained by forming a color filter layer on a glass base material RAGLE-XG (manufactured by Corning Incorporated) having a thickness of 0.7 mm was coated with a polyimide solution for an alignment film according to a spin coating method, dried at 100° C. for 10 minutes, and then baked at 200° C. for 60 minutes to obtain a coated film. Thereafter, the obtained coated film was subjected to a rubbing treatment. The rubbing treatment was performed using a commercially available rubbing device. Next, the obtained coated film was coated with the polymerizable composition (128) of the present invention according to a spin coating method and dried at 80° for 2 minutes. The obtained coated film was cooled to room temperature for 2 minutes and irradiated with ultraviolet rays at an intensity of 30 mW/cm for 30 seconds using a high-pressure mercury lamp, thereby obtaining a positive A plate. The positive A plate was coated with the polymerizable composition ( ) of the present invention according to a spin coating method and dried at 80° C. for 2 minutes. The obtained coated film was cooled to room temperature for 2 minutes and irradiated with ultraviolet rays at an intensity of 30 mW/cm² for 30 seconds using a high-pressure mercury lamp, thereby obtaining a negative C plate.

A transparent electrode layer having a thickness of 100 nm was formed on the obtained color filter layer retardation layer using a sputtering device. Further, an alignment film was formed on the transparent electrode layer. The film was coated with a polyimide solution for vertical alignment according to a spin coating method, dried, and then baked at 220° C. for 1 hour, thereby obtaining a polyimide film having a thickness of 100 nm.

Further, similar to the case described above, a transparent electrode layer was formed on another glass base material RAGLE-XG (manufactured by Corning Incorporated) using a sputtering device. A vertically aligned film formed of a polyimide film was formed on the transparent electrode layer under the conditions described above.

Next, the periphery of the edge of the alignment film substrate including only a transparent electrode layer was coated with a UV curable sealant containing 0.5% by mass of a spacer having a particle diameter of 4 μm using a dispenser (manufactured by MUSASHI ENGINEERING, INC.) such that the periphery was enclosed by the sealant, an appropriate amount of a liquid crystal composition (manufactured by DIC Corporation) having negative dielectric characteristics was added dropwise to the inside of the enclosure so as to be bonded with the base material provided with a color filter layer. Thereafter, only the sealant portion was irradiated with ultraviolet rays at an intensity of 10 mWcm² for 60 seconds using a high-pressure mercury lamp, thereby obtaining a liquid crystal display element of the present invention. When the obtained liquid crystal display element was placed between polarizing plates disposed in a cross-nicol alignment and then observed from the front and in an oblique direction at an angle of 450 with respect to the liquid crystal display element, it was confirmed that there was no light leakage and a uniform display was obtained.

### Example 129

A base material obtained by forming a color filter layer on a glass base material RAGLE-XG (manufactured by Corning Incorporated) having a thickness of 0.7 mm was coated with a polyimide solution for an alignment film according to a spin coating method, dried at 100° C. for 10 minutes, and then baked at 200° C. for 60 minutes to obtain a coated film. Thereafter, the obtained coated film was subjected to a rubbing treatment. The rubbing treatment was performed using a commercially available rubbing device. Next, the obtained coated film was coated with the polymerizable composition (128) of the present invention according to a spin coating method and dried at 80° C. for 2 minutes. The obtained coated film was cooled to room temperature for 2 minutes and irradiated with ultraviolet rays at an intensity of 30 mW/cm² for 30 seconds using a high-pressure mercury lamp, thereby obtaining a positive A plate.

Further, similar to the case described above, a transparent electrode layer was formed on another glass base material RAGLE-XG (manufactured by Corning Incorporated) using a sputtering device. A horizontally aligned film formed of a polyimide film was formed on the transparent electrode layer under the conditions described above.

Next, the periphery of the edge of the alignment film substrate including only a transparent electrode layer was coated with a UV curable sealant containing 0.5% by mass of a spacer having a particle diameter of 4 μm using a dispenser (manufactured by MUSASHI ENGINEERING, INC.) such that the periphery was enclosed by the sealant, an appropriate amount of a liquid crystal composition (manufactured by DIC Corporation) having positive dielectric characteristics was added dropwise to the inside of the enclosure so as to be bonded with the base material provided with a color filter layer. Thereafter, only the sealant portion was irradiated with ultraviolet rays at an intensity of 10 mWcm² for 60 seconds using a high-pressure mercury lamp, thereby obtaining a liquid crystal cell of the present invention. The glass surface on the color filter layer side of the obtained liquid crystal cell was coated with UCL-018-30 (manufactured by DIC Corporation) according to a spin coating method, dried at 60° C. for 3 minutes, maintained at room temperature for 3 minutes, and then irradiated with ultraviolet rays at an intensity of 30 mW/cm for 30 seconds using a high-pressure mercury lamp, thereby obtaining a positive C plate. When the obtained liquid crystal display element was placed between polarizing plates disposed in a cross-nicol alignment and then observed from the front and in an oblique direction at an angle of 45 with respect to the liquid crystal display element, it was confirmed that there was no light leakage and a uniform display was obtained.

### (Example 130) Anti-Reflective Film: Organic Light-Emitting Element

10 parts of a compound represented by Formula (1-6), 50 parts of a compound represented by Formula (1-7), 10 parts of a compound represented by Formula (1-109), 20 parts of a compound represented by Formula (2-a-1-a), and 10 parts of a compound represented by Formula (2-b-1-b) were added to 200 parts of methyl ethyl ketone and 200 parts of methyl isobutyl ketone, heated to 60° C., and stirred so that the mixture was dispersed and dissolved therein, the dispersion and dissolution were confirmed, the temperature thereof was returned to room temperature, 3 parts of IRGACURE 907 (manufactured by BASF SE), 0.2 parts of MEGAFACE F-554 (manufactured by DIC Corporation), 0.1 parts of p-methoxyphenol, 0.1 parts IRGANOX 1076 (manufactured by BASF SE) were added thereto, and the solution was further stirred, thereby obtaining a solution. The solution was uniform. The obtained solution was filtered using a membrane filter having a pore diameter of 0.20 μm, thereby obtaining a polymerizable composition (130) of the present invention.

A PET film having a thickness of 180 μm was subjected to a rubbing treatment using a commercially available rubbing device, coated with the polymerizable composition (130) of the present invention according to a bar coating method, and then dried at 80° C. for 2 minutes. The obtained coated film was cooled to room temperature and irradiated with ultraviolet rays at a conveyor speed of 5 m/min using a UV conveyor device (manufactured by GS Yuasa Corporation) having a lamp output of 2 kW, thereby obtaining an optically anisotropic body. The retardation (Re (550)) of the obtained optically anisotropic body was 137 nm and the ratio Re (450)/Re (550) of the in-plane retardation (Re (450)) to the in-plane retardation Re (550) at a wavelength of 450 nm was 0.821 and a retardation film with excellent uniformity was obtained.

Next, a polyvinyl alcohol film having an average polymerization degree of approximately 2400, a saponification degree of 99.9% by mole or greater, and a thickness of 75 μm was uniaxially stretched to approximately 5.5 times in a dry time, immersed in pure water at 60° C. for 60 seconds, and then immersed in an aqueous solution, in which the weight ratio of iodine/potassium iodide/water was 0.05/5/100, at 2830 for 20 seconds. Thereafter, the film was immersed in an aqueous solution, in which the weight ratio of potassium iodide/boric acid/water was 3.5/8.5/100, at 72° C. for 300 seconds. Next, the resulting film was washed with pure water at 26° C. for 20 seconds and dried at 65° C., thereby obtaining a polarizing film in which iodine was adsorbed and aligned in a polyvinyl alcohol resin.

The both surfaces of the obtained polarizer in the manner were protected by a triacetyl cellulose film [KC8UX2MW, manufactured by KONICA MINOLTA, INC.] on which a saponification treatment was performed through a polyvinyl alcohol-based adhesive prepared from 3 parts of carboxyl group-modified polyvinyl alcohol [KURARAY POVAL KL318, manufactured by KURARAY CO., LTD.] and 1.5 parts of a water-soluble polyamide epoxy resin [SUMIREZ RESIN 650, manufactured by Sumika Chemtex Co., Ltd. (aqueous solution having a solid content concentration of 30%)], thereby preparing a polarizing film.

The obtained polarizing film and the retardation film were bonded to each other through an adhesive such that the angle between the polarizing axis of the polarizing film and the slow axis of the retardation film was 45° C., thereby obtaining an anti-reflective film of the present invention. Further, the obtained anti-reflective film and an aluminum plate used as a substitute for an organic light-emitting element were bonded to each other through an adhesive. When the reflection visibility from the aluminum plate was confirmed by visual observation from the front and in an oblique direction at an angle of 45°, transfer from the aluminum plate was not observed.

### Example 131

A stretched cycloolefin polymer film “ZEONOR” (manufactured by ZEON CORPORATION) having a thickness of 40 μm was subjected to a rubbing treatment using a commercially available rubbing device, coated with the polymerizable composition (119) of the present invention according to a bar coating method and then dried at 80° C. for 2 minutes, and then irradiated with ultraviolet rays at a conveyor speed of 5 m/min using a UV conveyor device (manufactured by GS Yuasa Corporation) having a lamp output of 2 kW, thereby obtaining a polarizing film.

Next, the obtained polarizing film was coated with a photo-alignment solution (1) according to a bar coating method, dried at 80° C., and irradiated with ultraviolet rays at an intensity of 10 mW/cm² for 30 seconds such that the angle between the polarizing axis of the polarizing film and the polarizing axis of the linearly polarized light having a wavelength of 313 nm was set to 45°, thereby forming a photo-alignment film. The photo-alignment film was coated with the polymerizable composition (130) of the present invention according to a bar coating method and dried at 80′C for 2 minutes, the obtained coated film was cooled to room temperature and irradiated with ultraviolet rays at a conveyor speed of 5 m/min using a UV conveyor device (manufactured by GS Yuasa Corporation) having a lamp output of 2 kW, thereby obtaining an anti-reflective film of the present invention. Further, the obtained anti-reflective film and an aluminum plate used as a substitute for an organic light-emitting element were bonded to each other through an adhesive. When the reflection visibility from the aluminum plate was confirmed by visual observation, transfer from the aluminum plate was not observed.

(Preparation of Polymerizable Composition (132))

20 parts of a compound represented by Formula (1-6), 30 parts of a compound represented by Formula (1-117), and 50 parts of a compound represented by Formula (2-a-43) were added to 300 parts of toluene (TOL) and 100 parts of methyl ethyl ketone (MEK), heated to 70° C., and stirred so that the mixture was dissolved therein, the dissolution was confirmed, the temperature thereof was returned to room temperature, 5 parts of IRGACURE 907 (Irg97: manufactured by BASF SE), 0.2 parts of MEGAFACE F-554 (F-554: manufactured by DIC Corporation), and 0.1 parts of p-methoxyphenol (MEHQ) were added thereto, and the solution was further stirred, thereby obtaining a solution. The solution was transparent and uniform. The obtained solution was filtered using a membrane filter having a pore diameter of 0.20 μm, thereby obtaining a polymerizable composition (132) used in Example 1 and the like.

(Preparation of Polymerizable Compositions (133) to (141))

Polymerizable compositions (133) to (141) used in Examples 133 to 151 and the like were obtained under the same conditions as the conditions for preparation of the polymerizable composition (132) used in Example 132 and the like except that the proportions of respective compounds listed in the following table were changed as listed in the following table.

TABLE 9

| | Composition | | | | | | | | | |
|---|---|---|---|---|---|---|---|---|---|---|
| | (132) | (133) | (134) | (135) | (136) | (137) | (138) | (139) | (140) | (141) |
| 1-6 | 20 | | | 25 | | 30 | | | | |
| 1-7 | | | | 25 | | | | | | |
| 1-117 | 30 | | | | 50 | | 50 | | 20 | |
| 1-124 | | 30 | | | | 30 | | 25 | 50 | 35 |
| 1-126 | | | 30 | | 20 | | | 25 | | 35 |
| 2-a-1-a | | | | 50 | | 20 | | | | |
| 2-a-43 | 50 | | | | | | 50 | | | |
| 2-a-59 | | 50 | 50 | | 30 | | | 25 | 20 | 10 |
| 2-a-60 | | 20 | 20 | | | 20 | | 25 | | 20 |
| 2-b-1-a | | | | | | | | | 10 | |
| 10-10 | | | | | | | | | 6 | |
| 10-33 | | | | | | | | | | 5 |
| Irg907 | 5 | 5 | 5 | 5 | 5 | 5 | 5 | 5 | 3 | 3 |
| MEHQ | 0.1 | 0.1 | 0.1 | 0.1 | 0.1 | 0.1 | 0.1 | 0.1 | 0.1 | 0.1 |
| F-554 | 0.2 | 0.2 | 0.2 | 0.03 | 0.03 | 0.03 | 0.03 | 0.03 | | |
| PP | | | | | | | | | 0.2 | 0.2 |
| CPN | | | | | | | | | 200 | 200 |
| MEK | 100 | 100 | 100 | 100 | 100 | 100 | 100 | 100 | 200 | 200 |
| TOL | 300 | 300 | 300 | 300 | 300 | 300 | 300 | 300 | | |

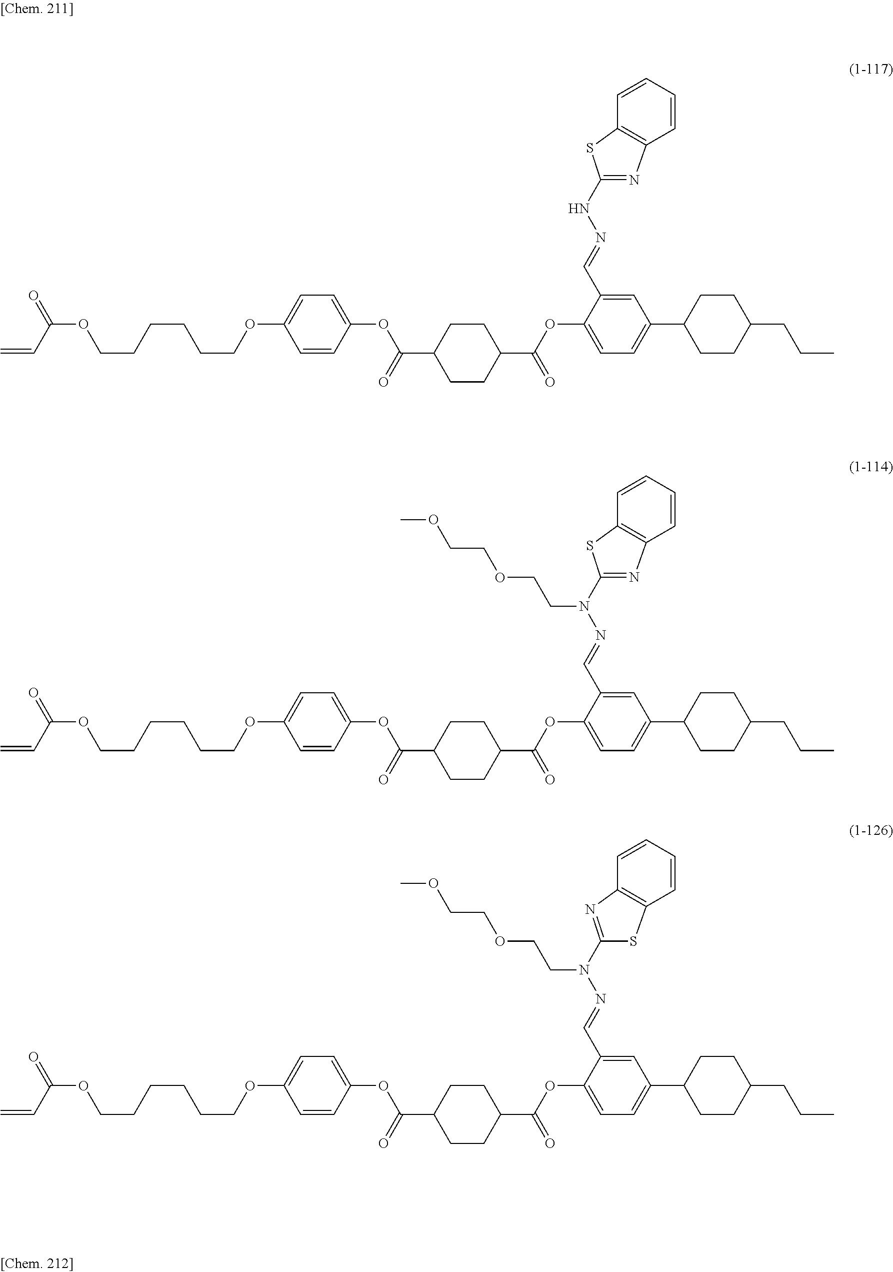

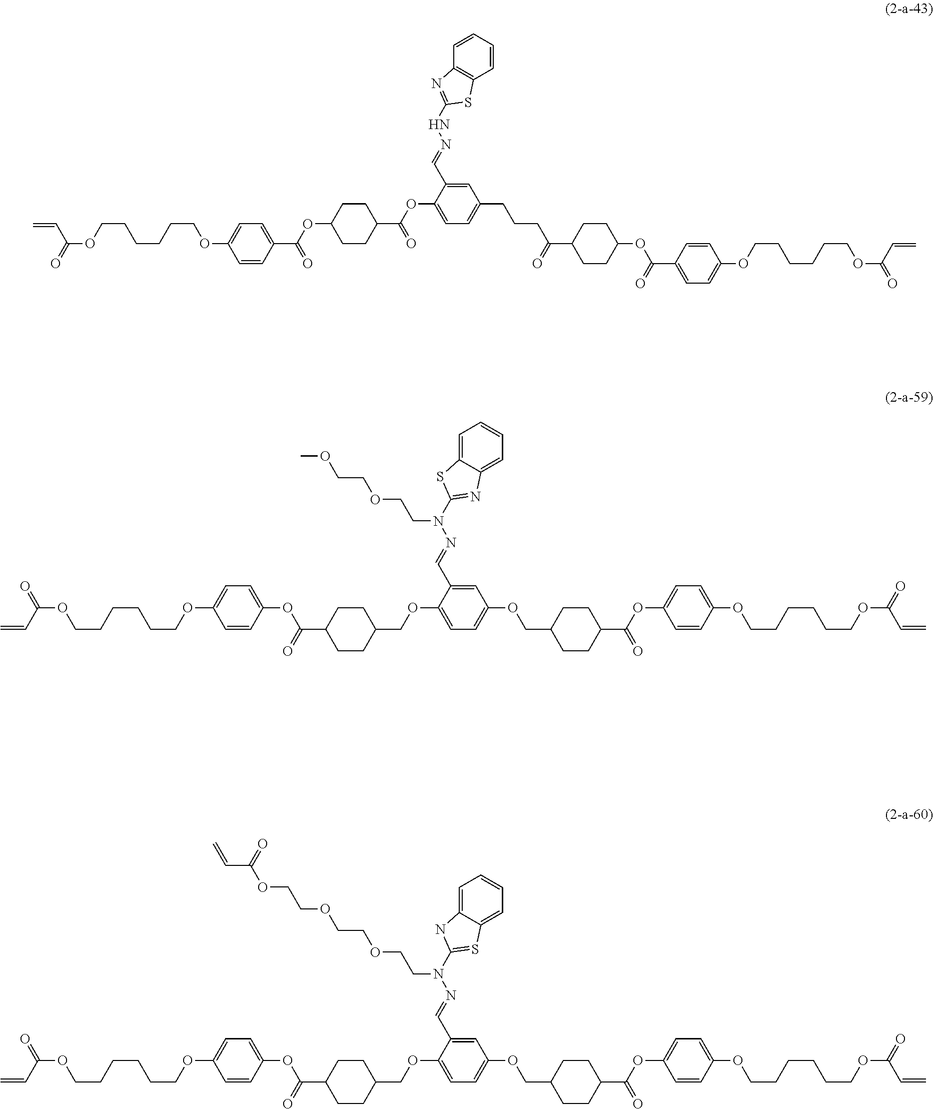

Re (450 nm)/Re (550 nm) of the compounds represented by Formulae (i-117), (1-124), and (1-126) are respectively 0.664, 0.769, and 0.749.

Re (450 nm)/Re (550 nm) of the compounds represented by Formulae (2-a-43), (2-a-59), and (2-a-60) are respectively 0.806, 0.723, and 0.823.

### Examples 132 to 141

(Solubility)

The solubility and the storage stability (storability) of the polymerizable compositions (132) to (141) of the present invention were evaluated based on the following evaluation criteria.

(Solubility)

A: After the preparation, the state of the polymerizable composition of being transparent and uniform was able to be visually confirmed.

B: The state of the polymerizable composition of being transparent and uniform was able to be visually confirmed when the composition was heated and stirred, but precipitation of the compound was confirmed when the temperature was returned to room temperature.

C: The compound was not able to be uniformly dissolved even when heated and stirred.

(Storage Stability)

The states of the polymerizable composition (132) to (141) of the present invention after the polymerizable compositions were allowed to stand for 3 days at room temperature were visually observed. The states of the polymerizable compositions of the present invention of being transparent and uniform were maintained even after 3 days. The evaluation of the storage stability was performed based on the following evaluation criteria.

A: The state of being transparent and uniform was maintained after the composition was allowed to stand at room temperature for 3 days.

B: The state of being transparent and uniform was maintained after the composition was allowed to stand at room temperature for 1 day.

C: The precipitation of the compound was confirmed after the composition was allowed to stand at room temperature for 1 hour.

TABLE 10

| | | | | Alignment | Retardation |
|---|---|---|---|---|---|
| | Composition | Solubility | Storability | properties | ratio |
| Example 132, Example 142 | Composition (132) | A | A | A | 0.848 |
| Example 133, Example 143 | Composition (133) | A | A | A | 0.826 |
| Example 134, Example 144 | Composition (134) | A | A | A | 0.837 |
| Example 135, Example 145 | Composition (135) | A | A | A | 0.861 |
| Example 136, Example 146 | Composition (136) | A | A | A | 0.814 |
| Example 137, Example 147 | Composition (137) | A | A | A | 0.823 |
| Example 138, Example 148 | Composition (138) | A | A | A | 0.826 |
| Example 139, Example 149 | Composition (139) | A | A | A | 0.843 |
| Example 140 | Composition (140) | A | A | A | — |
| Example 141 | Composition (141) | A | A | A | — |

### Example 142

A glass base material having a thickness of 0.7 mm was coated with a de solution for an alignment film according to a spin coating method, dried at 100° C. for 10 minutes, and then baked at 200° C. for 60 minutes to obtain a coated film. Thereafter, the obtained coated film was subjected to a rubbing treatment. The rubbing treatment was performed using a commercially available rubbing device.

The rubbed base material was coated with the polymerizable composition (132) of the present invention according to a spin coating method and then dried at 90° C. for 2 minutes. The obtained coated film was cooled to room temperature and irradiated with ultraviolet rays at an intensity of 30 mW/cm² for 30 seconds using a high-pressure mercury lamp, thereby obtaining an optically anisotropic body of Example 142. When the obtained optically anisotropic body was evaluated based on the following criteria, there were no defects found by visual observation and there were no defects found by observation using a polarizing microscope. In the following criteria, “A” indicates that the alignment properties were most excellent and “C” indicates that the alignment properties were not exhibited at all.

(Alignment Properties)

A: There were no defects found by visual observation and there were no defects found by observation using a polarizing microscope.

B: There were no defects found by visual observation, but non-aligned portions were present in the entire composition when the observation was made using a polarizing microscope.

C: There were defects found in the entire composition by visual observation.

The obtained results are listed in the table.

(Retardation Ratio)

When the retardation of the obtained optically anisotropic body was measured using a retardation film and optical material inspection device RETS-100 (manufactured by Otsuka Electronics Co., Ltd.), the in-plane retardation (Re (550)) at a wavelength of 550 nm was 130 nm. Further, the ratio Re (450)/Re (550) of the in-plane retardation (Re (450)) to the in-plane retardation Re (550) at a wavelength of 450 nm was 0.848 and a retardation film with excellent uniformity was obtained.

### Examples 143 and 144

Optically anisotropic bodies of Examples 143 and 144 were obtained under the same conditions as in Example 142 except that the polymerizable compositions to be used were changed into the polymerizable compositions (133) to (134) of the present invention.

### Example 145

A glass base material having a thickness of 0.7 mm was coated with a polyimide solution for vertical alignment according to a spin coating method, dried at 100° C. for 10 minutes, and then baked at 200° C. for 60 minutes to obtain a coated film.

The base material was coated with the polymerizable composition (135) of the present invention according to a spin coating method and then dried at 90′C for 2 minutes. The obtained coated film was cooled to room temperature and irradiated with ultraviolet rays at an intensity of 30 mW/cm² for 30 seconds using a high-pressure mercury lamp, thereby obtaining an optically anisotropic body of Example 145. When the obtained optically anisotropic body was evaluated in the same manner as in Example 142, there were no defects found by visual observation and there were no defects found by observation using a polarizing microscope.

(Retardation Ratio)

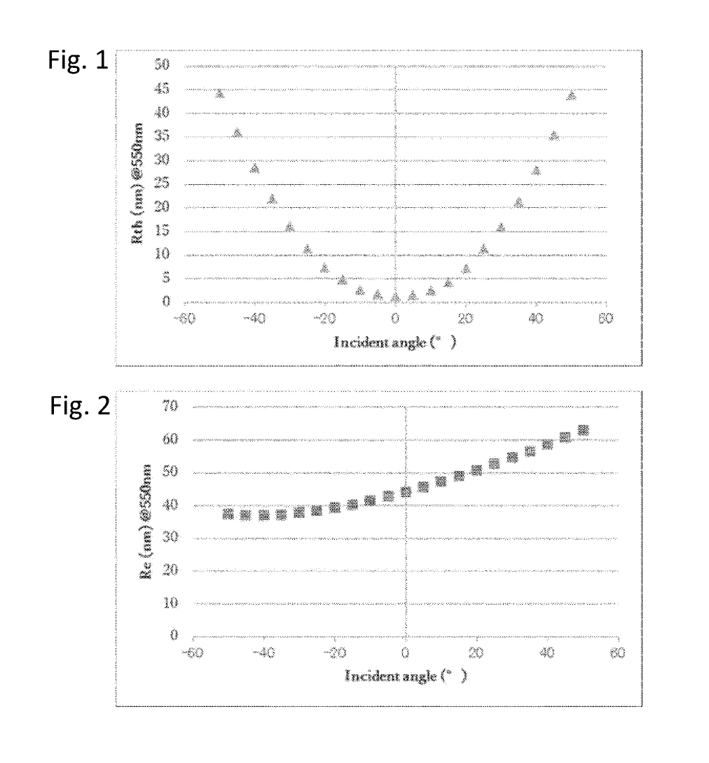

Further, when the retardation of the obtained optically anisotropic body and the incident angle dependence of the retardation were measured using a retardation film and optical material inspection device RETS-100 (manufactured by Otsuka Electronics Co., Ltd.), the outer retardation (Rth (550)) at a wavelength of 550 nm was 160 nm. Further, the ratio Rth (450)/Rth (550) of the outer retardation (Rth (450)) to the outer retardation Rth (550) at a wavelength of 450 nm was 0.861 and a vertically aligned retardation film (positive C plate) with excellent uniformity was obtained. Further, the in-plane retardation (RE(550)) was 0 nm (FIG. 1).

### Examples 146 and 147

Optically anisotropic bodies of Examples 146 and 147 were obtained under the same conditions as in Example 145 except that the polymerizable compositions to be used were changed into the polymerizable compositions (136) and (137) of the present invention.

### Examples 148 and 149

Optically anisotropic bodies of Examples 148 and 149 were obtained under the same conditions as in Example 142 except that the polymerizabie compositions to be used were changed into the polymerizable compositions (138) and (139) of the present invention. When the obtained optically anisotropic body was evaluated based on the following criteria, there were no defects found by visual observation and there were no defects found by observation using a polarizing microscope.

(Retardation Ratio)

Further, when the retardation of the obtained optically anisotropic body and the incident angle dependence of the retardation were measured using a retardation film and optical material inspection device RETS-100 (manufactured by Otsuka Electronics Co., Ltd.), the in-plane retardation (Re (550)) at a wavelength of 550 nm in a case of Example 148 was 44 nm and the in-plane retardation (Re (550)) in a case of Example 149 was 60 nm (FIG. 2). Further, the ratio Re (450)/Re (550) of the in-plane retardation (Re (450)) to the in-plane retardation Re (550) at a wavelength of 450 nm was 0.826 and a hybrid-aligned retardation film (positive 0 plate) with excellent uniformity was obtained.

### Examples 150 and 151

Optically anisotropic bodies of Examples 150 and 151 were obtained under the same conditions as in Example 142 except that the polymerizable compositions to be used were changed into the polymerizable compositions (140) and (141) of the present invention. When the obtained optically anisotropic body were evaluated based on the following criteria, there were no defects found by visual observation and there were no defects found by observation using a polarizing microscope. In addition, the obtained optically anisotropic body appeared to be green and it was understood that the film became a reflective film.

1. A polymerizable composition comprising:
a polymerizable compound (a) represented by General Formula (1);
a polymerizable compound (b) which contains at least two or more polymerizable groups;
an initiator (c) as necessary; and
a solvent (d) as necessary: 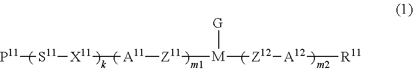
wherein P¹¹ represents a polymerizable group,
S¹¹ represents a spacer group or a single bond, and in a case where a plurality of S¹¹ is present, these may be the same as or different from each other;
X¹¹ represents —O—, —S—, —OCH₂—, —CH₂O—, —CO—, —COO—, —OCO—, —CO—S—, —S—CO—, —O—CO—O—, —CO—NH—, —NH—CO—, —SCH₂—, —CH₂S—, —CF₂O—, —OCF₂—, —CF₂S—, —SCF₂—, —CH═CH—COO—, —CH═CH—OCO—, —COO—CH═CH—, —OCO—CH═CH—, —COO—CH₂CH₂—, —OCO—CH₂CH₂—, —CH₂CH₂—COO—, —CH₂CH₂—OCO—, —COO—CH₂—, —OCO—CH₂—, —CH₂—COO—, —CH₂—OCO—, —CH═CH—, —N═N—, —CH═N—N═CH—, —CF═CF—, —C≡C—, or a single bond, and in a case where a plurality of X¹¹ is present, these may be the same as or different from each other, provided that P¹¹—(S¹¹—X¹¹)ₖ— does not have a —O—O— bond;
A¹¹ and A¹² each independently represent a 1,4-phenylene group, a 1,4-cyclohexylene group, a pyridine-2,5-diyl group, a pyrimidine-2,5-diyl group, a naphthalene-2,6-diyl group, a naphthalene-1,4-diyl group, a tetrahydronaphthalene-2,6-diyl group, a decahydronaphthalene-2,6-diyl group, or a 1,3-dioxane-2,5-diyl group, these groups may be unsubstituted or substituted with one or more of L¹'s, and in a case where a plurality of each of A¹¹ and A¹² is present, these may be the same as or different from each other;
Z¹¹ and Z¹² each independently represent —O—, —S—, —OCH₂—, —CH₂O—, —CH₂CH₂—, —CO—, —COO—, —OCO—, —CO—S—, —S—CO—, —O—CO—O—, —CO—NH—, —NH—CO—, —OCO—NH—, —NH—COO—, —NH—CO—NH—, —NH—O—, —O—NH—, —SCH₂—, —CH₂S—, —CF₂O—, —OCF₂—, —CF₂S—, —SCF₂—, —CH═CH—COO—, —CH═CH—OCO—, —COO—CH═CH—, —OCO—CH═CH—, —COO—CH₂CH₂—, —OCO—CH₂CH₂—, —CH₂CH₂—COO—, —CH₂CH₂—OCO—, —COO—CH₂—, —OCO—CH₂—, —CH₂—COO—, —CH₂—OCO—, —CH═CH—, —N═N—, —CH═N—, —N═CH—, —CH═N—N═CH—, —CF═CF—, —C≡C—, or a single bond, and in a case where a plurality of each of Z¹¹ and Z¹² is present, these may be the same as or different from each other;
k represents an integer of 0 to 8;
m1 and m2 each independently represent an integer of 0 to 5, provided that m1+m2 represents an integer of 1 to 5;
M represents a group selected from groups represented by Formula (M-1) to Formula (M-8), which may be unsubstituted or substituted with one or more of L¹'s: 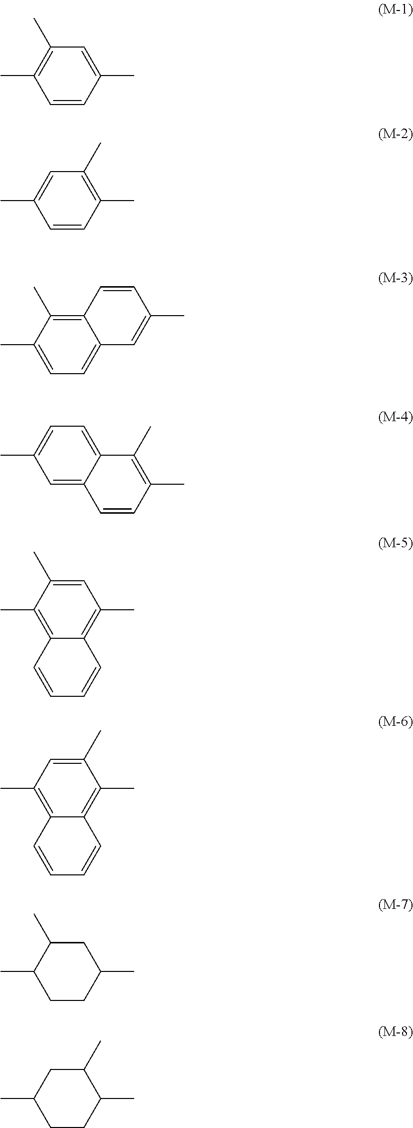
R¹¹ represents a hydrogen atom, a fluorine atom, a chlorine atom, a bromine atom, an iodine atom, a pentafluorosulfuranyl group, a cyano group, a nitro group, an isocyano group, a thioisocyano group, or a, linear or branched alkyl group having 1 to 20 carbon atoms in which one —CH₂— or two or more (—CH₂—)'s which are not adjacent to each other may be each independently substituted with —O—, —S—, —CO—, —COO—, —OCO—, —CO—S—, —S—CO—, —O—CO—O—, —CO—NH—, —NH—CO—, or —C≡C—, and one or more of arbitrary hydrogen atoms in the alkyl group may be substituted with a fluorine atom;
G represents a group selected from groups represented by Formula (G-1) or (G-2): 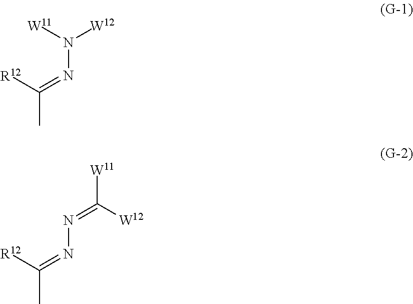
(wherein R¹² represents a hydrogen atom or a linear or branched alkyl group having 1 to 20 carbon atoms in which one —CH₂— or two or more (—CH₂—)'s which are not adjacent to each other may be each independently substituted with —O—, —S—, —CO—, —COO—, —OCO—, —CO—S—, —S—CO—, —O—CO—O—, —CO—NH—, —NH—CO—, or —C≡C—, and one or more of arbitrary hydrogen atoms in the alkyl group may be substituted with a fluorine atom;
W¹¹ represents a group having at least one aromatic group and 5 to 30 carbon atoms and the group may be unsubstituted or substituted with one or more of L¹'s;
W² represents a hydrogen atom or a linear or branched alkyl group having 1 to 20 carbon atoms in which one —CH₂— or two or more (—CH₂—)'s which are not adjacent to each other may be each independently substituted with —O—, —S—, —CO—, —COO—, —OCO—, —CO—S—, —S—CO—, —O—CO—O—, —CO—NH—, —NH—CO—, —CH═CH—COO—, —CH═CH—OCO—, —COO—CH═CH—, —OCO—CH═CH—, —CH═CH—, —CF═CF—, or —C≡C—, and one or more of arbitrary hydrogen atoms in the alkyl group may be substituted with a fluorine atom, W¹² may have the same definition as that for W¹¹, W¹¹ and W¹² may be linked to each other to form a ring structure, or W¹² represents a group selected from groups represented by the following formula: 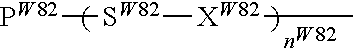
wherein P^{W82} has the same definition as that for R¹¹, S^{W82} has the same definition as that for S¹¹, X^{W82} has the same definition as that for X¹¹, and n^{W82} has the same definition as that for k, and one or more of arbitrary hydrogen atoms in the alkyl group may be substituted with a fluorine atom); and
L¹ represents a fluorine atom, a chlorine atom, a bromine atom, an iodine atom, a pentafluorosulfuranyl group, a nitro group, an isocyano group, an amino group, a hydroxyl group, a mercapto group, a methylamino group, a dimethylamino group, a diethylamino group, a diisopropylamino group, a trimethylsilyl group, a dimethylsilyl group, a thioisocyano group, or an alkyl group having 1 to 20 carbon atoms, and the alkyl group may be linear or branched, one or more of arbitrary hydrogen atoms may be substituted with a fluorine atom, one —CH₂— or two or more (—CH₂—)'s which are not adjacent to each other in the alkyl group may be each independently substituted with a group selected from —O—, —S—, —CO—, —COO—, —OCO—, —CO—S—, —S—CO—, —O—CO—O—, —CO—NH—, —NH—CO—, —CH═CH—COO—, —CH═CH—OCO—, —COO—CH═CH—, —OCO—CH═CH—, —CH═CH—, —CF═CF—, or —C≡C—, and in a case where a plurality of L is present in the compound, these may be the same as or different from each other.

2. The polymerizable composition according to claim 1,
wherein, in General Formula (1), P¹¹ represents a group selected from groups represented by Formula (P-1) to (P-20):

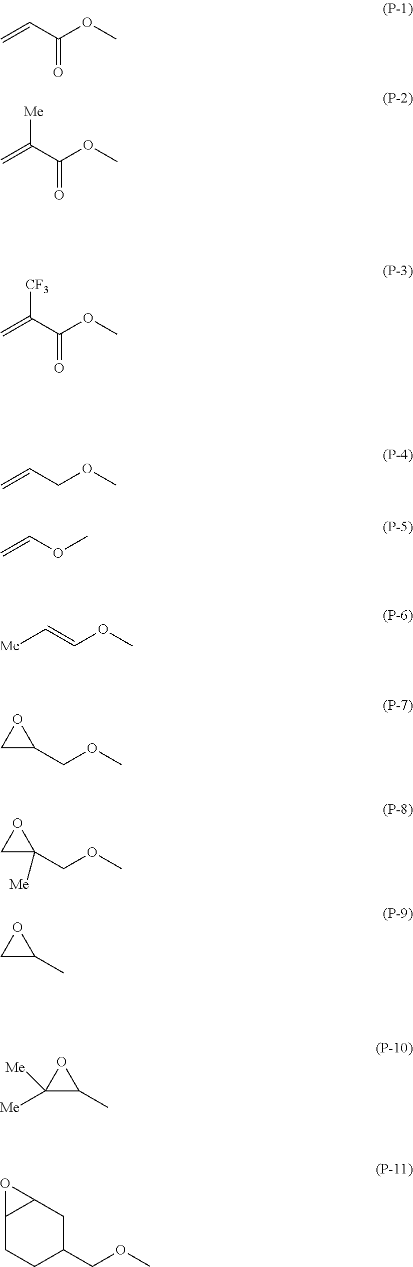

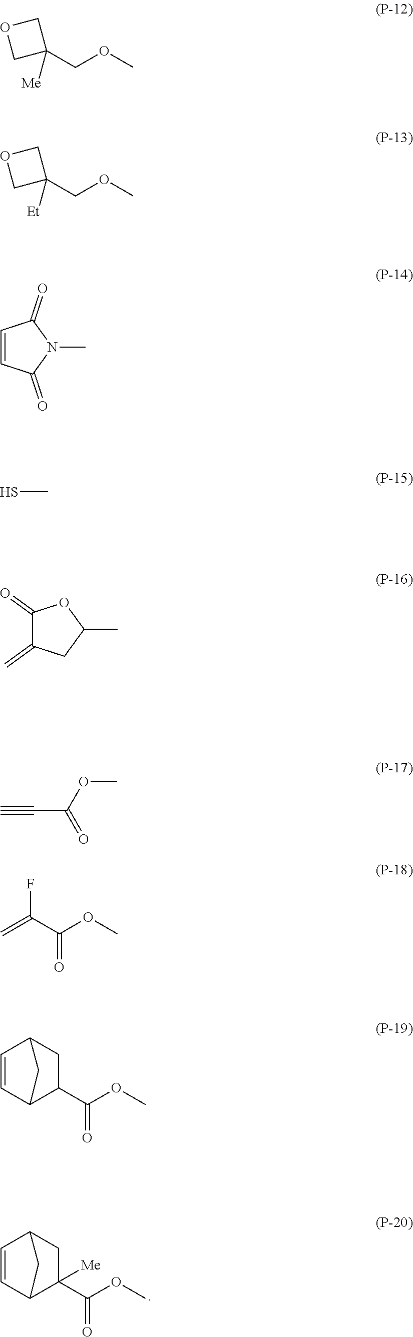

3. The polymerizable composition according to claim 1,
wherein, in General Formula (1), k represents 1 and S¹¹ represents an alkylene group having 1 to 20 carbon atoms in which one —CH₂— or two or more (—CH₂—)'s which are not adjacent to each other may be each independently substituted with —O—, —COO—, —OCO—, —OCO—O—, —CO—NH—, —NH—CO—, —CH═CH—, or —C≡C—.

4. The polymerizable composition according to claim 1,
wherein the total number of π electrons included in groups represented by W¹¹ and W¹² in General Formula (1) is from 4 to 24.

5. The polymerizable composition according to claim 1,
wherein the aromatic group included in the group as W¹¹ in General Formula (1) is a group represented by any of Formulae (W-1) to (W-19): 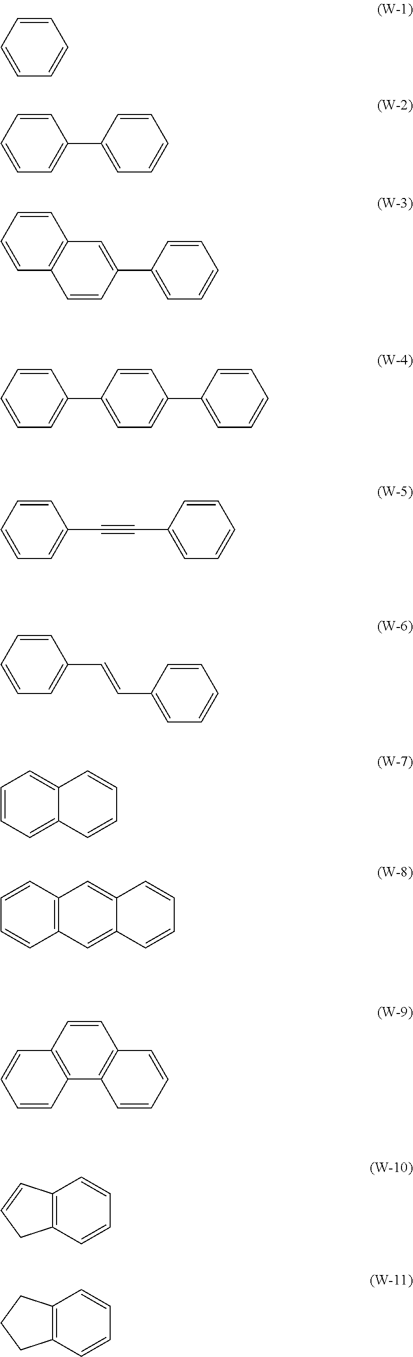 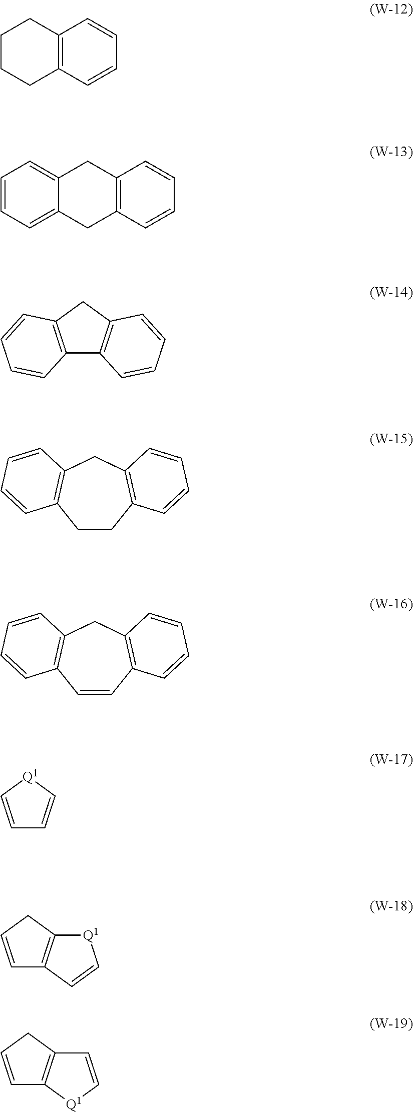
wherein these groups may have a binding site at an arbitrary position, Q¹ represents —O—, —S—, —NR³— (where R³ represents a hydrogen atom or an alkyl group having 1 to 8 carbon atoms), or —CO—, (—CH═)'s in these aromatic groups may be each independently substituted with —N═, (—CH₂—)'s may be each independently substituted with —O—, —S—, —NR⁴— (where R⁴ represents a hydrogen atom or an alkyl group having 1 to 8 carbon atoms), or —CO—, provided that they do not have a —O—O— bond, these aromatic groups may be unsubstituted or substituted with one or more of L's, and two or more aromatic groups selected from these groups may form a group by being linked to each other through a single bond.

6. The polymerizable composition according to claim 1,
wherein the polymerizable compound containing at least two or more polymerizable groups is a compound represented by any of General Formulae (2) to (7): 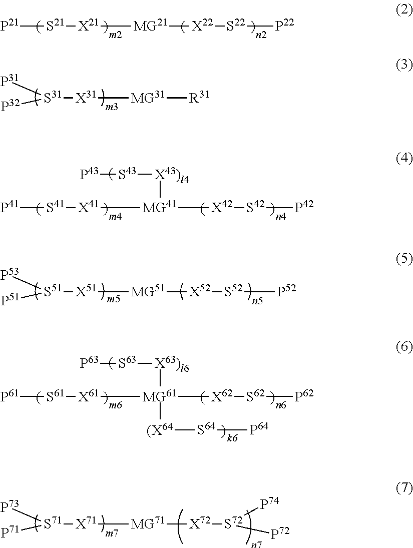
wherein P²¹ to P⁷⁴ each independently represent a polymerizable group;
S²¹ to S⁷² each independently represent a spacer group or a single bond, and hi a case where a plurality of each of S²¹ to S⁷² is present, these may be the same as or different from each other;
X²¹ to X⁷² each independently represent —O—, —S—, —OCH₂—, —CH₂O—, —CO—, —COO—, —OCO—, —CO—S—, —S—CO—, —O—CO—O—, —CO—NH—, —NH—CO—, —SCH₂—, —CH₂S—, —CF₂O—, —OCF₂—, —CF₂S—, —SCF₂—, —CH═CH—COO—, —CH═CH—OCO—, —COO—CH═CH—, —OCO—CH=CH—, —COO—CH₂CH₂—, —OCO—CH₂CH₂—, —CH₂CH₂—COO—, —CH₂CH₂—OCO—, —COO—CH₂—, —OCO—CH₂—, —CH₂—COO—, —CH₂—OCO—, —CH═CH—, —N═N—, —CH═N—N═CH—, —CF═CF—, —C≡C—, or a single bond, and in a case where a plurality of each of X²¹ to X⁷² is present, these may be the same as or different from each other, provided that each P—(S—X)— bond does not have —O—O—;
MG²¹ to MG⁷¹ each independently represent a mesogenic group; and
R³¹ represents a hydrogen atom, a fluorine atom, a chlorine atom, a bromine atom, an iodine atom, a pentafluorosulfuranyl group, a cyano group, a nitro group, an isocyano group, a thioisocyano group, or an alkyl group having 1 to 20 carbon atoms, the alkyl group may be linear or branched, one or more of arbitrary hydrogen atoms in the alkyl group may be substituted with a fluorine atom, and one —CH₂— or two or more (—CH₂—)'s which are not adjacent to each other in the alkyl group may be each independently substituted with —O—, —S—, —CO—, —COO—, —OCO—, —CO—S—, —S—CO—, —O—CO—O—, —CO—NH—, —NH—CO—, or —C≡C—; and
m2 to m7, n2 to n7, l4 to l6, and k6 each independently represent an integer of 0 to 5.

7. The polymerizable composition according to claim 6,
wherein the mesogenic group as MG²¹ to MG⁷¹ is a group selected from groups represented by Formula (8-a) or Formula (8-b): 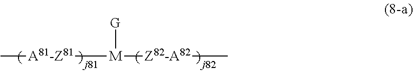
wherein A⁸¹ and A⁸² each independently represent a 1,4-phenylene group, a 1,4-cyclohexylene group, a pyridine-2,5-diyl group, a pyrimidine-2,5-diyl group, a naphthalene-2,6-diyl group, a naphthalene-1,4-diyl group, a tetrahydronaphthalene-2,6-diyl group, a decahydronaphthalene-2,6-diyl group, or a 1,3-dioxane-2,5-diyl group, these groups may be unsubstituted or substituted with one or more of L²'s, and in a case where a plurality of each of A⁸¹ and A⁸² is present, these may be the same as or different from each other;
Z⁸¹ and Z⁸² each independently represent —O—, —S—, —OCH₂—, —CH₂O—, —CH₂CH₂—, —CO—, —COO—, —OCO—, —CO—S—, —S—CO—, —O—CO—O—, —CO—NH—, —NH—CO—, —SCH₂—, —CH₂S—, —CF₂O—, —OCF₂—, —CF₂S—, —SCF₂—, —CH═CH—COO—, —CH═CH—OCO—, —COO—CH═CH—, —OCO—CH═CH—, —COO—CH₂CH₂—, —OCO—CH₂CH₂—, —CH₂CH₂—COO—, —CH₂CH₂—OCO—, —COO—CH₂—, —OCO—CH₂—, —CH₂—COO—, —CH₂—OCO—, —CH═CH—, —N═N—, —CH═N—, —N═CH—, —CH═N—N═CH—, —CF═CF—, —C≡C—, or a single bond, and in a case where a plurality of each of Z⁸¹ and Z⁸² is present, these may be the same as or different from each other;
M represents a group selected from groups represented by Formula (M-1) to Formula (M-11), and these groups may be unsubstituted or substituted with one or more of L²'s: 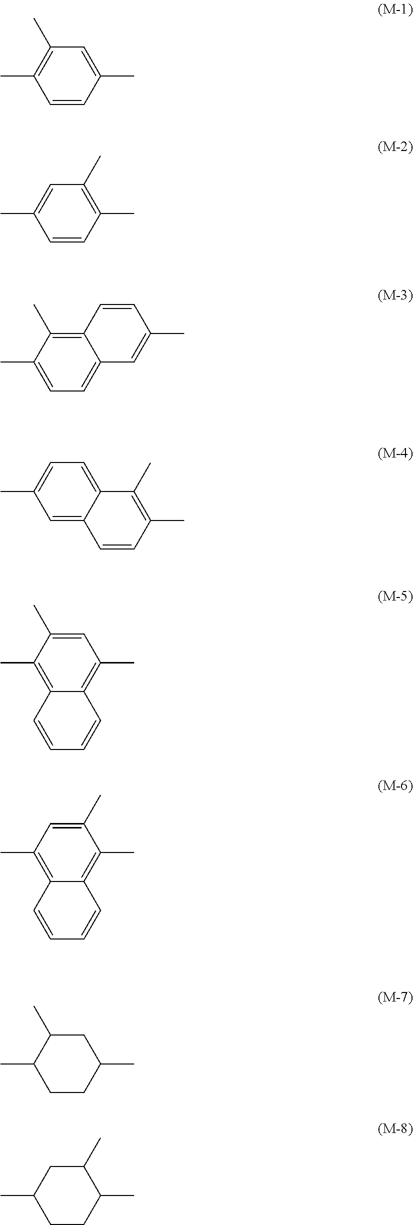 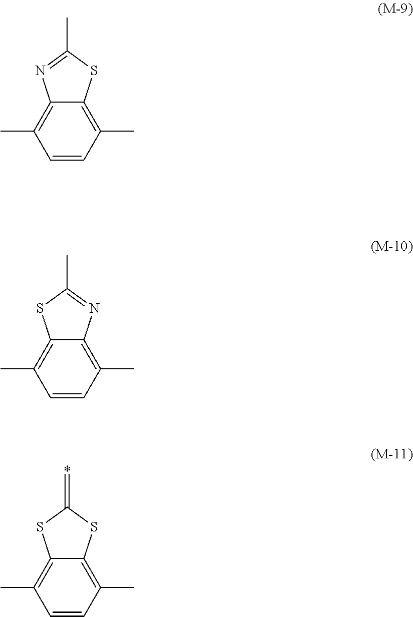
G represents a group selected from groups represented by Formula (G-1) to Formula (G-6): 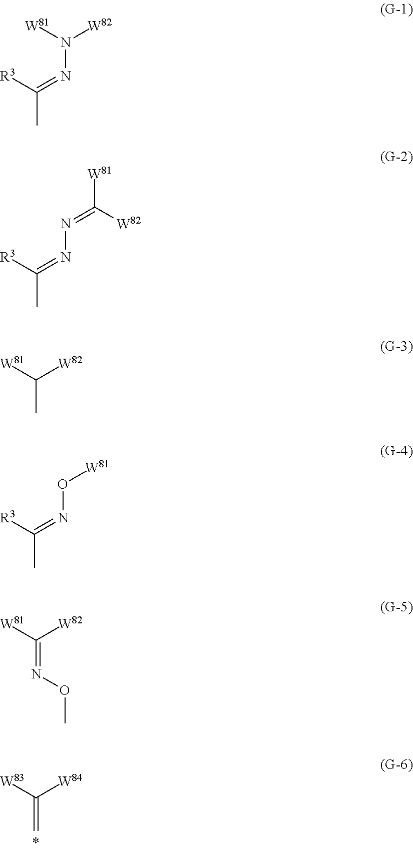
(wherein R³ represents a hydrogen atom or an alkyl group having 1 to 20 carbon atoms, the alkyl group may be linear or branched, one or more of arbitrary hydrogen atoms in the alkyl group may be substituted with a fluorine atom, and one —CH₂— or two or more (—CH₂—)'s which are not adjacent to each other in the alkyl group may be each independently substituted with —O—, —S—, —CO—, —COO—, —OCO—, —CO—S—, —S—CO—, —O—CO—O—, —CO—NH—, —NH—CO—, or —C≡C—;
W⁸¹ represents a group having at least one aromatic group and 5 to 30 carbon atoms and the group may be unsubstituted or substituted with one or more of L²'s; and
W⁸² represents a hydrogen atom or an alkyl group having 1 to 20 carbon atoms, the alkyl group may be linear or branched, one or more of arbitrary hydrogen atoms in the alkyl group may be substituted with a fluorine atom, one —CH₂— or two or more (—CH₂—)'s which are not adjacent to each other in the alkyl group may be each independently substituted with —O—, —S—, —CO—, —COO—, —OCO—, —CO—S—, —S—CO—, —O—CO—O—, —CO—NH—, —NH—CO—, —CH═CH—COO—, —CH═CH—OCO—, —COO—CH═CH—, —OCO—CH═CH—, —CH═CH—, —CF═CF—, or —C≡C—, W⁸² may have the same definition as that for W⁸¹, W⁸¹ and W⁸² may be linked to each other to form the same ring structure, and W⁸² represents a group represented by the following formula: 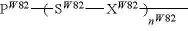
wherein P^{W82} has the same definition as that for P¹¹, S^{W82} has the same definition as that for S¹¹, X^{W82} has the same definition as that for X¹¹, and n^{W82} has the same definition as that for k;
W⁸³ and W⁸⁴ each independently represent a halogen atom, a cyano group, a hydroxy group, a nitro group, a carboxyl group, a carbamoyloxy group, an amino group, a sulfamoyl group, a group having at least one aromatic group and 5 to 30 carbon atoms, an alkyl group having 1 to 20 carbon atoms, a cycloalkyl group having 3 to 20 carbon atoms, an alkenyl group having 2 to 20 carbon atoms, a cycloalkenyl group having 3 to 20 carbon atoms, an alkoxy group having 1 to 20 carbon atoms, an acyloxy group having 2 to 20 carbon atoms, or an alkylcarbonyloxy group having 2 to 20 carbon atoms, one —CH₂— or two or more (—CH₂—)'s which are not adjacent to each other in the alkyl group, the cycloalkyl group, the alkenyl group, the cycloalkenyl group, the alkoxy group, the acyloxy group, and the alkylcarbonyloxy group may be each independently substituted with —O—, —S—, —CO—, —COO—, —OCO—, —CO—S—, —S—CO—, —O—CO—O—, —CO—NH—, —NH—CO—, or —C≡C—); provided that G represents a group selected from groups represented by Formula (G-1) to Formula (G-5) in a case where M represents a group selected from groups represented by Formula (M-1) to Formula (M-10) and G represents a group represented by Formula (G-6) in a case where M represents a group represented by Formula (M-11);
L² represents a fluorine atom, a chlorine atom, a bromine atom, an iodine atom, a pentafluorosulfuranyl group, a nitro group, an isocyano group, an amino group, a hydroxyl group, a mercapto group, a methylamino group, a dimethylamino group, a diethylamino group, a diisopropylamino group, a trimethylsilyl group, a dimethylsilyl group, a thioisocyano group, or an alkyl group having 1 to 20 carbon atoms, and the alkyl group may be linear or branched, one or more of arbitrary hydrogen atoms may be substituted with a fluorine atom, one —CH₂— or two or more (—CH₂—)'s which are not adjacent to each other in the alkyl group may be each independently substituted with a group selected from —O—, —S—, —CO—, —COO—, —OCO—, —CO—S—, —S—CO—, —O—CO—O—, —CO—NH—, —NH—CO—, —CH═CH—COO—, —CH═CH—OCO—, —COO—CH═C—, —OCO—CH═CH—, —CH═CH—, —CF═CF—, or —C≡C—, and in a case where a plurality of L² is present in the compound, these may be the same as or different from each other; and
j81 and j82 each independently represent an integer of 0 to 5, provided that j81+j82 represents an integer of 1 to 5: 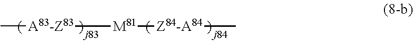
wherein A⁸³ and A⁸⁴ each independently represent a 1,4-phenylene group, a 1,4-cyclohexylene group, a pyridine-2,5-diyl group, a pyrimidine-2,5-diyl group, a naphthalene-2,6-diyl group, a naphthalene-1,4-diyl group, a tetrahydronaphthalene-2,6-diyl group, a decahydronaphthalene-2,6-diyl group, or a 1,3-dioxane-2,5-diyl group, these groups may be unsubstituted or substituted with one or more of L²'s, and in a case where a plurality of each of A⁸³ and A⁸⁴ is present, these may be the same as or different from each other;
Z⁸³ and Z⁸⁴ each independently represent —O—, —S—, —OCH₂—, —CH₂O—, —CH₂CH₂—, —CO—, —COO—, —OCO—, —CO—S—, —S—CO—, —O—CO—O—, —CO—NH—, —NH—CO—, —SCH₂—, —CH₂S—, —CF₂O—, —OCF₂—, —CF₂S—, —SCF₂—, —CH═CH—COO—, —CH═CH—OCO—, —COO—CH═CH—, —OCO—CH═CH—COO—CH₂CH₂—, —OCO—CH₂CH₂—, —CH₂CH₂—COO—, —CH₂CH—OCO—, —COO—CH₂—, —OCO—CH₂—, —CH₂—COO—, —CH₂—OCO—, —CH═CH—, —N═N—, —CH═N—, —N═CH—, —CH═N—N═CH—, —CF═CF—, —C≡C—, or a single bond, and in a case where a plurality of each of Z⁸³ and Z⁸⁴ is present, these may be the same as or different from each other;
M⁸¹ represents a group selected from a 1,4-phenylene group, a 1,4-cyclohexylene group, a 1,4-cyclohexenyl group, a tetrahydropyran-2,5-diyl group, a 1,3-dioxane-2,5-diyl group, a tetrahydrothiopyran-2,5-diyl group, a 1,4-bicyclo(2,2,2)octylene group, a decahydronaphthalene-2,6-diyl group, a pyridine-2,5-diyl group, a pyrimidine-2,5-diyl group, a pyrazine-2,5-diyl group, a thiophene-2,5-diyl group, a 1,2,3,4-tetrahydronaphthalene-2,6-diyl group, a naphthylene-1,4-diyl group, a naphthylene-1,5-diyl group, a naphthylene-1,6-diyl group, a naphthylene-2,6-diyl group, a phenanthrene-2,7-diyl group, a 9,10-dihydrophenanthrene-2,7-diyl group, a 1,2,3,4,4a,9,10a-octahydrophenanthrene-2,7-diyl group, a benzo[1,2-b:4,5-b′]dithiophene-2,6-diyl group, a benzo[1,2-b:4,5-b′]diselenophene-2,6-diyl group, a [1]benzothieno[3,2-b]thiophene-2,7-diyl group, a [1]benzoselenopheno[3,2-b]selenophene-2,7-diyl group, and a fluorene-2,7-diyl group, and these groups may be unsubstituted or substituted with one or more of L²'s; and
L² represents a fluorine atom, a chlorine atom, a bromine atom, an iodine atom, a pentafluorosulfuranyl group, a nitro group, an isocyano group, an amino group, a hydroxyl group, a mercapto group, a methylamino group, a dimethylamino group, a diethylamino group, a diisopropylamino group, a trimethylsilyl group, a dimethylsilyl group, a thioisocyano group, or an alkyl group having 1 to 20 carbon atoms, and the alkyl group may be linear or branched, one or more of arbitrary hydrogen atoms may be substituted with a fluorine atom, one —CH₂— or two or more (—CH₂—)'s which are not adjacent to each other in the alkyl group may be each independently substituted with a group selected from —O—, —S—, —CO—, —COO—, —OCO—, —CO—S—, —S—CO—, —O—CO—O—, —CO—NH—, —NH—CO—, —CH═CH—COO—, —CH═CH—OCO—, —COO—CH═CH—, —OCO—CH═CH—, —CH═CH—, —CF═CF—, or —C≡C—, and in a case where a plurality of L² is present in the compound, these may be the same as or different from each other, m represents an integer of 0 to 8; and
j83 and j84 each independently represent an integer of 0 to 5, provided that j83+j84 represents an integer of 1 to 5.

8. The polymerizable composition according to claim 6,
wherein polymerizable groups P²¹ to P⁷⁴ each independently represent a group represented by any of Formulae (P-1) to (P-20):

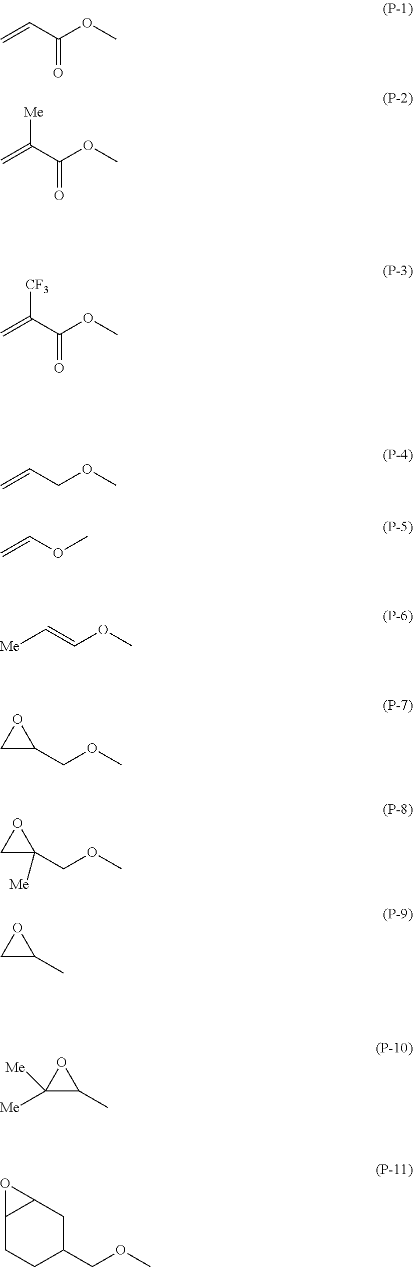

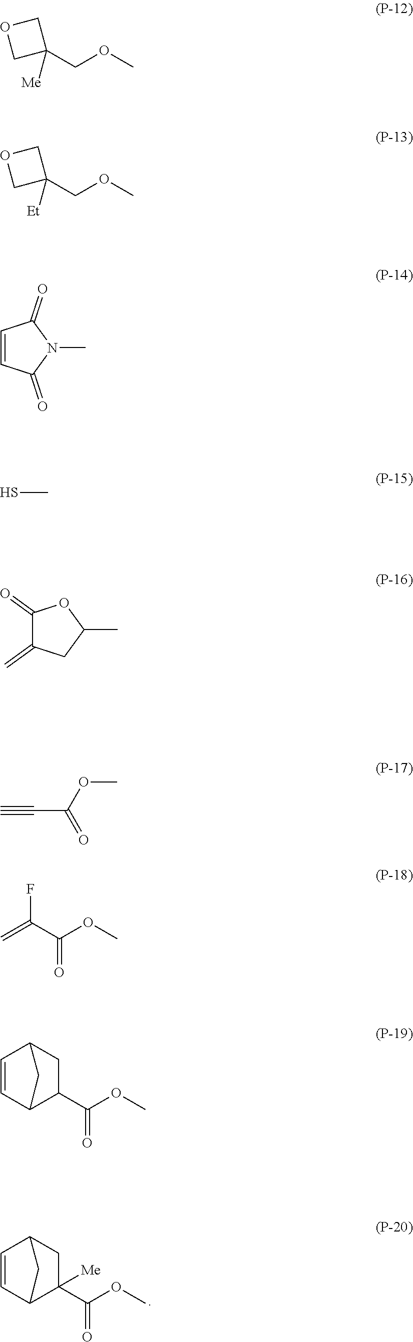

9. The polymerizable composition according to claim 1,
wherein the polymerizable compound containing at least two or more polymerizable groups satisfies Formula (I):
Re(450 nm)/Re(550 nm)<1.0 (I)
wherein Re (450 nm) represents an in-plane phase difference of the compound containing at least two or more polymerizable groups at a wavelength of 450 nm when the polymerizable compound is aligned on a substrate such that a long axis direction of the molecule is substantially horizontal with respect to the substrate and Re (550 nm) represents an in-plane phase difference of the compound containing at least two or more polymerizable groups at a wavelength of 550 nm when the polymerizable compound is aligned on a substrate such that a long axis direction of the molecule is substantially horizontal with respect to the substrate.

10. A polymer obtained by using the polymerizable composition according to claim 1.

11. An optically anisotropic body obtained by using the polymerizable composition according to claim 1.

12. A retardation film obtained by using the polymerizable composition according to claim 1.

13. A display element comprising:
the optically anisotropic body according to claim 11.

14. A light-emitting element comprising:
the optically anisotropic body according to claim 11.

15. A light-emitting diode lighting device comprising:
the polymer according to claim 10.

16. A reflective film comprising:
the retardation film according to claim 12.

17. A lens sheet comprising:
the polymer according to claim 10.

18. A polymerizable composition comprising:
the polymerizable composition according to claim 1; and
a dichroic dye.

19. A polarizing film obtained by using the polymerizable composition according to claim 18.

20. A polymerizable composition comprising:
the polymerizable composition according to claim 1 and at least one derivative selected from an azo derivative, a chalcone derivative, a coumarin derivative, a cinnamate derivative, and a cycloalkane derivative.

21. An optically anisotropic body obtained by using the polymerizable composition according to claim 20.

22. A retardation film obtained by using the polymerizable composition according to claim 20.

23. A display element comprising:
the retardation film according to claim 12.

24. A light-emitting element comprising:
the retardation film according to claim 12.
